(19) United States
(12) Patent Application Publication
(10) Pub. No.: US 2026/0096278 A1
(43) Pub. Date: Apr. 2, 2026

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Cuifang ZHANG, Beijing (CN); Han ZHANG, Beijing (CN); Qi ZHANG, Beijing (CN); Zhihong DAI, Beijng (CN); Chi Yuen Raymond Kwong, Beijing (CN); Cuanjun Xia, Beijing (CN)

(21) Appl. No.: 19/343,521

(22) Filed: Sep. 29, 2025

(30) Foreign Application Priority Data
Sep. 30, 2024 (CN) 202411385706.4

(51) Int. Cl. H10K 50/11; C09K 11/06; H10K 85/30; H10K 85/40; H10K 85/60; H10K 101/00

(52) U.S. Cl. CPC H10K 50/11; C09K 11/06; H10K 85/342; H10K 85/40; H10K 85/622; H10K 85/626; H10K 85/633; H10K 85/636; H10K 85/654; H10K 85/656; H10K 85/6572; H10K 85/6574; H10K 85/6576; C09K 2211/185; H10K 2101/90

(57) ABSTRACT

Provided are an organic electroluminescent material and a device. The organic electroluminescent material is a metal complex comprising a ligand having a structure of Formula 1 and a ligand having a structure of Formula 3. Since particular biphenylene represented by Formula 2 or a similar structure thereof is introduced into a skeleton structure of a ligand Lₐ and a particular ligand having a PPy skeleton structure is used, the metal complex can achieve light emission in different bands from deep red to near infrared, having great potential to become a phosphorescent material with excellent performance, and having great application potential and broad application prospects of bringing devices excellent performance such as low voltages, high efficiency and long lifetimes. Further provided are an organic electroluminescent device comprising the metal complex and a compound composition comprising the metal complex.

### CROSS-REFERENCE TO RELATED APPLICATION(S)

This application claims priority to Chinese Patent Application No. 202411385706.4 filed on Sep. 30, 2024, the disclosure of which is incorporated herein by reference in its entirety.

### TECHNICAL FIELD

The present disclosure relates to compounds for organic electronic devices such as organic light-emitting devices. More particularly, the present disclosure relates to a metal complex comprising a ligand having a structure of Formula 1 and a ligand having a structure of Formula 3, an organic electroluminescent device comprising the metal complex and a compound composition comprising the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation (VTE method). Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

CN111269269A discloses an iridium complex. The iridium complex has a general structure of Formula I:

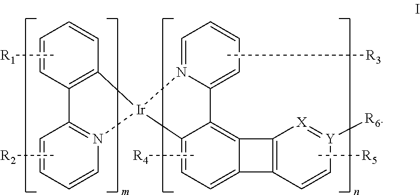

This iridium complex disclosed in the related art must have a ligand structure where pyridine is joined at a particular position of biphenylene. The application has neither disclosed nor taught an application of a ligand formed by joining biphenylene and a similar structure thereof to other carbocyclic rings or heterocyclic rings in a metal complex, nor has the application discovered a unique advantage of such metal complex.

Phosphorescent materials have been reported in the related art. However, further research and development is still required to meet the increasing requirements of the industry on device performance such as emitted colors of devices, luminescence saturation, voltage, device efficiency and device lifetime.

### SUMMARY

The present disclosure aims to provide a series of new metal complexes to solve at least part of the above-mentioned problems. Since particular biphenylene or a similar structure thereof represented by Formula 2 is introduced into a skeleton structure of a ligand Lₐ and a particular ligand having a PPy skeleton structure is used, the new metal complex can achieve light emission in different bands from deep red to near-infrared, having great potential to become a phosphorescent material with excellent performance, and having great application potential and broad application prospects of bringing devices excellent performance such as low voltages, high efficiency and long lifetimes.

According to an embodiment of the present disclosure, disclosed is a metal complex having a general formula of M(Lₐ)ₘ(L_{b})ₙ(L_{c})_{q}, wherein the metal M is selected from a metal with a relative atomic mass greater than 40, and Lₐ, L_{b} and Le are a first ligand, a second ligand and a third ligand coordinated to the metal M, respectively; Lₐ, L_{b} and L_{c} are the same or different;
Lₐ, L_{b} and L_{c} can be optionally joined to form a multidentate ligand;
m is 1 or 2, n is 1 or 2, q is 0 or 1, and m+n+q is equal to an oxidation state of the metal M; when m is equal to 2, two Lₐ are the same or different; when n is equal to 2, two L_{b} are the same or different;
the first ligand Lₐ has a structure represented by Formula 1:

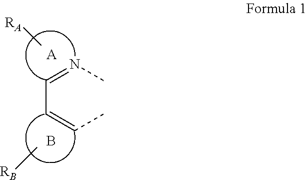

the ring A or the ring B has a structure represented by Formula 2:

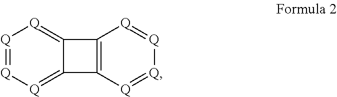

Q is, at each occurrence identically or differently, selected from N or C;
when the ring A has the structure represented by Formula 2, the ring B is selected from an unsaturated carbocyclic ring having 5 to 30 carbon atoms or an unsaturated heterocyclic ring having 2 to 30 carbon atoms;
when the ring B has the structure represented by Formula 2, the ring A is selected from a fused heteroaromatic ring having 3 to 30 carbon atoms;
R_{A} and R_{B} represent, at each occurrence identically or differently, mono-substitution, multiple substitutions or non-substitution;
R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{A} and R_{B} can be optionally joined to form a ring;
the second ligand L_{b} is represented by Formula 3:

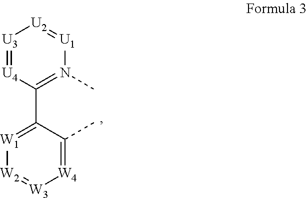

U₁ to U₄ are, at each occurrence identically or differently, selected from N or CR_{U};
W₁ to W₄ are, at each occurrence identically or differently, selected from N or CR_{W};
R_{U} and R_{W} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{U} and R_{W} can be optionally joined to form a ring; and
L_{c} is selected from a monoanionic bidentate ligand.

According to another embodiment of the present disclosure, further disclosed is an electroluminescent device. The electroluminescent device comprises an anode, a cathode and an organic layer disposed between the anode and the cathode, wherein the organic layer comprises a metal complex whose structure is described in the preceding embodiment.

According to another embodiment of the present disclosure, further disclosed is a in compound composition. The compound composition comprises a metal complex whose structure is described in the preceding embodiment.

Since particular biphenylene or a similar structure thereof represented by Formula 2 is introduced into a skeleton structure of a ligand Lₐ and a particular ligand having a PPy skeleton structure is used, the new metal complex disclosed in the present disclosure can achieve light emission in different bands from deep red to near-infrared, having great potential to become a phosphorescent material with excellent performance, and having great application potential and broad application prospects of bringing devices excellent performance such as low voltages, high efficiency and long lifetimes.

### BRIEF DESCRIPTION OF DRAWINGS

FIG. 1 is a schematic diagram of an organic light-emitting device that may contain a metal complex and a compound composition disclosed herein.

FIG. 2 is a schematic diagram of another organic light-emitting device that may contain a metal complex and a compound composition disclosed herein.

### DETAILED DESCRIPTION

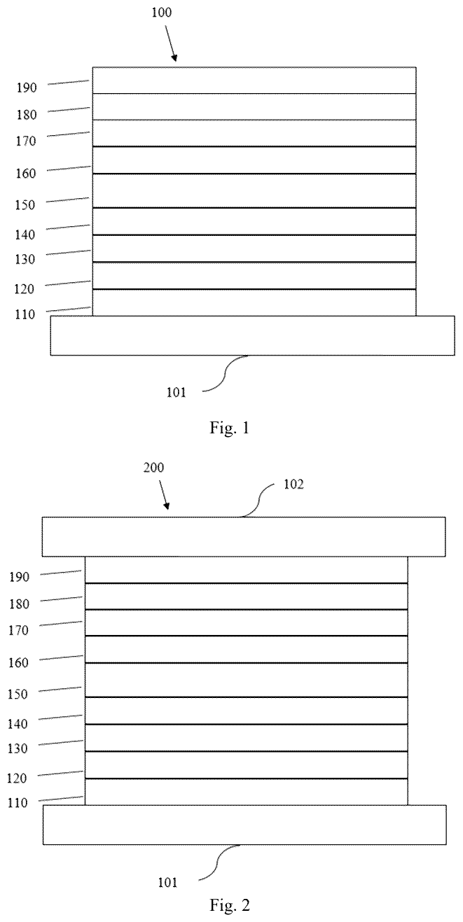

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEs-T).

Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small AEs-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with at least one aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions, etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

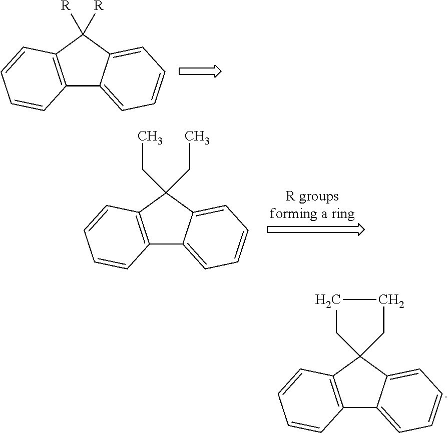

The expression that adjacent substituents can be optionally joined to form a ring is also intended to mean that two substituents bonded to carbon atoms which are directly bonded to each other are joined to each other via a chemical bond to form a ring, which can be exemplified by the following formula:

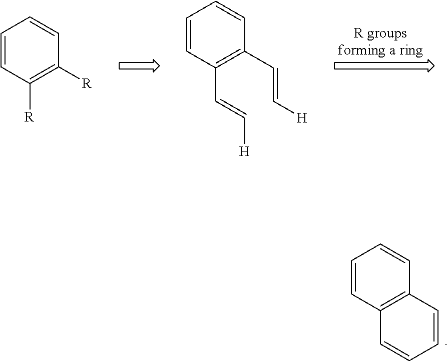

The expression that adjacent substituents can be optionally joined to form a ring is also intended to mean that two substituents bonded to further distant carbon atoms are joined to each other via a chemical bond to form a ring, which can be exemplified by the following formula:

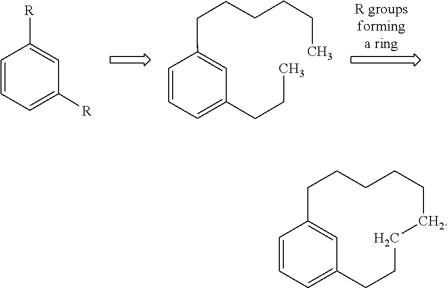

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

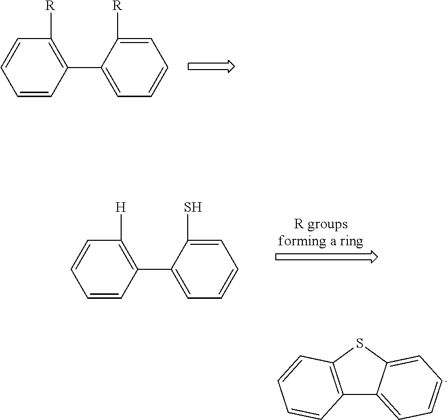

According to an embodiment of the present disclosure, disclosed is a metal complex having a general formula of M(Lₐ)ₘ(L_{b})ₙ(L_{c})_{q}, wherein the metal M is selected from a metal with a relative atomic mass greater than 40, and Lₐ, L_{b} and L_{c} are a first ligand, a second ligand and a third ligand coordinated to the metal M, respectively; Lₐ, L_{b} and L_{c} are the same or different;
Lₐ, L_{b} and L_{c} can be optionally joined to form a multidentate ligand;
m is 1 or 2, n is 1 or 2, q is 0 or 1, and m+n+q is equal to an oxidation state of the metal M;
when m is equal to 2, two Lₐ are the same or different; when n is equal to 2, two L_{b} are the same or different;
the first ligand Lₐ has a structure represented by Formula 1:

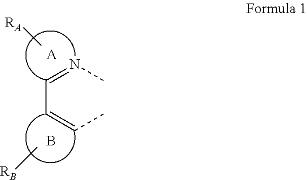

the ring A or the ring B has a structure represented by Formula 2:

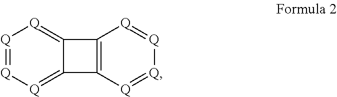

Q is, at each occurrence identically or differently, selected from N or C;
when the ring A has the structure represented by Formula 2, the ring B is selected from an unsaturated carbocyclic ring having 5 to 30 carbon atoms or an unsaturated heterocyclic ring having 2 to 30 carbon atoms;
when the ring B has the structure represented by Formula 2, the ring A is selected from a fused heteroaromatic ring having 3 to 30 carbon atoms;
R_{A} and R_{B} represent, at each occurrence identically or differently, mono-substitution, multiple substitutions or non-substitution;
R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{A} and R_{B} can be optionally joined to form a ring;
the second ligand L_{b} is represented by Formula 3:

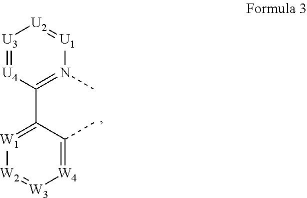

U₁ to U₄ are, at each occurrence identically or differently, selected from N or CR_{U};
W₁ to W₄ are, at each occurrence identically or differently, selected from N or CR_{W};
R_{U} and R_{W} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{U} and R_{W} can be optionally joined to form a ring; and
L_{c} is selected from a monoanionic bidentate ligand.

In this embodiment, when the ring A has the structure represented by Formula 2, the ring B is selected from an unsaturated carbocyclic ring having 5 to 30 carbon atoms or an unsaturated heterocyclic ring having 2 to 30 carbon atoms. The unsaturated carbocyclic ring may be a non-aromatic unsaturated carbocyclic ring or an aromatic unsaturated carbocyclic ring (i.e., an aromatic ring), and the unsaturated heterocyclic ring may be a non-aromatic unsaturated heterocyclic ring or an aromatic unsaturated heterocyclic ring (i.e., a heteroaromatic ring).

In this embodiment, when the ring B has the structure represented by Formula 2, the ring A is selected from a fused heteroaromatic ring having 3 to 30 carbon atoms. The fused heteroaromatic ring aims to represent a heteroaromatic ring formed by the fusion of at least two monocyclic rings, for example, a quinoline ring and an isoquinoline ring are both formed by the fusion of a benzene ring (a monocyclic aromatic ring) and a pyridine ring (a monocyclic heteroaromatic ring), and a dibenzofuran ring is formed by the fusion of two benzene rings (monocyclic aromatic rings) and one furan ring (a monocyclic heteroaromatic ring). Apparently, those skilled in the art can understand that monocyclic heteroaromatic rings such as a pyridine ring, a pyrimidine ring, a triazine ring and a furan ring do not belong to the fused heteroaromatic ring described herein.

In the present disclosure, the expression that adjacent substituents R_{A} and R_{B} can be optionally joined to form a ring is intended to mean that one or more of groups of adjacent substituents, such as two adjacent substituents R_{A}, two adjacent substituents R_{B}, and adjacent substituents R_{A} and R_{B}, can be joined to form a ring. Obviously, it is also possible that none of these groups of adjacent substituents are joined to form a ring.

In the present disclosure, the expression that adjacent substituents R_{U} and R_{W} can be optionally joined to form a ring is intended to mean that one or more of groups of adjacent substituents, such as two adjacent substituents R_{U}, two adjacent substituents R_{W}, and adjacent substituents R_{U} and R_{W}, can be joined to form a ring. Obviously, it is also possible that none of these groups of adjacent substituents are joined to form a ring.

In the present disclosure, in Lₐ, the ring A has the structure represented by Formula 2:

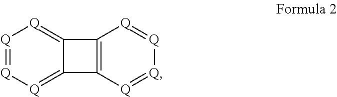

wherein obviously, one of Q is selected from N and joined to the metal M.

According to an embodiment of the present disclosure, in Lₐ, the ring A has the structure represented by Formula 2, and the ring B is selected from an aromatic ring having 6 to 30 carbon atoms or a heteroaromatic ring having 3 to 30 carbon atoms.

According to an embodiment of the present disclosure, in Lₐ, the ring B has the structure represented by Formula 2, the ring A is selected from a heteroaromatic ring having 3 to 30 carbon atoms, and Lₐ does not have a structure represented by Formula X:

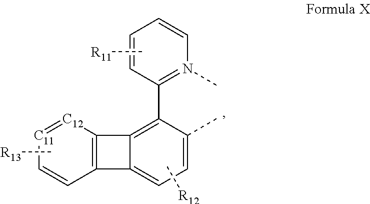

wherein in Formula X, R₁₁, R₁₂ and R₁₃ each independently represent mono-substitution, multiple substitutions or non-substitution;
C₁₁ and C₁₂ are each independently selected from CR₁₃ or N;
R₁₁, R₁₂ and R₁₃ are each independently selected from hydrogen, deuterium, halogen, cyano, substituted or unsubstituted alkyl having 1 to 20 carbon atoms, substituted or unsubstituted aryl having 6 to 30 carbon atoms, substituted or unsubstituted heteroaryl having 3 to 30 carbon atoms or a combination thereof.

According to an embodiment of the present disclosure, in Lₐ, the ring B has the structure represented by Formula 2, and the ring A is selected from a heteroaromatic ring having 6 to 30 carbon atoms.

According to an embodiment of the present disclosure, in Lₐ, the ring B has the structure represented by Formula 2, and the ring A is selected from a fused heteroaromatic ring having 8 to 30 ring atoms.

According to an embodiment of the present disclosure, in Lₐ, the ring B has the structure represented by Formula 2, and the ring A is selected from a fused heteroaromatic ring having 9 to 30 ring atoms.

According to an embodiment of the present disclosure, in Lₐ, the ring B has the structure represented by Formula 2, and the ring A is selected from a fused heteroaromatic ring having 10 to 30 ring atoms.

According to an embodiment of the present disclosure, in Lₐ, the ring B has the structure represented by Formula 2, and the ring A is selected from a fused heteroaromatic ring having 9 to 24 ring atoms.

According to an embodiment of the present disclosure, in Lₐ, the ring B has the structure represented by Formula 2, and the ring A is selected from a fused heteroaromatic ring having 9 to 18 ring atoms.

According to an embodiment of the present disclosure, in Lₐ, the ring A has the structure represented by Formula 2, and the ring B is selected from an aromatic ring having 6 to 18 carbon atoms or a heteroaromatic ring having 3 to 18 carbon atoms.

According to an embodiment of the present disclosure, in Lₐ, the ring A has the structure represented by Formula 2, and the ring B is selected from a benzene ring, a naphthalene ring, a pyridine ring, a pyrimidine ring, a pyrazine ring, an azanaphthalene ring, a furan ring, a thiophene ring, an isoxazole ring, an isothiazole ring, a pyrrole ring, a pyrazole ring, a benzofuran ring, a benzothiophene ring, a benzopyrrole ring, a dibenzofuran ring, a dibenzothiophene ring, a dibenzopyrrole ring, an azabenzofuran ring or an azabenzothiophene ring.

According to an embodiment of the present disclosure, in Lₐ, the ring A has the structure represented by Formula 2, and the ring B is selected from a benzene ring, a naphthalene ring, a benzofuran ring, a benzothiophene ring, a dibenzofuran ring, a dibenzothiophene ring or a dibenzopyrrole ring.

According to an embodiment of the present disclosure, in Lₐ, the ring B has the structure represented by Formula 2, and the ring A is selected from a fused heteroaromatic ring having 3 to 18 carbon atoms.

According to an embodiment of the present disclosure, in Lₐ, the ring B has the structure represented by Formula 2, and the ring A is selected from a quinoline ring, an isoquinoline ring, a benzoquinoline ring, a benzisoquinoline ring, a quinazoline ring, a benzoxazole ring, a benzisothiazole ring, a benzopyrrole ring, a benzopyrazole ring, an azabenzofuran ring, an azabenzothiophene ring, an azabenzopyrrole ring, an azadibenzofuran ring, an azadibenzothiophene ring or an azadibenzopyrrole ring.

According to an embodiment of the present disclosure, in Lₐ, the ring B has the structure represented by Formula 2, and the ring A is selected from a quinoline ring, an isoquinoline ring, a benzoquinoline ring, a benzisoquinoline ring, an azadibenzofuran ring, an azadibenzothiophene ring or an azadibenzopyrrole ring.

According to an embodiment of the present disclosure, Lₐ is selected from a structure represented by any one of Formula 4 to Formula 27:

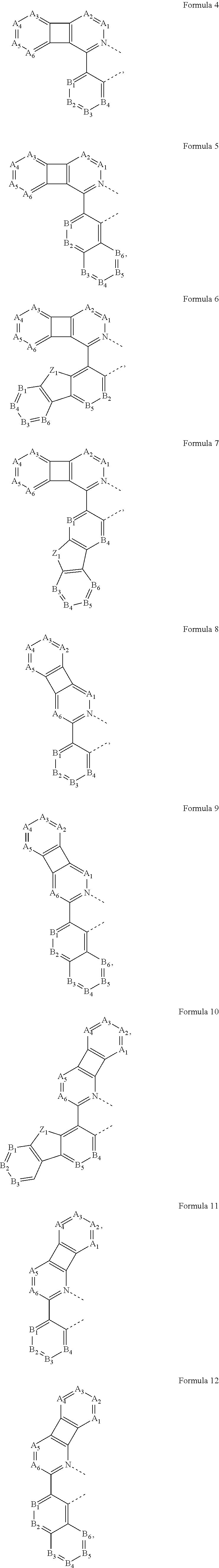

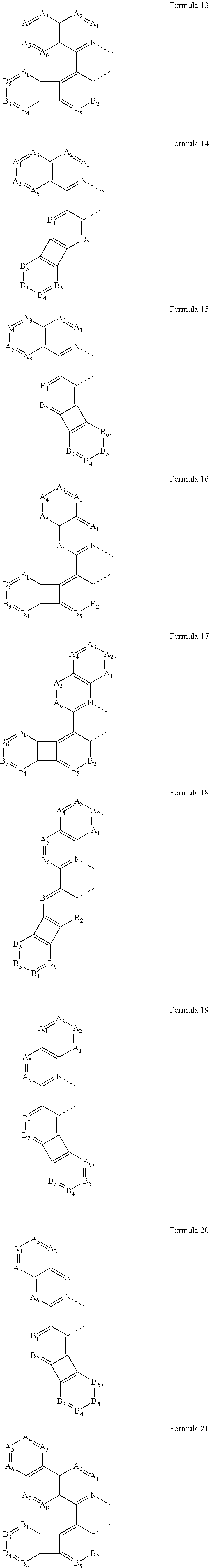

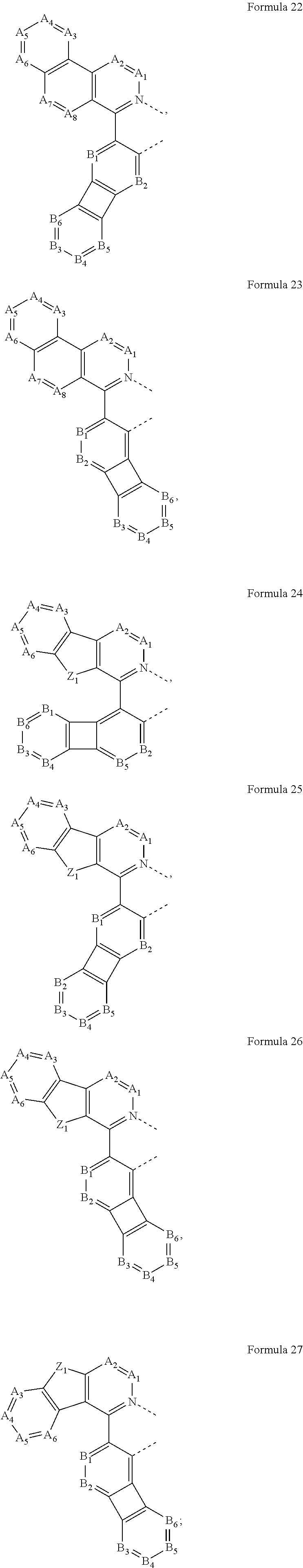

wherein,
A₁ to A₈ are, at each occurrence identically or differently, selected from N or CR_{A};
B₁ to B₆ are, at each occurrence identically or differently, selected from N or CR_{B};
Z₁ is, at each occurrence identically or differently, selected from O, S, Se, NR_{Z}, CR_{Z}R_{Z}, SiR_{Z}R_{Z} or PR_{Z};
R_{A}, R_{B} and R_{Z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{A}, R_{B} and R_{Z} can be optionally joined to form a ring.

In the present disclosure, the expression that adjacent substituents R_{A}, R_{B} and R_{Z} can be optionally joined to form a ring is intended to mean that one or more of groups of adjacent substituents, such as two adjacent substituents R_{A}, two adjacent substituents R_{B}, two adjacent substituents R_{Z}, adjacent substituents R_{A} and R_{Z}, adjacent substituents R_{B} and R_{Z}, and adjacent substituents R_{A} and R_{B}, can be joined to form a ring. Obviously, it is also possible that none of these groups of adjacent substituents are joined to form a ring.

According to an embodiment of the present disclosure, Lₐ is selected from a structure represented by Formula 4, Formula 5, Formula 10, Formula 12, Formula 13, Formula 15, Formula 17, Formula 19, Formula 21, Formula 23, Formula 24 or Formula 26.

According to an embodiment of the present disclosure, Lₐ is selected from a structure represented by Formula 5, Formula 12, Formula 15, Formula 19, Formula 21, Formula 23, Formula 24 or Formula 26.

According to an embodiment of the present disclosure, in Formula 6, Formula 7, Formula 10, Formula 24, Formula 25, Formula 26 or Formula 27, Z₁ is selected from O, S or NR_{Z}; R_{Z} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms and combinations thereof.

According to an embodiment of the present disclosure, in Formula 6, Formula 7, Formula 10, Formula 24, Formula 25, Formula 26 or Formula 27, Z₁ is selected from O or S.

According to an embodiment of the present disclosure, in Formula 4 to Formula 27, A₁ to A₈ are each independently selected from CR_{A}, and B₁ to B₆ are each independently selected from CR_{B}; R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{A} and R_{B} can be optionally joined to form a ring.

According to an embodiment of the present disclosure, in Formula 4 to Formula 27, A₁ to A₈ are each independently selected from CR_{A}, and B₁ to B₆ are each independently selected from CR_{B}; R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkoxy having 1 to 20 carbon atoms, substituted or unsubstituted aryloxy having 6 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group and combinations thereof; and
adjacent substituents R_{A} and R_{B} can be optionally joined to form a ring.

According to an embodiment of the present disclosure, in Formula 4 to Formula 27, A₁ to A₈ are each independently selected from CR_{A}, and B₁ to B₆ are each independently selected from CR_{B}; R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, a cyano group and combinations thereof; and
adjacent substituents R_{A} and R_{B} can be optionally joined to form a ring.

According to an embodiment of the present disclosure, in Formula 4 to Formula 27, at least one of A₁ to Aₘ is, at each occurrence identically or differently, selected from CR_{A}, wherein Aₘ corresponds to one with the largest serial number among A₁ to A₈ in any one of Formula 4 to Formula 27; R_{A} is, at each occurrence identically or differently, selected from the group consisting of: deuterium, halogen, cyano, hydroxyl, sulfanyl, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms and combinations thereof; and
adjacent substituents R_{A} can be optionally joined to form a ring.

In the present disclosure, Aₘ corresponds to one with the largest serial number among A₁ to A₈ in any one of Formula 4 to Formula 27. For example, for Formula 4, one with the largest serial number among A₁ to A₈ in Formula 4 is A₆, that is, for Formula 4, Aₘ is A₆. For example, for Formula 22, one with the largest serial number among A₁ to A₈ in Formula 22 is A₈, that is, for Formula 22, Aₘ is A₈. For other general formulas, the situations are similar and not repeated here.

In the present disclosure, the expression that adjacent substituents R_{A} can be optionally joined to form a ring is intended to mean that any adjacent substituents R_{A} can be joined to form a ring. Obviously, it is possible that any adjacent substituents R_{A} are not joined to form a ring.

According to an embodiment of the present disclosure, in Formula 4 to Formula 27, at least one of A₁ to Aₘ is, at each occurrence identically or differently, selected from CR_{A}, wherein Aₘ corresponds to one with the largest serial number among A₁ to A₈ in any one of Formula 4 to Formula 27; R_{A} is, at each occurrence identically or differently, selected from the group consisting of: deuterium, fluorine, cyano, hydroxyl, sulfanyl, amino, methoxy, phenoxy, methyl, ethyl, isopropyl, isobutyl, sec-butyl, tert-butyl, neopentyl, cyclopentyl, cyclopentylmethyl, cyclohexyl, norbornyl, adamantyl, trimethylsilyl, triethylsilyl, phenyldimethylsilyl, trimethylgermanyl, triethylgermanyl, phenyl, 2,6-dimethylphenyl, 2,6-diisopropylphenyl, pyridyl, pyrimidinyl, triazinyl and combinations thereof; and
adjacent substituents R_{A} can be optionally joined to form a ring.

According to an embodiment of the present disclosure, in Formula 4 to Formula 27, at least one of B₁ to Bₙ is selected from CR_{B}, wherein Bₙ corresponds to one with the largest serial number among B₁ to B₆ in any one of Formula 4 to Formula 27; R_{B} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group, a hydroxyl group, a sulfanyl group and combinations thereof; and
adjacent substituents R_{B} can be optionally joined to form a ring.

In the present disclosure, B, corresponds to one with the largest serial number among B₁ to B₆ in any one of Formula 4 to Formula 27. For example, for Formula 4, one with the largest serial number among B₁ to B₆ in Formula 4 is B₄, that is, for Formula 4, Bₙ is B₄. For example, for Formula 10, one with the largest serial number among B₁ to B₆ in Formula 10 is B₅, that is, for Formula 10, Bₙ is B₅. For other general formulas, the situations are similar and not repeated here.

In the present disclosure, the expression that adjacent substituents R_{B} can be optionally joined to form a ring is intended to mean that any adjacent substituents R_{B} can be joined to form a ring. Obviously, it is possible that any adjacent substituents R_{B} are not joined to form a ring.

According to an embodiment of the present disclosure, in Formula 4 to Formula 27, B₂ and/or B₄ is selected from CR_{B}; and adjacent substituents R_{B} can be optionally joined to form a ring.

According to an embodiment of the present disclosure, in Formula 4 to Formula 27, B₂ and/or B₄ are selected from CR_{B}; R_{B} is, at each occurrence identically or differently, selected from the group consisting of: hydrogen, deuterium, fluorine, cyano, hydroxyl, sulfanyl, amino, methoxy, phenoxy, methylthio, phenylthio, dimethylamino, diphenylamino, phenylmethylamino, vinyl, tetrahydrofuryl, tetrahydropyranyl, tetrahydrothienyl, piperidinyl, morpholinyl, benzyl, methyl, ethyl, isopropyl, isobutyl, tert-butyl, neopentyl, cyclopentyl, cyclopentylmethyl, cyclohexyl, trimethylsilyl, triethylsilyl, trimethylgermanyl, triethylgermanyl, phenyl, pyridyl, triazinyl, deuterated methyl, deuterated ethyl, deuterated isopropyl, deuterated isobutyl, deuterated tert-butyl, deuterated cyclopentyl, deuterated cyclopentylmethyl, deuterated cyclohexyl, deuterated neopentyl and combinations thereof; and
adjacent substituents R_{B} can be optionally joined to form a ring.

According to an embodiment of the present disclosure, in Formula 4 to Formula 27, at least one of A₁ to Aₘ and/or B₁ to Bₙ is selected from N, wherein Aₘ corresponds to one with the largest serial number among A₁ to A₈ in any one of Formula 4 to Formula 27, and Bₙ corresponds to one with the largest serial number among B₁ to B₆ in any one of Formula 4 to Formula 27.

According to an embodiment of the present disclosure, in Formula 4 to Formula 7, Formula 13 to Formula 15 and Formula 21 to Formula 27, A₂ is N; in Formula 17 to Formula 19, A₅ is N.

According to an embodiment of the present disclosure, Lₐ is, at each occurrence identically or differently, selected from the group consisting of Lₐ₁ to Lₐ₅₉₅:

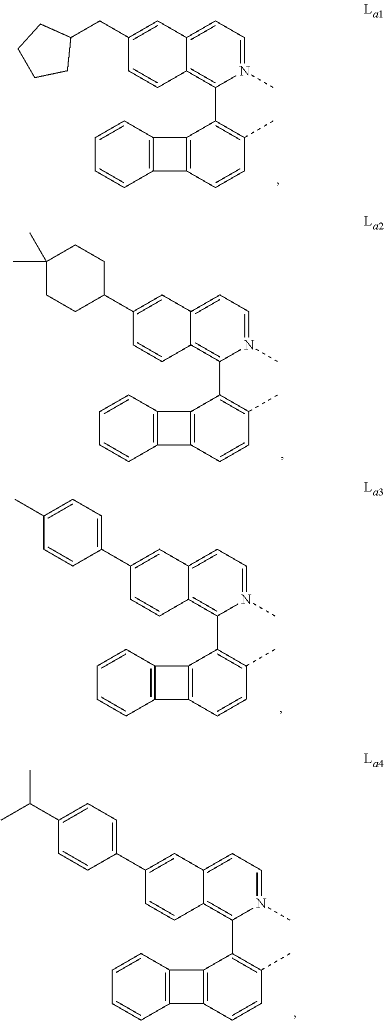

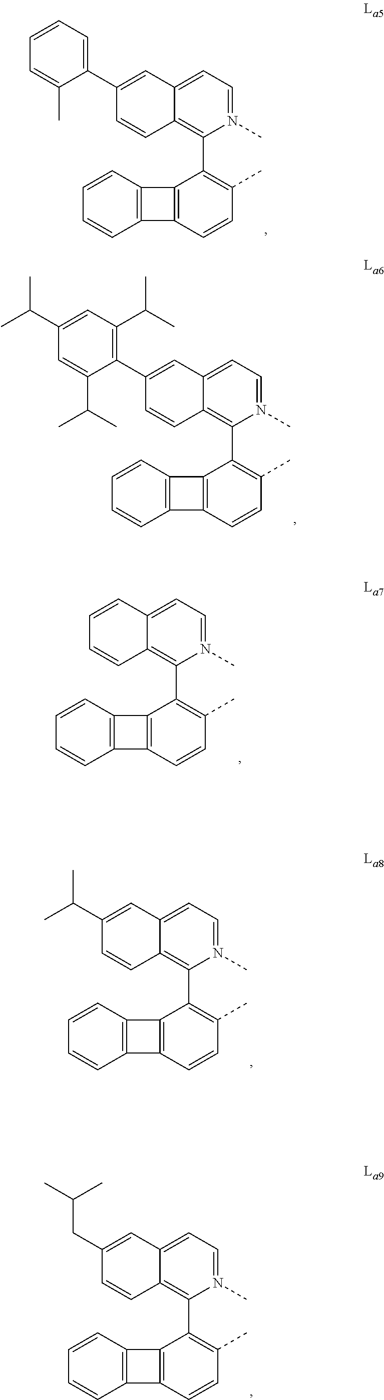

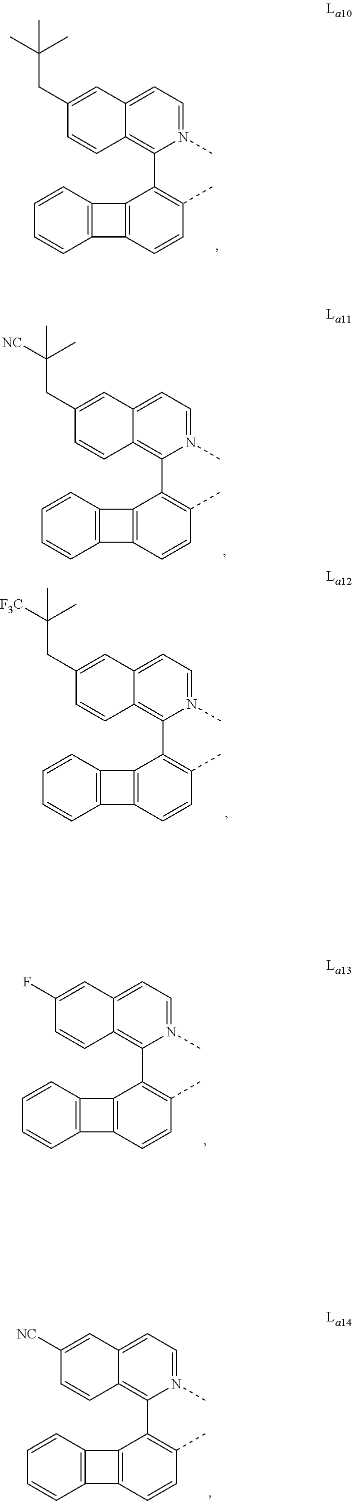

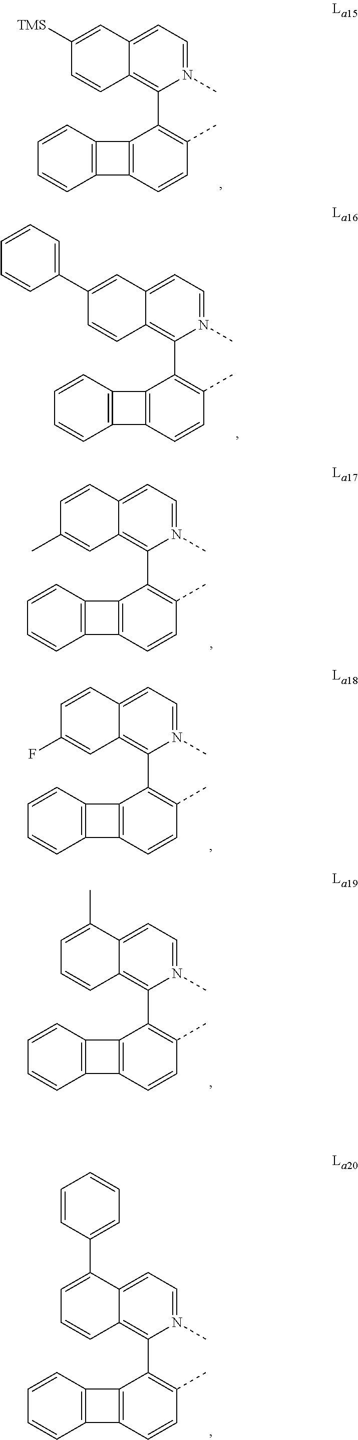

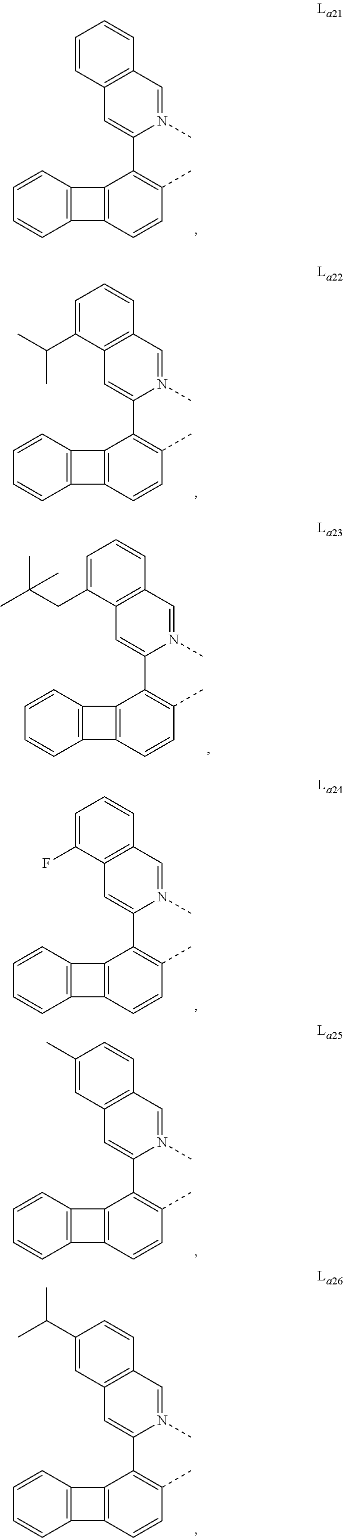

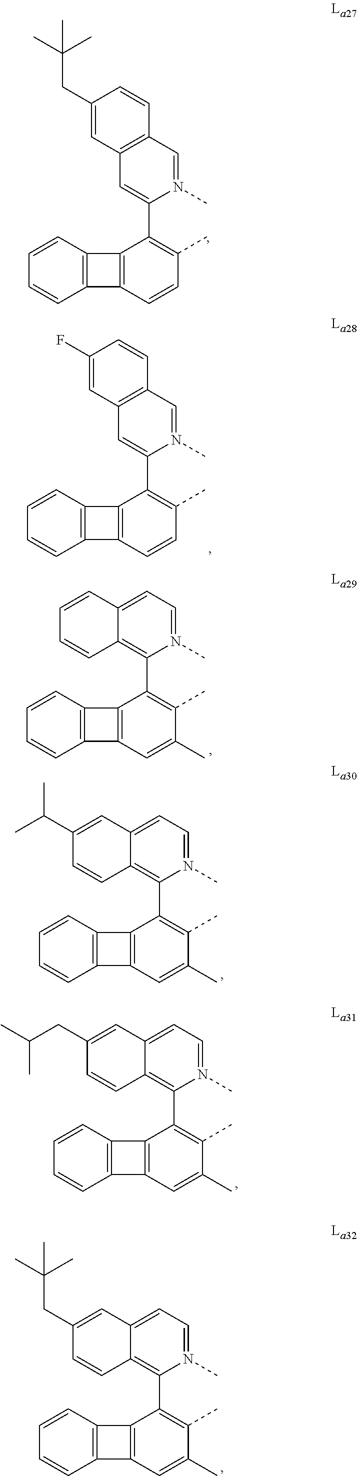

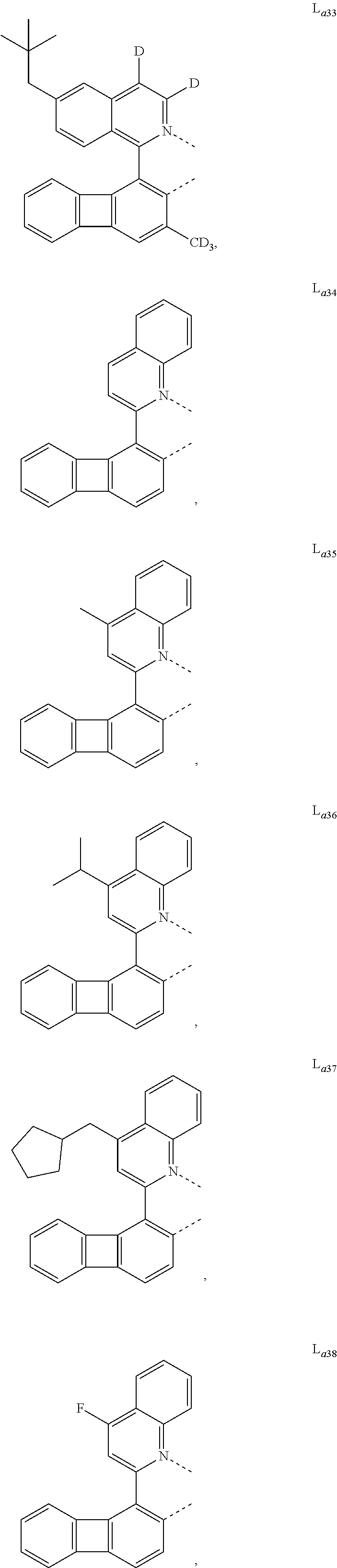

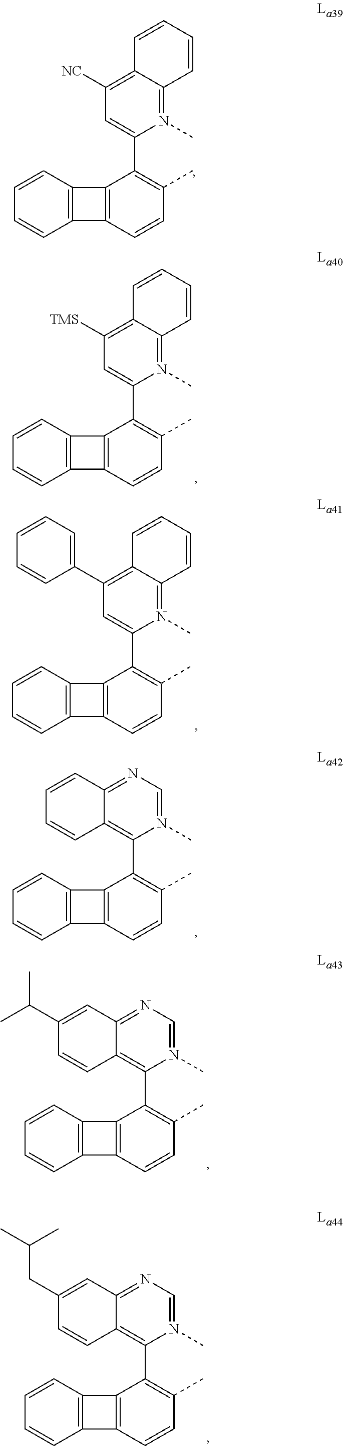

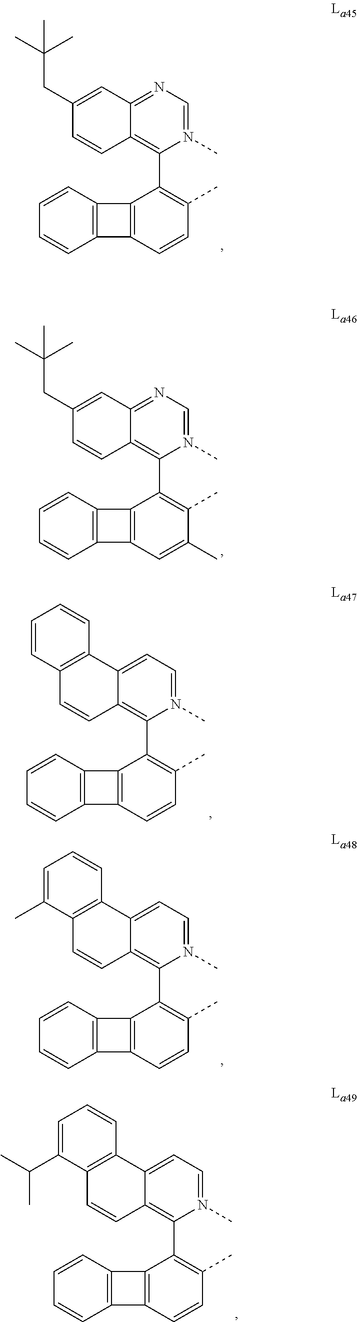

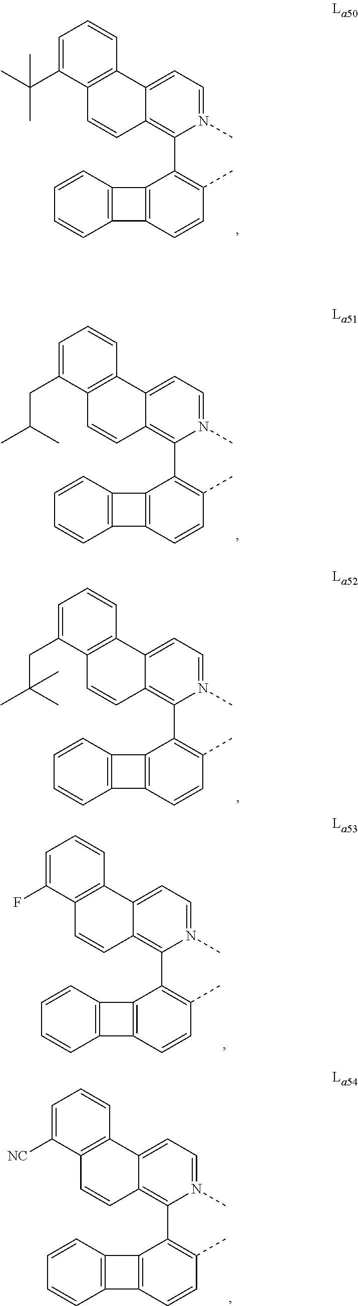

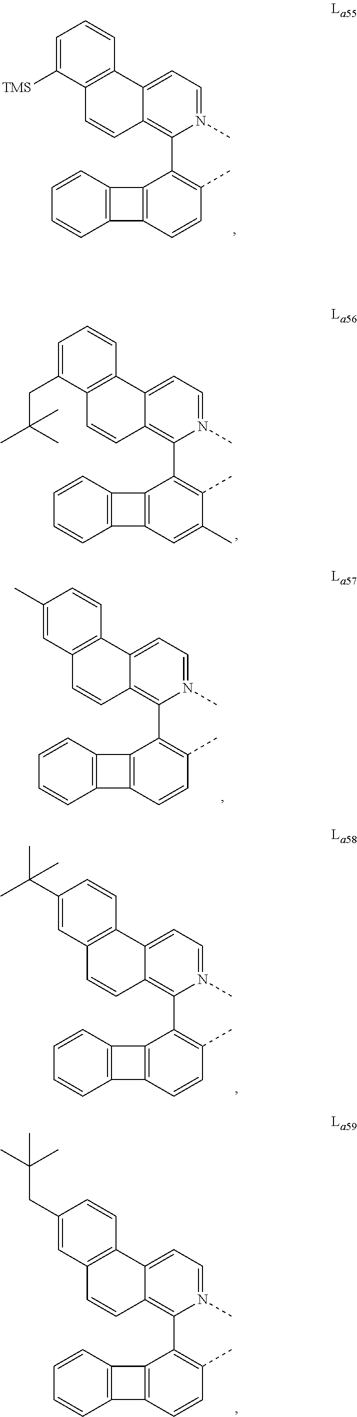

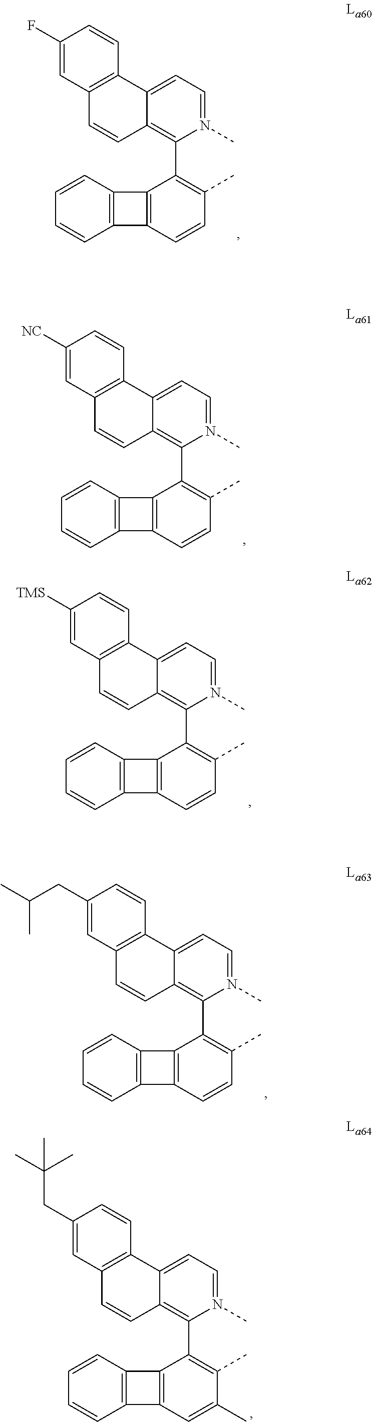

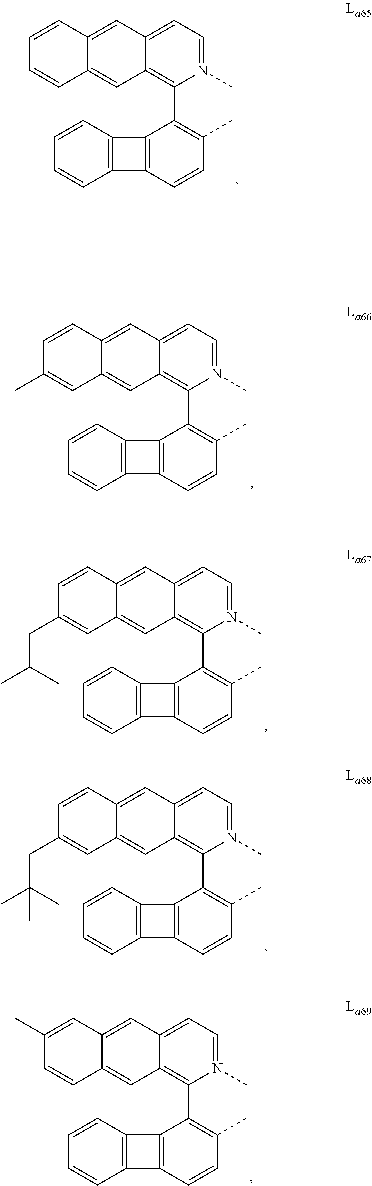

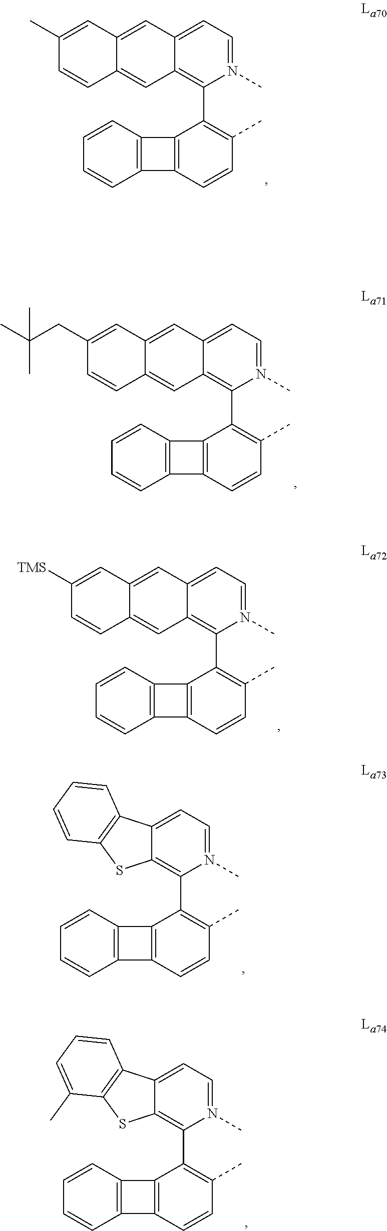

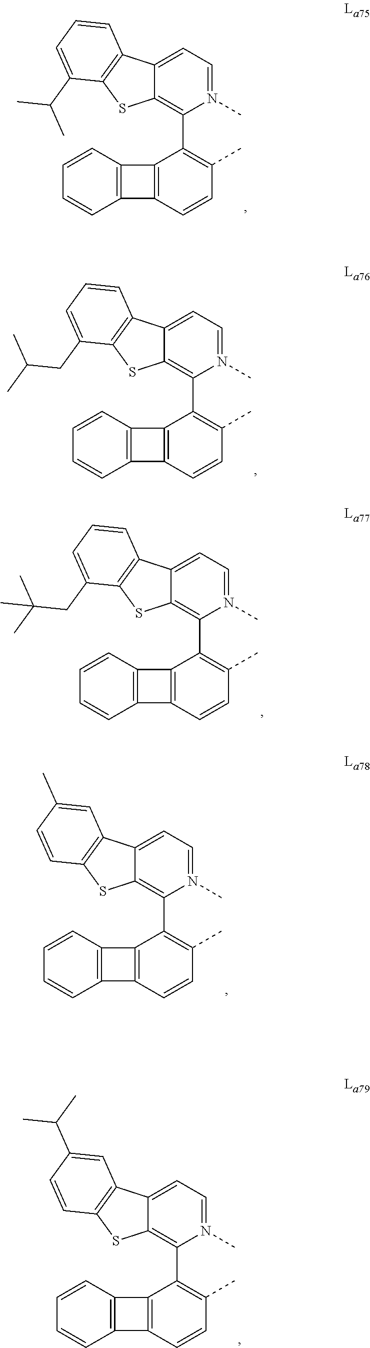

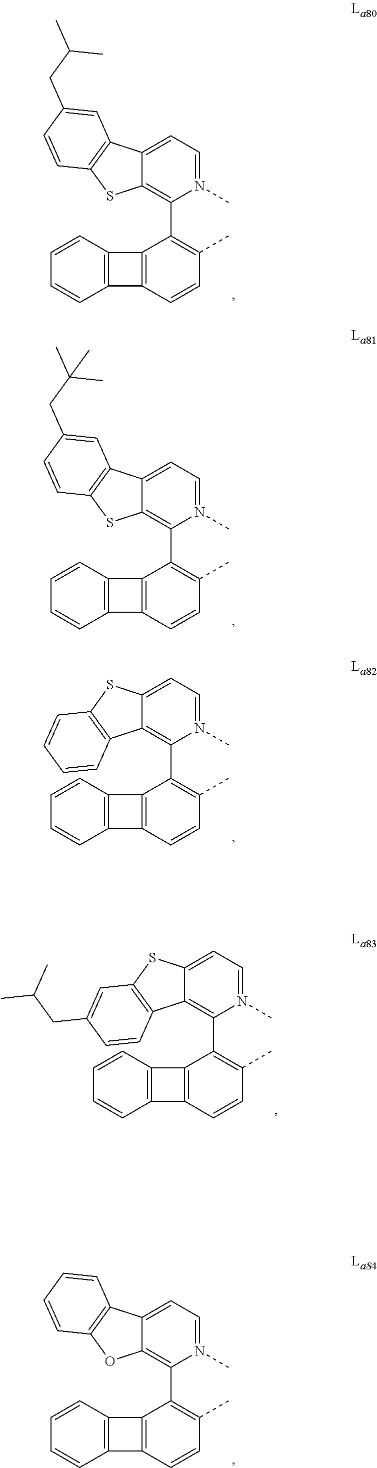

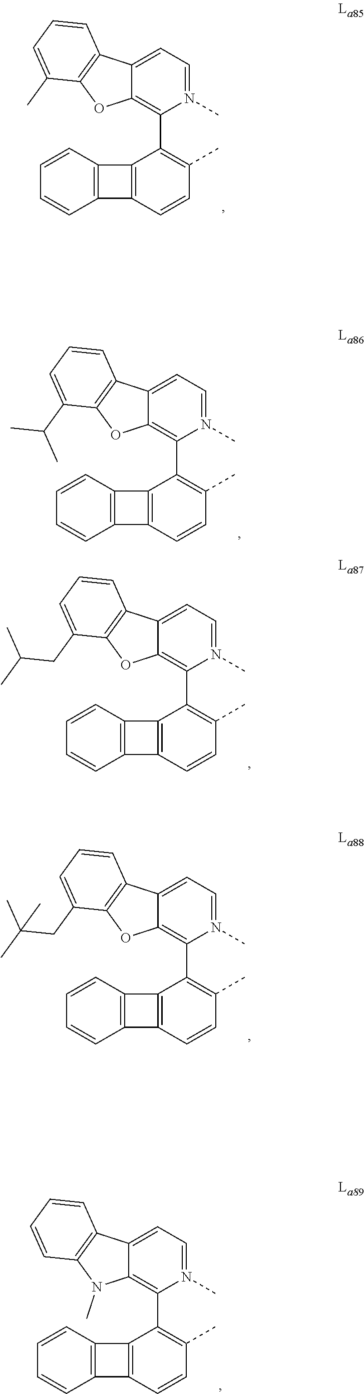

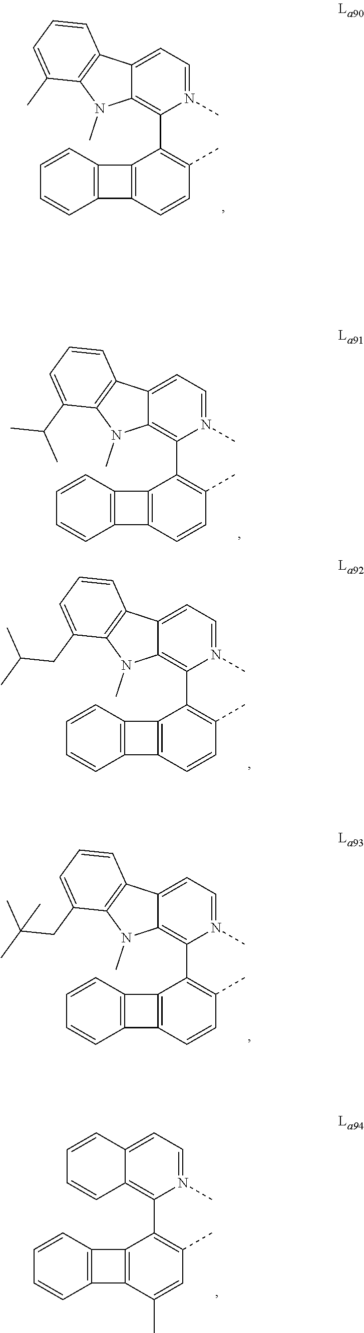

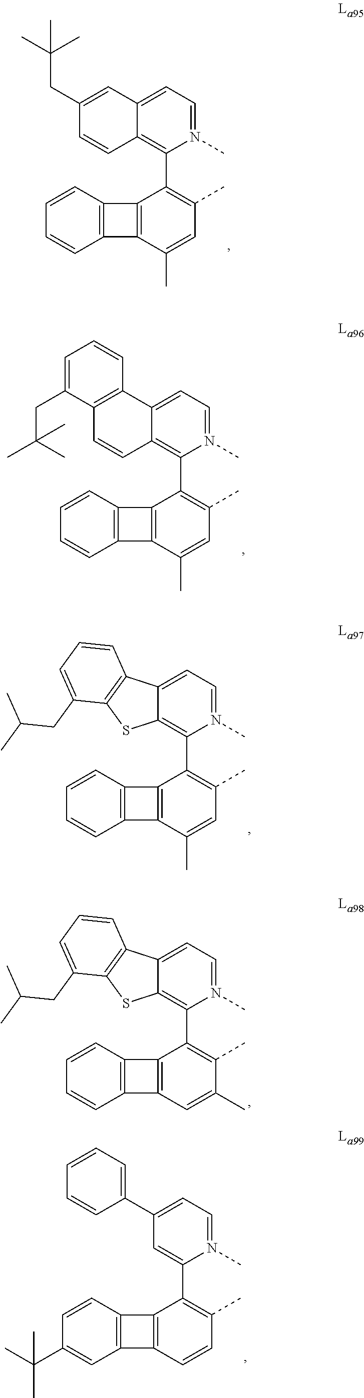

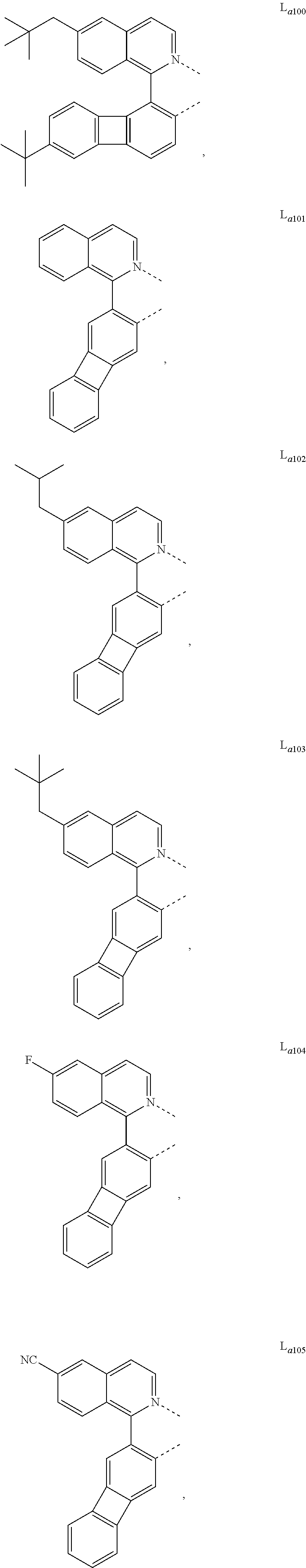

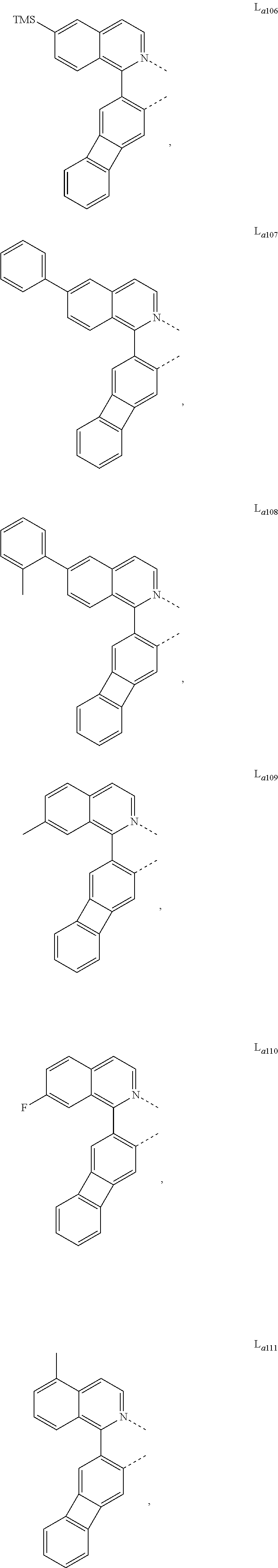

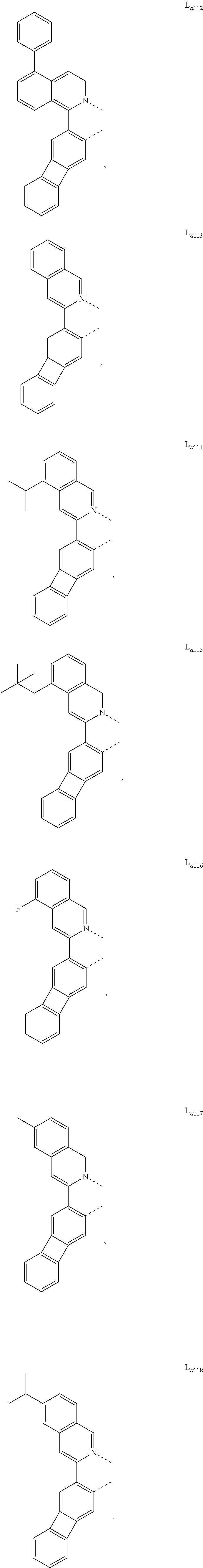

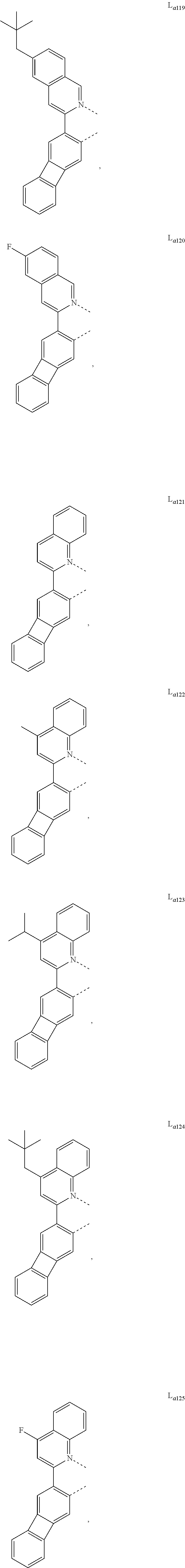

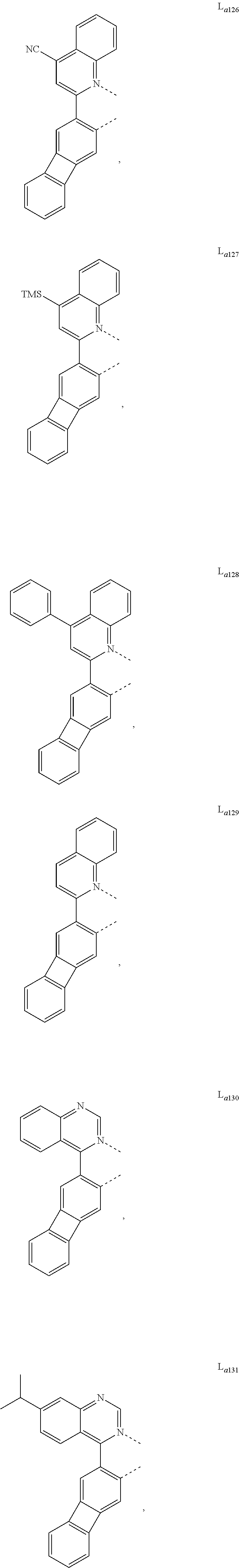

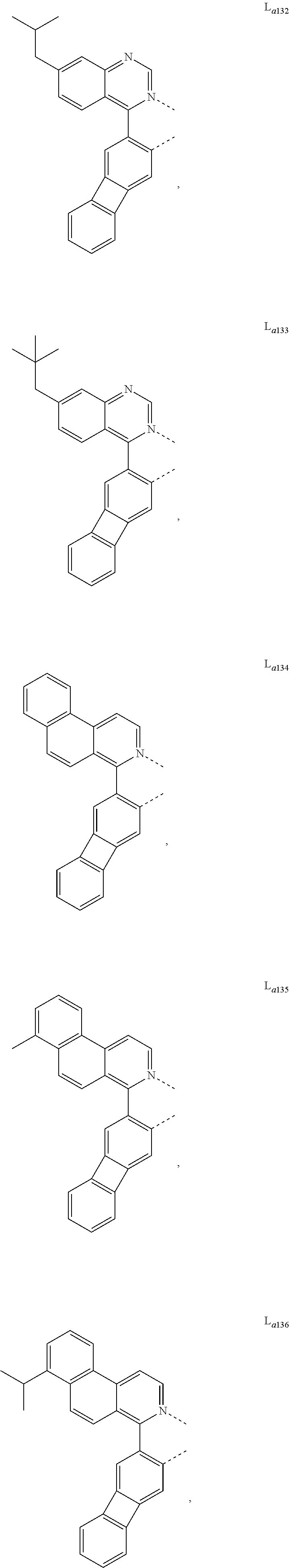

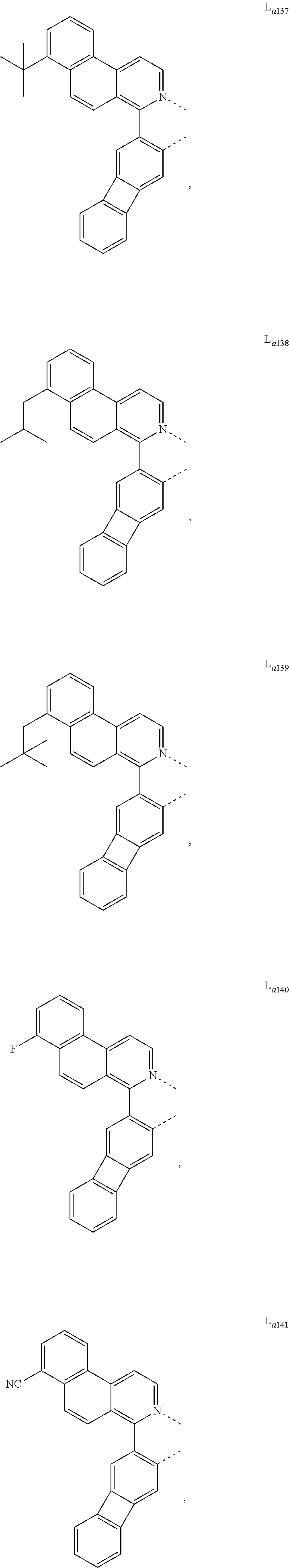

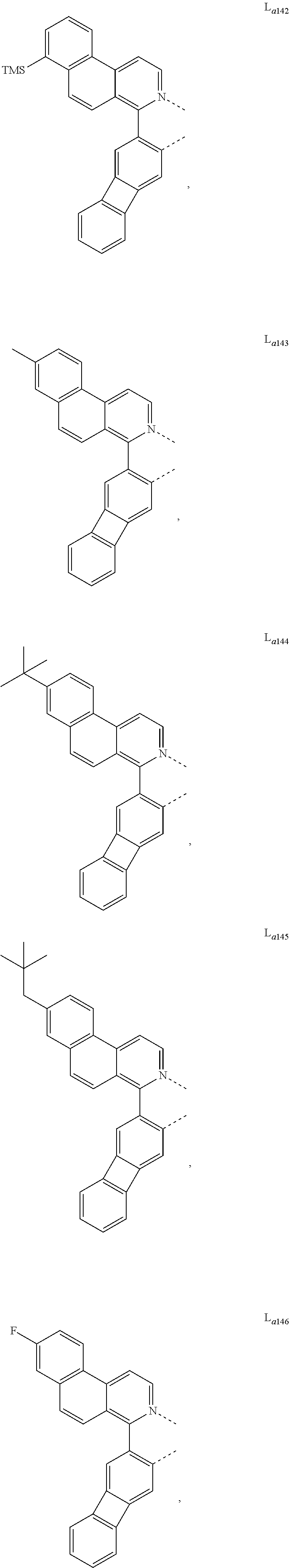

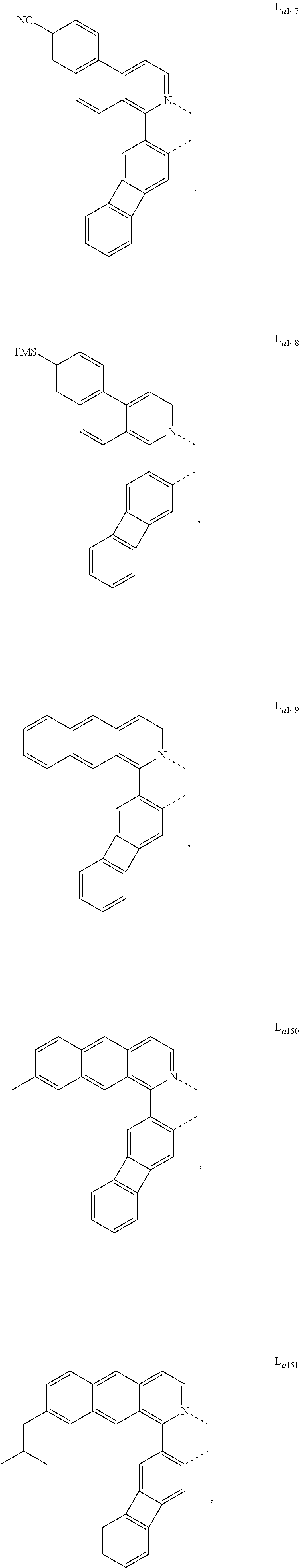

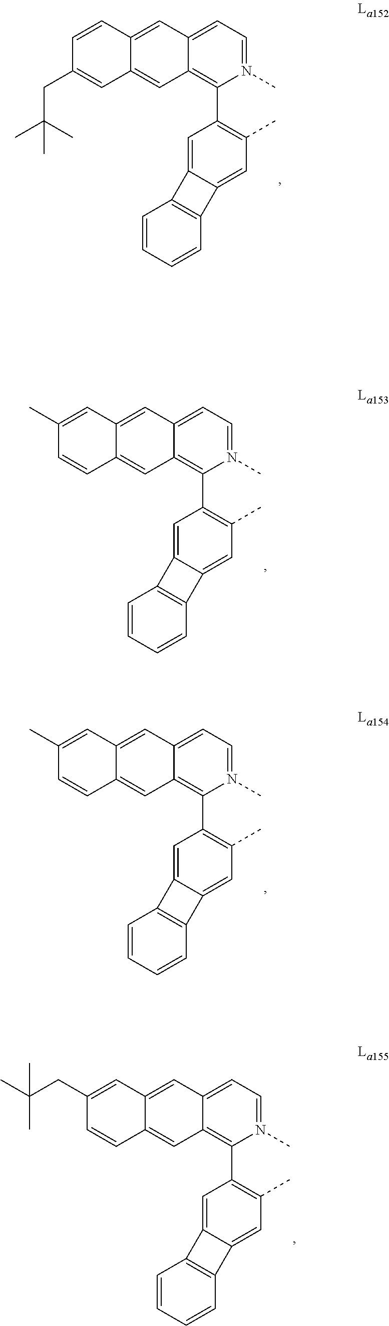

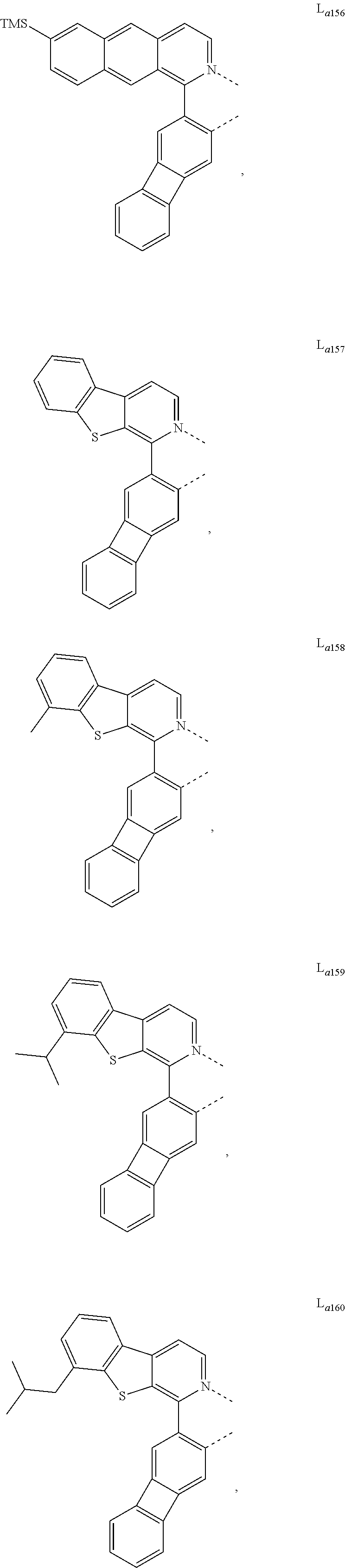

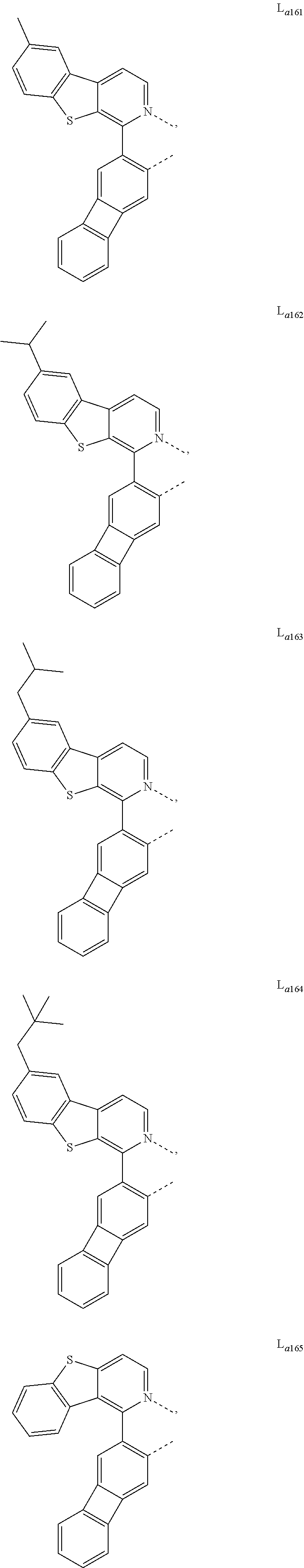

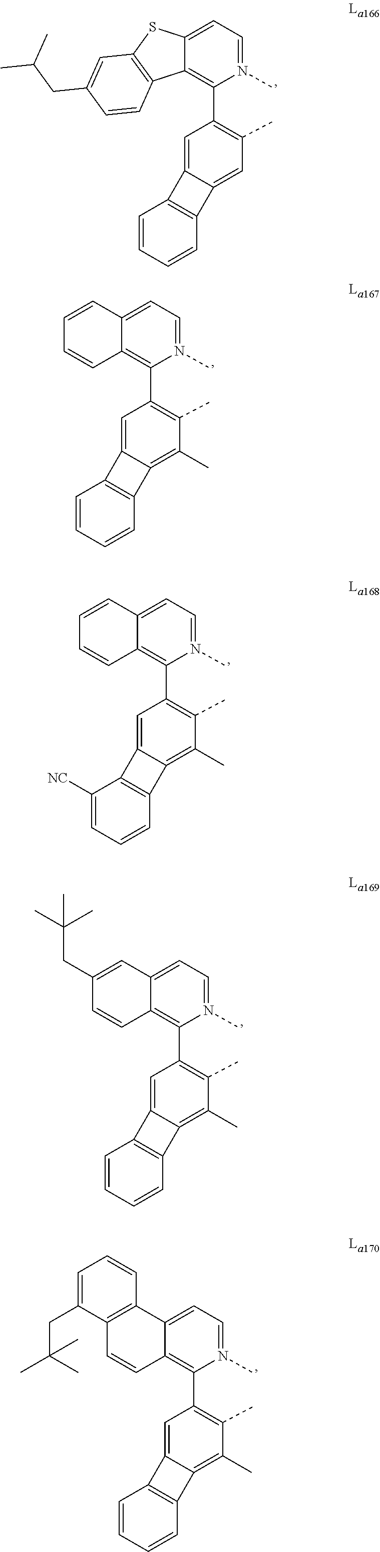

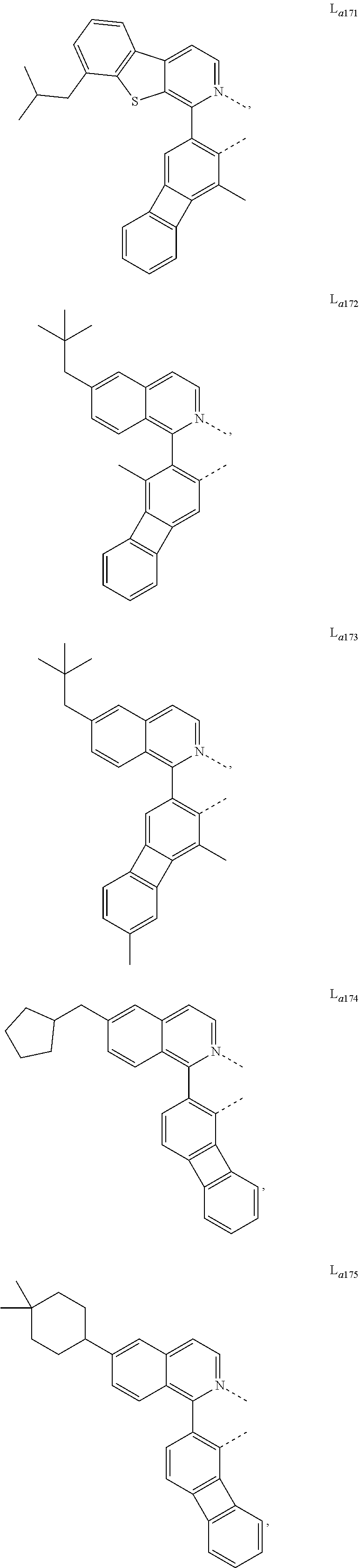

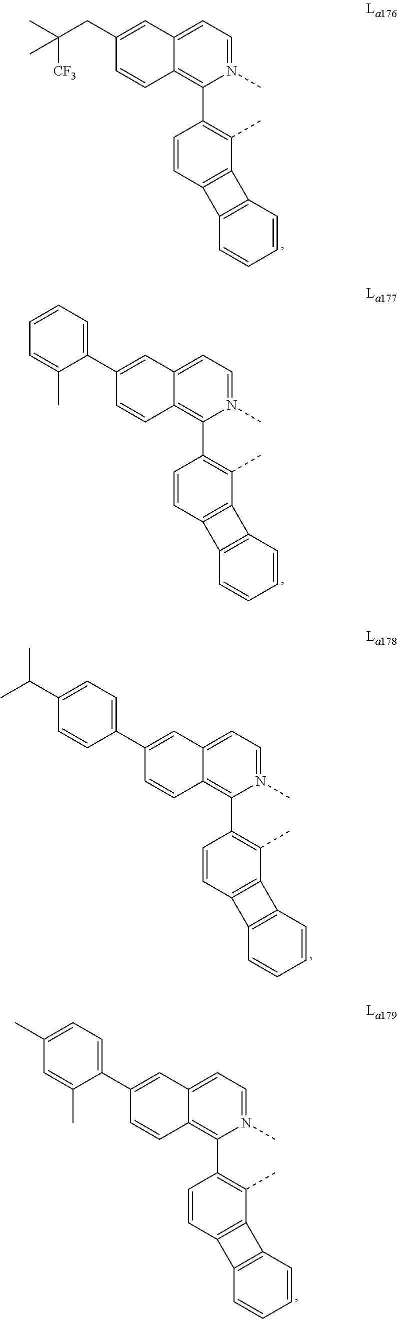

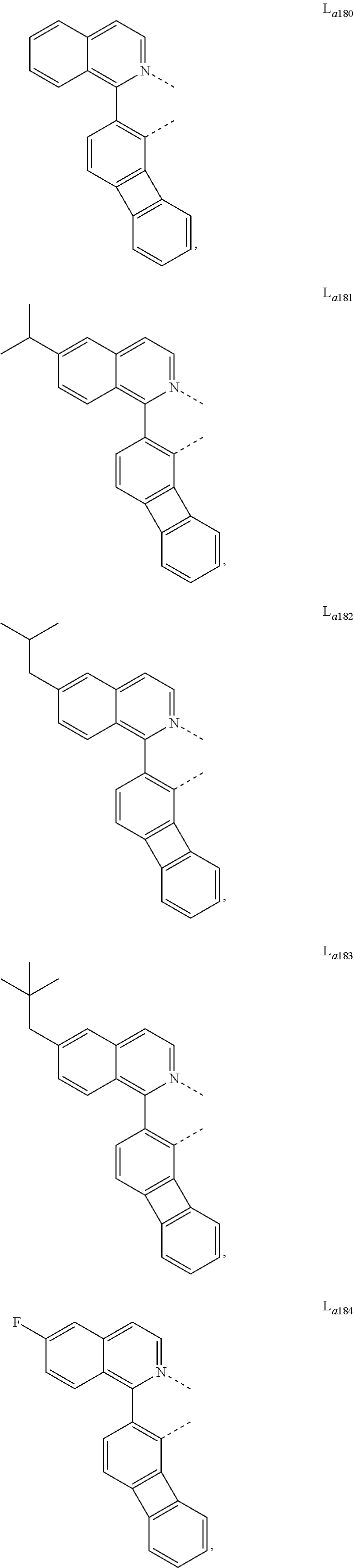

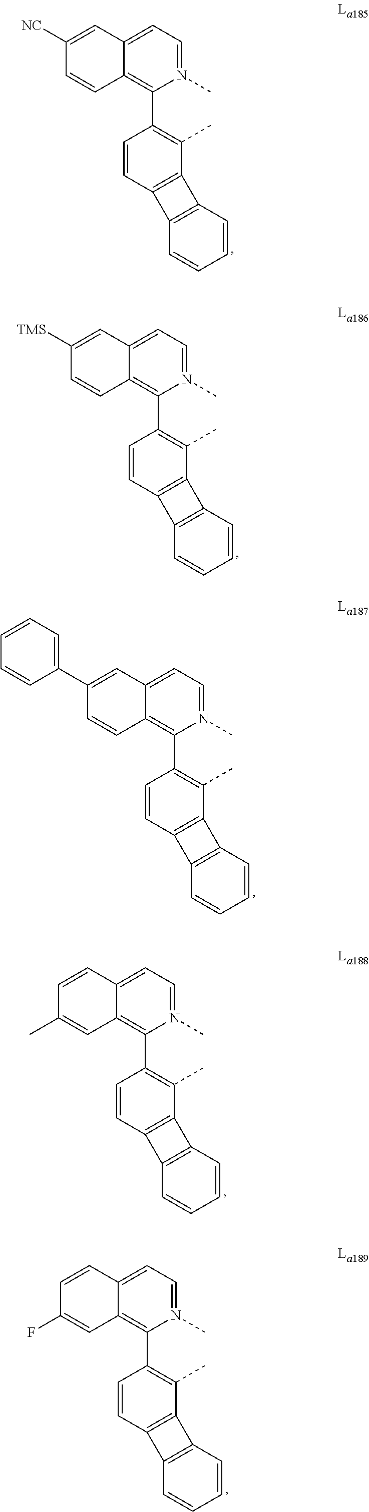

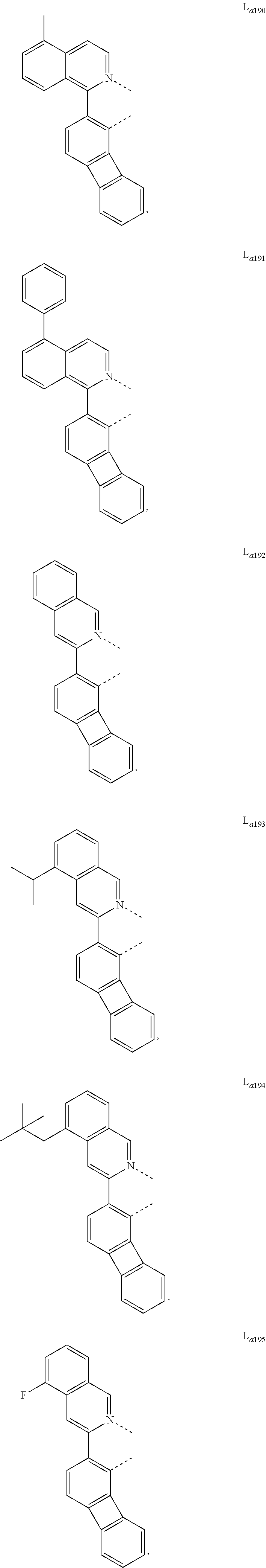

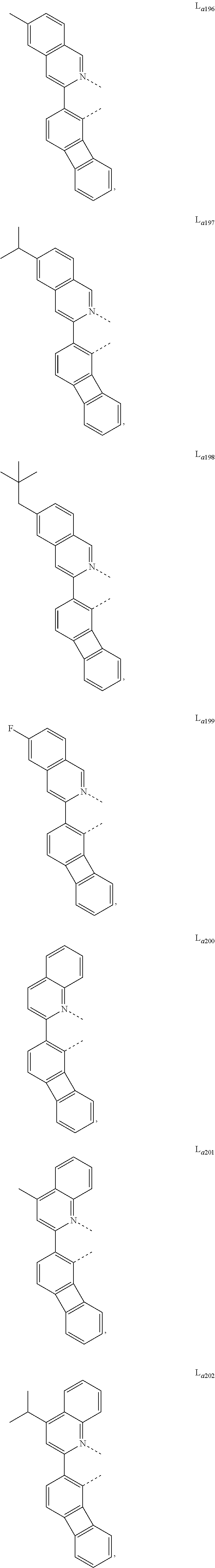

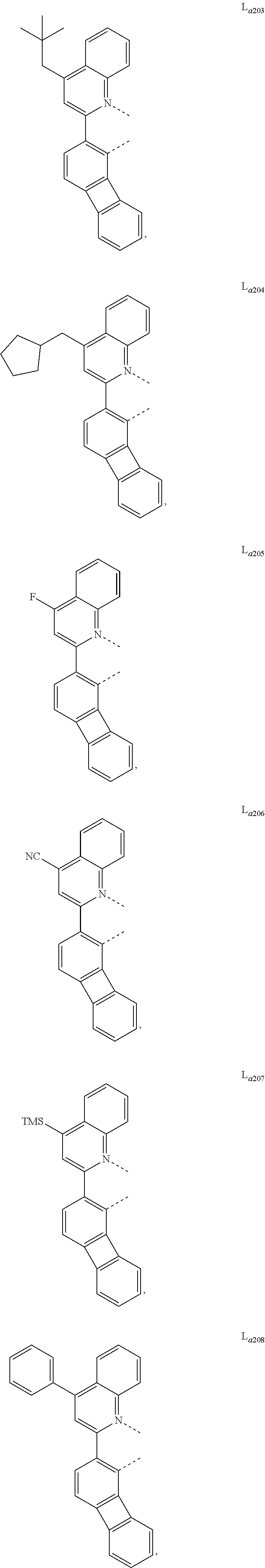

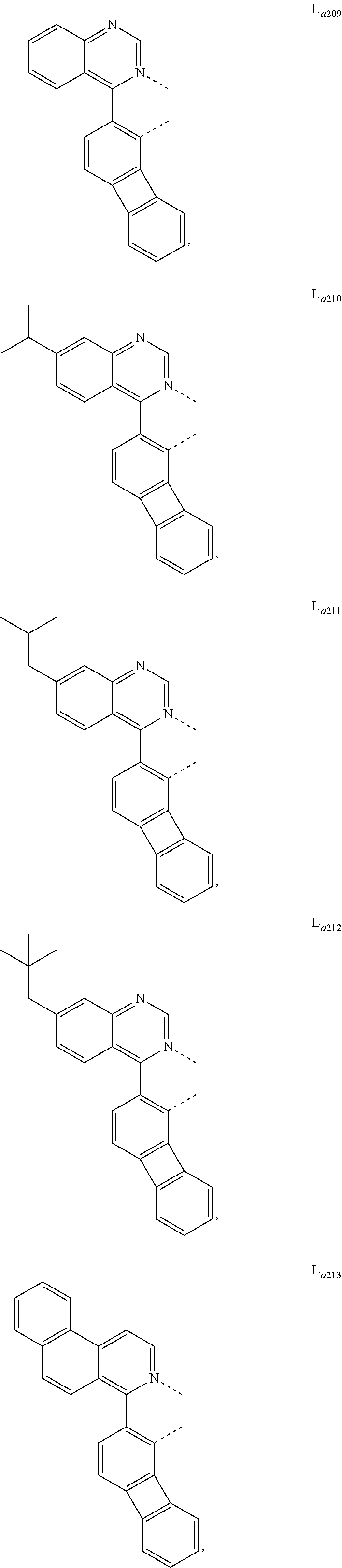

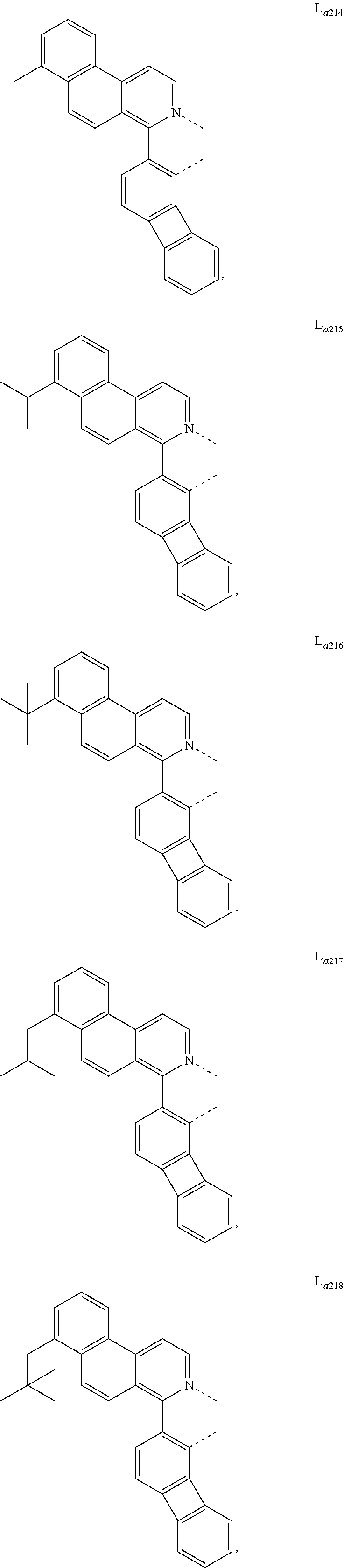

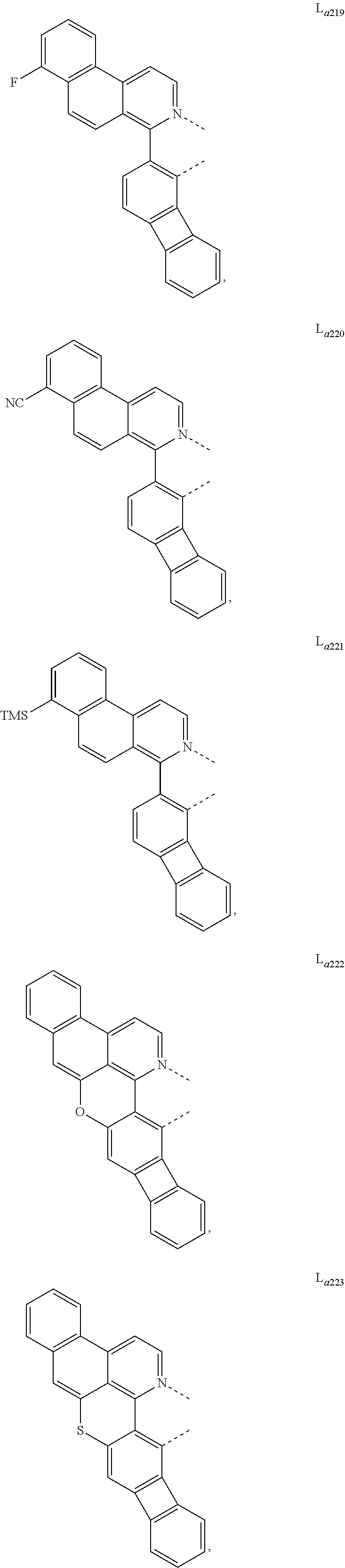

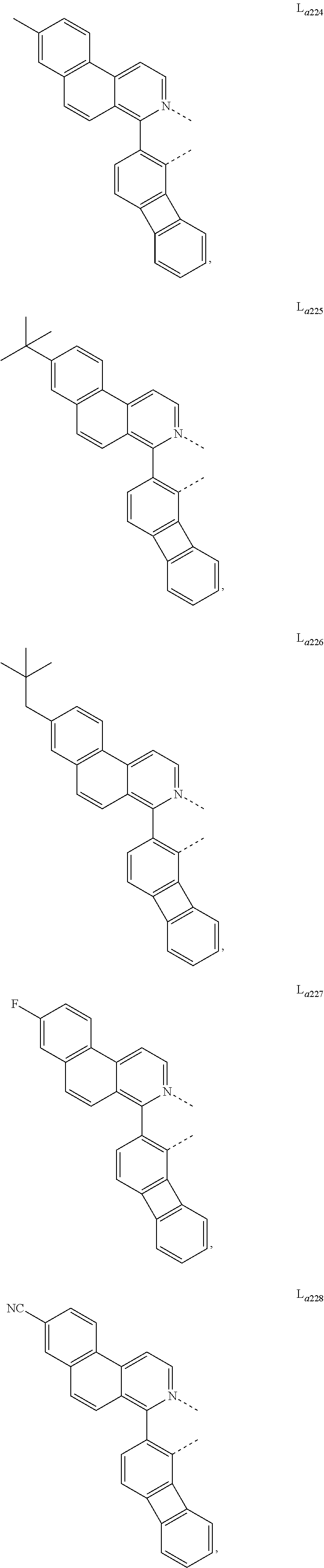

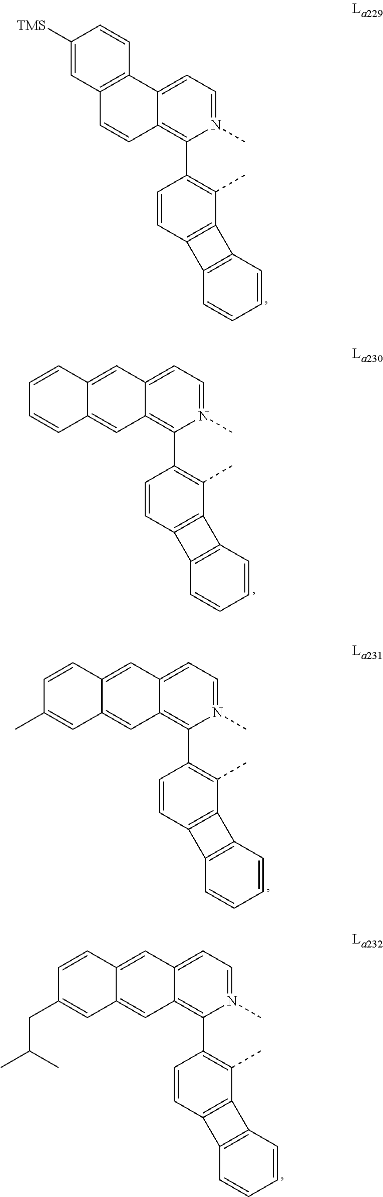

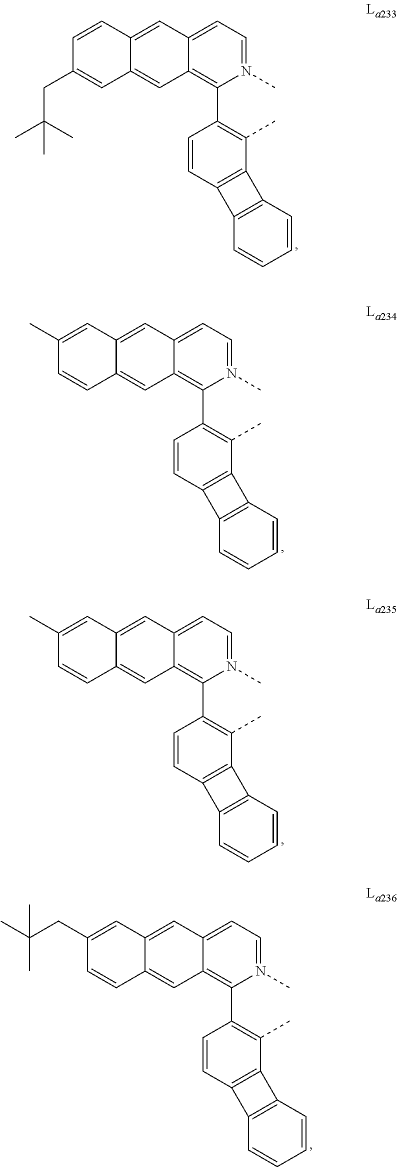

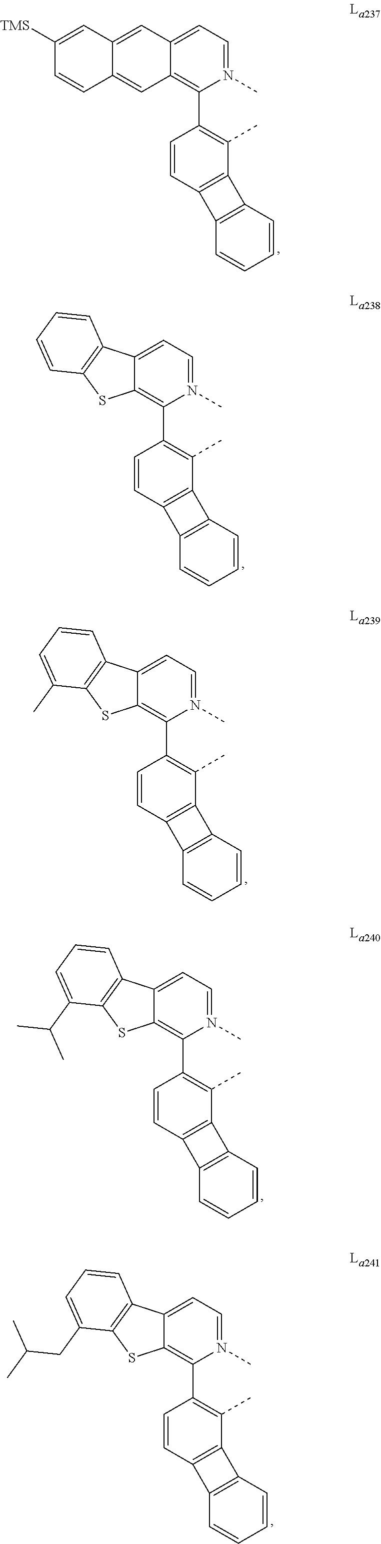

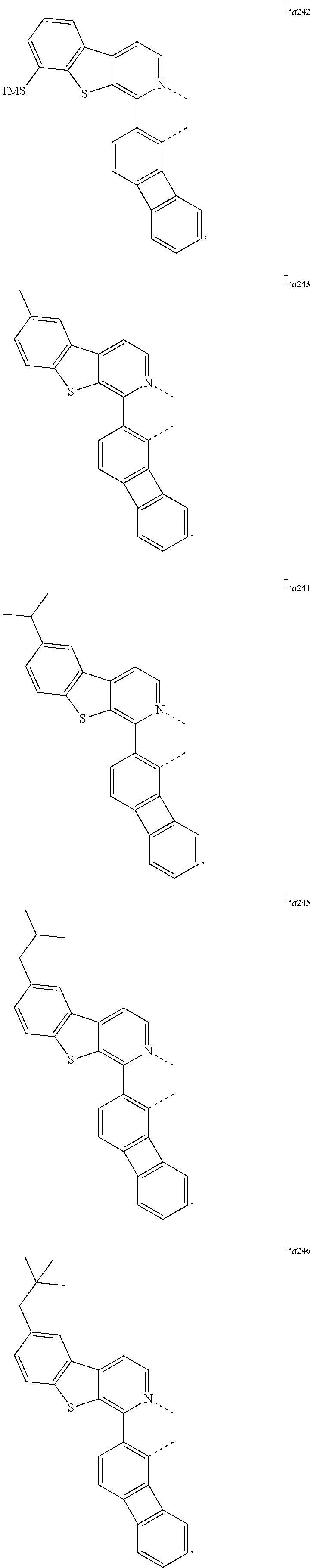

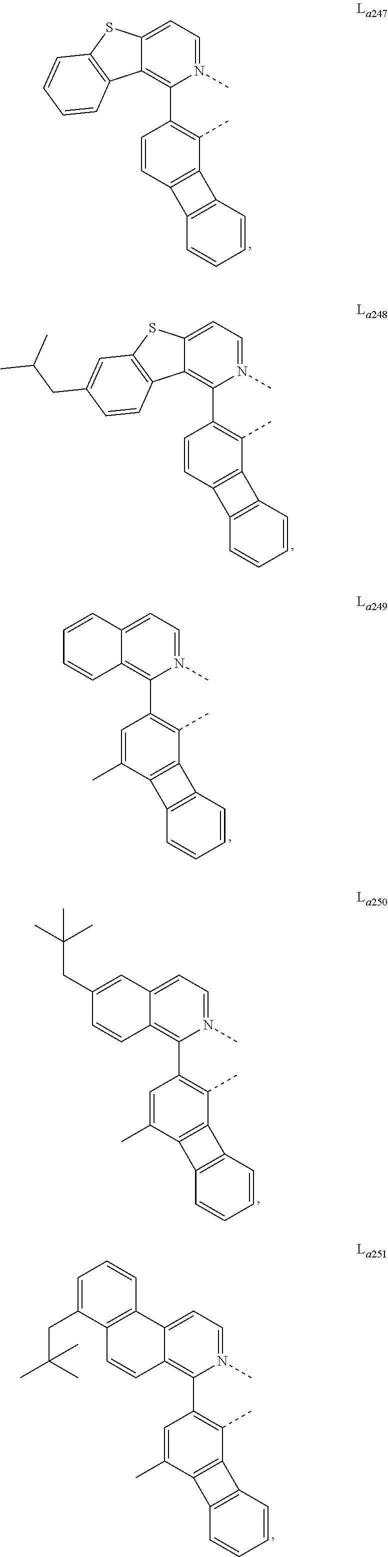

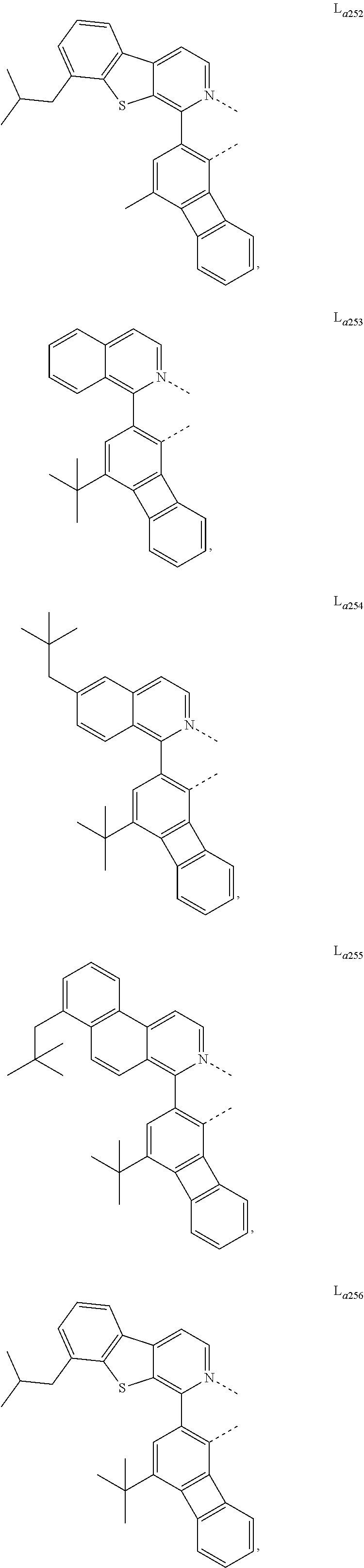

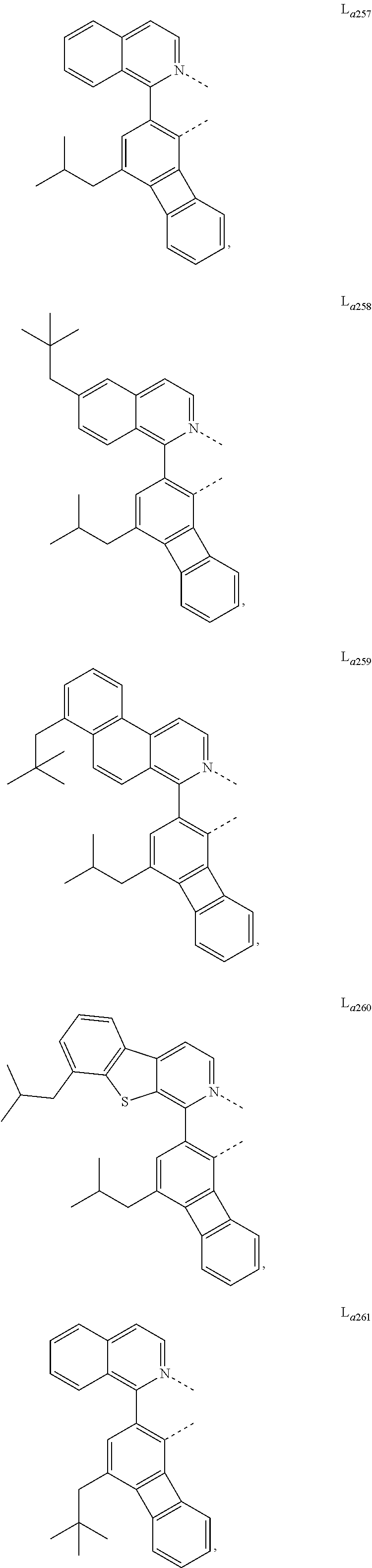

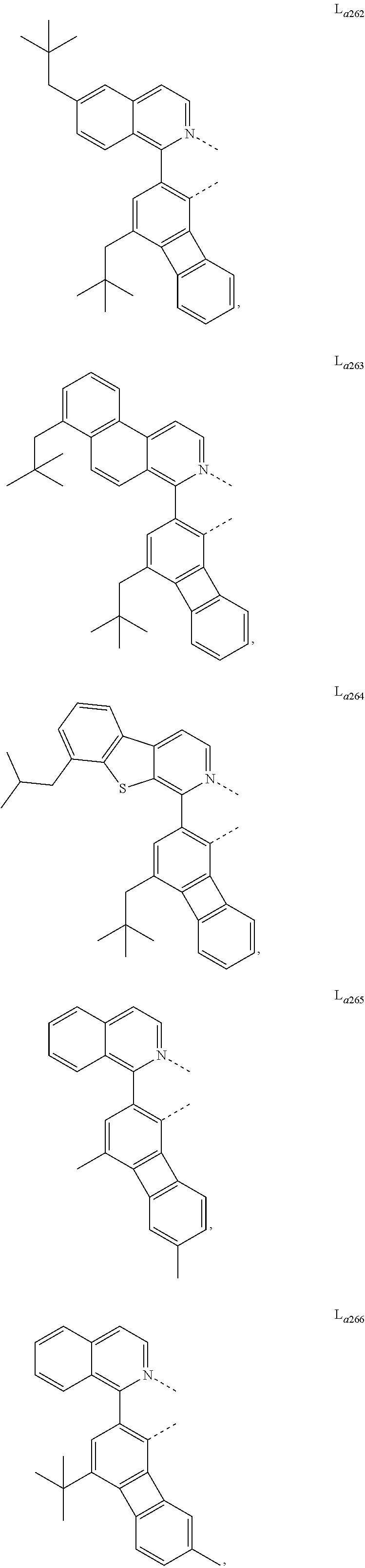

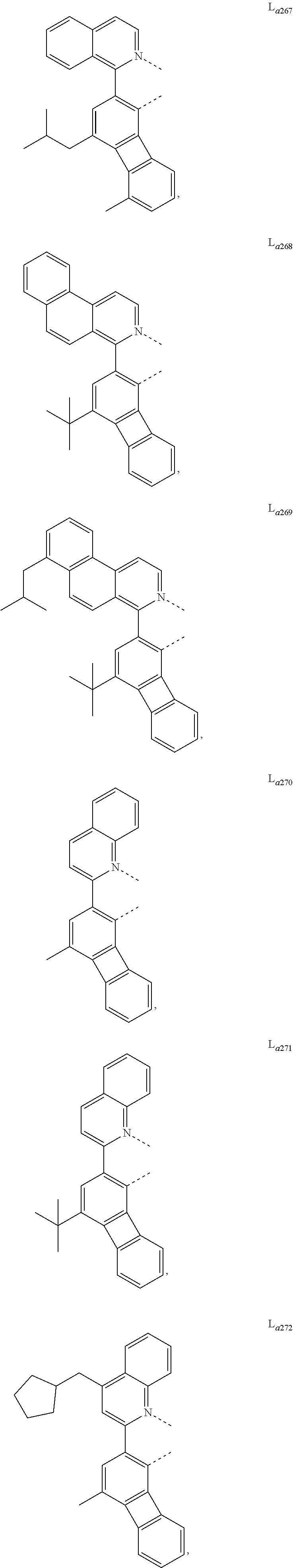

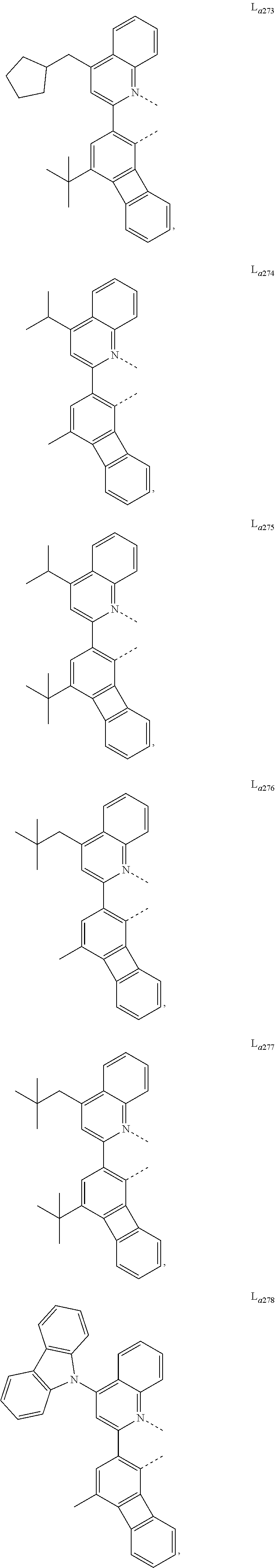

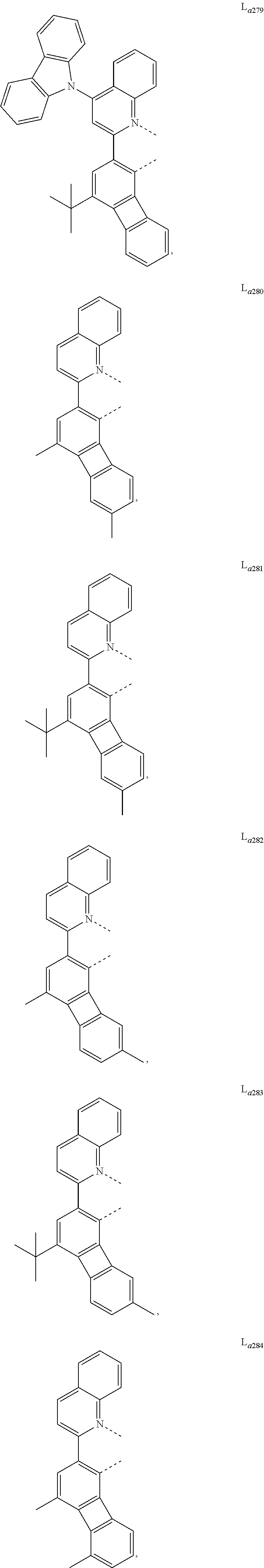

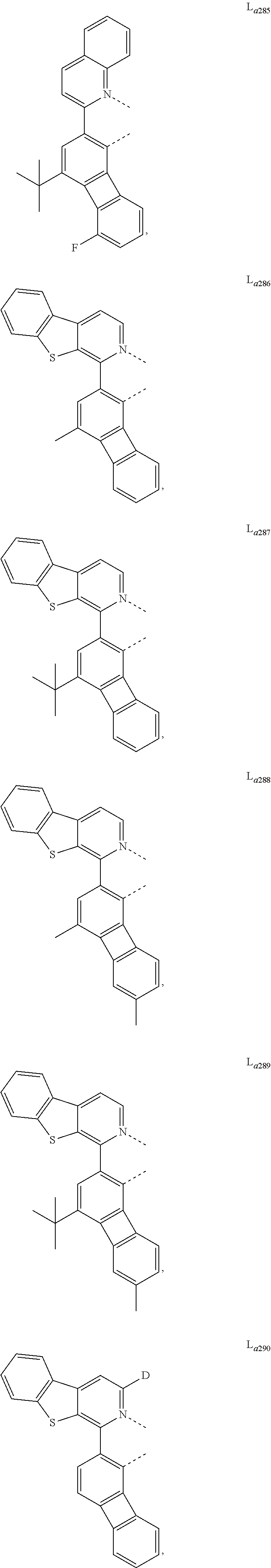

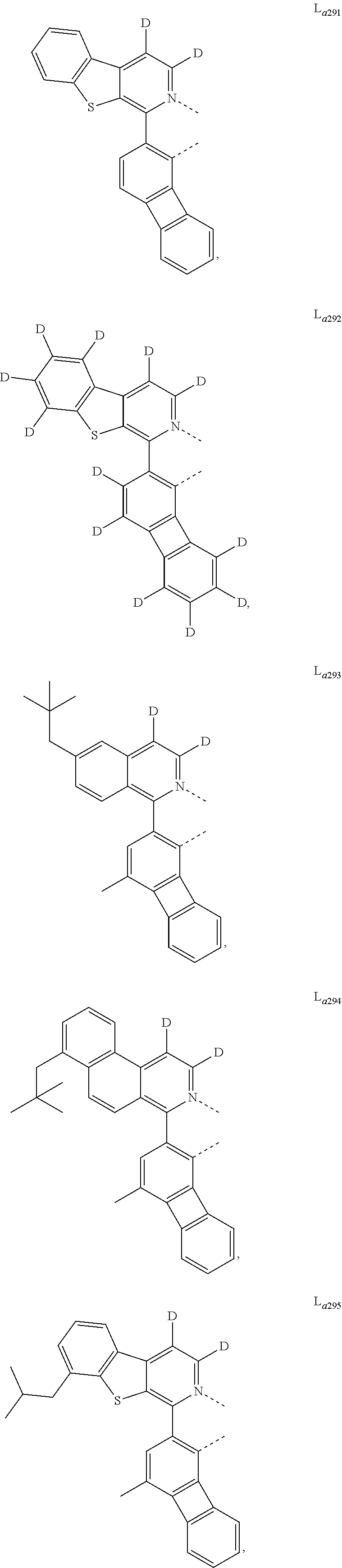

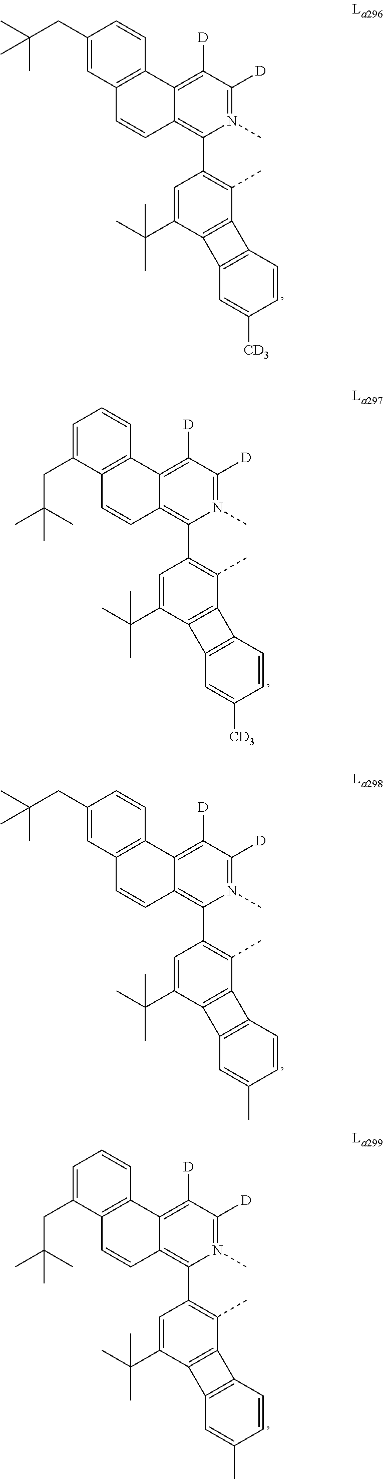

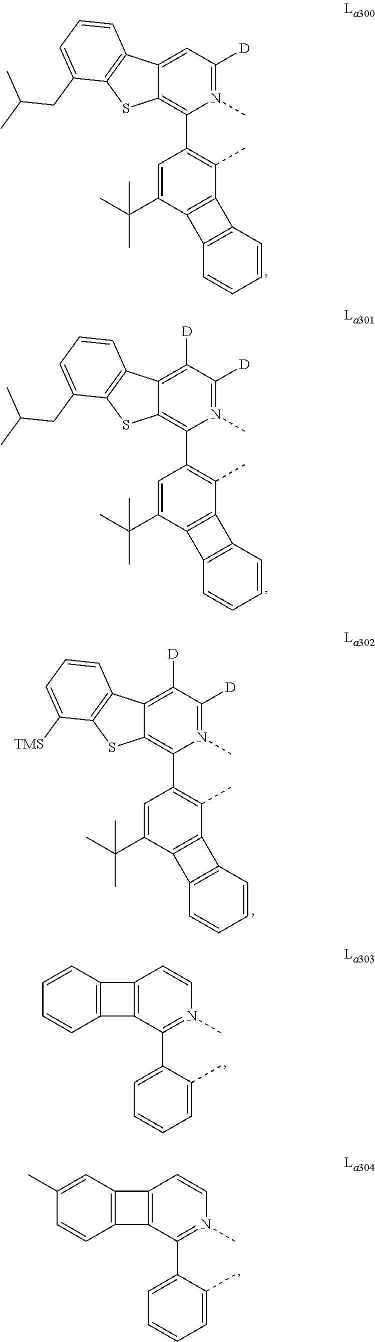

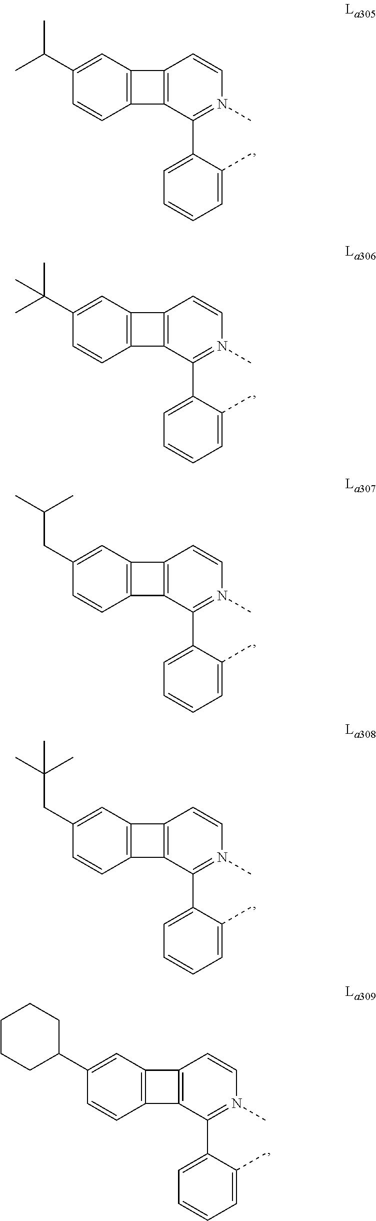

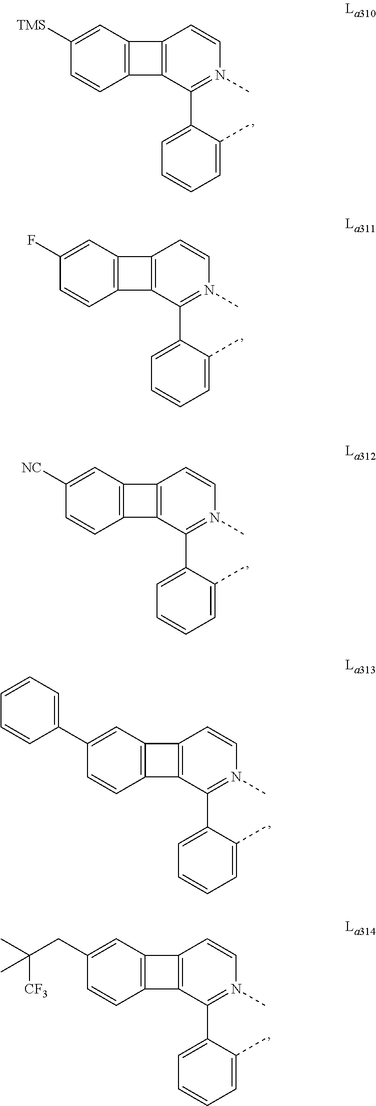

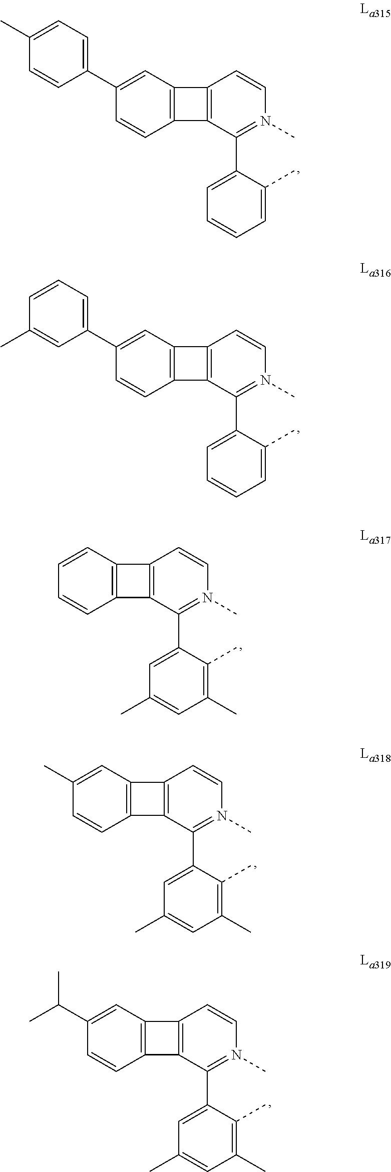

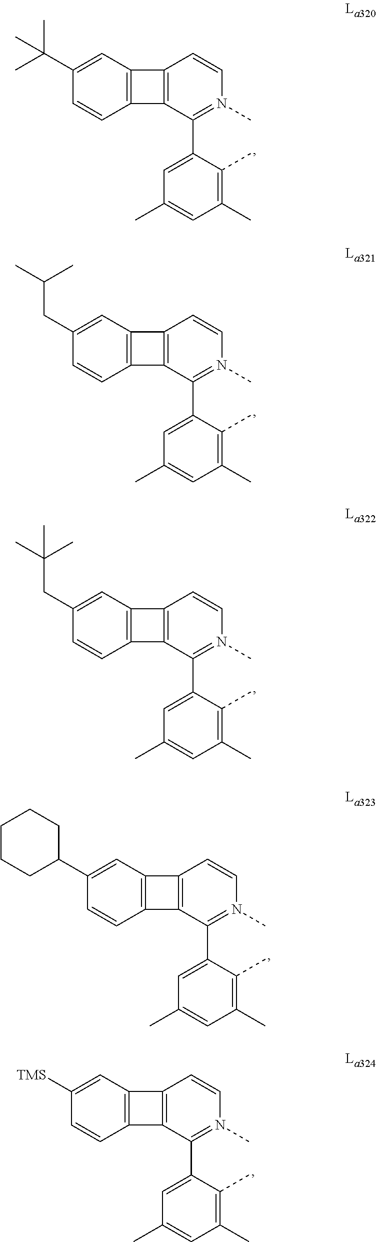

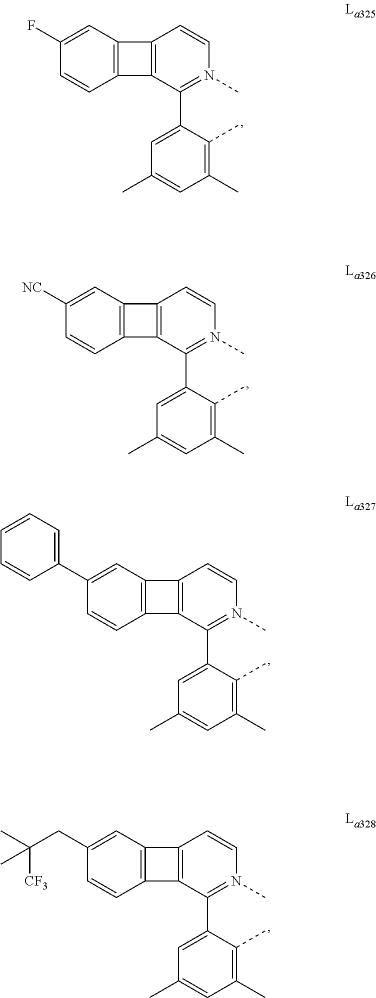

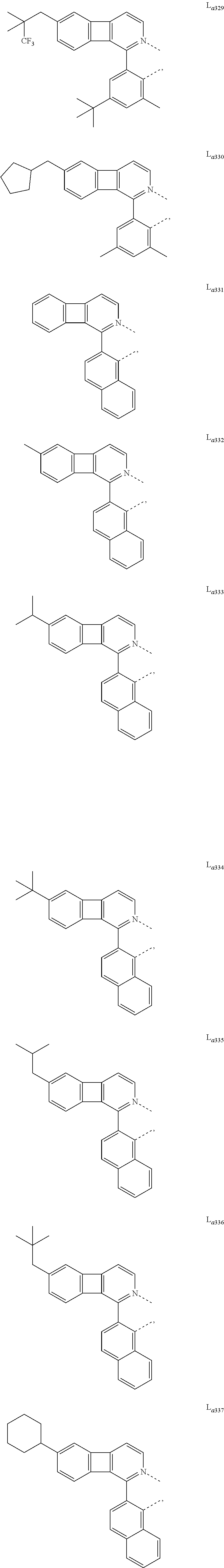

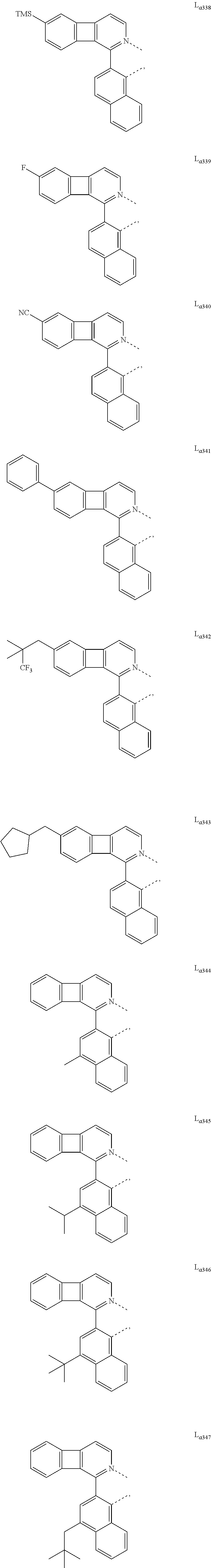

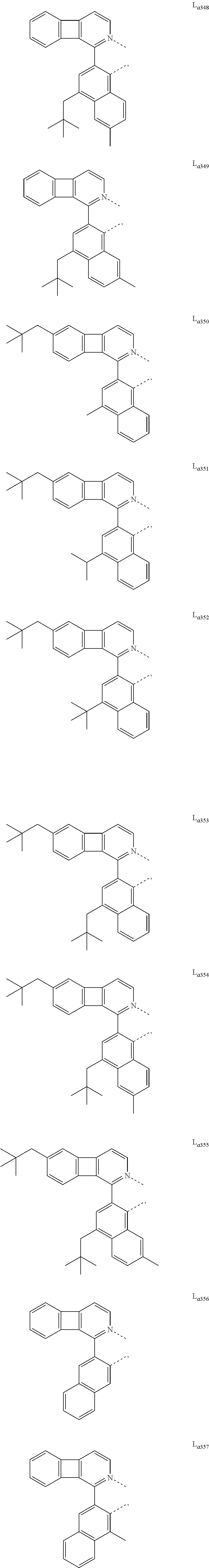

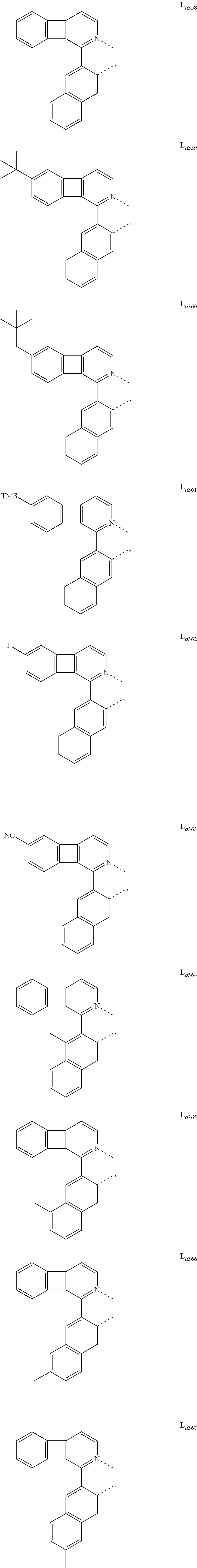

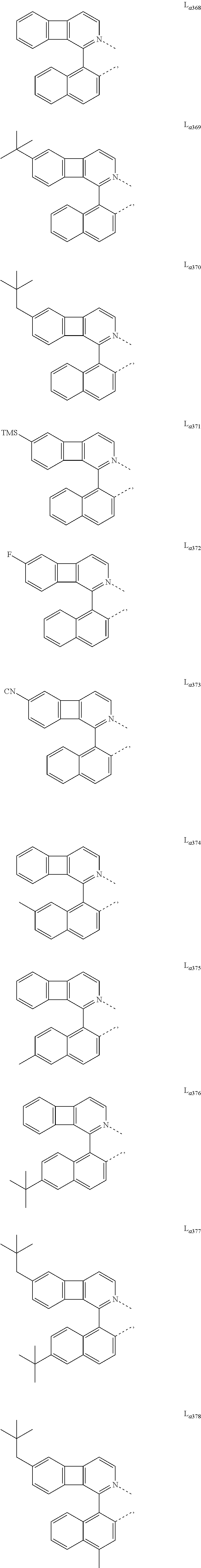

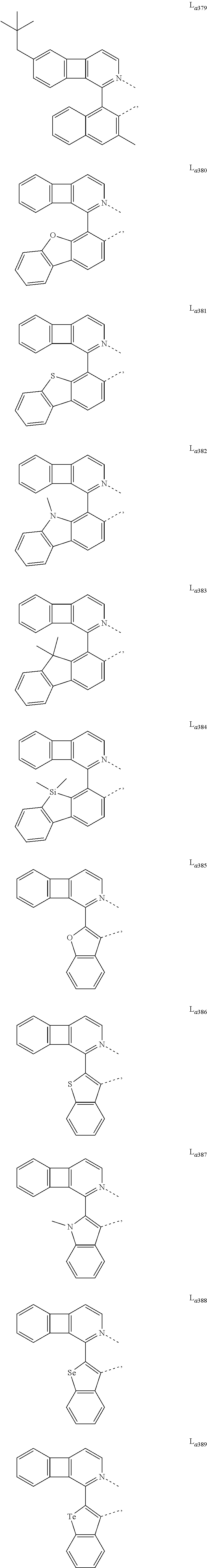

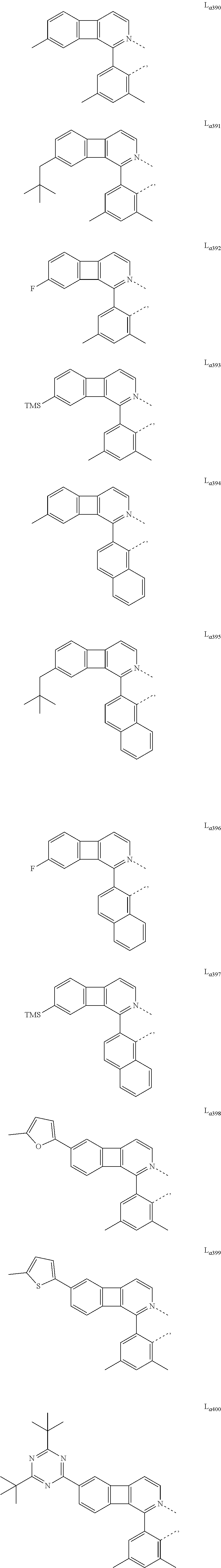

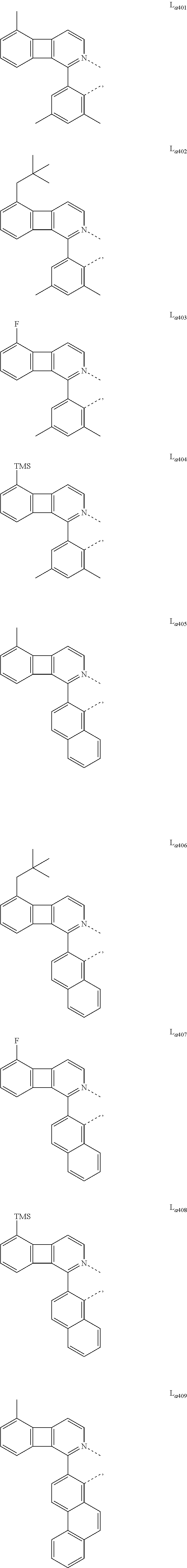

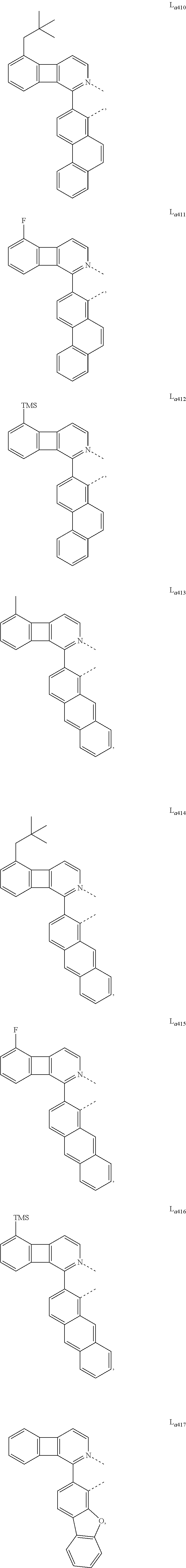

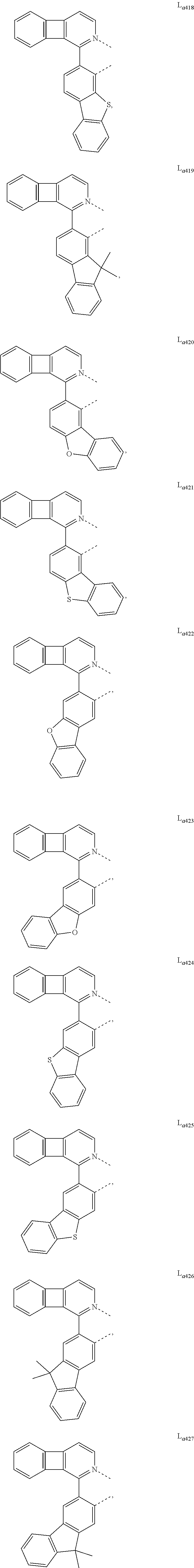

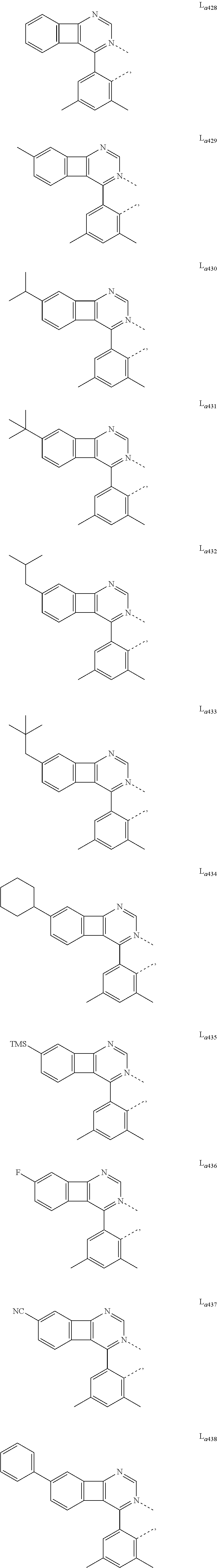

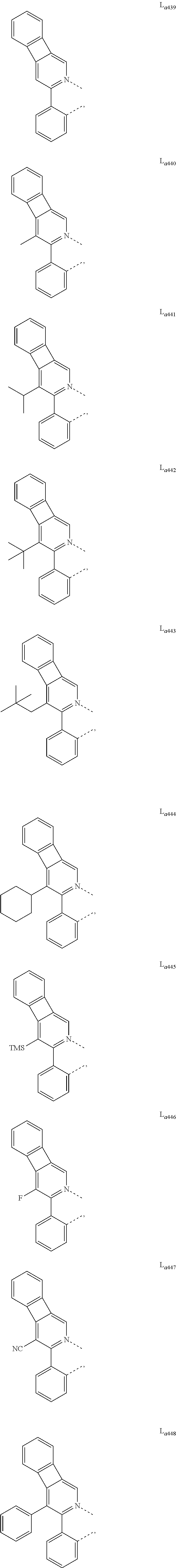

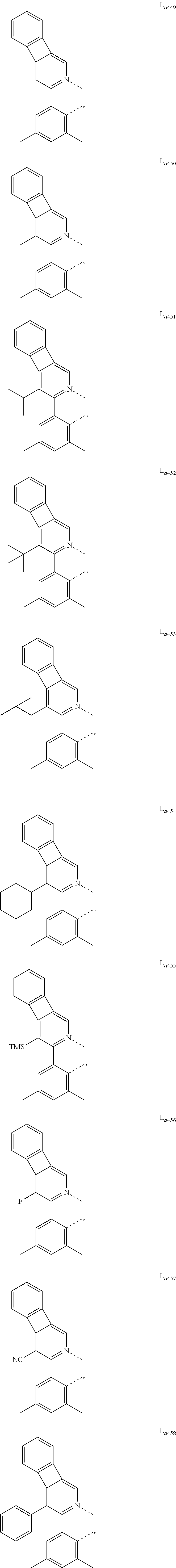

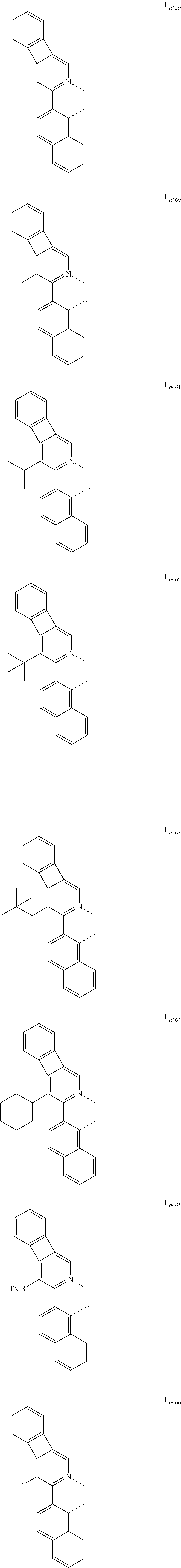

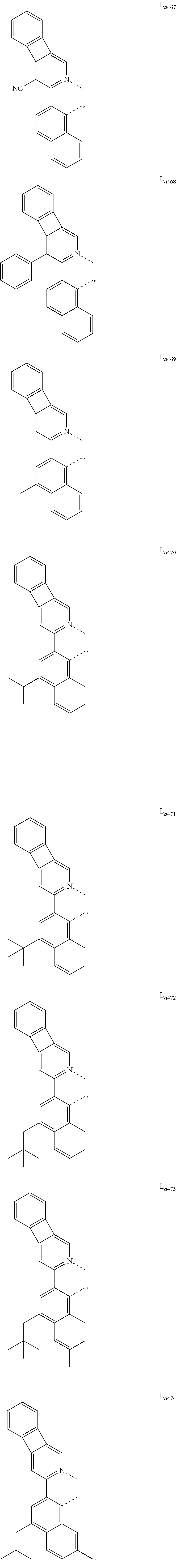

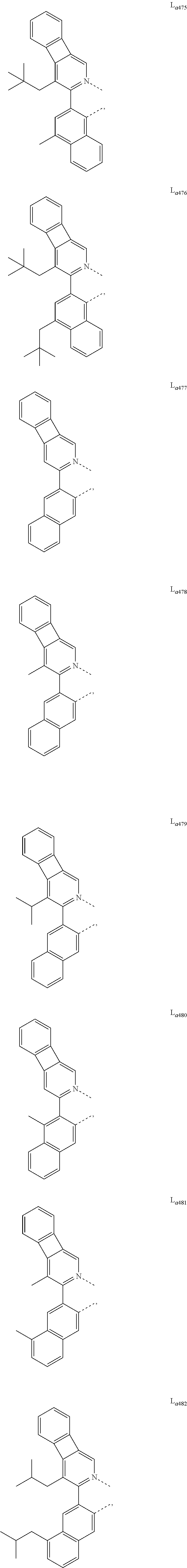

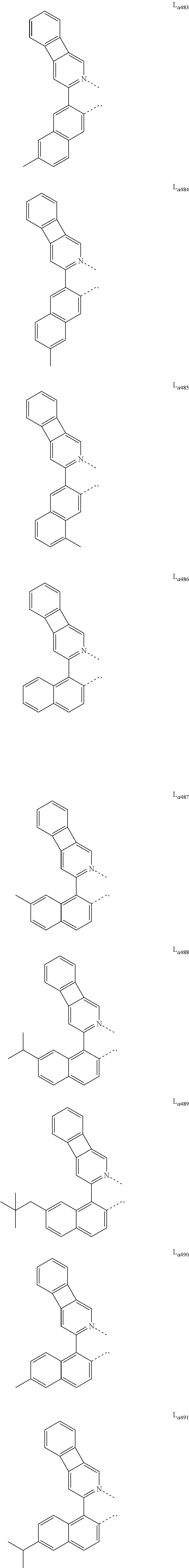

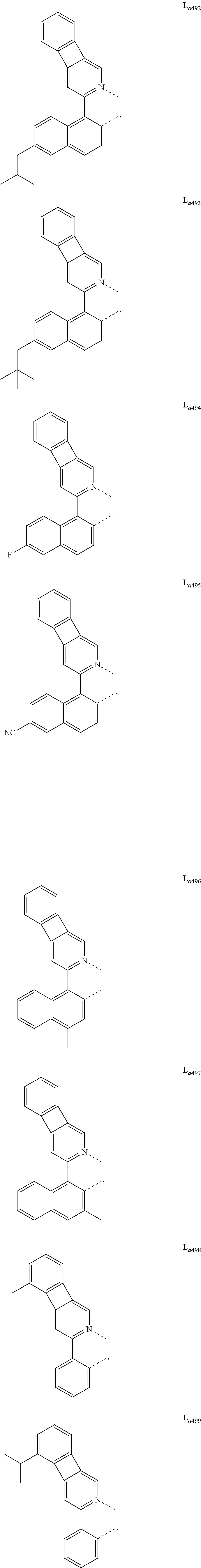

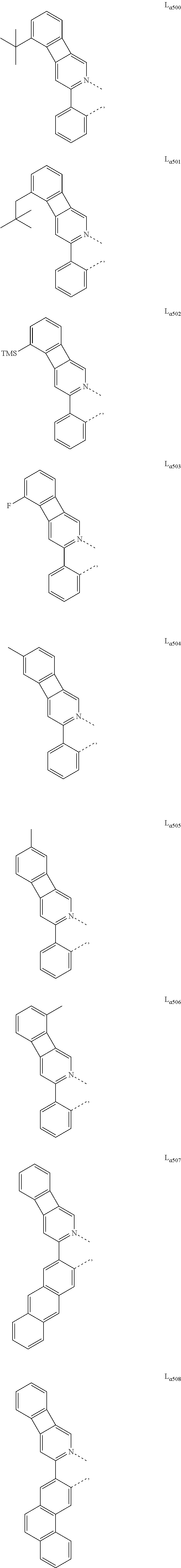

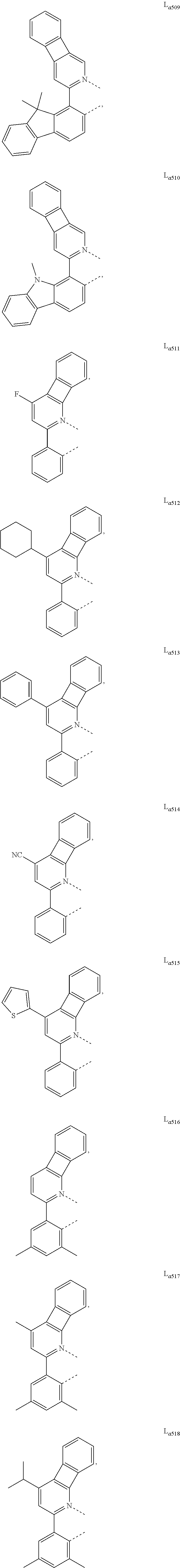

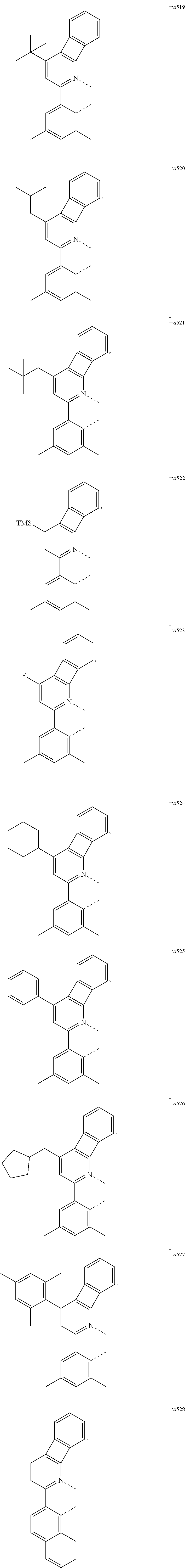

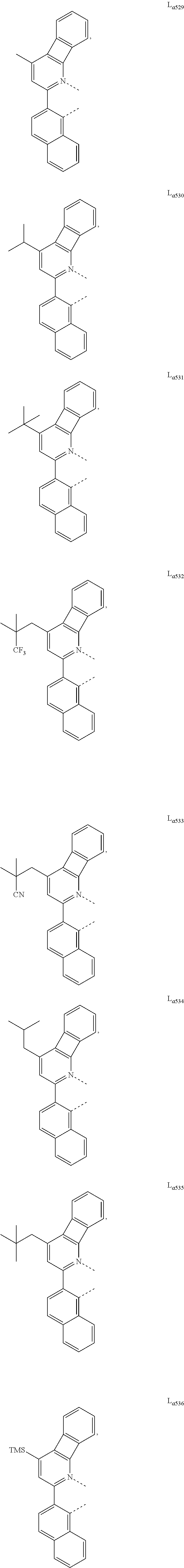

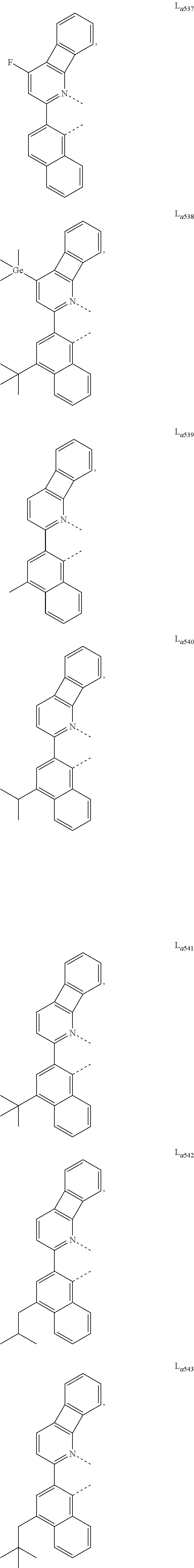

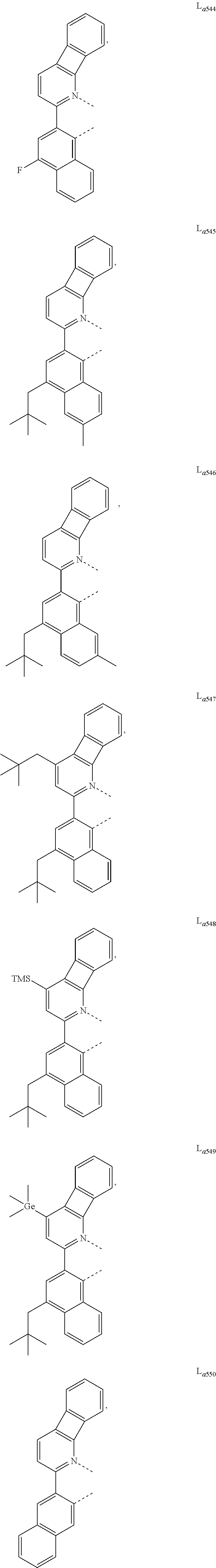

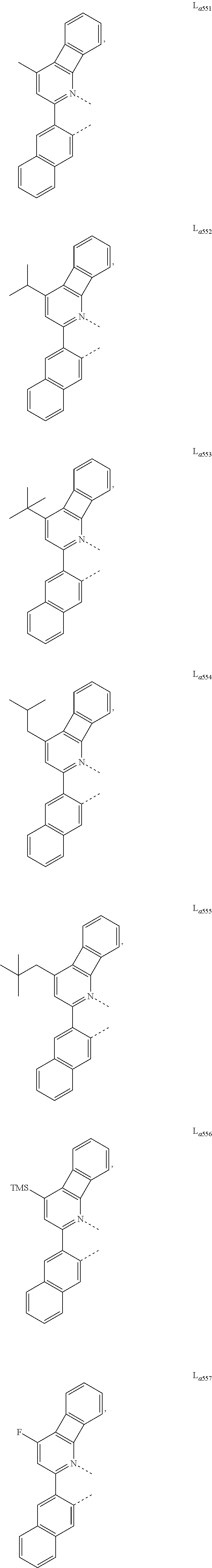

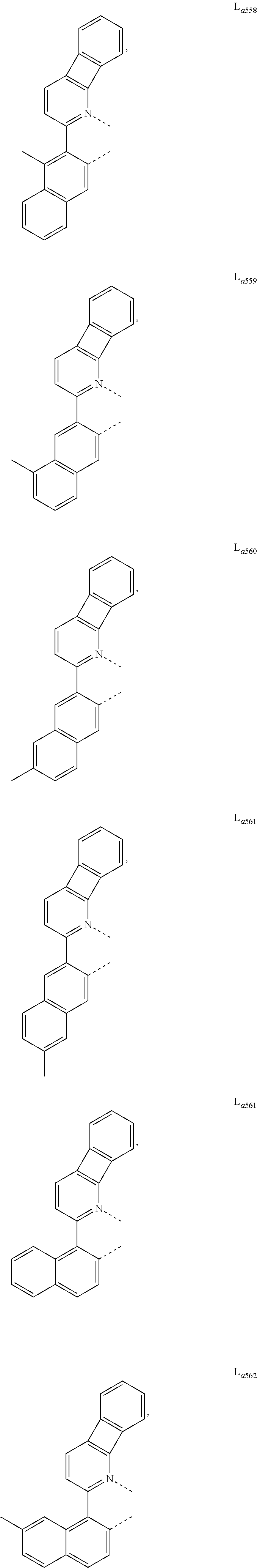

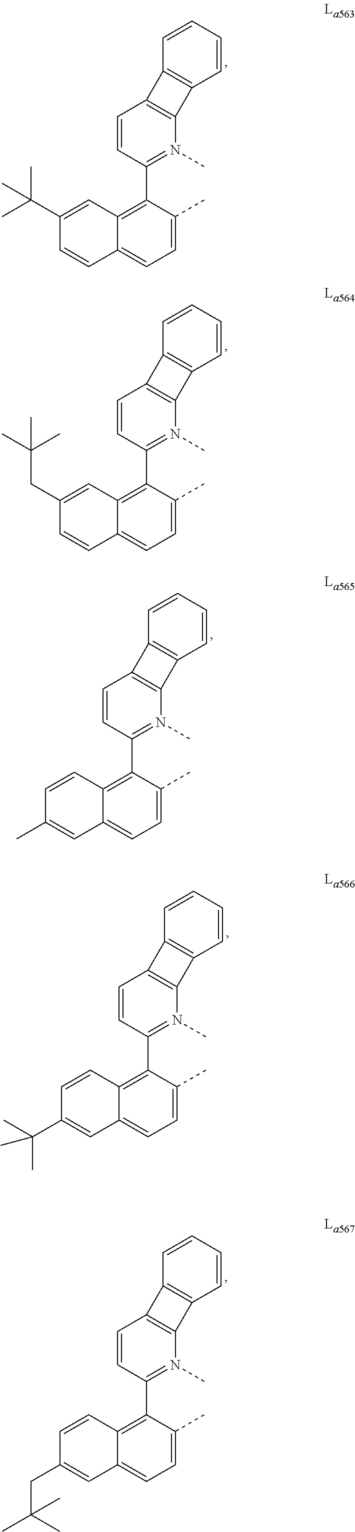

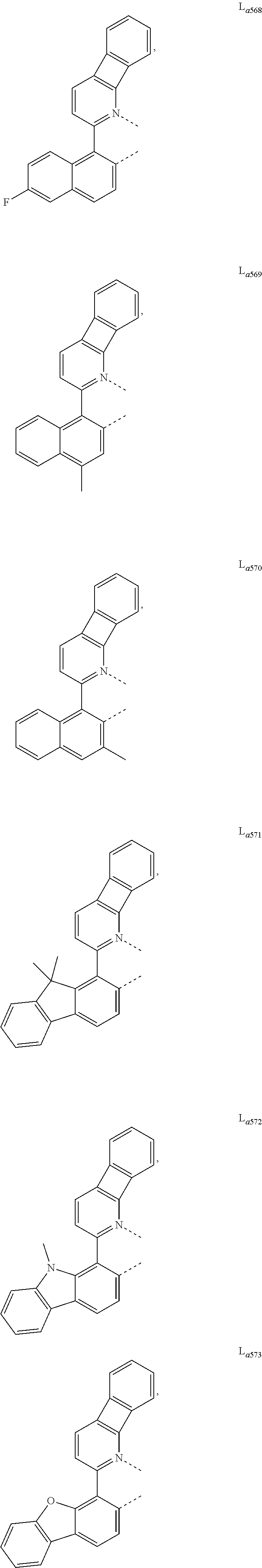

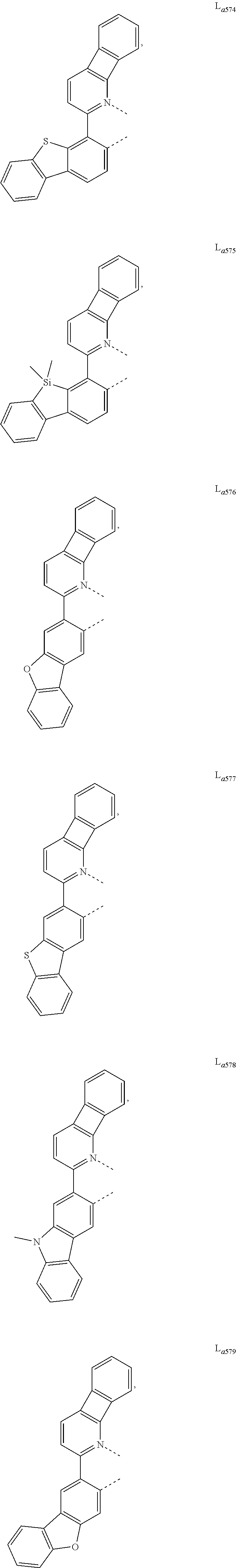

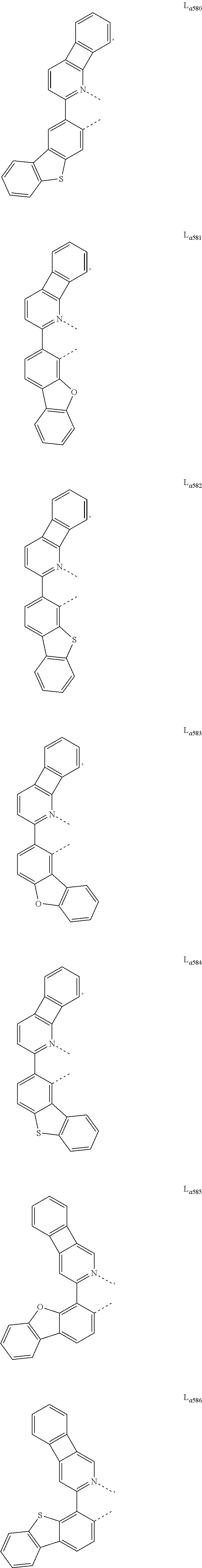

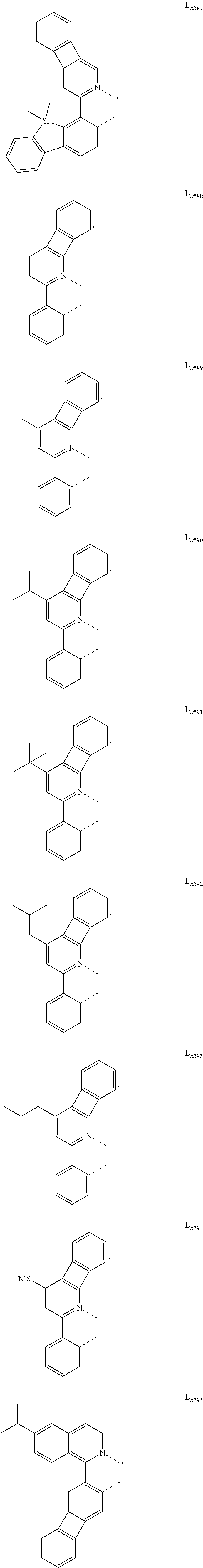

wherein TMS represents trimethylsilyl.

According to an embodiment of the present disclosure, hydrogen in the structures of Lₐ₁ to Lₐ₅₉₅ can be partially or fully substituted with deuterium.

According to an embodiment of the present disclosure, the ligand L_{b} has a structure represented by Formula 28:

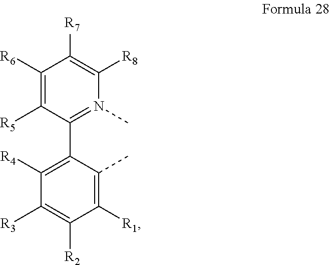

R₁ to R₈ are, at each occurrence identically or differently, selected from the group consisting of: hydrogen, deuterium, halogen, cyano, hydroxyl, sulfanyl, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms and combinations thereof; and
adjacent substituents R₁ to R₈ can be optionally joined to form a ring.

In the present disclosure, the expression that adjacent substituents R₁ to R₈ can be optionally joined to form a ring is intended to mean that any one or more of groups of adjacent substituents, such as adjacent substituents R₁ and R₂, adjacent substituents R₂ and R₃, adjacent substituents R₃ and R₄, adjacent substituents R₄ and R₈, adjacent substituents R₅ and R₆, adjacent substituents R₆ and R₇, and adjacent substituents R₇ and R₈, can be joined to form a ring. Obviously, it is also possible that none of these groups of adjacent substituents are joined to form a ring.

According to an embodiment of the present disclosure, R₁ to R₈ are identically or differently selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof.

According to an embodiment of the present disclosure, R₁ to R₈ are, at each occurrence identically or differently, selected from the group consisting of: hydrogen, deuterium, fluorine, methyl, ethyl, isopropyl, isobutyl, tert-butyl, cyclopentyl, cyclopentylmethyl, cyclohexyl, neopentyl, deuterated methyl, deuterated ethyl, deuterated isopropyl, deuterated isobutyl, deuterated tert-butyl, deuterated cyclopentyl, deuterated cyclopentylmethyl, deuterated cyclohexyl, deuterated neopentyl, trimethylsilyl and combinations thereof.

According to an embodiment of the present disclosure, at least one, at least two, at least three or all of R₂, R₃, R₆ and R₇ are, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, at least one, at least two, at least three or all of R₂, R₃, R₆ and R₇ are, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms and combinations thereof.

According to an embodiment of the present disclosure, at least one, at least two, at least three or all of R₂, R₃, R₆ and R₇ are, at each occurrence identically or differently, selected from the group consisting of: deuterium, methyl, ethyl, propyl, isopropyl, n-butyl, isobutyl, ter-butyl, cyclopentyl, cyclohexyl, neopentyl, tert-pentyl, and any preceding group that is partially or fully substituted with deuterium.

According to an embodiment of the present disclosure, L_{b} is selected from the group consisting of L_{b1} to L_{b339}:

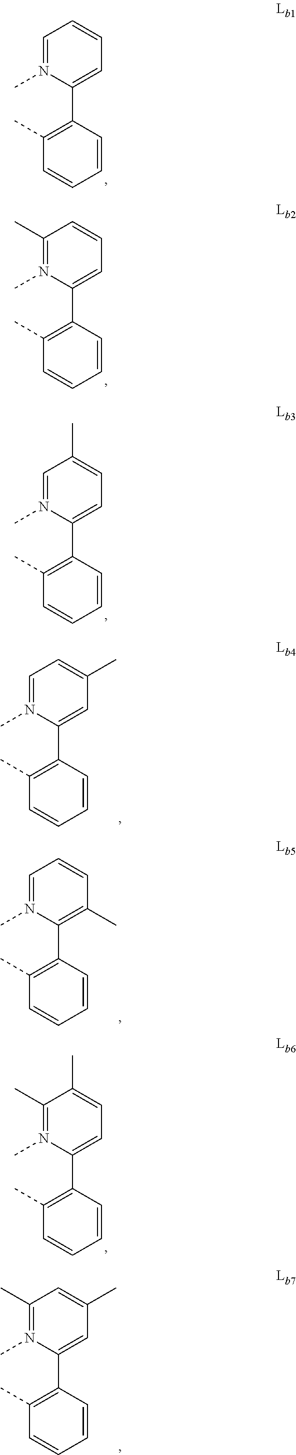

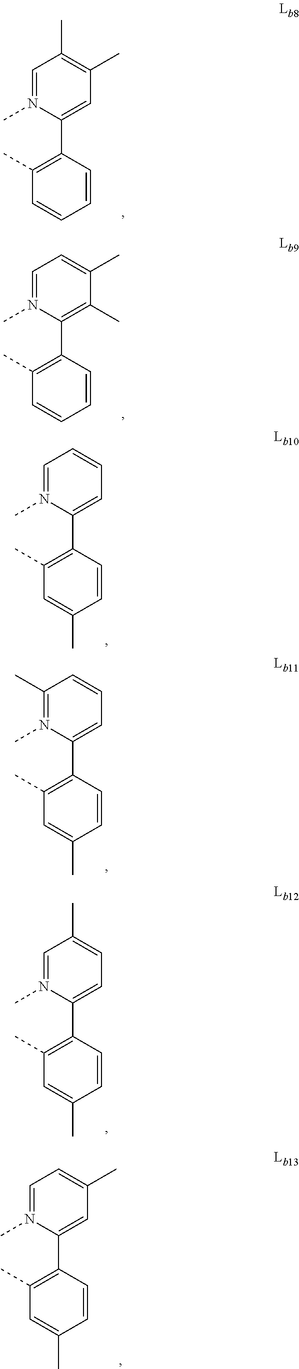

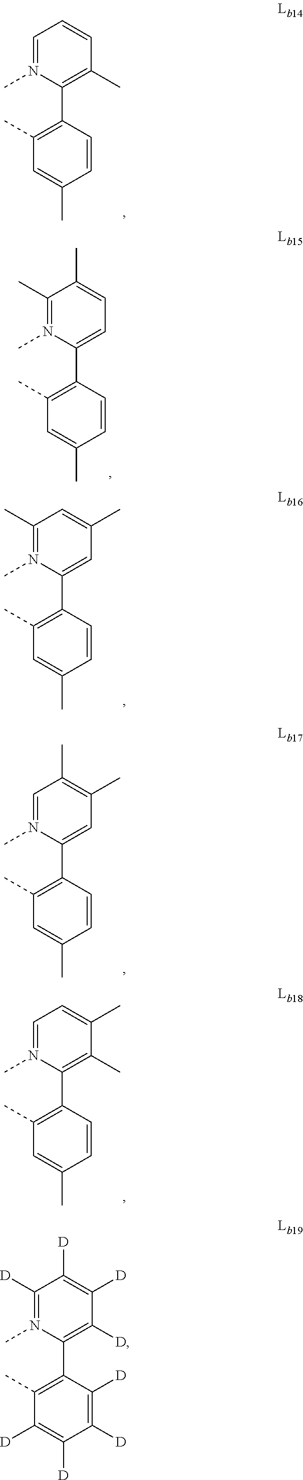

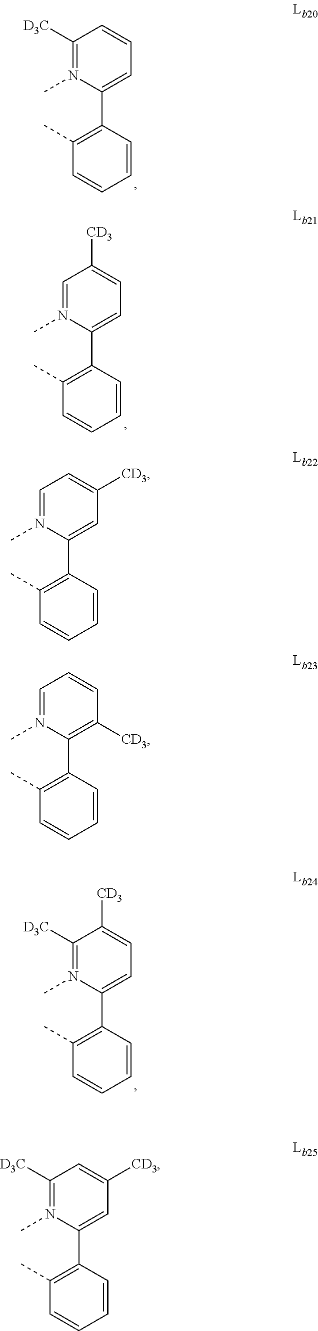

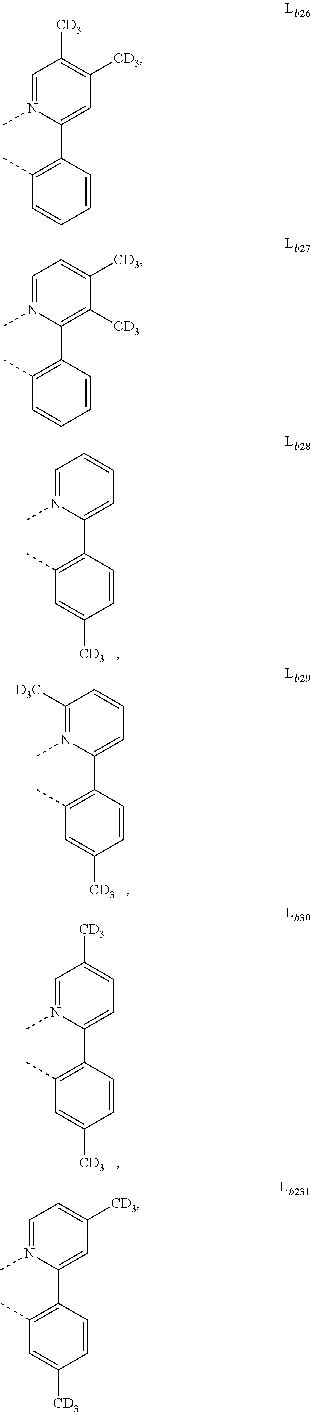

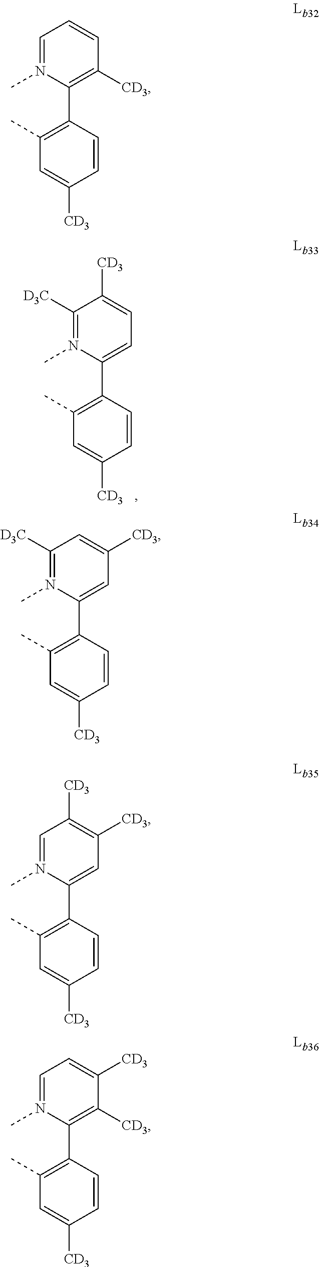

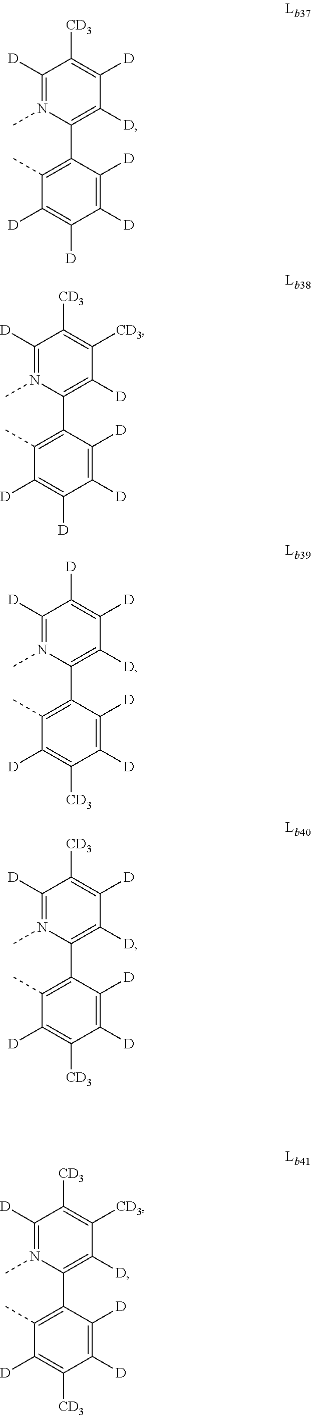

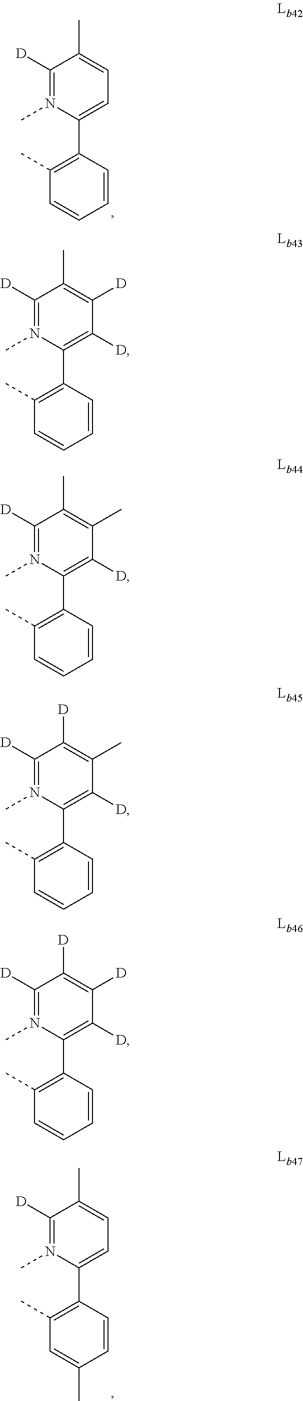

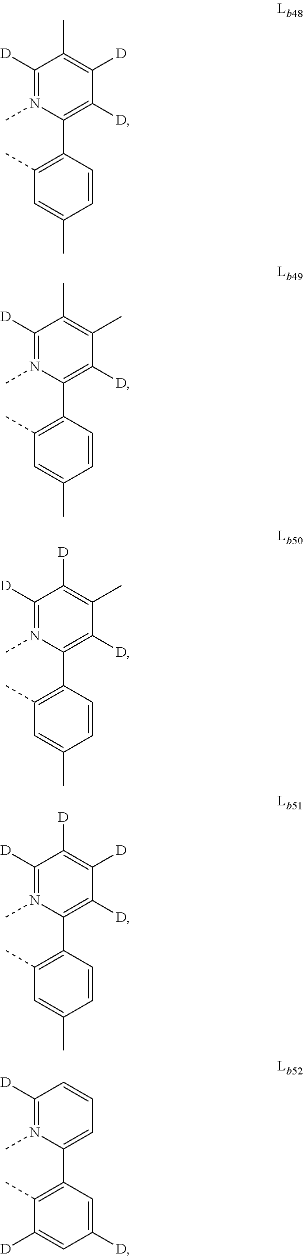

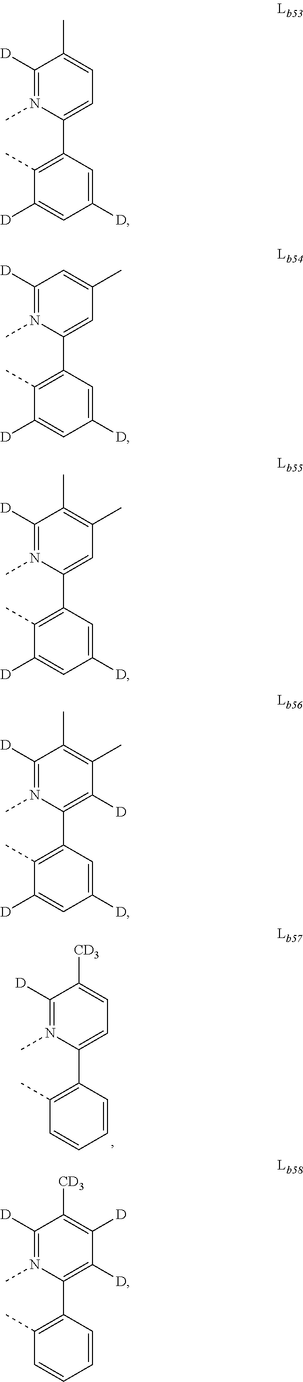

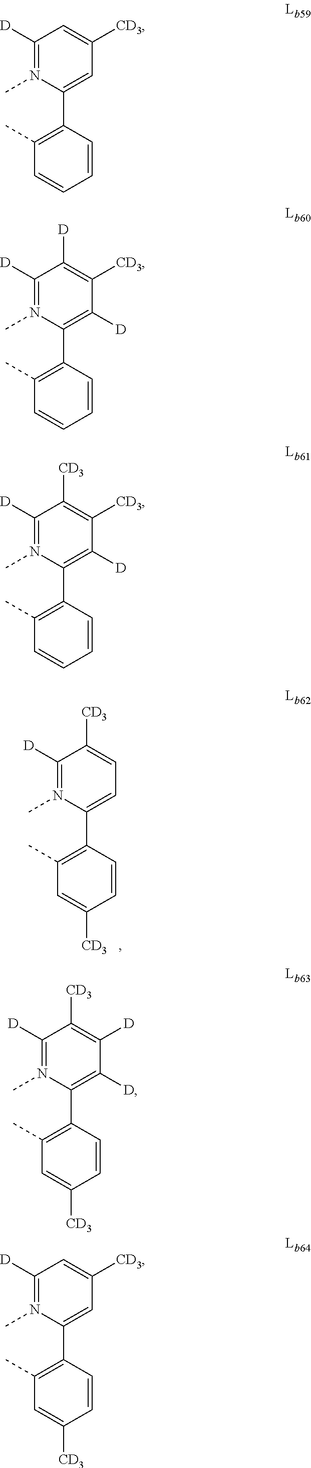

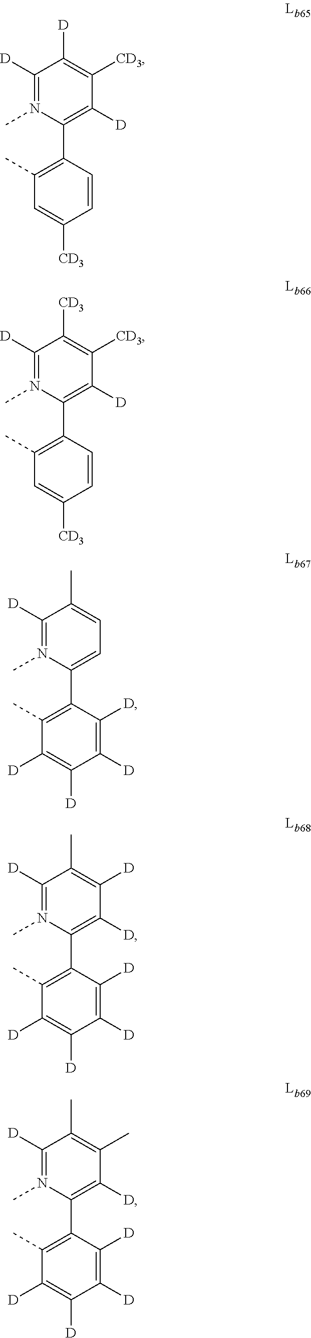

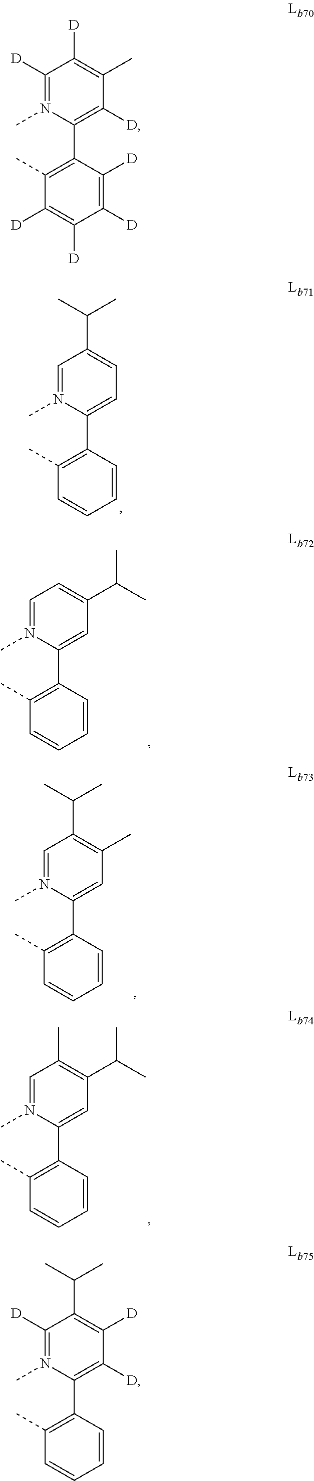

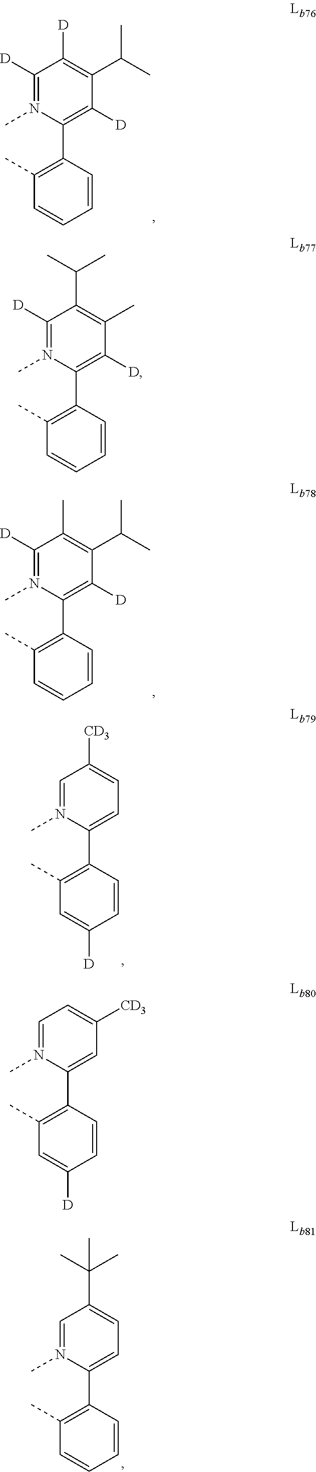

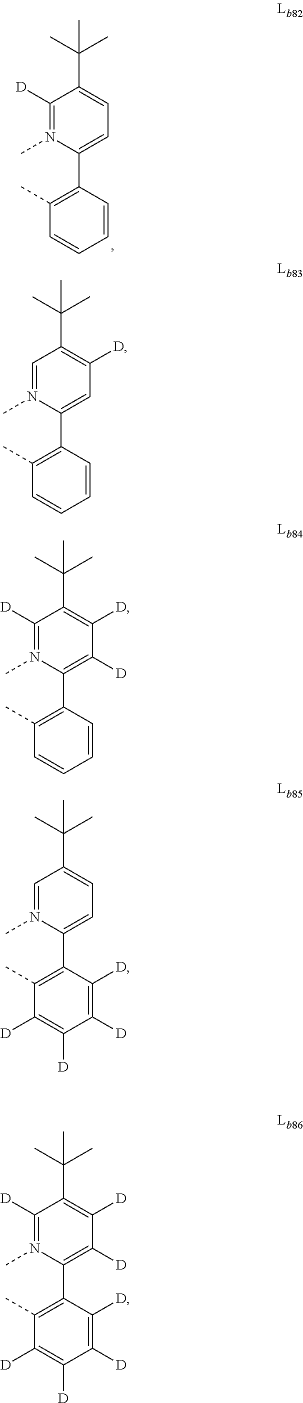

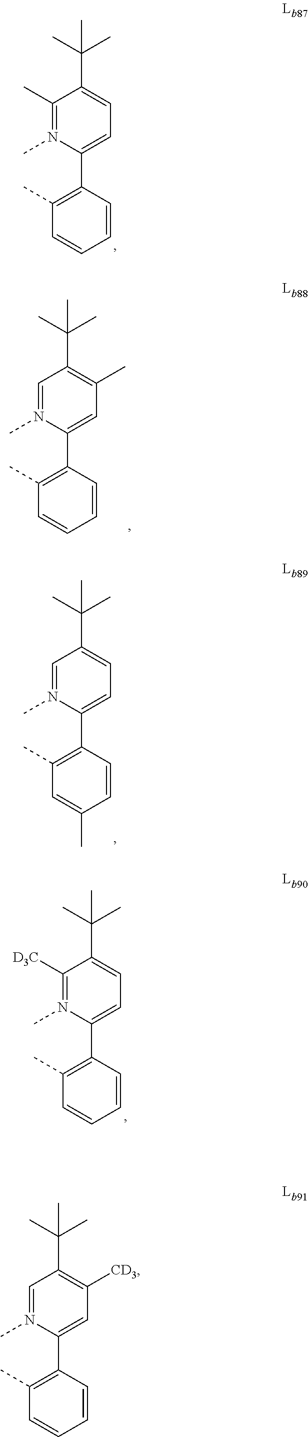

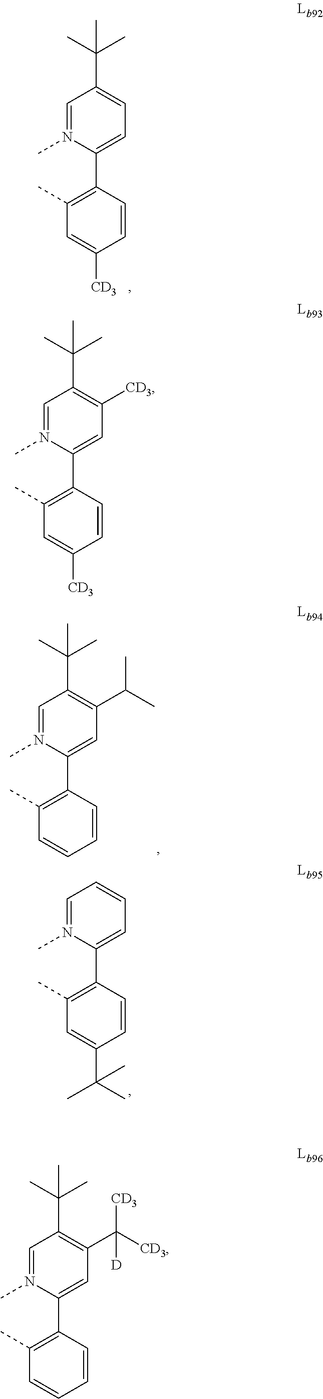

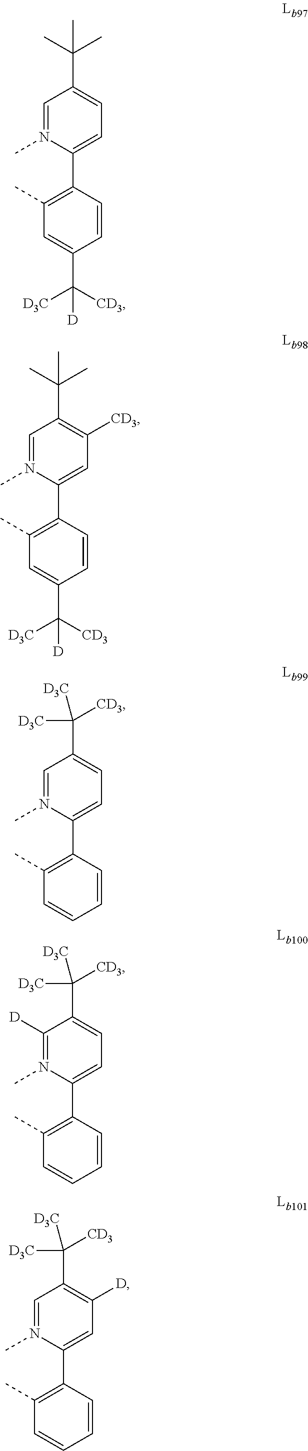

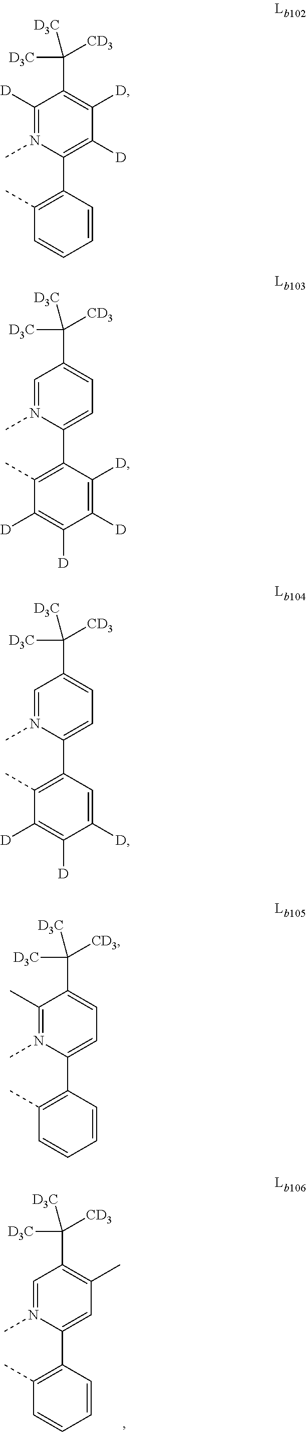

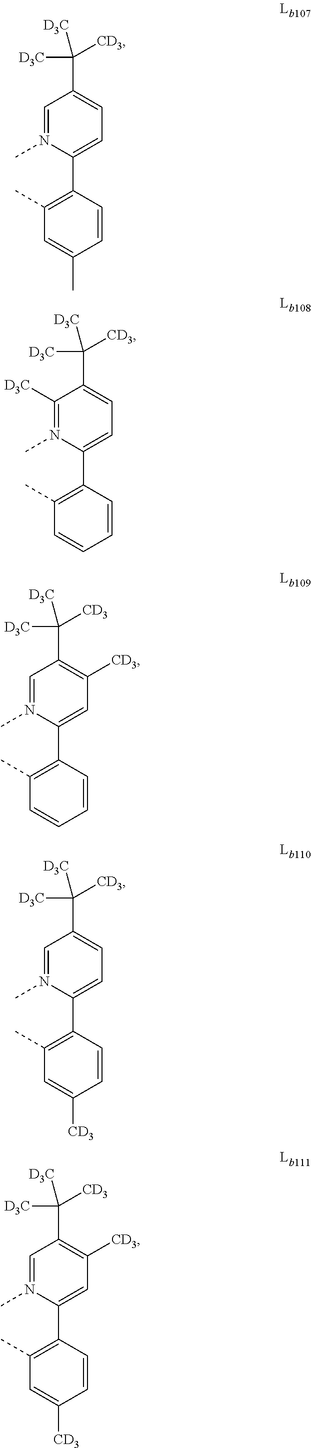

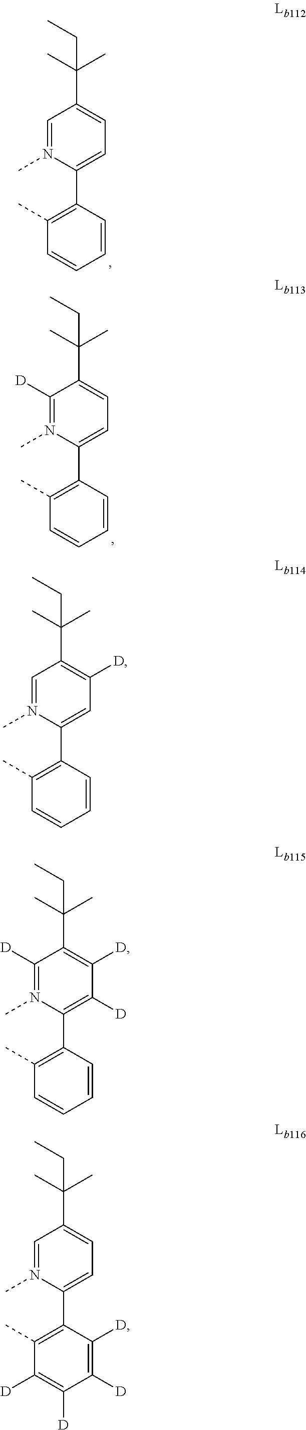

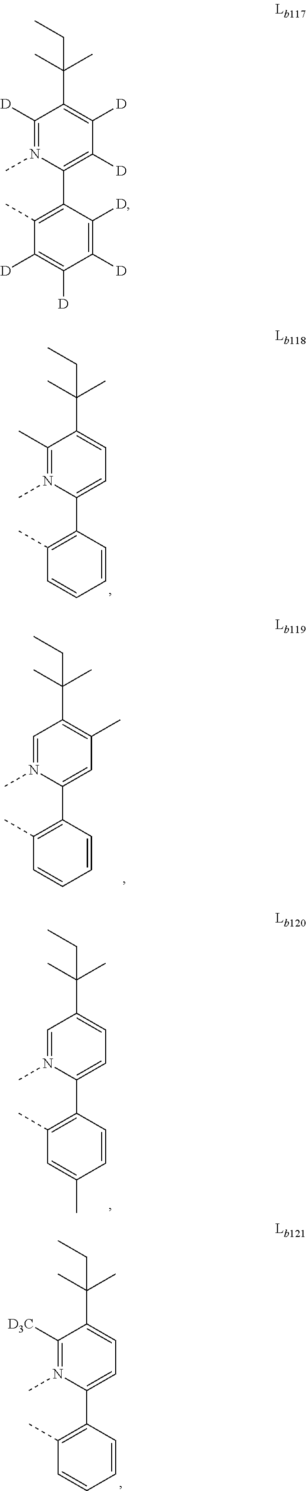

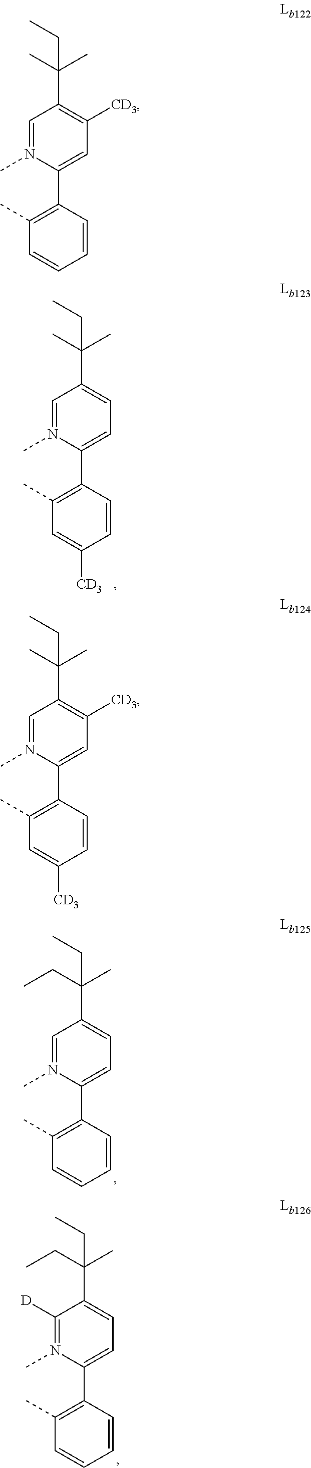

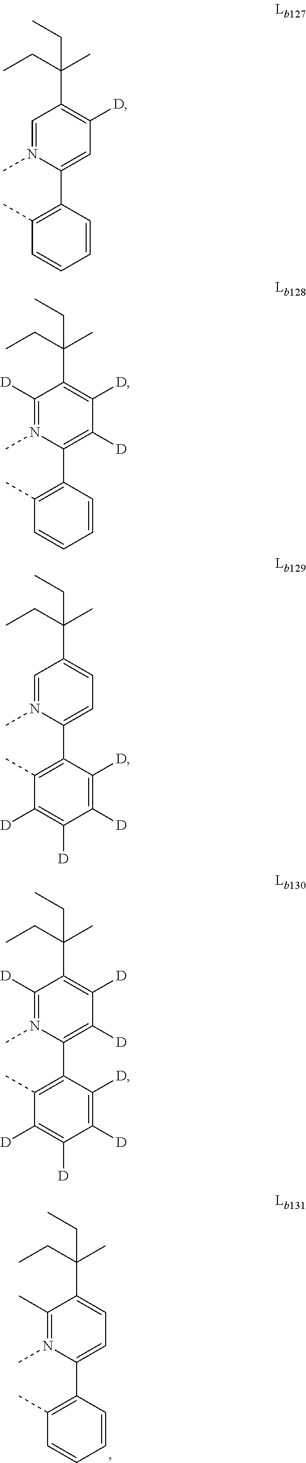

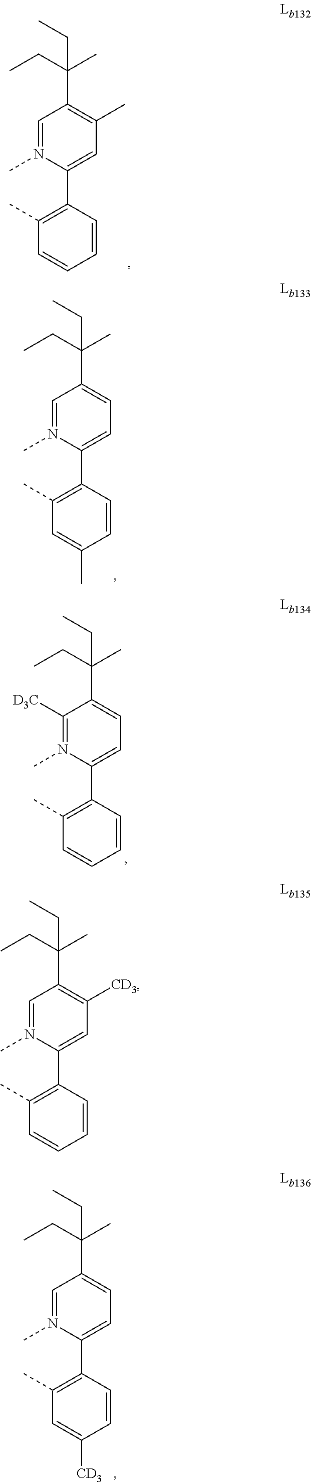

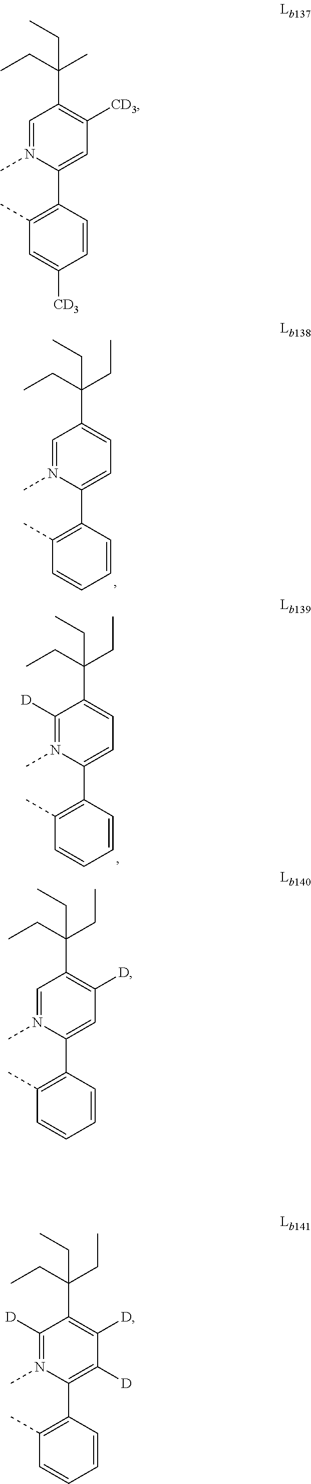

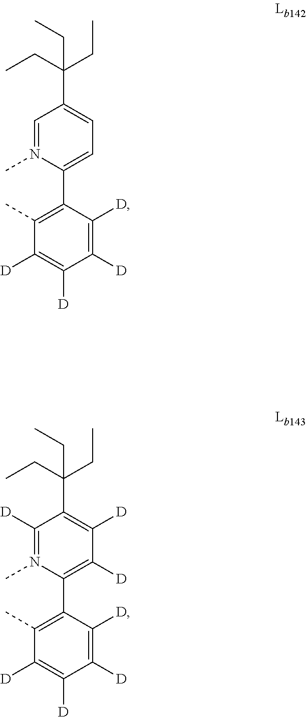

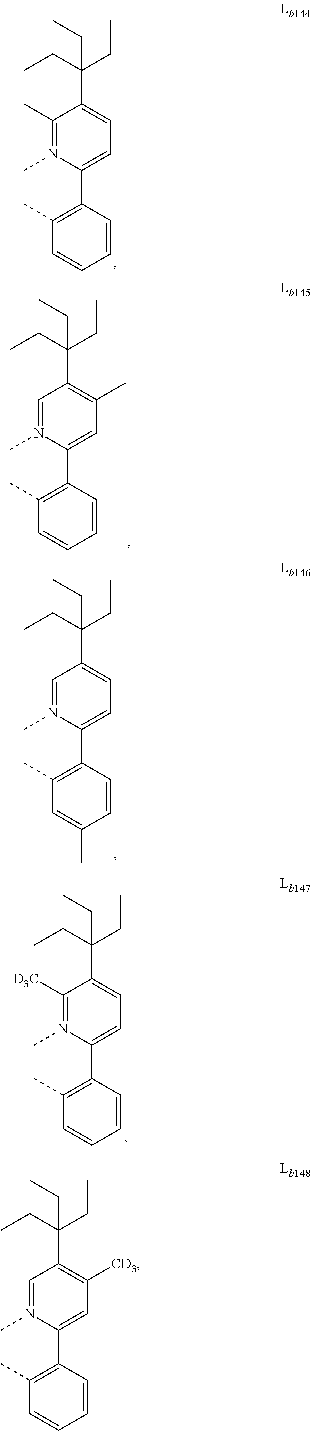

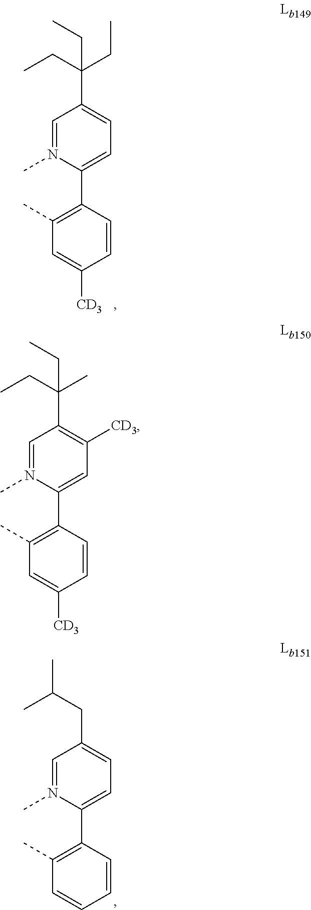

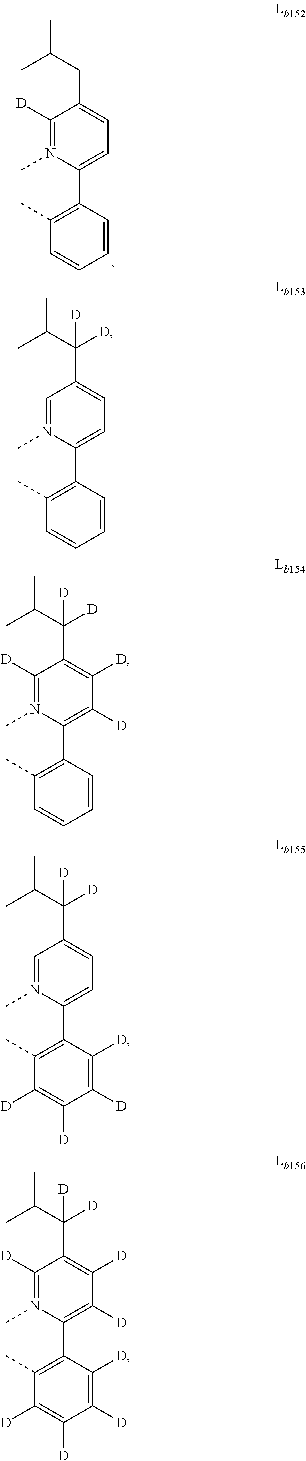

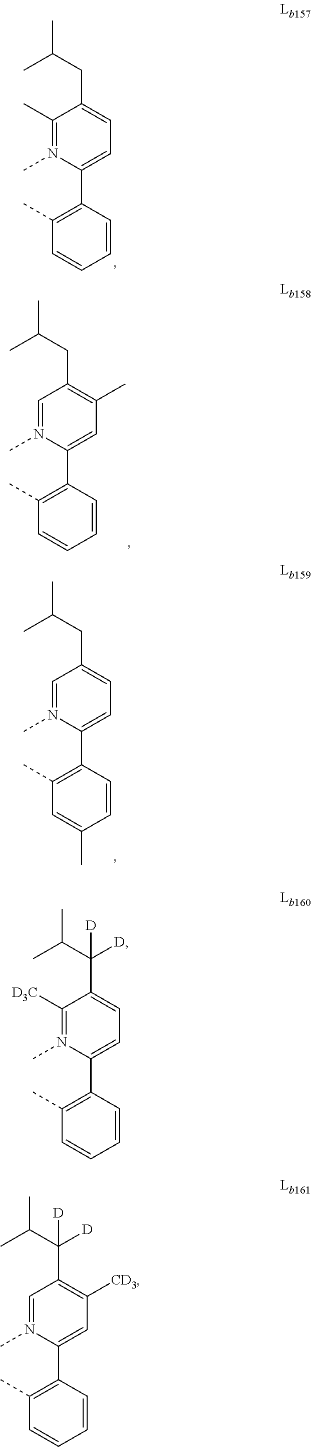

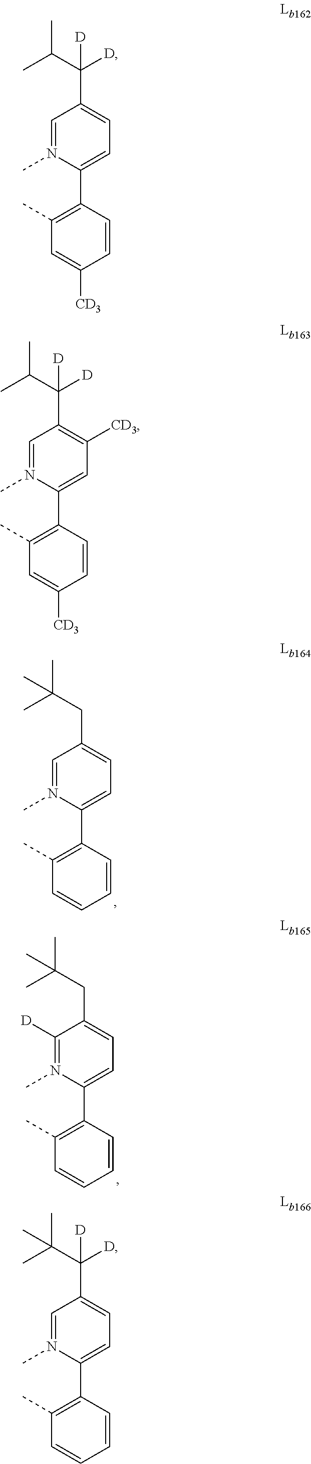

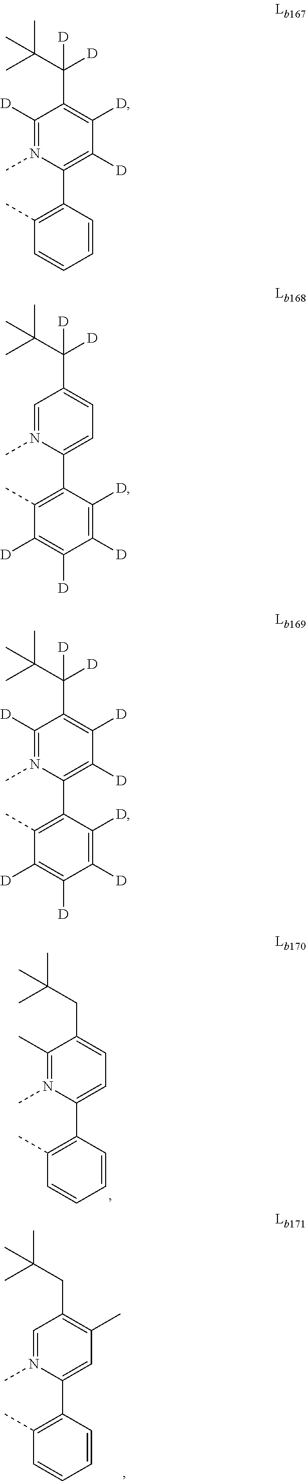

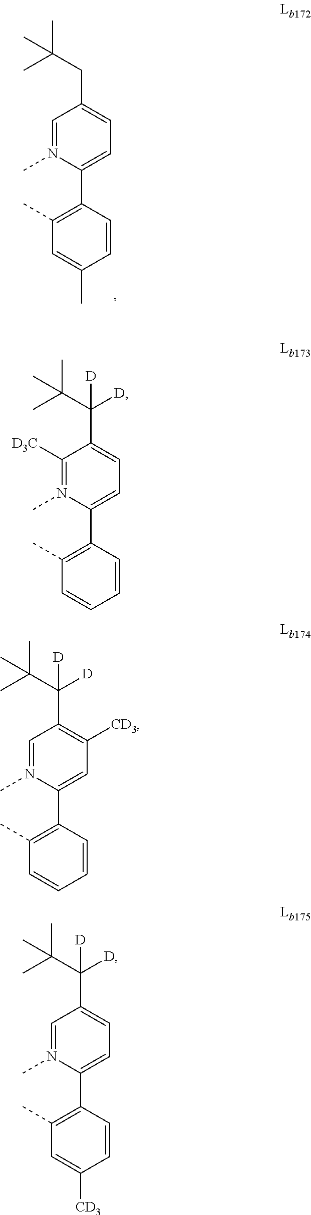

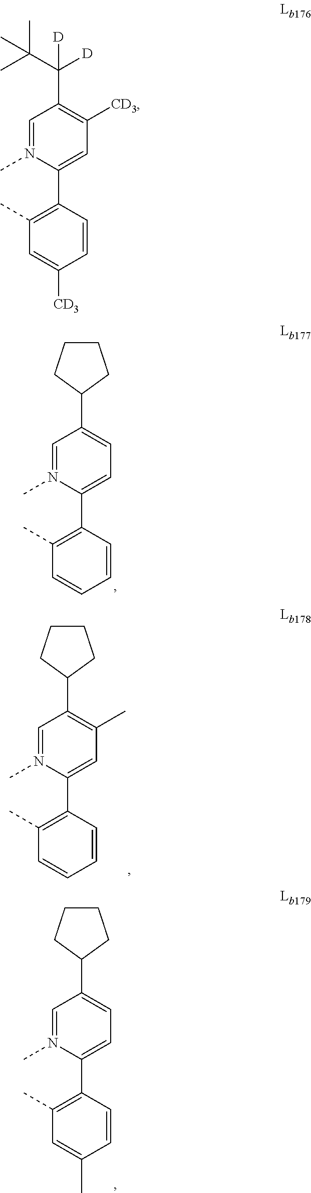

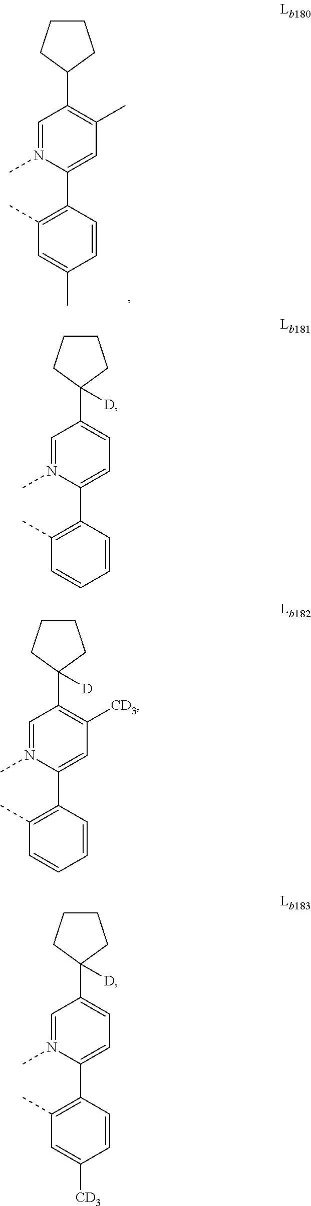

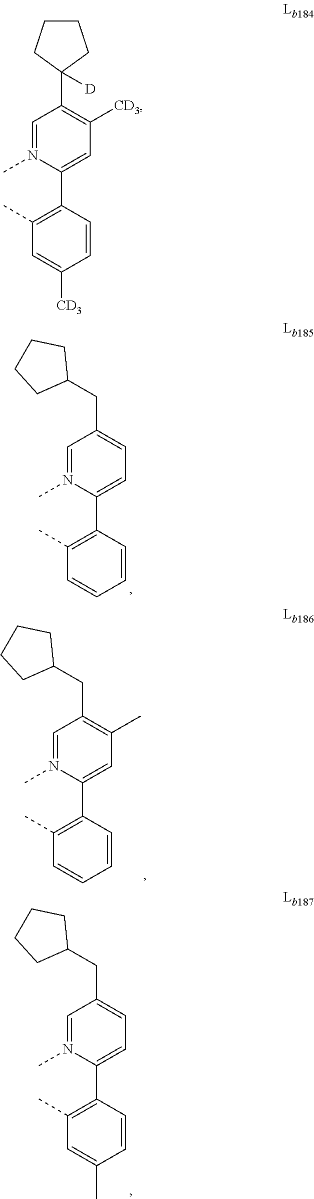

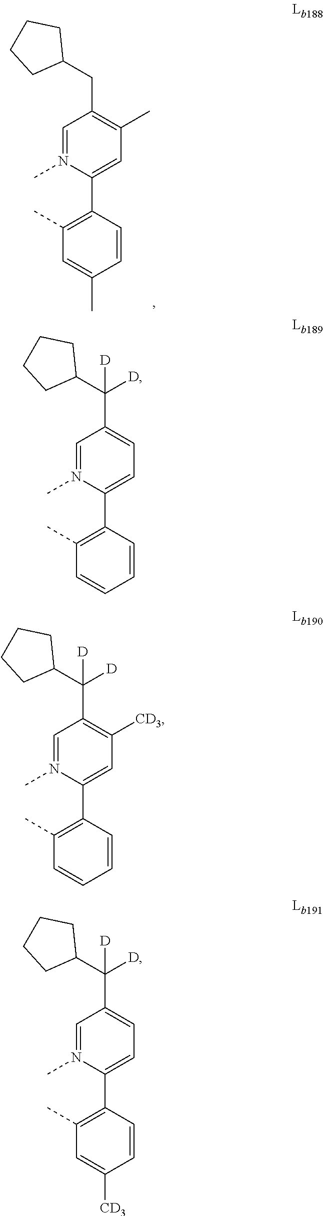

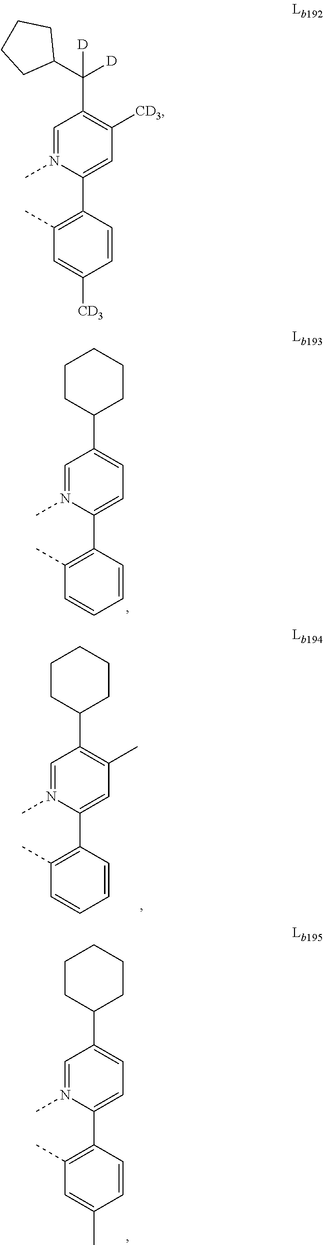

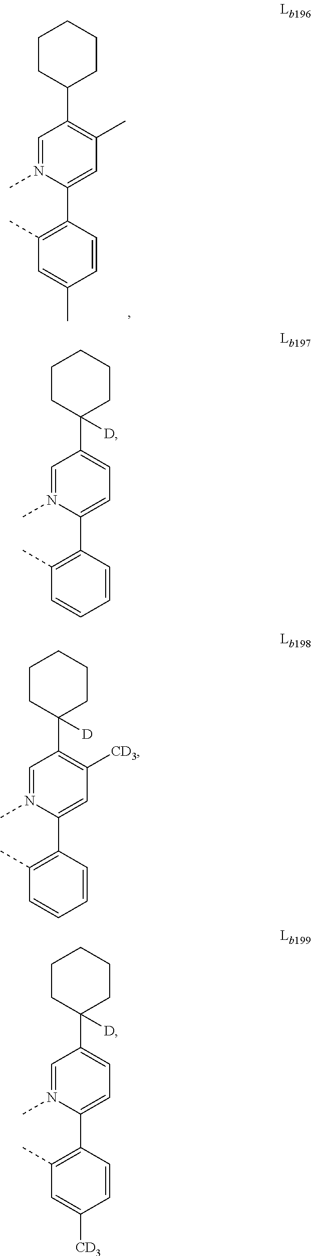

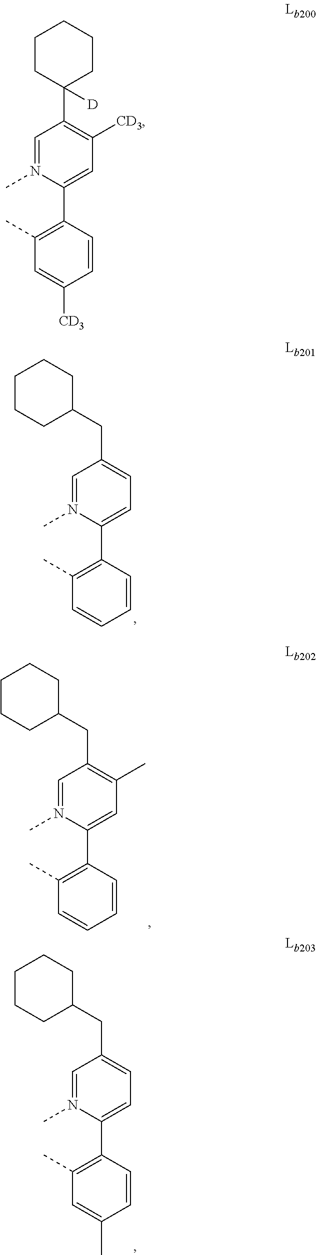

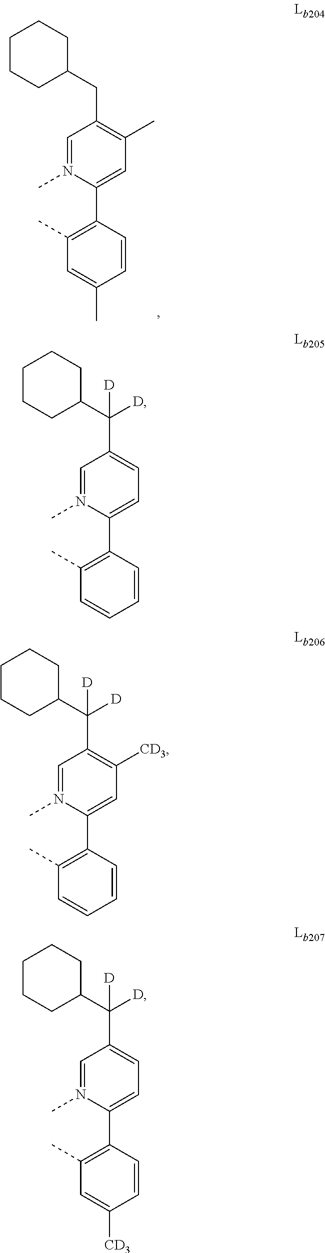

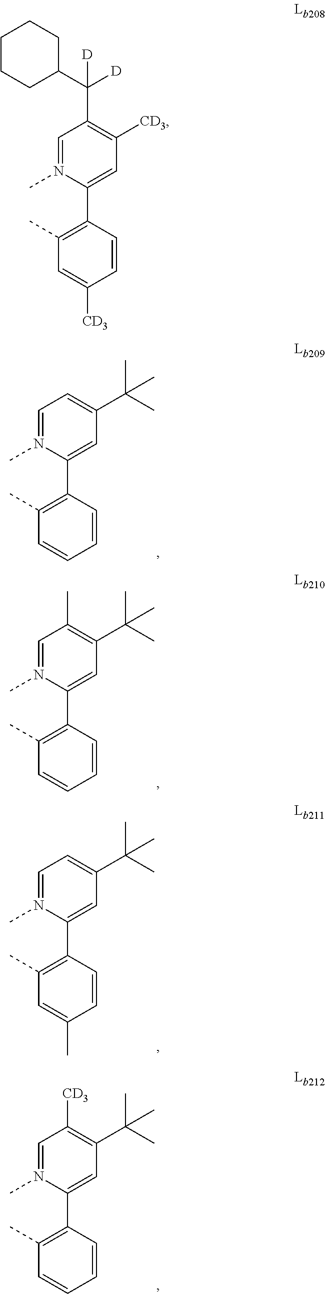

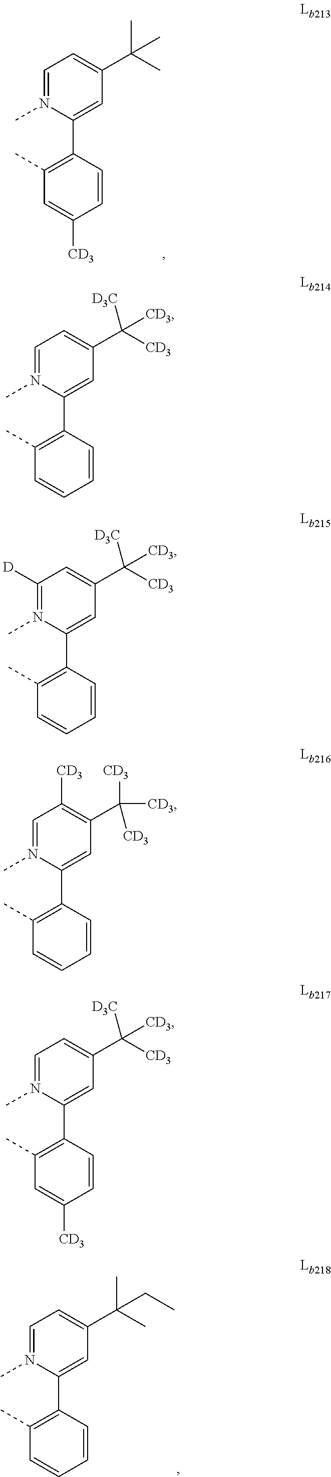

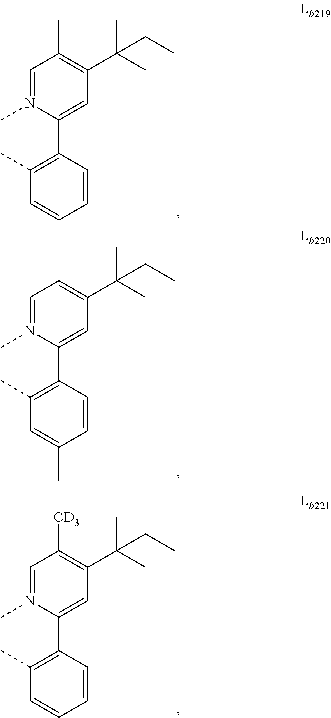

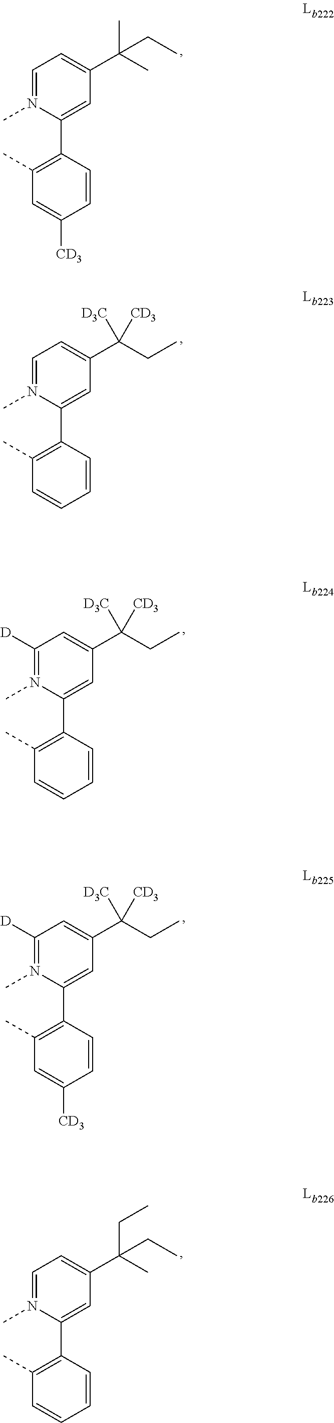

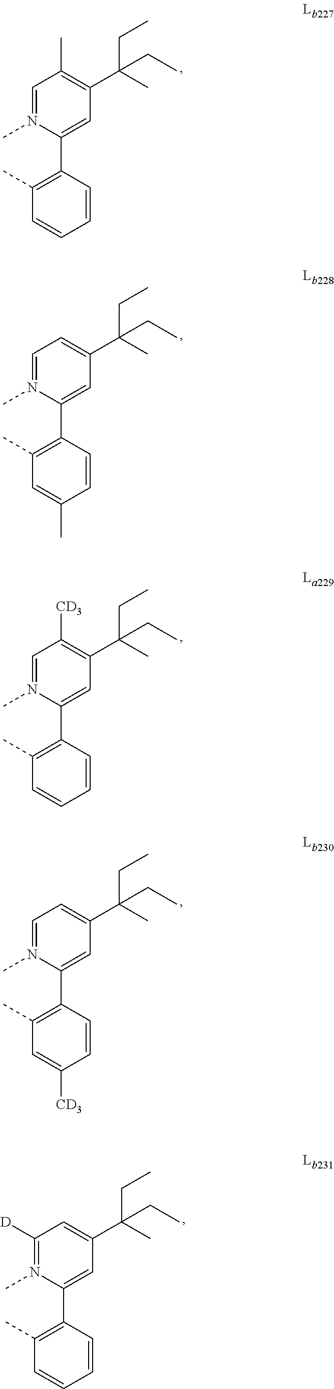

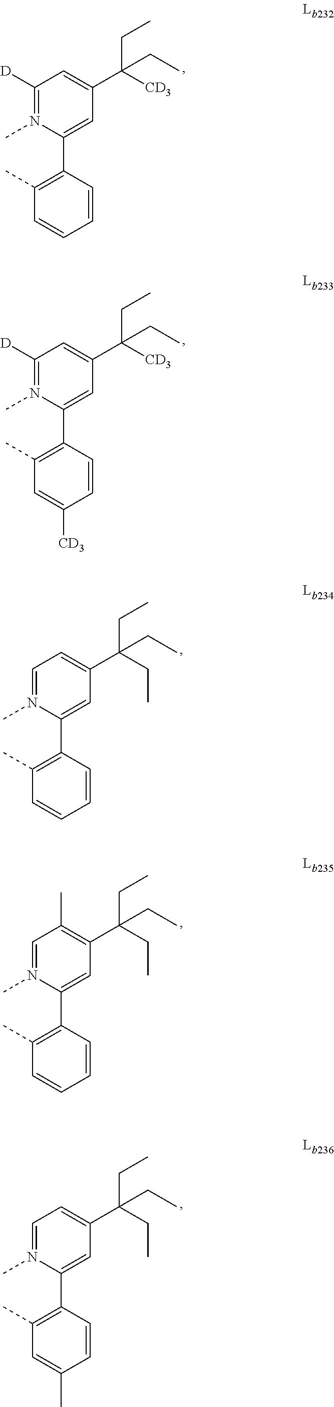

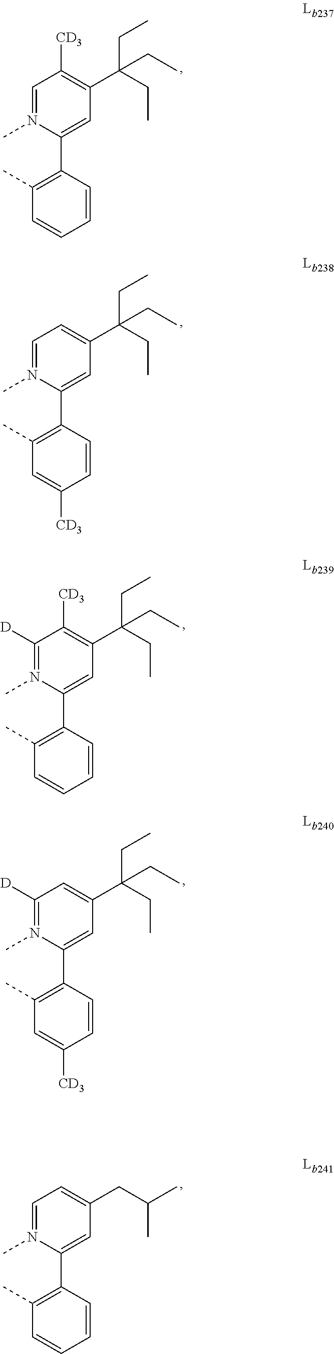

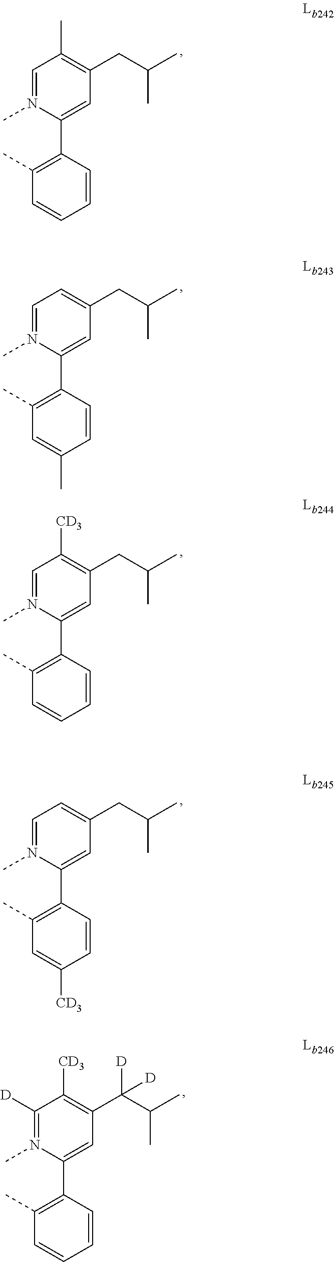

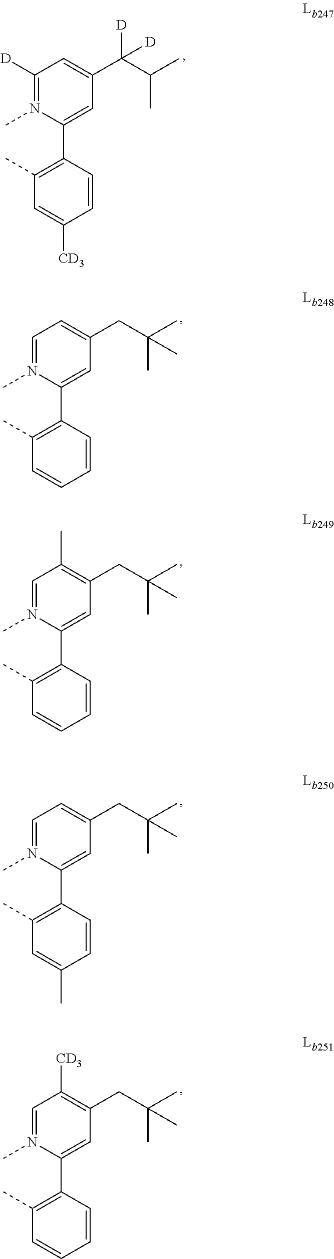

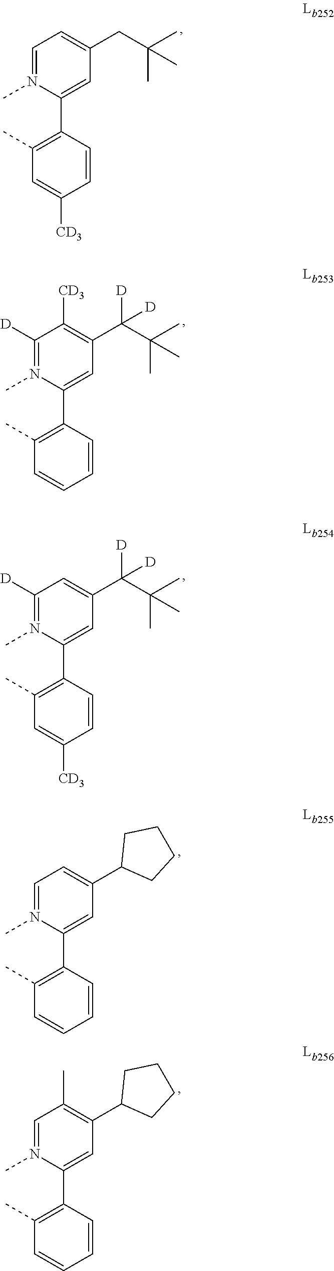

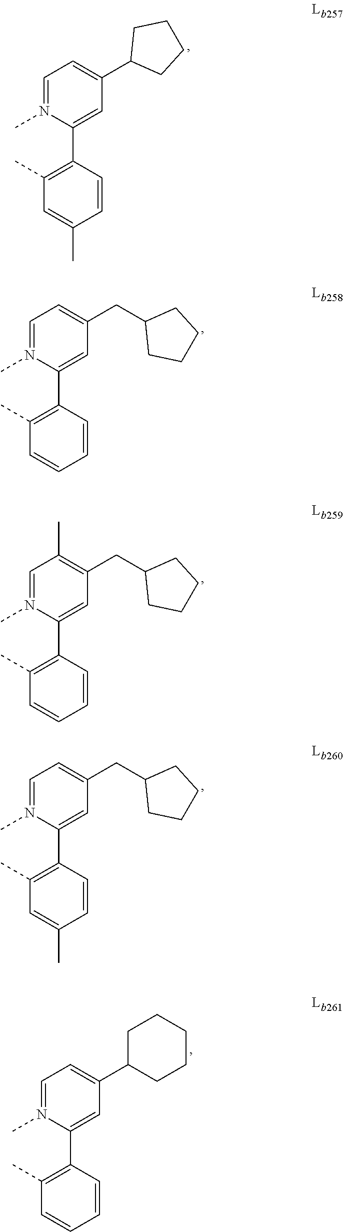

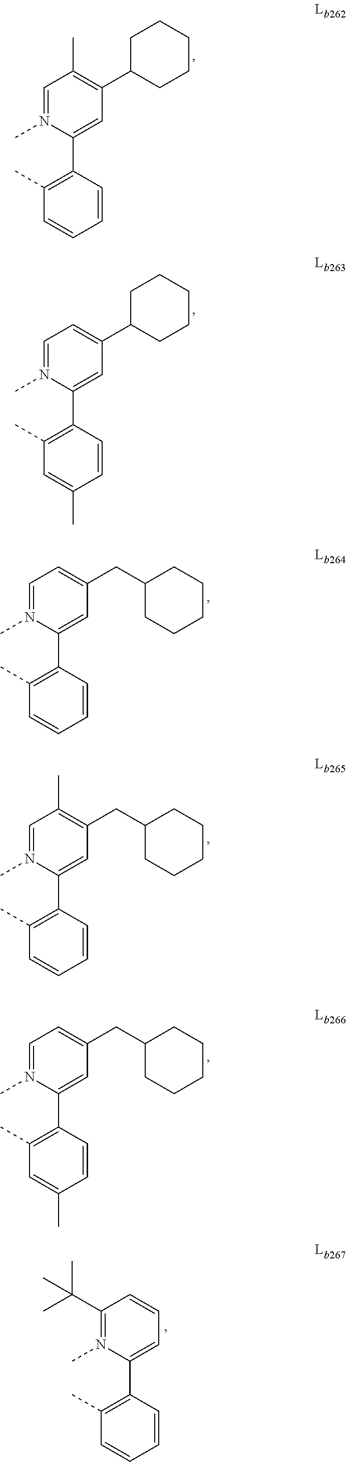

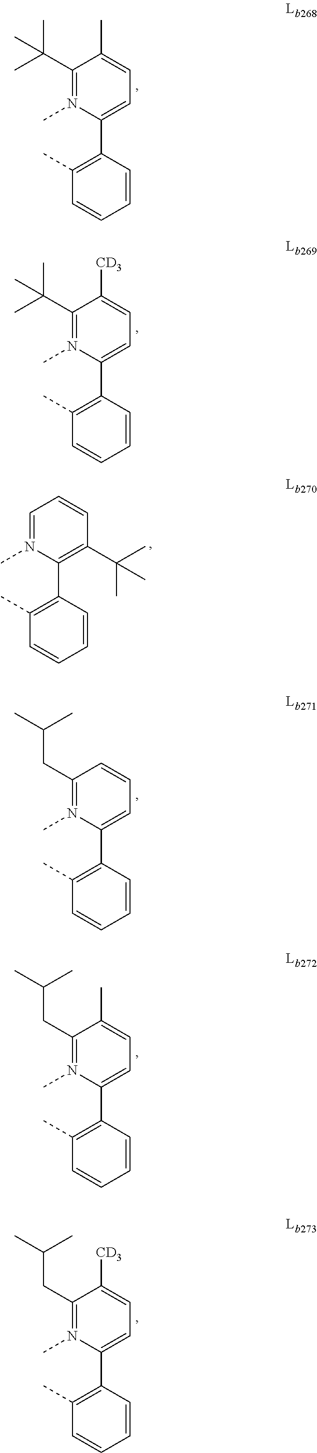

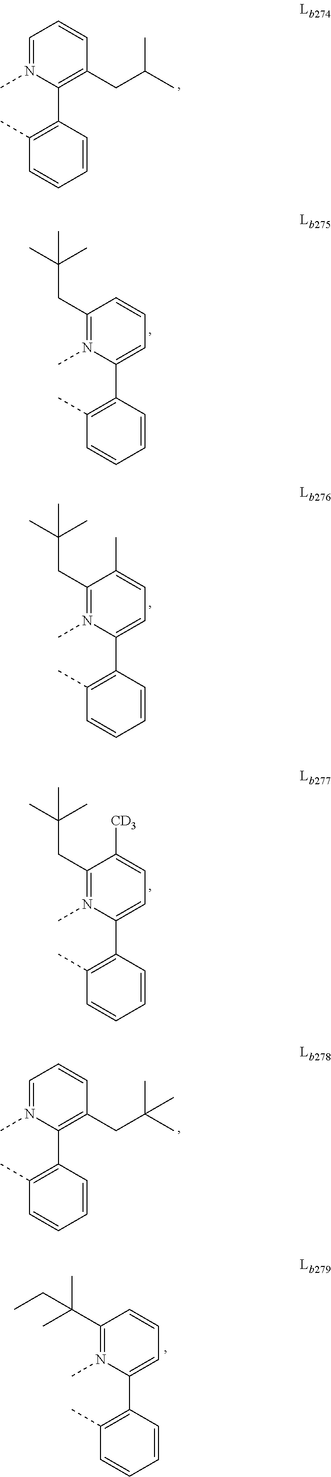

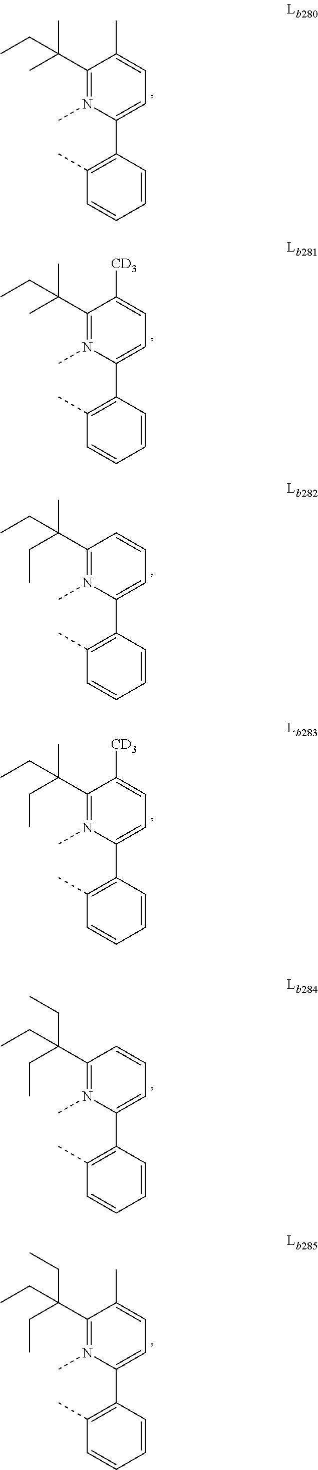

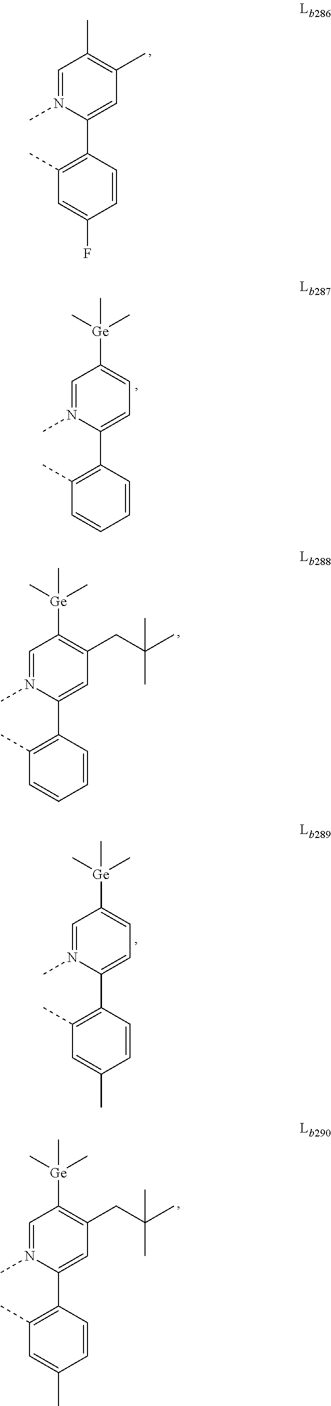

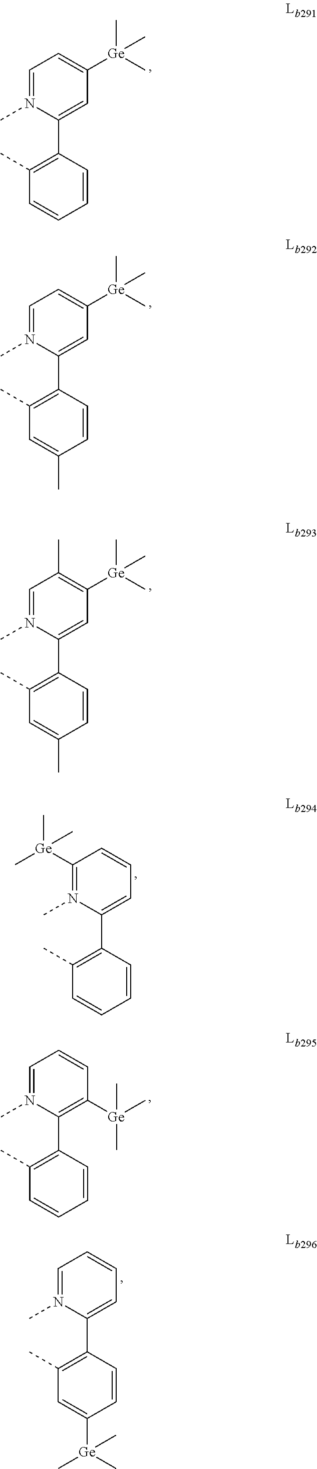

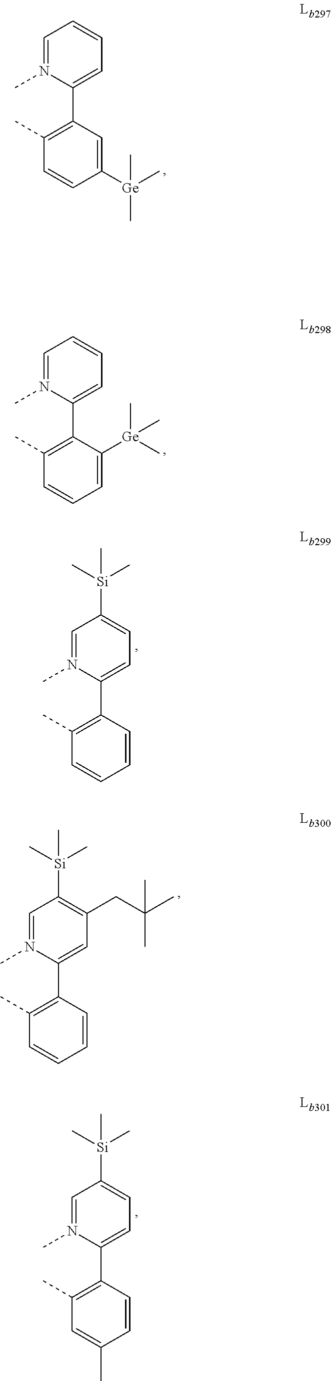

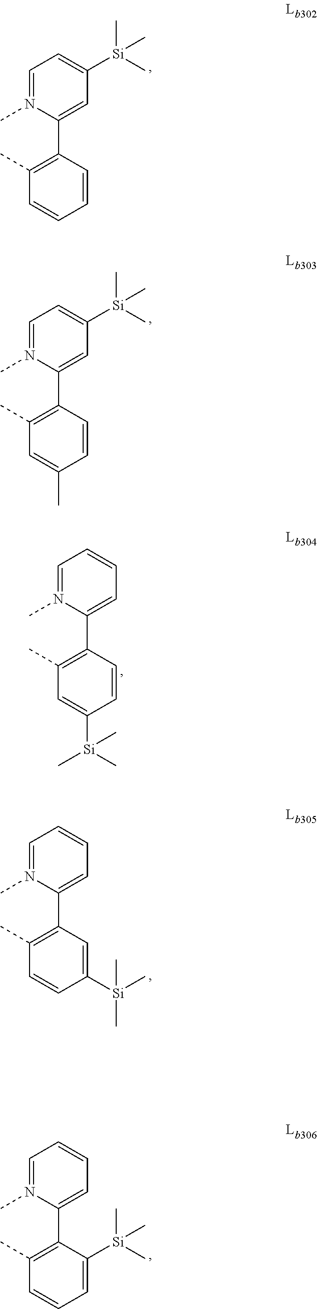

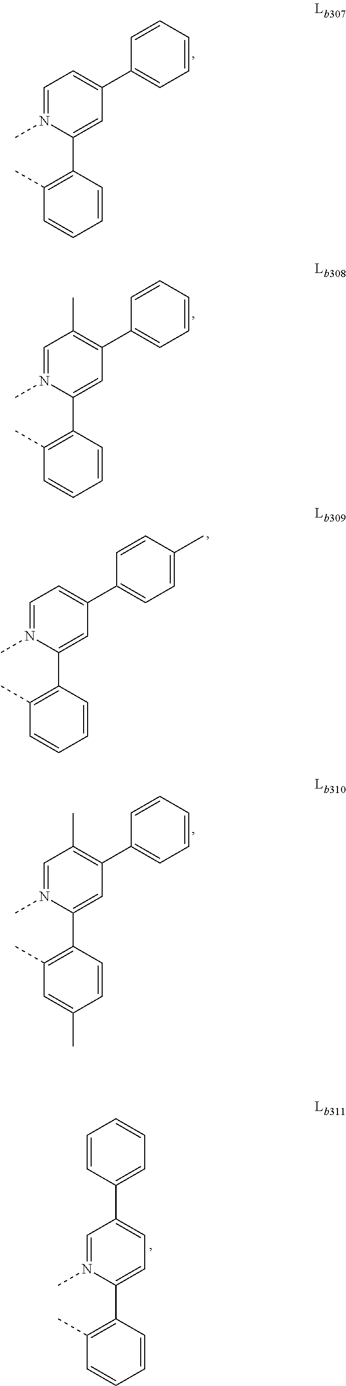

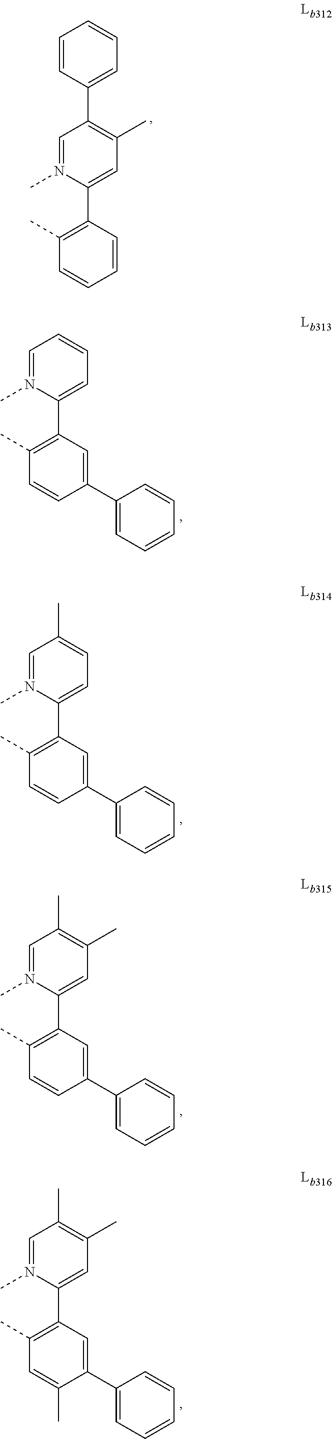

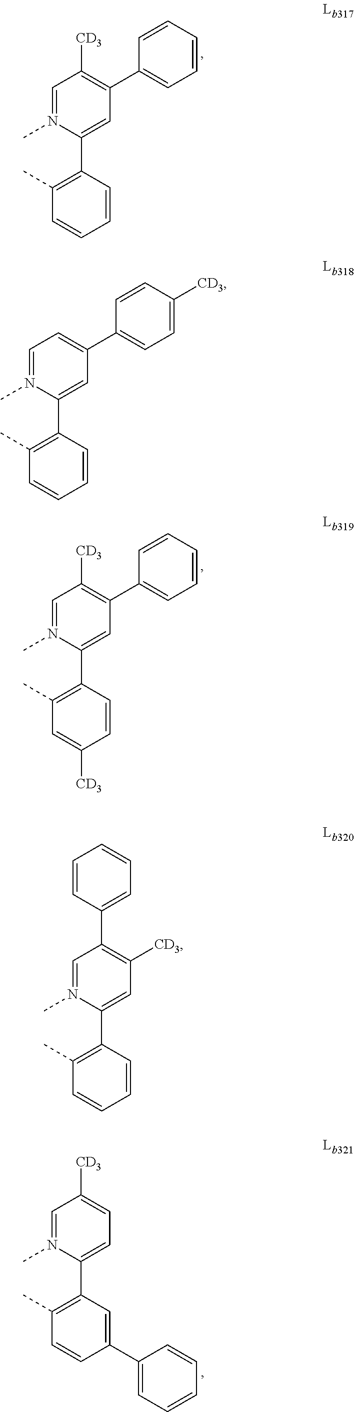

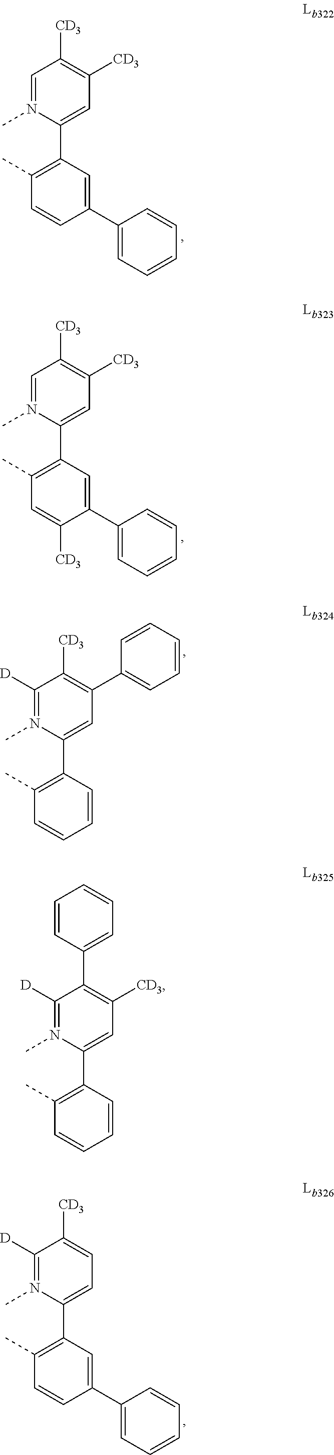

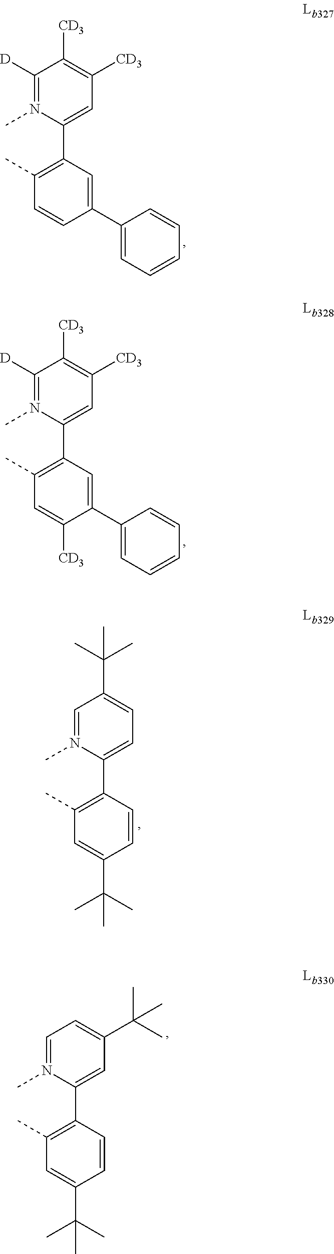

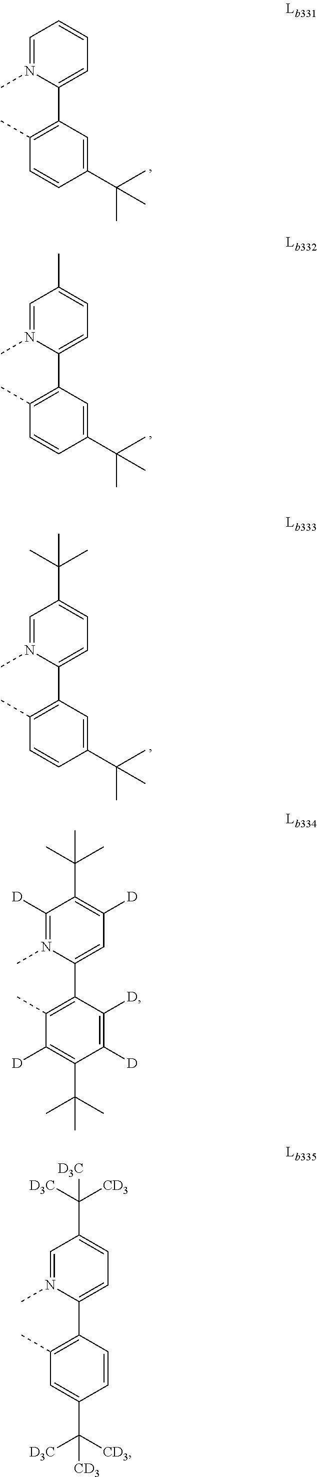

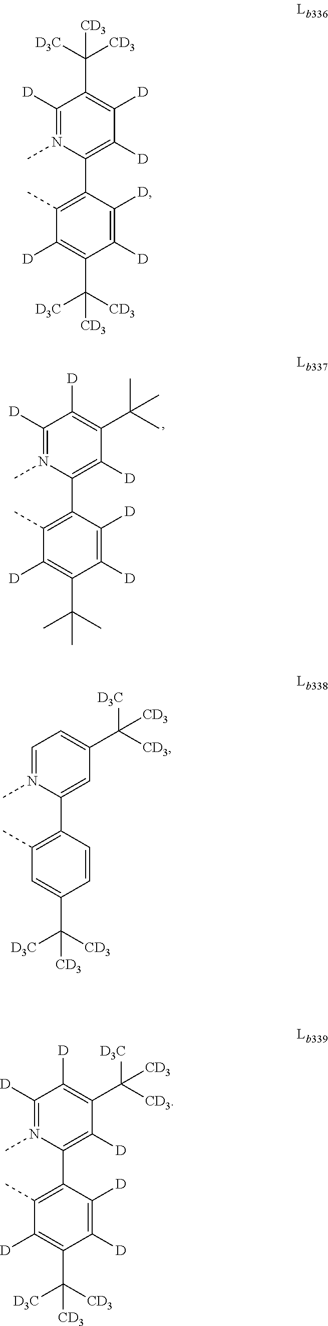

According to an embodiment of the present disclosure, hydrogen atoms in L_{b1} to L_{b339} can be partially or fully substituted with deuterium.

According to an embodiment of the present disclosure, L_{c} is, at each occurrence identically or differently, selected from the group consisting of the following structures:

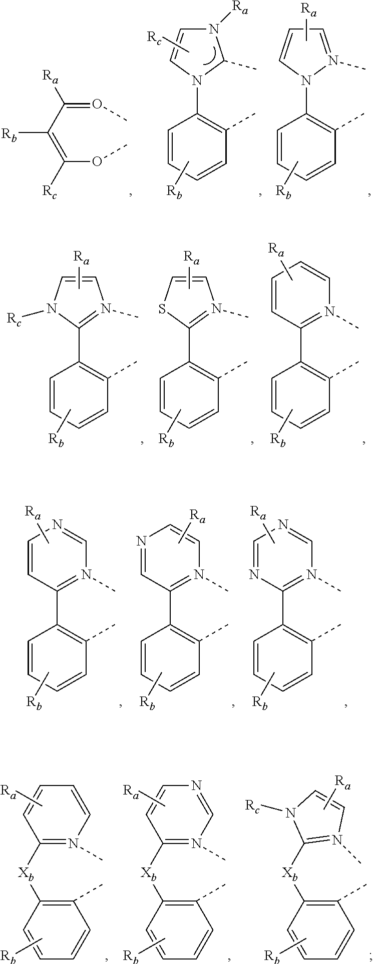

Rₐ, R_{b} and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{C1} and R_{C2} can be optionally joined to form a ring.

In this embodiment, the expression that adjacent substituents Rₐ, R_{b}, R_{c}, R_{N1}, R_{N2}, R_{C1} and R_{C2} can be optionally joined to form a ring is intended to mean that any one or more of groups of adjacent substituents in the structure of L_{c}, such as adjacent substituents Rₐ, adjacent substituents R_{b}, adjacent substituents R_{c}, adjacent substituents Rₐ and R_{b}, adjacent substituents R_{b} and R_{c}, adjacent substituents Rₐ and R_{c}, adjacent substituents Rₐ and R_{N1}, adjacent substituents Rₐ and R_{C1}, adjacent substituents Rₐ and R_{C2}, adjacent substituents R_{b} and R_{N1}, adjacent substituents R_{c} and R_{N1}, adjacent substituents R_{b} and R_{C1}, adjacent substituents R_{b} and R_{C2}, adjacent substituents R_{c} and R_{C1}, adjacent substituents R_{c} and R_{C2}, and adjacent substituents R_{C1} and R_{C2}, can be joined to form a ring. Obviously, it is also possible that none of these substituents are joined to form a ring. For example, adjacent substituents Rₐ and R_{b} in

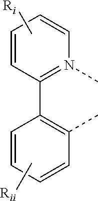

can be optionally joined to form a ring, which can form one or more of the following structures including, but not limited to,

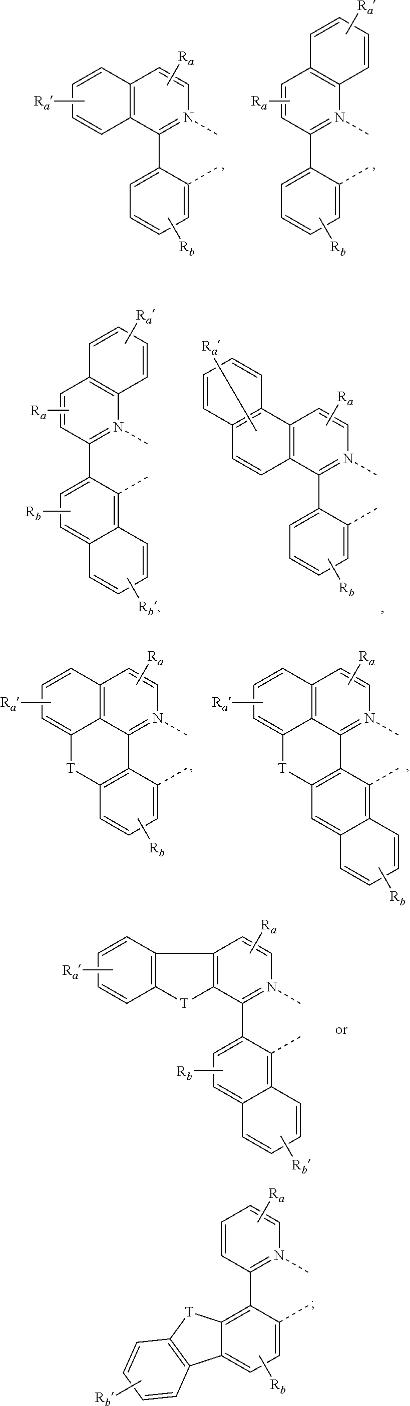

wherein T is selected from O, S, Se, NR′ or CR′R′, and R′, Rₐ′ and R_{b}′ are defined the same as Rₐ. Obviously, it is also possible that none of these substituents are joined to form a ring.

According to an embodiment of the present disclosure, the metal M is selected from Ir, Rh, Re, Os, Pt, Au or Cu.

According to an embodiment of the present disclosure, the metal M is selected from Ir, Pt or Os.

According to an embodiment of the present disclosure, the metal M is Ir.

According to an embodiment of the present disclosure, L_{c} is, at each occurrence identically or differently, selected from the group consisting of L_{c1} to L_{c329}:

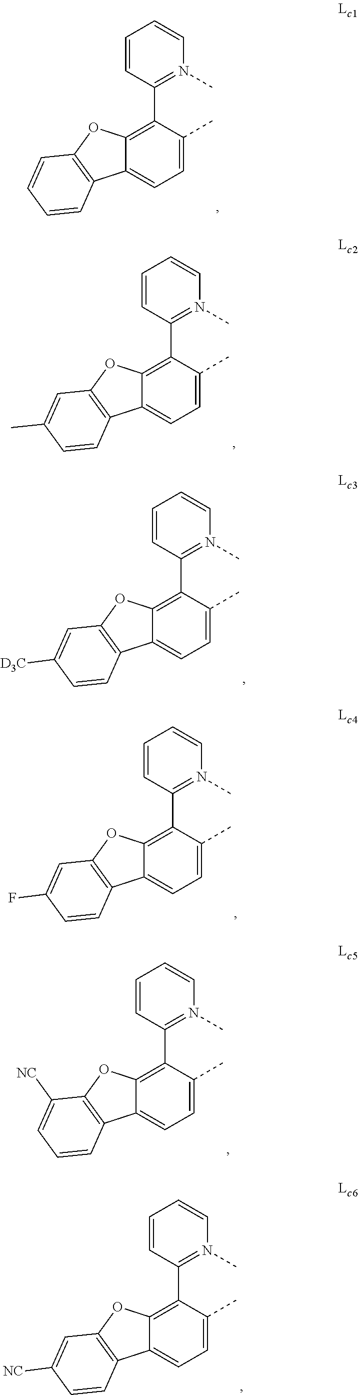

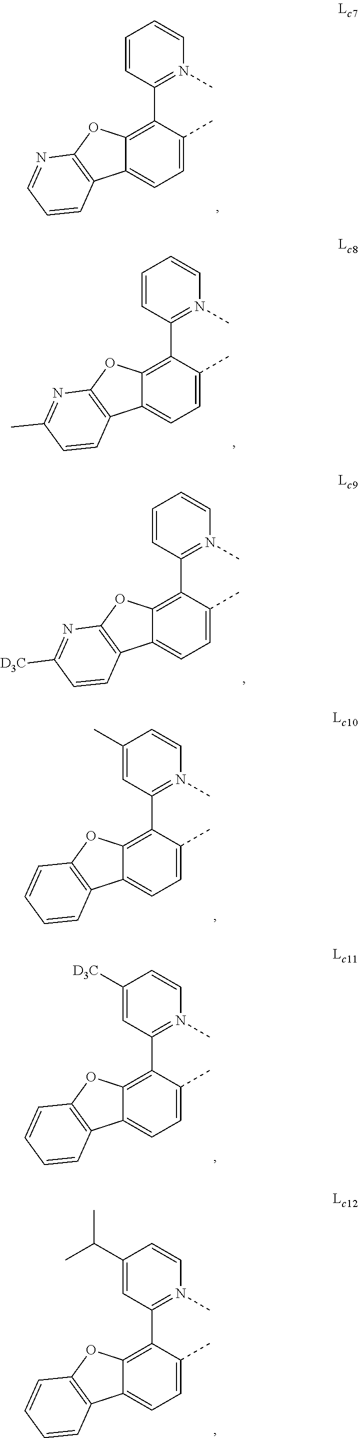

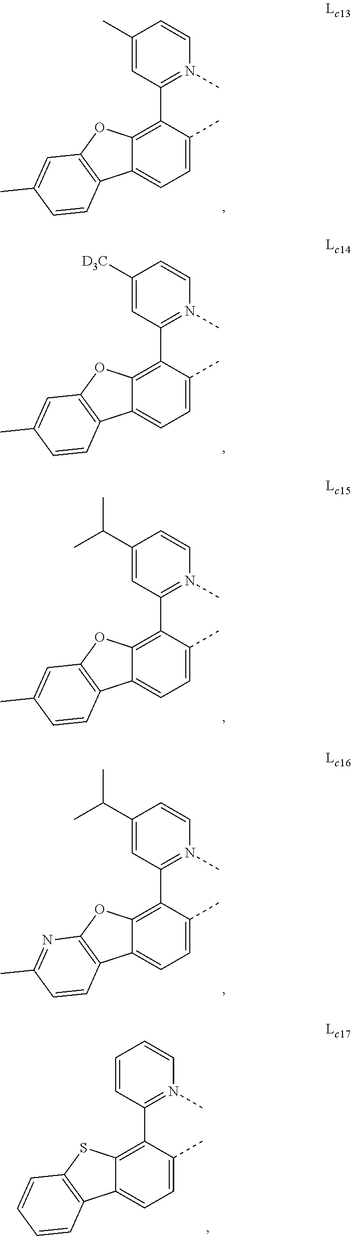

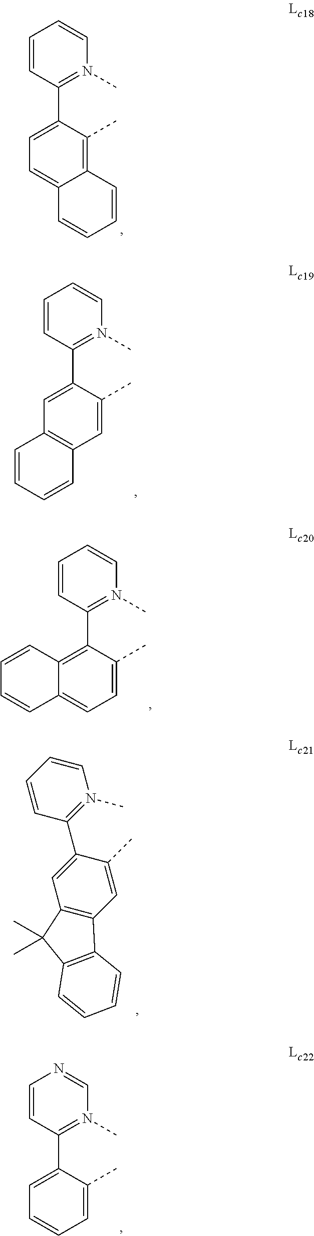

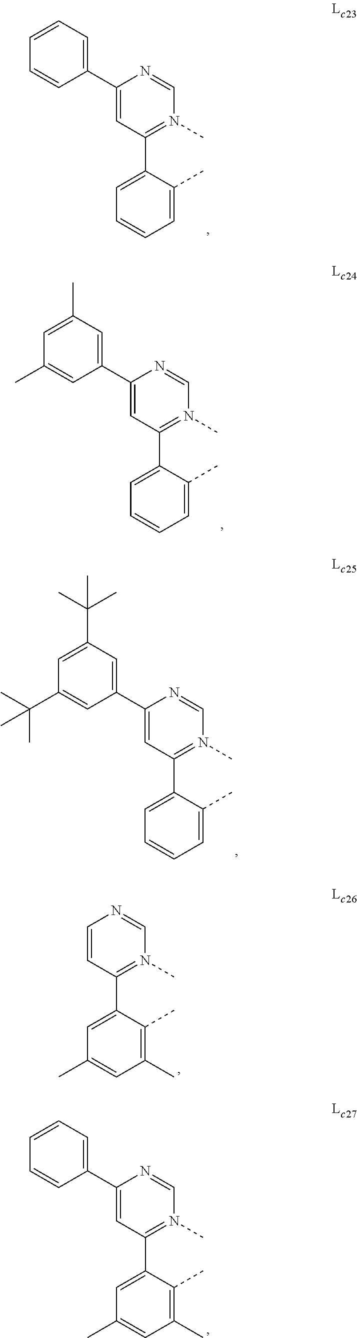

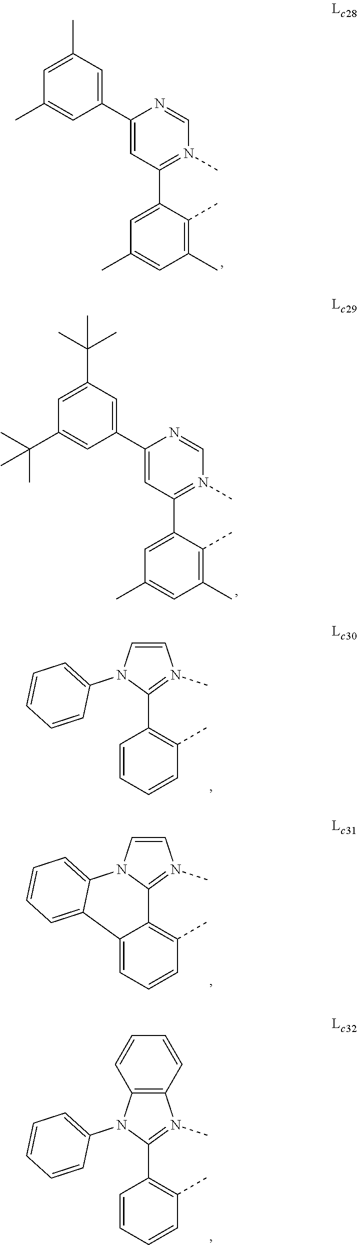

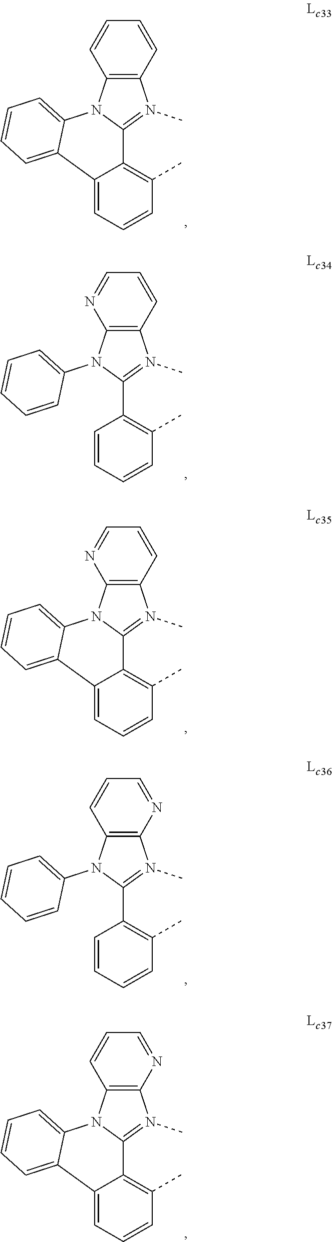

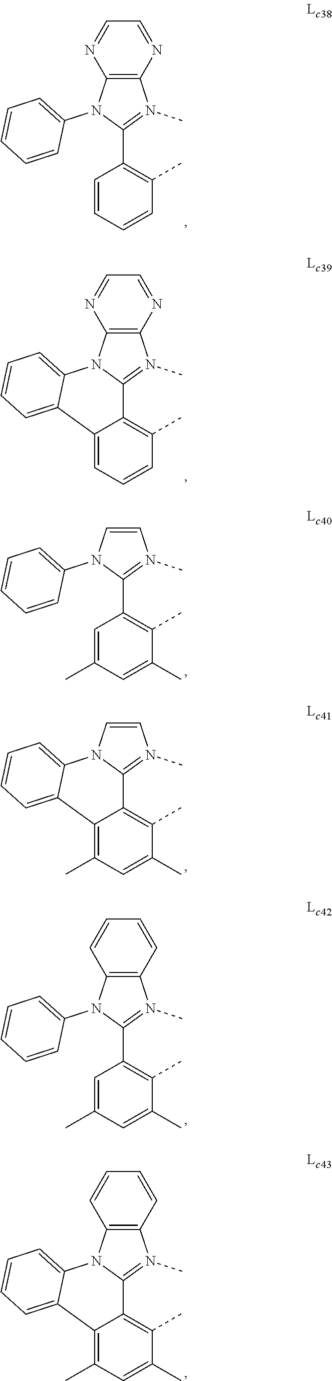

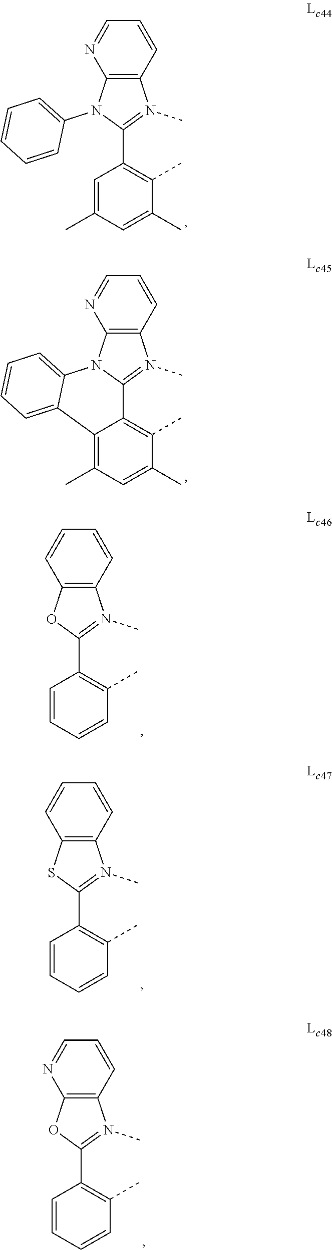

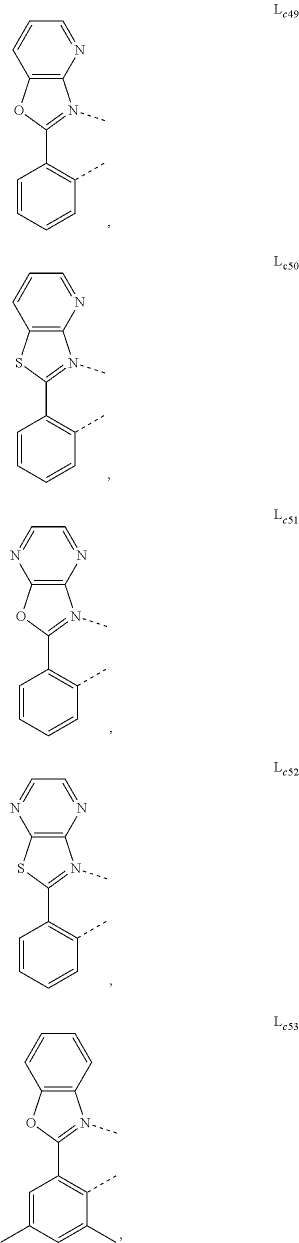

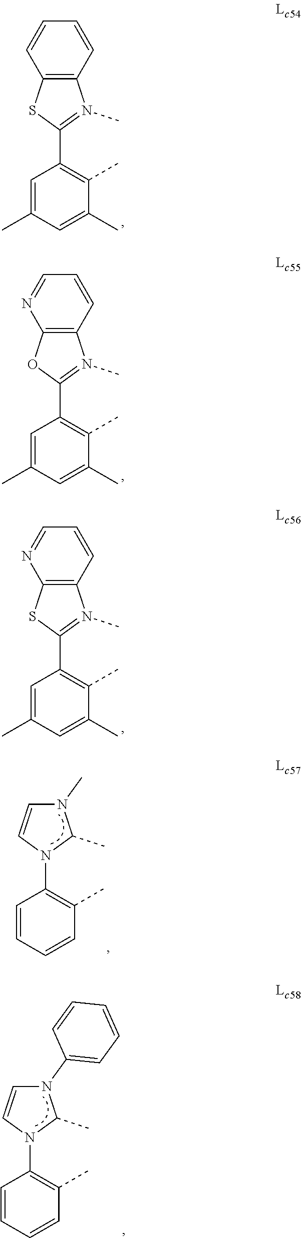

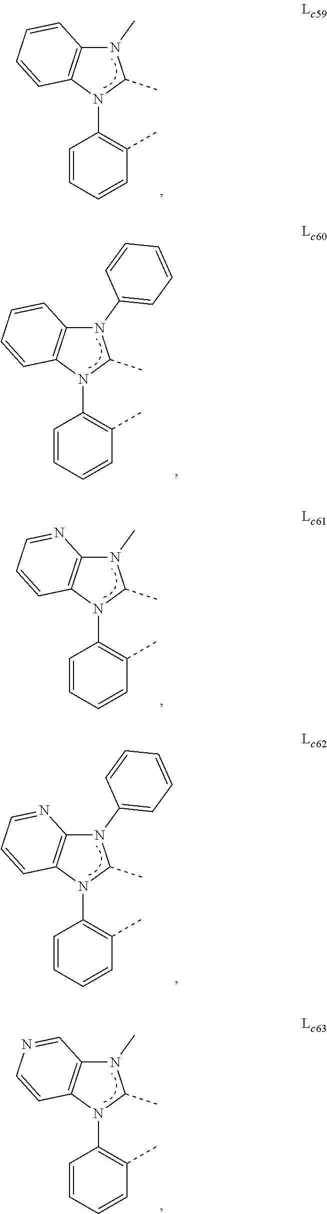

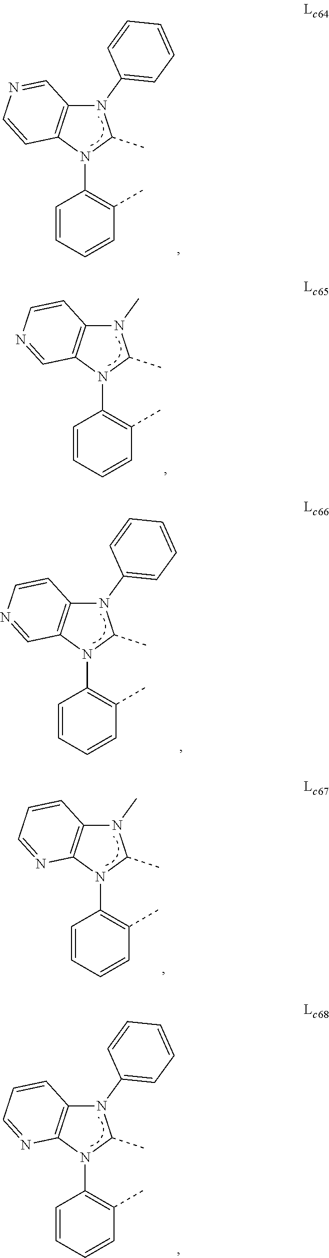

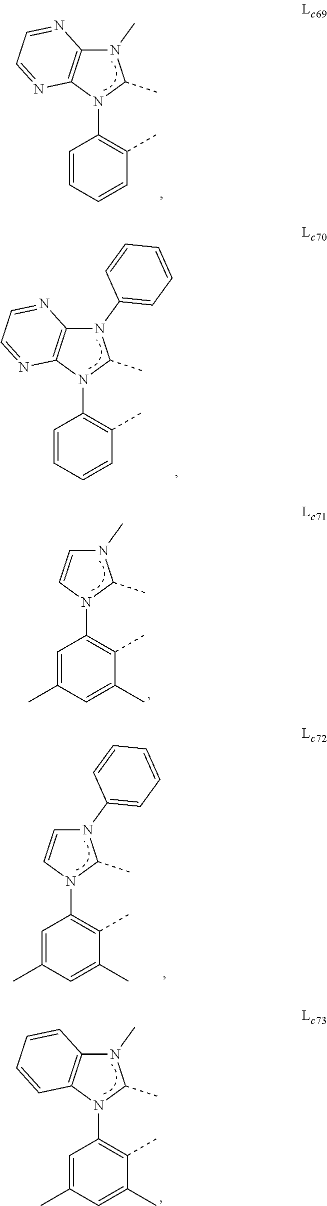

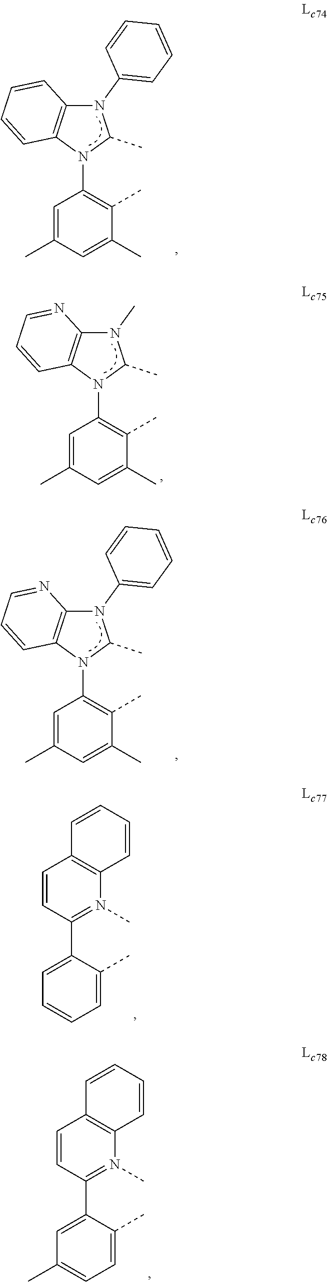

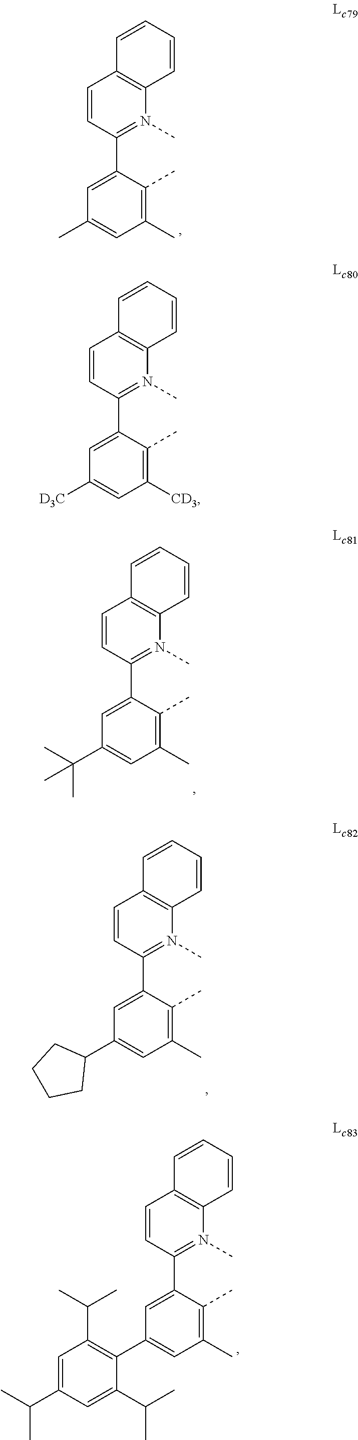

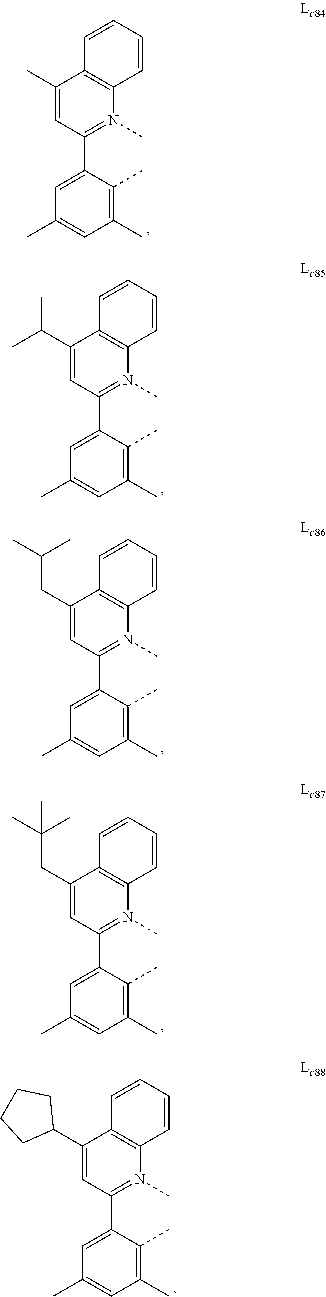

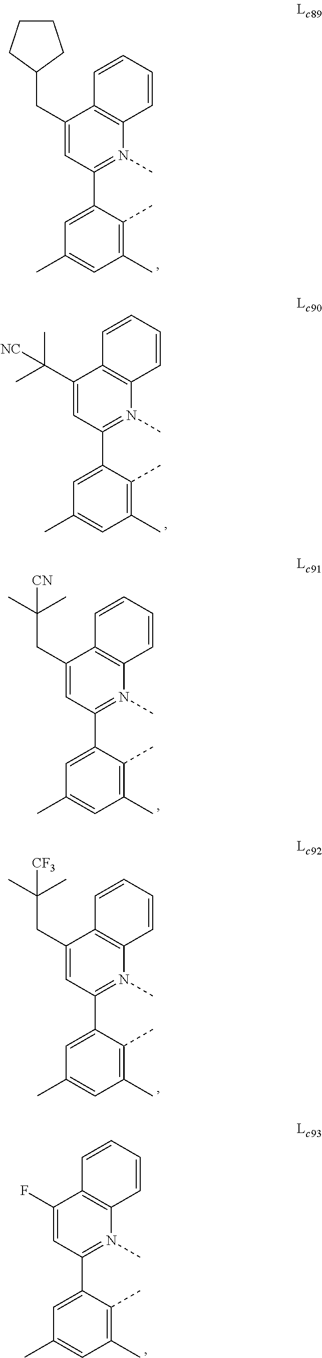

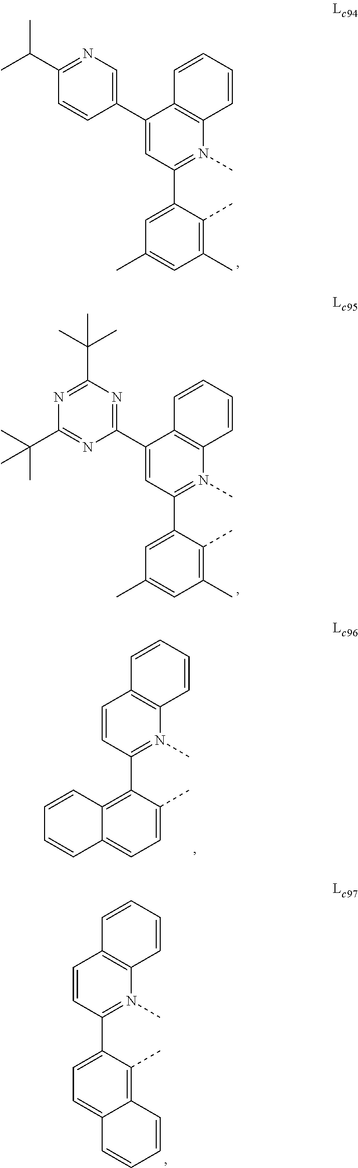

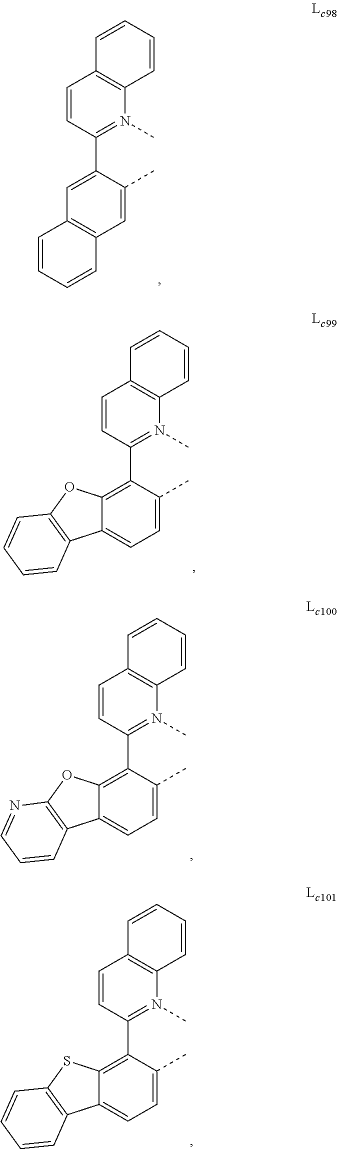

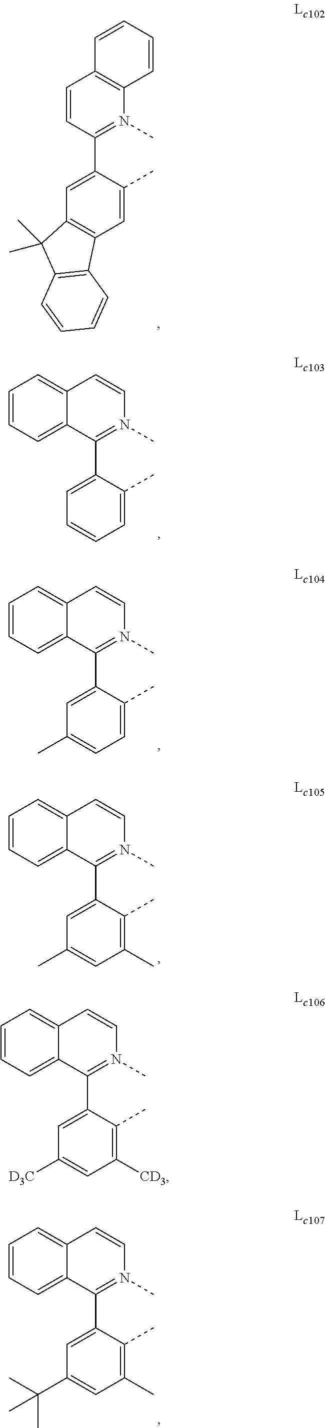

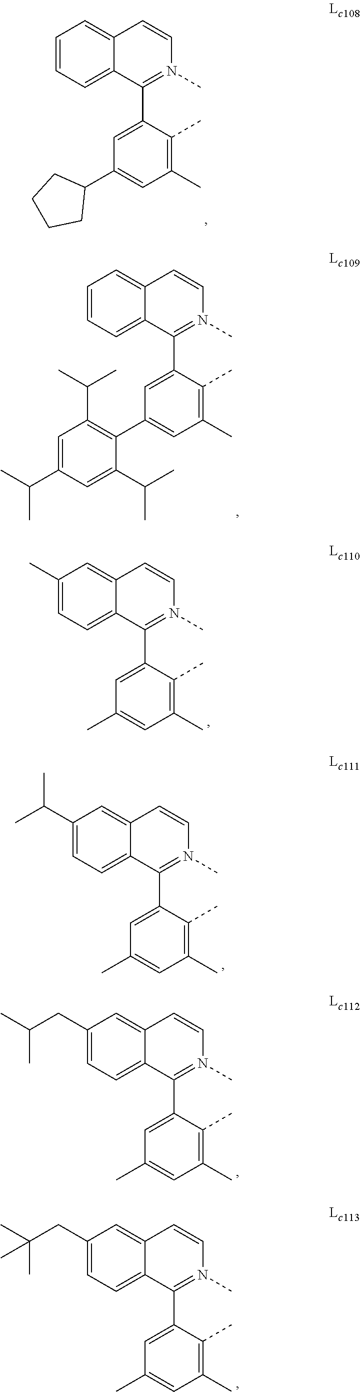

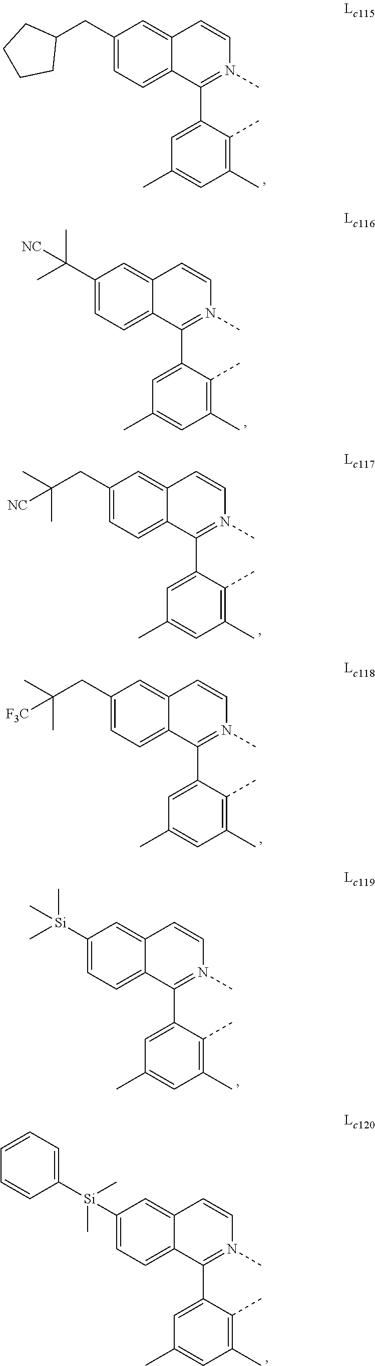

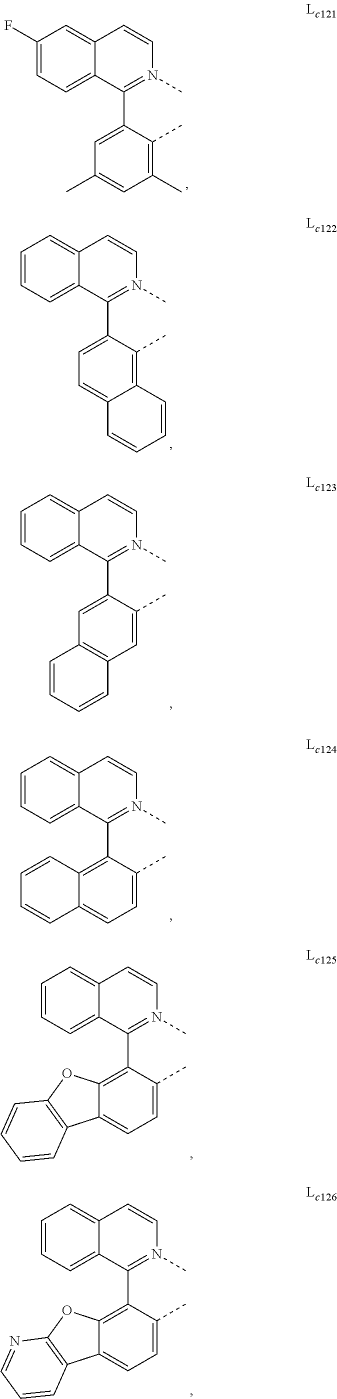

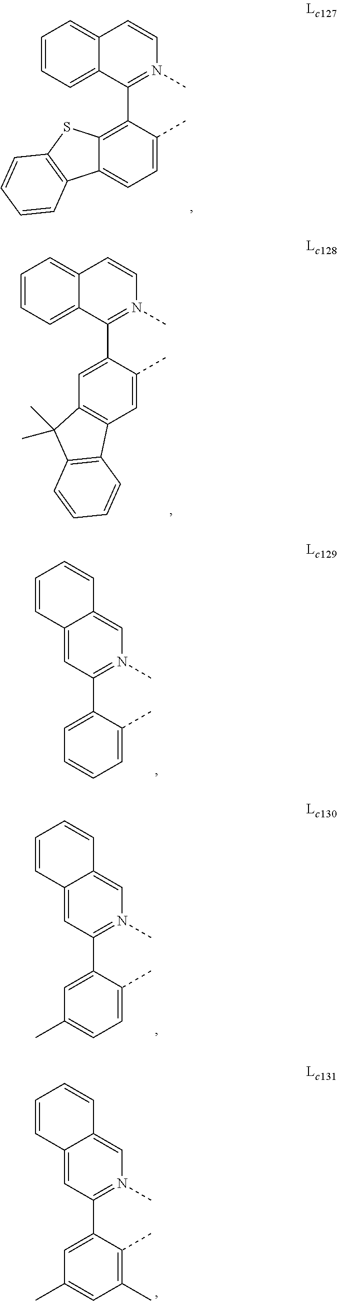

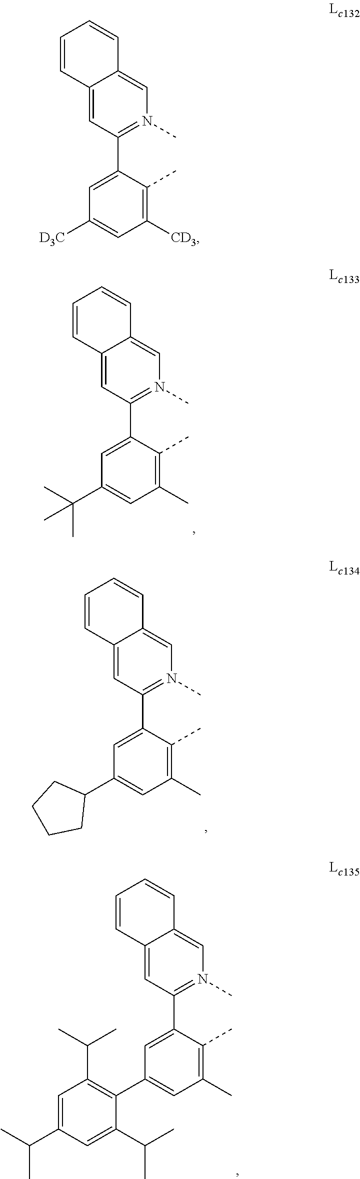

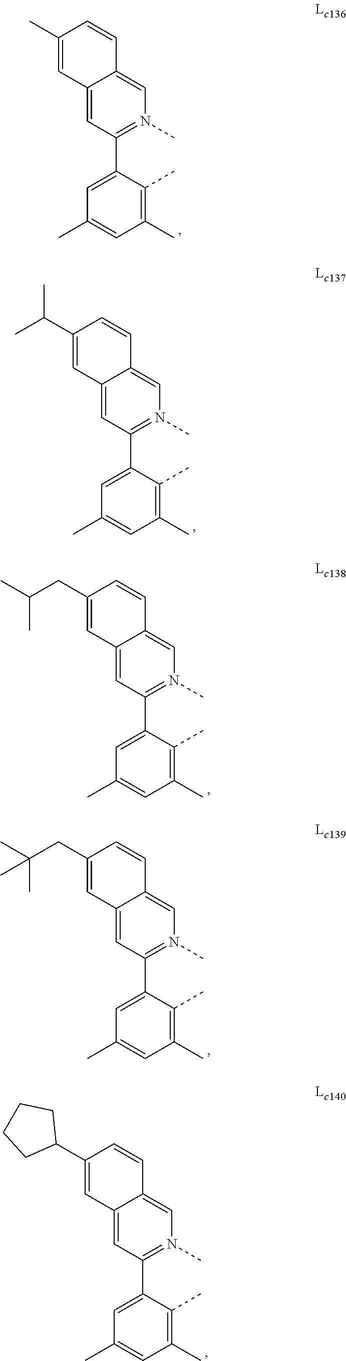

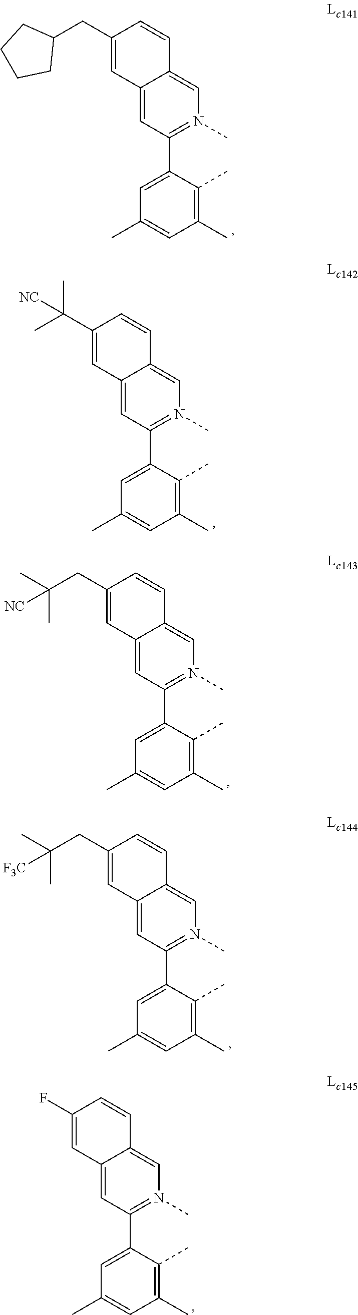

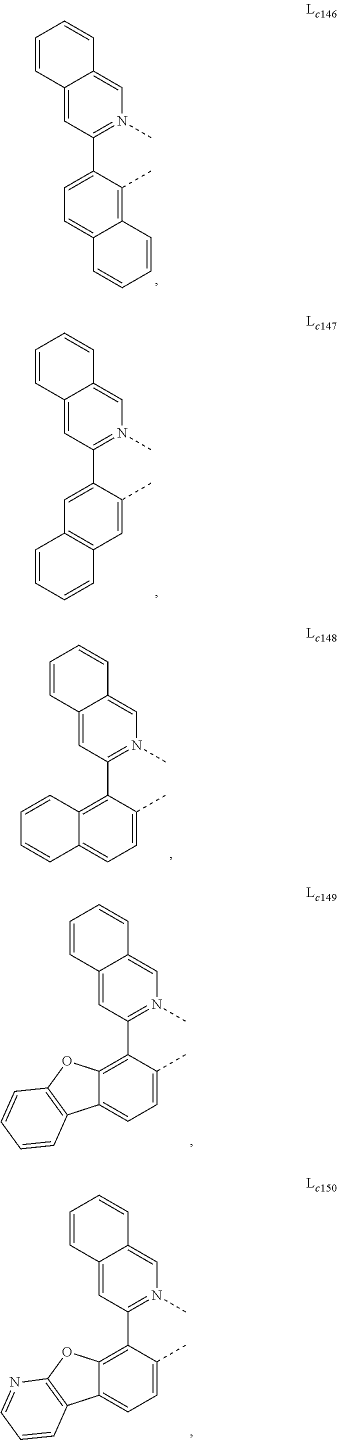

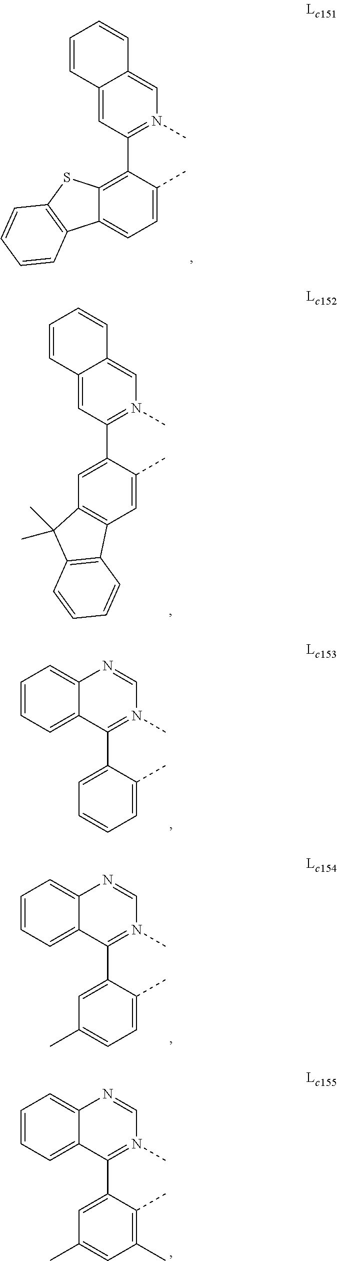

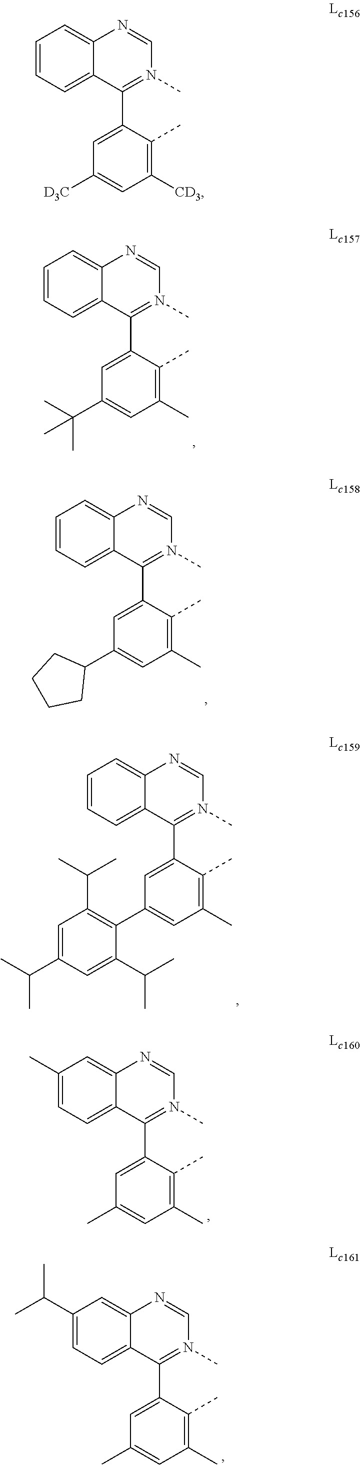

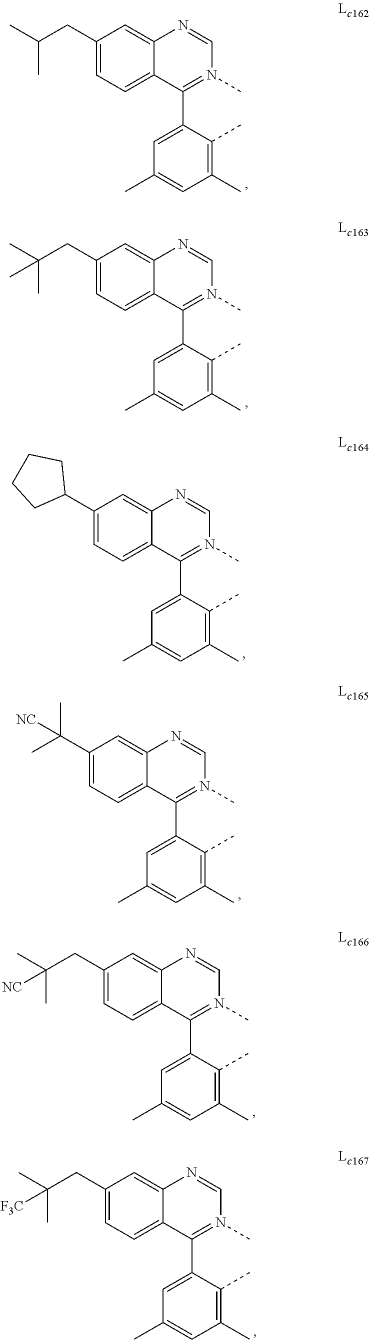

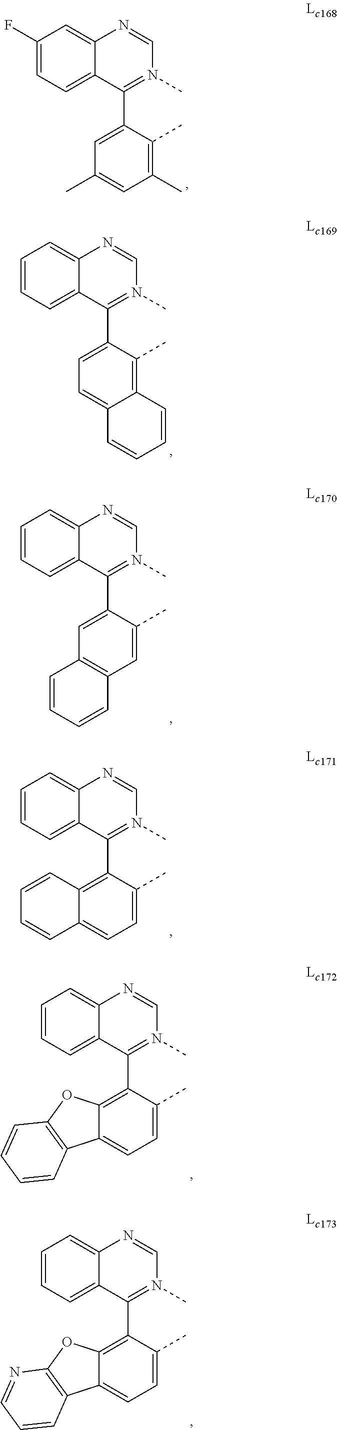

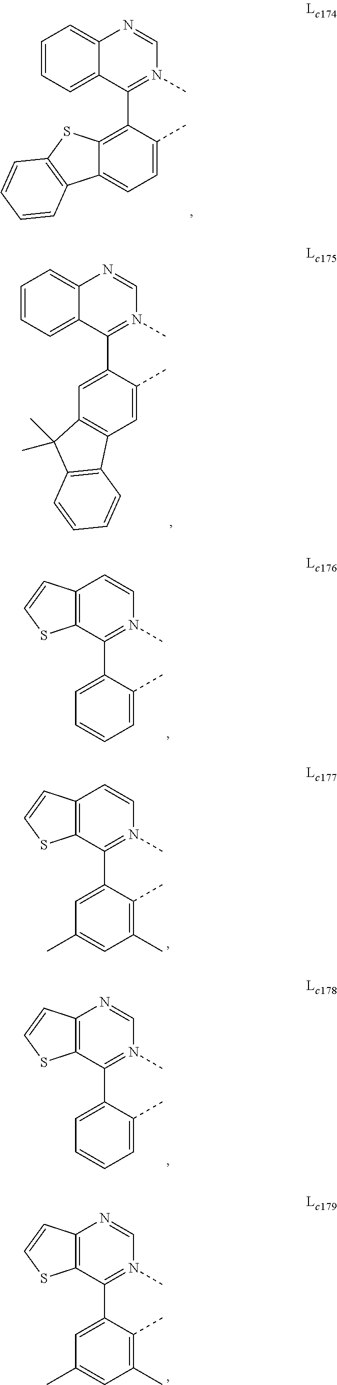

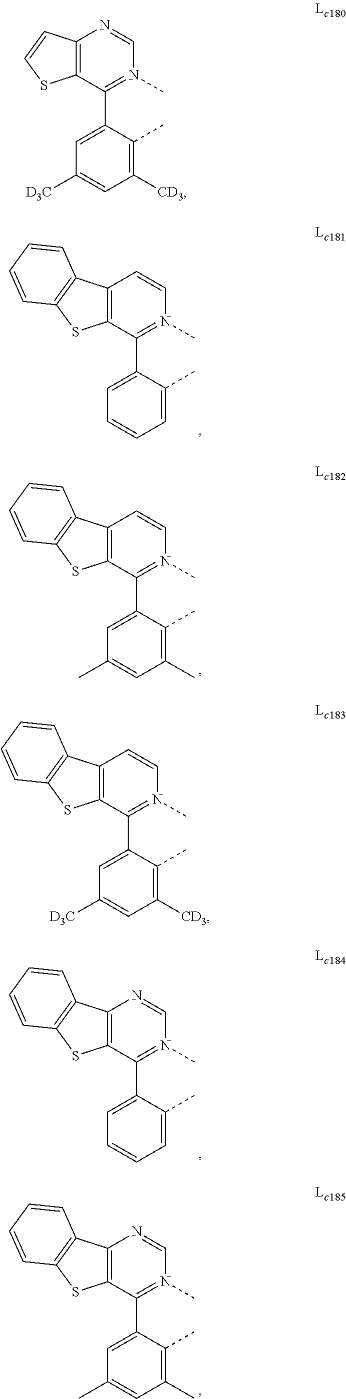

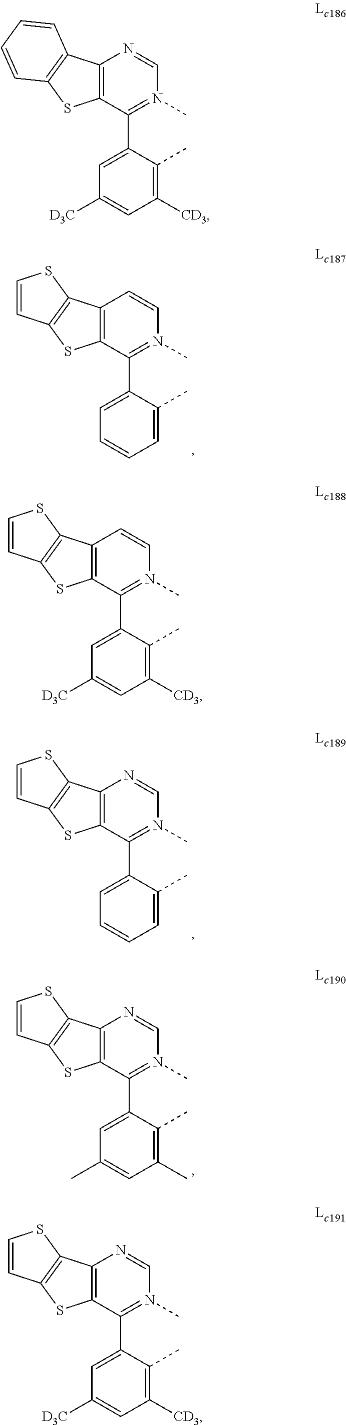

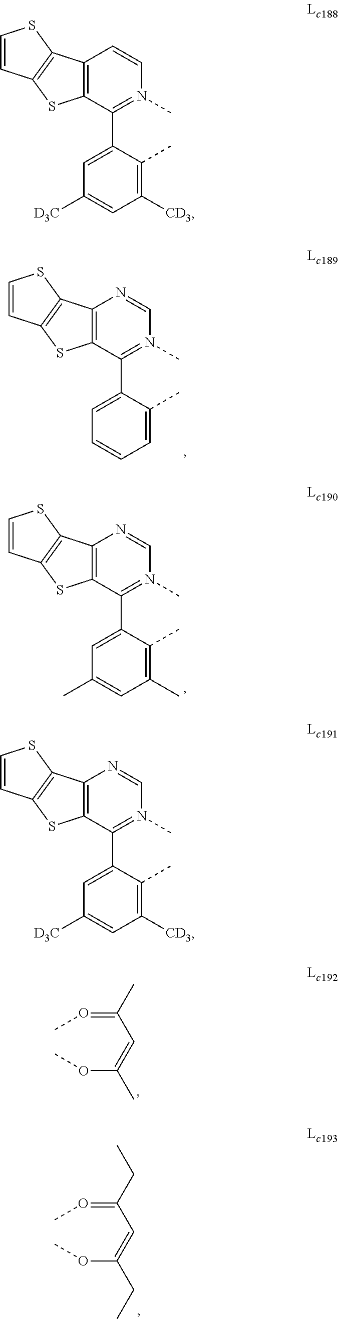

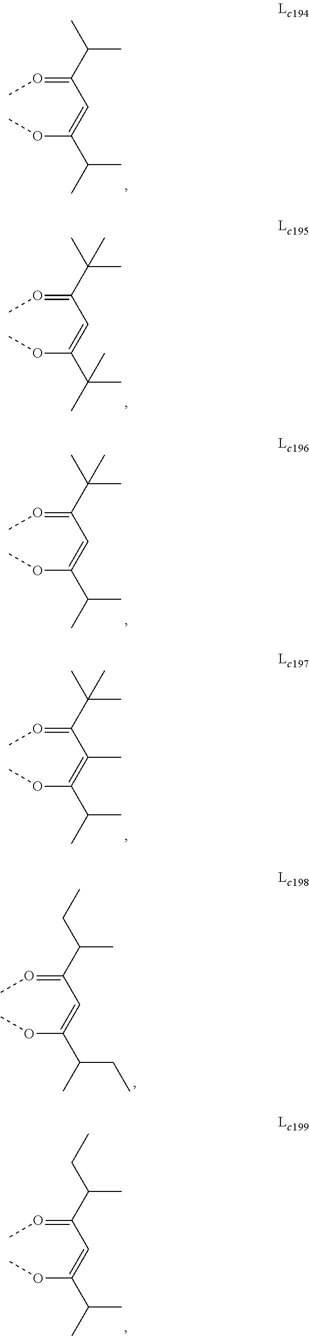

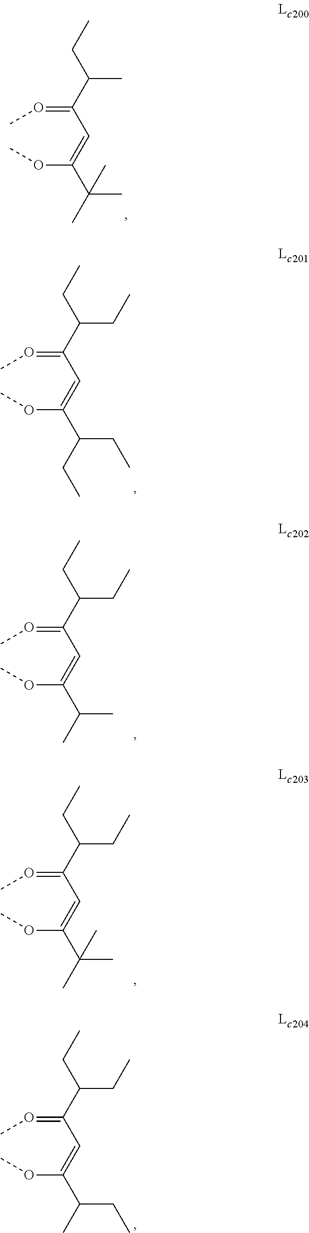

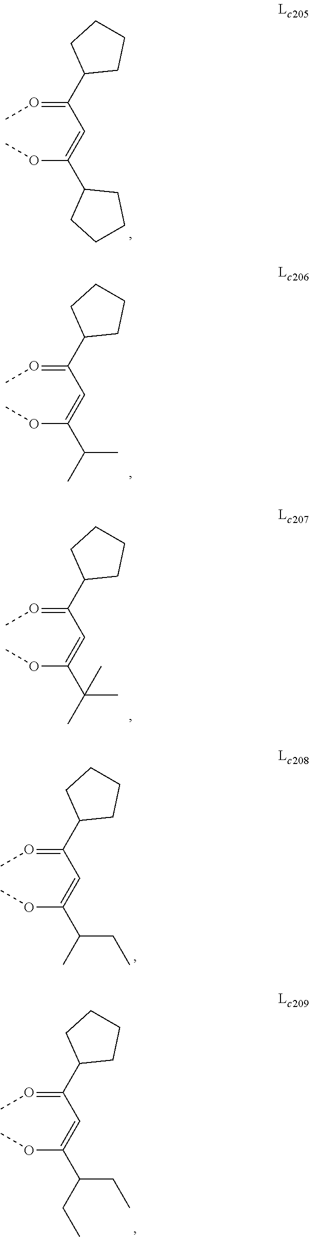

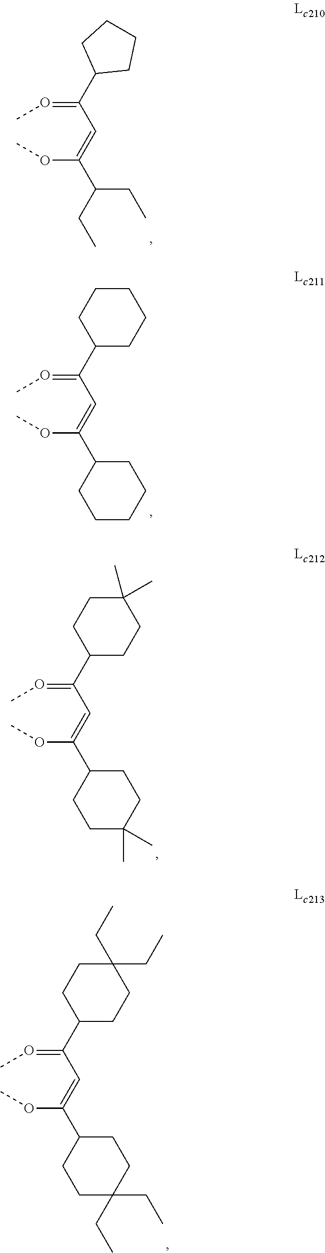

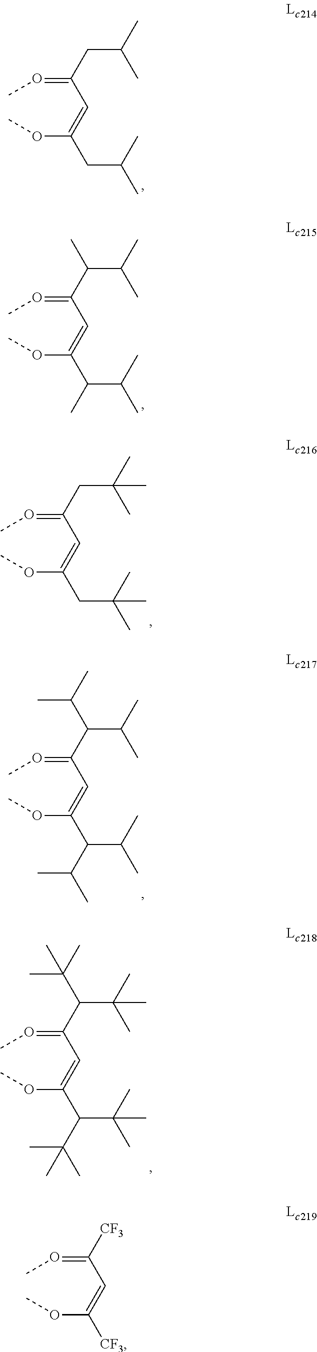

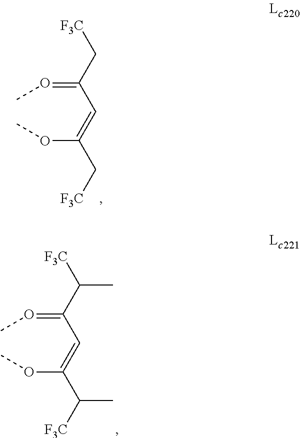

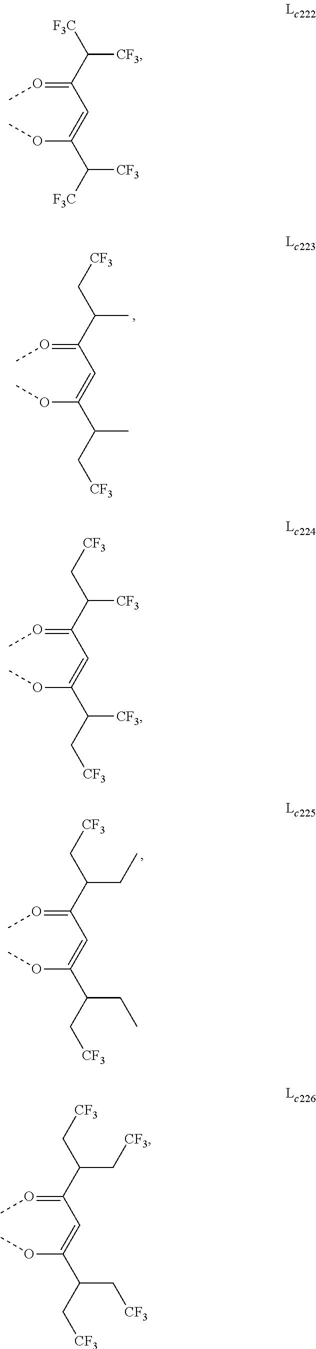

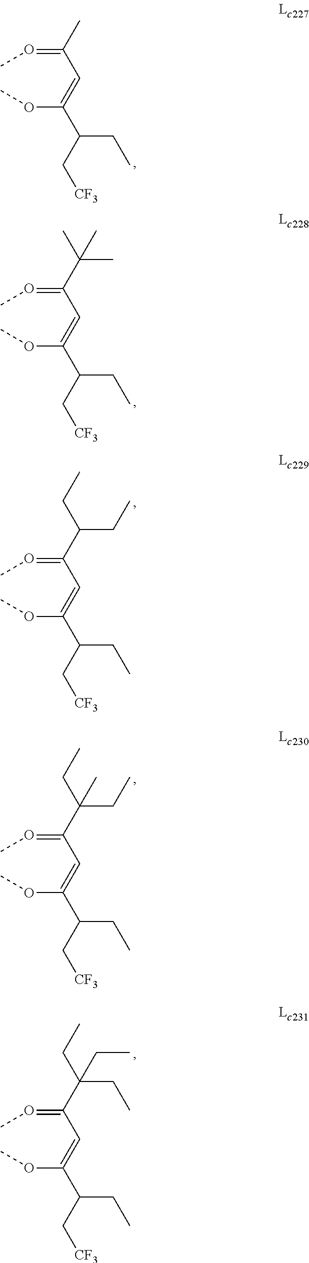

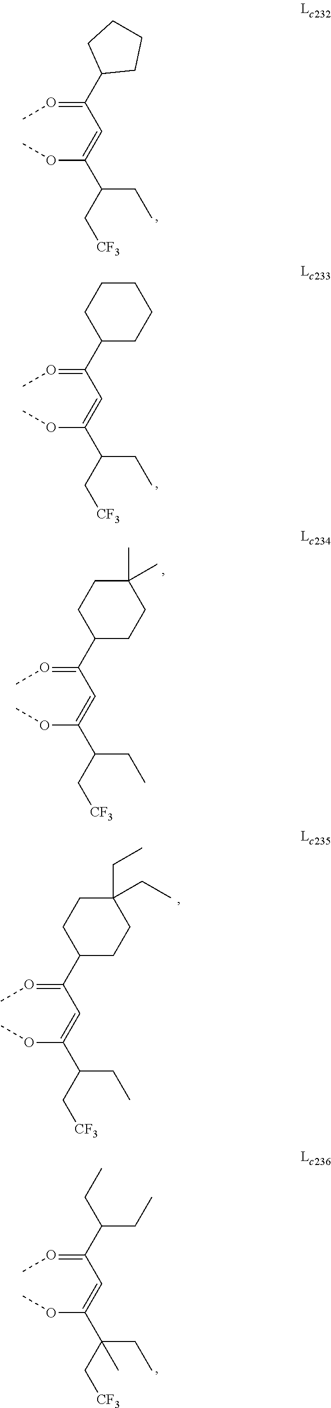

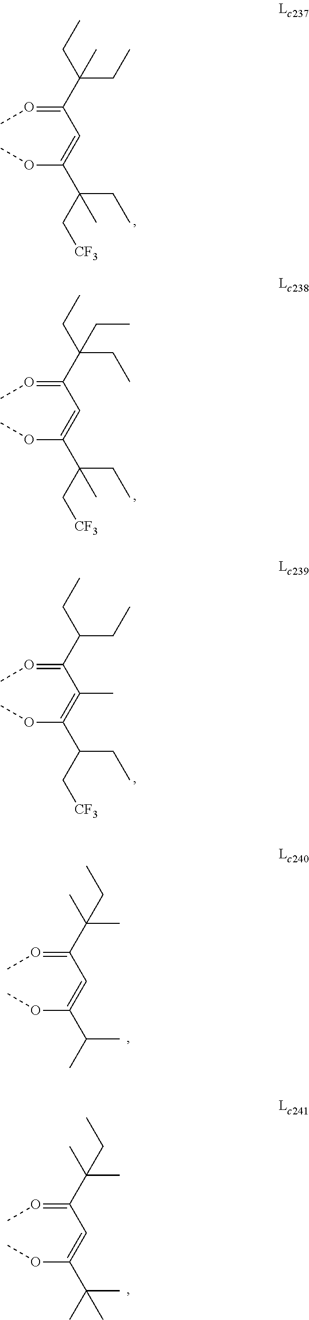

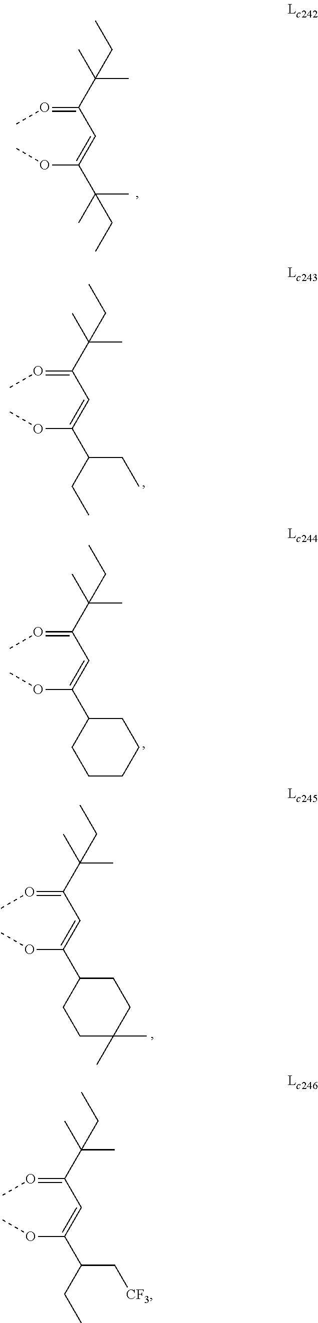

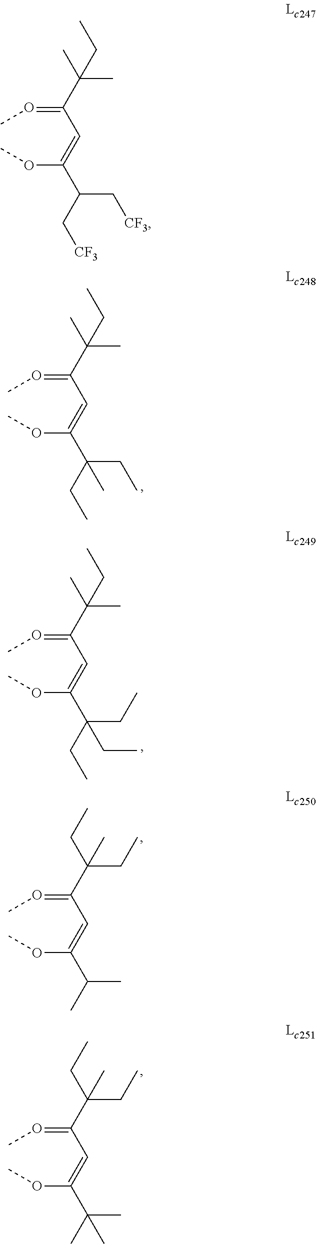

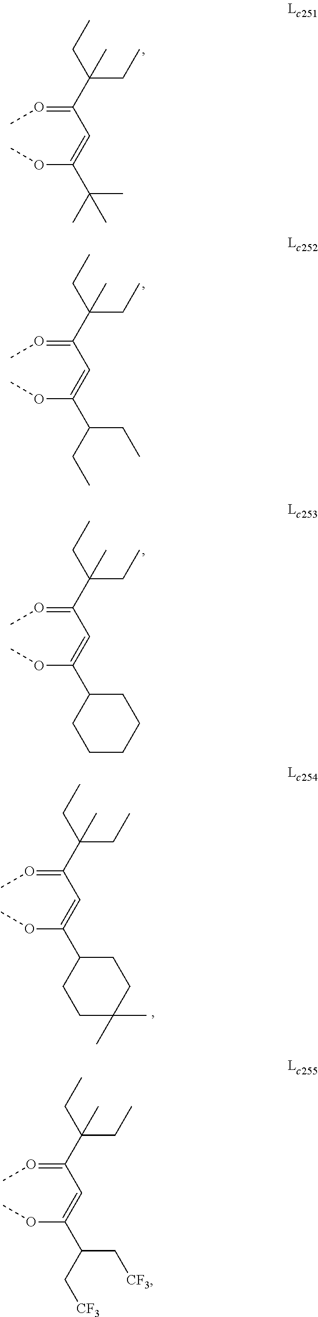

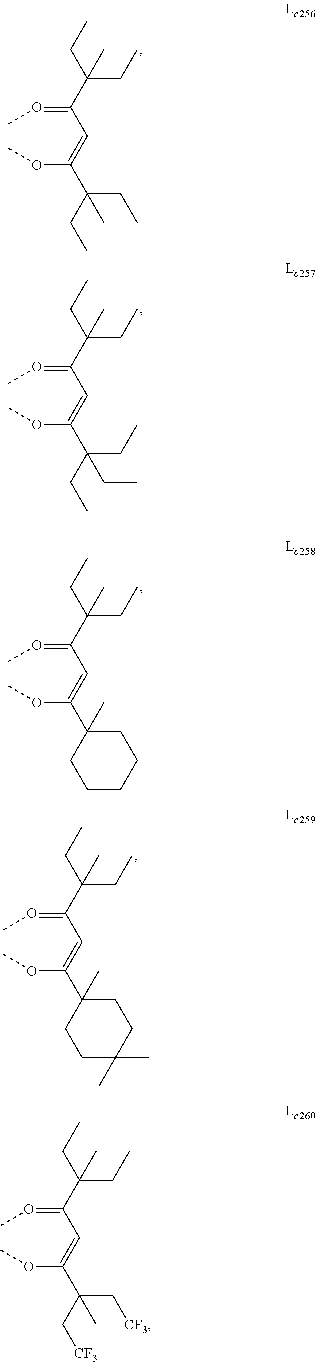

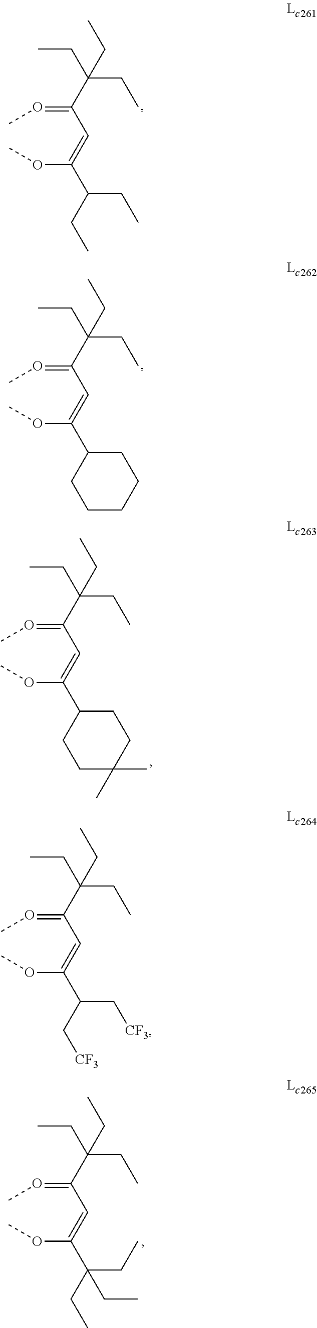

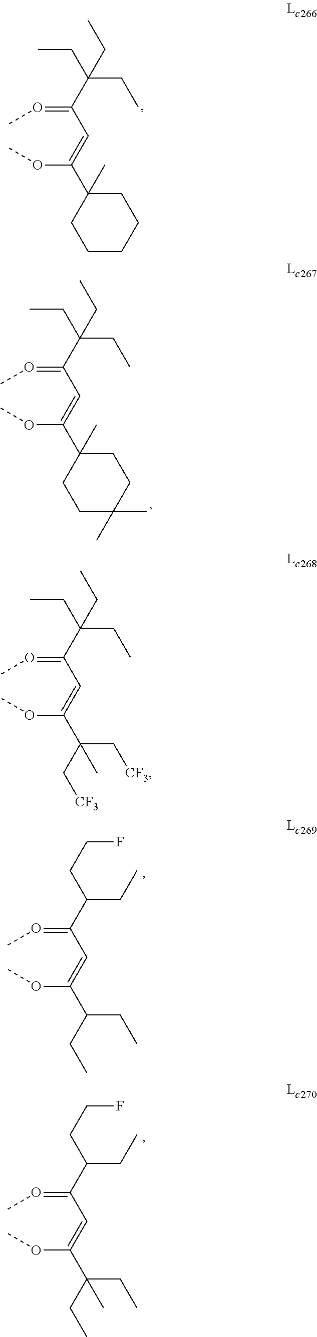

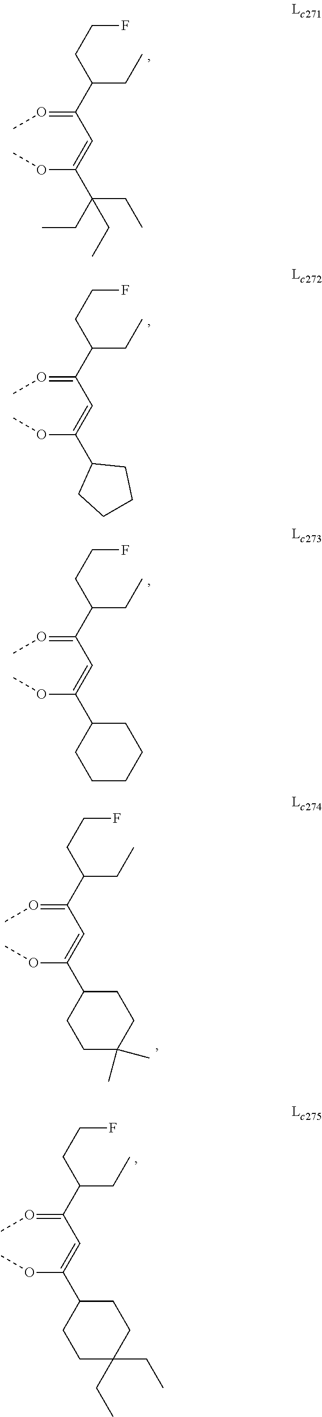

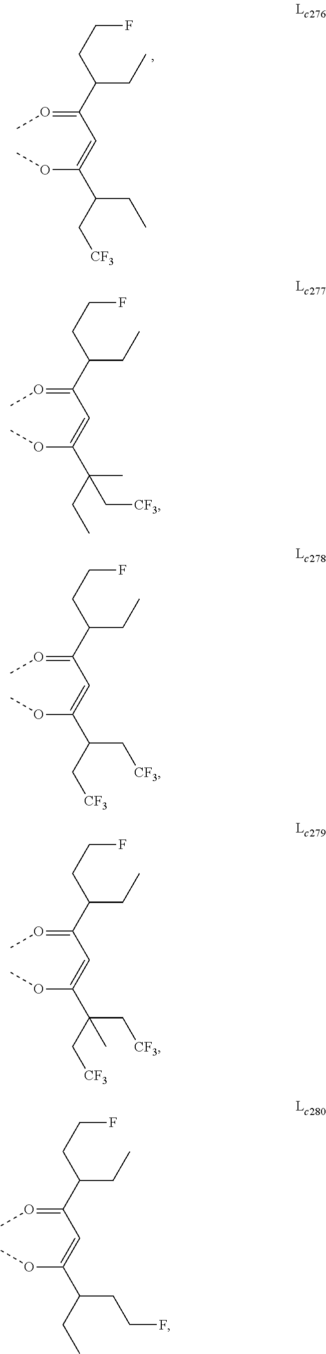

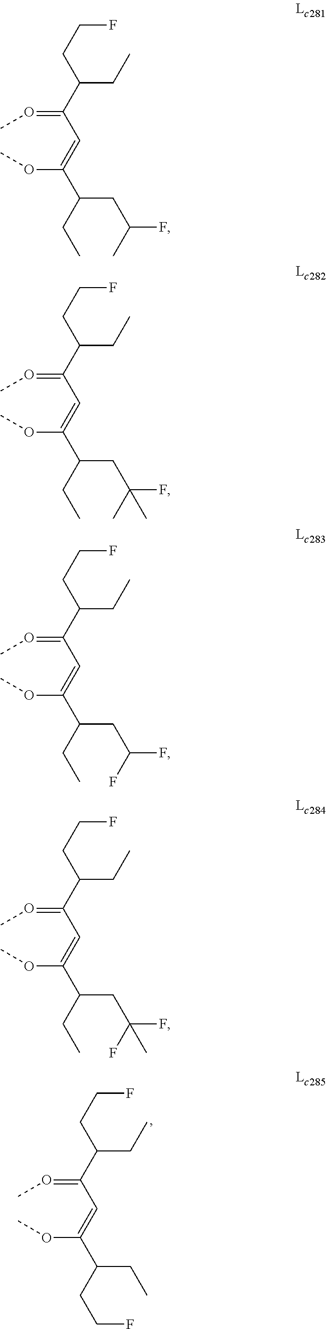

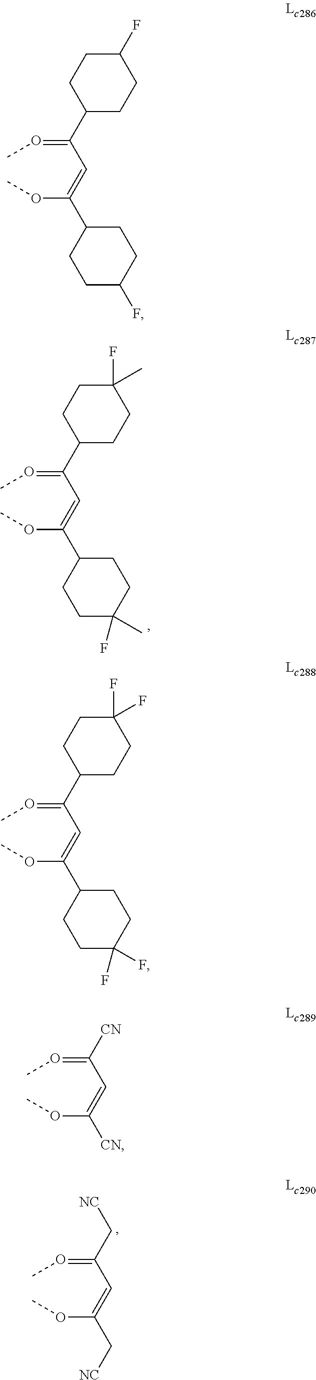

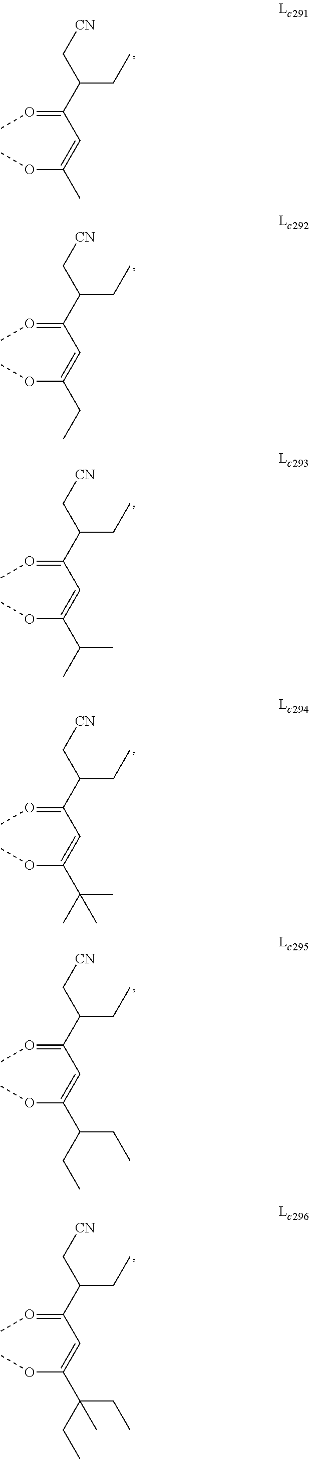

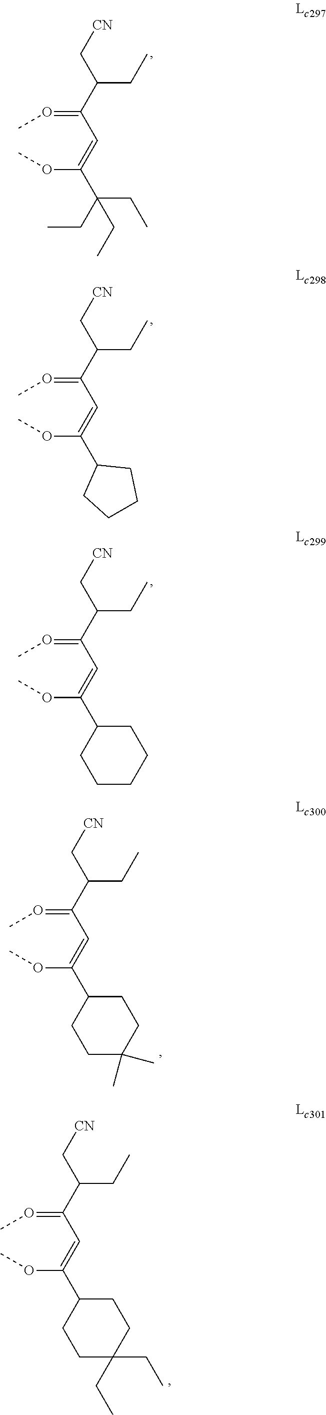

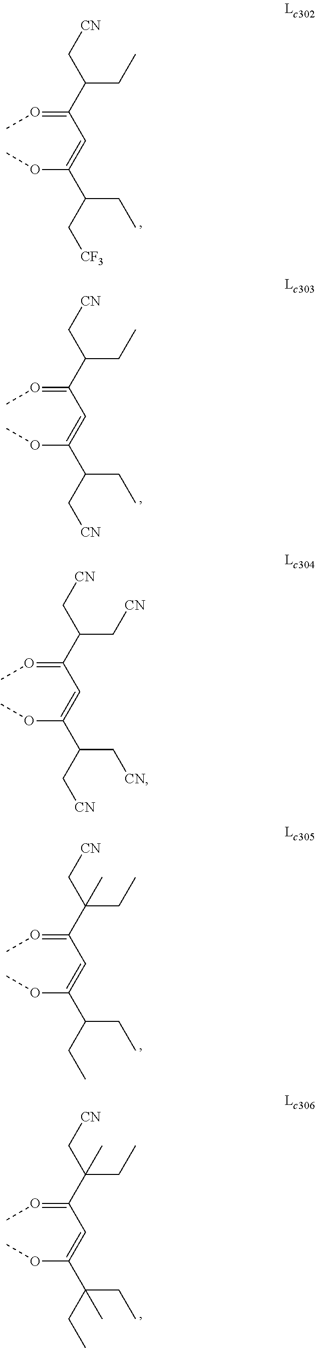

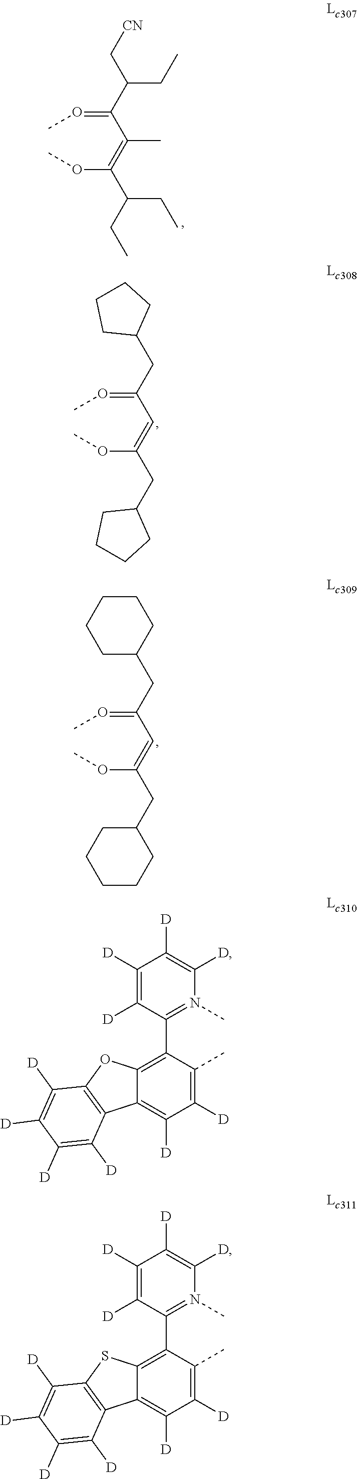

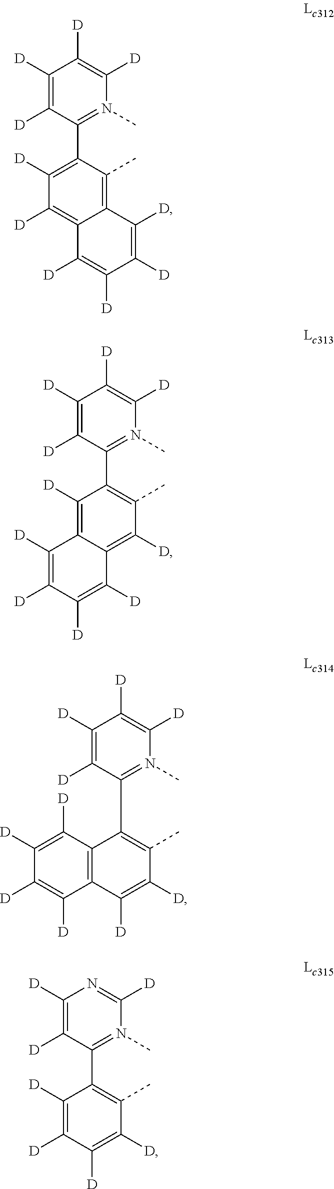

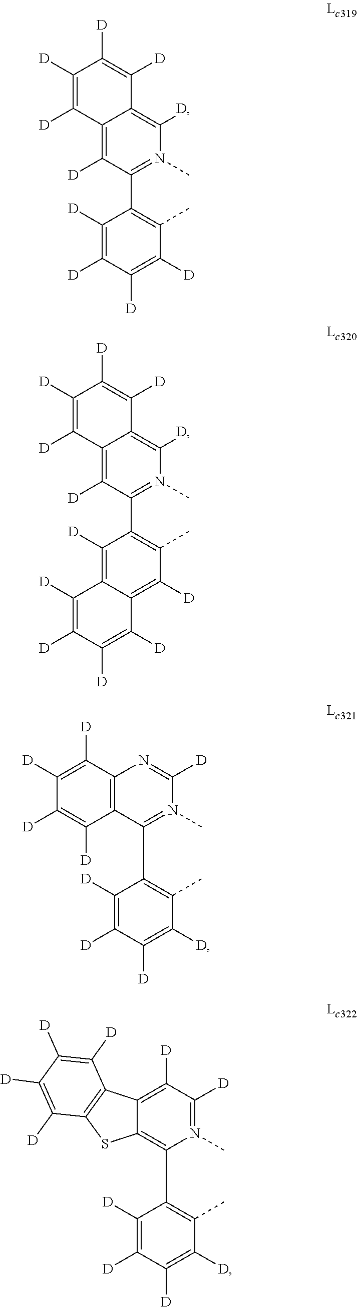

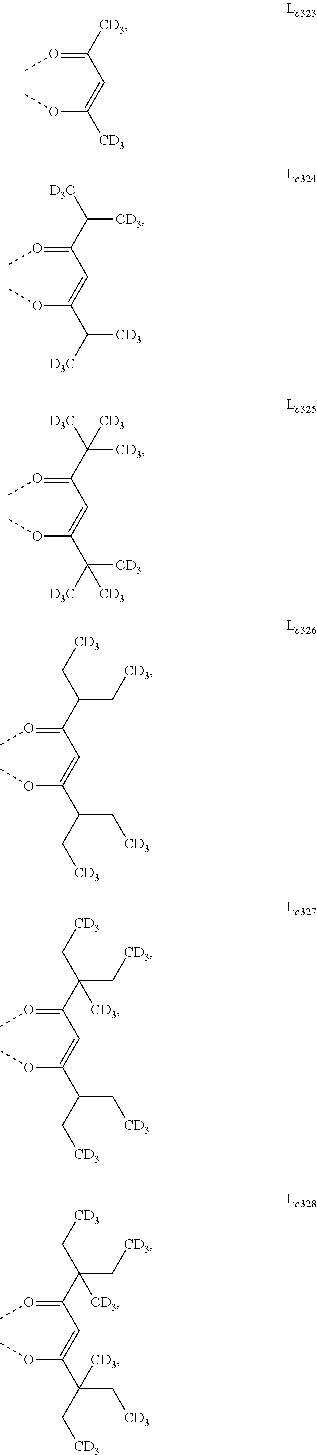

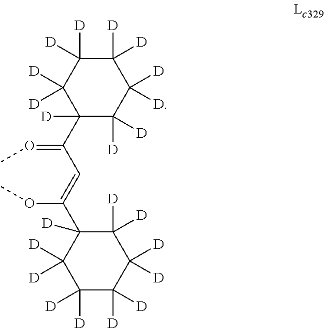

According to an embodiment of the present disclosure, the metal complex has a structure of Ir(Lₐ)(L_{b}) 2 or Ir(Lₐ)₂(L_{b}) or Ir(Lₐ)(L_{b})(L_{c});
when the metal complex has a structure of Ir(Lₐ)(L_{b}) 2, Lₐ is selected from any one of the group consisting of Lₐ₁ to Lₐ₅₉₅, and L_{b} is, at each occurrence identically or differently, selected from any one or any two of the group consisting of L_{b1} to L_{b339}; when the metal complex has a structure of Ir(Lₐ)₂(L_{b}), Lₐ is, at each occurrence identically or differently, selected from any one or any two of the group consisting of Lₐ₁ to Lₐ₅₉₅, and L_{b} is selected from any one of the group consisting of L_{b1} to L_{b339}; when the metal complex has a structure of Ir(Lₐ)(L_{b})(L_{c}), Lₐ is selected from any one of the group consisting of Lₐ₁ to Lₐ₅₉₅, L_{b} is selected from any one of the group consisting of L_{b1} to L_{b339}, and L_{c} is selected from any one of the group consisting of L_{c1} to L_{c329}.

According to an embodiment of the present disclosure, the metal complex is selected from the group consisting of Compound 1 to Compound 608;
wherein Compound 1 to Compound 400 each have a structure of Ir(Lₐ)(L_{b})₂, wherein the two L_{b} are the same, and Lₐ and L_{b} are selected from the structures listed in the following table, respectively:

| Compound | | | Compound | | |
|---|---|---|---|---|---|
| No. | Lₐ | L_{b} | No. | Lₐ | L_{b} |
| 1 | Lₐ₂₇₁ | L_{b2} | 2 | Lₐ₂₇₁ | L_{b3} |
| 3 | Lₐ₂₅₃ | L_{b2} | 4 | Lₐ₂₅₃ | L_{b3} |
| 5 | Lₐ₁₂₉ | L_{b2} | 6 | Lₐ₁₂₉ | L_{b3} |
| 7 | Lₐ₁₆₈ | L_{b2} | 8 | Lₐ₁₆₈ | L_{b3} |
| 9 | Lₐ₃₇ | L_{b2} | 10 | Lₐ₃₇ | L_{b3} |
| 11 | Lₐ₃₁ | L_{b2} | 12 | Lₐ₃₁ | L_{b3} |
| 13 | Lₐ₃₂₈ | L_{b2} | 14 | Lₐ₃₂₈ | L_{b3} |
| 15 | Lₐ₅₂₂ | L_{b2} | 16 | Lₐ₅₂₂ | L_{b3} |
| 17 | Lₐ₂₆₈ | L_{b2} | 18 | Lₐ₂₆₈ | L_{b3} |
| 19 | Lₐ₂₈₇ | L_{b2} | 20 | Lₐ₂₈₇ | L_{b3} |
| 21 | Lₐ₇ | L_{b2} | 22 | Lₐ₇ | L_{b3} |
| 23 | Lₐ₂₁ | L_{b2} | 24 | Lₐ₂₁ | L_{b3} |
| 25 | Lₐ₃₄ | L_{b2} | 26 | Lₐ₃₄ | L_{b3} |
| 27 | Lₐ₄₇ | L_{b2} | 28 | Lₐ₄₇ | L_{b3} |
| 29 | Lₐ₆₅ | L_{b2} | 30 | Lₐ₆₅ | L_{b3} |
| 31 | Lₐ₇₃ | L_{b2} | 32 | Lₐ₇₃ | L_{b3} |
| 33 | Lₐ₁₀₁ | L_{b2} | 34 | Lₐ₁₀₁ | L_{b3} |
| 35 | Lₐ₁₁₃ | L_{b2} | 36 | Lₐ₁₁₃ | L_{b3} |
| 37 | Lₐ₁₂₁ | L_{b2} | 38 | Lₐ₁₂₁ | L_{b3} |
| 39 | Lₐ₁₂₀ | L_{b2} | 40 | Lₐ₁₂₀ | L_{b3} |
| 41 | Lₐ₁₃₄ | L_{b2} | 42 | Lₐ₁₃₄ | L_{b3} |
| 43 | Lₐ₁₄₉ | L_{b2} | 44 | Lₐ₁₄₉ | L_{b3} |
| 45 | Lₐ₁₅₇ | L_{b2} | 46 | Lₐ₁₅₇ | L_{b3} |
| 47 | Lₐ₁₈₀ | L_{b2} | 48 | Lₐ₁₈₀ | L_{b3} |
| 49 | Lₐ₁₉₂ | L_{b2} | 50 | Lₐ₁₉₂ | L_{b3} |
| 51 | Lₐ₂₀₀ | L_{b2} | 52 | Lₐ₂₀₀ | L_{b3} |
| 53 | Lₐ₂₁₃ | L_{b2} | 54 | Lₐ₂₁₃ | L_{b3} |
| 55 | Lₐ₂₃₀ | L_{b2} | 56 | Lₐ₂₃₀ | L_{b3} |
| 57 | Lₐ₂₃₈ | L_{b2} | 58 | Lₐ₂₃₈ | L_{b3} |
| 59 | Lₐ₂₉₇ | L_{b2} | 60 | Lₐ₂₉₇ | L_{b3} |
| 61 | Lₐ₃₀₂ | L_{b2} | 62 | Lₐ₃₀₂ | L_{b3} |
| 63 | Lₐ₃₅₄ | L_{b2} | 64 | Lₐ₃₅₄ | L_{b3} |
| 65 | Lₐ₃₅₅ | L_{b2} | 66 | Lₐ₃₅₅ | L_{b3} |
| 67 | Lₐ₃₆₈ | L_{b2} | 68 | Lₐ₃₆₈ | L_{b3} |
| 69 | Lₐ₄₀₉ | L_{b2} | 70 | Lₐ₄₀₉ | L_{b3} |
| 71 | Lₐ₄₁₇ | L_{b2} | 72 | Lₐ₄₁₇ | L_{b3} |
| 73 | Lₐ₄₂₇ | L_{b2} | 74 | Lₐ₄₂₇ | L_{b3} |
| 75 | Lₐ₄₃₃ | L_{b2} | 76 | Lₐ₄₃₃ | L_{b3} |
| 77 | Lₐ₄₄₈ | L_{b2} | 78 | Lₐ₄₄₈ | L_{b3} |
| 79 | Lₐ₅₃₈ | L_{b2} | 80 | Lₐ₅₃₈ | L_{b3} |
| 81 | Lₐ₂₇₁ | L_{b1} | 82 | Lₐ₂₇₁ | L_{b81} |
| 83 | Lₐ₂₅₃ | L_{b1} | 84 | Lₐ₂₅₃ | L_{b81} |
| 85 | Lₐ₁₂₉ | L_{b1} | 86 | Lₐ₁₂₉ | L_{b81} |
| 87 | Lₐ₁₆₈ | L_{b1} | 88 | Lₐ₁₆₈ | L_{b81} |
| 89 | Lₐ₃₇ | L_{b1} | 90 | Lₐ₃₇ | L_{b81} |
| 91 | Lₐ₃₁ | L_{b1} | 92 | Lₐ₃₁ | L_{b81} |
| 93 | Lₐ₃₂₈ | L_{b1} | 94 | Lₐ₃₂₈ | L_{b81} |
| 95 | Lₐ₅₂₂ | L_{b1} | 96 | Lₐ₅₂₂ | L_{b81} |
| 97 | Lₐ₂₆₈ | L_{b1} | 98 | Lₐ₂₆₈ | L_{b81} |
| 99 | Lₐ₂₈₇ | L_{b1} | 100 | Lₐ₂₈₇ | L_{b81} |
| 101 | Lₐ₇ | L_{b1} | 102 | Lₐ₇ | L_{b81} |
| 103 | Lₐ₂₁ | L_{b1} | 104 | Lₐ₂₁ | L_{b81} |
| 105 | Lₐ₃₄ | L_{b1} | 106 | Lₐ₃₄ | L_{b81} |
| 107 | Lₐ₄₇ | L_{b1} | 108 | Lₐ₄₇ | L_{b81} |
| 109 | Lₐ₆₅ | L_{b1} | 110 | Lₐ₆₅ | L_{b81} |
| 111 | Lₐ₇₃ | L_{b1} | 112 | Lₐ₇₃ | L_{b81} |
| 113 | Lₐ₁₀₁ | L_{b1} | 114 | Lₐ₁₀₁ | L_{b81} |
| 115 | Lₐ₁₁₃ | L_{b1} | 116 | Lₐ₁₁₃ | L_{b81} |
| 117 | Lₐ₁₂₁ | L_{b1} | 118 | Lₐ₁₂₁ | L_{b81} |
| 119 | Lₐ₁₂₀ | L_{b1} | 120 | Lₐ₁₂₀ | L_{b81} |
| 121 | Lₐ₁₃₄ | L_{b1} | 122 | Lₐ₁₃₄ | L_{b81} |
| 123 | Lₐ₁₄₉ | L_{b1} | 124 | Lₐ₁₄₉ | L_{b81} |
| 125 | Lₐ₁₅₇ | L_{b1} | 126 | Lₐ₁₅₇ | L_{b81} |
| 127 | Lₐ₁₈₀ | L_{b1} | 128 | Lₐ₁₈₀ | L_{b81} |
| 129 | Lₐ₁₉₂ | L_{b1} | 130 | Lₐ₁₉₂ | L_{b81} |
| 131 | Lₐ₂₀₀ | L_{b1} | 132 | Lₐ₂₀₀ | L_{b81} |
| 133 | Lₐ₂₁₃ | L_{b1} | 134 | Lₐ₂₁₃ | L_{b81} |
| 135 | Lₐ₂₃₀ | L_{b1} | 136 | Lₐ₂₃₀ | L_{b81} |
| 137 | Lₐ₂₃₈ | L_{b1} | 138 | Lₐ₂₃₈ | L_{b81} |
| 139 | Lₐ₂₉₇ | L_{b1} | 140 | Lₐ₂₉₇ | L_{b81} |
| 141 | Lₐ₃₀₂ | L_{b1} | 142 | Lₐ₃₀₂ | L_{b81} |
| 143 | Lₐ₃₅₄ | L_{b1} | 144 | Lₐ₃₅₄ | L_{b81} |
| 145 | Lₐ₃₅₅ | L_{b1} | 146 | Lₐ₃₅₅ | L_{b81} |
| 147 | Lₐ₃₆₈ | L_{b1} | 148 | Lₐ₃₆₈ | L_{b81} |
| 149 | Lₐ₄₀₉ | L_{b1} | 150 | Lₐ₄₀₉ | L_{b81} |
| 151 | Lₐ₄₁₇ | L_{b1} | 152 | Lₐ₄₁₇ | L_{b81} |
| 153 | Lₐ₄₂₇ | L_{b1} | 154 | Lₐ₄₂₇ | L_{b81} |
| 155 | Lₐ₄₃₃ | L_{b1} | 156 | Lₐ₄₃₃ | L_{b81} |
| 157 | Lₐ₄₈ | L_{b1} | 158 | Lₐ₄₈ | L_{b81} |
| 159 | Lₐ₅₃₈ | L_{b1} | 160 | Lₐ₅₃₈ | L_{b81} |
| 161 | Lₐ₂₇₁ | L_{b10} | 162 | Lₐ₂₇₁ | L_{b209} |
| 163 | Lₐ₂₅₃ | L_{b10} | 164 | Lₐ₂₅₃ | L_{b209} |
| 165 | Lₐ₁₂₉ | L_{b10} | 166 | Lₐ₁₂₉ | L_{b209} |
| 167 | Lₐ₁₆₈ | L_{b10} | 168 | Lₐ₁₆₈ | L_{b209} |
| 169 | Lₐ₃₇ | L_{b10} | 170 | Lₐ₃₇ | L_{b209} |
| 171 | Lₐ₃₁ | L_{b10} | 172 | Lₐ₃₁ | L_{b209} |
| 173 | Lₐ₃₂₈ | L_{b10} | 174 | Lₐ₃₂₈ | L_{b209} |
| 175 | Lₐ₅₂₂ | L_{b10} | 176 | Lₐ₅₂₂ | L_{b209} |
| 177 | Lₐ₂₆₈ | L_{b10} | 178 | Lₐ₂₆₈ | L_{b209} |
| 179 | Lₐ₂₈₇ | L_{b10} | 180 | Lₐ₂₈₇ | L_{b209} |
| 181 | Lₐ₇ | L_{b10} | 182 | Lₐ₇ | L_{b209} |
| 183 | Lₐ₂₁ | L_{b10} | 184 | Lₐ₂₁ | L_{b209} |
| 185 | Lₐ₃₄ | L_{b10} | 186 | Lₐ₃₄ | L_{b209} |
| 187 | Lₐ₄₇ | L_{b10} | 188 | Lₐ₄₇ | L_{b209} |
| 189 | Lₐ₆₅ | L_{b10} | 190 | Lₐ₆₅ | L_{b209} |
| 191 | Lₐ₇₃ | L_{b10} | 192 | Lₐ₇₃ | L_{b209} |
| 193 | Lₐ₁₀₁ | L_{b10} | 194 | Lₐ₁₀₁ | L_{b209} |
| 195 | Lₐ₁₁₃ | L_{b10} | 196 | Lₐ₁₁₃ | L_{b209} |
| 197 | Lₐ₁₂₁ | L_{b10} | 198 | Lₐ₁₂₁ | L_{b209} |
| 199 | Lₐ₁₂₀ | L_{b10} | 200 | Lₐ₁₂₀ | L_{b209} |
| 201 | Lₐ₁₃₄ | L_{b10} | 202 | Lₐ₁₃₄ | L_{b209} |
| 203 | Lₐ₁₄₉ | L_{b10} | 204 | Lₐ₁₄₉ | L_{b209} |
| 205 | Lₐ₁₅₇ | L_{b10} | 206 | Lₐ₁₅₇ | L_{b209} |
| 207 | Lₐ₁₈₀ | L_{b10} | 208 | Lₐ₁₈₀ | L_{b209} |
| 209 | Lₐ₁₉₂ | L_{b10} | 210 | Lₐ₁₉₂ | L_{b209} |
| 211 | Lₐ₂₀₀ | L_{b10} | 212 | Lₐ₂₀₀ | L_{b209} |
| 213 | Lₐ₂₁₃ | L_{b10} | 214 | Lₐ₂₁₃ | L_{b209} |
| 215 | Lₐ₂₃₀ | L_{b10} | 216 | Lₐ₂₃₀ | L_{b209} |
| 217 | Lₐ₂₃₈ | L_{b10} | 218 | Lₐ₂₃₈ | L_{b209} |
| 219 | Lₐ₂₉₇ | L_{b10} | 220 | Lₐ₂₉₇ | L_{b209} |
| 221 | Lₐ₃₀₂ | L_{b10} | 222 | Lₐ₃₀₂ | L_{b209} |
| 223 | Lₐ₃₅₄ | L_{b10} | 224 | Lₐ₃₅₄ | L_{b209} |
| 225 | Lₐ₃₅₅ | L_{b10} | 226 | Lₐ₃₅ | L_{b209} |
| 227 | Lₐ₃₆₈ | L_{b10} | 228 | Lₐ₃₆₈ | L_{b209} |
| 229 | Lₐ₄₀₉ | L_{b10} | 230 | Lₐ₄₀₉ | L_{b209} |
| 231 | Lₐ₄₁₇ | L_{b10} | 232 | Lₐ₄₁₇ | L_{b209} |
| 233 | Lₐ₄₂₇ | L_{b10} | 234 | Lₐ₄₂₇ | L_{b209} |
| 235 | Lₐ₄₃₃ | L_{b10} | 236 | Lₐ₄₃₃ | L_{b209} |
| 237 | Lₐ₄₄₈ | L_{b10} | 238 | Lₐ₄₄₈ | L_{b209} |
| 239 | Lₐ₅₃₈ | L_{b10} | 240 | Lₐ₅₃₈ | L_{b209} |
| 241 | Lₐ₂₇₁ | L_{b95} | 242 | Lₐ₂₇₁ | L_{b21} |
| 243 | Lₐ₂₅₃ | L_{b95} | 244 | Lₐ₂₅₃ | L_{b21} |
| 245 | Lₐ₁₂₉ | L_{b95} | 246 | Lₐ₁₂₉ | L_{b21} |
| 247 | Lₐ₁₆₈ | L_{b95} | 248 | Lₐ₁₆₈ | L_{b21} |
| 249 | Lₐ₃₇ | L_{b95} | 250 | Lₐ₃₇ | L_{b21} |
| 251 | Lₐ₃₁ | L_{b95} | 252 | Lₐ₃₁ | L_{b21} |
| 253 | Lₐ₃₂₈ | L_{b95} | 254 | Lₐ₃₂₈ | L_{b21} |
| 255 | Lₐ₅₂₂ | L_{b95} | 256 | Lₐ₅₂₂ | L_{b21} |
| 257 | Lₐ₂₆₈ | L_{b95} | 258 | Lₐ₂₆₈ | L_{b21} |
| 259 | Lₐ₂₈₇ | L_{b95} | 260 | Lₐ₂₈₇ | L_{b21} |
| 261 | Lₐ₇ | L_{b95} | 262 | Lₐ₇ | L_{b21} |
| 263 | Lₐ₂₁ | L_{b95} | 264 | Lₐ₂₁ | L_{b21} |
| 265 | Lₐ₃₄ | L_{b95} | 266 | Lₐ₃₄ | L₆₂₁ |
| 267 | Lₐ₄₇ | L_{b95} | 268 | Lₐ₄₇ | L_{b21} |
| 269 | Lₐ₆₅ | L_{b95} | 270 | Lₐ₆₅ | L_{b21} |
| 271 | Lₐ₇₃ | L_{b95} | 272 | Lₐ₇₃ | L_{b21} |
| 273 | Lₐ₁₀₁ | L_{b95} | 274 | Lₐ₁₀₁ | L_{b21} |
| 275 | Lₐ₁₁₃ | L_{b95} | 276 | Lₐ₁₁₃ | L_{b21} |
| 277 | Lₐ₁₂₁ | L_{b95} | 278 | Lₐ₁₂₁ | L_{b21} |
| 279 | Lₐ₁₂₀ | L_{b95} | 280 | Lₐ₁₂₀ | L_{b21} |
| 281 | Lₐ₁₃₄ | L_{b95} | 282 | Lₐ₁₃₄ | L_{b21} |
| 283 | Lₐ₁₄₉ | L_{b95} | 284 | Lₐ₁₄₉ | L_{b21} |
| 285 | Lₐ₁₅₇ | L_{b95} | 286 | Lₐ₁₅₇ | L₆₂₁ |
| 287 | Lₐ₁₈₀ | L_{b95} | 288 | Lₐ₁₈₀ | L₆₂₁ |
| 289 | Lₐ₁₉₂ | L_{b95} | 290 | Lₐ₁₉₂ | L_{b21} |
| 291 | Lₐ₂₀₀ | L_{b95} | 292 | Lₐ₂₀₀ | L₆₂₁ |
| 293 | Lₐ₂₁₃ | L_{b95} | 294 | Lₐ₂₁₃ | L_{b21} |
| 295 | Lₐ₂₃₀ | L_{b95} | 296 | Lₐ₂₃₀ | L_{b21} |
| 297 | Lₐ₂₃₈ | L_{b95} | 298 | Lₐ₂₃₈ | L_{b21} |
| 299 | Lₐ₂₉₇ | L_{b95} | 300 | Lₐ₂₉₇ | L_{b21} |
| 301 | Lₐ₃₀₂ | L_{b95} | 302 | Lₐ₃₀₂ | L_{b21} |
| 303 | Lₐ₃₅₄ | L_{b95} | 304 | Lₐ₃₅₄ | L_{b21} |
| 305 | Lₐ₃₅₅ | L_{b95} | 306 | Lₐ₃₅₅ | L_{b21} |
| 307 | Lₐ₃₆₈ | L_{b95} | 308 | Lₐ₃₆₈ | L_{b21} |
| 309 | Lₐ₄₀₉ | L_{b95} | 310 | Lₐ₄₀₉ | L_{b21} |
| 311 | Lₐ₄₁₇ | L_{b95} | 312 | Lₐ₄₁₇ | L_{b21} |
| 313 | Lₐ₄₂₇ | L_{b95} | 314 | Lₐ₄₂₇ | L_{b21} |
| 315 | Lₐ₄₃₃ | L_{b95} | 316 | Lₐ₄₃₃ | L_{b21} |
| 317 | Lₐ₄₄₈ | L_{b95} | 318 | Lₐ₄₄₈ | L_{b21} |
| 319 | Lₐ₅₃₈ | L_{b95} | 320 | Lₐ₅₃₈ | L_{b21} |
| 321 | Lₐ₂₇₁ | L_{b12} | 322 | Lₐ₂₇₁ | L_{b286} |
| 323 | Lₐ₂₅₃ | L_{b12} | 324 | Lₐ₂₅₃ | L_{b286} |
| 325 | Lₐ₁₂₉ | L_{b12} | 326 | Lₐ₁₂₉ | L_{b286} |
| 327 | Lₐ₁₆₈ | L_{b12} | 328 | Lₐ₁₆₈ | L_{b286} |
| 329 | Lₐ₃₇ | L_{b12} | 330 | Lₐ₃₇ | L_{b286} |
| 331 | Lₐ₃₁ | L_{b12} | 332 | Lₐ₃₁ | L_{b286} |
| 333 | Lₐ₃₂₈ | L_{b12} | 334 | Lₐ₃₂₈ | L_{b286} |
| 335 | Lₐ₅₂₂ | L_{b12} | 336 | Lₐ₅₂₂ | L_{b286} |
| 337 | Lₐ₂₆₈ | L_{b12} | 338 | Lₐ₂₆₈ | L_{b286} |
| 339 | Lₐ₂₈₇ | L_{b12} | 340 | Lₐ₂₈₇ | L_{b286} |
| 341 | Lₐ₇ | L_{b12} | 342 | Lₐ₇ | L_{b286} |
| 343 | Lₐ₂₁ | L_{b12} | 344 | Lₐ₂₁ | L_{b286} |
| 345 | Lₐ₃₄ | L_{b12} | 346 | Lₐ₃₄ | L_{b286} |
| 347 | Lₐ₄₇ | L_{b12} | 348 | Lₐ₄₇ | L_{b286} |
| 349 | Lₐ₆₅ | L_{b12} | 350 | Lₐ₆₅ | L_{b286} |
| 351 | Lₐ₇₃ | L_{b12} | 352 | Lₐ₇₃ | L_{b286} |
| 353 | Lₐ₁₀₁ | L_{b12} | 354 | Lₐ₁₀₁ | L_{b286} |
| 355 | Lₐ₁₁₃ | L_{b12} | 356 | Lₐ₁₁₃ | L_{b286} |
| 357 | Lₐ₁₂₁ | L_{b12} | 358 | Lₐ₁₂₁ | L_{b286} |
| 359 | Lₐ₁₂₀ | L_{b12} | 360 | Lₐ₁₂₀ | L_{b286} |
| 361 | Lₐ₁₃₄ | L_{b12} | 362 | Lₐ₁₃₄ | L_{b286} |
| 363 | Lₐ₁₄₉ | L_{b12} | 364 | Lₐ₁₄₉ | L_{b286} |
| 365 | Lₐ₁₅₇ | L_{b12} | 366 | Lₐ₁₅₇ | L_{b286} |
| 367 | Lₐ₁₈₀ | L_{b12} | 368 | Lₐ₁₈₀ | L_{b286} |
| 369 | Lₐ₁₉₂ | L_{b12} | 370 | Lₐ₁₉₂ | L_{b286} |
| 371 | Lₐ₂₀₀ | L_{b12} | 372 | Lₐ₂₀₀ | L_{b286} |
| 373 | Lₐ₂₁₃ | L_{b12} | 374 | Lₐ₂₁₃ | L_{b286} |
| 375 | Lₐ₂₃₀ | L_{b12} | 376 | Lₐ₂₃₀ | L_{b286} |
| 377 | Lₐ₂₃₈ | L_{b12} | 378 | Lₐ₂₃₈ | L_{b286} |
| 379 | Lₐ₂₉₇ | L_{b12} | 380 | Lₐ₂₉₇ | L_{b286} |
| 381 | Lₐ₃₀₂ | L_{b12} | 382 | Lₐ₃₀₂ | L_{b286} |
| 383 | Lₐ₃₅₄ | L_{b12} | 384 | Lₐ₃₅₄ | L_{b286} |
| 385 | Lₐ₃₅₅ | L_{b12} | 386 | Lₐ₃₅₅ | L_{b286} |
| 387 | Lₐ₃₆₈ | L_{b12} | 388 | Lₐ₃₆₈ | L_{b286} |
| 389 | Lₐ₄₀₉ | L_{b12} | 390 | Lₐ₄₀₉ | L_{b286} |
| 391 | Lₐ₄₁₇ | L_{b12} | 392 | Lₐ₄₁₇ | L_{b286} |
| 393 | Lₐ₄₂₇ | L_{b12} | 394 | Lₐ₄₂₇ | L_{b286} |
| 395 | Lₐ₄₃₃ | L_{b12} | 396 | Lₐ₄₃₃ | L_{b286} |
| 397 | Lₐ₄₄₈ | L_{b12} | 398 | Lₐ₄₄₈ | L_{b286} |
| 399 | Lₐ₅₃₈ | L_{b12} | 400 | Lₐ₅₃₈ | L_{b286} |

wherein Compound 401 to Compound 522 each have a structure of Ir(Lₐ)₂(L_{b}), wherein the two Lₐ are the same, and Lₐ and L_{b} are selected from the structures listed in the following table, respectively:

| Compound | | | Compound | | |
|---|---|---|---|---|---|
| No. | Lₐ | L_{b} | No. | Lₐ | L_{b} |
| 401 | Lₐ₂₇₁ | L_{b2} | 402 | Lₐ₂₇ | L_{b3} |
| 403 | Lₐ₂₅₃ | L_{b2} | 404 | Lₐ₂₅₃ | L_{b3} |
| 405 | Lₐ₁₀₁ | L_{b2} | 406 | Lₐ₁₀₁ | L_{b3} |
| 407 | Lₐ₁₁₃ | L_{b2} | 408 | Lₐ₁₁₃ | L_{b3} |
| 409 | Lₐ₁₂₁ | L_{b2} | 410 | Lₐ₁₂₁ | L_{b3} |
| 411 | Lₐ₁₂₀ | L_{b2} | 412 | Lₐ₁₂₀ | L_{b3} |
| 413 | _{Ja134} | L_{b2} | 414 | Lₐ₁₃₄ | L_{b3} |
| 415 | Lₐ₁₄₉ | L_{b2} | 416 | Lₐ₁₄₉ | L_{b3} |
| 417 | Lₐ₁₅₇ | L_{b2} | 418 | Lₐ₁₅₇ | L_{b3} |
| 419 | Lₐ₁₈₀ | L_{b2} | 420 | Lₐ₁₈₀ | L_{b3} |
| 421 | Lₐ₁₉₂ | L_{b2} | 422 | Lₐ₁₉₂ | L_{b3} |
| 423 | Lₐ₂₀₀ | L_{b2} | 424 | Lₐ₂₀₀ | L_{b3} |
| 425 | Lₐ₂₁₃ | L_{b2} | 426 | Lₐ₂₁₃ | L_{b3} |
| 427 | Lₐ₂₃₀ | L_{b2} | 428 | Lₐ₂₃₀ | L_{b3} |
| 429 | Lₐ₂₃₈ | L_{b2} | 430 | Lₐ₂₃₈ | L_{b3} |
| 431 | Lₐ₅₂₂ | L_{b1} | 432 | Lₐ₅₂₂ | L_{b81} |
| 433 | Lₐ₂₆₈ | L_{b1} | 434 | Lₐ₂₆₈ | L_{b81} |
| 435 | Lₐ₂₇₁ | L_{b10} | 436 | Lₐ₂₇₁ | L_{b209} |
| 437 | Lₐ₂₅₃ | L_{b10} | 438 | Lₐ₂₅₃ | L_{b209} |
| 465 | Lₐ₇₃ | L_{b10} | 466 | Lₐ₇₃ | L_{b209} |
| 467 | Lₐ₁₀₁ | L_{b10} | 468 | Lₐ₁₀₁ | L_{b209} |
| 469 | Lₐ₁₁₃ | L_{b10} | 470 | Lₐ₁₁₃ | L_{b209} |
| 471 | Lₐ₁₂₁ | L_{b10} | 472 | Lₐ₁₂₁ | L_{b209} |
| 473 | Lₐ₁₂₀ | L_{b10} | 474 | Lₐ₁₂₀ | L_{b209} |
| 475 | Lₐ₁₃₄ | L_{b10} | 476 | Lₐ₁₃₄ | L_{b209} |
| 477 | Lₐ₁₄₉ | L_{b10} | 478 | Lₐ₁₄₉ | L_{b209} |
| 479 | Lₐ₃₆₈ | L_{b10} | 480 | Lₐ₃₆₈ | L_{b209} |
| 481 | Lₐ₄₀₉ | L_{b10} | 482 | Lₐ₄₀₉ | L_{b209} |
| 483 | Lₐ₄₁₇ | L_{b10} | 484 | Lₐ₄₁₇ | L_{b209} |
| 485 | Lₐ₄₂₇ | L_{b10} | 486 | Lₐ₄₂₇ | L_{b209} |
| 487 | Lₐ₄₃₃ | L_{b10} | 488 | Lₐ₄₃₃ | L_{b209} |
| 489 | Lₐ₄₈ | L_{b10} | 490 | Lₐ₄₄₈ | L_{b209} |
| 491 | Lₐ₅₃₈ | L_{b10} | 492 | Lₐ₅₃₈ | L_{b209} |
| 493 | Lₐ₂₇₁ | L_{b95} | 494 | Lₐ₂₇₁ | L_{b21} |
| 495 | Lₐ₂₅₃ | L_{b95} | 496 | Lₐ₂₅₃ | L_{b21} |
| 497 | Lₐ₁₂₉ | L_{b95} | 498 | Lₐ₁₂₉ | L_{b21} |
| 499 | Lₐ₁₆₈ | L_{b95} | 500 | Lₐ₁₆₈ | L_{b21} |
| 501 | Lₐ₃₇ | L_{b95} | 502 | Lₐ₃₇ | L_{b21} |
| 503 | Lₐ₅₂₂ | L_{b12} | 504 | Lₐ₅₂₂ | L_{b286} |
| 505 | Lₐ₂₆₈ | L_{b12} | 506 | Lₐ₂₆₈ | L_{b286} |
| 507 | Lₐ₁₃₄ | L_{b12} | 508 | Lₐ₁₃₄ | L_{b286} |
| 509 | Lₐ₁₄₉ | L_{b12} | 510 | Lₐ₁₄₉ | L_{b286} |
| 511 | Lₐ₁₅₇ | L_{b12} | 512 | Lₐ₁₅₇ | L_{b286} |
| 513 | Lₐ₁₈₀ | L_{b12} | 514 | Lₐ₁₈₀ | L_{b286} |
| 515 | Lₐ₁₉₂ | L_{b12} | 516 | Lₐ₁₉₂ | L_{b286} |
| 517 | Lₐ₂₀₀ | L_{b12} | 518 | Lₐ₂₀₀ | L_{b286} |
| 519 | Lₐ₂₁₃ | L_{b12} | 520 | Lₐ₂₁₃ | L_{b286} |
| 521 | Lₐ₂₃₀ | L_{b12} | 522 | Lₐ₂₃₀ | L_{b286} |

wherein Compound 523 to Compound 608 each have a structure of Ir(Lₐ)(L_{b})(L_{c}), wherein Lₐ, L_{b} and L_{c} are selected from the structures listed in the following table, respectively:

| Compound | | | | Compound | | | |
|---|---|---|---|---|---|---|---|
| No. | Lₐ | L_{b} | L_{c} | No. | Lₐ | L_{b} | L_{c} |
| 523 | Lₐ₂₇₁ | L_{b81} | L_{c1} | 524 | Lₐ₄₇ | L_{b81} | L_{c1} |
| 525 | Lₐ₂₅₃ | L_{b81} | L_{c3} | 526 | Lₐ₆₅ | L_{b81} | L_{c3} |
| 527 | Lₐ₁₂₉ | L_{b81} | L_{c5} | 528 | Lₐ₇₃ | L_{b81} | L_{c5} |
| 529 | Lₐ₁₆₈ | L_{b81} | L_{c12} | 530 | Lₐ₁₀₁ | L_{b81} | L_{c12} |
| 531 | Lₐ₃₇ | L_{b81} | L_{c17} | 532 | Lₐ₁₁₃ | L_{b81} | L_{c17} |
| 533 | Lₐ₃₁ | L_{b81} | L_{c18} | 534 | Lₐ₁₂₁ | L_{b81} | L_{c18} |
| 535 | Lₐ₃₂₈ | L_{b81} | L_{c29} | 536 | Lₐ₁₃₄ | L_{b81} | L_{c29} |
| 537 | Lₐ₅₂₂ | L_{b81} | L_{c30} | 538 | Lₐ₁₄₉ | L_{b81} | L_{c30} |
| 539 | Lₐ₂₆₈ | L_{b81} | L_{c40} | 540 | Lₐ₁₅₇ | L_{b81} | L_{c40} |
| 541 | Lₐ₂₈₇ | L_{b81} | L_{c46} | 542 | Lₐ₁₈₀ | L_{b81} | L_{c46} |
| 543 | Lₐ₇ | L_{b81} | L_{c59} | 544 | Lₐ₁₉₂ | L_{b81} | L_{c59} |
| 545 | Lₐ₂₁ | L_{b81} | L_{c79} | 546 | Lₐ₂₀₀ | L_{b81} | L_{c79} |
| 547 | Lₐ₃₄ | L_{b81} | L_{c99} | 548 | Lₐ₂₁₃ | L_{b81} | L_{c99} |
| 549 | Lₐ₂₃₀ | L_{b81} | L_{c112} | 550 | Lₐ₂₃₈ | L_{b81} | L_{c112} |
| 551 | Lₐ₂₉₇ | L_{b81} | L_{c138} | 552 | Lₐ₃₃₀₂ | L_{b81} | L_{c138} |
| 553 | Lₐ₃₅₄ | L_{b81} | L_{c182} | 554 | Lₐ₃₅₅ | L_{b81} | L_{c182} |
| 555 | Lₐ₃₆₈ | L_{b81} | L_{c192} | 556 | Lₐ₄₀₉ | L_{b81} | L_{c192} |
| 557 | Lₐ₄₁₇ | L_{b81} | L_{c195} | 558 | Lₐ₄₂₇ | L_{b81} | L_{c195} |
| 559 | Lₐ₄₃₃ | L_{b81} | L_{c201} | 560 | Lₐ₄₄₈ | L_{b81} | L_{c201} |
| 587 | Lₐ₅₃₈ | L_{b81} | L_{c205} | 588 | Lₐ₃₃ | L_{b81} | L_{c205} |
| 589 | Lₐ₂₈ | L_{b81} | L_{c211} | 590 | Lₐ₃₃ | L_{b81} | L_{c211} |
| 591 | Lₐ₂₈ | L_{b81} | L_{c212} | 592 | Lₐ₃₃ | L_{b81} | L_{c212} |
| 593 | Lₐ₂₈ | L_{b81} | L_{c226} | 594 | Lₐ₃₃ | L_{b81} | L_{c226} |
| 595 | Lₐ₂₈ | L_{b81} | L_{c229} | 596 | Lₐ₃₃ | L_{b81} | L_{c229} |
| 597 | Lₐ₂₈ | L_{b81} | L_{c252} | 598 | Lₐ₃₃ | L_{b81} | L_{c252} |
| 599 | Lₐ₂₈ | L_{b81} | L_{c256} | 600 | Lₐ₃₃ | L_{b81} | L_{c256} |
| 601 | Lₐ₂₈ | L_{b81} | L_{c310} | 602 | Lₐ₃₃ | L_{b81} | L_{c310} |
| 603 | Lₐ₂₈ | L_{b81} | L_{c326} | 604 | Lₐ₃₃ | L_{b81} | L_{c326} |
| 605 | Lₐ₂₈ | L_{b81} | L_{c327} | 606 | Lₐ₃₃ | L_{b81} | L_{c327} |
| 607 | Lₐ₂₈ | L_{b81} | L_{c328} | 608 | Lₐ₃₃ | L_{b81} | L_{c328}. |

According to an embodiment of the present disclosure, further disclosed is an electroluminescent device comprising:
an anode,
a cathode, and
an organic layer disposed between the anode and the cathode, wherein the organic layer comprises a metal complex whose specific structure is described in any one of the preceding embodiments.

According to an embodiment of the present disclosure, in the device, the organic layer is an emissive layer, and the compound is a light-emitting material.

According to an embodiment of the present disclosure, in the electroluminescent device, the emissive layer further comprises at least one host material.

According to an embodiment of the present disclosure, the at least one host material comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

According to an embodiment of the present disclosure, in the electroluminescent device, the emissive layer further comprises a first host material and a second host material.

According to an embodiment of the present disclosure, the first host material has a structure represented by Formula 4-1, Formula 4-2 or Formula 4-3:

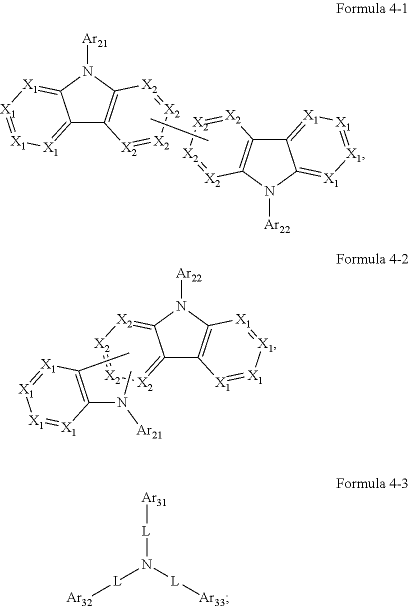

wherein X₁ is at each occurrence identically or differently, selected from CRₓ or N;
X₂ is, at each occurrence identically or differently, selected from C, CRₓ or N;
L is, at each occurrence identically or differently, selected from a single bond, substituted or unsubstituted arylene having 6 to 30 carbon atoms, substituted or unsubstituted heteroarylene having 3 to 30 carbon atoms or a combination thereof;
Ar₂₁, Ar₂₂, Ar₃₁, Ar₃₂ and Ar₃₃ are, at each occurrence identically or differently, selected from substituted or unsubstituted aryl having 6 to 30 carbon atoms or substituted or unsubstituted heteroaryl having 3 to 30 carbon atoms;
Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₓ can be optionally joined to form a ring.

In the present disclosure, the expression that adjacent substituents Rₓ can be optionally joined to form a ring is intended to mean that a group of adjacent substituents, such as adjacent substituents Rₓ, can be joined to form a ring. Obviously, it is also possible that none of these substituents are joined to form a ring.

According to an embodiment of the present disclosure, the first host material has a structure represented by Formula 4-1-1, Formula 4-2-1 or Formula 4-3-1:

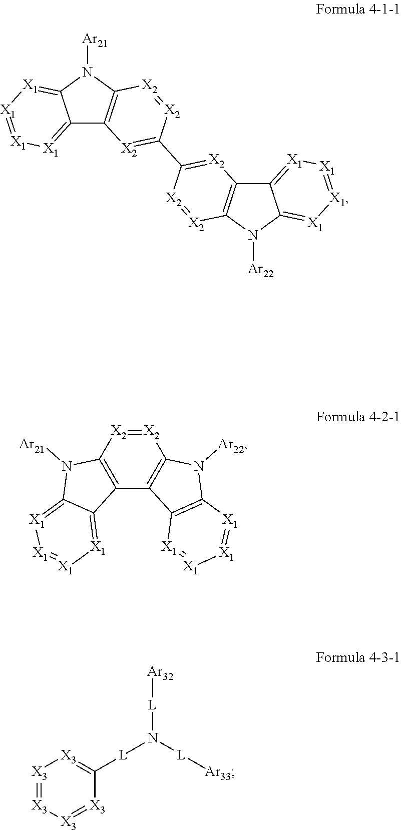

wherein X₁, X₂ and X₃ are, at each occurrence identically or differently, selected from CRₓ or N;
Ar₂₁, Ar₂₂, Ar₃₂ and Ar₃₃ are, at each occurrence identically or differently, selected from substituted or unsubstituted aryl having 6 to 30 carbon atoms or substituted or unsubstituted heteroaryl having 3 to 30 carbon atoms;
L is, at each occurrence identically or differently, selected from a single bond, substituted or unsubstituted arylene having 6 to 30 carbon atoms, substituted or unsubstituted heteroarylene having 3 to 30 carbon atoms or a combination thereof;
Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₓ can be optionally joined to form a ring.

According to an embodiment of the present disclosure, the first host material is selected from the group consisting of Compound 1-1-1 to Compound 1-1-104, Compound 1-2-1 to Compound 1-2-100 and Compound 1-3-1 to Compound 1-3-100:

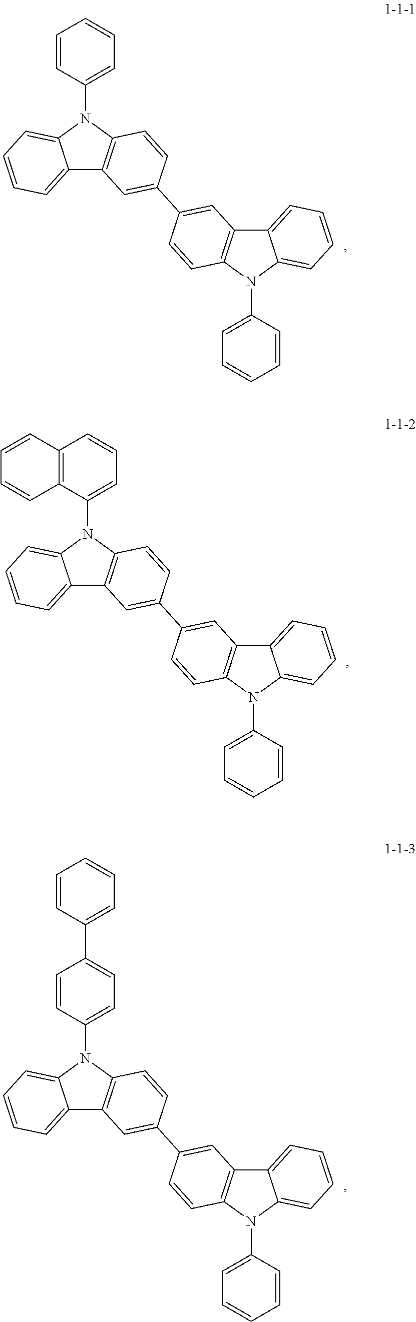 [SMILES: c1ccc(-n2c3ccccc3c3cc(-c4ccc5c(c4)c4ccccc4n5-c4ccccc4)ccc32)cc1 ; c1ccc(-n2c3ccccc3c3cc(-c4ccc5c(c4)c4ccccc4n5-c4cccc5ccccc45)ccc32)cc1 ; c1ccc(-c2ccc(-n3c4ccccc4c4cc(-c5ccc6c(c5)c5ccccc5n6-c5ccccc5)ccc43)cc2)cc1]

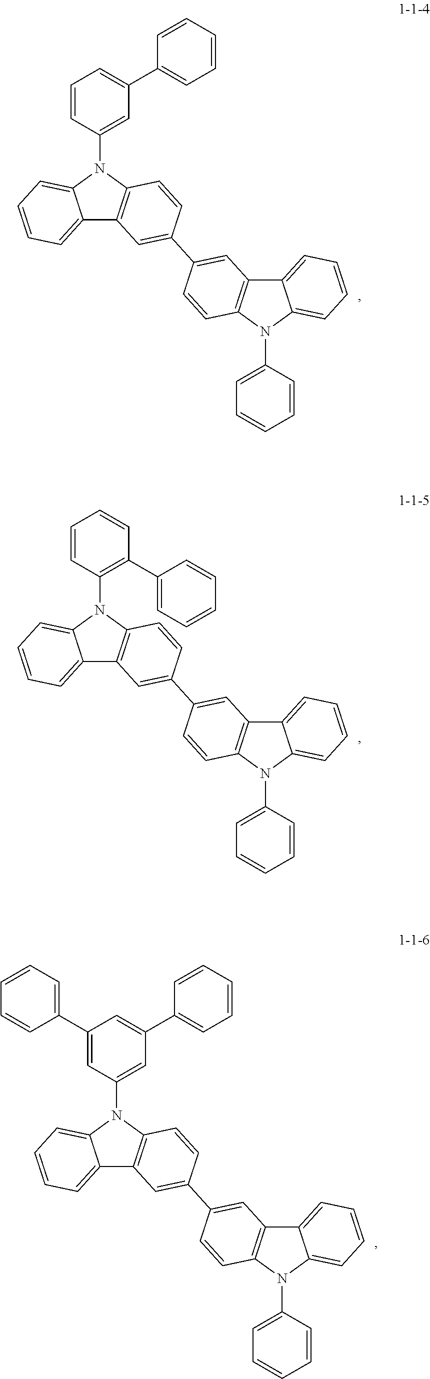 [SMILES: c1ccc(-c2cccc(-n3c4ccccc4c4cc(-c5ccc6c(c5)c5ccccc5n6-c5ccccc5)ccc43)c2)cc1 ; c1ccc(-c2ccccc2-n2c3ccccc3c3cc(-c4ccc5c(c4)c4ccccc4n5-c4ccccc4)ccc32)cc1 ; c1ccc(-c2cc(-c3ccccc3)cc(-n3c4ccccc4c4cc(-c5ccc6c(c5)c5ccccc5n6-c5ccccc5)ccc43)c2)cc1]

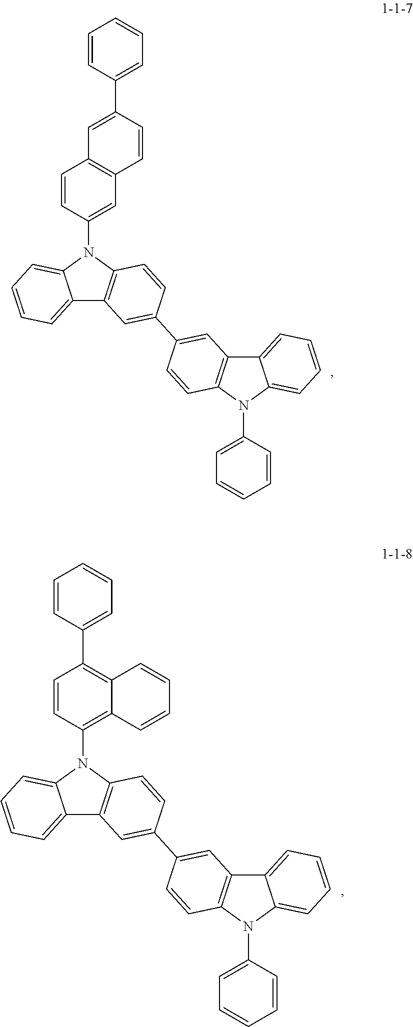 [SMILES: c1ccc(-c2ccc3cc(-n4c5ccccc5c5cc(-c6ccc7c(c6)c6ccccc6n7-c6ccccc6)ccc54)ccc3c2)cc1 ; c1ccc(-c2ccc(-n3c4ccccc4c4cc(-c5ccc6c(c5)c5ccccc5n6-c5ccccc5)ccc43)c3ccccc23)cc1]

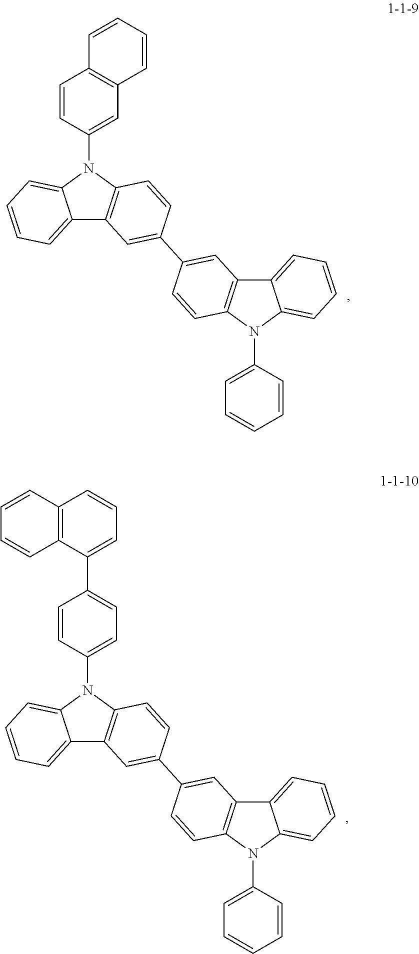 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4ccc(-c5cccc6ccccc56)cc4)ccc32)cc1]

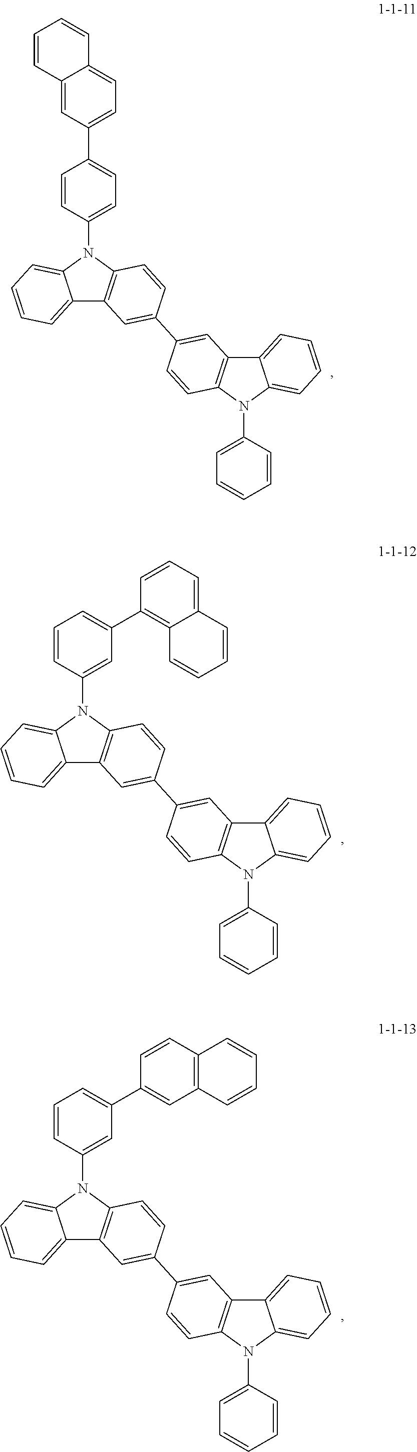 [SMILES: c1ccc(-n2c3ccccc3c3cc(-c4ccc5c(c4)c4ccccc4n5-c4ccc(-c5ccc6ccccc6c5)cc4)ccc32)cc1 ; c1ccc(-n2c3ccccc3c3cc(-c4ccc5c(c4)c4ccccc4n5-c4cccc(-c5cccc6ccccc56)c4)ccc32)cc1 ; c1ccc(-n2c3ccccc3c3cc(-c4ccc5c(c4)c4ccccc4n5-c4cccc(-c5ccc6ccccc6c5)c4)ccc32)cc1]

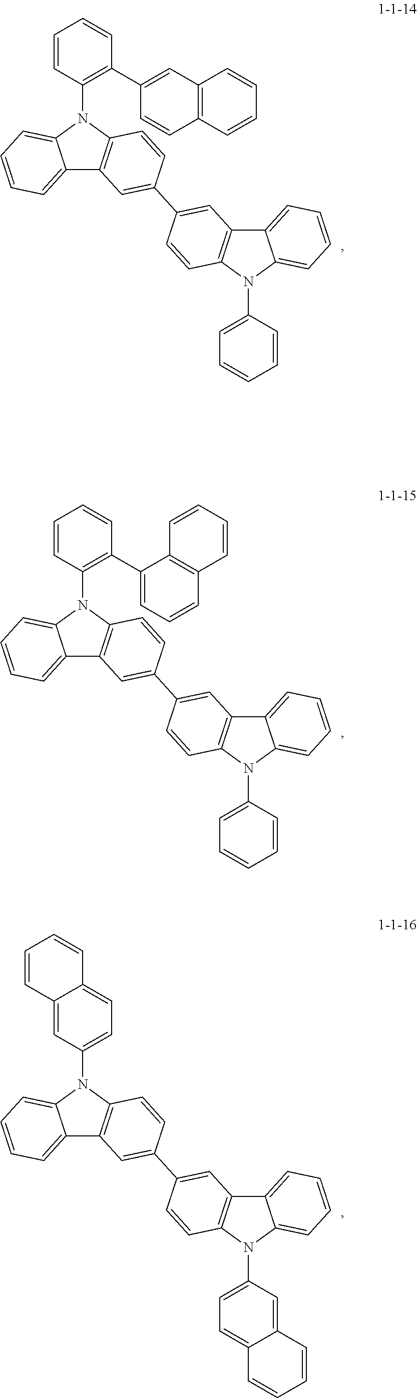 [SMILES: c1ccc(-n2c3ccccc3c3cc(-c4ccc5c(c4)c4ccccc4n5-c4ccccc4-c4ccc5ccccc5c4)ccc32)cc1 ; c1ccc(-n2c3ccccc3c3cc(-c4ccc5c(c4)c4ccccc4n5-c4ccccc4-c4cccc5ccccc45)ccc32)cc1 ; c1ccc2cc(-n3c4ccccc4c4cc(-c5ccc6c(c5)c5ccccc5n6-c5ccc6ccccc6c5)ccc43)ccc2c1]

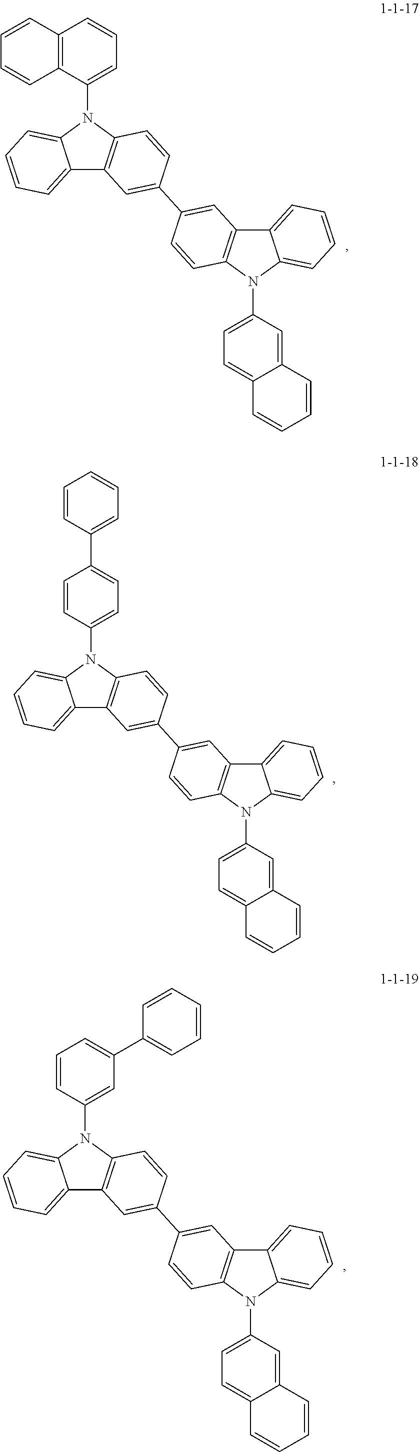 [SMILES: c1ccc2cc(-n3c4ccccc4c4cc(-c5ccc6c(c5)c5ccccc5n6-c5cccc6ccccc56)ccc43)ccc2c1 ; c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5ccc6ccccc6c5)ccc43)c2)cc1]

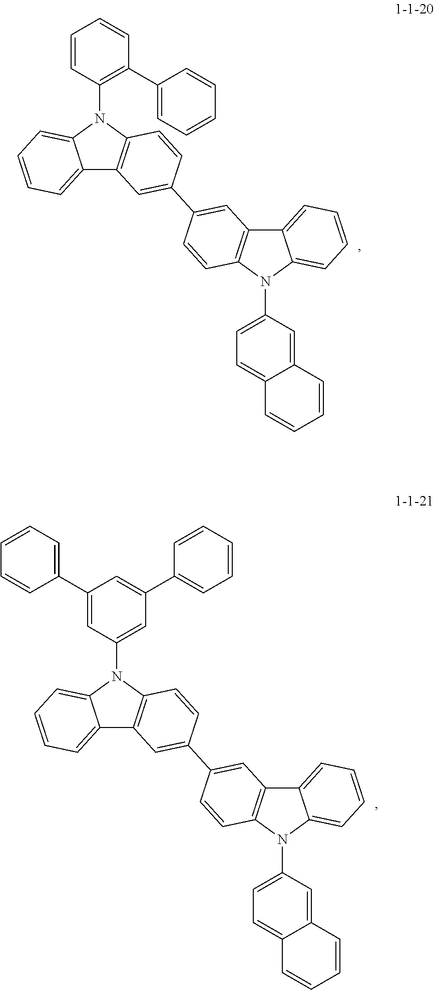 [SMILES: c1ccc(-c2ccccc2-n2c3ccccc3c3cc(-c4ccc5c(c4)c4ccccc4n5-c4ccc5ccccc5c4)ccc32)cc1 ; c1ccc(-c2cc(-c3ccccc3)cc(-n3c4ccccc4c4cc(-c5ccc6c(c5)c5ccccc5n6-c5ccc6ccccc6c5)ccc43)c2)cc1]

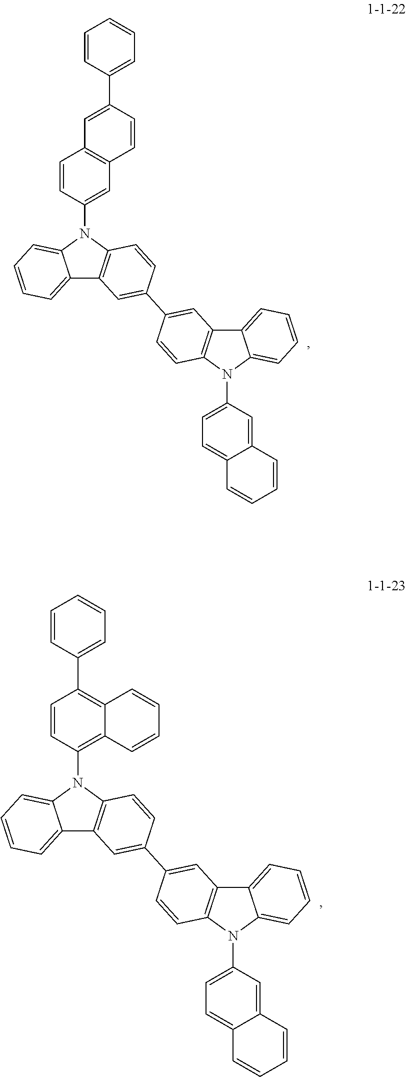 [SMILES: c1ccc(-c2ccc3cc(-n4c5ccccc5c5cc(-c6ccc7c(c6)c6ccccc6n7-c6ccc7ccccc7c6)ccc54)ccc3c2)cc1 ; c1ccc(-c2ccc(-n3c4ccccc4c4cc(-c5ccc6c(c5)c5ccccc5n6-c5ccc6ccccc6c5)ccc43)c3ccccc23)cc1]

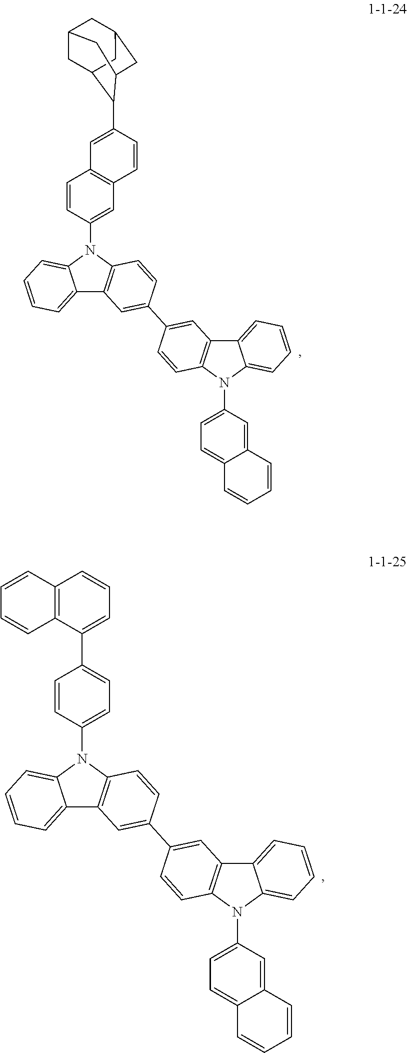 [SMILES: c1ccc2cc(-n3c4ccccc4c4cc(-c5ccc6c(c5)c5ccccc5n6-c5ccc6cc(C7C8CC9CC(C8)CC7C9)ccc6c5)ccc43)ccc2c1 ; c1ccc2cc(-n3c4ccccc4c4cc(-c5ccc6c(c5)c5ccccc5n6-c5ccc(-c6cccc7ccccc67)cc5)ccc43)ccc2c1]

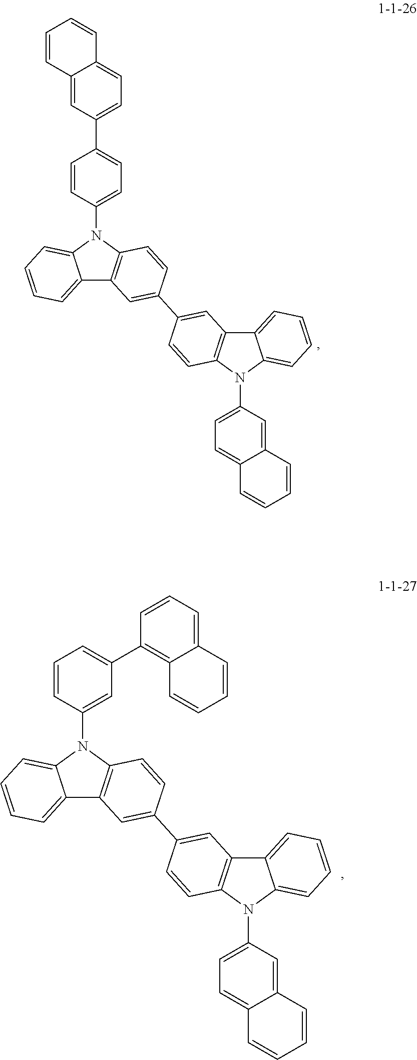 [SMILES: c1ccc2cc(-c3ccc(-n4c5ccccc5c5cc(-c6ccc7c(c6)c6ccccc6n7-c6ccc7ccccc7c6)ccc54)cc3)ccc2c1 ; c1cc(-c2cccc3ccccc23)cc(-n2c3ccccc3c3cc(-c4ccc5c(c4)c4ccccc4n5-c4ccc5ccccc5c4)ccc32)c1]

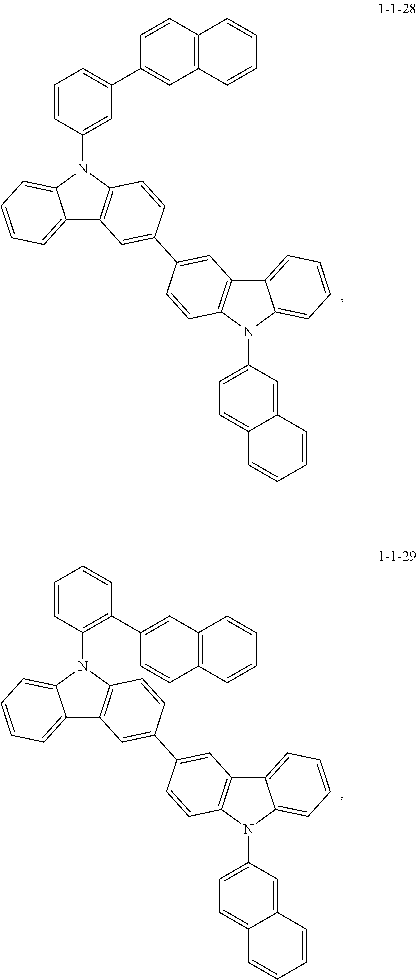 [SMILES: c1cc(-c2ccc3ccccc3c2)cc(-n2c3ccccc3c3cc(-c4ccc5c(c4)c4ccccc4n5-c4ccc5ccccc5c4)ccc32)c1 ; c1ccc(-n2c3ccccc3c3cc(-c4ccc5c(c4)c4ccccc4n5-c4ccc5ccccc5c4)ccc32)c(-c2ccc3ccccc3c2)c1]

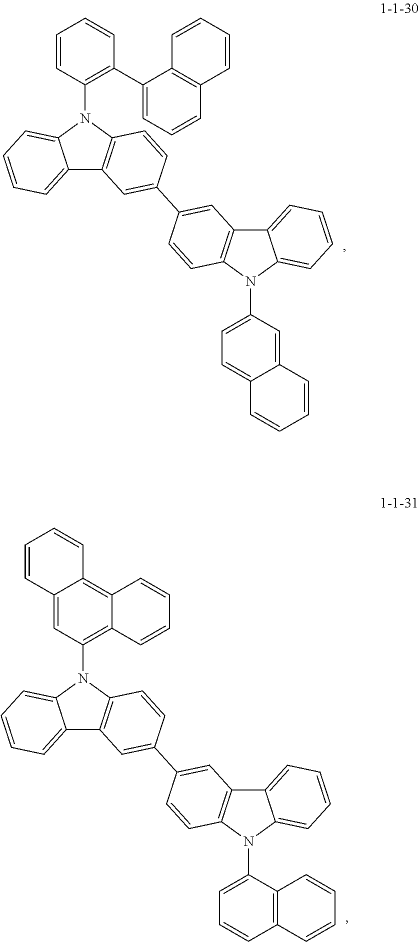 [SMILES: c1ccc(-n2c3ccccc3c3cc(-c4ccc5c(c4)c4ccccc4n5-c4ccc5ccccc5c4)ccc32)c(-c2cccc3ccccc23)c1 ; c1ccc2c(-n3c4ccccc4c4cc(-c5ccc6c(c5)c5ccccc5n6-c5cc6ccccc6c6ccccc56)ccc43)cccc2c1]

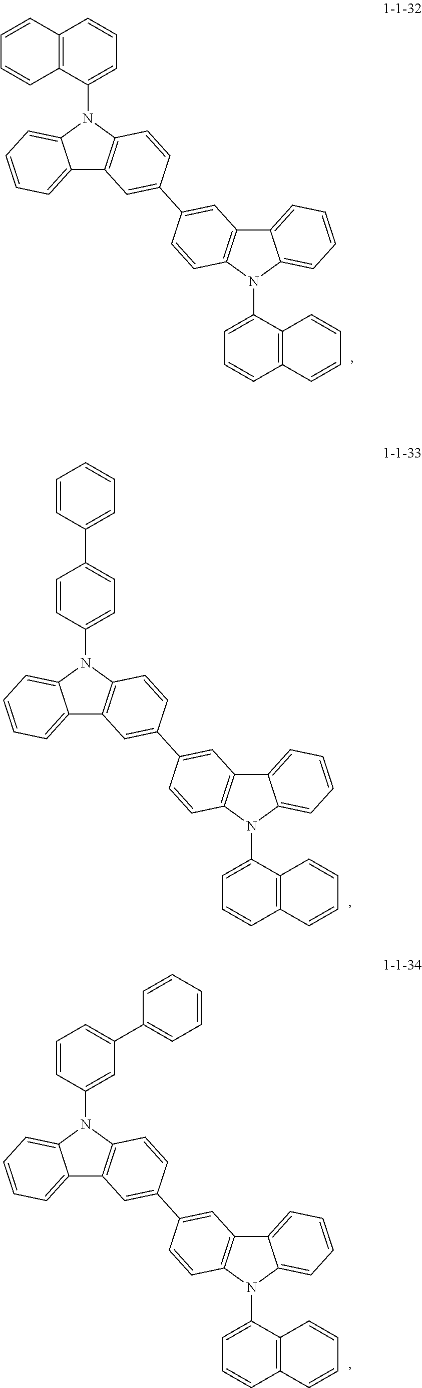 [SMILES: c1ccc2c(-n3c4ccccc4c4cc(-c5ccc6c(c5)c5ccccc5n6-c5cccc6ccccc56)ccc43)cccc2c1 ; c1ccc(-c2ccc(-n3c4ccccc4c4cc(-c5ccc6c(c5)c5ccccc5n6-c5cccc6ccccc56)ccc43)cc2)cc1 ; c1ccc(-c2cccc(-n3c4ccccc4c4cc(-c5ccc6c(c5)c5ccccc5n6-c5cccc6ccccc56)ccc43)c2)cc1]

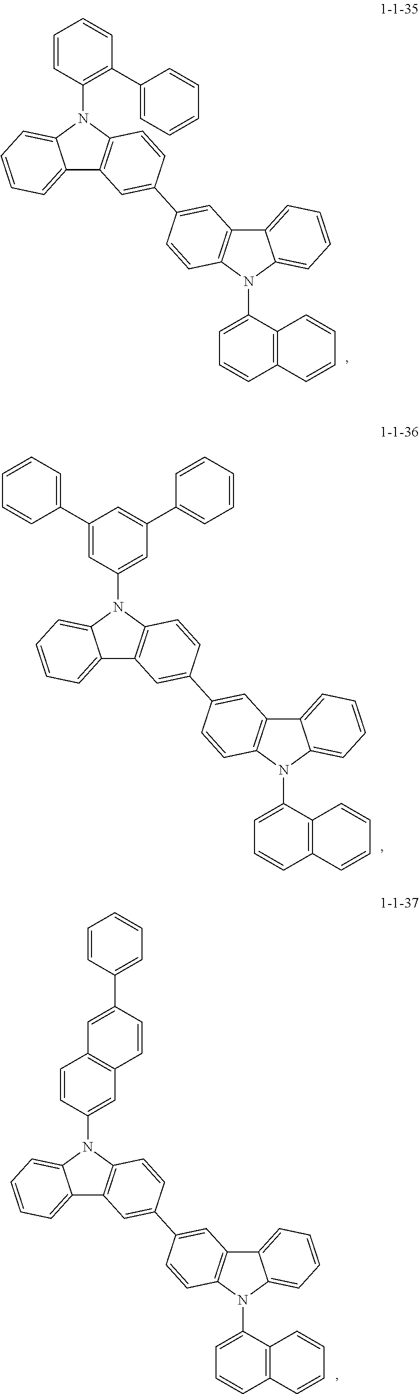 [SMILES: c1ccc(-c2ccccc2-n2c3ccccc3c3cc(-c4ccc5c(c4)c4ccccc4n5-c4cccc5ccccc45)ccc32)cc1 ; c1ccc(-c2cc(-c3ccccc3)cc(-n3c4ccccc4c4cc(-c5ccc6c(c5)c5ccccc5n6-c5cccc6ccccc56)ccc43)c2)cc1 ; c1ccc(-c2ccc3cc(-n4c5ccccc5c5cc(-c6ccc7c(c6)c6ccccc6n7-c6cccc7ccccc67)ccc54)ccc3c2)cc1]

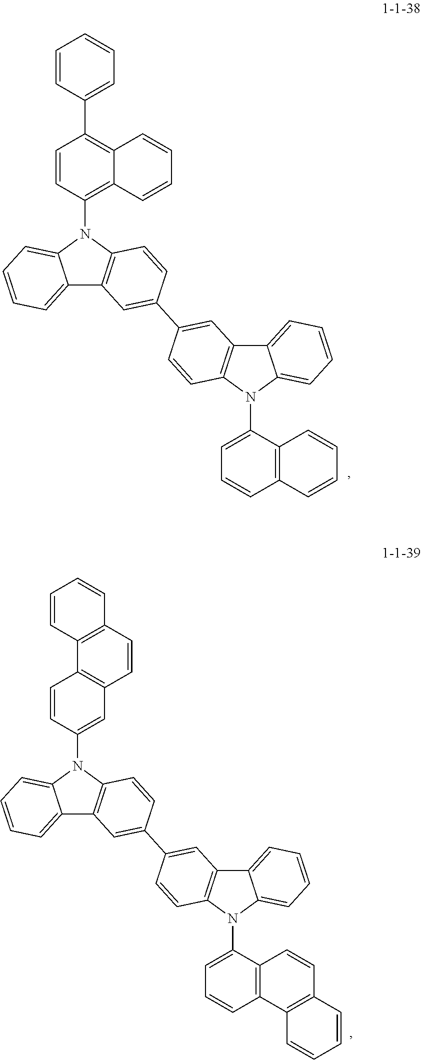 [SMILES: c1ccc(-c2ccc(-n3c4ccccc4c4cc(-c5ccc6c(c5)c5ccccc5n6-c5cccc6ccccc56)ccc43)c3ccccc23)cc1 ; c1ccc2c(c1)ccc1cc(-n3c4ccccc4c4cc(-c5ccc6c(c5)c5ccccc5n6-c5cccc6c5ccc5ccccc56)ccc43)ccc12]

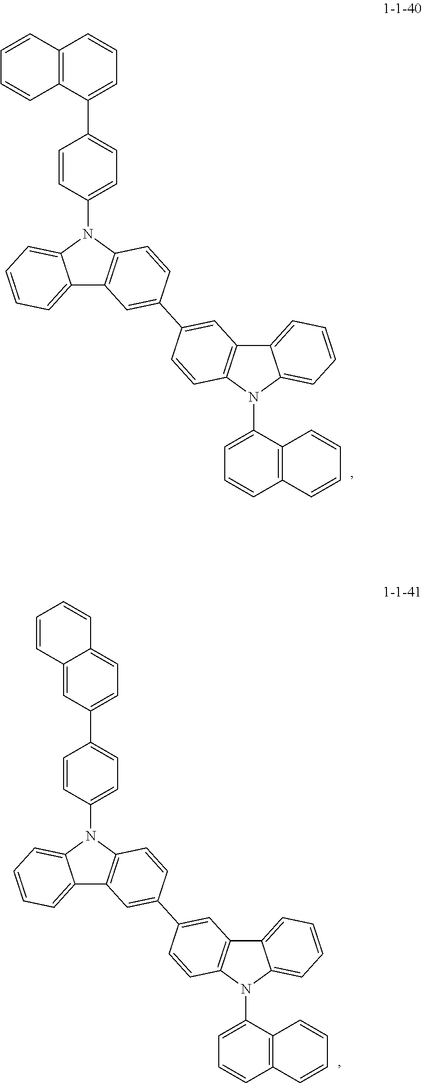 [SMILES: c1ccc2c(-c3ccc(-n4c5ccccc5c5cc(-c6ccc7c(c6)c6ccccc6n7-c6cccc7ccccc67)ccc54)cc3)cccc2c1 ; c1ccc2cc(-c3ccc(-n4c5ccccc5c5cc(-c6ccc7c(c6)c6ccccc6n7-c6cccc7ccccc67)ccc54)cc3)ccc2c1]

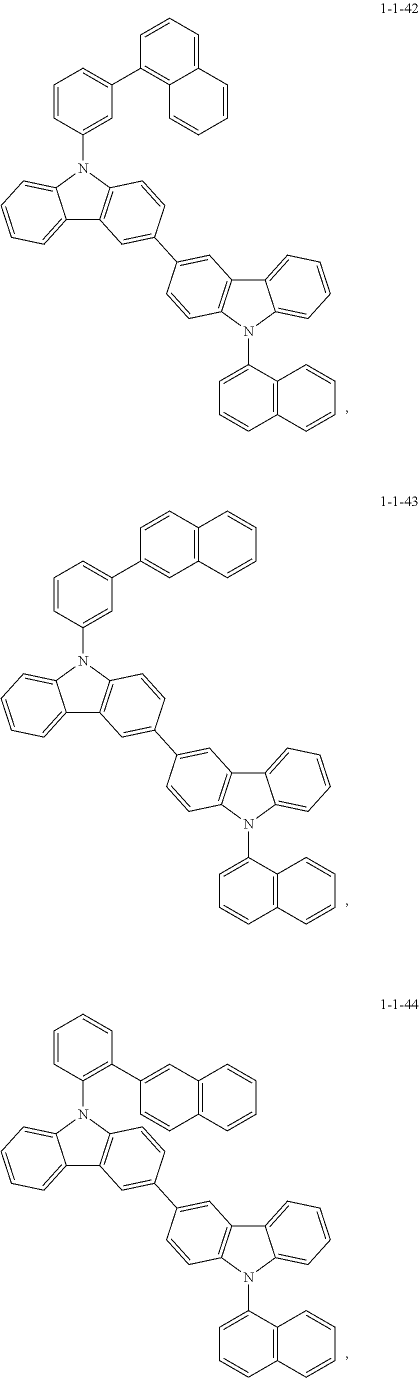 [SMILES: c1cc(-c2cccc3ccccc23)cc(-n2c3ccccc3c3cc(-c4ccc5c(c4)c4ccccc4n5-c4cccc5ccccc45)ccc32)c1 ; c1cc(-c2ccc3ccccc3c2)cc(-n2c3ccccc3c3cc(-c4ccc5c(c4)c4ccccc4n5-c4cccc5ccccc45)ccc32)c1 ; c1ccc(-n2c3ccccc3c3cc(-c4ccc5c(c4)c4ccccc4n5-c4cccc5ccccc45)ccc32)c(-c2ccc3ccccc3c2)c1]

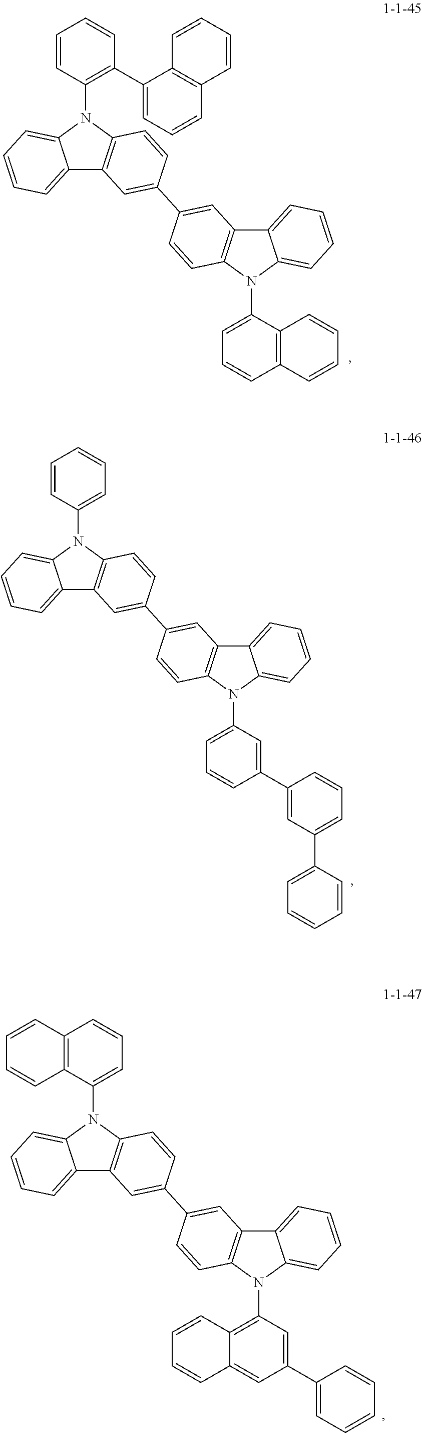 [SMILES: c1ccc(-n2c3ccccc3c3cc(-c4ccc5c(c4)c4ccccc4n5-c4cccc5ccccc45)ccc32)c(-c2cccc3ccccc23)c1 ; c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cc(-n3c4ccccc4c4cc(-c5ccc6c(c5)c5ccccc5n6-c5cccc6ccccc56)ccc43)c3ccccc3c2)cc1]

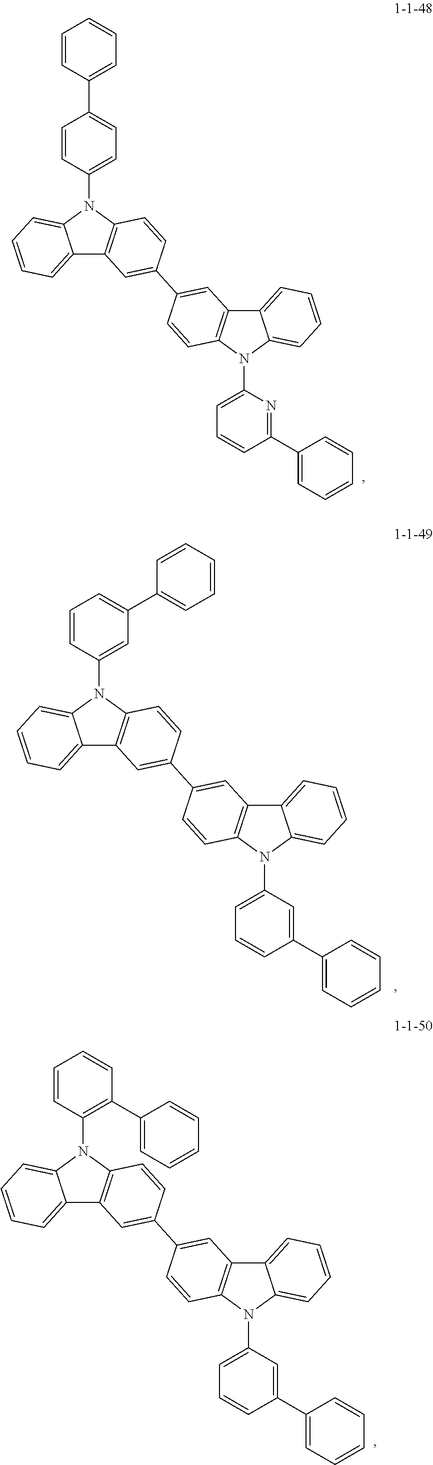 [SMILES: c1ccc(-c2ccc(-n3c4ccccc4c4cc(-c5ccc6c(c5)c5ccccc5n6-c5cccc(-c6ccccc6)n5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1]

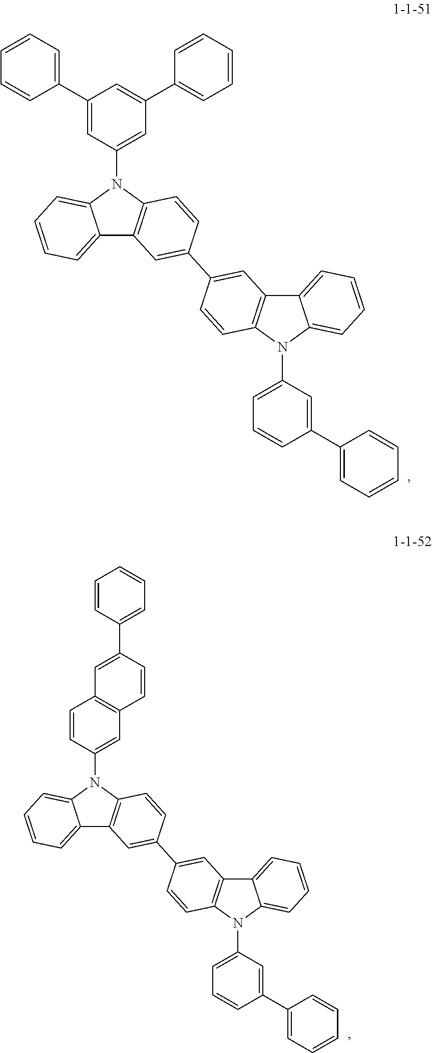 [SMILES: c1ccc(-c2cccc(-n3c4ccccc4c4cc(-c5ccc6c(c5)c5ccccc5n6-c5cc(-c6ccccc6)cc(-c6ccccc6)c5)ccc43)c2)cc1 ; c1ccc(-c2cccc(-n3c4ccccc4c4cc(-c5ccc6c(c5)c5ccccc5n6-c5ccc6cc(-c7ccccc7)ccc6c5)ccc43)c2)cc1]

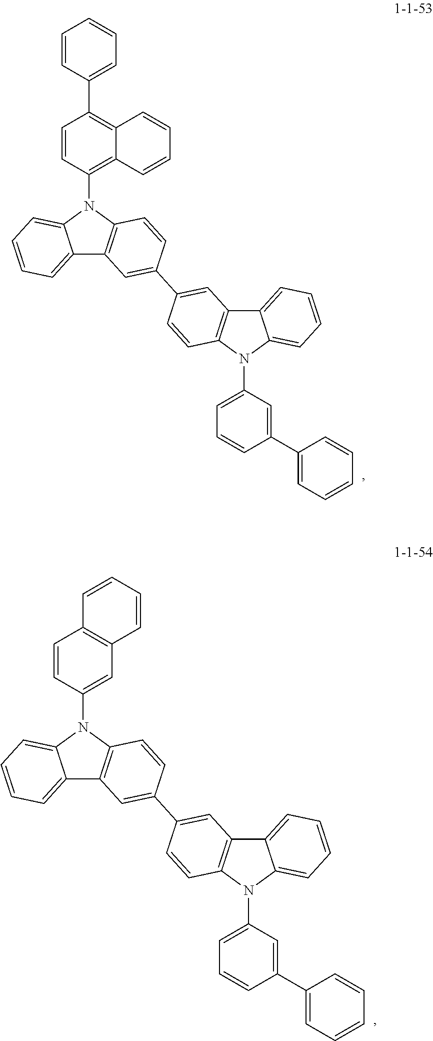 [SMILES: c1ccc(-c2cccc(-n3c4ccccc4c4cc(-c5ccc6c(c5)c5ccccc5n6-c5ccc(-c6ccccc6)c6ccccc56)ccc43)c2)cc1 ; c1ccc(-c2cccc(-n3c4ccccc4c4cc(-c5ccc6c(c5)c5ccccc5n6-c5ccc6ccccc6c5)ccc43)c2)cc1]

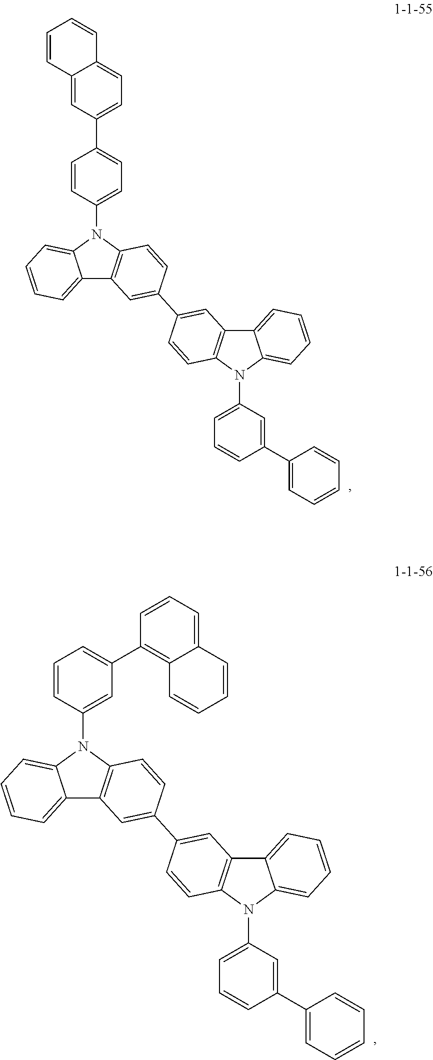 [SMILES: c1ccc(-c2cccc(-n3c4ccccc4c4cc(-c5ccc6c(c5)c5ccccc5n6-c5ccc(-c6ccc7ccccc7c6)cc5)ccc43)c2)cc1 ; c1ccc(-c2cccc(-n3c4ccccc4c4cc(-c5ccc6c(c5)c5ccccc5n6-c5cccc(-c6cccc7ccccc67)c5)ccc43)c2)cc1]

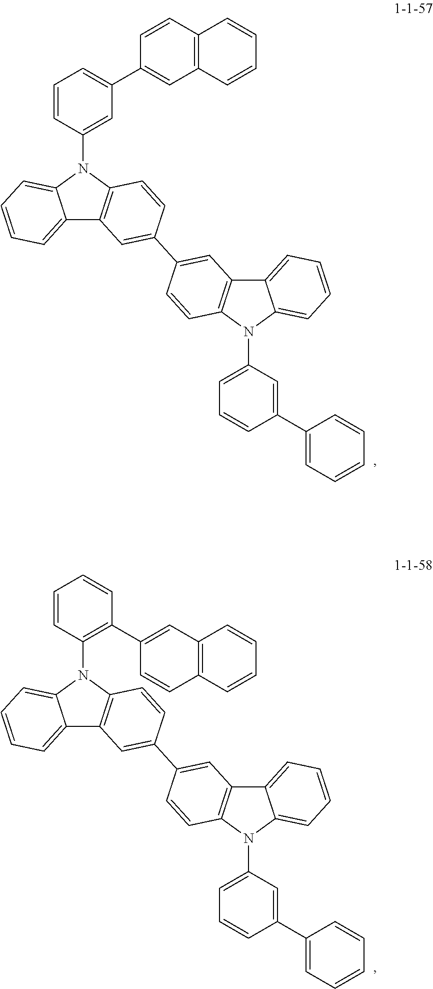 [SMILES: c1ccc(-c2cccc(-n3c4ccccc4c4cc(-c5ccc6c(c5)c5ccccc5n6-c5cccc(-c6ccc7ccccc7c6)c5)ccc43)c2)cc1 ; c1ccc(-c2cccc(-n3c4ccccc4c4cc(-c5ccc6c(c5)c5ccccc5n6-c5ccccc5-c5ccc6ccccc6c5)ccc43)c2)cc1]

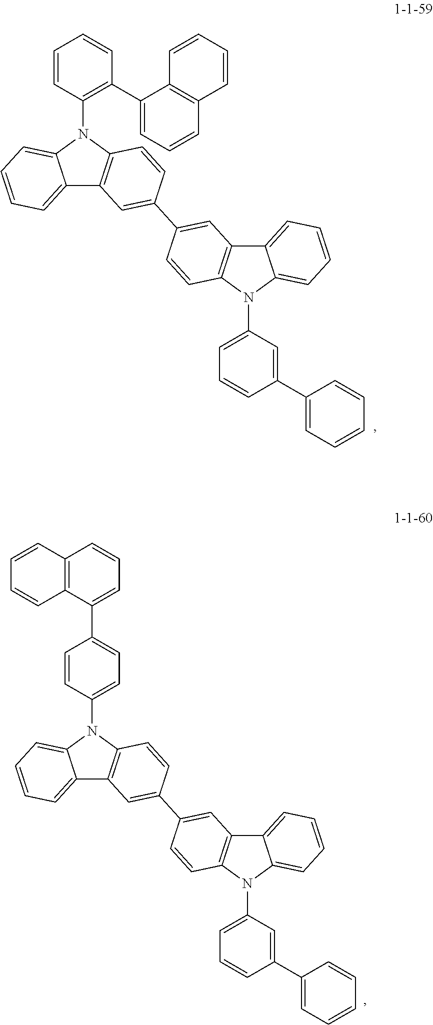 [SMILES: c1ccc(-c2cccc(-n3c4ccccc4c4cc(-c5ccc6c(c5)c5ccccc5n6-c5ccccc5-c5cccc6ccccc56)ccc43)c2)cc1 ; c1ccc(-c2cccc(-n3c4ccccc4c4cc(-c5ccc6c(c5)c5ccccc5n6-c5ccc(-c6cccc7ccccc67)cc5)ccc43)c2)cc1]

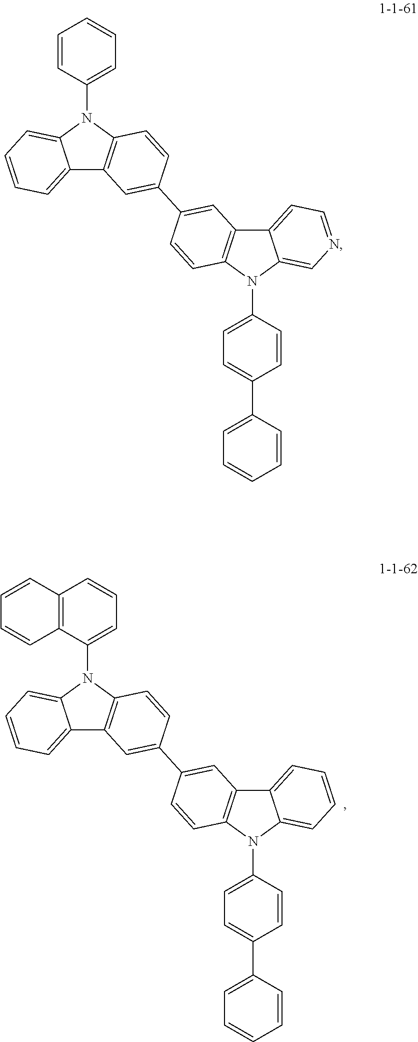 [SMILES: c1ccc(-c2ccc(-n3c4ccc(-c5ccc6c(c5)c5ccccc5n6-c5ccccc5)cc4c4ccncc43)cc2)cc1 ; c1ccc(-c2ccc(-n3c4ccccc4c4cc(-c5ccc6c(c5)c5ccccc5n6-c5cccc6ccccc56)ccc43)cc2)cc1]

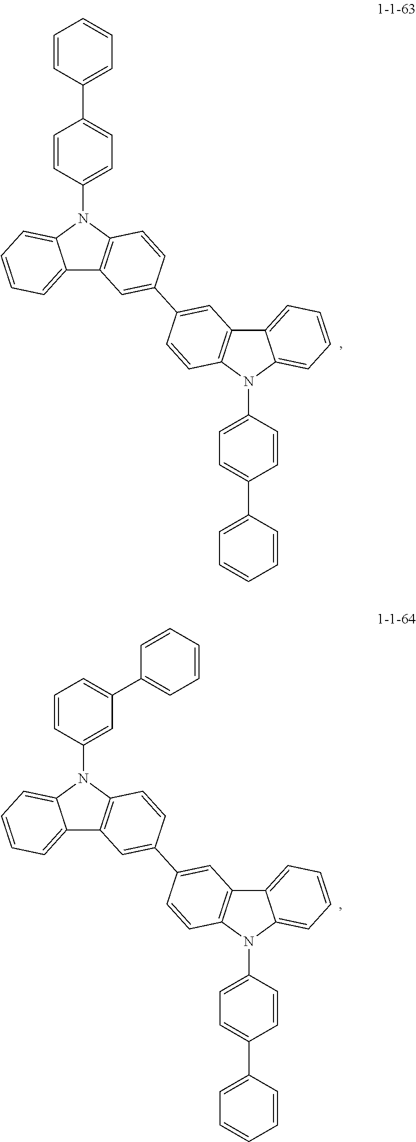 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

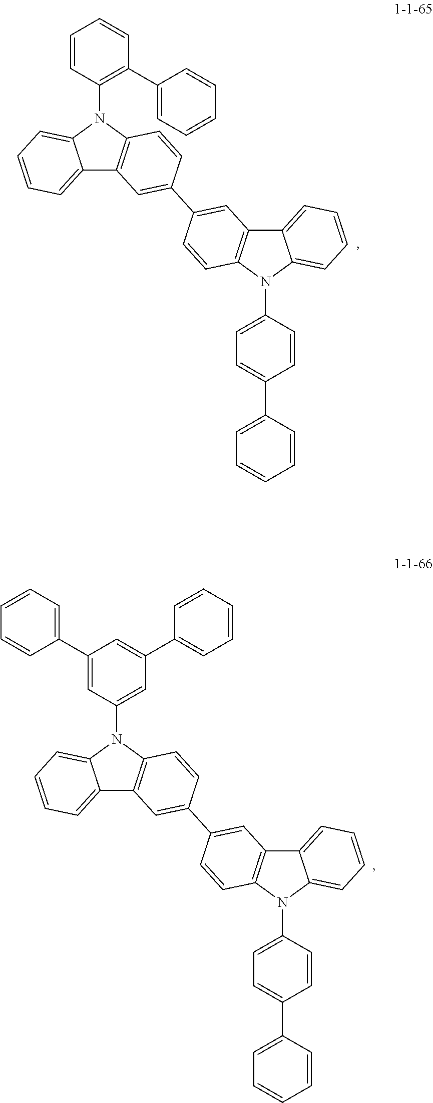 [SMILES: c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5cc(-c6ccccc6)cc(-c6ccccc6)c5)ccc43)cc2)cc1]

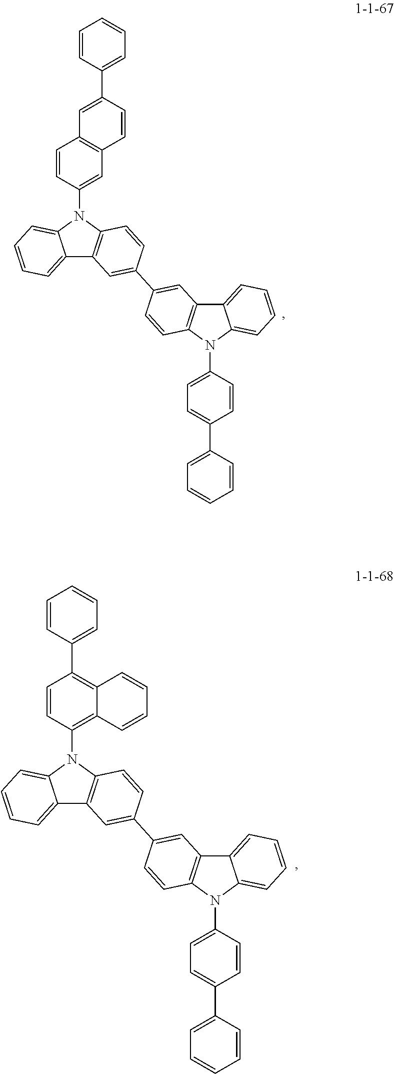 [SMILES: c1ccc(-c2ccc(-n3c4ccccc4c4cc(-c5ccc6c(c5)c5ccccc5n6-c5ccc6cc(-c7ccccc7)ccc6c5)ccc43)cc2)cc1 ; c1ccc(-c2ccc(-n3c4ccccc4c4cc(-c5ccc6c(c5)c5ccccc5n6-c5ccc(-c6ccccc6)c6ccccc56)ccc43)cc2)cc1]

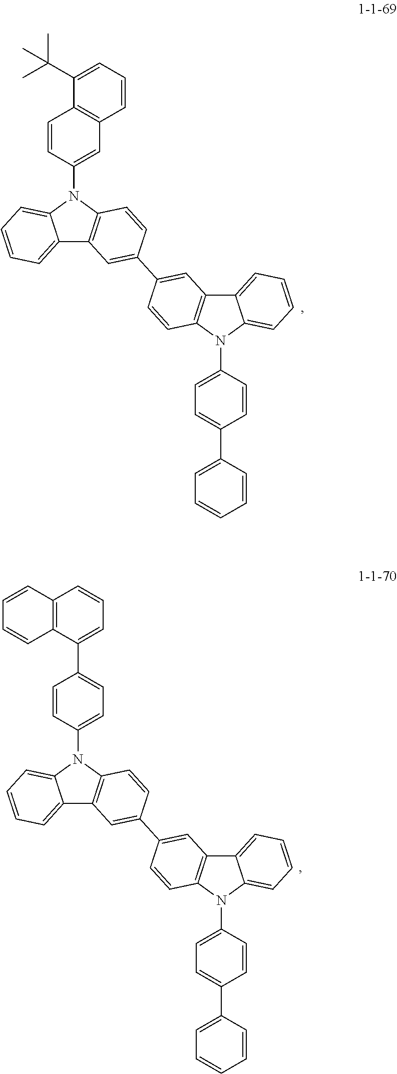 [SMILES: CC(C)(C)c1cccc2cc(-n3c4ccccc4c4cc(-c5ccc6c(c5)c5ccccc5n6-c5ccc(-c6ccccc6)cc5)ccc43)ccc12 ; c1ccc(-c2ccc(-n3c4ccccc4c4cc(-c5ccc6c(c5)c5ccccc5n6-c5ccc(-c6cccc7ccccc67)cc5)ccc43)cc2)cc1]

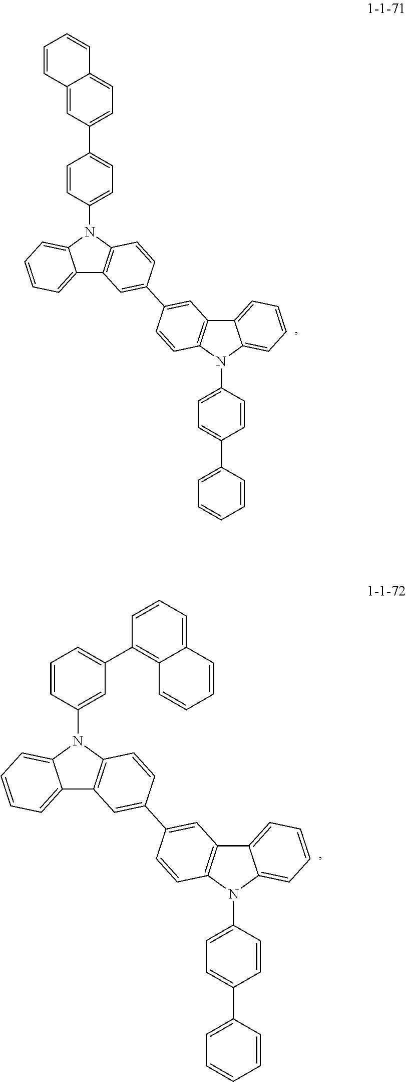 [SMILES: c1ccc(-c2ccc(-n3c4ccccc4c4cc(-c5ccc6c(c5)c5ccccc5n6-c5ccc(-c6ccc7ccccc7c6)cc5)ccc43)cc2)cc1 ; c1ccc(-c2ccc(-n3c4ccccc4c4cc(-c5ccc6c(c5)c5ccccc5n6-c5cccc(-c6cccc7ccccc67)c5)ccc43)cc2)cc1]

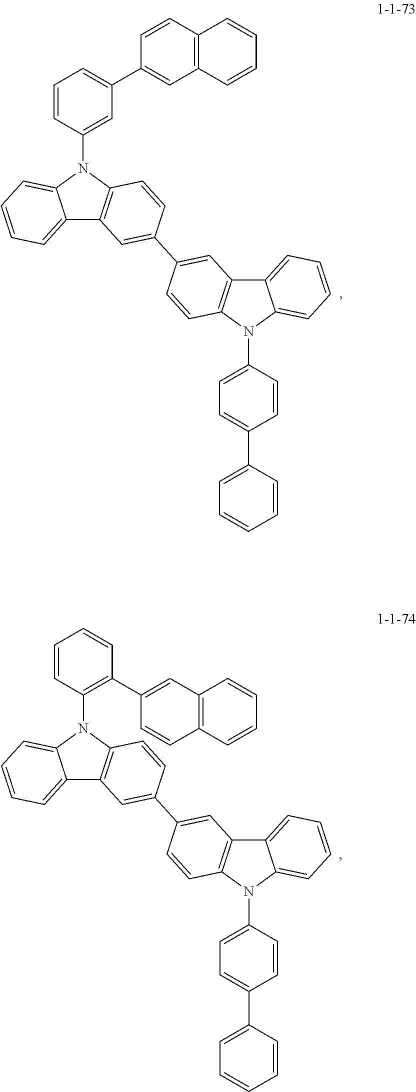 [SMILES: c1ccc(-c2ccc(-n3c4ccccc4c4cc(-c5ccc6c(c5)c5ccccc5n6-c5cccc(-c6ccc7ccccc7c6)c5)ccc43)cc2)cc1 ; c1ccc(-c2ccc(-n3c4ccccc4c4cc(-c5ccc6c(c5)c5ccccc5n6-c5ccccc5-c5ccc6ccccc6c5)ccc43)cc2)cc1]

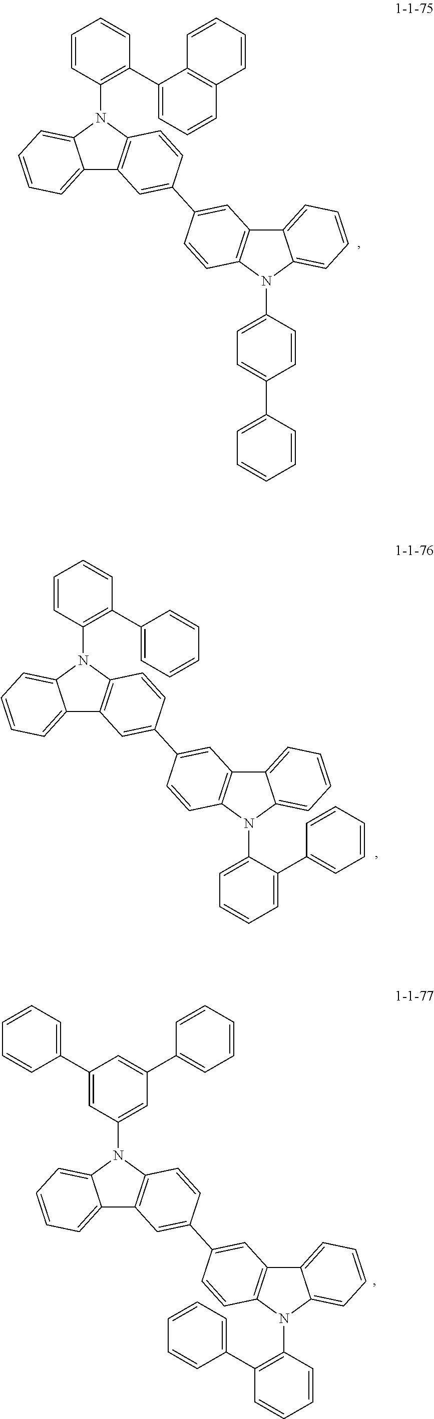 [SMILES: c1ccc(-c2ccc(-n3c4ccccc4c4cc(-c5ccc6c(c5)c5ccccc5n6-c5ccccc5-c5cccc6ccccc56)ccc43)cc2)cc1 ; c1ccc(-c2ccccc2-n2c3ccccc3c3cc(-c4ccc5c(c4)c4ccccc4n5-c4ccccc4-c4ccccc4)ccc32)cc1 ; c1ccc(-c2cc(-c3ccccc3)cc(-n3c4ccccc4c4cc(-c5ccc6c(c5)c5ccccc5n6-c5ccccc5-c5ccccc5)ccc43)c2)cc1]

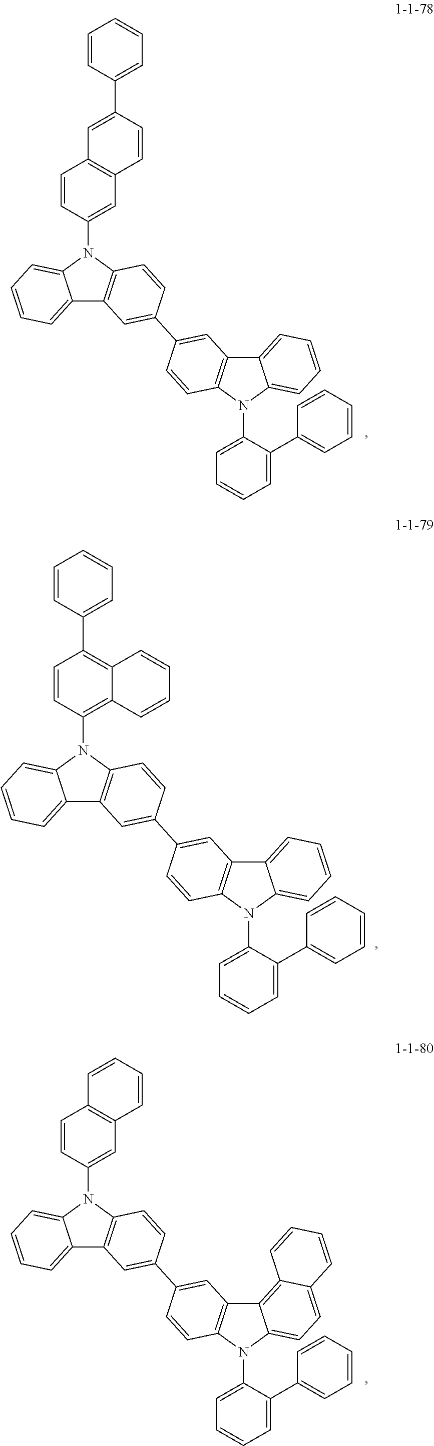 [SMILES: c1ccc(-c2ccc3cc(-n4c5ccccc5c5cc(-c6ccc7c(c6)c6ccccc6n7-c6ccccc6-c6ccccc6)ccc54)ccc3c2)cc1 ; c1ccc(-c2ccccc2-n2c3ccccc3c3cc(-c4ccc5c(c4)c4ccccc4n5-c4ccc(-c5ccccc5)c5ccccc45)ccc32)cc1 ; c1ccc(-c2ccccc2-n2c3ccc(-c4ccc5c(c4)c4ccccc4n5-c4ccc5ccccc5c4)cc3c3c4ccccc4ccc32)cc1]

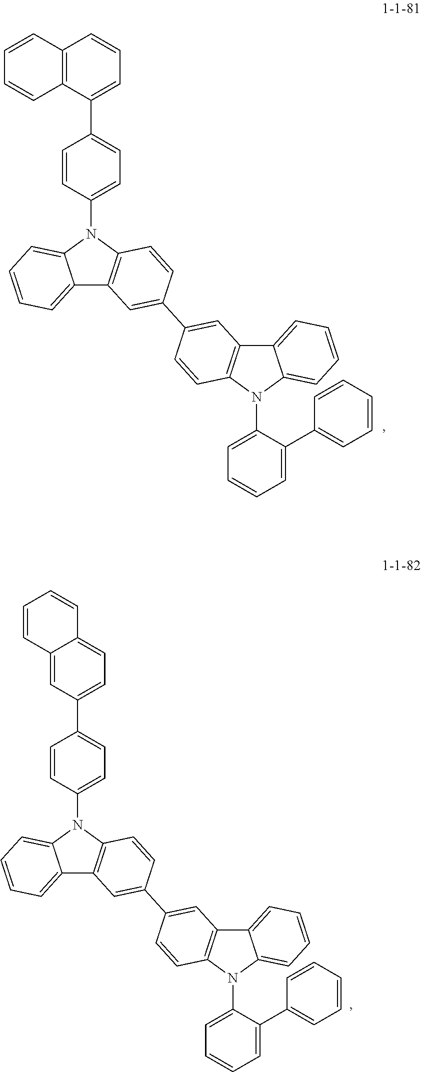 [SMILES: c1ccc(-c2ccccc2-n2c3ccccc3c3cc(-c4ccc5c(c4)c4ccccc4n5-c4ccc(-c5cccc6ccccc56)cc4)ccc32)cc1 ; c1ccc(-c2ccccc2-n2c3ccccc3c3cc(-c4ccc5c(c4)c4ccccc4n5-c4ccc(-c5ccc6ccccc6c5)cc4)ccc32)cc1]

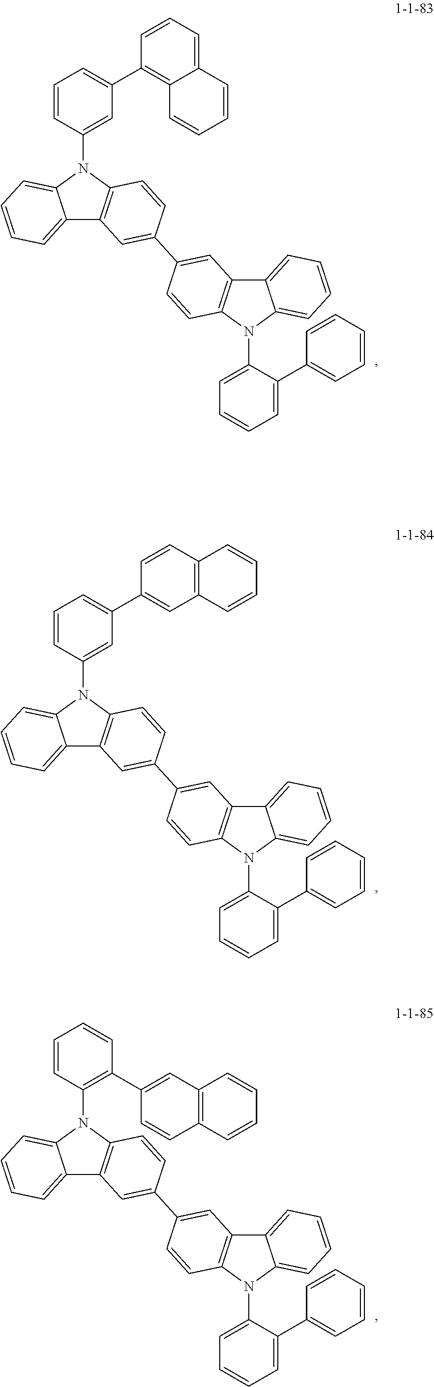 [SMILES: c1ccc(-c2ccccc2-n2c3ccccc3c3cc(-c4ccc5c(c4)c4ccccc4n5-c4cccc(-c5cccc6ccccc56)c4)ccc32)cc1 ; c1ccc(-c2ccccc2-n2c3ccccc3c3cc(-c4ccc5c(c4)c4ccccc4n5-c4cccc(-c5ccc6ccccc6c5)c4)ccc32)cc1 ; c1ccc(-c2ccccc2-n2c3ccccc3c3cc(-c4ccc5c(c4)c4ccccc4n5-c4ccccc4-c4ccc5ccccc5c4)ccc32)cc1]

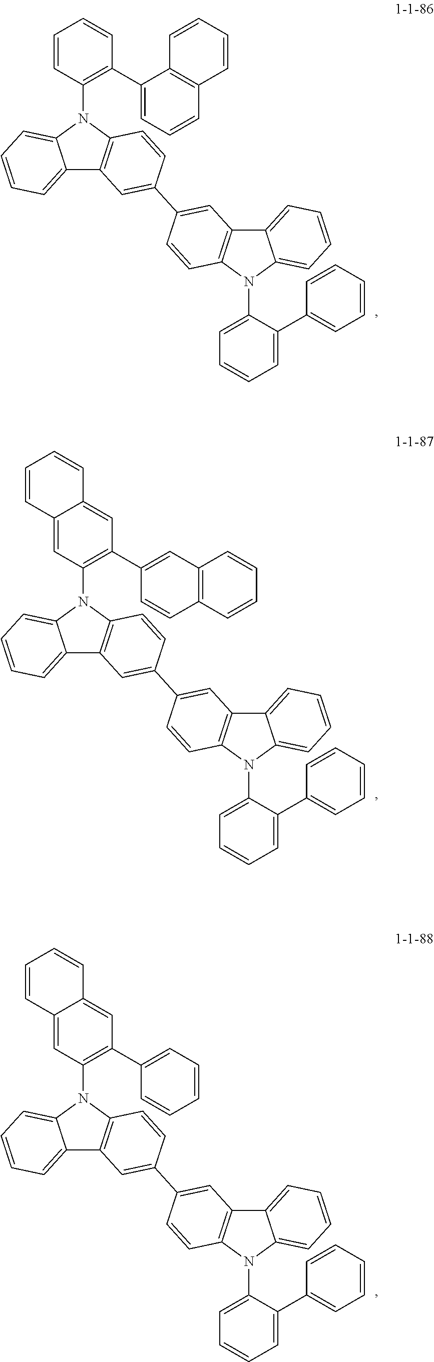 [SMILES: c1ccc(-c2ccccc2-n2c3ccccc3c3cc(-c4ccc5c(c4)c4ccccc4n5-c4ccccc4-c4cccc5ccccc45)ccc32)cc1 ; c1ccc(-c2ccccc2-n2c3ccccc3c3cc(-c4ccc5c(c4)c4ccccc4n5-c4cc5ccccc5cc4-c4ccc5ccccc5c4)ccc32)cc1 ; c1ccc(-c2ccccc2-n2c3ccccc3c3cc(-c4ccc5c(c4)c4ccccc4n5-c4cc5ccccc5cc4-c4ccccc4)ccc32)cc1]

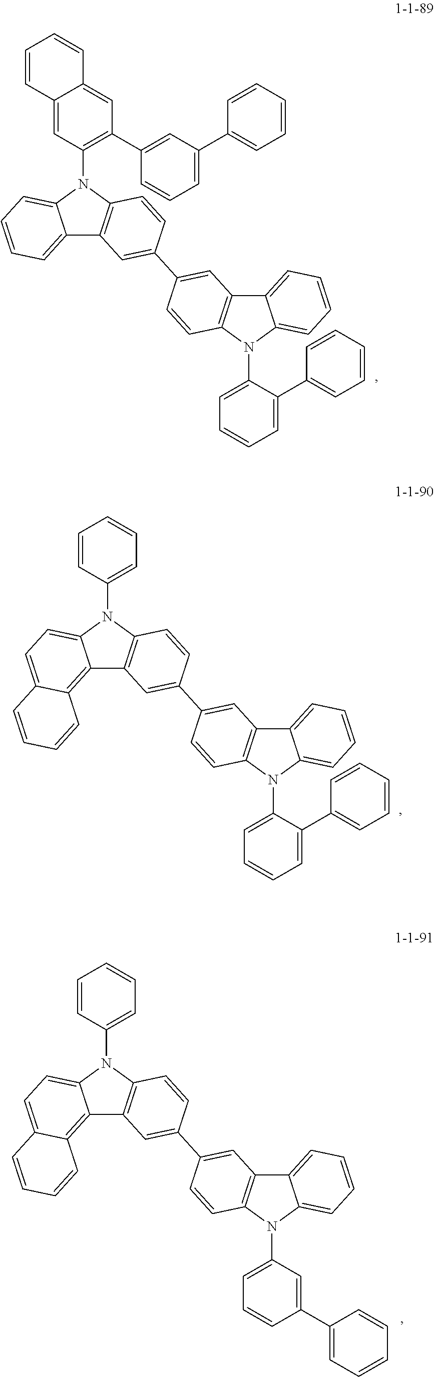 [SMILES: c1ccc(-c2cccc(-c3cc4ccccc4cc3-n3c4ccccc4c4cc(-c5ccc6c(c5)c5ccccc5n6-c5ccccc5-c5ccccc5)ccc43)c2)cc1 ; c1ccc(-c2ccccc2-n2c3ccccc3c3cc(-c4ccc5c(c4)c4c6ccccc6ccc4n5-c4ccccc4)ccc32)cc1 ; c1ccc(-c2cccc(-n3c4ccccc4c4cc(-c5ccc6c(c5)c5c7ccccc7ccc5n6-c5ccccc5)ccc43)c2)cc1]

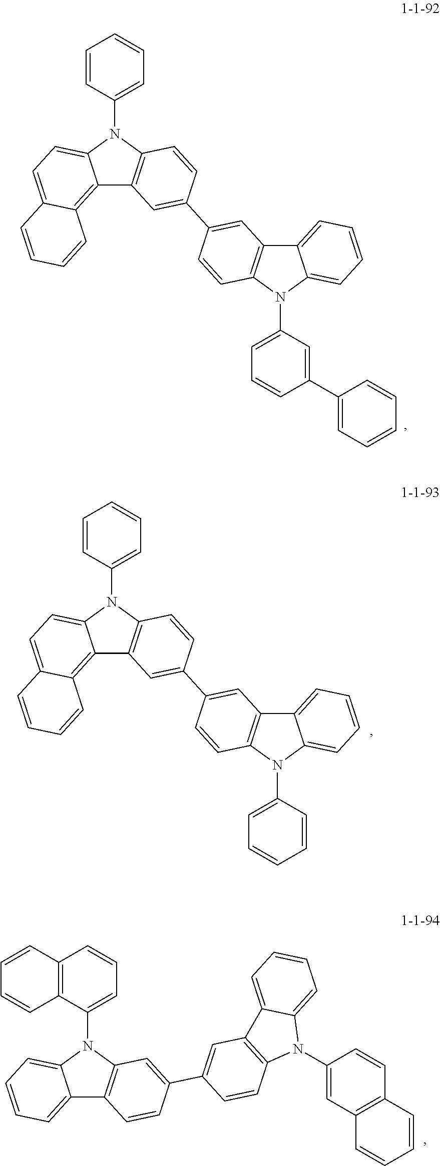 [SMILES: c1ccc(-c2cccc(-n3c4ccccc4c4cc(-c5ccc6c(c5)c5c7ccccc7ccc5n6-c5ccccc5)ccc43)c2)cc1 ; c1ccc(-n2c3ccccc3c3cc(-c4ccc5c(c4)c4c6ccccc6ccc4n5-c4ccccc4)ccc32)cc1 ; c1ccc2cc(-n3c4ccccc4c4cc(-c5ccc6c7ccccc7n(-c7cccc8ccccc78)c6c5)ccc43)ccc2c1]

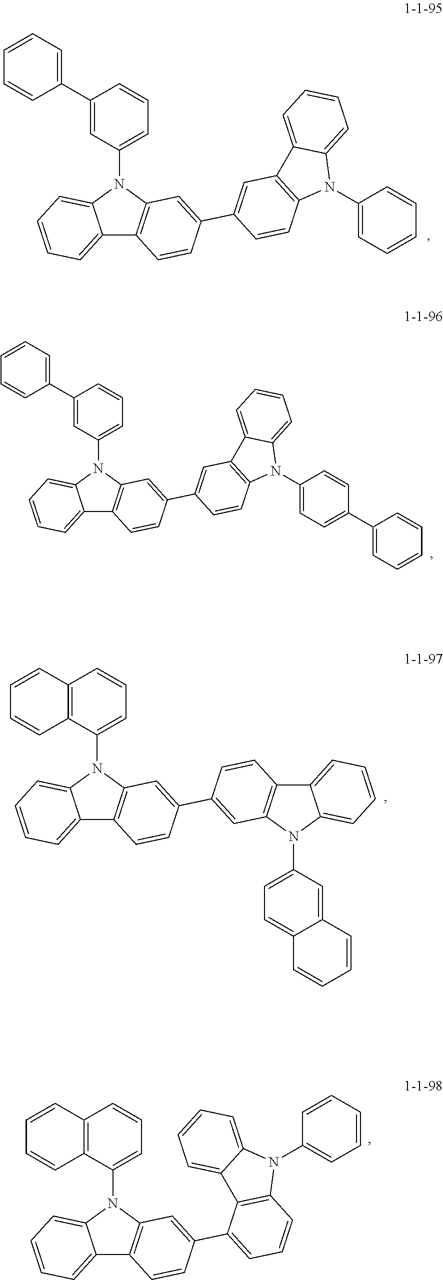 [SMILES: c1ccc(-c2cccc(-n3c4ccccc4c4ccc(-c5ccc6c(c5)c5ccccc5n6-c5ccccc5)cc43)c2)cc1 ; c1ccc(-c2ccc(-n3c4ccccc4c4cc(-c5ccc6c7ccccc7n(-c7cccc(-c8ccccc8)c7)c6c5)ccc43)cc2)cc1 ; c1ccc2cc(-n3c4ccccc4c4ccc(-c5ccc6c7ccccc7n(-c7cccc8ccccc78)c6c5)cc43)ccc2c1 ; c1ccc(-n2c3ccccc3c3c(-c4ccc5c6ccccc6n(-c6cccc7ccccc67)c5c4)cccc32)cc1]

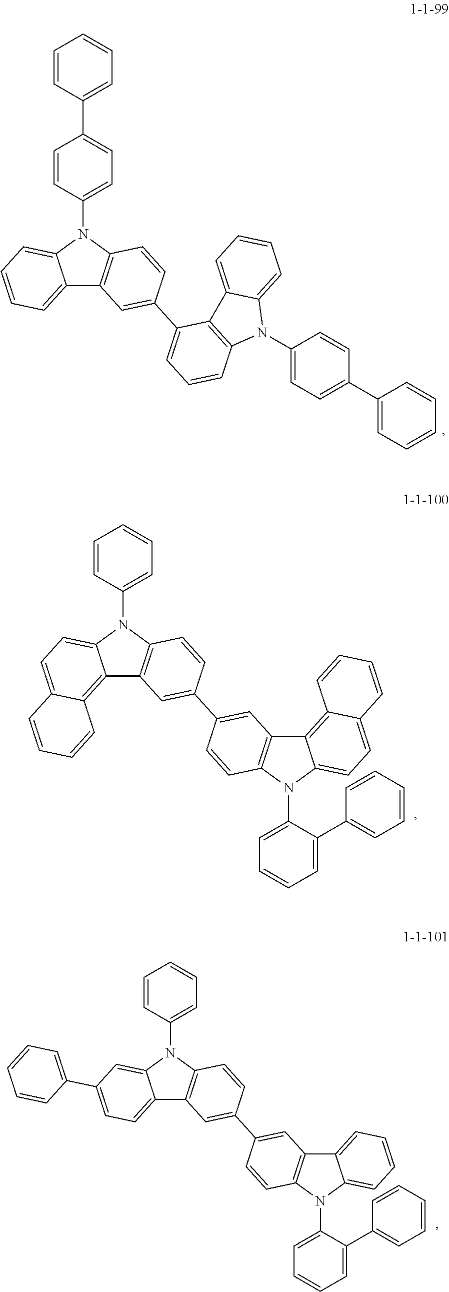 [SMILES: c1ccc(-c2ccc(-n3c4ccccc4c4cc(-c5cccc6c5c5ccccc5n6-c5ccc(-c6ccccc6)cc5)ccc43)cc2)cc1 ; c1ccc(-c2ccccc2-n2c3ccc(-c4ccc5c(c4)c4c6ccccc6ccc4n5-c4ccccc4)cc3c3c4ccccc4ccc32)cc1 ; c1ccc(-c2ccc3c4cc(-c5ccc6c(c5)c5ccccc5n6-c5ccccc5-c5ccccc5)ccc4n(-c4ccccc4)c3c2)cc1]

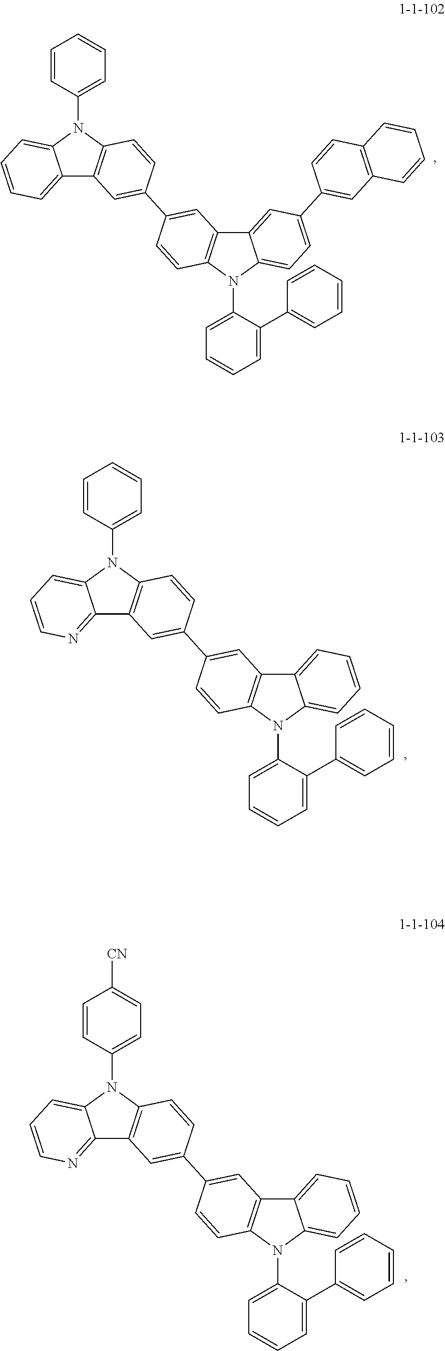 [SMILES: c1ccc(-c2ccccc2-n2c3ccc(-c4ccc5ccccc5c4)cc3c3cc(-c4ccc5c(c4)c4ccccc4n5-c4ccccc4)ccc32)cc1 ; c1ccc(-c2ccccc2-n2c3ccccc3c3cc(-c4ccc5c(c4)c4ncccc4n5-c4ccccc4)ccc32)cc1 ; N#Cc1ccc(-n2c3ccc(-c4ccc5c(c4)c4ccccc4n5-c4ccccc4-c4ccccc4)cc3c3ncccc32)cc1]

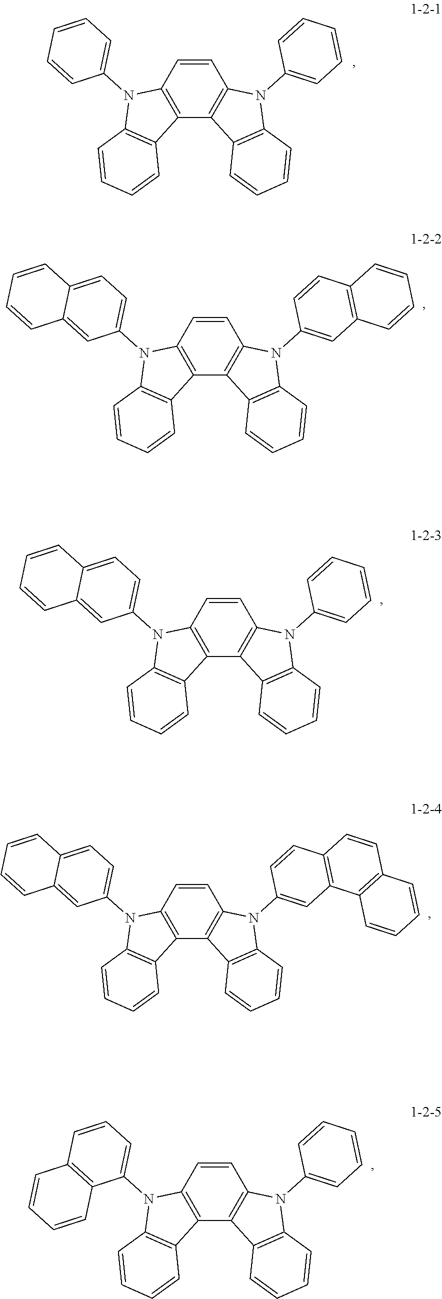 [SMILES: c1ccc(-n2c3ccccc3c3c4c5ccccc5n(-c5ccccc5)c4ccc32)cc1 ; c1ccc2cc(-n3c4ccccc4c4c5c6ccccc6n(-c6ccc7ccccc7c6)c5ccc43)ccc2c1 ; c1ccc(-n2c3ccccc3c3c4c5ccccc5n(-c5ccc6ccccc6c5)c4ccc32)cc1 ; c1ccc2cc(-n3c4ccccc4c4c5c6ccccc6n(-c6ccc7ccc8ccccc8c7c6)c5ccc43)ccc2c1 ; c1ccc(-n2c3ccccc3c3c4c5ccccc5n(-c5cccc6ccccc56)c4ccc32)cc1]

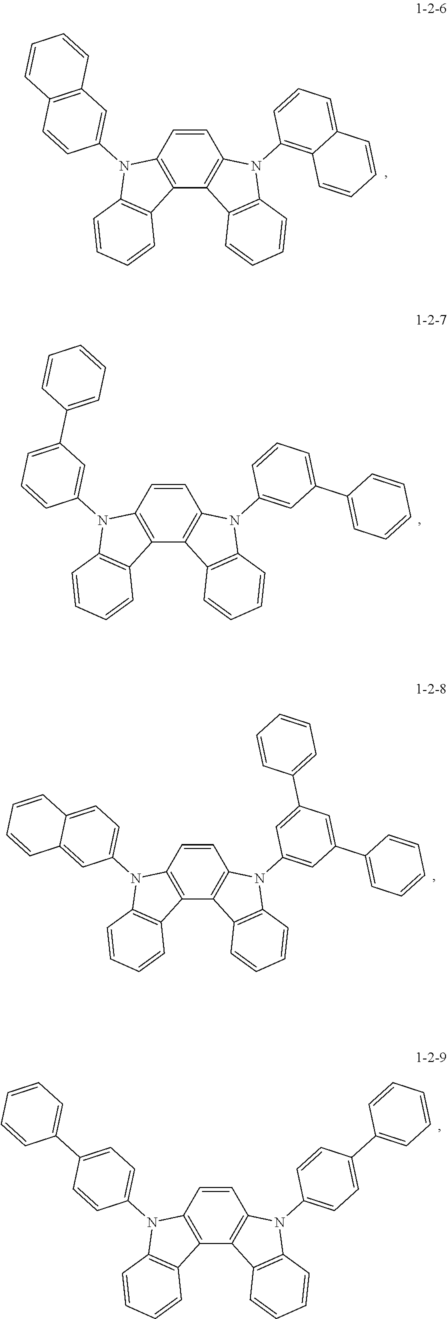 [SMILES: c1ccc2cc(-n3c4ccccc4c4c5c6ccccc6n(-c6cccc7ccccc67)c5ccc43)ccc2c1 ; c1ccc(-c2cccc(-n3c4ccccc4c4c5c6ccccc6n(-c6cccc(-c7ccccc7)c6)c5ccc43)c2)cc1 ; c1ccc(-c2cc(-c3ccccc3)cc(-n3c4ccccc4c4c5c6ccccc6n(-c6ccc7ccccc7c6)c5ccc43)c2)cc1 ; c1ccc(-c2ccc(-n3c4ccccc4c4c5c6ccccc6n(-c6ccc(-c7ccccc7)cc6)c5ccc43)cc2)cc1]

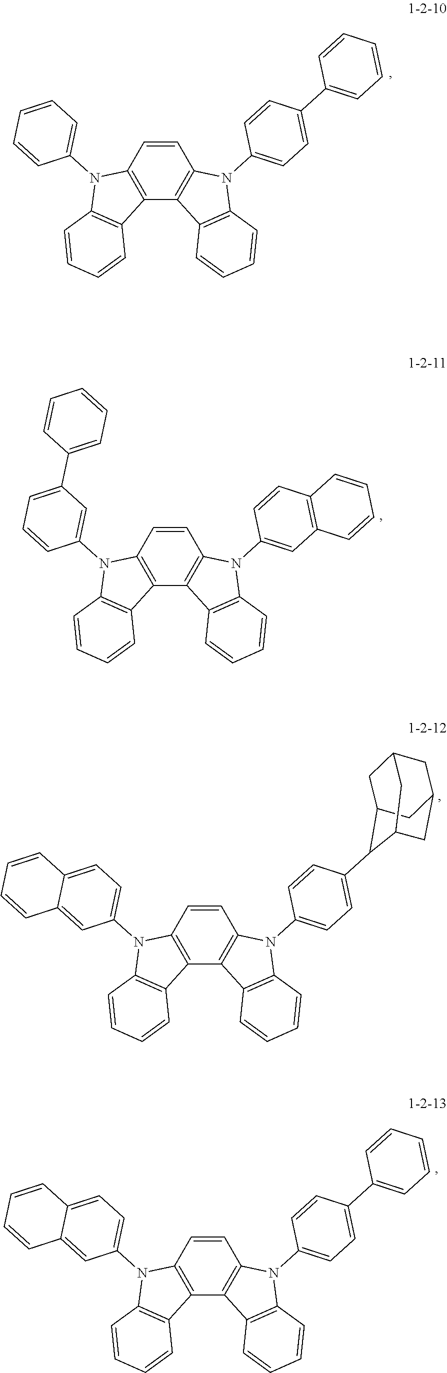 [SMILES: c1ccc(-c2ccc(-n3c4ccccc4c4c5c6ccccc6n(-c6ccccc6)c5ccc43)cc2)cc1 ; c1ccc(-c2cccc(-n3c4ccccc4c4c5c6ccccc6n(-c6ccc7ccccc7c6)c5ccc43)c2)cc1 ; c1ccc2cc(-n3c4ccccc4c4c5c6ccccc6n(-c6ccc(C7C8CC9CC(C8)CC7C9)cc6)c5ccc43)ccc2c1 ; c1ccc(-c2ccc(-n3c4ccccc4c4c5c6ccccc6n(-c6ccc7ccccc7c6)c5ccc43)cc2)cc1]

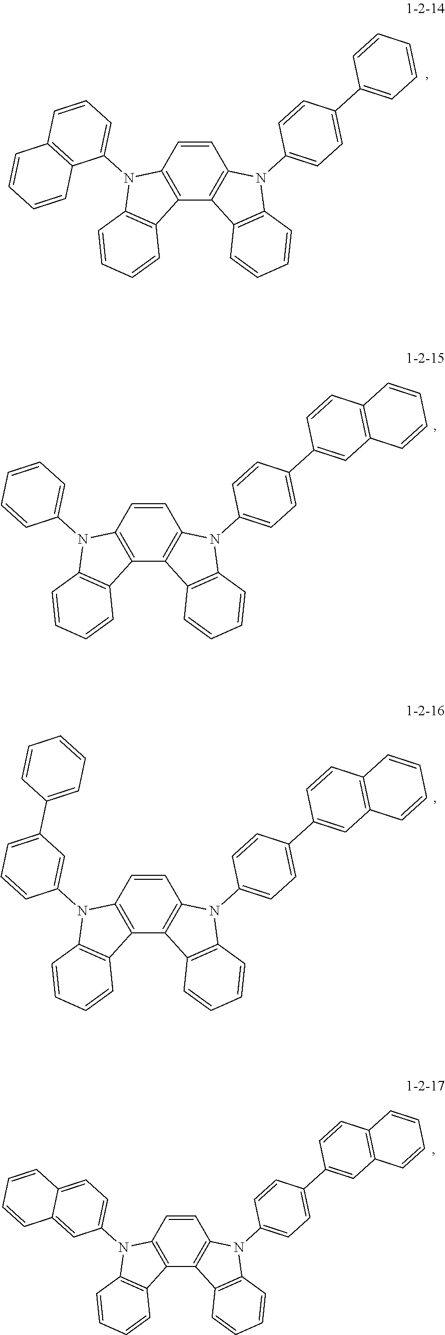 [SMILES: c1ccc(-c2ccc(-n3c4ccccc4c4c5c6ccccc6n(-c6cccc7ccccc67)c5ccc43)cc2)cc1 ; c1ccc(-n2c3ccccc3c3c4c5ccccc5n(-c5ccc(-c6ccc7ccccc7c6)cc5)c4ccc32)cc1 ; c1ccc(-c2cccc(-n3c4ccccc4c4c5c6ccccc6n(-c6ccc(-c7ccc8ccccc8c7)cc6)c5ccc43)c2)cc1 ; c1ccc2cc(-c3ccc(-n4c5ccccc5c5c6c7ccccc7n(-c7ccc8ccccc8c7)c6ccc54)cc3)ccc2c1]

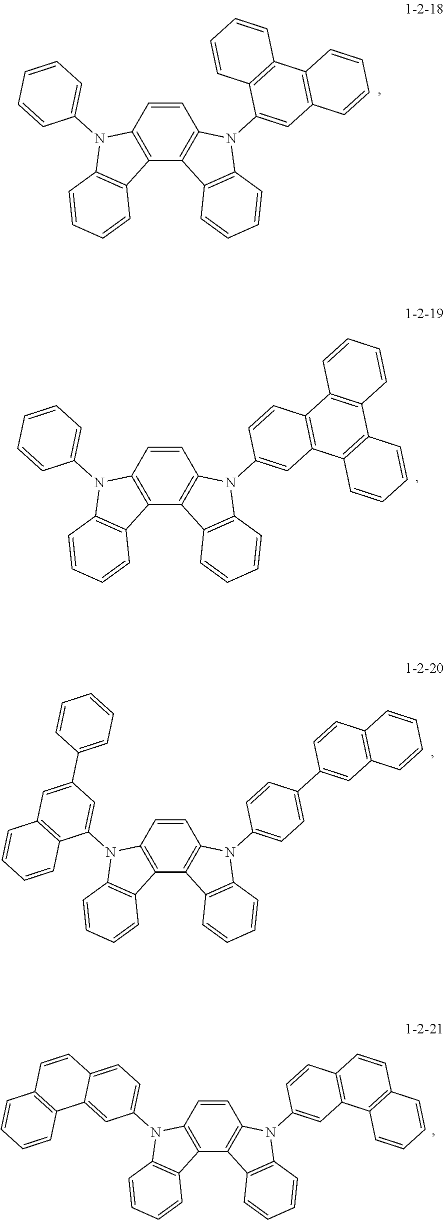 [SMILES: c1ccc(-n2c3ccccc3c3c4c5ccccc5n(-c5cc6ccccc6c6ccccc56)c4ccc32)cc1 ; c1ccc(-n2c3ccccc3c3c4c5ccccc5n(-c5ccc6c7ccccc7c7ccccc7c6c5)c4ccc32)cc1 ; c1ccc(-c2cc(-n3c4ccccc4c4c5c6ccccc6n(-c6ccc(-c7ccc8ccccc8c7)cc6)c5ccc43)c3ccccc3c2)cc1 ; c1ccc2c(c1)ccc1ccc(-n3c4ccccc4c4c5c6ccccc6n(-c6ccc7ccc8ccccc8c7c6)c5ccc43)cc12]

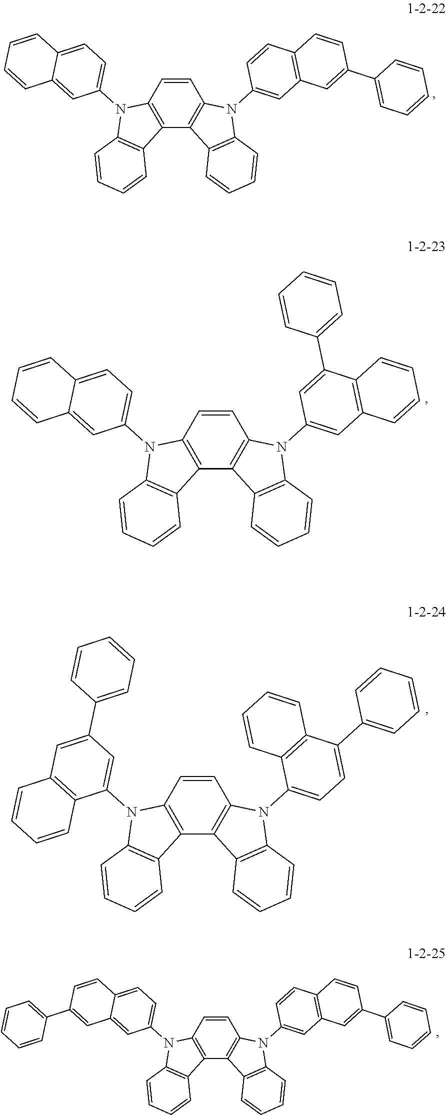 [SMILES: c1ccc(-c2ccc3ccc(-n4c5ccccc5c5c6c7ccccc7n(-c7ccc8ccccc8c7)c6ccc54)cc3c2)cc1 ; c1ccc(-c2cc(-n3c4ccccc4c4c5c6ccccc6n(-c6ccc7ccccc7c6)c5ccc43)cc3ccccc23)cc1 ; c1ccc(-c2cc(-n3c4ccccc4c4c5c6ccccc6n(-c6ccc(-c7ccccc7)c7ccccc67)c5ccc43)c3ccccc3c2)cc1 ; c1ccc(-c2ccc3ccc(-n4c5ccccc5c5c6c7ccccc7n(-c7ccc8ccc(-c9ccccc9)cc8c7)c6ccc54)cc3c2)cc1]

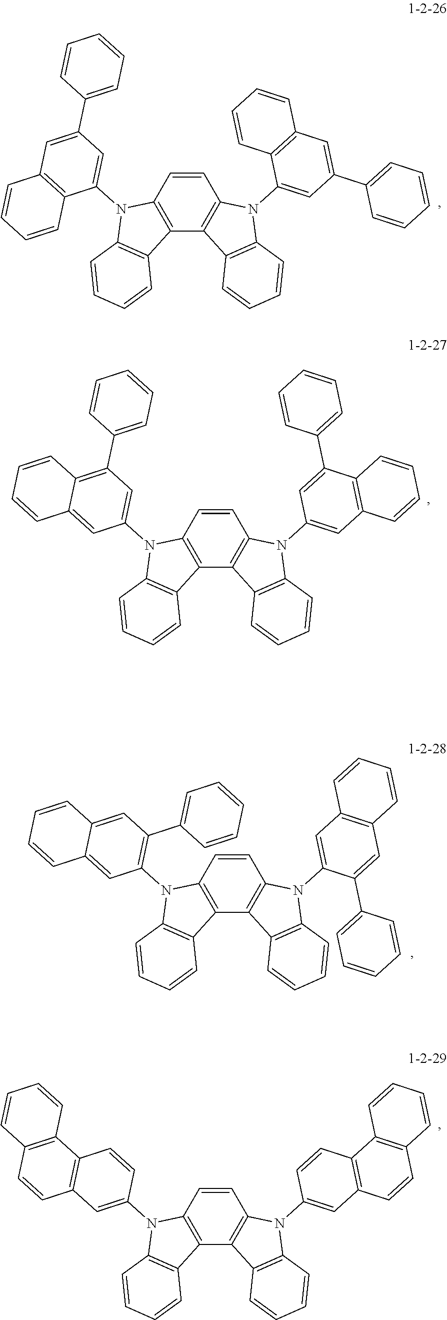 [SMILES: c1ccc(-c2cc(-n3c4ccccc4c4c5c6ccccc6n(-c6cc(-c7ccccc7)cc7ccccc67)c5ccc43)c3ccccc3c2)cc1 ; c1ccc(-c2cc(-n3c4ccccc4c4c5c6ccccc6n(-c6cc(-c7ccccc7)c7ccccc7c6)c5ccc43)cc3ccccc23)cc1 ; c1ccc(-c2cc3ccccc3cc2-n2c3ccccc3c3c4c5ccccc5n(-c5cc6ccccc6cc5-c5ccccc5)c4ccc32)cc1 ; c1ccc2c(c1)ccc1cc(-n3c4ccccc4c4c5c6ccccc6n(-c6ccc7c(ccc8ccccc87)c6)c5ccc43)ccc12]

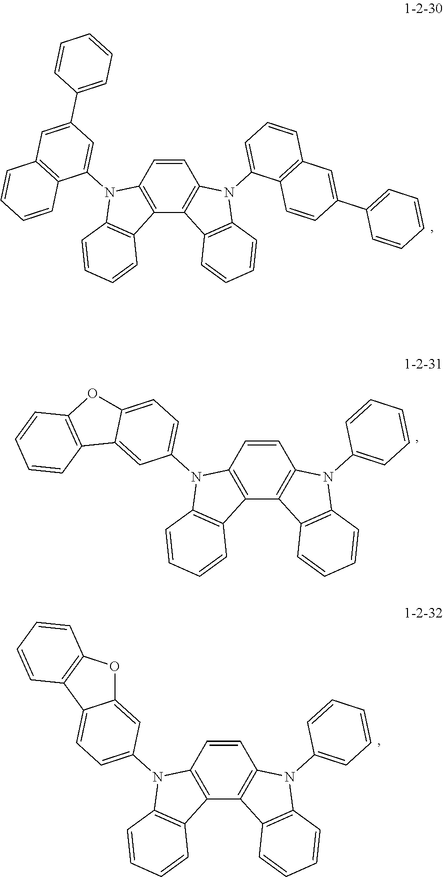 [SMILES: c1ccc(-c2ccc3c(-n4c5ccccc5c5c6c7ccccc7n(-c7cc(-c8ccccc8)cc8ccccc78)c6ccc54)cccc3c2)cc1 ; c1ccc(-n2c3ccccc3c3c4c5ccccc5n(-c5ccc6oc7ccccc7c6c5)c4ccc32)cc1 ; c1ccc(-n2c3ccccc3c3c4c5ccccc5n(-c5ccc6c(c5)oc5ccccc56)c4ccc32)cc1]

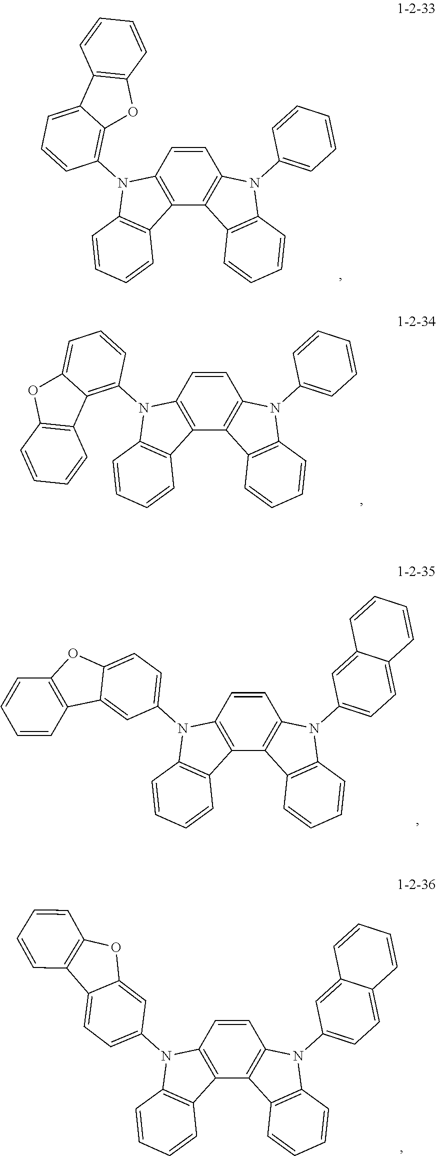 [SMILES: c1ccc(-n2c3ccccc3c3c4c5ccccc5n(-c5cccc6c5oc5ccccc56)c4ccc32)cc1 ; c1ccc(-n2c3ccccc3c3c4c5ccccc5n(-c5cccc6oc7ccccc7c56)c4ccc32)cc1 ; c1ccc2cc(-n3c4ccccc4c4c5c6ccccc6n(-c6ccc7oc8ccccc8c7c6)c5ccc43)ccc2c1 ; c1ccc2cc(-n3c4ccccc4c4c5c6ccccc6n(-c6ccc7c(c6)oc6ccccc67)c5ccc43)ccc2c1]

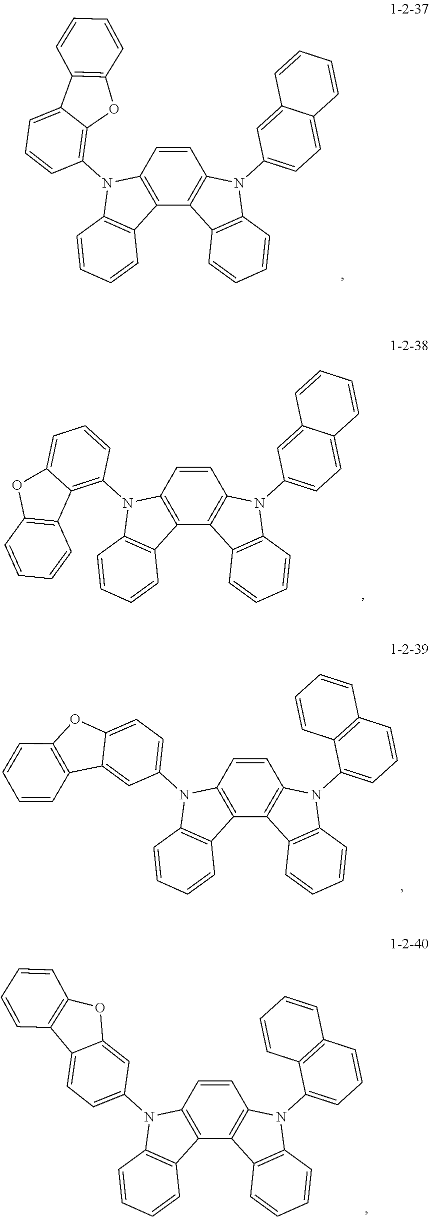 [SMILES: c1ccc2cc(-n3c4ccccc4c4c5c6ccccc6n(-c6cccc7c6oc6ccccc67)c5ccc43)ccc2c1 ; c1ccc2cc(-n3c4ccccc4c4c5c6ccccc6n(-c6cccc7oc8ccccc8c67)c5ccc43)ccc2c1 ; c1ccc2c(-n3c4ccccc4c4c5c6ccccc6n(-c6ccc7oc8ccccc8c7c6)c5ccc43)cccc2c1 ; c1ccc2c(-n3c4ccccc4c4c5c6ccccc6n(-c6ccc7c(c6)oc6ccccc67)c5ccc43)cccc2c1]

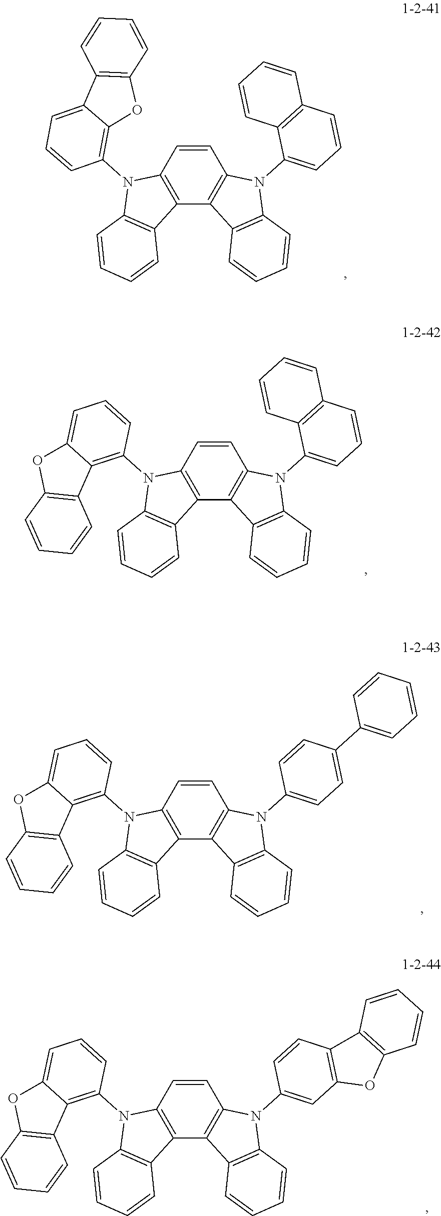 [SMILES: c1ccc2c(-n3c4ccccc4c4c5c6ccccc6n(-c6cccc7c6oc6ccccc67)c5ccc43)cccc2c1 ; c1ccc2c(-n3c4ccccc4c4c5c6ccccc6n(-c6cccc7oc8ccccc8c67)c5ccc43)cccc2c1 ; c1ccc(-c2ccc(-n3c4ccccc4c4c5c6ccccc6n(-c6cccc7oc8ccccc8c67)c5ccc43)cc2)cc1 ; c1ccc2c(c1)oc1cc(-n3c4ccccc4c4c5c6ccccc6n(-c6cccc7oc8ccccc8c67)c5ccc43)ccc12]

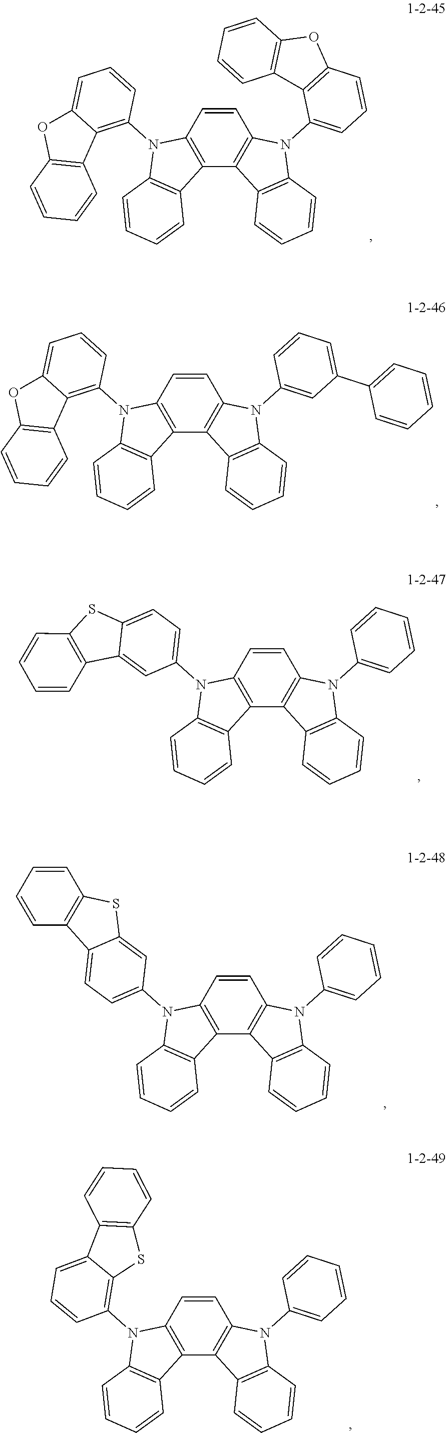 [SMILES: c1ccc2c(c1)oc1cccc(-n3c4ccccc4c4c5c6ccccc6n(-c6cccc7oc8ccccc8c67)c5ccc43)c12 ; c1ccc(-c2cccc(-n3c4ccccc4c4c5c6ccccc6n(-c6cccc7oc8ccccc8c67)c5ccc43)c2)cc1 ; c1ccc(-n2c3ccccc3c3c4c5ccccc5n(-c5ccc6sc7ccccc7c6c5)c4ccc32)cc1 ; c1ccc(-n2c3ccccc3c3c4c5ccccc5n(-c5ccc6c(c5)sc5ccccc56)c4ccc32)cc1 ; c1ccc(-n2c3ccccc3c3c4c5ccccc5n(-c5cccc6c5sc5ccccc56)c4ccc32)cc1]

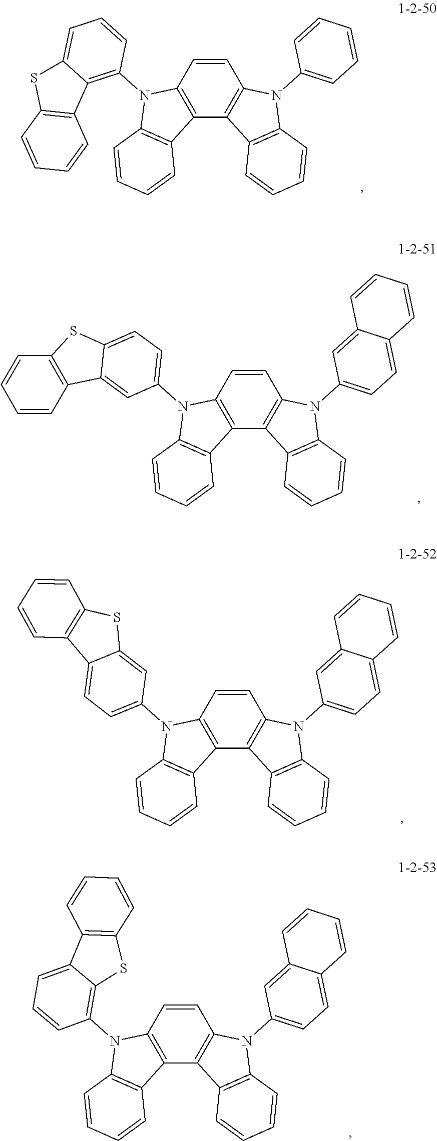 [SMILES: c1ccc(-n2c3ccccc3c3c4c5ccccc5n(-c5cccc6sc7ccccc7c56)c4ccc32)cc1 ; c1ccc2cc(-n3c4ccccc4c4c5c6ccccc6n(-c6ccc7sc8ccccc8c7c6)c5ccc43)ccc2c1 ; c1ccc2cc(-n3c4ccccc4c4c5c6ccccc6n(-c6ccc7c(c6)sc6ccccc67)c5ccc43)ccc2c1 ; c1ccc2cc(-n3c4ccccc4c4c5c6ccccc6n(-c6cccc7c6sc6ccccc67)c5ccc43)ccc2c1]

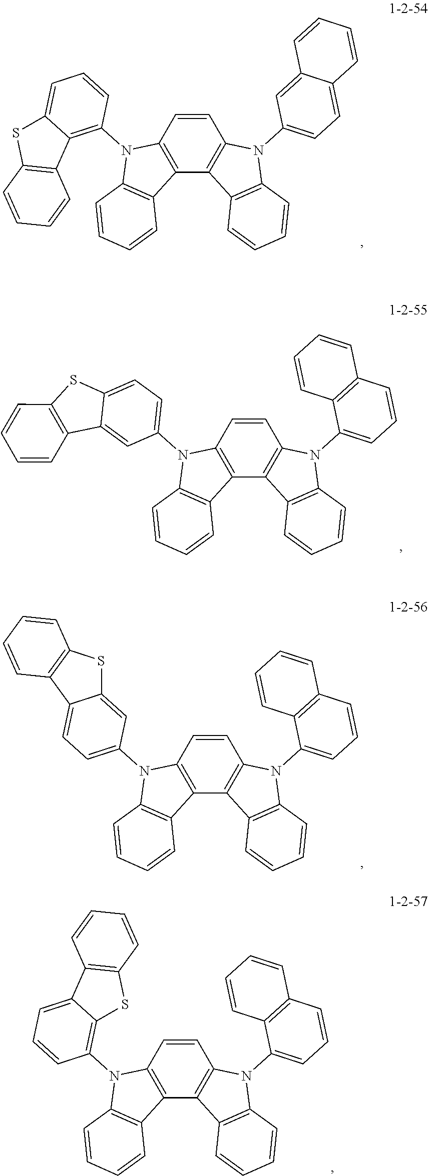 [SMILES: c1ccc2cc(-n3c4ccccc4c4c5c6ccccc6n(-c6cccc7sc8ccccc8c67)c5ccc43)ccc2c1 ; c1ccc2c(-n3c4ccccc4c4c5c6ccccc6n(-c6ccc7sc8ccccc8c7c6)c5ccc43)cccc2c1 ; c1ccc2c(-n3c4ccccc4c4c5c6ccccc6n(-c6ccc7c(c6)sc6ccccc67)c5ccc43)cccc2c1 ; c1ccc2c(-n3c4ccccc4c4c5c6ccccc6n(-c6cccc7c6sc6ccccc67)c5ccc43)cccc2c1]

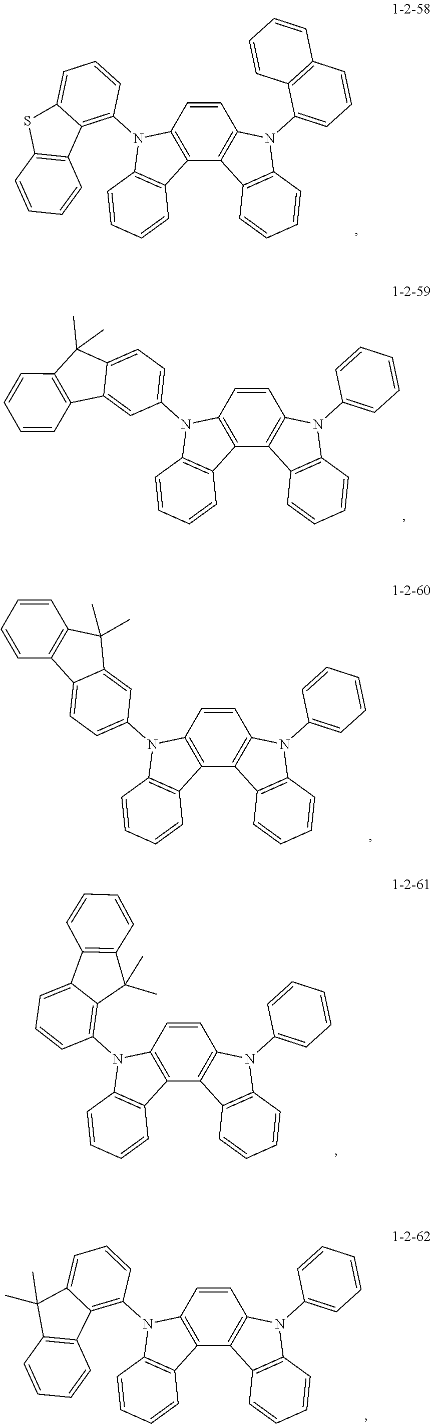 [SMILES: c1ccc2c(-n3c4ccccc4c4c5c6ccccc6n(-c6cccc7sc8ccccc8c67)c5ccc43)cccc2c1 ; CC1(C)c2ccccc2-c2cc(-n3c4ccccc4c4c5c6ccccc6n(-c6ccccc6)c5ccc43)ccc21 ; CC1(C)c2ccccc2-c2ccc(-n3c4ccccc4c4c5c6ccccc6n(-c6ccccc6)c5ccc43)cc21 ; CC1(C)c2ccccc2-c2cccc(-n3c4ccccc4c4c5c6ccccc6n(-c6ccccc6)c5ccc43)c21 ; CC1(C)c2ccccc2-c2c(-n3c4ccccc4c4c5c6ccccc6n(-c6ccccc6)c5ccc43)cccc21]

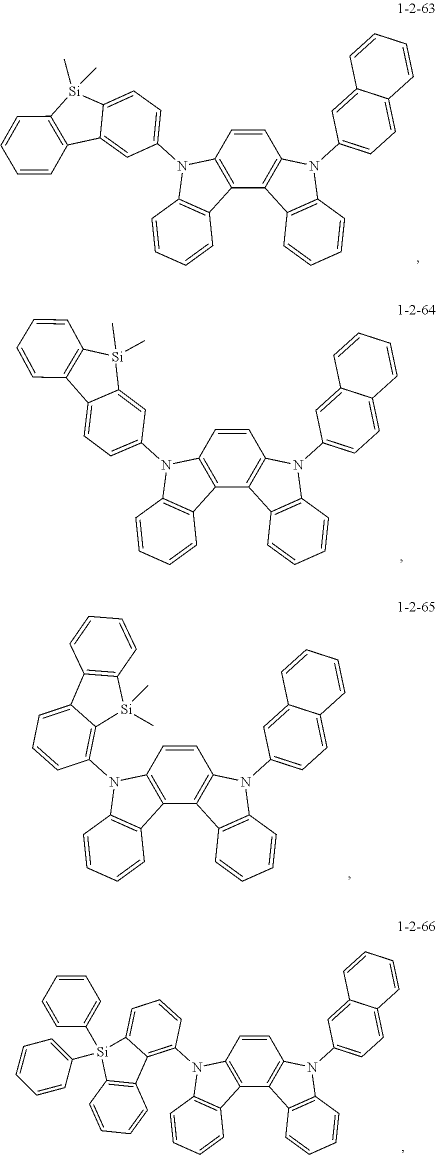 [SMILES: C[Si]1(C)c2ccccc2-c2cc(-n3c4ccccc4c4c5c6ccccc6n(-c6ccc7ccccc7c6)c5ccc43)ccc21 ; C[Si]1(C)c2ccccc2-c2ccc(-n3c4ccccc4c4c5c6ccccc6n(-c6ccc7ccccc7c6)c5ccc43)cc21 ; C[Si]1(C)c2ccccc2-c2cccc(-n3c4ccccc4c4c5c6ccccc6n(-c6ccc7ccccc7c6)c5ccc43)c21 ; c1ccc([Si]2(c3ccccc3)c3ccccc3-c3c(-n4c5ccccc5c5c6c7ccccc7n(-c7ccc8ccccc8c7)c6ccc54)cccc32)cc1]

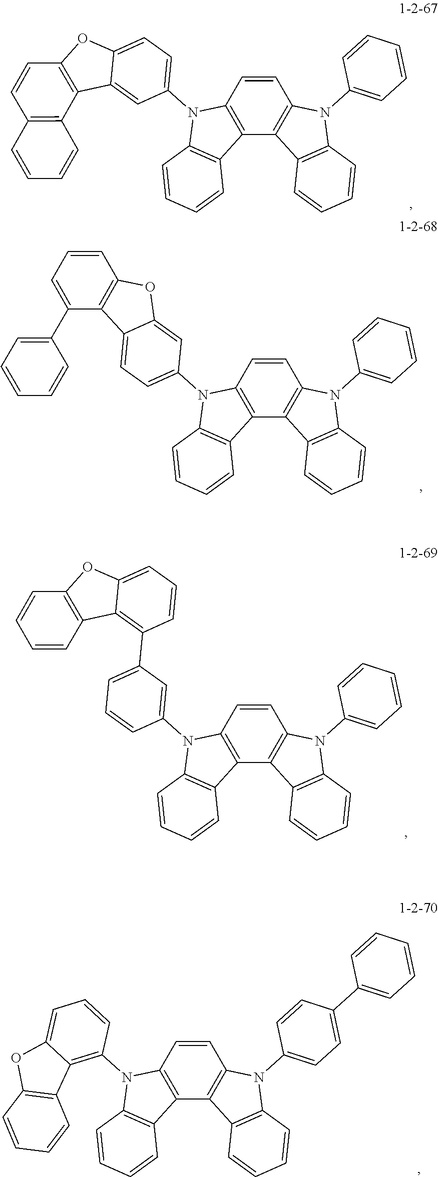 [SMILES: c1ccc(-n2c3ccccc3c3c4c5ccccc5n(-c5ccc6oc7ccc8ccccc8c7c6c5)c4ccc32)cc1 ; c1ccc(-c2cccc3oc4cc(-n5c6ccccc6c6c7c8ccccc8n(-c8ccccc8)c7ccc65)ccc4c23)cc1 ; c1ccc(-n2c3ccccc3c3c4c5ccccc5n(-c5cccc(-c6cccc7oc8ccccc8c67)c5)c4ccc32)cc1 ; c1ccc(-c2ccc(-n3c4ccccc4c4c5c6ccccc6n(-c6cccc7oc8ccccc8c67)c5ccc43)cc2)cc1]

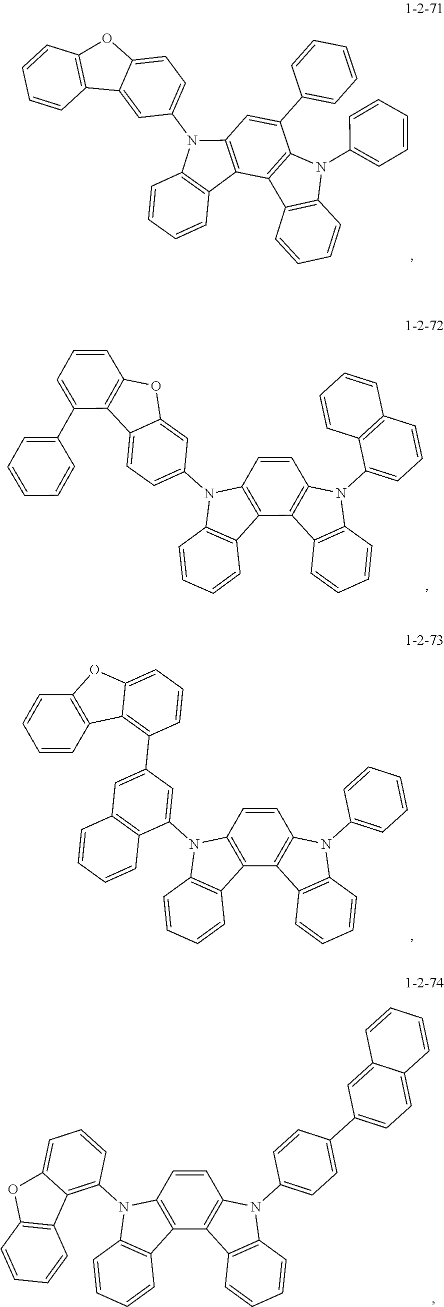 [SMILES: c1ccc(-c2cc3c(c4ccccc4n3-c3ccc4oc5ccccc5c4c3)c3c4ccccc4n(-c4ccccc4)c23)cc1 ; c1ccc(-c2cccc3oc4cc(-n5c6ccccc6c6c7c8ccccc8n(-c8cccc9ccccc89)c7ccc65)ccc4c23)cc1 ; c1ccc(-n2c3ccccc3c3c4c5ccccc5n(-c5cc(-c6cccc7oc8ccccc8c67)cc6ccccc56)c4ccc32)cc1 ; c1ccc2cc(-c3ccc(-n4c5ccccc5c5c6c7ccccc7n(-c7cccc8oc9ccccc9c78)c6ccc54)cc3)ccc2c1]

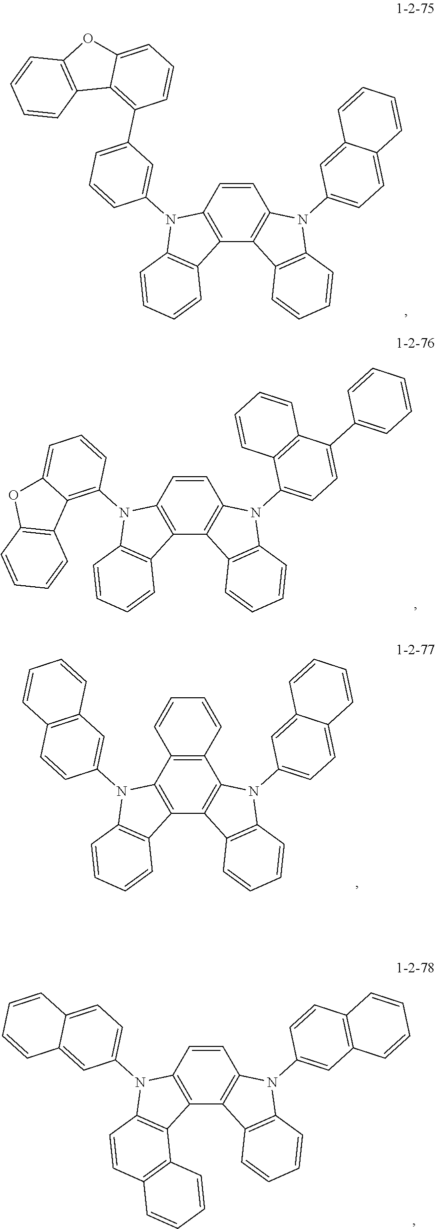 [SMILES: c1cc(-c2cccc3oc4ccccc4c23)cc(-n2c3ccccc3c3c4c5ccccc5n(-c5ccc6ccccc6c5)c4ccc32)c1 ; c1ccc(-c2ccc(-n3c4ccccc4c4c5c6ccccc6n(-c6cccc7oc8ccccc8c67)c5ccc43)c3ccccc23)cc1 ; c1ccc2cc(-n3c4ccccc4c4c5c6ccccc6n(-c6ccc7ccccc7c6)c5c5ccccc5c43)ccc2c1 ; c1ccc2cc(-n3c4ccccc4c4c5c6c7ccccc7ccc6n(-c6ccc7ccccc7c6)c5ccc43)ccc2c1]

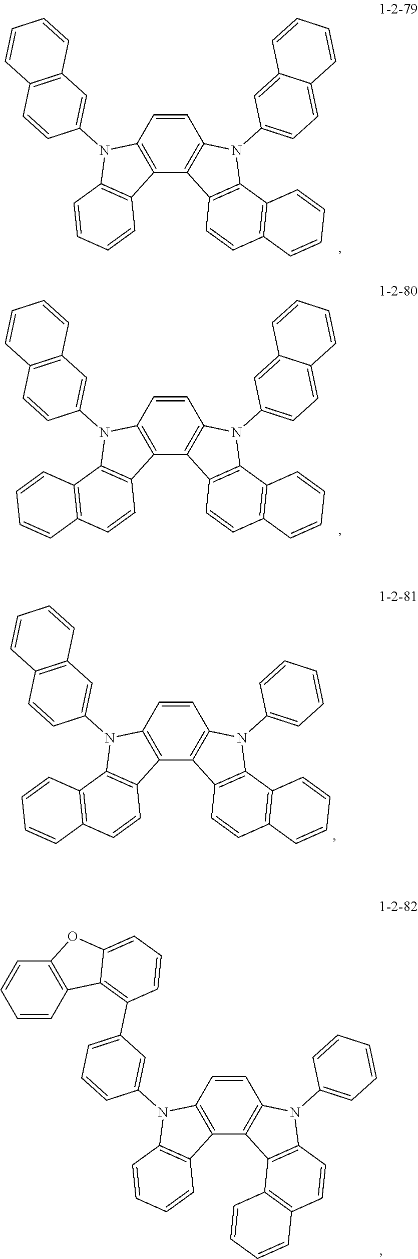

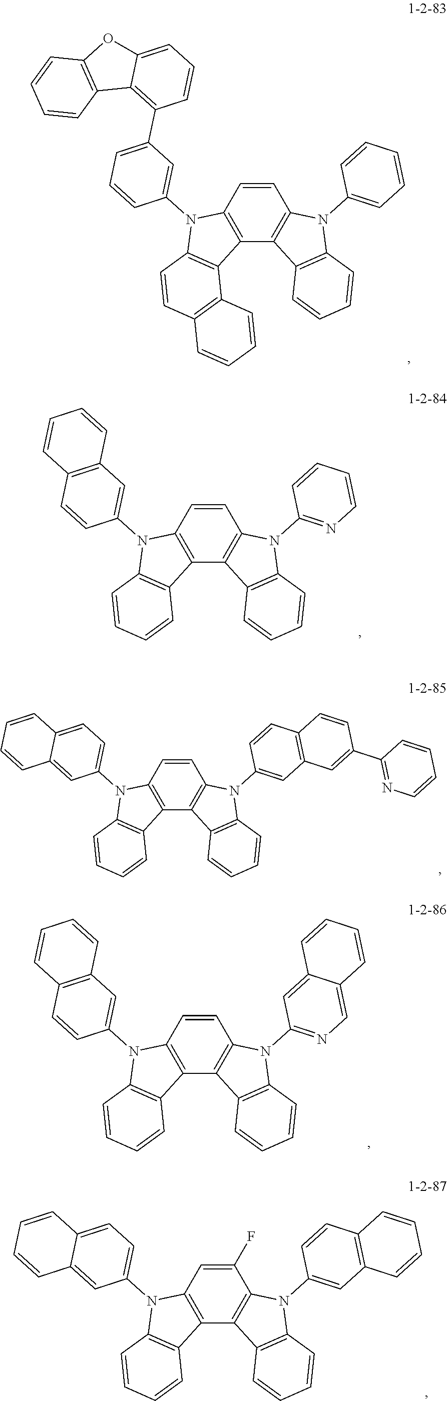 [SMILES: c1ccc(-n2c3ccccc3c3c4c5c6ccccc6ccc5n(-c5cccc(-c6cccc7oc8ccccc8c67)c5)c4ccc32)cc1 ; c1ccc(-n2c3ccccc3c3c4c5ccccc5n(-c5ccc6ccccc6c5)c4ccc32)nc1 ; c1ccc(-c2ccc3ccc(-n4c5ccccc5c5c6c7ccccc7n(-c7ccc8ccccc8c7)c6ccc54)cc3c2)nc1 ; c1ccc2cc(-n3c4ccccc4c4c5c6ccccc6n(-c6cc7ccccc7cn6)c5ccc43)ccc2c1 ; Fc1cc2c(c3ccccc3n2-c2ccc3ccccc3c2)c2c3ccccc3n(-c3ccc4ccccc4c3)c12]

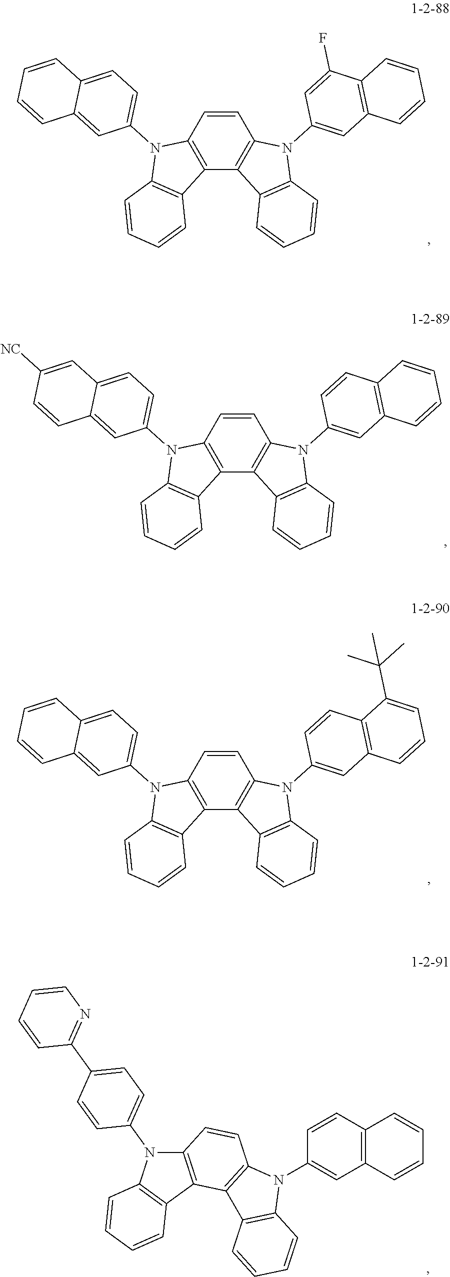 [SMILES: Fc1cc(-n2c3ccccc3c3c4c5ccccc5n(-c5ccc6ccccc6c5)c4ccc32)cc2ccccc12 ; N#Cc1ccc2cc(-n3c4ccccc4c4c5c6ccccc6n(-c6ccc7ccccc7c6)c5ccc43)ccc2c1 ; CC(C)(C)c1cccc2cc(-n3c4ccccc4c4c5c6ccccc6n(-c6ccc7ccccc7c6)c5ccc43)ccc12 ; c1ccc(-c2ccc(-n3c4ccccc4c4c5c6ccccc6n(-c6ccc7ccccc7c6)c5ccc43)cc2)nc1]

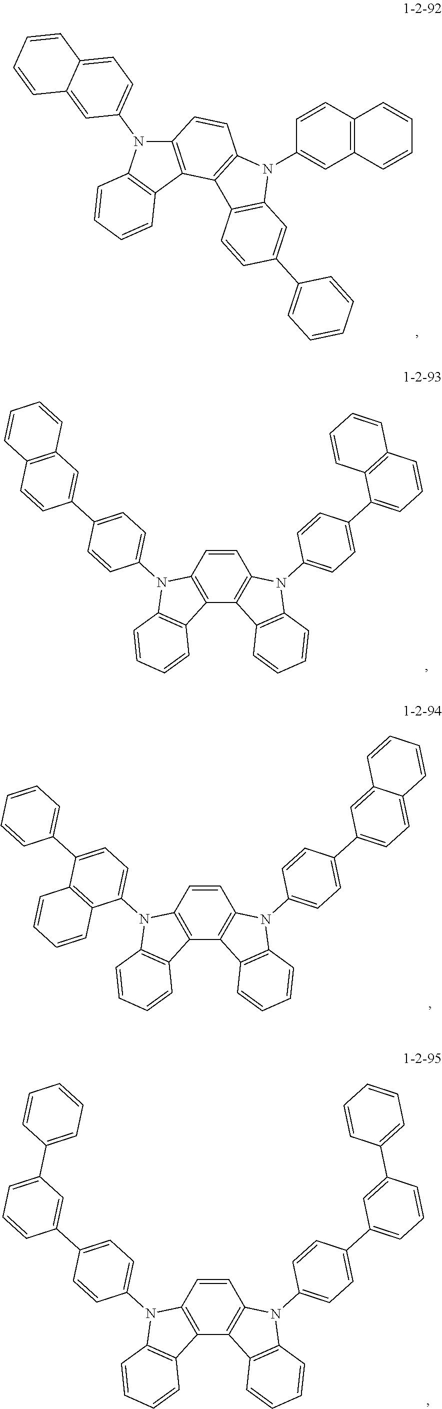 [SMILES: c1ccc(-c2ccc3c4c5c6ccccc6n(-c6ccc7ccccc7c6)c5ccc4n(-c4ccc5ccccc5c4)c3c2)cc1 ; c1ccc2cc(-c3ccc(-n4c5ccccc5c5c6c7ccccc7n(-c7ccc(-c8cccc9ccccc89)cc7)c6ccc54)cc3)ccc2c1 ; c1ccc(-c2ccc(-n3c4ccccc4c4c5c6ccccc6n(-c6ccc(-c7ccc8ccccc8c7)cc6)c5ccc43)c3ccccc23)cc1 ; c1ccc(-c2cccc(-c3ccc(-n4c5ccccc5c5c6c7ccccc7n(-c7ccc(-c8cccc(-c9ccccc9)c8)cc7)c6ccc54)cc3)c2)cc1]

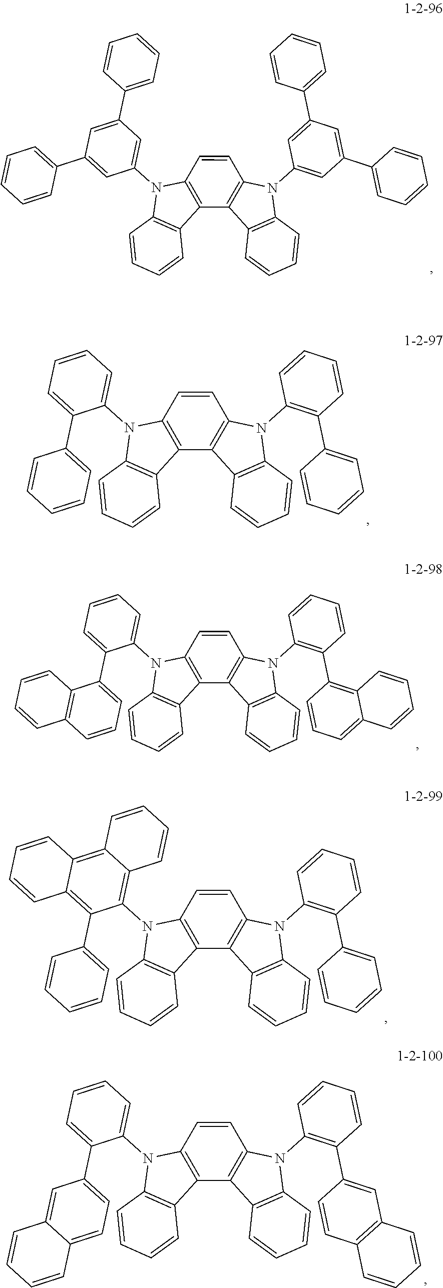 [SMILES: c1ccc(-c2cc(-c3ccccc3)cc(-n3c4ccccc4c4c5c6ccccc6n(-c6cc(-c7ccccc7)cc(-c7ccccc7)c6)c5ccc43)c2)cc1 ; c1ccc(-c2ccccc2-n2c3ccccc3c3c4c5ccccc5n(-c5ccccc5-c5ccccc5)c4ccc32)cc1 ; c1ccc(-n2c3ccccc3c3c4c5ccccc5n(-c5ccccc5-c5cccc6ccccc56)c4ccc32)c(-c2cccc3ccccc23)c1 ; c1ccc(-c2ccccc2-n2c3ccccc3c3c4c5ccccc5n(-c5c(-c6ccccc6)c6ccccc6c6ccccc56)c4ccc32)cc1 ; c1ccc(-n2c3ccccc3c3c4c5ccccc5n(-c5ccccc5-c5ccc6ccccc6c5)c4ccc32)c(-c2ccc3ccccc3c2)c1]

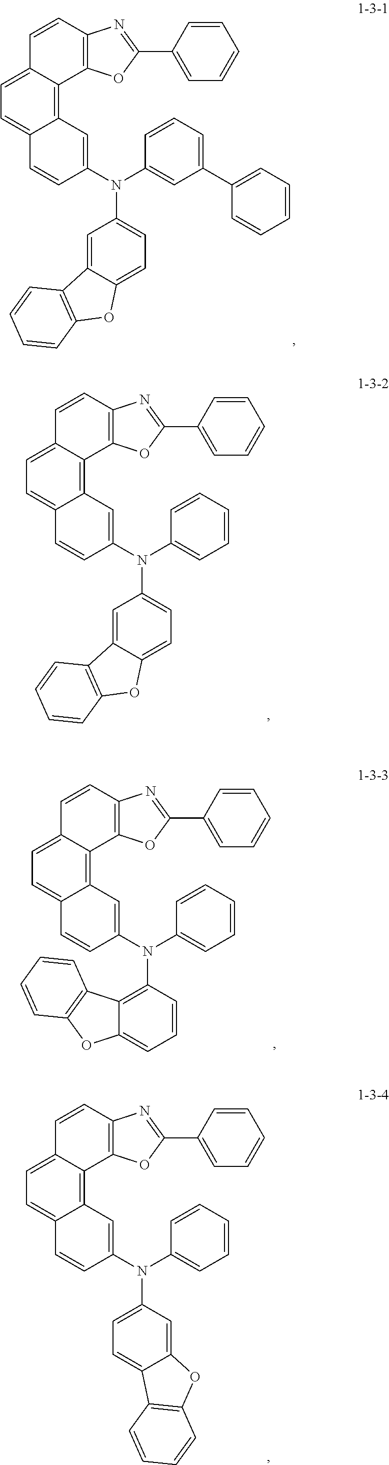 [SMILES: c1ccc(-c2cccc(N(c3ccc4oc5ccccc5c4c3)c3ccc4ccc5ccc6nc(-c7ccccc7)oc6c5c4c3)c2)cc1 ; c1ccc(-c2nc3ccc4ccc5ccc(N(c6ccccc6)c6ccc7oc8ccccc8c7c6)cc5c4c3o2)cc1 ; c1ccc(-c2nc3ccc4ccc5ccc(N(c6ccccc6)c6cccc7oc8ccccc8c67)cc5c4c3o2)cc1 ; c1ccc(-c2nc3ccc4ccc5ccc(N(c6ccccc6)c6ccc7c(c6)oc6ccccc67)cc5c4c3o2)cc1]

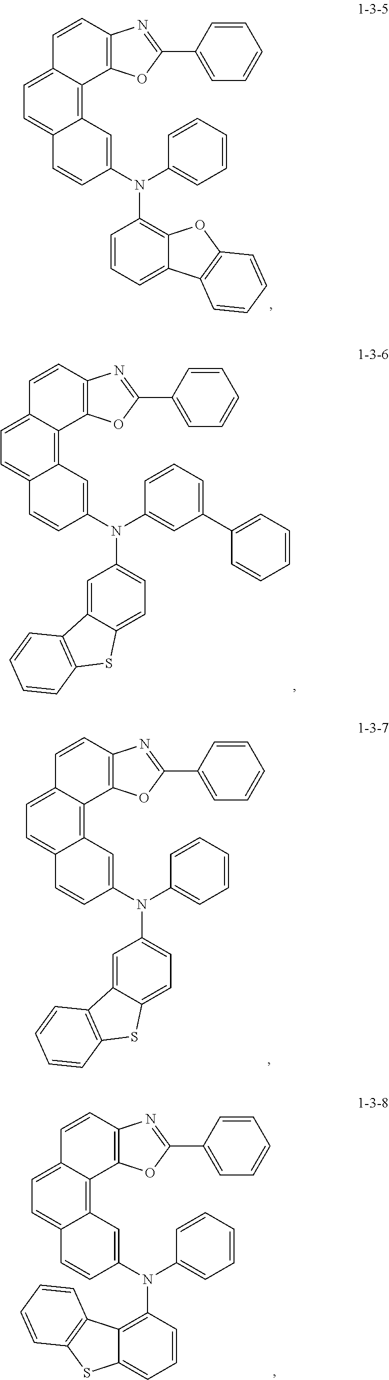

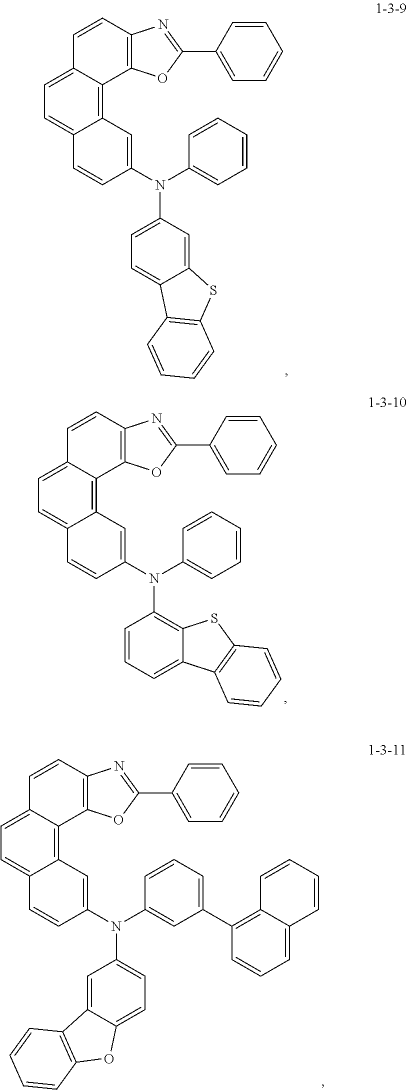

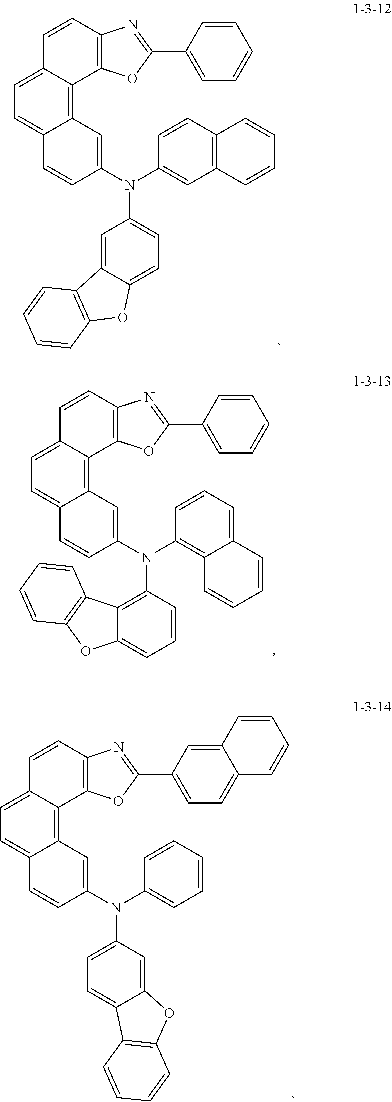 [SMILES: c1ccc(-c2nc3ccc4ccc5ccc(N(c6ccc7ccccc7c6)c6ccc7oc8ccccc8c7c6)cc5c4c3o2)cc1 ; c1ccc(-c2nc3ccc4ccc5ccc(N(c6cccc7ccccc67)c6cccc7oc8ccccc8c67)cc5c4c3o2)cc1 ; c1ccc(N(c2ccc3c(c2)oc2ccccc23)c2ccc3ccc4ccc5nc(-c6ccc7ccccc7c6)oc5c4c3c2)cc1]

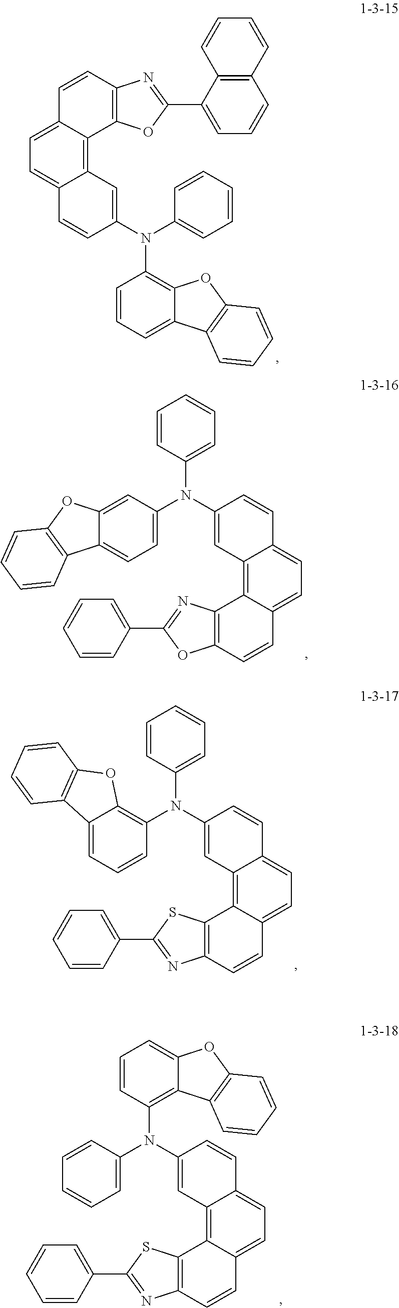 [SMILES: c1ccc(N(c2ccc3ccc4ccc5nc(-c6cccc7ccccc67)oc5c4c3c2)c2cccc3c2oc2ccccc23)cc1 ; c1ccc(-c2nc3c(ccc4ccc5ccc(N(c6ccccc6)c6ccc7c(c6)oc6ccccc67)cc5c43)o2)cc1 ; c1ccc(-c2nc3ccc4ccc5ccc(N(c6ccccc6)c6cccc7c6oc6ccccc67)cc5c4c3s2)cc1 ; c1ccc(-c2nc3ccc4ccc5ccc(N(c6ccccc6)c6cccc7oc8ccccc8c67)cc5c4c3s2)cc1]

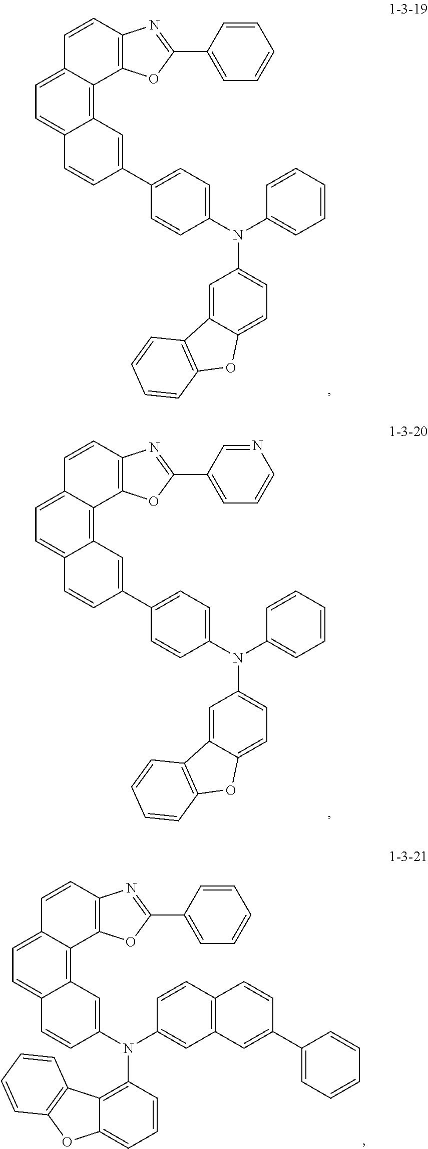 [SMILES: c1ccc(-c2nc3ccc4ccc5ccc(-c6ccc(N(c7ccccc7)c7ccc8oc9ccccc9c8c7)cc6)cc5c4c3o2)cc1 ; c1ccc(N(c2ccc(-c3ccc4ccc5ccc6nc(-c7cccnc7)oc6c5c4c3)cc2)c2ccc3oc4ccccc4c3c2)cc1 ; c1ccc(-c2ccc3ccc(N(c4ccc5ccc6ccc7nc(-c8ccccc8)oc7c6c5c4)c4cccc5oc6ccccc6c45)cc3c2)cc1]

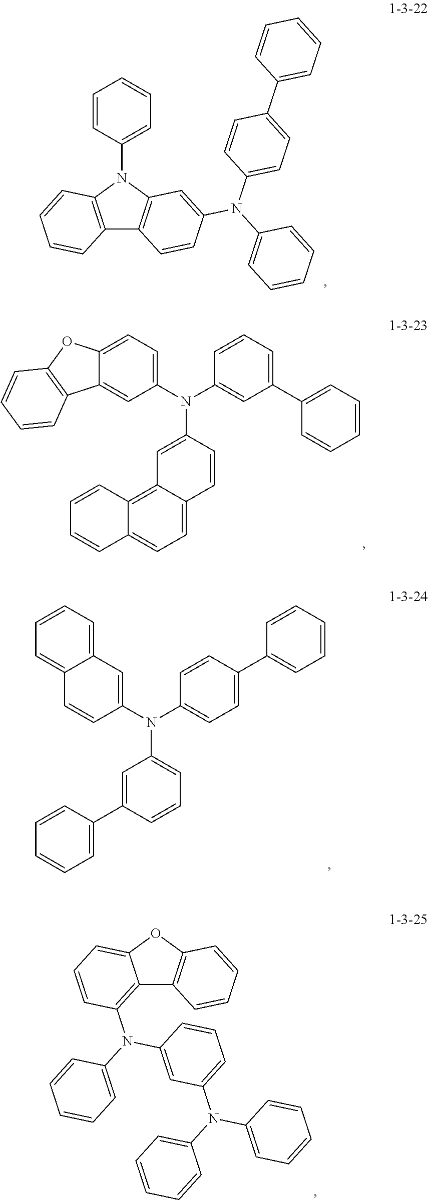 [SMILES: c1ccc(-c2ccc(N(c3ccccc3)c3ccc4c5ccccc5n(-c5ccccc5)c4c3)cc2)cc1 ; c1ccc(-c2cccc(N(c3ccc4ccc5ccccc5c4c3)c3ccc4oc5ccccc5c4c3)c2)cc1 ; c1ccc(-c2ccc(N(c3cccc(-c4ccccc4)c3)c3ccc4ccccc4c3)cc2)cc1 ; c1ccc(N(c2ccccc2)c2cccc(N(c3ccccc3)c3cccc4oc5ccccc5c34)c2)cc1]

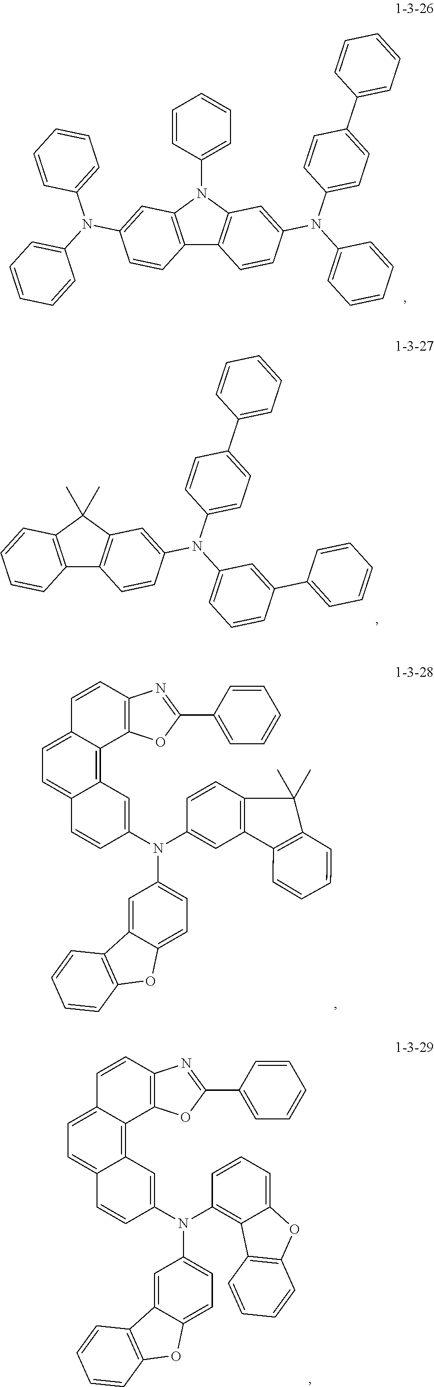 [SMILES: c1ccc(-c2ccc(N(c3ccccc3)c3ccc4c5ccc(N(c6ccccc6)c6ccccc6)cc5n(-c5ccccc5)c4c3)cc2)cc1 ; CC1(C)c2ccccc2-c2ccc(N(c3ccc(-c4ccccc4)cc3)c3cccc(-c4ccccc4)c3)cc21 ; CC1(C)c2ccccc2-c2cc(N(c3ccc4oc5ccccc5c4c3)c3ccc4ccc5ccc6nc(-c7ccccc7)oc6c5c4c3)ccc21 ; c1ccc(-c2nc3ccc4ccc5ccc(N(c6ccc7oc8ccccc8c7c6)c6cccc7oc8ccccc8c67)cc5c4c3o2)cc1]

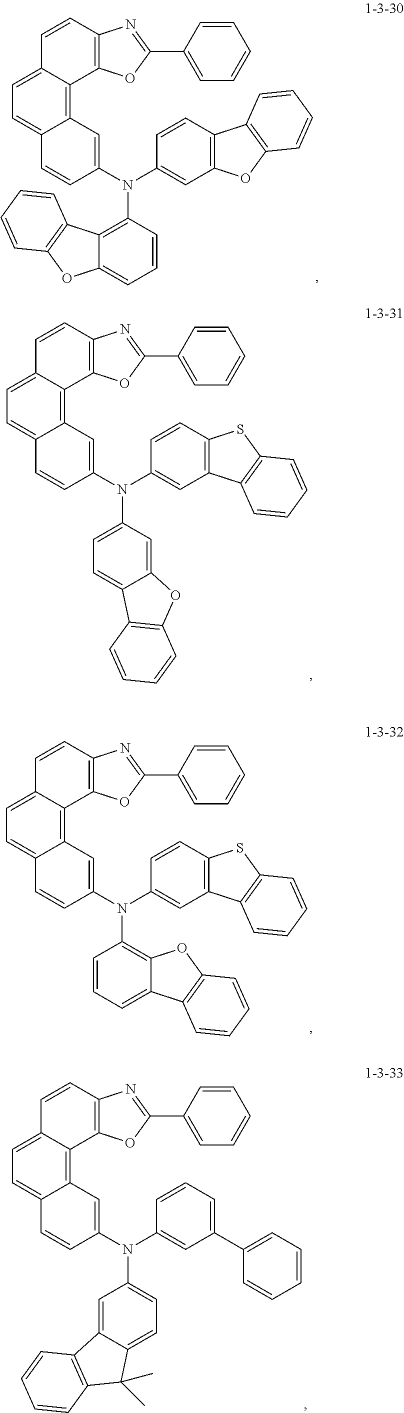

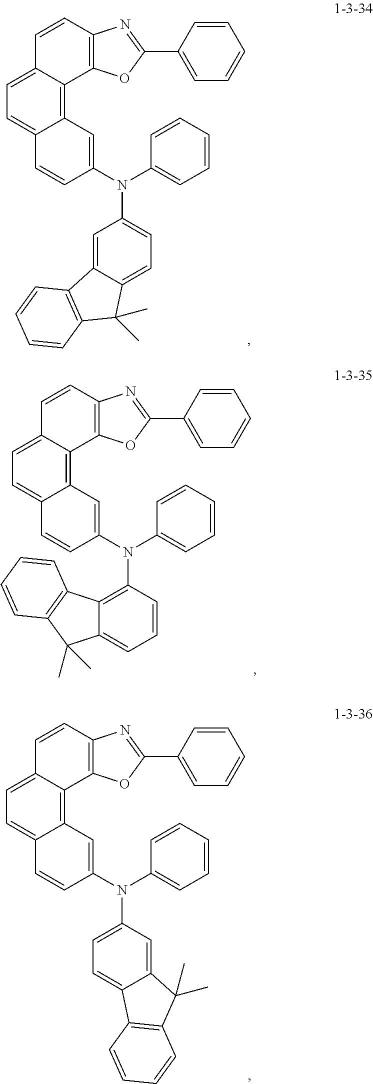

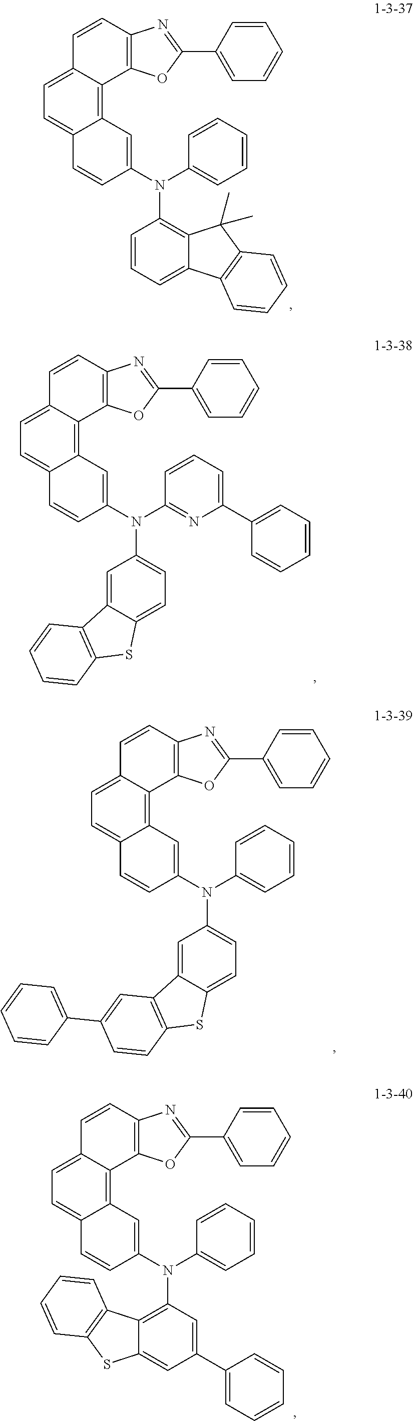 [SMILES: CC1(C)c2ccccc2-c2cccc(N(c3ccccc3)c3ccc4ccc5ccc6nc(-c7ccccc7)oc6c5c4c3)c21 ; c1ccc(-c2cccc(N(c3ccc4sc5ccccc5c4c3)c3ccc4ccc5ccc6nc(-c7ccccc7)oc6c5c4c3)n2)cc1 ; c1ccc(-c2ccc3sc4ccc(N(c5ccccc5)c5ccc6ccc7ccc8nc(-c9ccccc9)oc8c7c6c5)cc4c3c2)cc1 ; c1ccc(-c2cc(N(c3ccccc3)c3ccc4ccc5ccc6nc(-c7ccccc7)oc6c5c4c3)c3c(c2)sc2ccccc23)cc1]

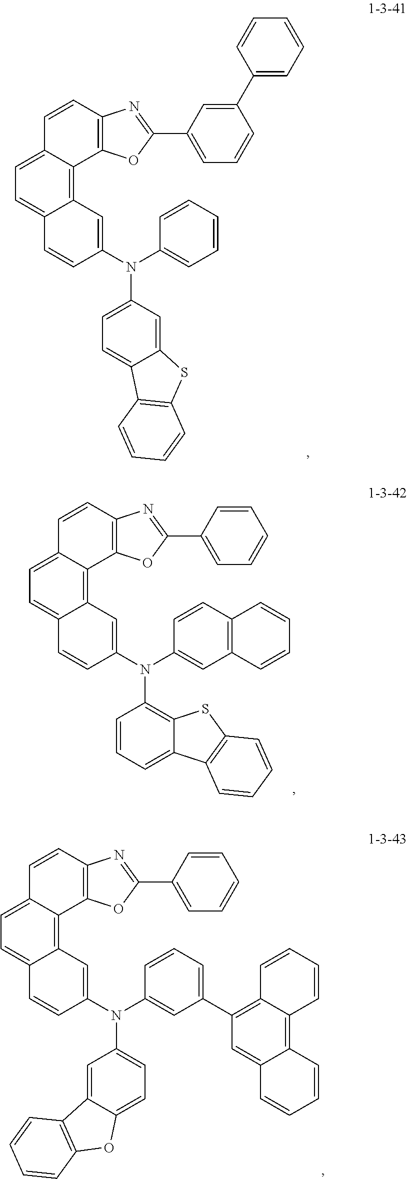 [SMILES: c1ccc(-c2cccc(-c3nc4ccc5ccc6ccc(N(c7ccccc7)c7ccc8c(c7)sc7ccccc78)cc6c5c4o3)c2)cc1 ; c1ccc(-c2nc3ccc4ccc5ccc(N(c6ccc7ccccc7c6)c6cccc7c6sc6ccccc67)cc5c4c3o2)cc1 ; c1ccc(-c2nc3ccc4ccc5ccc(N(c6cccc(-c7cc8ccccc8c8ccccc78)c6)c6ccc7oc8ccccc8c7c6)cc5c4c3o2)cc1]

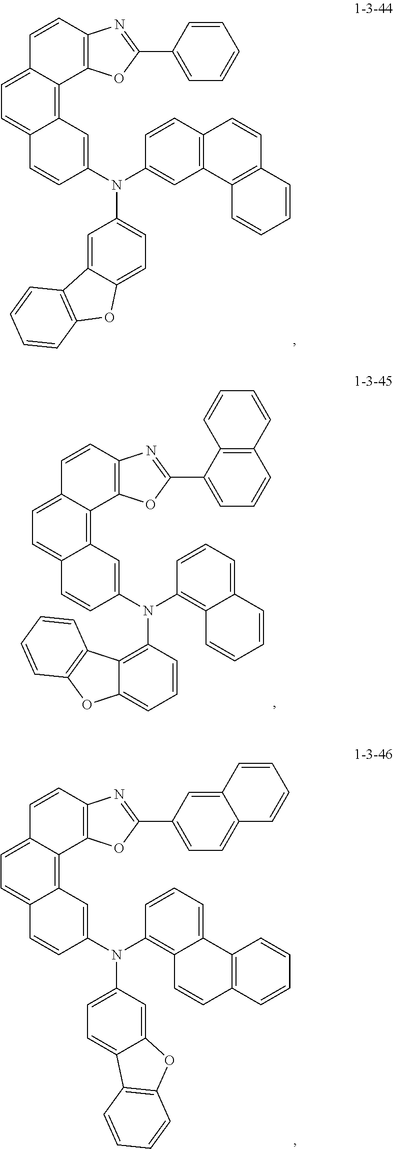 [SMILES: c1ccc(-c2nc3ccc4ccc5ccc(N(c6ccc7ccc8ccccc8c7c6)c6ccc7oc8ccccc8c7c6)cc5c4c3o2)cc1 ; c1ccc2c(-c3nc4ccc5ccc6ccc(N(c7cccc8ccccc78)c7cccc8oc9ccccc9c78)cc6c5c4o3)cccc2c1 ; c1ccc2cc(-c3nc4ccc5ccc6ccc(N(c7ccc8c(c7)oc7ccccc78)c7cccc8c7ccc7ccccc78)cc6c5c4o3)ccc2c1]

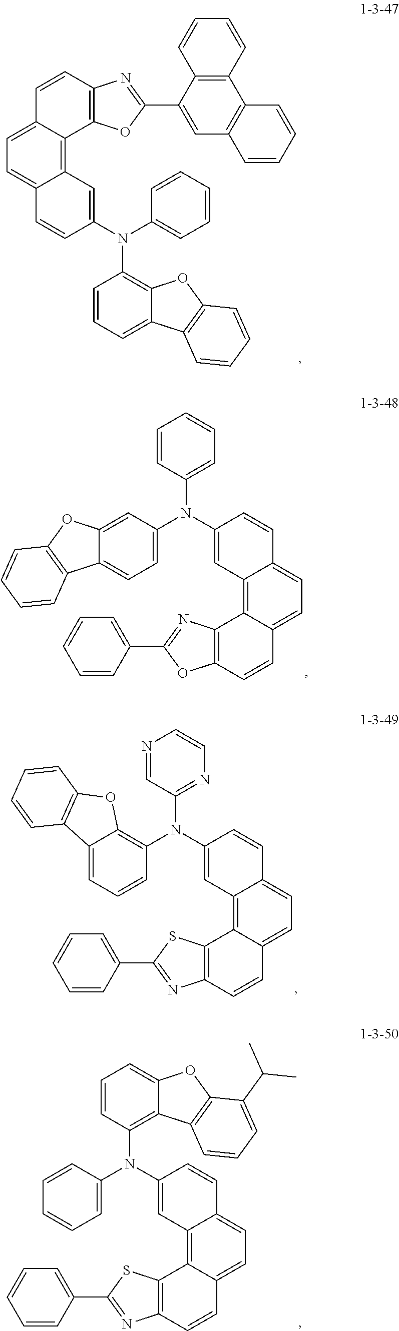 [SMILES: c1ccc(N(c2ccc3ccc4ccc5nc(-c6cc7ccccc7c7ccccc67)oc5c4c3c2)c2cccc3c2oc2ccccc23)cc1 ; c1ccc(-c2nc3c(ccc4ccc5ccc(N(c6ccccc6)c6ccc7c(c6)oc6ccccc67)cc5c43)o2)cc1 ; c1ccc(-c2nc3ccc4ccc5ccc(N(c6cnccn6)c6cccc7c6oc6ccccc67)cc5c4c3s2)cc1 ; CC(C)c1cccc2c1oc1cccc(N(c3ccccc3)c3ccc4ccc5ccc6nc(-c7ccccc7)sc6c5c4c3)c12]

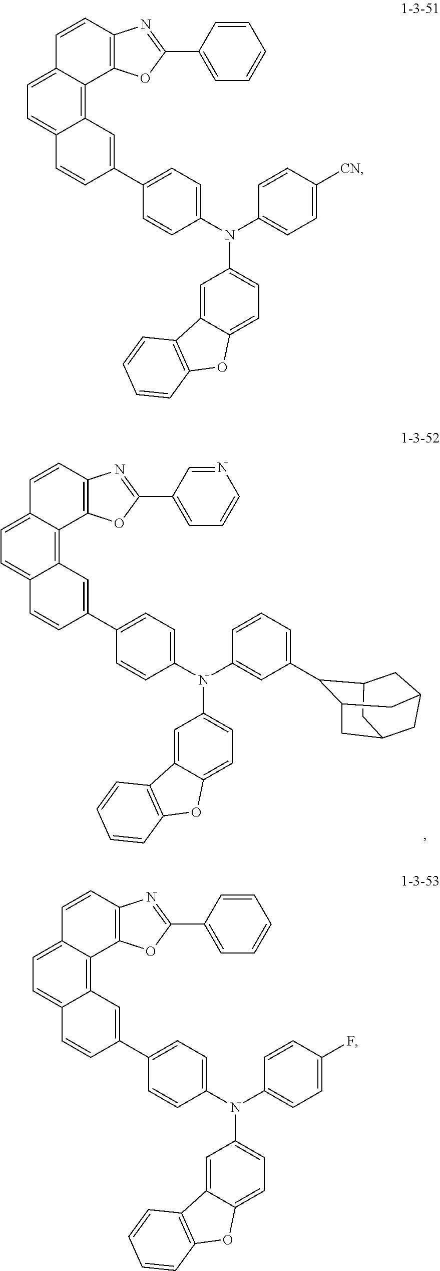 [SMILES: N#Cc1ccc(N(c2ccc(-c3ccc4ccc5ccc6nc(-c7ccccc7)oc6c5c4c3)cc2)c2ccc3oc4ccccc4c3c2)cc1 ; c1cncc(-c2nc3ccc4ccc5ccc(-c6ccc(N(c7cccc(C8C9CC%10CC(C9)CC8C%10)c7)c7ccc8oc9ccccc9c8c7)cc6)cc5c4c3o2)c1 ; Fc1ccc(N(c2ccc(-c3ccc4ccc5ccc6nc(-c7ccccc7)oc6c5c4c3)cc2)c2ccc3oc4ccccc4c3c2)cc1]

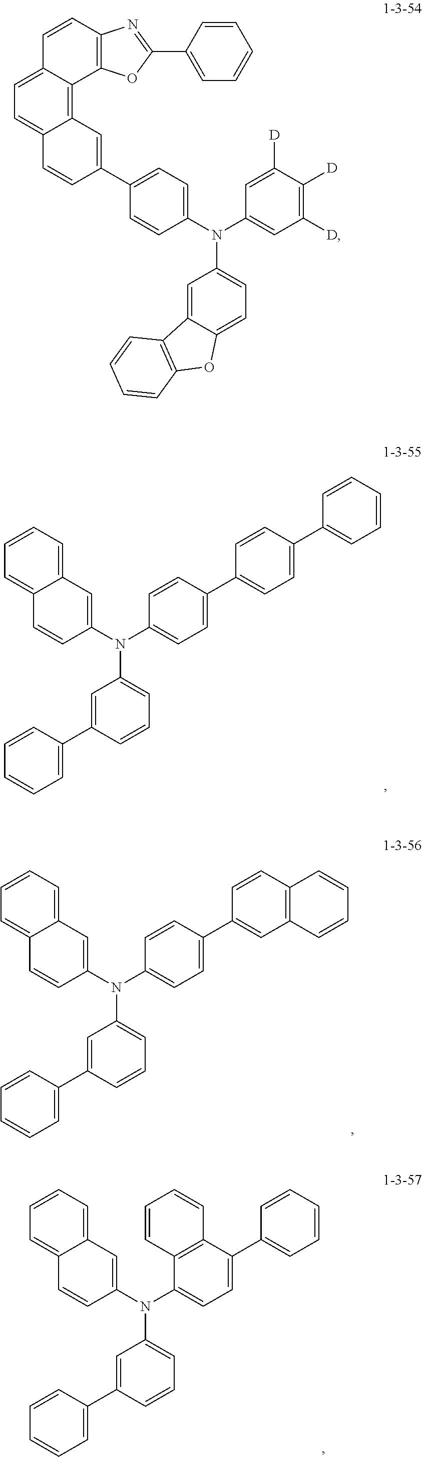

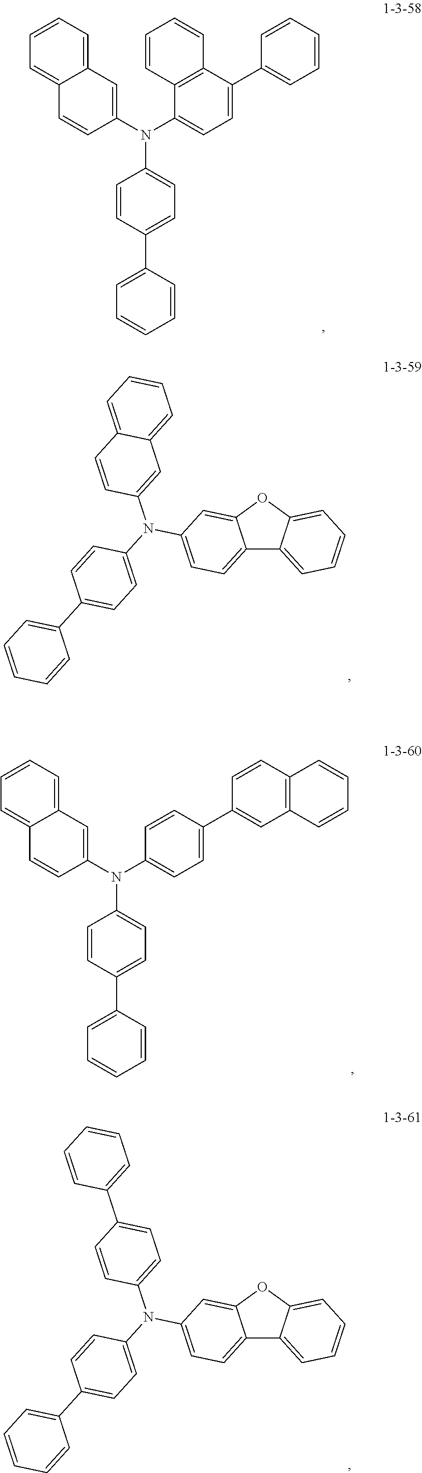

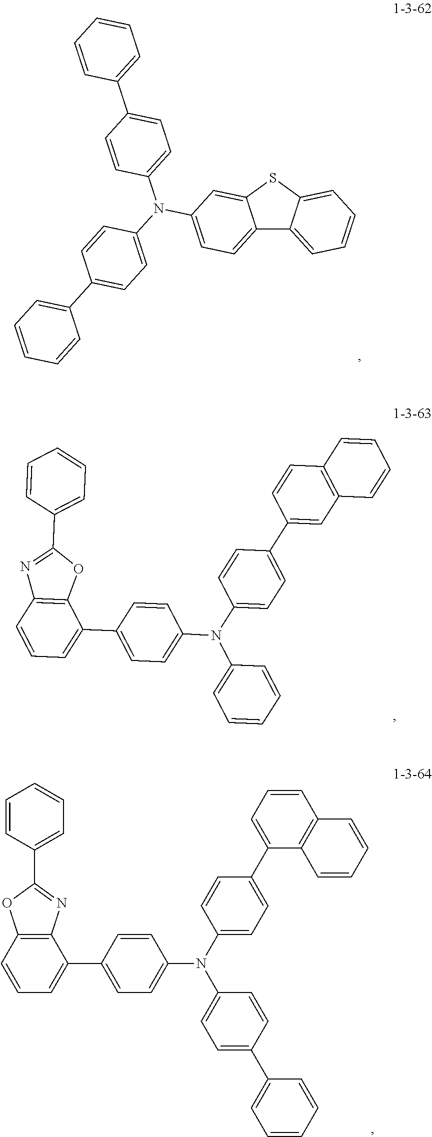 [SMILES: c1ccc(-c2ccc(N(c3ccc(-c4ccccc4)cc3)c3ccc4c(c3)sc3ccccc34)cc2)cc1 ; c1ccc(-c2nc3cccc(-c4ccc(N(c5ccccc5)c5ccc(-c6ccc7ccccc7c6)cc5)cc4)c3o2)cc1 ; c1ccc(-c2ccc(N(c3ccc(-c4cccc5ccccc45)cc3)c3ccc(-c4cccc5oc(-c6ccccc6)nc45)cc3)cc2)cc1]

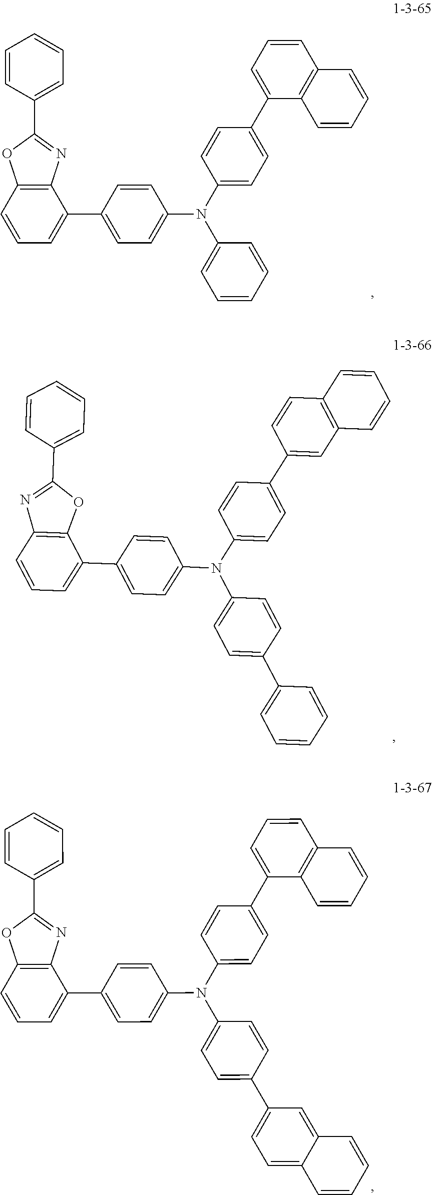 [SMILES: c1ccc(-c2nc3c(-c4ccc(N(c5ccccc5)c5ccc(-c6cccc7ccccc67)cc5)cc4)cccc3o2)cc1 ; c1ccc(-c2ccc(N(c3ccc(-c4ccc5ccccc5c4)cc3)c3ccc(-c4cccc5nc(-c6ccccc6)oc45)cc3)cc2)cc1 ; c1ccc(-c2nc3c(-c4ccc(N(c5ccc(-c6ccc7ccccc7c6)cc5)c5ccc(-c6cccc7ccccc67)cc5)cc4)cccc3o2)cc1]

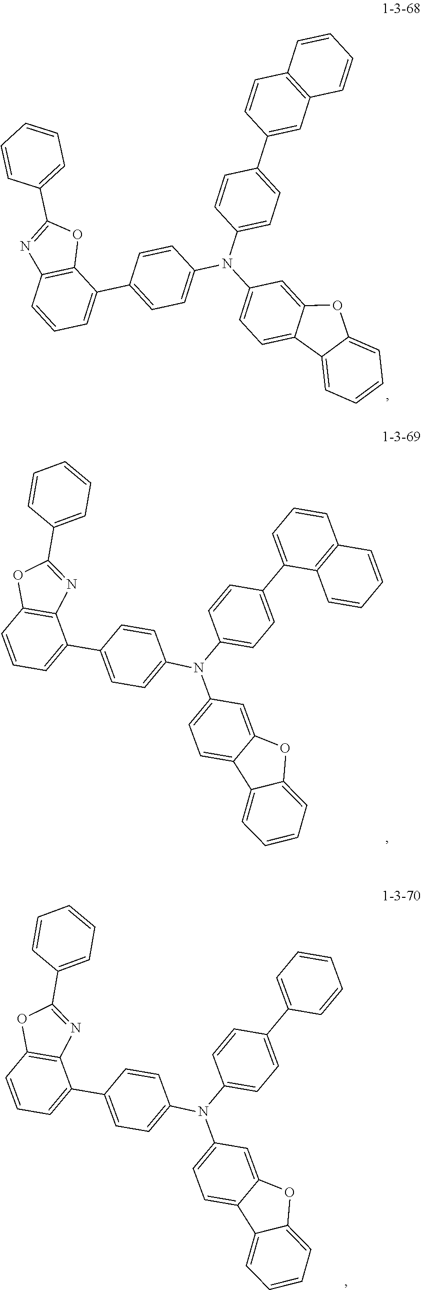 [SMILES: c1ccc(-c2nc3cccc(-c4ccc(N(c5ccc(-c6ccc7ccccc7c6)cc5)c5ccc6c(c5)oc5ccccc56)cc4)c3o2)cc1 ; c1ccc(-c2nc3c(-c4ccc(N(c5ccc(-c6cccc7ccccc67)cc5)c5ccc6c(c5)oc5ccccc56)cc4)cccc3o2)cc1 ; c1ccc(-c2ccc(N(c3ccc(-c4cccc5oc(-c6ccccc6)nc45)cc3)c3ccc4c(c3)oc3ccccc34)cc2)cc1]

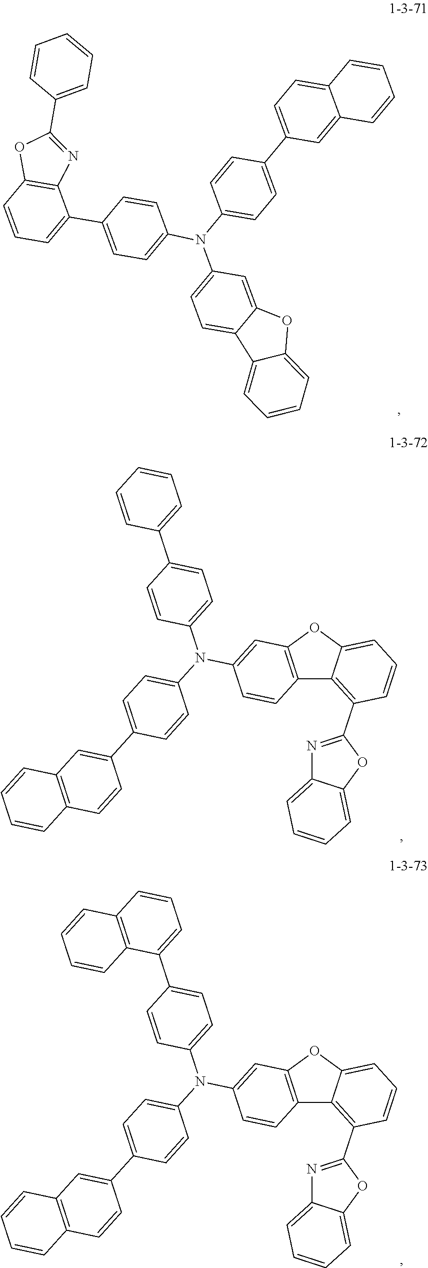 [SMILES: c1ccc(-c2nc3c(-c4ccc(N(c5ccc(-c6ccc7ccccc7c6)cc5)c5ccc6c(c5)oc5ccccc56)cc4)cccc3o2)cc1 ; c1ccc(-c2ccc(N(c3ccc(-c4ccc5ccccc5c4)cc3)c3ccc4c(c3)oc3cccc(-c5nc6ccccc6o5)c34)cc2)cc1 ; c1ccc2cc(-c3ccc(N(c4ccc(-c5cccc6ccccc56)cc4)c4ccc5c(c4)oc4cccc(-c6nc7ccccc7o6)c45)cc3)ccc2c1]

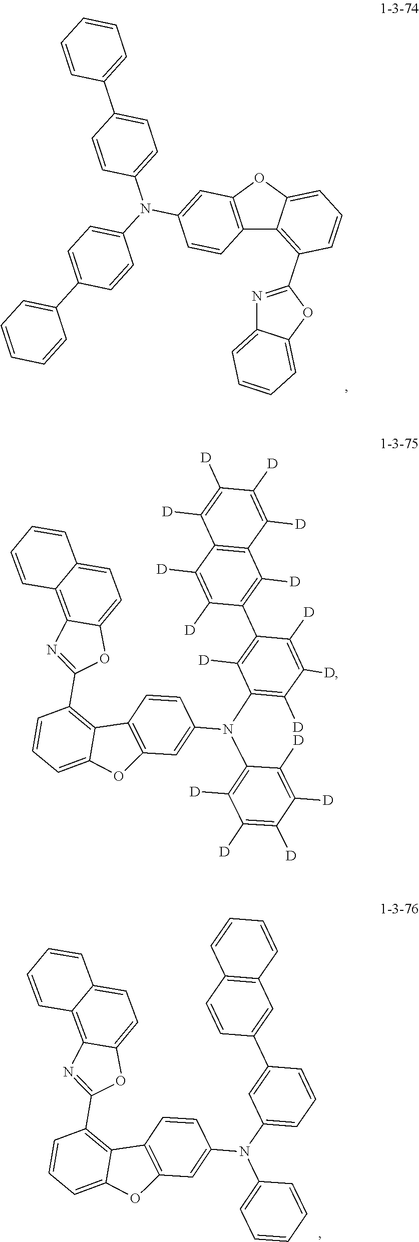

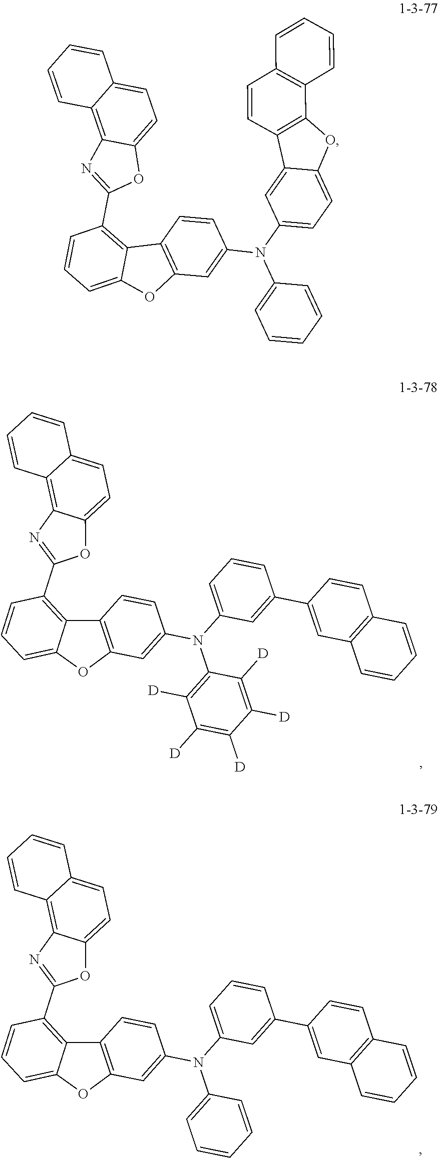 [SMILES: c1ccc(N(c2ccc3c(c2)oc2cccc(-c4nc5c(ccc6ccccc65)o4)c23)c2ccc3oc4c5ccccc5ccc4c3c2)cc1 ; [2H]c1c([2H])c([2H])c(N(c2cccc(-c3ccc4ccccc4c3)c2)c2ccc3c(c2)oc2cccc(-c4nc5c(ccc6ccccc65)o4)c23)c([2H])c1[2H] ; c1ccc(N(c2cccc(-c3ccc4ccccc4c3)c2)c2ccc3c(c2)oc2cccc(-c4nc5c(ccc6ccccc65)o4)c23)cc1]

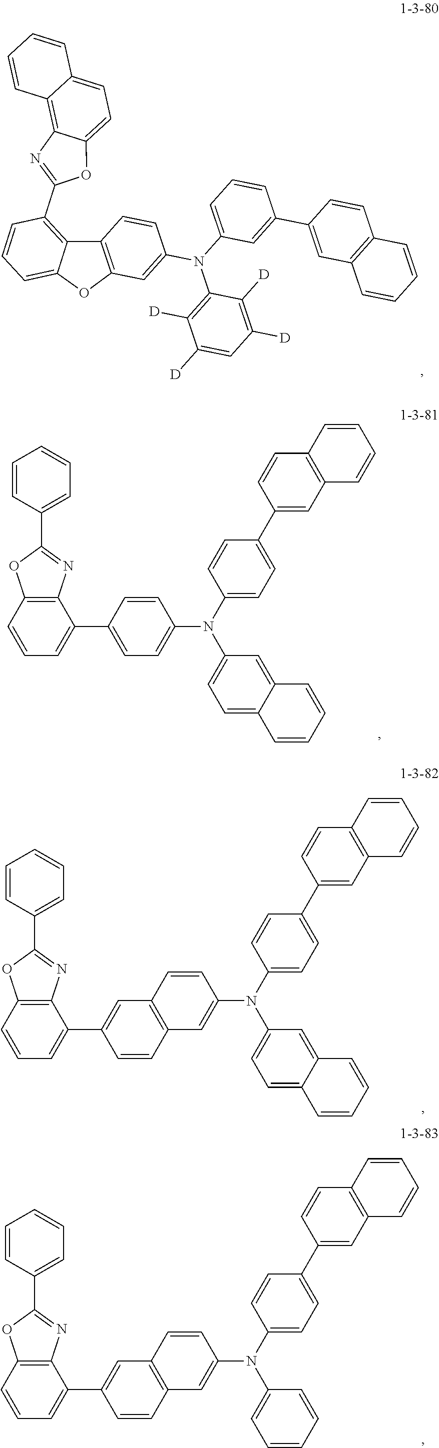

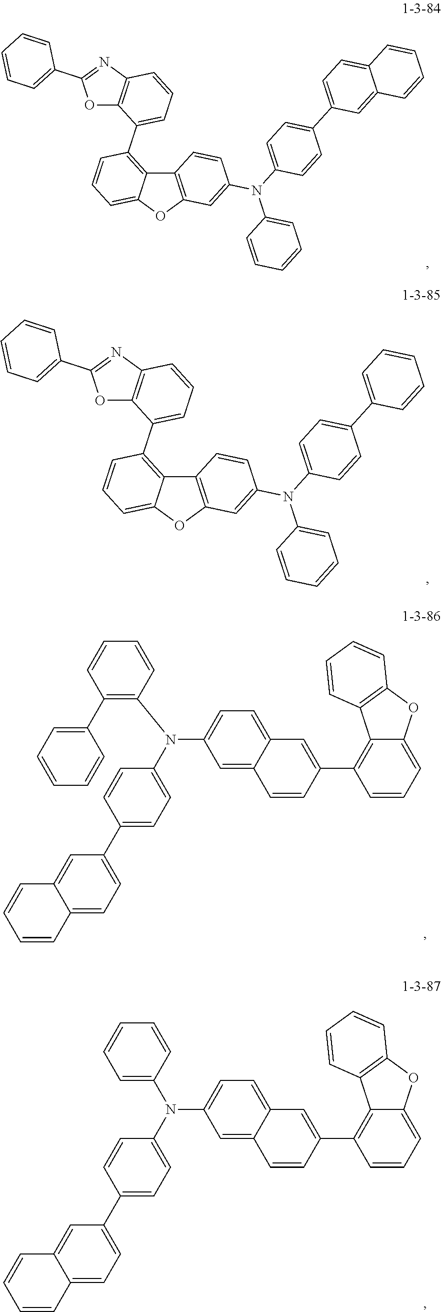 [SMILES: c1ccc(-c2nc3cccc(-c4cccc5oc6cc(N(c7ccccc7)c7ccc(-c8ccc9ccccc9c8)cc7)ccc6c45)c3o2)cc1 ; c1ccc(-c2ccc(N(c3ccccc3)c3ccc4c(c3)oc3cccc(-c5cccc6nc(-c7ccccc7)oc56)c34)cc2)cc1 ; c1ccc(-c2ccccc2N(c2ccc(-c3ccc4ccccc4c3)cc2)c2ccc3cc(-c4cccc5oc6ccccc6c45)ccc3c2)cc1 ; c1ccc(N(c2ccc(-c3ccc4ccccc4c3)cc2)c2ccc3cc(-c4cccc5oc6ccccc6c45)ccc3c2)cc1]

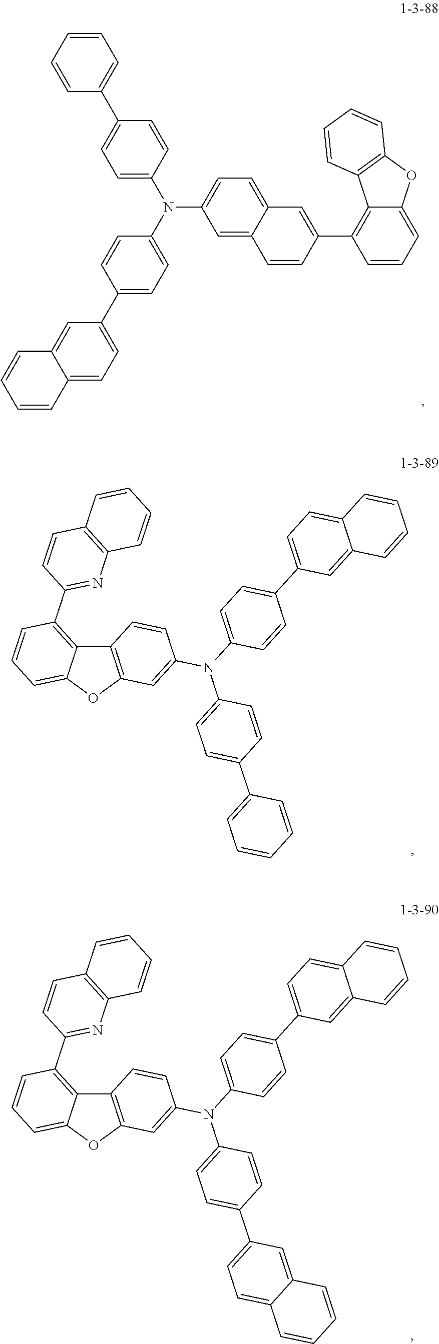 [SMILES: c1ccc(-c2ccc(N(c3ccc(-c4ccc5ccccc5c4)cc3)c3ccc4cc(-c5cccc6oc7ccccc7c56)ccc4c3)cc2)cc1 ; c1ccc(-c2ccc(N(c3ccc(-c4ccc5ccccc5c4)cc3)c3ccc4c(c3)oc3cccc(-c5ccc6ccccc6n5)c34)cc2)cc1 ; c1ccc2cc(-c3ccc(N(c4ccc(-c5ccc6ccccc6c5)cc4)c4ccc5c(c4)oc4cccc(-c6ccc7ccccc7n6)c45)cc3)ccc2c1]

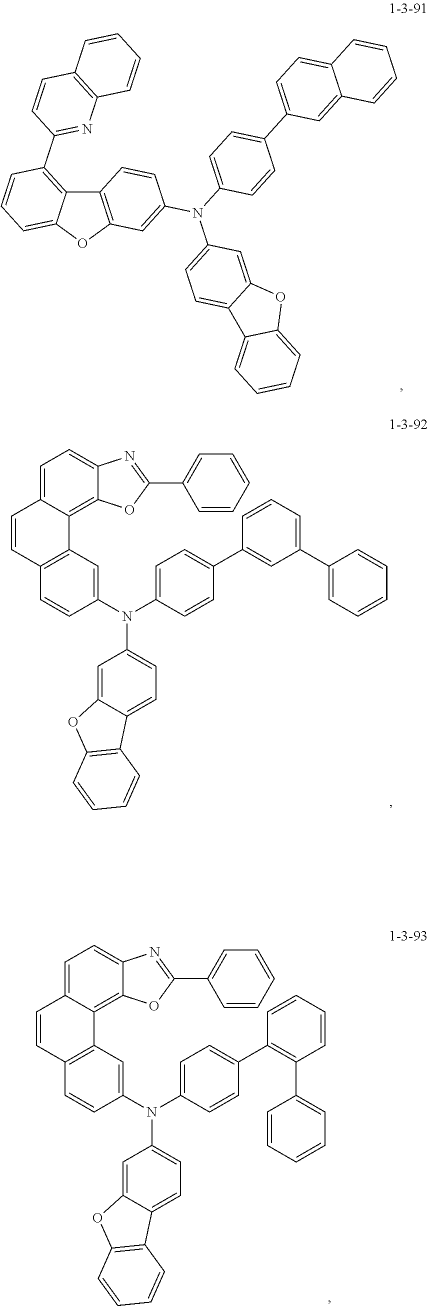 [SMILES: c1ccc2cc(-c3ccc(N(c4ccc5c(c4)oc4ccccc45)c4ccc5c(c4)oc4cccc(-c6ccc7ccccc7n6)c45)cc3)ccc2c1 ; c1ccc(-c2cccc(-c3ccc(N(c4ccc5c(c4)oc4ccccc45)c4ccc5ccc6ccc7nc(-c8ccccc8)oc7c6c5c4)cc3)c2)cc1 ; c1ccc(-c2nc3ccc4ccc5ccc(N(c6ccc(-c7ccccc7-c7ccccc7)cc6)c6ccc7c(c6)oc6ccccc67)cc5c4c3o2)cc1]

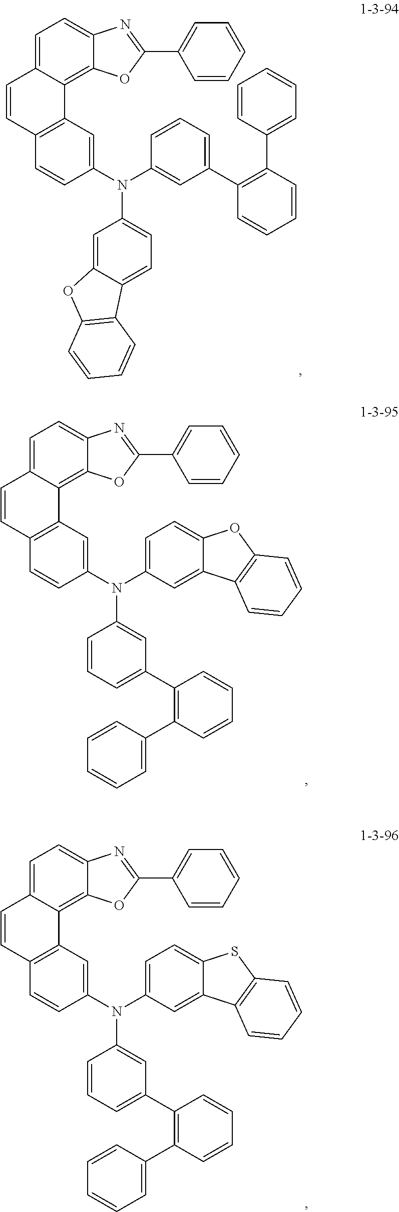 [SMILES: c1ccc(-c2nc3ccc4ccc5ccc(N(c6cccc(-c7ccccc7-c7ccccc7)c6)c6ccc7c(c6)oc6ccccc67)cc5c4c3o2)cc1 ; c1ccc(-c2nc3ccc4ccc5ccc(N(c6cccc(-c7ccccc7-c7ccccc7)c6)c6ccc7oc8ccccc8c7c6)cc5c4c3o2)cc1 ; c1ccc(-c2nc3ccc4ccc5ccc(N(c6cccc(-c7ccccc7-c7ccccc7)c6)c6ccc7sc8ccccc8c7c6)cc5c4c3o2)cc1]

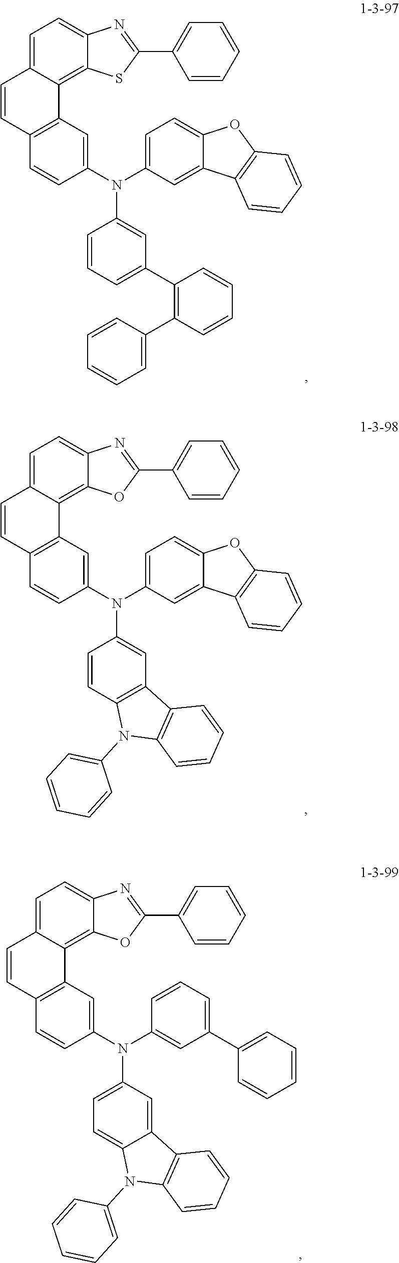 [SMILES: c1ccc(-c2nc3ccc4ccc5ccc(N(c6cccc(-c7ccccc7-c7ccccc7)c6)c6ccc7oc8ccccc8c7c6)cc5c4c3s2)cc1 ; c1ccc(-c2nc3ccc4ccc5ccc(N(c6ccc7oc8ccccc8c7c6)c6ccc7c(c6)c6ccccc6n7-c6ccccc6)cc5c4c3o2)cc1 ; c1ccc(-c2cccc(N(c3ccc4ccc5ccc6nc(-c7ccccc7)oc6c5c4c3)c3ccc4c(c3)c3ccccc3n4-c3ccccc3)c2)cc1]

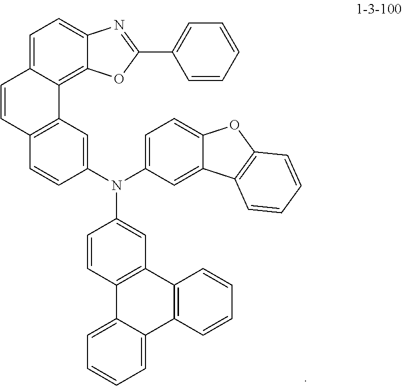 [SMILES: c1ccc(-c2nc3ccc4ccc5ccc(N(c6ccc7oc8ccccc8c7c6)c6ccc7c8ccccc8c8ccccc8c7c6)cc5c4c3o2)cc1]

According to an embodiment of the present disclosure, hydrogen in Compound 1-1-1 to Compound 1-1-104, Compound 1-2-1 to Compound 1-2-100 and Compound 1-3-1 to Compound 1-3-100 can be partially or fully substituted with deuterium.

According to an embodiment of the present disclosure, the second host material has a structure represented by Formula 5:

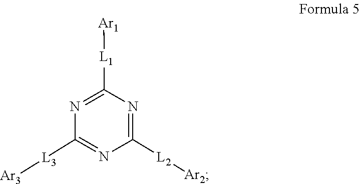

wherein L₁ to L₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms or a combination thereof; and
Ar₁ to Ar₃ are, at each occurrence identically or differently, selected from substituted or unsubstituted aryl having 6 to 30 carbon atoms, substituted or unsubstituted heteroaryl having 3 to 30 carbon atoms or a combination thereof.

According to an embodiment of the present disclosure, the second host material has a structure represented by Formula 5-1 or Formula 5-2:

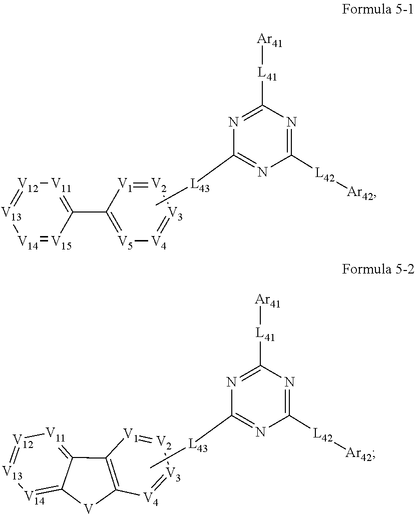

wherein in Formula 5-1, V₁ to V₅ are, at each occurrence identically or differently, selected from C, N or CRᵥ, V₁₁ to V₁₅ are, at each occurrence identically or differently, selected from N or CRᵥ₁, and one of V₁ to V₅ is C and joined to L₄₃;
in Formula 5-2, V₁ to V₄ are, at each occurrence identically or differently, selected from C, N or CRᵥ, V₁₁ to V₁₄ are, at each occurrence identically or differently, selected from N or CRᵥ₁, and one of V₁ to V₄ is C and joined to L₄₃;
V is selected from O, S or Se;
L₄₁ to L₄₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms or a combination thereof;
Ar₄₁ and Ar₄₂ are, at each occurrence identically or differently, selected from substituted or unsubstituted aryl having 6 to 30 carbon atoms, substituted or unsubstituted heteroaryl having 3 to 30 carbon atoms or a combination thereof;
Rᵥ and Rᵥ₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rᵥ and Rᵥ₁ can be optionally joined to form a ring.

In the present disclosure, the expression that adjacent substituents Rᵥ and Rᵥ₁ can be optionally joined to form a ring is intended to mean that any one or more of groups of adjacent substituents, such as adjacent substituents Rᵥ, adjacent substituents Rᵥ₁, and adjacent substituents Rᵥ and Rᵥ₁, can be joined to form a ring. Obviously, it is also possible that none of these substituents are joined to form a ring.

According to an embodiment of the present disclosure, at least one of Ar₄₁ and Ar₄₂ is a structure with two or three fused rings.

According to an embodiment of the present disclosure, Ar₄₁ and Ar₄₂ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted phenanthryl, substituted or unsubstituted triphenylenyl, substituted or unsubstituted chrysenyl, substituted or unsubstituted fluorenyl, substituted or unsubstituted carbazolyl, substituted or unsubstituted dibenzofuryl, substituted or unsubstituted dibenzothienyl, substituted or unsubstituted pyridyl, substituted or unsubstituted pyrimidinyl, substituted or unsubstituted quinolyl, substituted or unsubstituted indolocarbazolyl or a combination thereof.

According to an embodiment of the present disclosure, in a third compound, L₄₁ to L₄₃ are, at each occurrence identically or differently, selected from a single bond, substituted or unsubstituted phenylene, substituted or unsubstituted naphthylene, substituted or unsubstituted biphenylylene or a combination thereof.

According to an embodiment of the present disclosure, the second host compound is selected from the group consisting of Compound B-1 to Compound B-236:

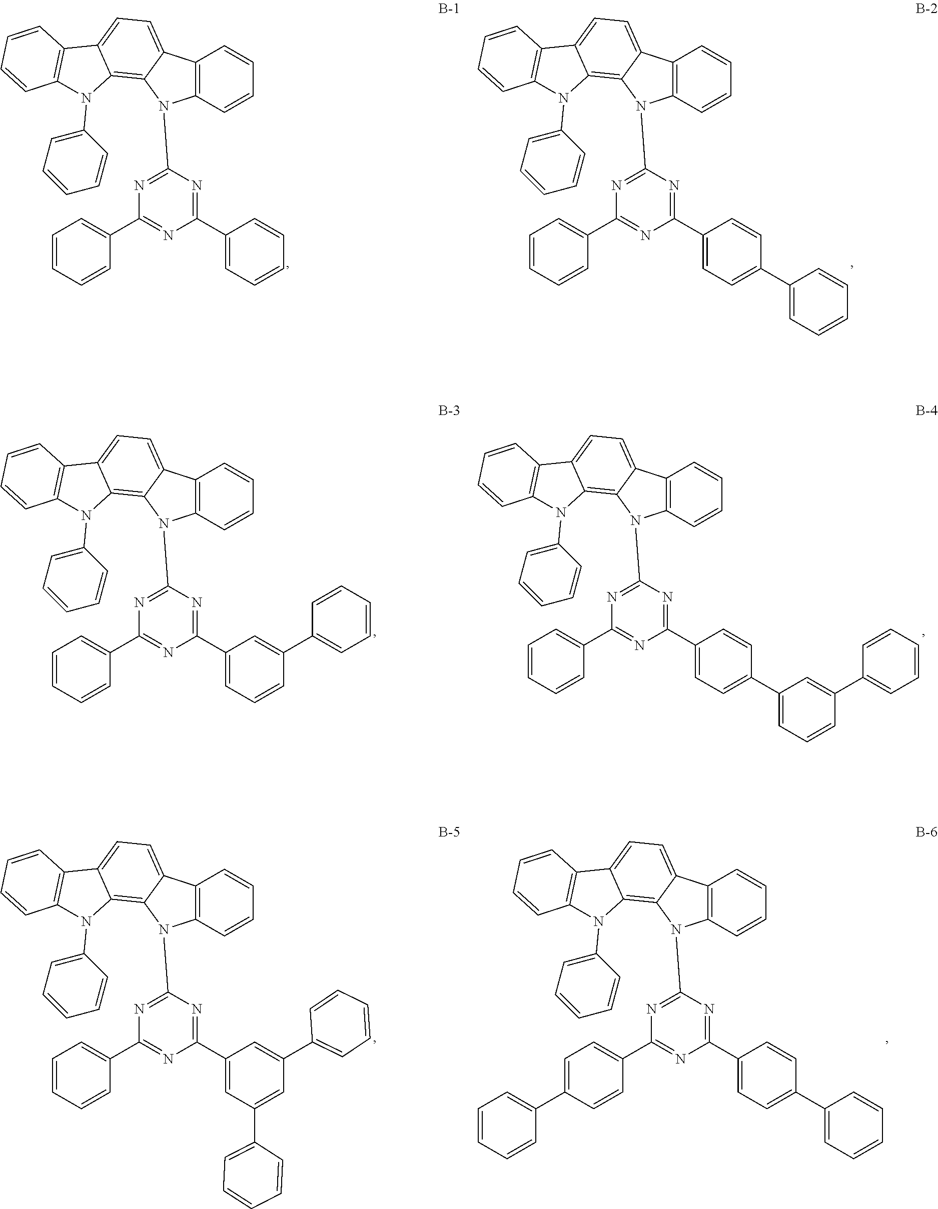

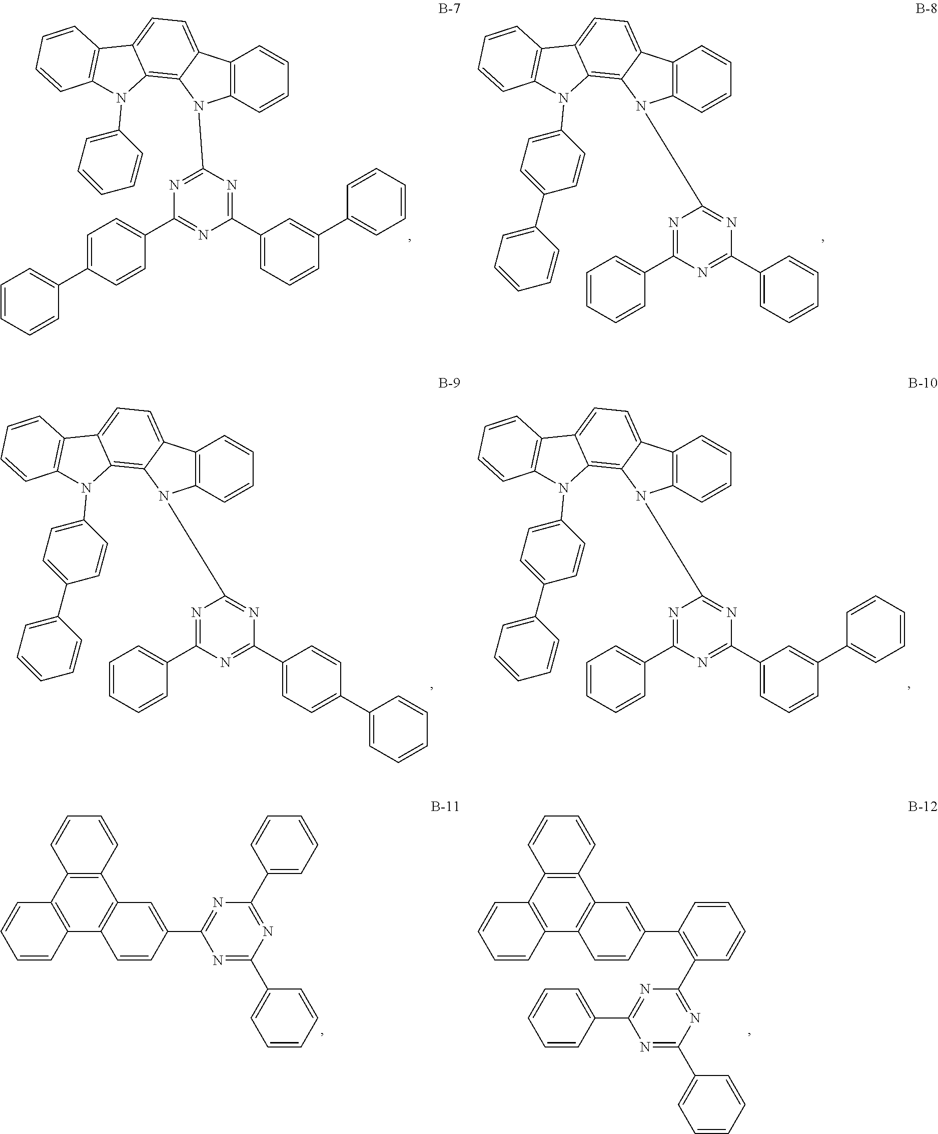

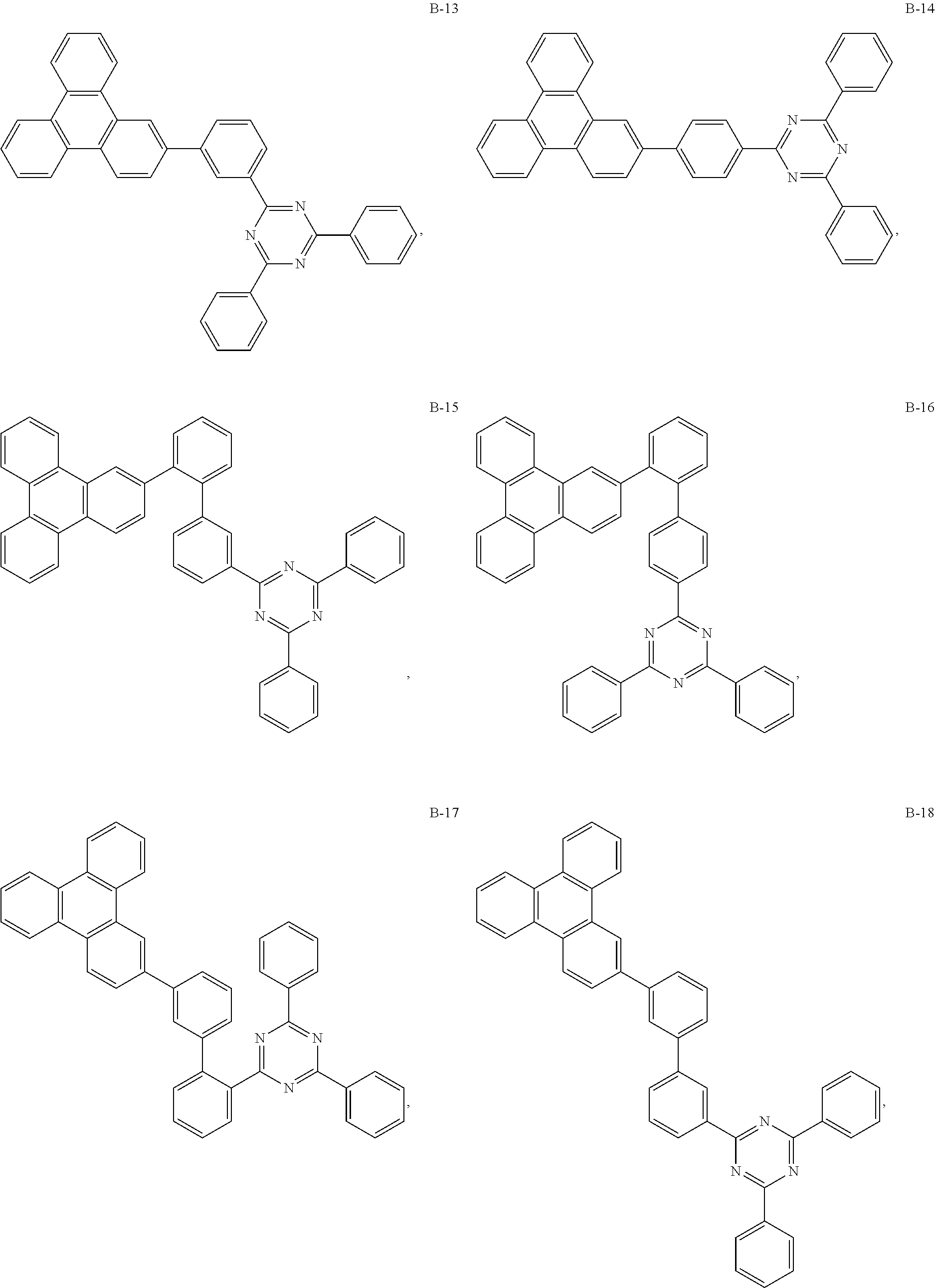 [SMILES: c1ccc(-c2nc(-c3ccccc3)nc(-c3cccc(-c4ccc5c6ccccc6c6ccccc6c5c4)c3)n2)cc1 ; c1ccc(-c2nc(-c3ccccc3)nc(-c3ccc(-c4ccc5c6ccccc6c6ccccc6c5c4)cc3)n2)cc1 ; c1ccc(-c2nc(-c3ccccc3)nc(-c3cccc(-c4ccccc4-c4ccc5c6ccccc6c6ccccc6c5c4)c3)n2)cc1 ; c1ccc(-c2nc(-c3ccccc3)nc(-c3ccc(-c4ccccc4-c4ccc5c6ccccc6c6ccccc6c5c4)cc3)n2)cc1 ; c1ccc(-c2nc(-c3ccccc3)nc(-c3ccccc3-c3cccc(-c4ccc5c6ccccc6c6ccccc6c5c4)c3)n2)cc1 ; c1ccc(-c2nc(-c3ccccc3)nc(-c3cccc(-c4cccc(-c5ccc6c7ccccc7c7ccccc7c6c5)c4)c3)n2)cc1]

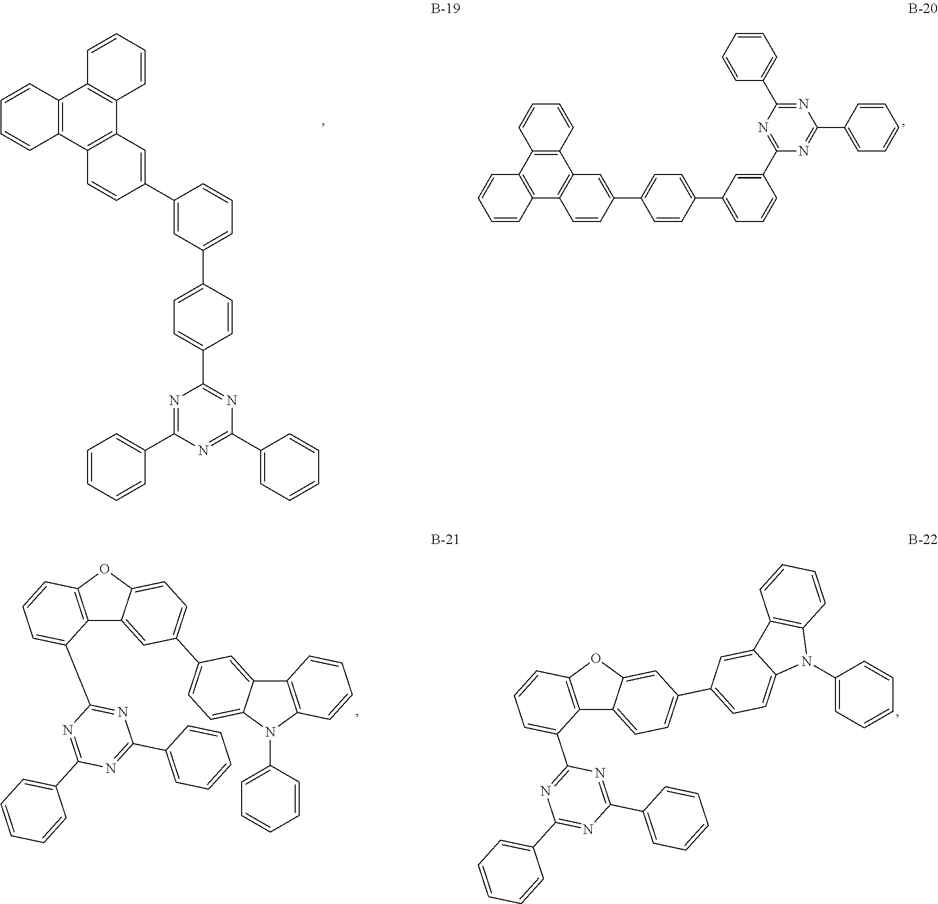 [SMILES: c1ccc(-c2nc(-c3ccccc3)nc(-c3ccc(-c4cccc(-c5ccc6c7ccccc7c7ccccc7c6c5)c4)cc3)n2)cc1 ; c1ccc(-c2nc(-c3ccccc3)nc(-c3cccc(-c4ccc(-c5ccc6c7ccccc7c7ccccc7c6c5)cc4)c3)n2)cc1 ; c1ccc(-c2nc(-c3ccccc3)nc(-c3cccc4oc5ccc(-c6ccc7c(c6)c6ccccc6n7-c6ccccc6)cc5c34)n2)cc1 ; c1ccc(-c2nc(-c3ccccc3)nc(-c3cccc4oc5cc(-c6ccc7c(c6)c6ccccc6n7-c6ccccc6)ccc5c34)n2)cc1]

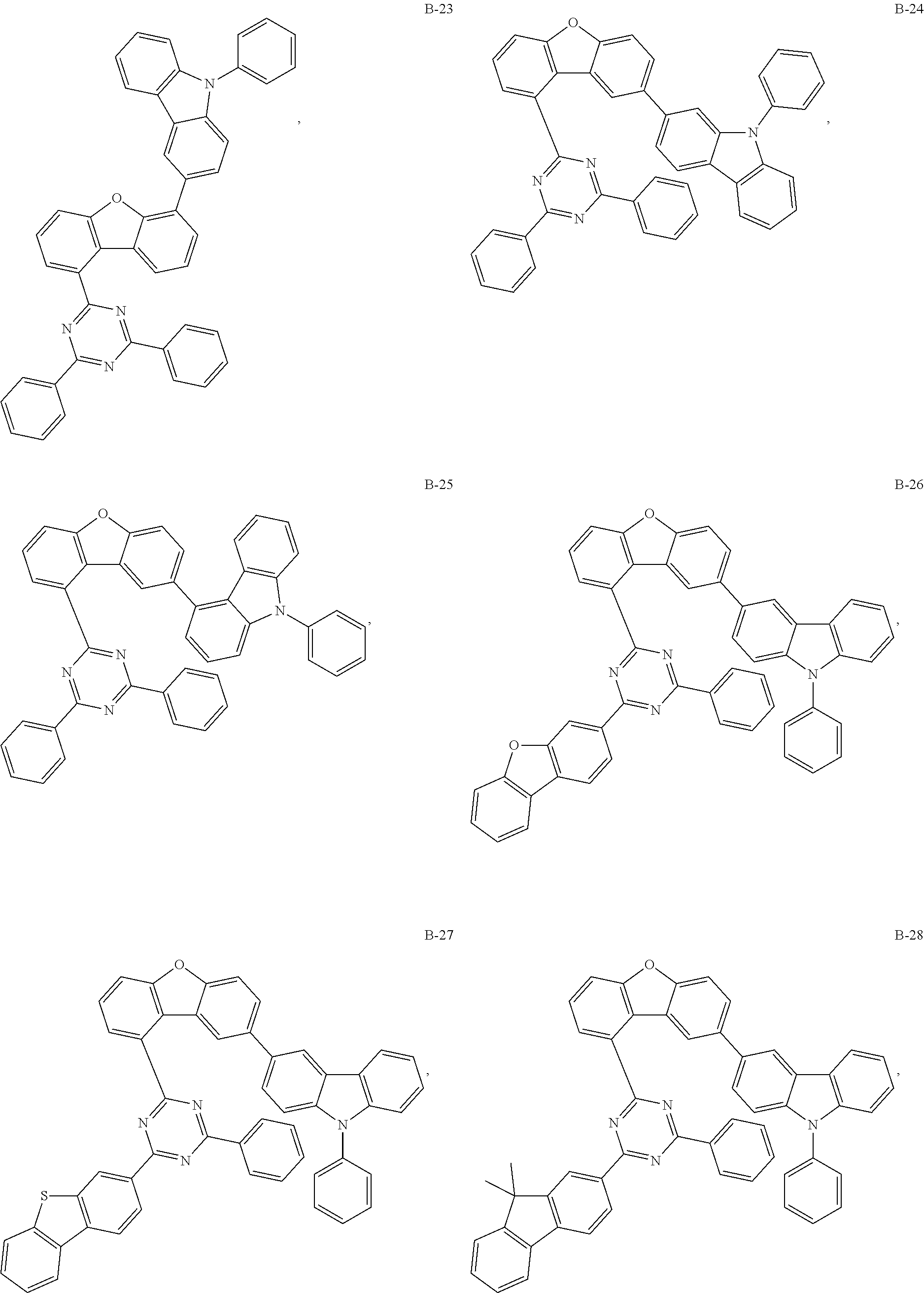

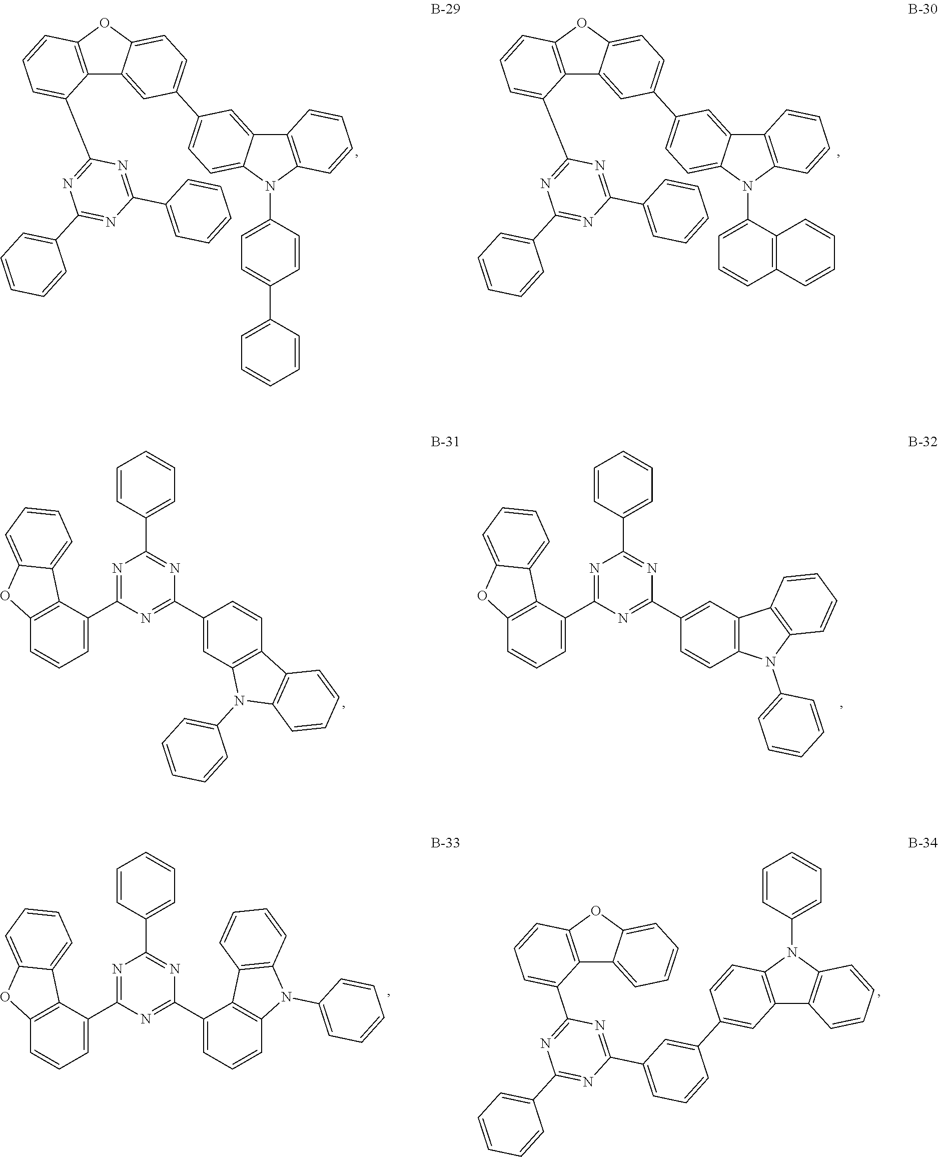

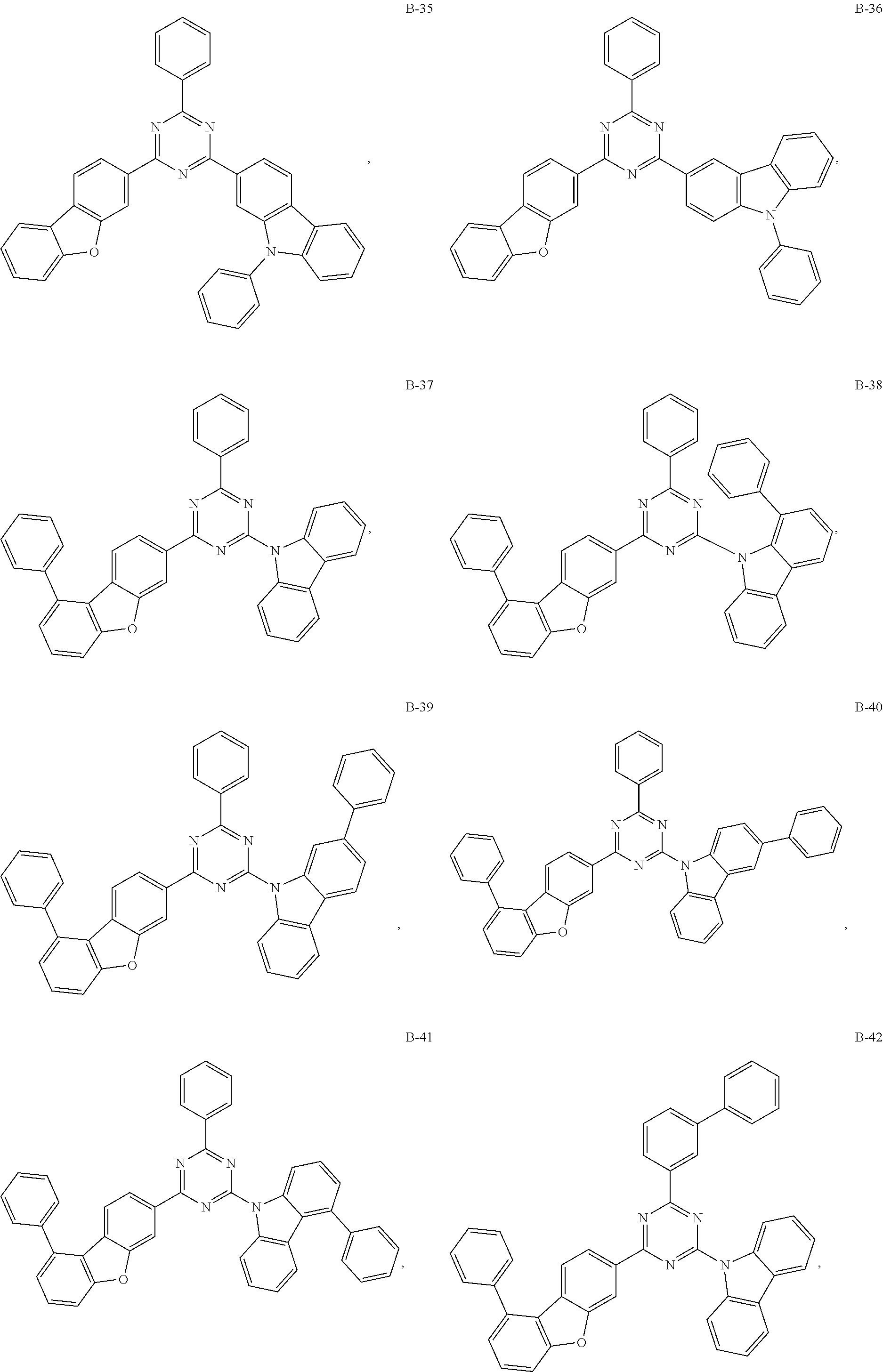

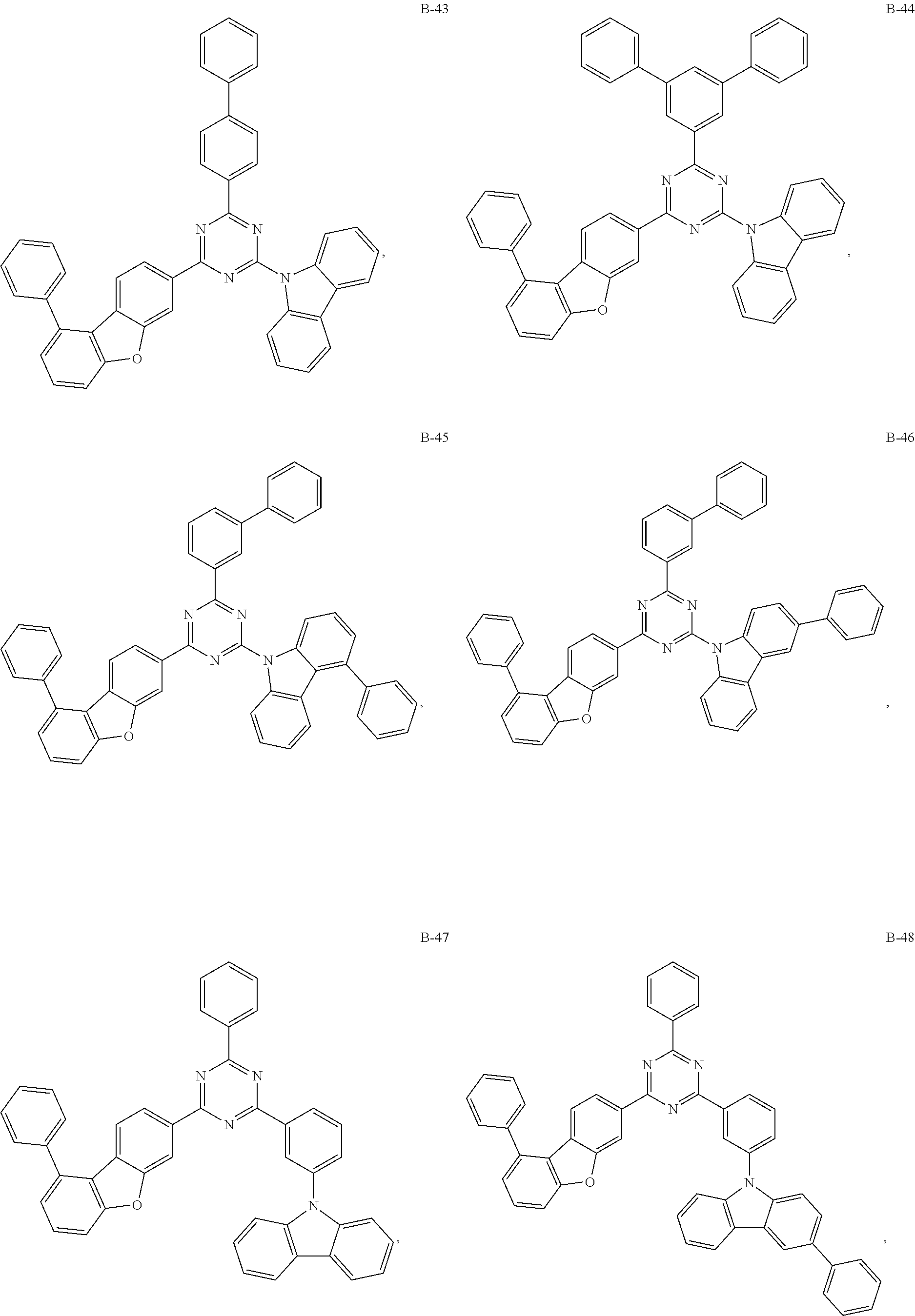

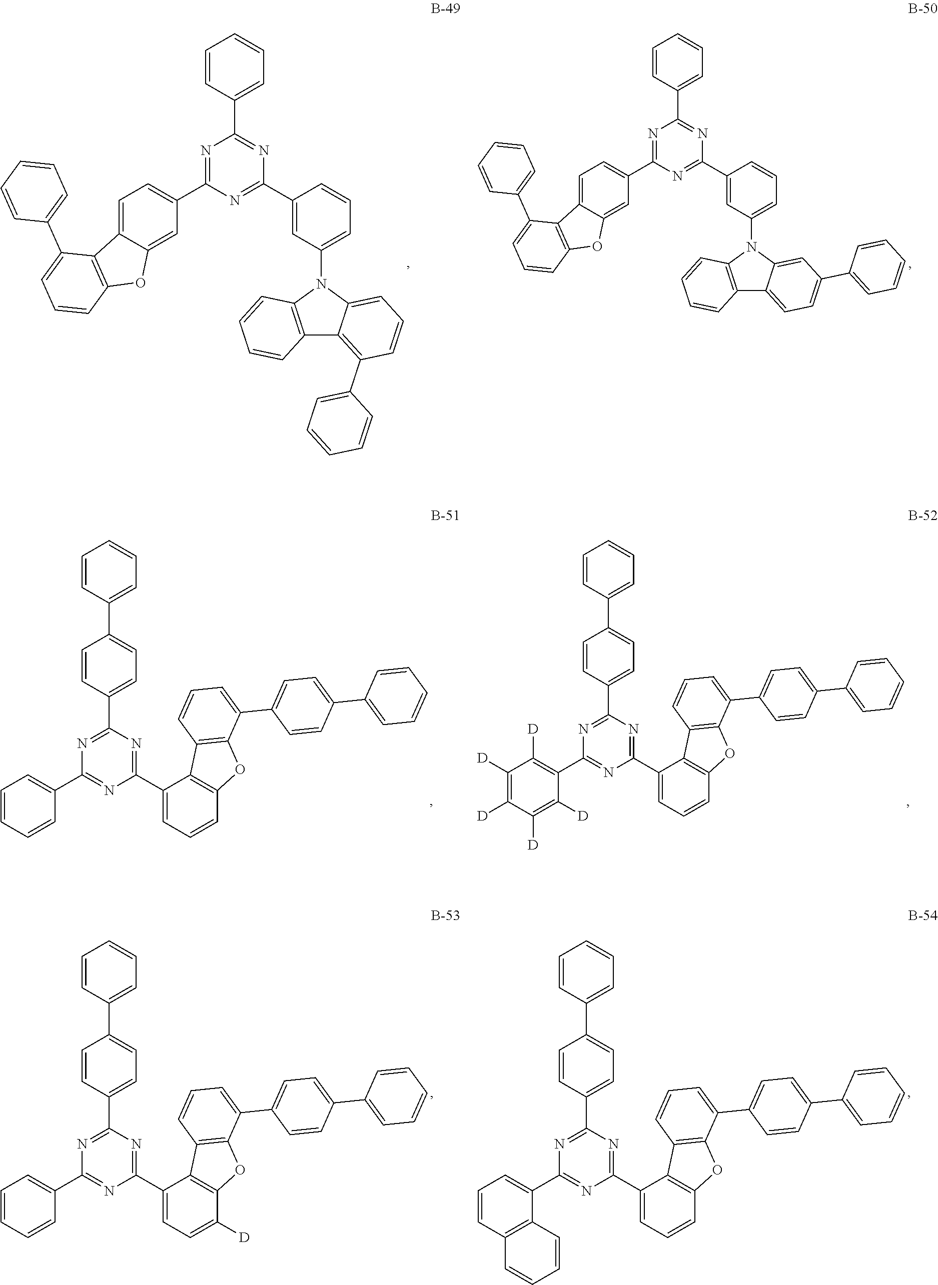

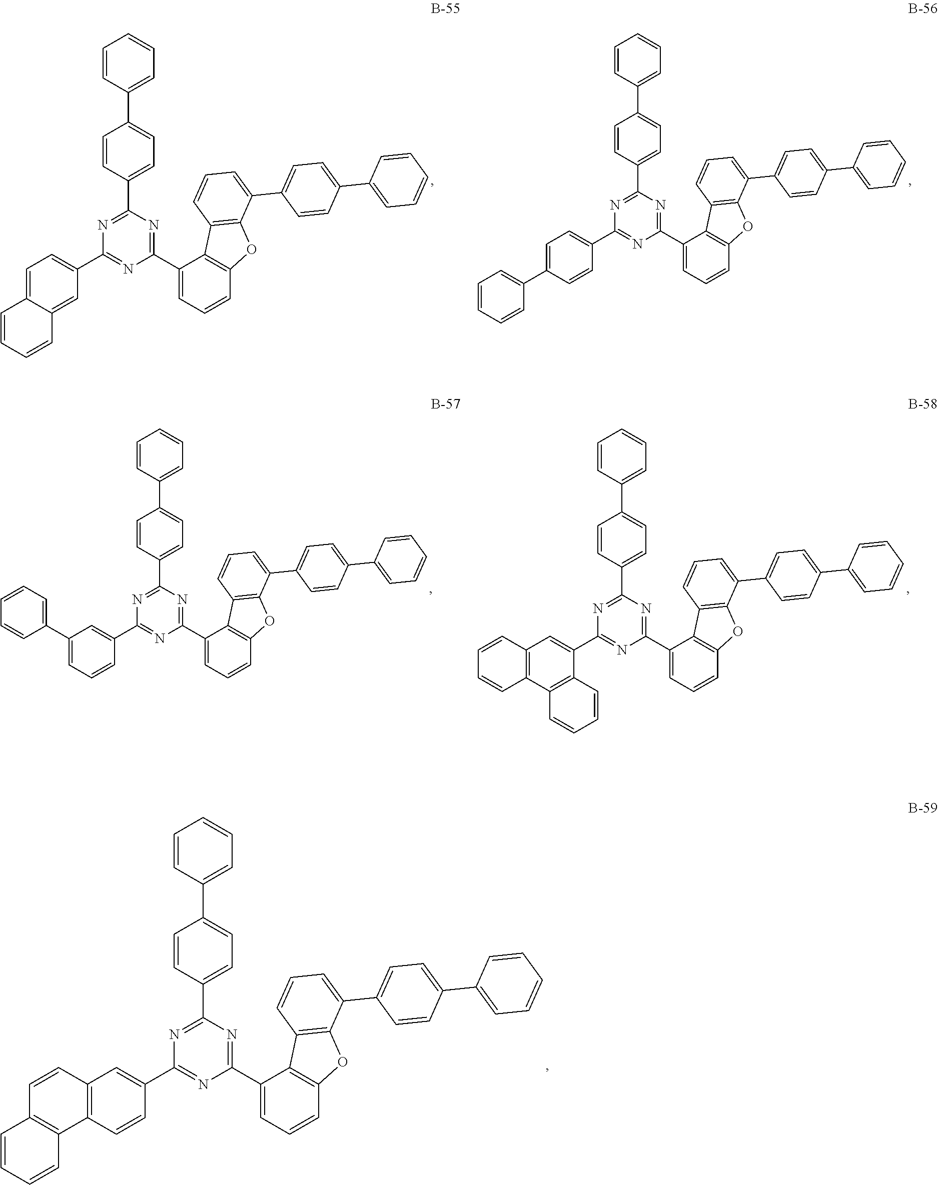 [SMILES: c1ccc(-c2ccc(-c3nc(-c4ccc5ccccc5c4)nc(-c4cccc5oc6c(-c7ccc(-c8ccccc8)cc7)cccc6c45)n3)cc2)cc1 ; c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1 ; c1ccc(-c2ccc(-c3nc(-c4cc5ccccc5c5ccccc45)nc(-c4cccc5oc6c(-c7ccc(-c8ccccc8)cc7)cccc6c45)n3)cc2)cc1 ; c1ccc(-c2ccc(-c3nc(-c4ccc5c(ccc6ccccc65)c4)nc(-c4cccc5oc6c(-c7ccc(-c8ccccc8)cc7)cccc6c45)n3)cc2)cc1]

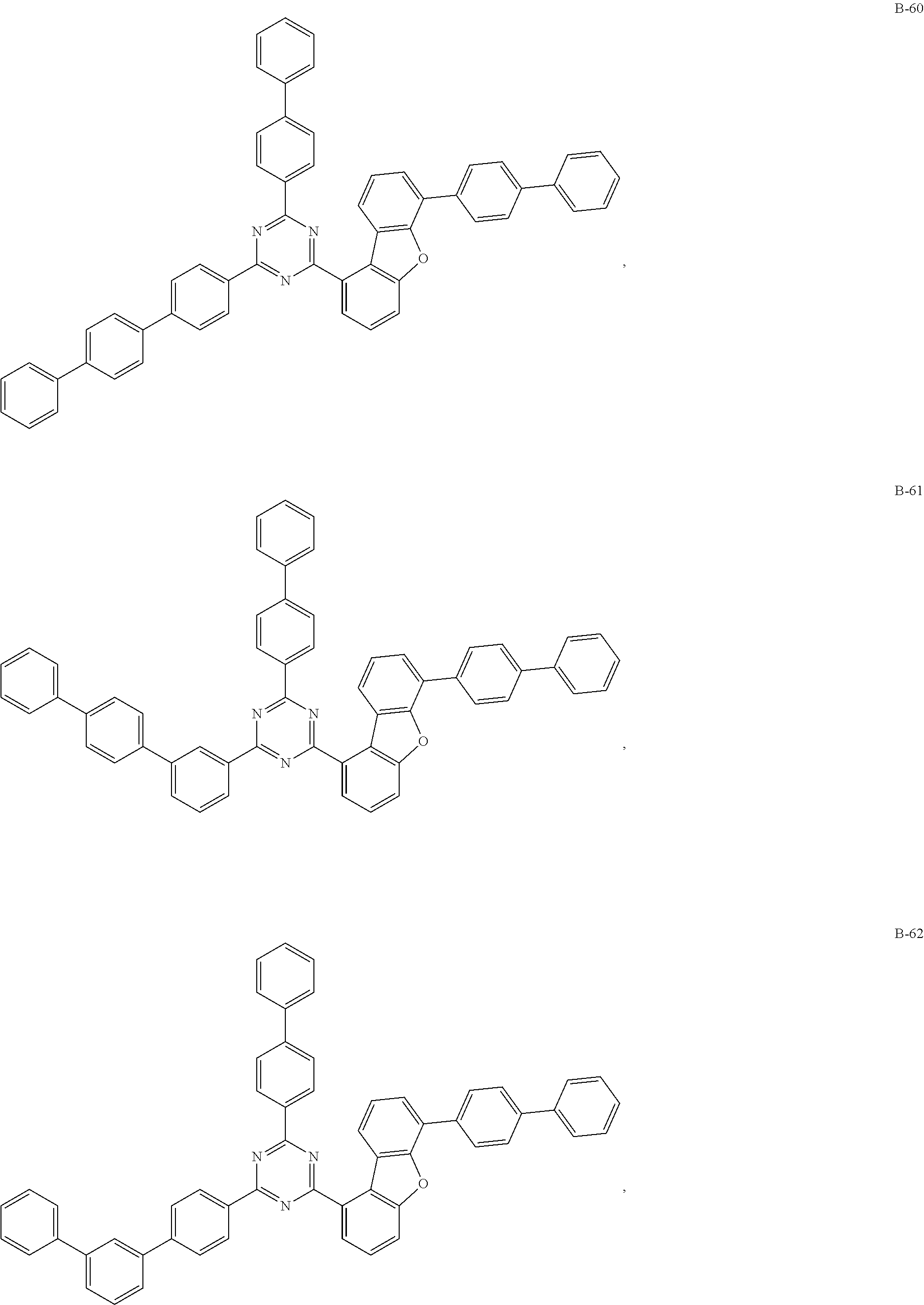 [SMILES: c1ccc(-c2ccc(-c3ccc(-c4nc(-c5ccc(-c6ccccc6)cc5)nc(-c5cccc6oc7c(-c8ccc(-c9ccccc9)cc8)cccc7c56)n4)cc3)cc2)cc1 ; c1ccc(-c2ccc(-c3cccc(-c4nc(-c5ccc(-c6ccccc6)cc5)nc(-c5cccc6oc7c(-c8ccc(-c9ccccc9)cc8)cccc7c56)n4)c3)cc2)cc1 ; c1ccc(-c2ccc(-c3nc(-c4ccc(-c5cccc(-c6ccccc6)c5)cc4)nc(-c4cccc5oc6c(-c7ccc(-c8ccccc8)cc7)cccc6c45)n3)cc2)cc1]

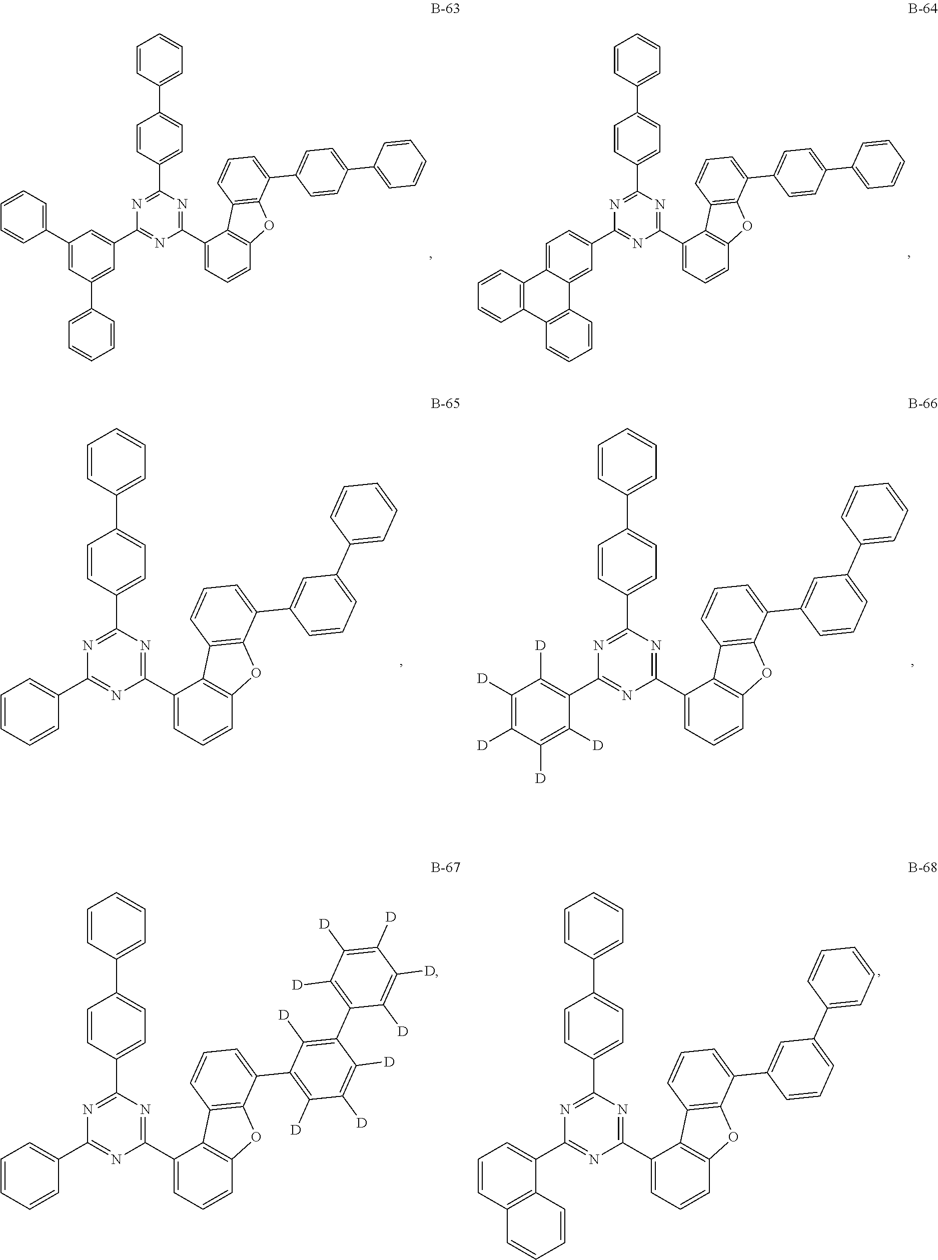

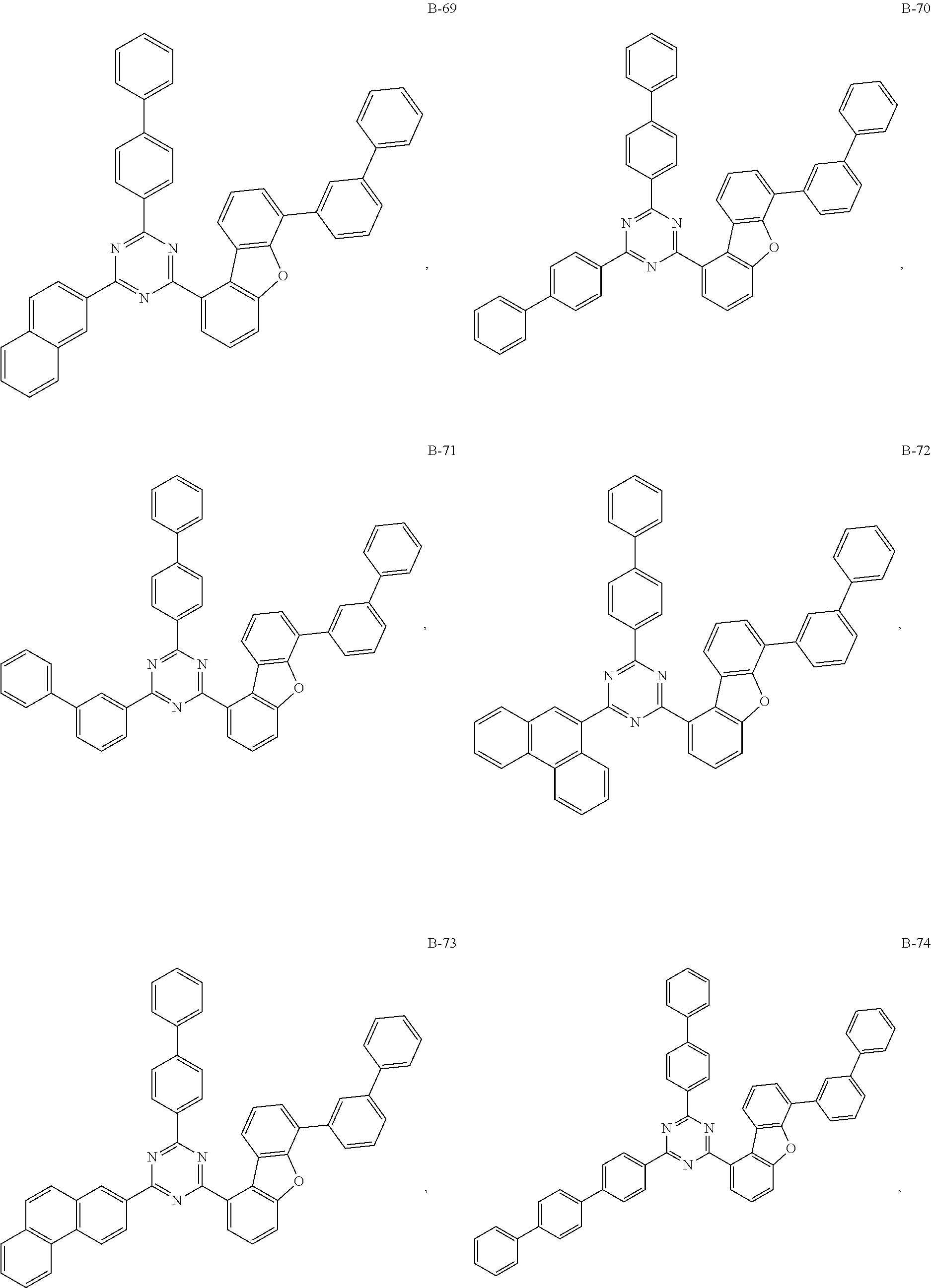

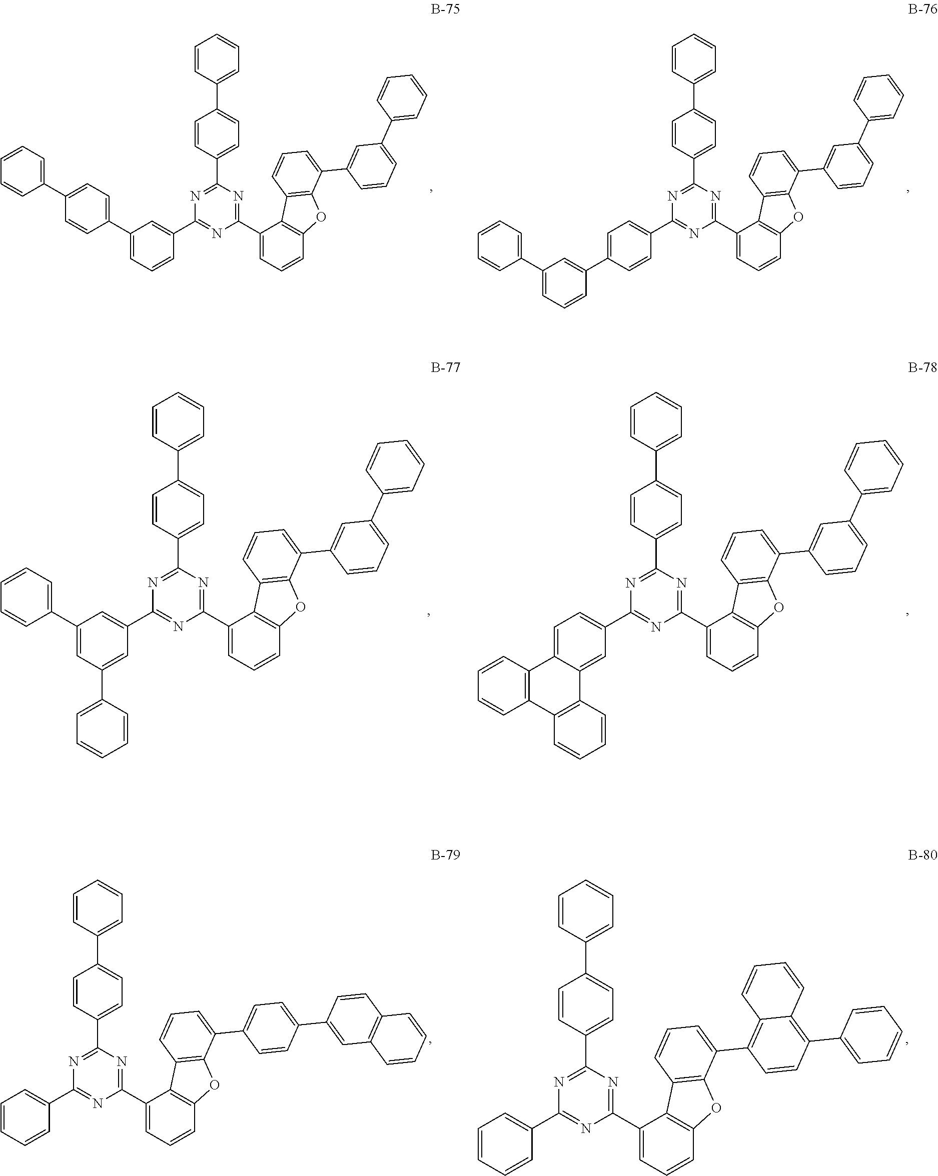

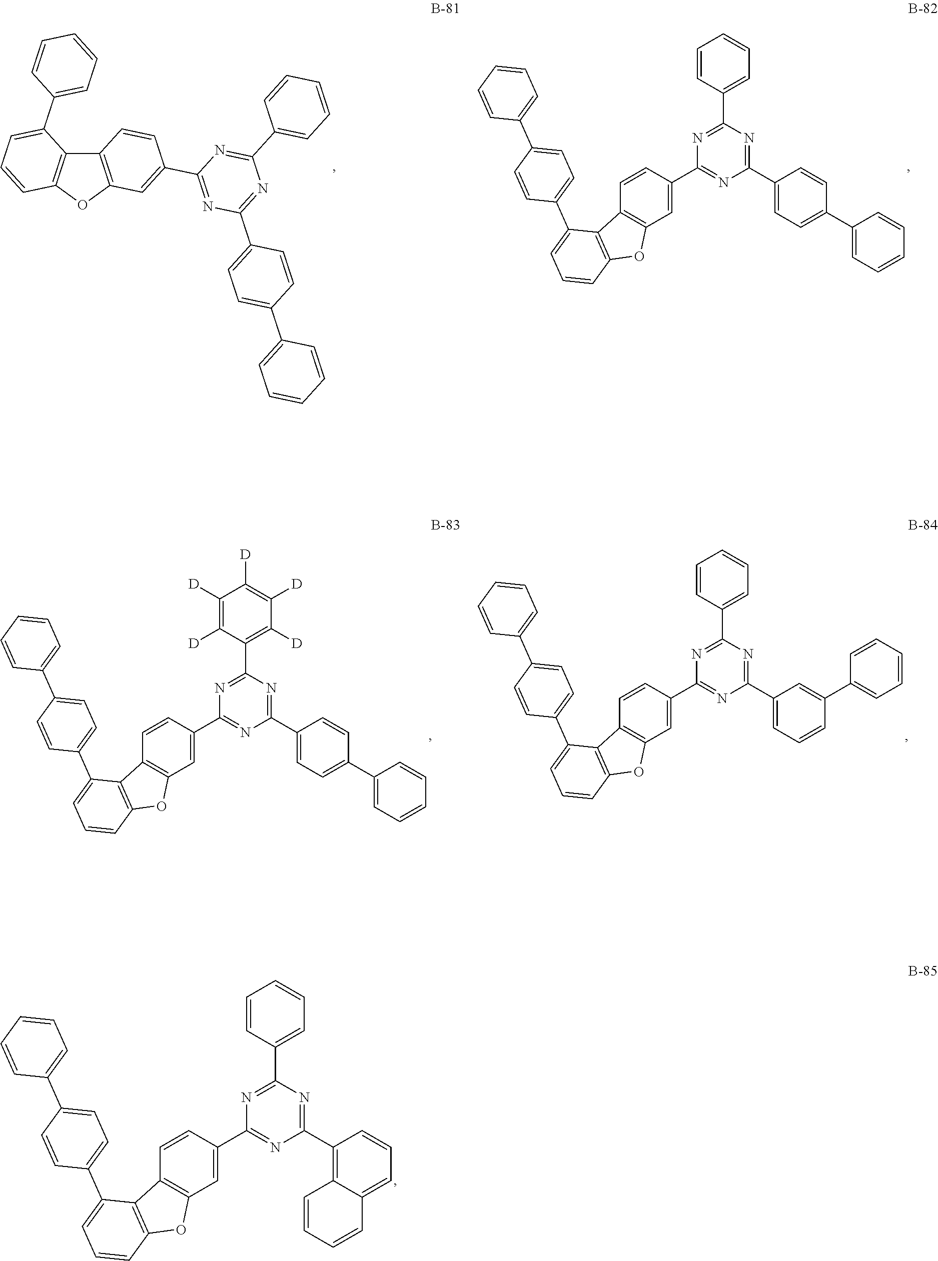 [SMILES: c1ccc(-c2ccc(-c3nc(-c4ccccc4)nc(-c4ccc5c(c4)oc4cccc(-c6ccccc6)c45)n3)cc2)cc1 ; c1ccc(-c2ccc(-c3nc(-c4ccccc4)nc(-c4ccc5c(c4)oc4cccc(-c6ccc(-c7ccccc7)cc6)c45)n3)cc2)cc1 ; [2H]c1c([2H])c([2H])c(-c2nc(-c3ccc(-c4ccccc4)cc3)nc(-c3ccc4c(c3)oc3cccc(-c5ccc(-c6ccccc6)cc5)c34)n2)c([2H])c1[2H] ; c1ccc(-c2ccc(-c3cccc4oc5cc(-c6nc(-c7ccccc7)nc(-c7cccc(-c8ccccc8)c7)n6)ccc5c34)cc2)cc1 ; c1ccc(-c2ccc(-c3cccc4oc5cc(-c6nc(-c7ccccc7)nc(-c7cccc8ccccc78)n6)ccc5c34)cc2)cc1]

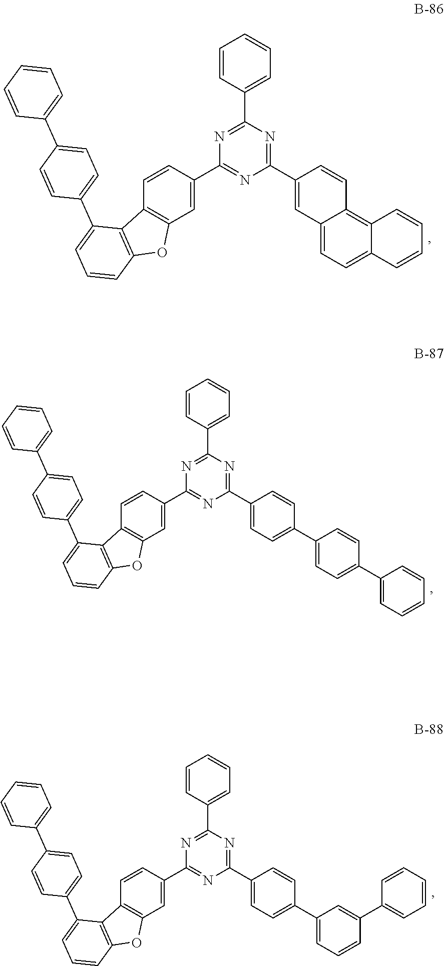 [SMILES: c1ccc(-c2ccc(-c3cccc4oc5cc(-c6nc(-c7ccccc7)nc(-c7ccc8c(ccc9ccccc98)c7)n6)ccc5c34)cc2)cc1 ; c1ccc(-c2ccc(-c3ccc(-c4nc(-c5ccccc5)nc(-c5ccc6c(c5)oc5cccc(-c7ccc(-c8ccccc8)cc7)c56)n4)cc3)cc2)cc1 ; c1ccc(-c2ccc(-c3cccc4oc5cc(-c6nc(-c7ccccc7)nc(-c7ccc(-c8cccc(-c9ccccc9)c8)cc7)n6)ccc5c34)cc2)cc1]

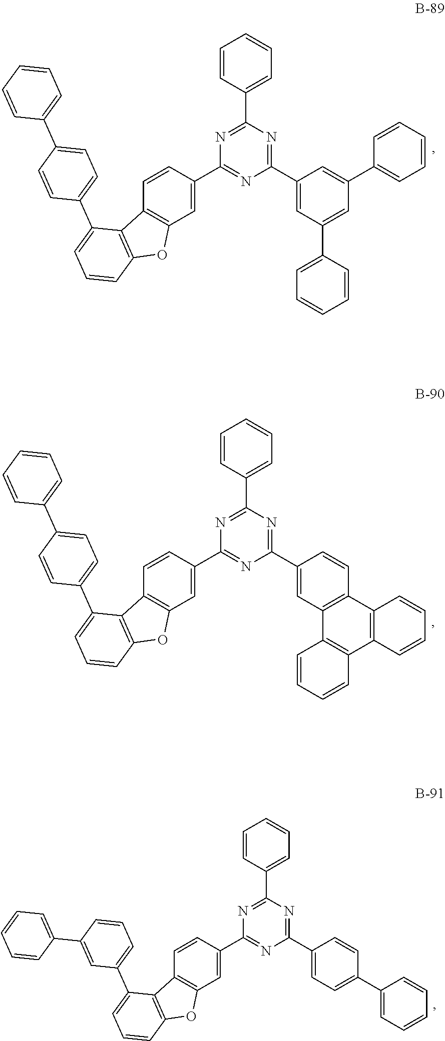 [SMILES: c1ccc(-c2ccc(-c3cccc4oc5cc(-c6nc(-c7ccccc7)nc(-c7cc(-c8ccccc8)cc(-c8ccccc8)c7)n6)ccc5c34)cc2)cc1 ; c1ccc(-c2ccc(-c3cccc4oc5cc(-c6nc(-c7ccccc7)nc(-c7ccc8c9ccccc9c9ccccc9c8c7)n6)ccc5c34)cc2)cc1 ; c1ccc(-c2ccc(-c3nc(-c4ccccc4)nc(-c4ccc5c(c4)oc4cccc(-c6cccc(-c7ccccc7)c6)c45)n3)cc2)cc1]

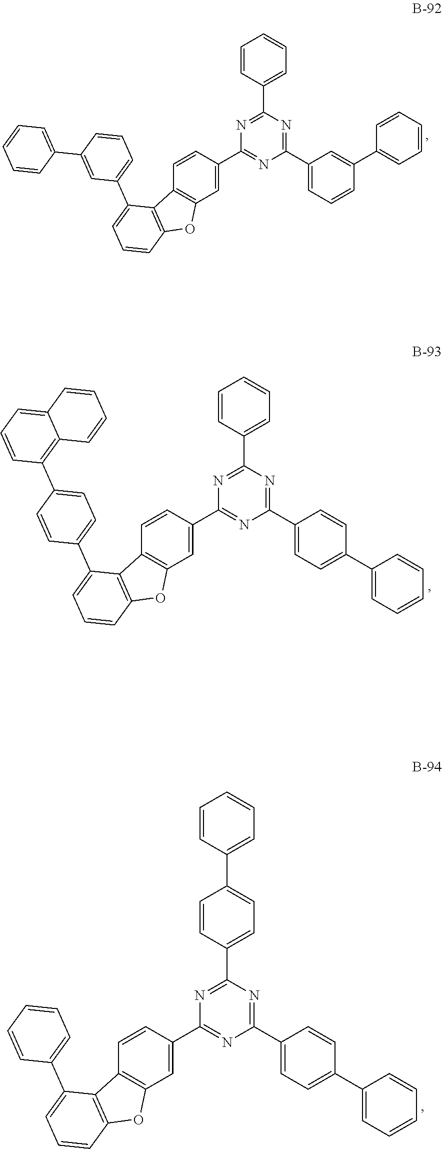 [SMILES: c1ccc(-c2cccc(-c3nc(-c4ccccc4)nc(-c4ccc5c(c4)oc4cccc(-c6cccc(-c7ccccc7)c6)c45)n3)c2)cc1 ; c1ccc(-c2ccc(-c3nc(-c4ccccc4)nc(-c4ccc5c(c4)oc4cccc(-c6ccc(-c7cccc8ccccc78)cc6)c45)n3)cc2)cc1 ; c1ccc(-c2ccc(-c3nc(-c4ccc(-c5ccccc5)cc4)nc(-c4ccc5c(c4)oc4cccc(-c6ccccc6)c45)n3)cc2)cc1]

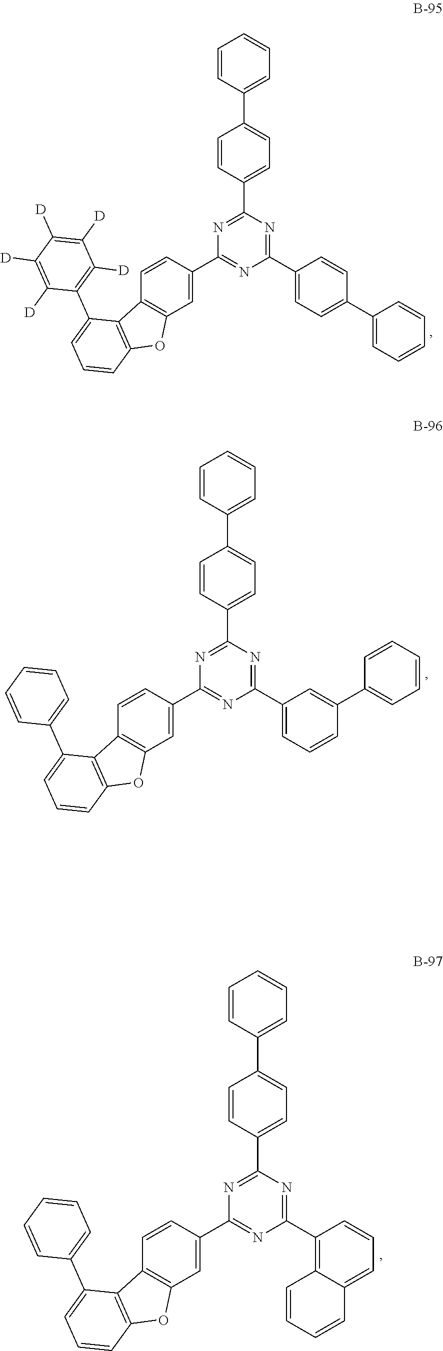 [SMILES: [2H]c1c([2H])c([2H])c(-c2cccc3oc4cc(-c5nc(-c6ccc(-c7ccccc7)cc6)nc(-c6ccc(-c7ccccc7)cc6)n5)ccc4c23)c([2H])c1[2H] ; c1ccc(-c2ccc(-c3nc(-c4cccc(-c5ccccc5)c4)nc(-c4ccc5c(c4)oc4cccc(-c6ccccc6)c45)n3)cc2)cc1 ; c1ccc(-c2ccc(-c3nc(-c4ccc5c(c4)oc4cccc(-c6ccccc6)c45)nc(-c4cccc5ccccc45)n3)cc2)cc1]

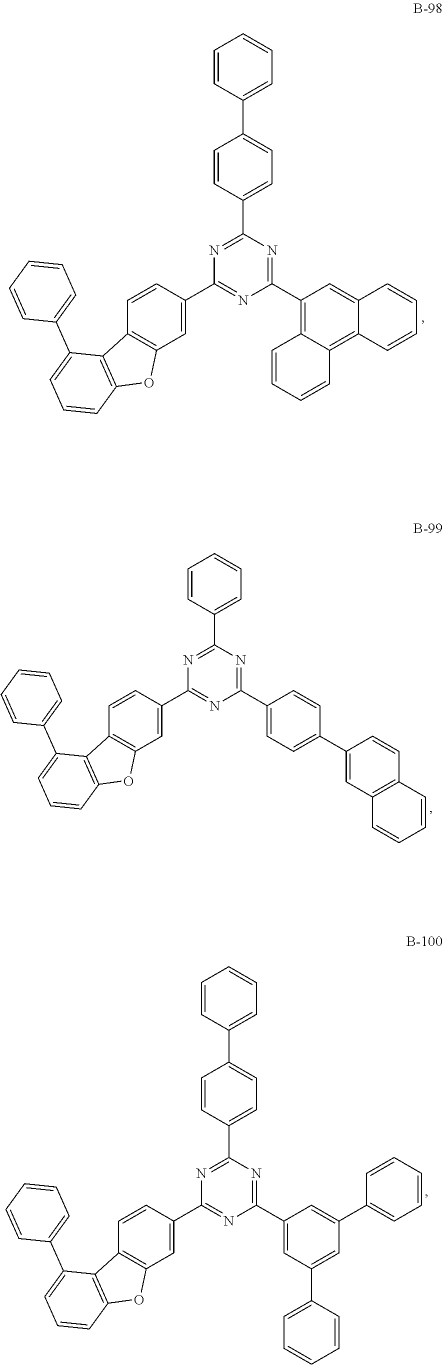 [SMILES: c1ccc(-c2ccc(-c3nc(-c4ccc5c(c4)oc4cccc(-c6ccccc6)c45)nc(-c4cc5ccccc5c5ccccc45)n3)cc2)cc1 ; c1ccc(-c2nc(-c3ccc(-c4ccc5ccccc5c4)cc3)nc(-c3ccc4c(c3)oc3cccc(-c5ccccc5)c34)n2)cc1 ; c1ccc(-c2ccc(-c3nc(-c4cc(-c5ccccc5)cc(-c5ccccc5)c4)nc(-c4ccc5c(c4)oc4cccc(-c6ccccc6)c45)n3)cc2)cc1]

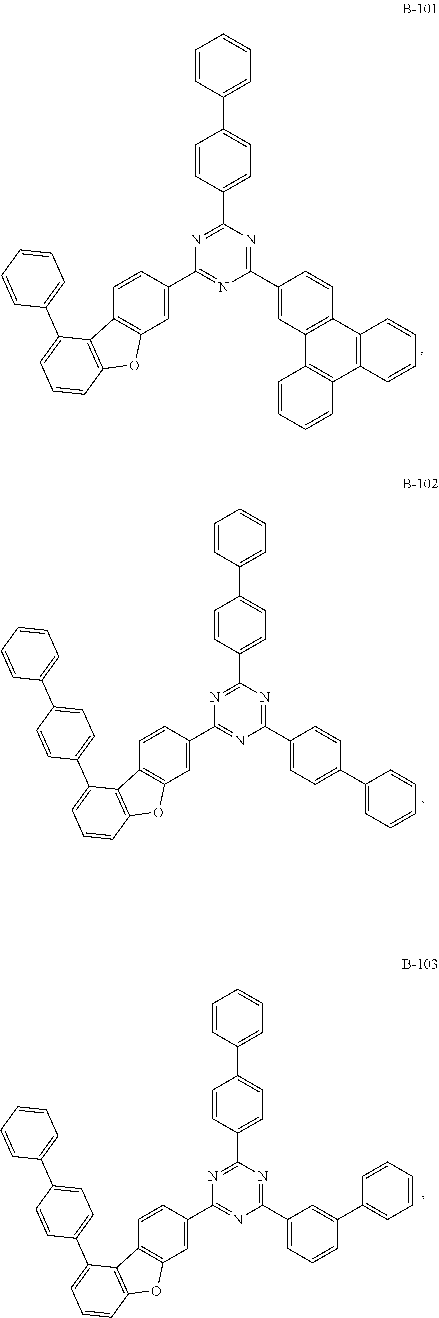 [SMILES: c1ccc(-c2ccc(-c3nc(-c4ccc5c(c4)oc4cccc(-c6ccccc6)c45)nc(-c4ccc5c6ccccc6c6ccccc6c5c4)n3)cc2)cc1 ; c1ccc(-c2ccc(-c3nc(-c4ccc(-c5ccccc5)cc4)nc(-c4ccc5c(c4)oc4cccc(-c6ccc(-c7ccccc7)cc6)c45)n3)cc2)cc1 ; c1ccc(-c2ccc(-c3nc(-c4cccc(-c5ccccc5)c4)nc(-c4ccc5c(c4)oc4cccc(-c6ccc(-c7ccccc7)cc6)c45)n3)cc2)cc1]

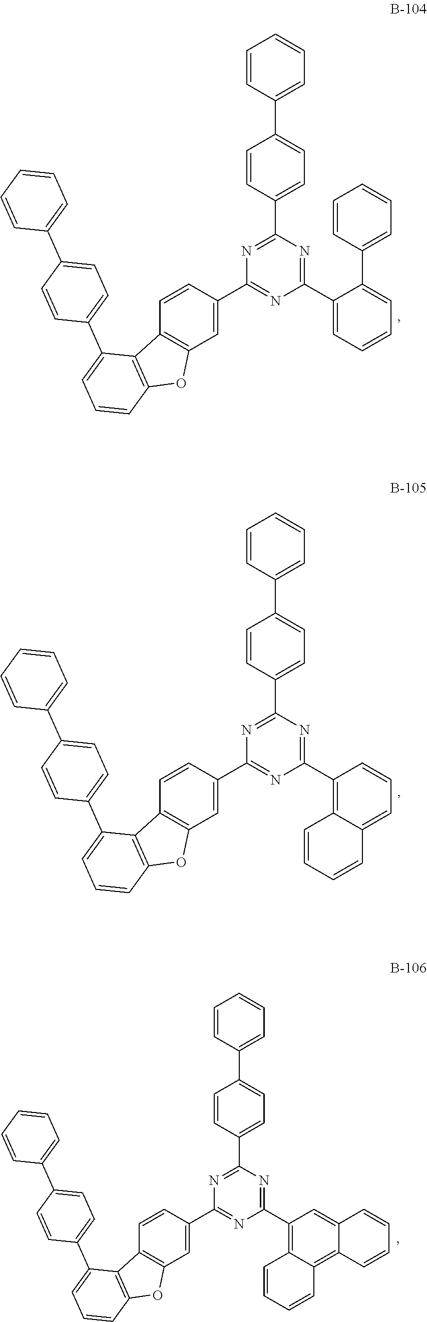 [SMILES: c1ccc(-c2ccc(-c3nc(-c4ccc5c(c4)oc4cccc(-c6ccc(-c7ccccc7)cc6)c45)nc(-c4ccccc4-c4ccccc4)n3)cc2)cc1 ; c1ccc(-c2ccc(-c3nc(-c4ccc5c(c4)oc4cccc(-c6ccc(-c7ccccc7)cc6)c45)nc(-c4cccc5ccccc45)n3)cc2)cc1 ; c1ccc(-c2ccc(-c3nc(-c4ccc5c(c4)oc4cccc(-c6ccc(-c7ccccc7)cc6)c45)nc(-c4cc5ccccc5c5ccccc45)n3)cc2)cc1]

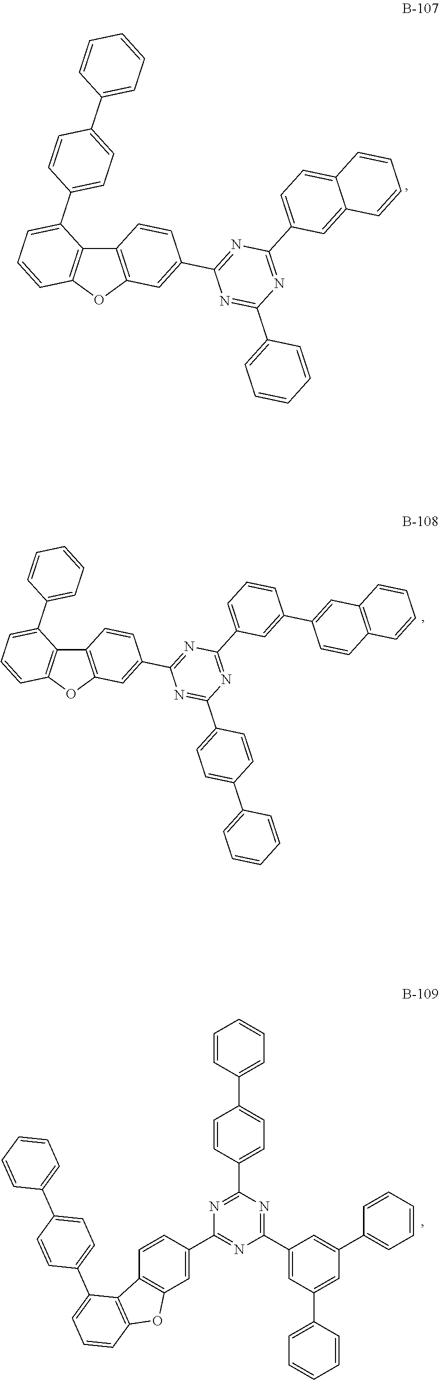 [SMILES: c1ccc(-c2ccc(-c3cccc4oc5cc(-c6nc(-c7ccccc7)nc(-c7ccc8ccccc8c7)n6)ccc5c34)cc2)cc1 ; c1ccc(-c2ccc(-c3nc(-c4cccc(-c5ccc6ccccc6c5)c4)nc(-c4ccc5c(c4)oc4cccc(-c6ccccc6)c45)n3)cc2)cc1 ; c1ccc(-c2ccc(-c3nc(-c4cc(-c5ccccc5)cc(-c5ccccc5)c4)nc(-c4ccc5c(c4)oc4cccc(-c6ccc(-c7ccccc7)cc6)c45)n3)cc2)cc1]

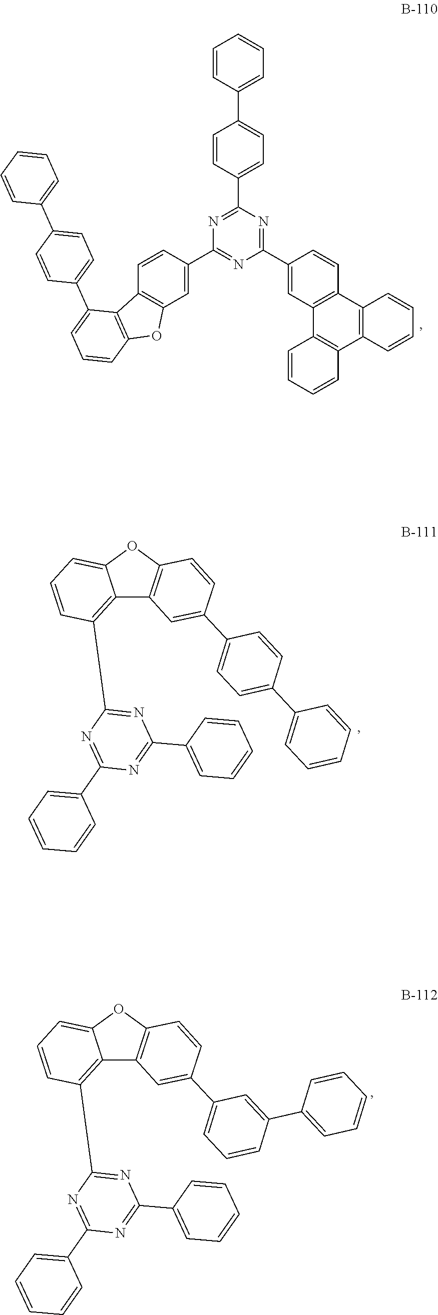 [SMILES: c1ccc(-c2ccc(-c3nc(-c4ccc5c(c4)oc4cccc(-c6ccc(-c7ccccc7)cc6)c45)nc(-c4ccc5c6ccccc6c6ccccc6c5c4)n3)cc2)cc1 ; c1ccc(-c2ccc(-c3ccc4oc5cccc(-c6nc(-c7ccccc7)nc(-c7ccccc7)n6)c5c4c3)cc2)cc1 ; c1ccc(-c2cccc(-c3ccc4oc5cccc(-c6nc(-c7ccccc7)nc(-c7ccccc7)n6)c5c4c3)c2)cc1]

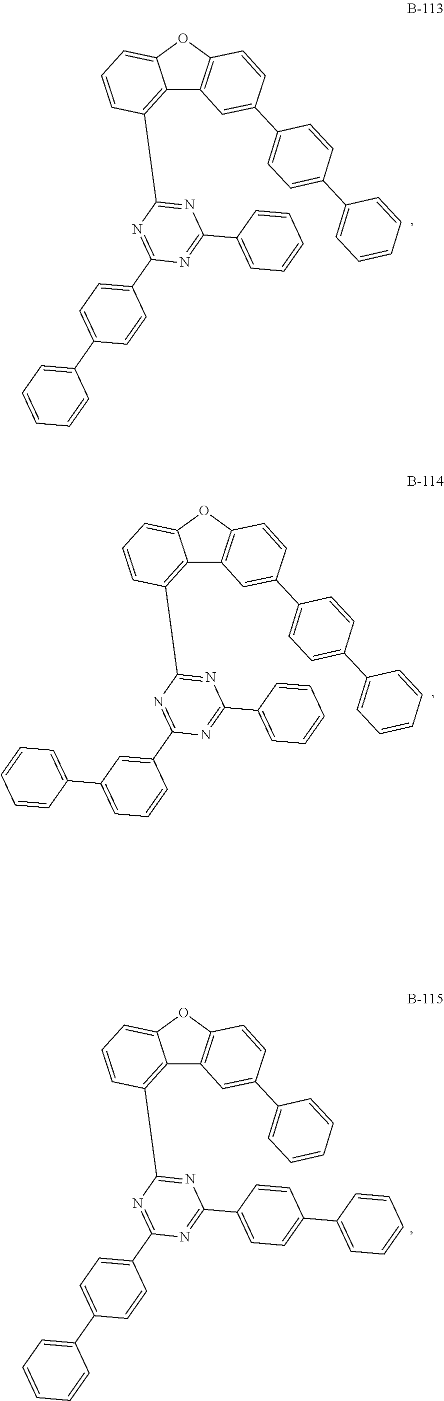 [SMILES: c1ccc(-c2ccc(-c3ccc4oc5cccc(-c6nc(-c7ccccc7)nc(-c7ccc(-c8ccccc8)cc7)n6)c5c4c3)cc2)cc1 ; c1ccc(-c2ccc(-c3ccc4oc5cccc(-c6nc(-c7ccccc7)nc(-c7cccc(-c8ccccc8)c7)n6)c5c4c3)cc2)cc1 ; c1ccc(-c2ccc(-c3nc(-c4ccc(-c5ccccc5)cc4)nc(-c4cccc5oc6ccc(-c7ccccc7)cc6c45)n3)cc2)cc1]

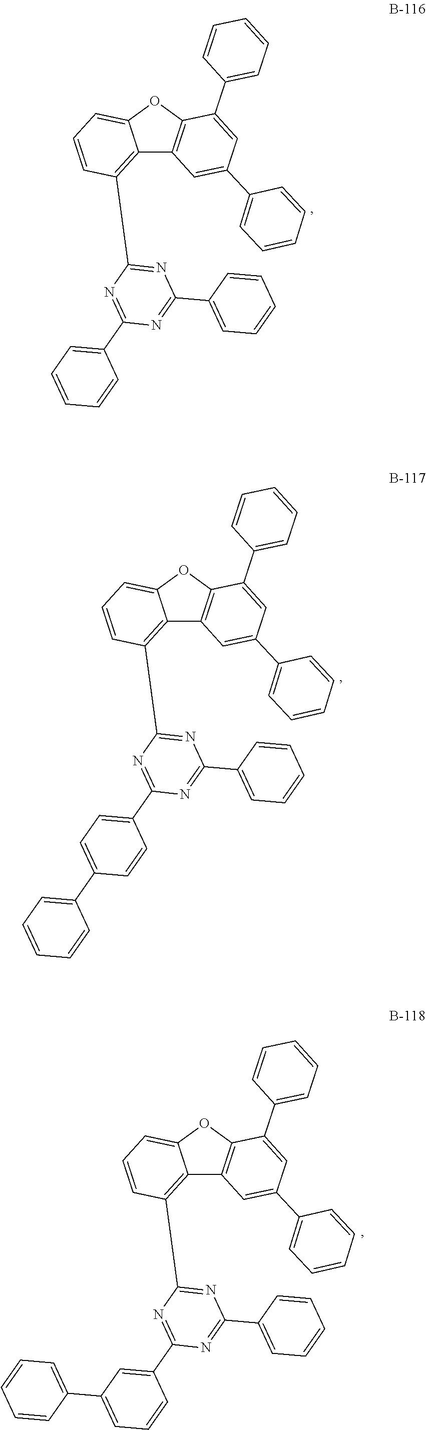 [SMILES: c1ccc(-c2cc(-c3ccccc3)c3oc4cccc(-c5nc(-c6ccccc6)nc(-c6ccccc6)n5)c4c3c2)cc1 ; c1ccc(-c2ccc(-c3nc(-c4ccccc4)nc(-c4cccc5oc6c(-c7ccccc7)cc(-c7ccccc7)cc6c45)n3)cc2)cc1 ; c1ccc(-c2cccc(-c3nc(-c4ccccc4)nc(-c4cccc5oc6c(-c7ccccc7)cc(-c7ccccc7)cc6c45)n3)c2)cc1]

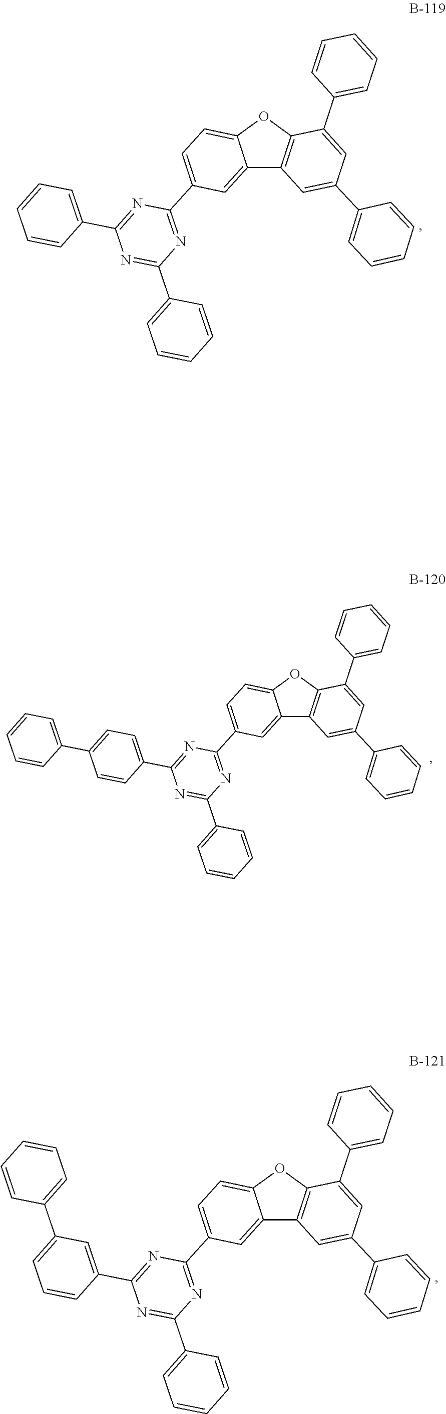 [SMILES: c1ccc(-c2cc(-c3ccccc3)c3oc4ccc(-c5nc(-c6ccccc6)nc(-c6ccccc6)n5)cc4c3c2)cc1 ; c1ccc(-c2ccc(-c3nc(-c4ccccc4)nc(-c4ccc5oc6c(-c7ccccc7)cc(-c7ccccc7)cc6c5c4)n3)cc2)cc1 ; c1ccc(-c2cccc(-c3nc(-c4ccccc4)nc(-c4ccc5oc6c(-c7ccccc7)cc(-c7ccccc7)cc6c5c4)n3)c2)cc1]

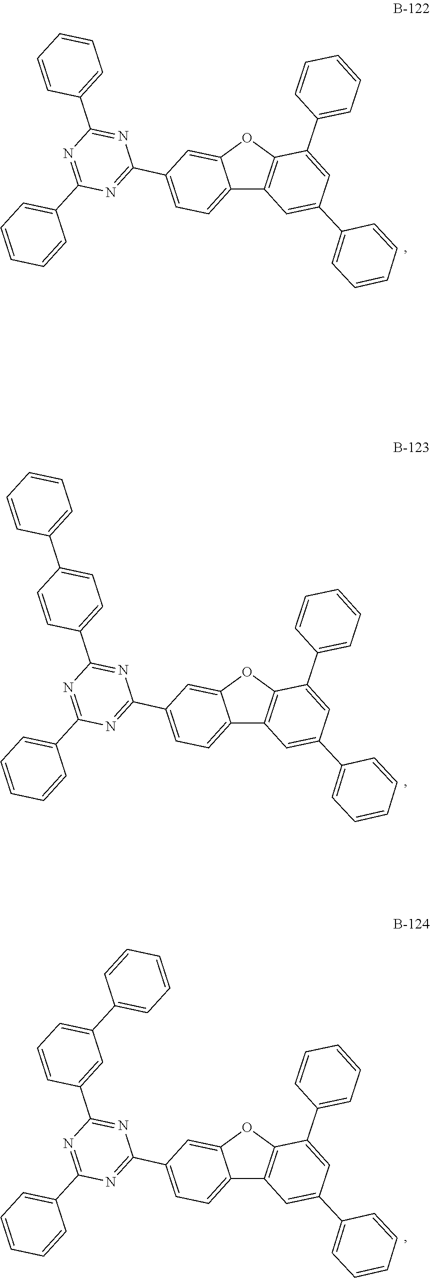 [SMILES: c1ccc(-c2cc(-c3ccccc3)c3oc4cc(-c5nc(-c6ccccc6)nc(-c6ccccc6)n5)ccc4c3c2)cc1 ; c1ccc(-c2ccc(-c3nc(-c4ccccc4)nc(-c4ccc5c(c4)oc4c(-c6ccccc6)cc(-c6ccccc6)cc45)n3)cc2)cc1 ; c1ccc(-c2cccc(-c3nc(-c4ccccc4)nc(-c4ccc5c(c4)oc4c(-c6ccccc6)cc(-c6ccccc6)cc45)n3)c2)cc1]

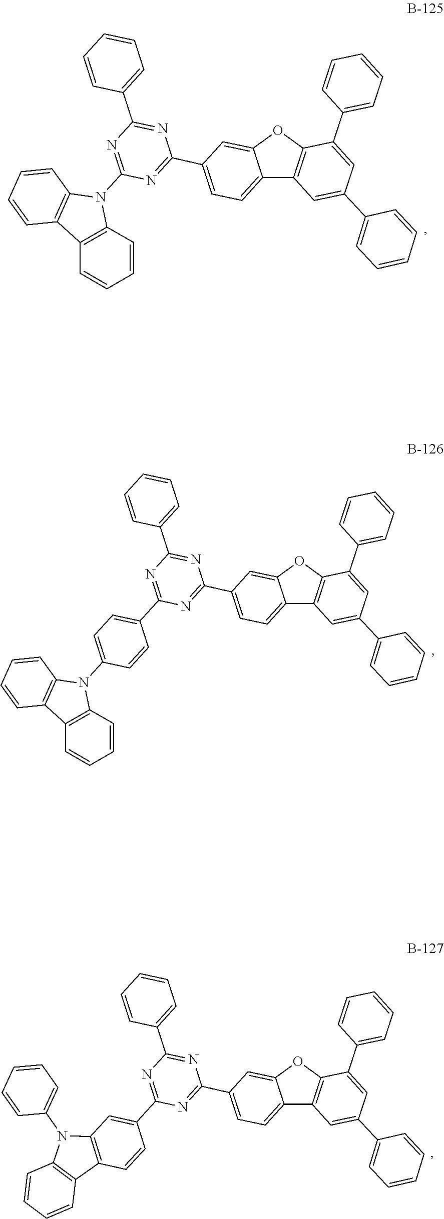 [SMILES: c1ccc(-c2cc(-c3ccccc3)c3oc4cc(-c5nc(-c6ccccc6)nc(-n6c7ccccc7c7ccccc76)n5)ccc4c3c2)cc1 ; c1ccc(-c2cc(-c3ccccc3)c3oc4cc(-c5nc(-c6ccccc6)nc(-c6ccc(-n7c8ccccc8c8ccccc87)cc6)n5)ccc4c3c2)cc1 ; c1ccc(-c2cc(-c3ccccc3)c3oc4cc(-c5nc(-c6ccccc6)nc(-c6ccc7c8ccccc8n(-c8ccccc8)c7c6)n5)ccc4c3c2)cc1]

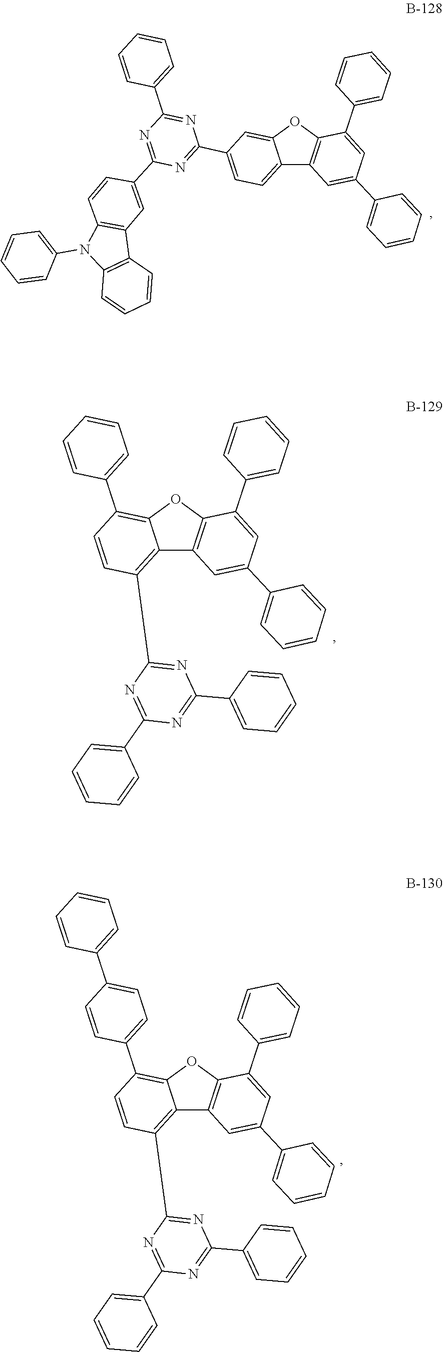 [SMILES: c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1 ; c1ccc(-c2cc(-c3ccccc3)c3oc4c(-c5ccccc5)ccc(-c5nc(-c6ccccc6)nc(-c6ccccc6)n5)c4c3c2)cc1 ; c1ccc(-c2ccc(-c3ccc(-c4nc(-c5ccccc5)nc(-c5ccccc5)n4)c4c3oc3c(-c5ccccc5)cc(-c5ccccc5)cc34)cc2)cc1]

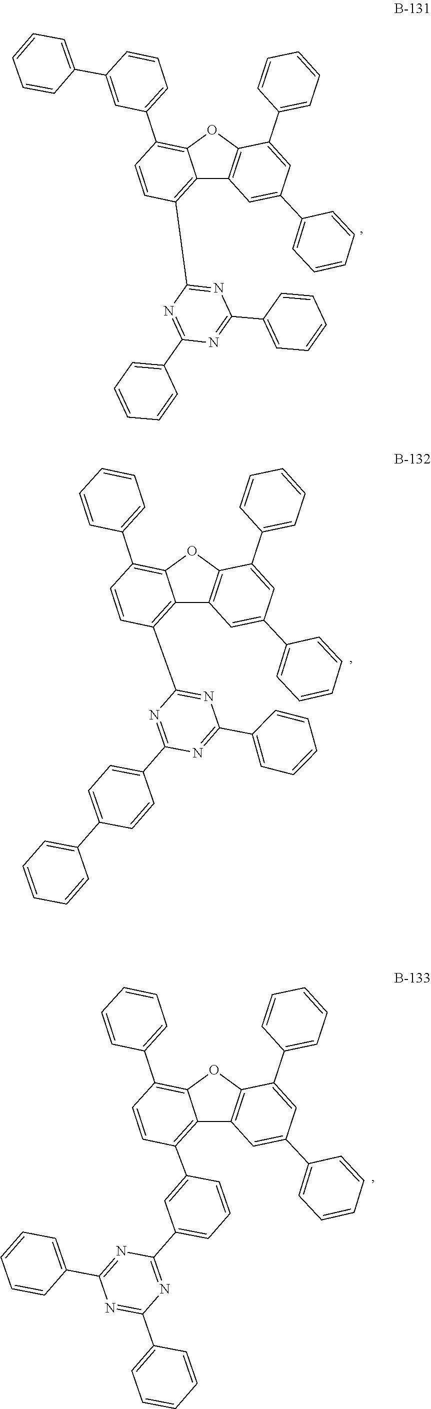 [SMILES: c1ccc(-c2cccc(-c3ccc(-c4nc(-c5ccccc5)nc(-c5ccccc5)n4)c4c3oc3c(-c5ccccc5)cc(-c5ccccc5)cc34)c2)cc1 ; c1ccc(-c2ccc(-c3nc(-c4ccccc4)nc(-c4ccc(-c5ccccc5)c5oc6c(-c7ccccc7)cc(-c7ccccc7)cc6c45)n3)cc2)cc1 ; c1ccc(-c2cc(-c3ccccc3)c3oc4c(-c5ccccc5)ccc(-c5cccc(-c6nc(-c7ccccc7)nc(-c7ccccc7)n6)c5)c4c3c2)cc1]

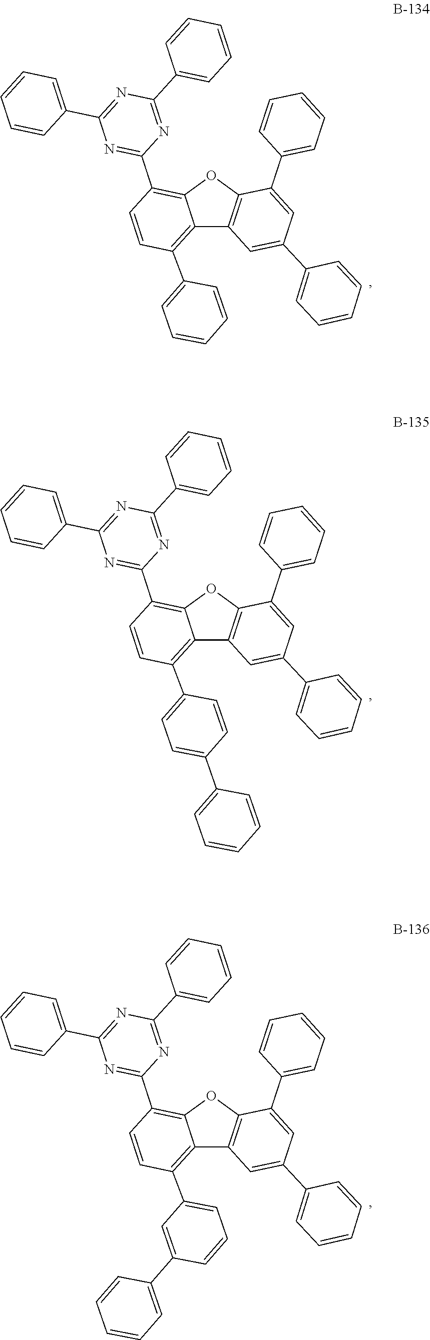 [SMILES: c1ccc(-c2cc(-c3ccccc3)c3oc4c(-c5nc(-c6ccccc6)nc(-c6ccccc6)n5)ccc(-c5ccccc5)c4c3c2)cc1 ; c1ccc(-c2ccc(-c3ccc(-c4nc(-c5ccccc5)nc(-c5ccccc5)n4)c4oc5c(-c6ccccc6)cc(-c6ccccc6)cc5c34)cc2)cc1 ; c1ccc(-c2cccc(-c3ccc(-c4nc(-c5ccccc5)nc(-c5ccccc5)n4)c4oc5c(-c6ccccc6)cc(-c6ccccc6)cc5c34)c2)cc1]

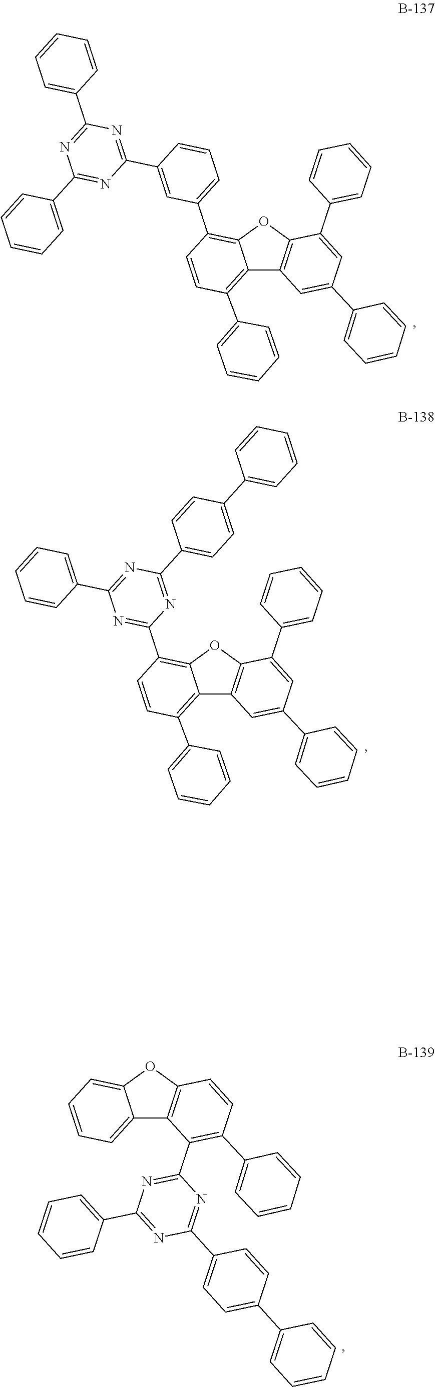 [SMILES: c1ccc(-c2cc(-c3ccccc3)c3oc4c(-c5cccc(-c6nc(-c7ccccc7)nc(-c7ccccc7)n6)c5)ccc(-c5ccccc5)c4c3c2)cc1 ; c1ccc(-c2ccc(-c3nc(-c4ccccc4)nc(-c4ccc(-c5ccccc5)c5c4oc4c(-c6ccccc6)cc(-c6ccccc6)cc45)n3)cc2)cc1 ; c1ccc(-c2ccc(-c3nc(-c4ccccc4)nc(-c4c(-c5ccccc5)ccc5oc6ccccc6c45)n3)cc2)cc1]

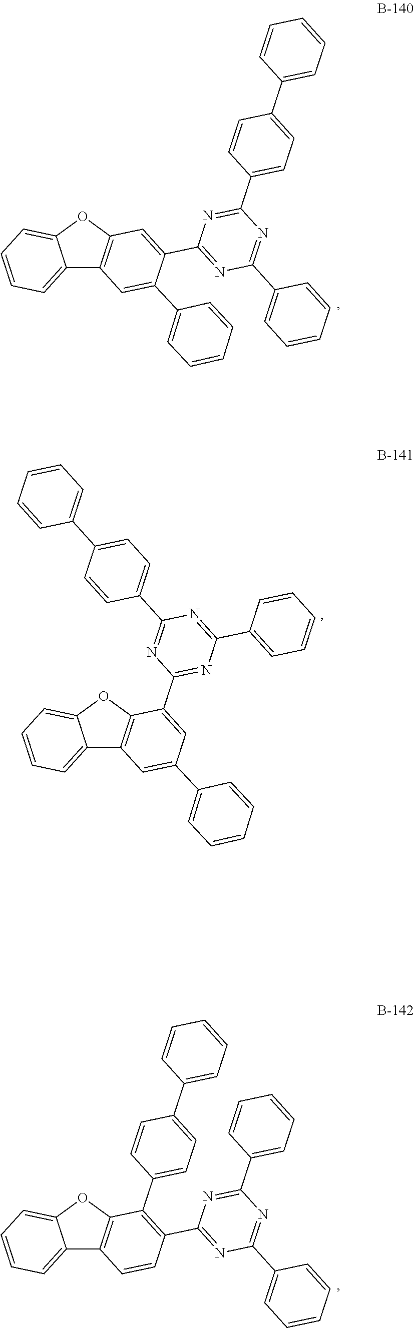 [SMILES: c1ccc(-c2ccc(-c3nc(-c4ccccc4)nc(-c4cc5oc6ccccc6c5cc4-c4ccccc4)n3)cc2)cc1 ; c1ccc(-c2ccc(-c3nc(-c4ccccc4)nc(-c4cc(-c5ccccc5)cc5c4oc4ccccc45)n3)cc2)cc1 ; c1ccc(-c2ccc(-c3c(-c4nc(-c5ccccc5)nc(-c5ccccc5)n4)ccc4c3oc3ccccc34)cc2)cc1]

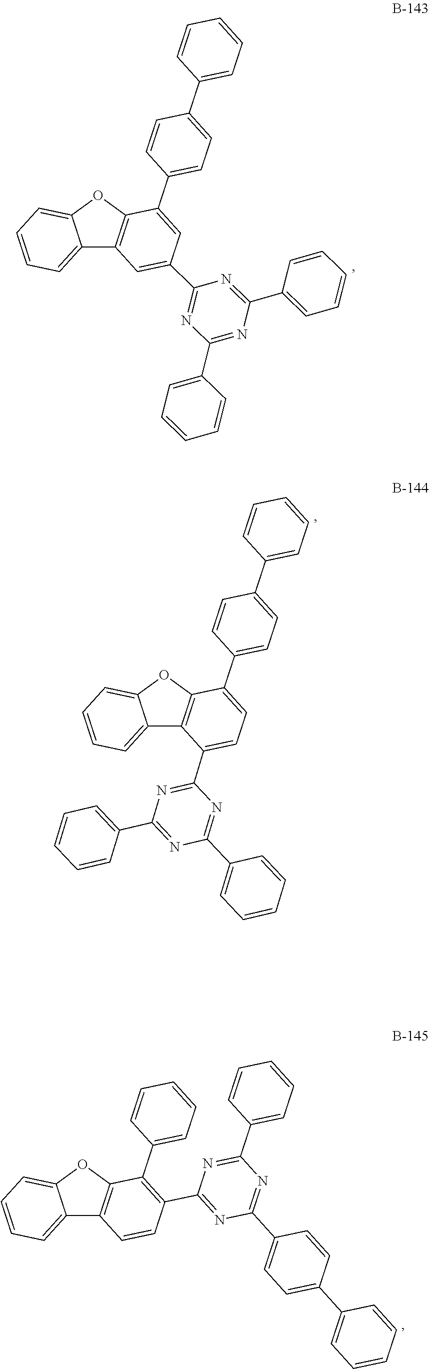 [SMILES: c1ccc(-c2ccc(-c3cc(-c4nc(-c5ccccc5)nc(-c5ccccc5)n4)cc4c3oc3ccccc34)cc2)cc1 ; c1ccc(-c2ccc(-c3ccc(-c4nc(-c5ccccc5)nc(-c5ccccc5)n4)c4c3oc3ccccc34)cc2)cc1 ; c1ccc(-c2ccc(-c3nc(-c4ccccc4)nc(-c4ccc5c(oc6ccccc65)c4-c4ccccc4)n3)cc2)cc1]

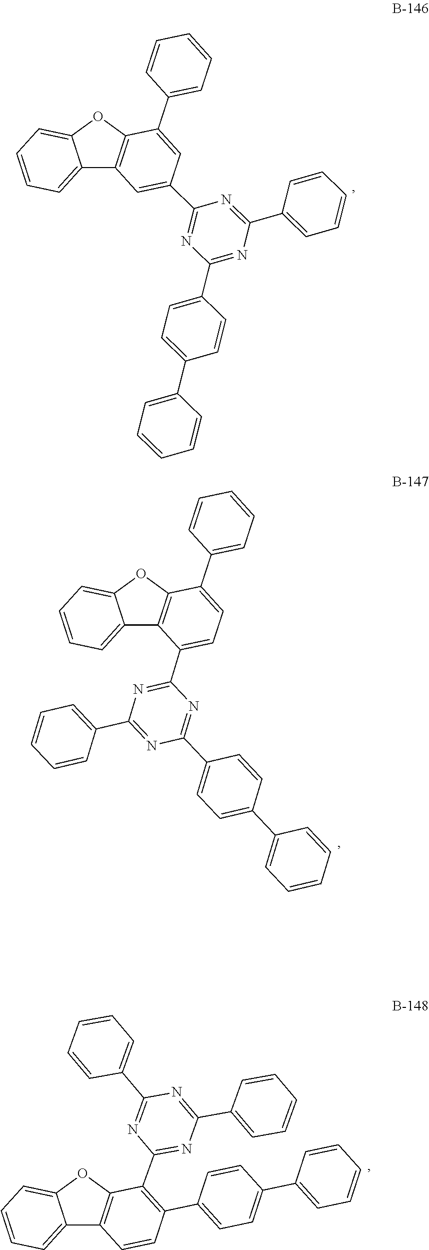 [SMILES: c1ccc(-c2ccc(-c3nc(-c4ccccc4)nc(-c4cc(-c5ccccc5)c5oc6ccccc6c5c4)n3)cc2)cc1 ; c1ccc(-c2ccc(-c3nc(-c4ccccc4)nc(-c4ccc(-c5ccccc5)c5oc6ccccc6c45)n3)cc2)cc1 ; c1ccc(-c2ccc(-c3ccc4c(oc5ccccc54)c3-c3nc(-c4ccccc4)nc(-c4ccccc4)n3)cc2)cc1]

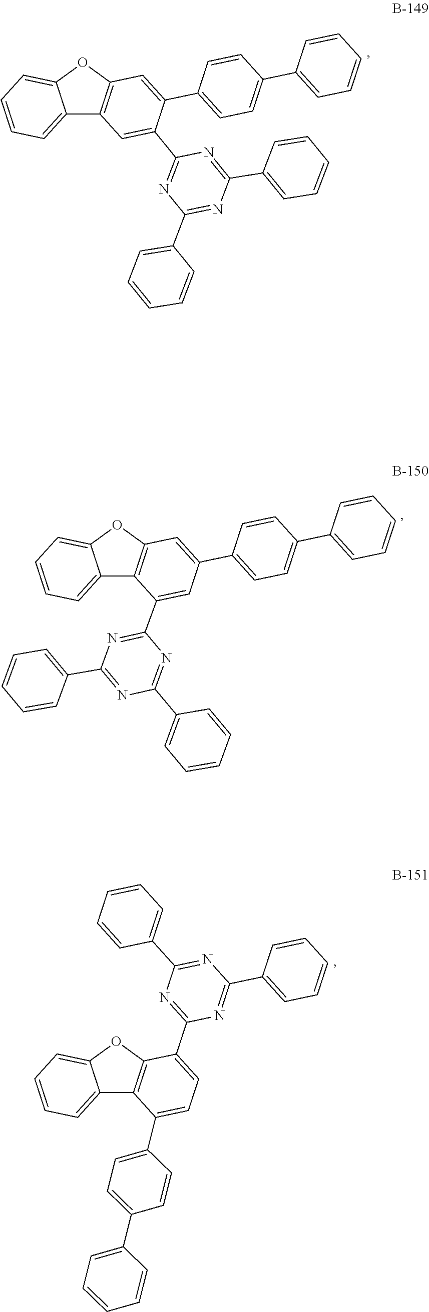 [SMILES: c1ccc(-c2ccc(-c3cc4oc5ccccc5c4cc3-c3nc(-c4ccccc4)nc(-c4ccccc4)n3)cc2)cc1 ; c1ccc(-c2ccc(-c3cc(-c4nc(-c5ccccc5)nc(-c5ccccc5)n4)c4c(c3)oc3ccccc34)cc2)cc1 ; c1ccc(-c2ccc(-c3ccc(-c4nc(-c5ccccc5)nc(-c5ccccc5)n4)c4oc5ccccc5c34)cc2)cc1]

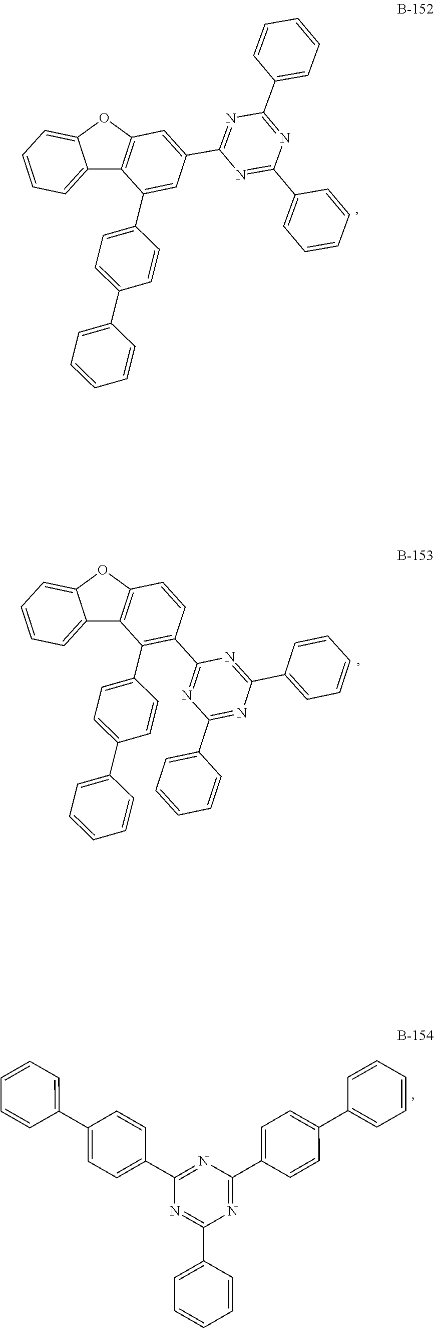 [SMILES: c1ccc(-c2ccc(-c3cc(-c4nc(-c5ccccc5)nc(-c5ccccc5)n4)cc4oc5ccccc5c34)cc2)cc1 ; c1ccc(-c2ccc(-c3c(-c4nc(-c5ccccc5)nc(-c5ccccc5)n4)ccc4oc5ccccc5c34)cc2)cc1 ; c1ccc(-c2ccc(-c3nc(-c4ccccc4)nc(-c4ccc(-c5ccccc5)cc4)n3)cc2)cc1]

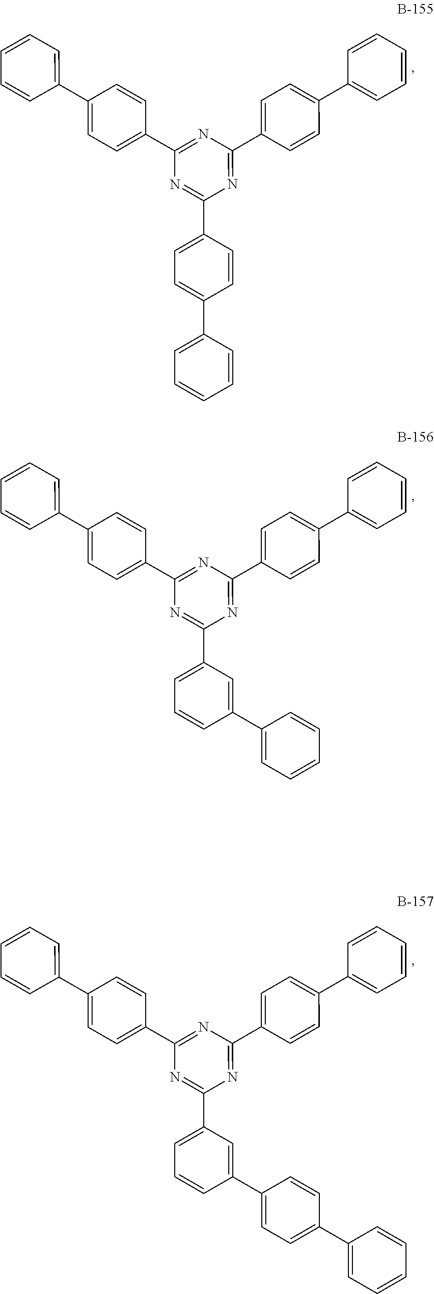 [SMILES: c1ccc(-c2ccc(-c3nc(-c4ccc(-c5ccccc5)cc4)nc(-c4ccc(-c5ccccc5)cc4)n3)cc2)cc1 ; c1ccc(-c2ccc(-c3nc(-c4ccc(-c5ccccc5)cc4)nc(-c4cccc(-c5ccccc5)c4)n3)cc2)cc1 ; c1ccc(-c2ccc(-c3cccc(-c4nc(-c5ccc(-c6ccccc6)cc5)nc(-c5ccc(-c6ccccc6)cc5)n4)c3)cc2)cc1]

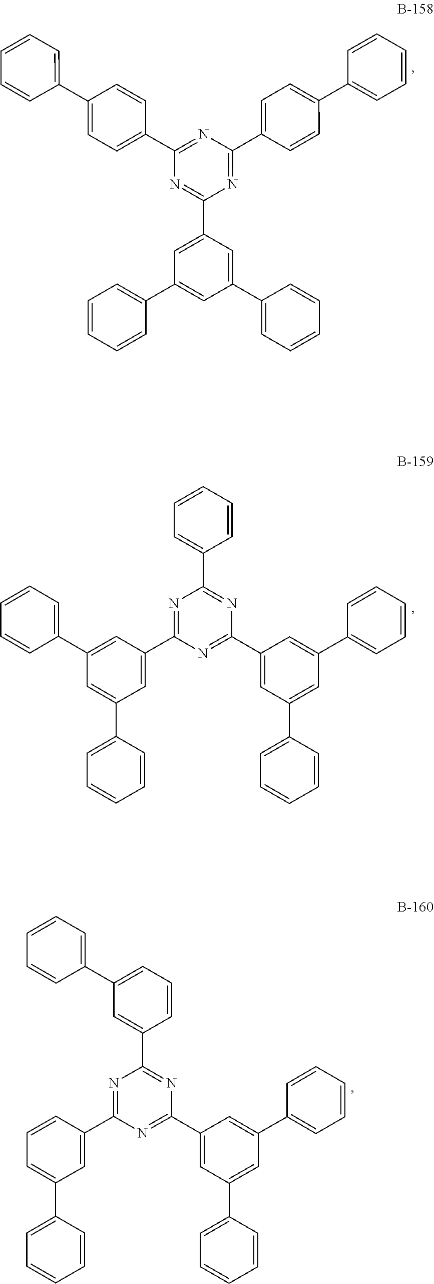 [SMILES: c1ccc(-c2ccc(-c3nc(-c4ccc(-c5ccccc5)cc4)nc(-c4cc(-c5ccccc5)cc(-c5ccccc5)c4)n3)cc2)cc1 ; c1ccc(-c2cc(-c3ccccc3)cc(-c3nc(-c4ccccc4)nc(-c4cc(-c5ccccc5)cc(-c5ccccc5)c4)n3)c2)cc1 ; c1ccc(-c2cccc(-c3nc(-c4cccc(-c5ccccc5)c4)nc(-c4cc(-c5ccccc5)cc(-c5ccccc5)c4)n3)c2)cc1]

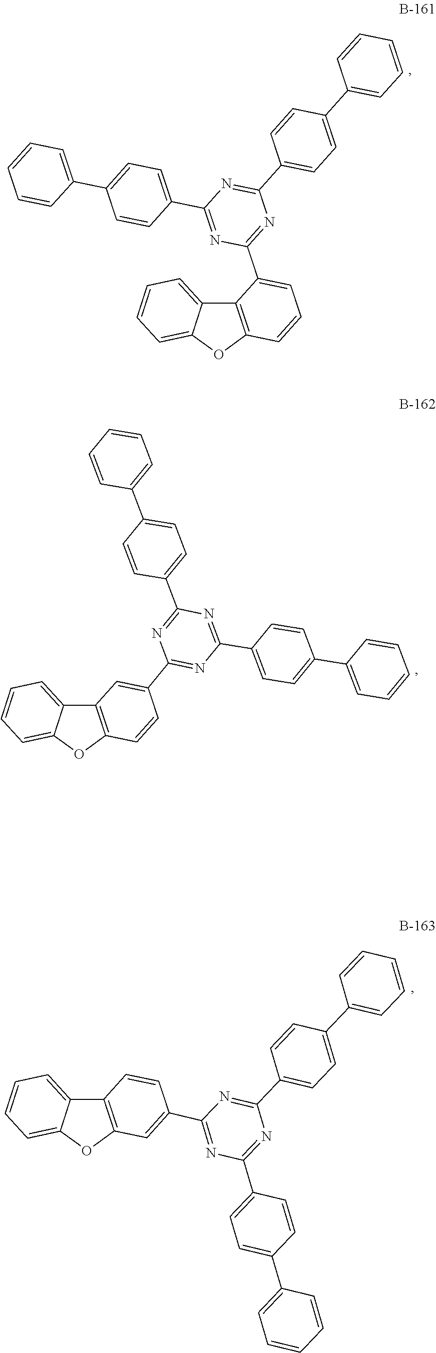 [SMILES: c1ccc(-c2ccc(-c3nc(-c4ccc(-c5ccccc5)cc4)nc(-c4cccc5oc6ccccc6c45)n3)cc2)cc1 ; c1ccc(-c2ccc(-c3nc(-c4ccc(-c5ccccc5)cc4)nc(-c4ccc5oc6ccccc6c5c4)n3)cc2)cc1 ; c1ccc(-c2ccc(-c3nc(-c4ccc(-c5ccccc5)cc4)nc(-c4ccc5c(c4)oc4ccccc45)n3)cc2)cc1]

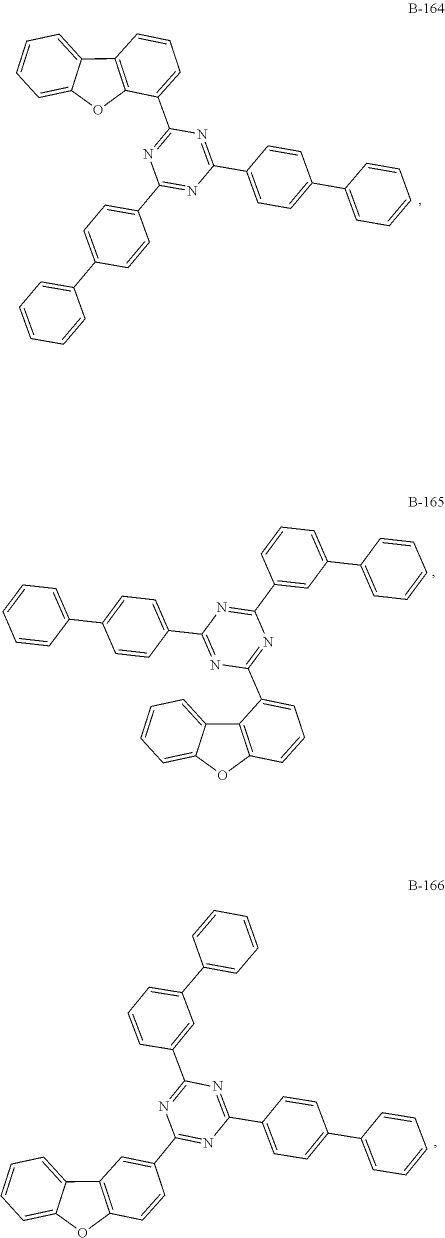 [SMILES: c1ccc(-c2ccc(-c3nc(-c4ccc(-c5ccccc5)cc4)nc(-c4cccc5c4oc4ccccc45)n3)cc2)cc1 ; c1ccc(-c2ccc(-c3nc(-c4cccc(-c5ccccc5)c4)nc(-c4cccc5oc6ccccc6c45)n3)cc2)cc1 ; c1ccc(-c2ccc(-c3nc(-c4cccc(-c5ccccc5)c4)nc(-c4ccc5oc6ccccc6c5c4)n3)cc2)cc1]

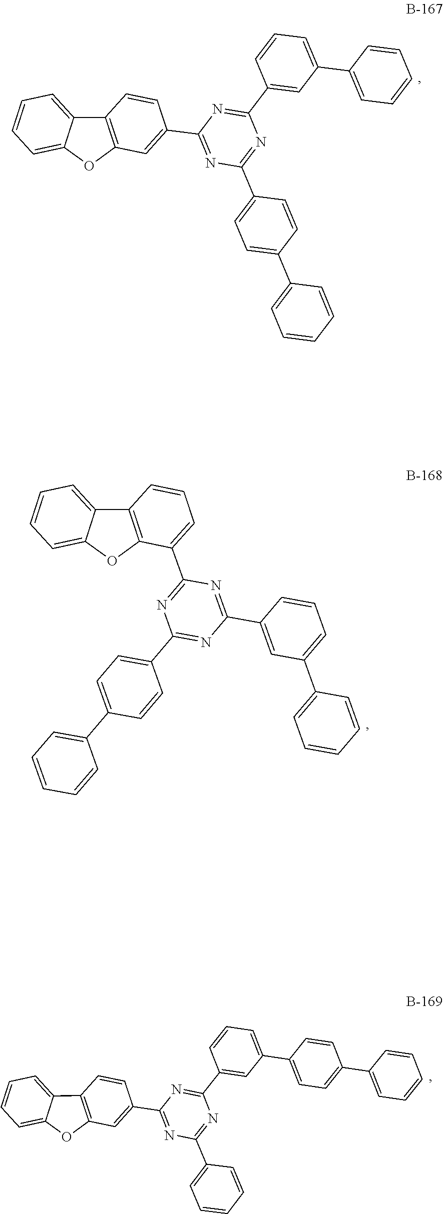 [SMILES: c1ccc(-c2ccc(-c3nc(-c4cccc(-c5ccccc5)c4)nc(-c4ccc5c(c4)oc4ccccc45)n3)cc2)cc1 ; c1ccc(-c2ccc(-c3nc(-c4cccc(-c5ccccc5)c4)nc(-c4cccc5c4oc4ccccc45)n3)cc2)cc1 ; c1ccc(-c2ccc(-c3cccc(-c4nc(-c5ccccc5)nc(-c5ccc6c(c5)oc5ccccc56)n4)c3)cc2)cc1]

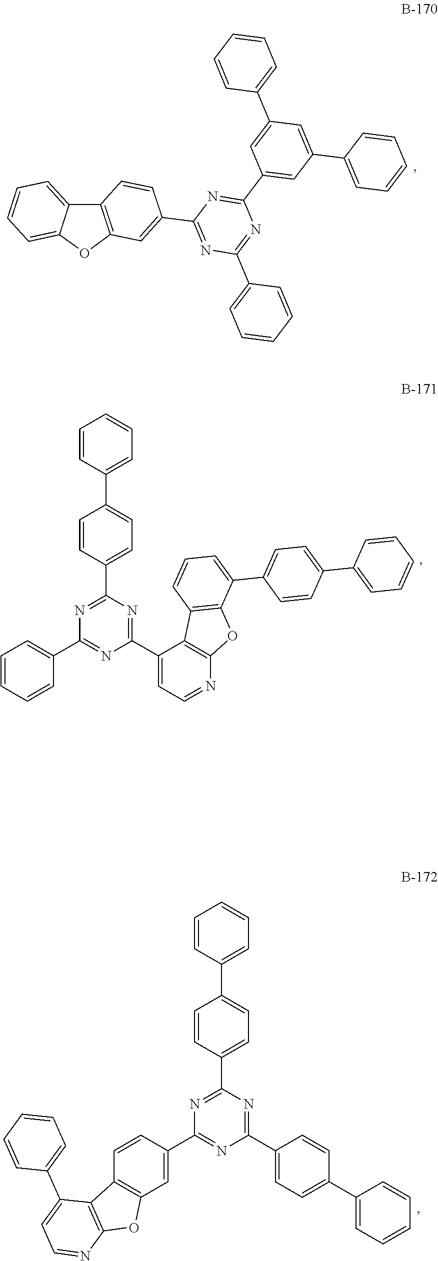 [SMILES: c1ccc(-c2cc(-c3ccccc3)cc(-c3nc(-c4ccccc4)nc(-c4ccc5c(c4)oc4ccccc45)n3)c2)cc1 ; c1ccc(-c2ccc(-c3nc(-c4ccccc4)nc(-c4ccnc5oc6c(-c7ccc(-c8ccccc8)cc7)cccc6c45)n3)cc2)cc1 ; c1ccc(-c2ccc(-c3nc(-c4ccc(-c5ccccc5)cc4)nc(-c4ccc5c(c4)oc4nccc(-c6ccccc6)c45)n3)cc2)cc1]

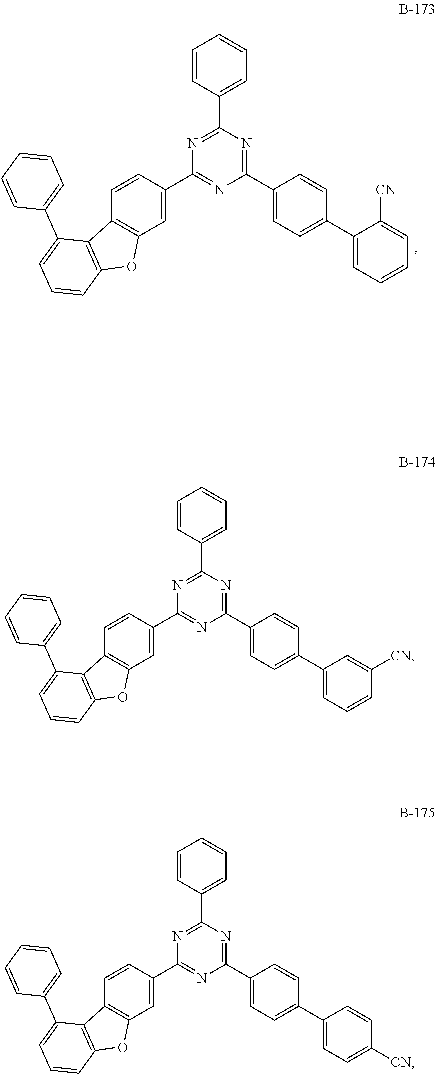 [SMILES: N#Cc1ccccc1-c1ccc(-c2nc(-c3ccccc3)nc(-c3ccc4c(c3)oc3cccc(-c5ccccc5)c34)n2)cc1 ; N#Cc1cccc(-c2ccc(-c3nc(-c4ccccc4)nc(-c4ccc5c(c4)oc4cccc(-c6ccccc6)c45)n3)cc2)c1 ; N#Cc1ccc(-c2ccc(-c3nc(-c4ccccc4)nc(-c4ccc5c(c4)oc4cccc(-c6ccccc6)c45)n3)cc2)cc1]

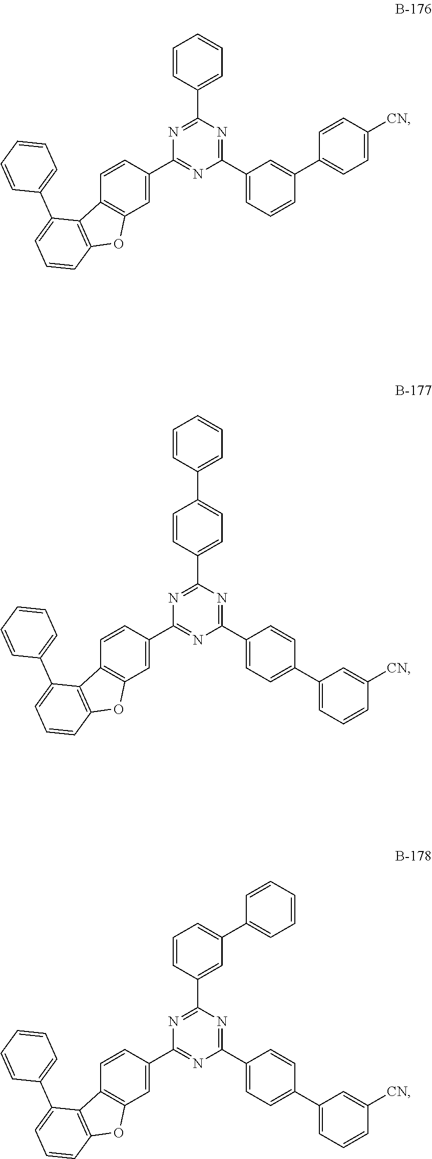 [SMILES: N#Cc1ccc(-c2cccc(-c3nc(-c4ccccc4)nc(-c4ccc5c(c4)oc4cccc(-c6ccccc6)c45)n3)c2)cc1 ; N#Cc1cccc(-c2ccc(-c3nc(-c4ccc(-c5ccccc5)cc4)nc(-c4ccc5c(c4)oc4cccc(-c6ccccc6)c45)n3)cc2)c1 ; N#Cc1cccc(-c2ccc(-c3nc(-c4cccc(-c5ccccc5)c4)nc(-c4ccc5c(c4)oc4cccc(-c6ccccc6)c45)n3)cc2)c1]

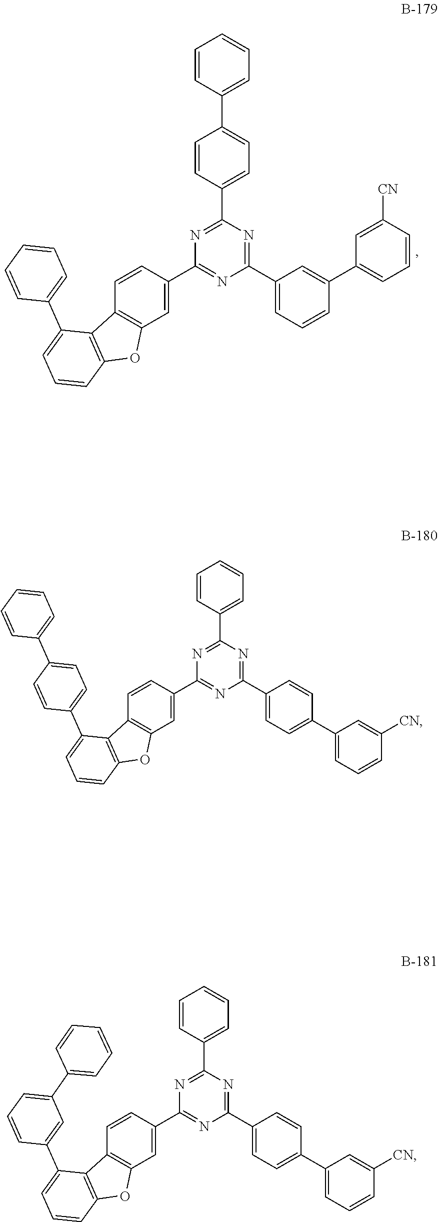 [SMILES: N#Cc1cccc(-c2cccc(-c3nc(-c4ccc(-c5ccccc5)cc4)nc(-c4ccc5c(c4)oc4cccc(-c6ccccc6)c45)n3)c2)c1 ; N#Cc1cccc(-c2ccc(-c3nc(-c4ccccc4)nc(-c4ccc5c(c4)oc4cccc(-c6ccc(-c7ccccc7)cc6)c45)n3)cc2)c1 ; N#Cc1cccc(-c2ccc(-c3nc(-c4ccccc4)nc(-c4ccc5c(c4)oc4cccc(-c6cccc(-c7ccccc7)c6)c45)n3)cc2)c1]

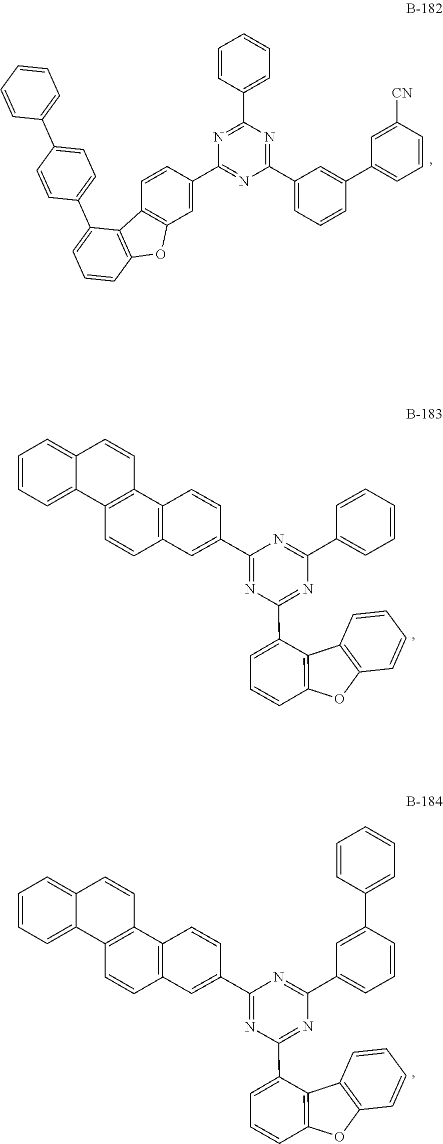 [SMILES: N#Cc1cccc(-c2cccc(-c3nc(-c4ccccc4)nc(-c4ccc5c(c4)oc4cccc(-c6ccc(-c7ccccc7)cc6)c45)n3)c2)c1 ; c1ccc(-c2nc(-c3ccc4c(ccc5c6ccccc6ccc45)c3)nc(-c3cccc4oc5ccccc5c34)n2)cc1 ; c1ccc(-c2cccc(-c3nc(-c4ccc5c(ccc6c7ccccc7ccc56)c4)nc(-c4cccc5oc6ccccc6c45)n3)c2)cc1]

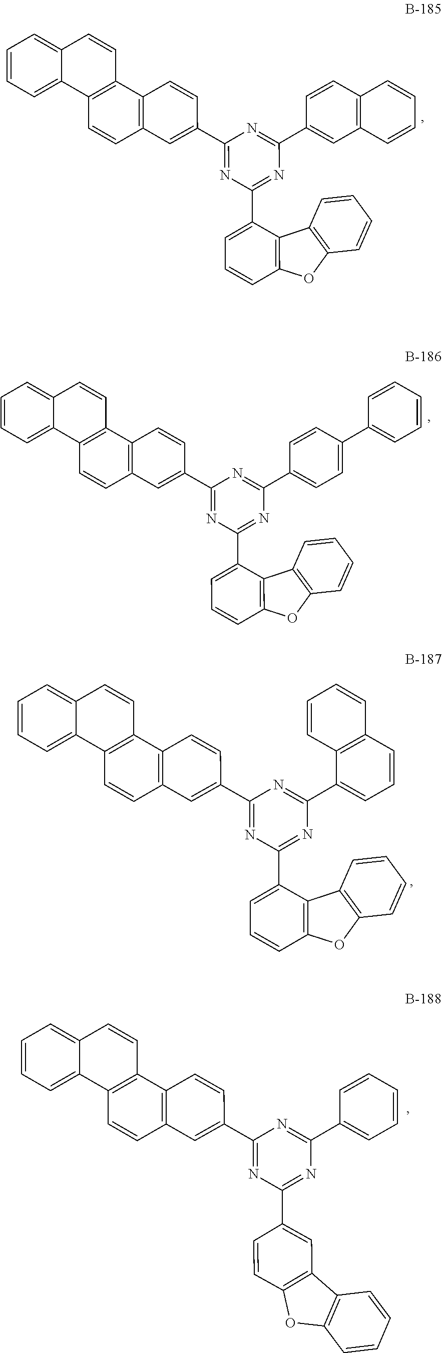 [SMILES: c1ccc2cc(-c3nc(-c4ccc5c(ccc6c7ccccc7ccc56)c4)nc(-c4cccc5oc6ccccc6c45)n3)ccc2c1 ; c1ccc(-c2ccc(-c3nc(-c4ccc5c(ccc6c7ccccc7ccc56)c4)nc(-c4cccc5oc6ccccc6c45)n3)cc2)cc1 ; c1ccc2c(-c3nc(-c4ccc5c(ccc6c7ccccc7ccc56)c4)nc(-c4cccc5oc6ccccc6c45)n3)cccc2c1 ; c1ccc(-c2nc(-c3ccc4c(ccc5c6ccccc6ccc45)c3)nc(-c3ccc4oc5ccccc5c4c3)n2)cc1]

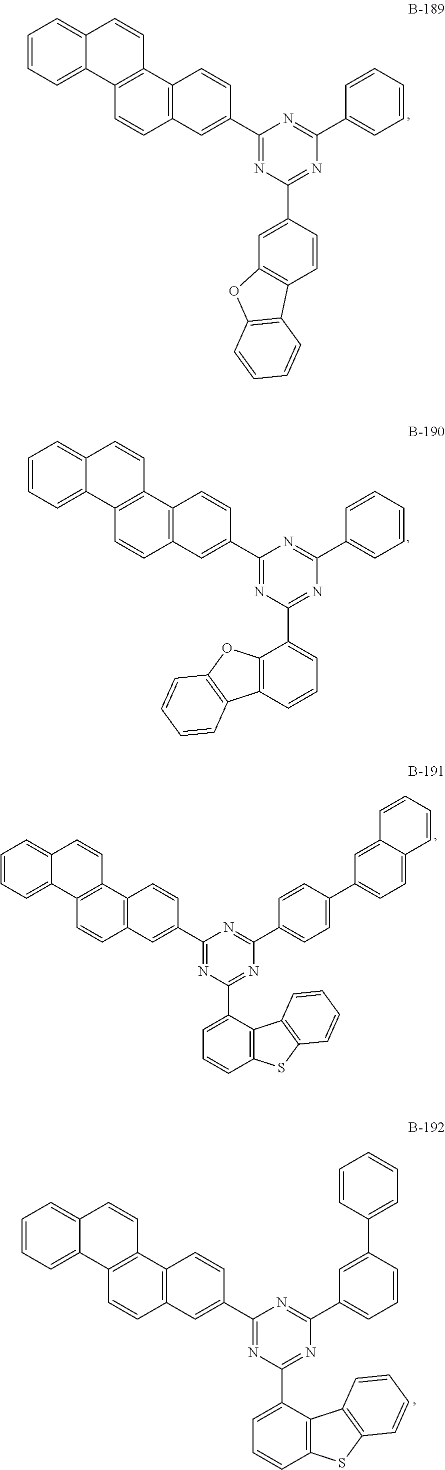 [SMILES: c1ccc(-c2nc(-c3ccc4c(ccc5c6ccccc6ccc45)c3)nc(-c3ccc4c(c3)oc3ccccc34)n2)cc1 ; c1ccc(-c2nc(-c3ccc4c(ccc5c6ccccc6ccc45)c3)nc(-c3cccc4c3oc3ccccc34)n2)cc1 ; c1ccc2cc(-c3ccc(-c4nc(-c5ccc6c(ccc7c8ccccc8ccc67)c5)nc(-c5cccc6sc7ccccc7c56)n4)cc3)ccc2c1 ; c1ccc(-c2cccc(-c3nc(-c4ccc5c(ccc6c7ccccc7ccc56)c4)nc(-c4cccc5sc6ccccc6c45)n3)c2)cc1]

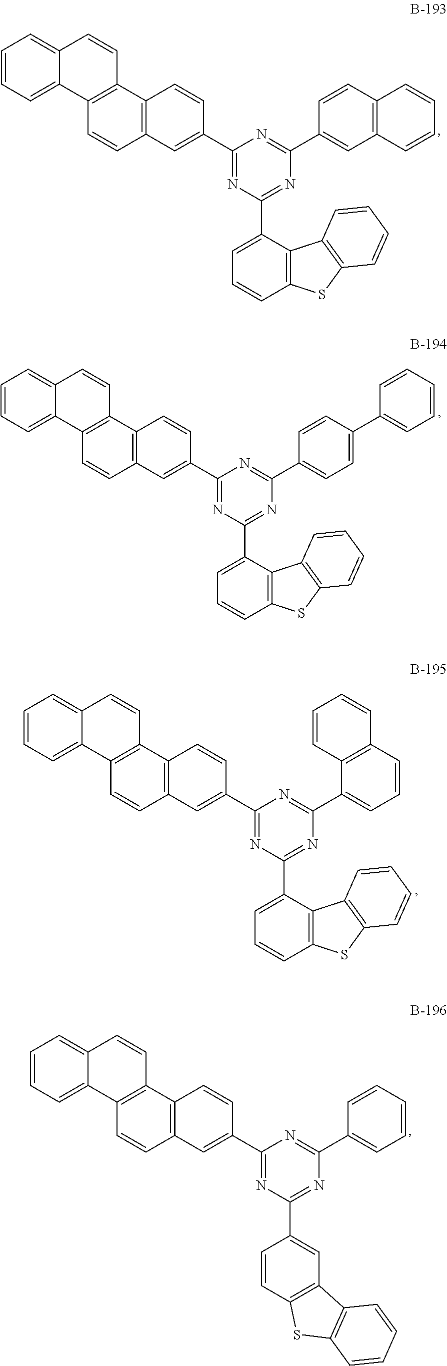 [SMILES: c1ccc2cc(-c3nc(-c4ccc5c(ccc6c7ccccc7ccc56)c4)nc(-c4cccc5sc6ccccc6c45)n3)ccc2c1 ; c1ccc(-c2ccc(-c3nc(-c4ccc5c(ccc6c7ccccc7ccc56)c4)nc(-c4cccc5sc6ccccc6c45)n3)cc2)cc1 ; c1ccc2c(-c3nc(-c4ccc5c(ccc6c7ccccc7ccc56)c4)nc(-c4cccc5sc6ccccc6c45)n3)cccc2c1 ; c1ccc(-c2nc(-c3ccc4c(ccc5c6ccccc6ccc45)c3)nc(-c3ccc4sc5ccccc5c4c3)n2)cc1]

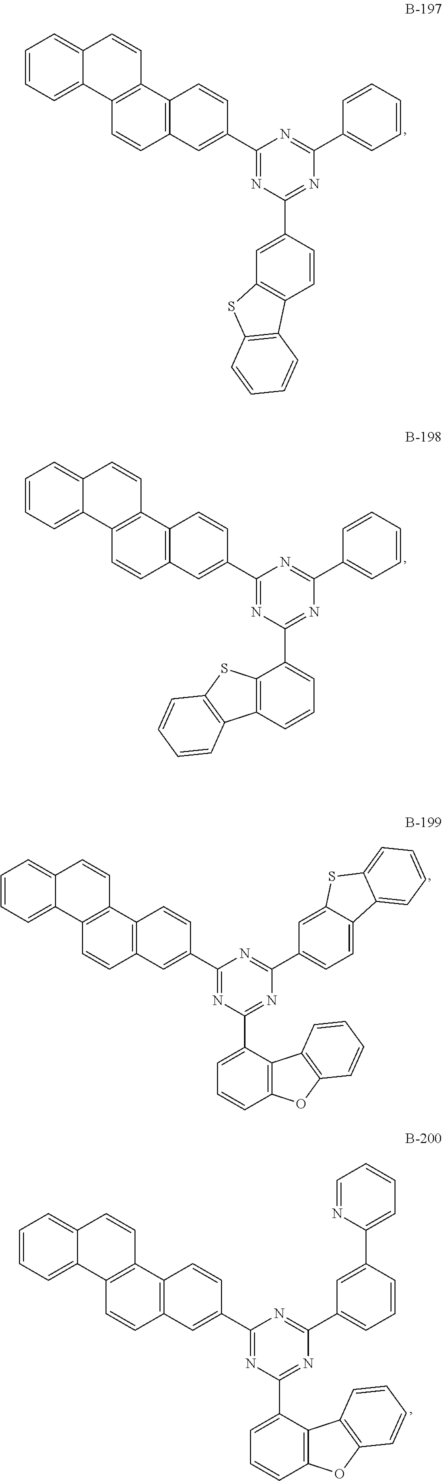 [SMILES: c1ccc(-c2nc(-c3ccc4c(ccc5c6ccccc6ccc45)c3)nc(-c3ccc4c(c3)sc3ccccc34)n2)cc1 ; c1ccc(-c2nc(-c3ccc4c(ccc5c6ccccc6ccc45)c3)nc(-c3cccc4c3sc3ccccc34)n2)cc1 ; c1ccc2c(c1)ccc1c3ccc(-c4nc(-c5ccc6c(c5)sc5ccccc56)nc(-c5cccc6oc7ccccc7c56)n4)cc3ccc21 ; c1ccc(-c2cccc(-c3nc(-c4ccc5c(ccc6c7ccccc7ccc56)c4)nc(-c4cccc5oc6ccccc6c45)n3)c2)nc1]

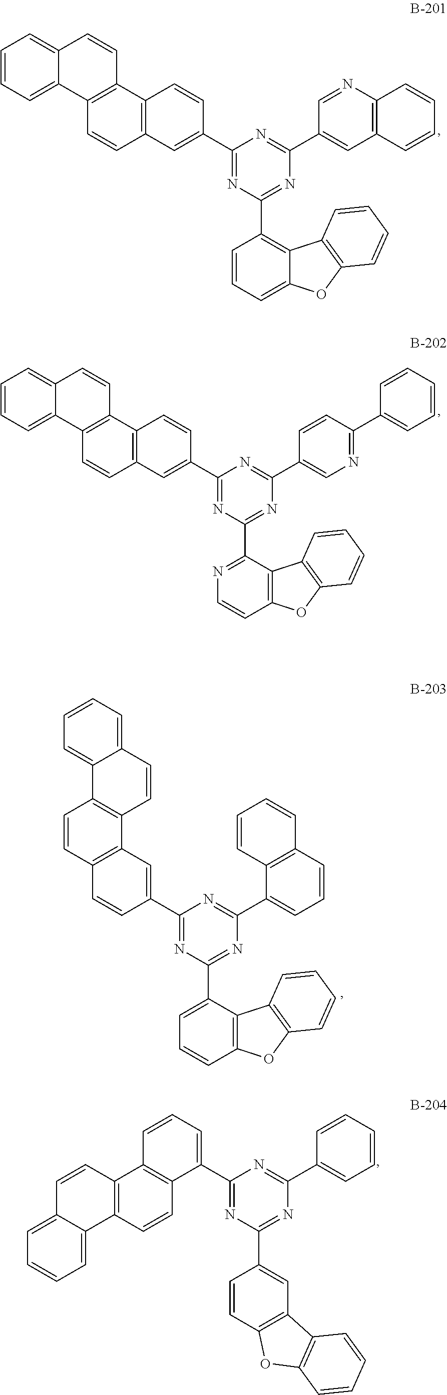 [SMILES: c1ccc2ncc(-c3nc(-c4ccc5c(ccc6c7ccccc7ccc56)c4)nc(-c4cccc5oc6ccccc6c45)n3)cc2c1 ; c1ccc(-c2ccc(-c3nc(-c4ccc5c(ccc6c7ccccc7ccc56)c4)nc(-c4nccc5oc6ccccc6c45)n3)cn2)cc1 ; c1ccc2c(-c3nc(-c4ccc5ccc6c7ccccc7ccc6c5c4)nc(-c4cccc5oc6ccccc6c45)n3)cccc2c1 ; c1ccc(-c2nc(-c3ccc4oc5ccccc5c4c3)nc(-c3cccc4c3ccc3c5ccccc5ccc43)n2)cc1]

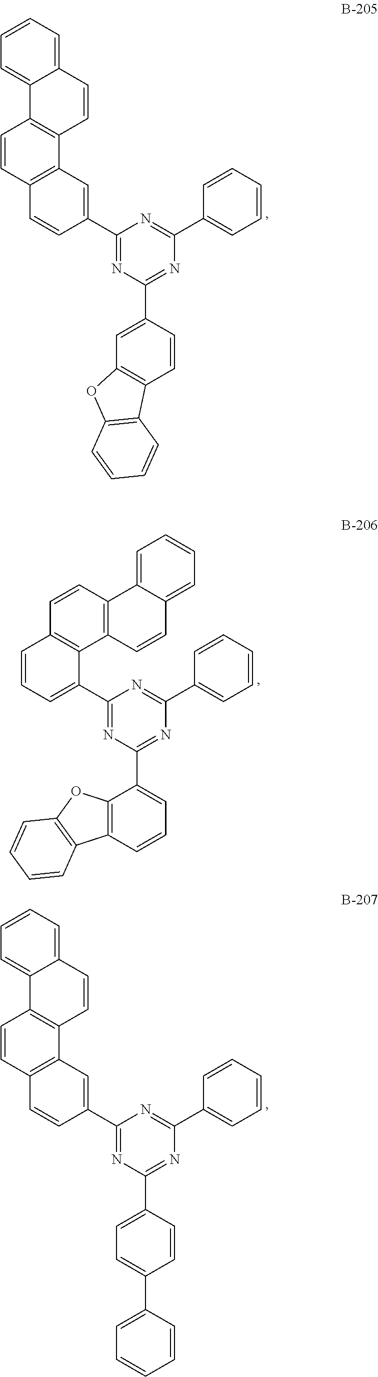

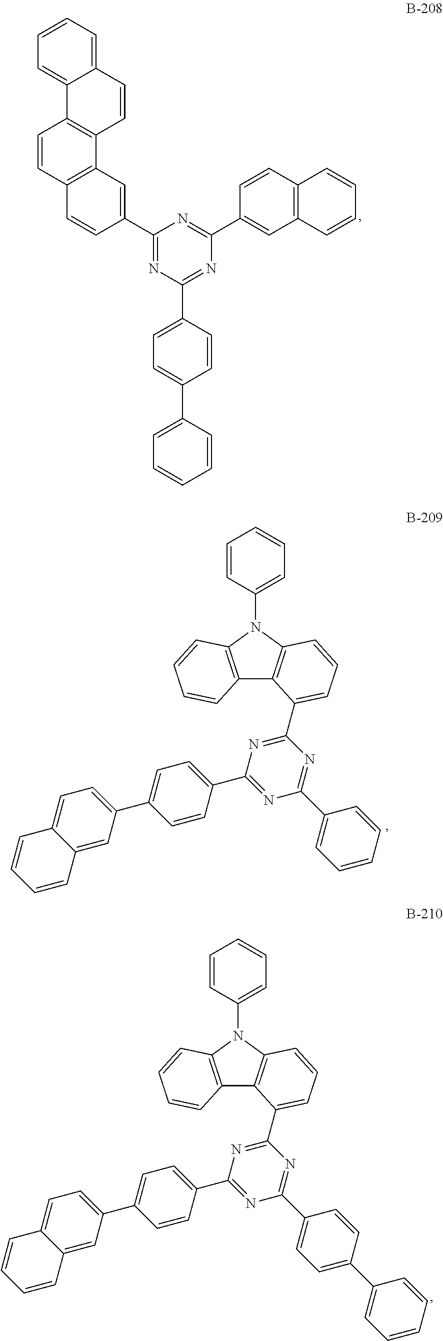 [SMILES: c1ccc(-c2ccc(-c3nc(-c4ccc5ccccc5c4)nc(-c4ccc5ccc6c7ccccc7ccc6c5c4)n3)cc2)cc1 ; c1ccc(-c2nc(-c3ccc(-c4ccc5ccccc5c4)cc3)nc(-c3cccc4c3c3ccccc3n4-c3ccccc3)n2)cc1 ; c1ccc(-c2ccc(-c3nc(-c4ccc(-c5ccc6ccccc6c5)cc4)nc(-c4cccc5c4c4ccccc4n5-c4ccccc4)n3)cc2)cc1]

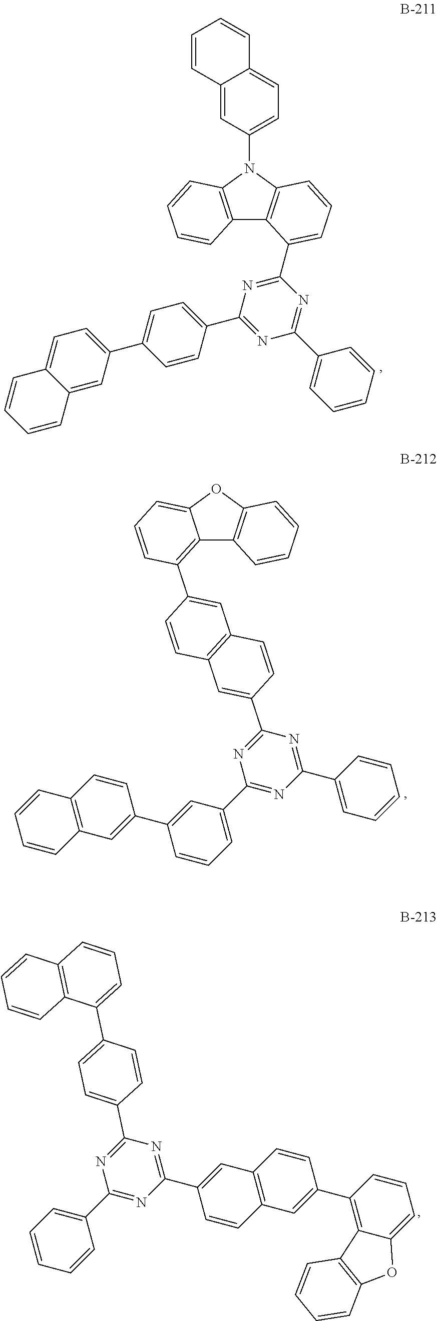 [SMILES: c1ccc(-c2nc(-c3ccc(-c4ccc5ccccc5c4)cc3)nc(-c3cccc4c3c3ccccc3n4-c3ccc4ccccc4c3)n2)cc1 ; c1ccc(-c2nc(-c3cccc(-c4ccc5ccccc5c4)c3)nc(-c3ccc4cc(-c5cccc6oc7ccccc7c56)ccc4c3)n2)cc1 ; c1ccc(-c2nc(-c3ccc(-c4cccc5ccccc45)cc3)nc(-c3ccc4cc(-c5cccc6oc7ccccc7c56)ccc4c3)n2)cc1]

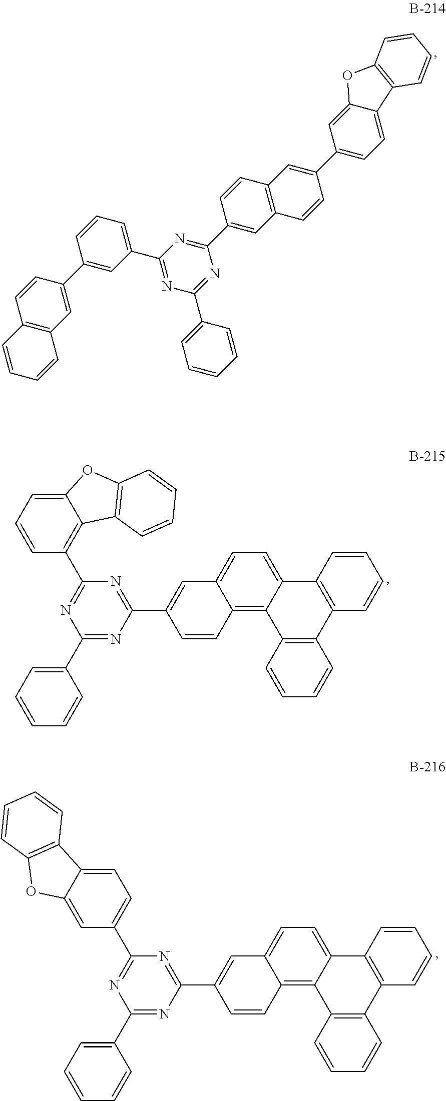 [SMILES: c1ccc(-c2nc(-c3cccc(-c4ccc5ccccc5c4)c3)nc(-c3ccc4cc(-c5ccc6c(c5)oc5ccccc56)ccc4c3)n2)cc1 ; c1ccc(-c2nc(-c3ccc4c(ccc5c6ccccc6c6ccccc6c45)c3)nc(-c3cccc4oc5ccccc5c34)n2)cc1 ; c1ccc(-c2nc(-c3ccc4c(ccc5c6ccccc6c6ccccc6c45)c3)nc(-c3ccc4c(c3)oc3ccccc34)n2)cc1]

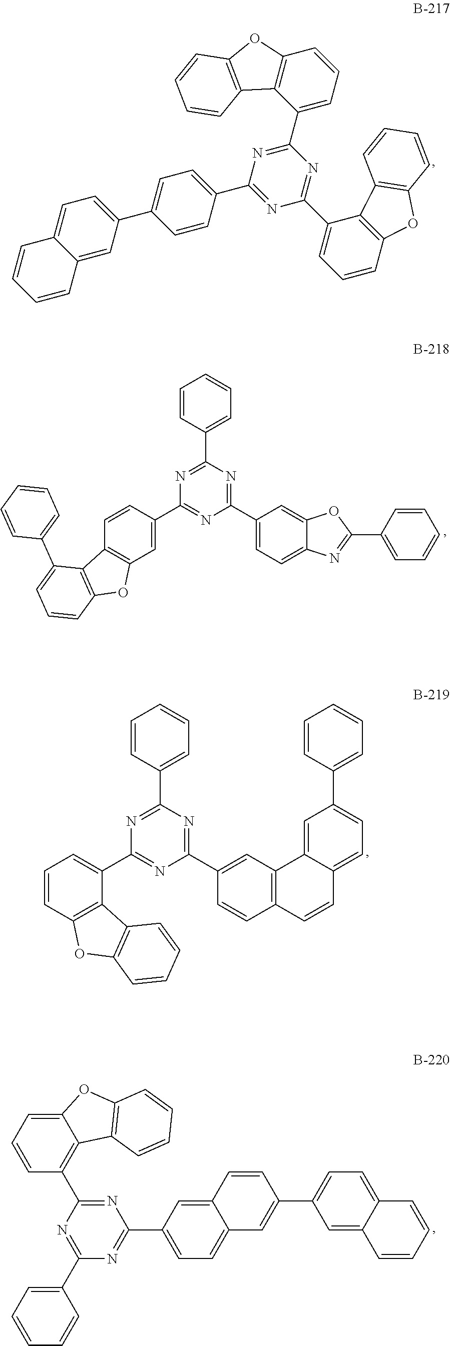 [SMILES: c1ccc2cc(-c3ccc(-c4nc(-c5cccc6oc7ccccc7c56)nc(-c5cccc6oc7ccccc7c56)n4)cc3)ccc2c1 ; c1ccc(-c2nc(-c3ccc4nc(-c5ccccc5)oc4c3)nc(-c3ccc4c(c3)oc3cccc(-c5ccccc5)c34)n2)cc1 ; c1ccc(-c2ccc3ccc4ccc(-c5nc(-c6ccccc6)nc(-c6cccc7oc8ccccc8c67)n5)cc4c3c2)cc1 ; c1ccc(-c2nc(-c3ccc4cc(-c5ccc6ccccc6c5)ccc4c3)nc(-c3cccc4oc5ccccc5c34)n2)cc1]

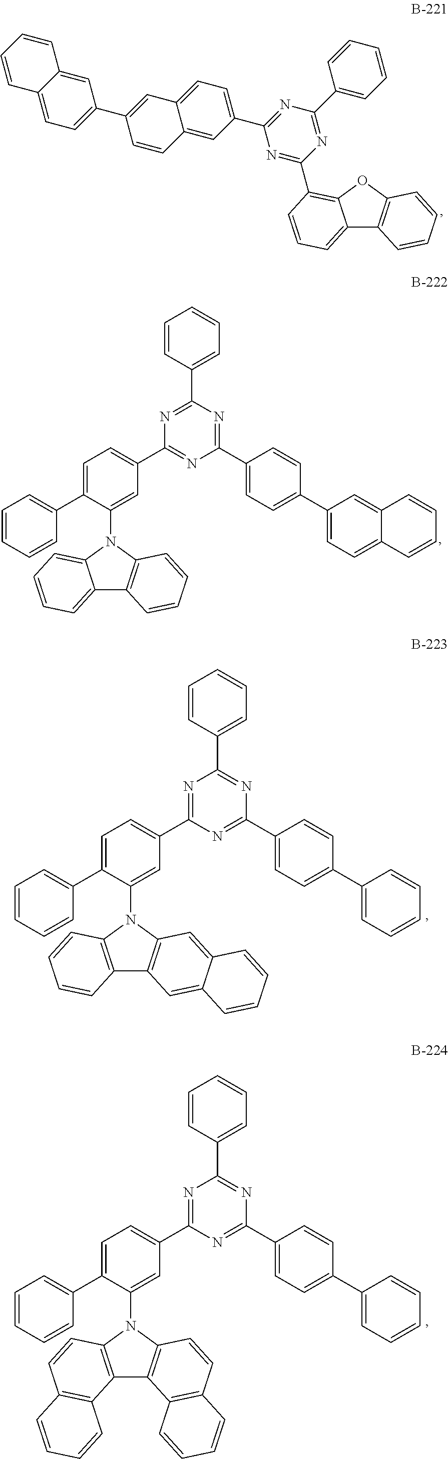 [SMILES: c1ccc(-c2nc(-c3ccc4cc(-c5ccc6ccccc6c5)ccc4c3)nc(-c3cccc4c3oc3ccccc34)n2)cc1 ; c1ccc(-c2nc(-c3ccc(-c4ccc5ccccc5c4)cc3)nc(-c3ccc(-c4ccccc4)c(-n4c5ccccc5c5ccccc54)c3)n2)cc1 ; c1ccc(-c2ccc(-c3nc(-c4ccccc4)nc(-c4ccc(-c5ccccc5)c(-n5c6ccccc6c6cc7ccccc7cc65)c4)n3)cc2)cc1 ; c1ccc(-c2ccc(-c3nc(-c4ccccc4)nc(-c4ccc(-c5ccccc5)c(-n5c6ccc7ccccc7c6c6c7ccccc7ccc65)c4)n3)cc2)cc1]

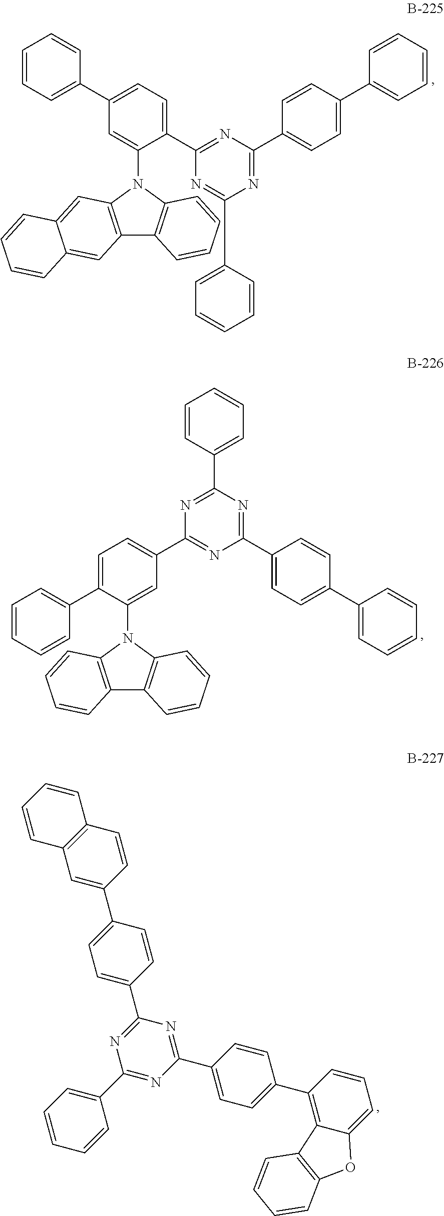 [SMILES: c1ccc(-c2ccc(-c3nc(-c4ccccc4)nc(-c4ccc(-c5ccccc5)cc4-n4c5ccccc5c5cc6ccccc6cc54)n3)cc2)cc1 ; c1ccc(-c2ccc(-c3nc(-c4ccccc4)nc(-c4ccc(-c5ccccc5)c(-n5c6ccccc6c6ccccc65)c4)n3)cc2)cc1 ; c1ccc(-c2nc(-c3ccc(-c4ccc5ccccc5c4)cc3)nc(-c3ccc(-c4cccc5oc6ccccc6c45)cc3)n2)cc1]

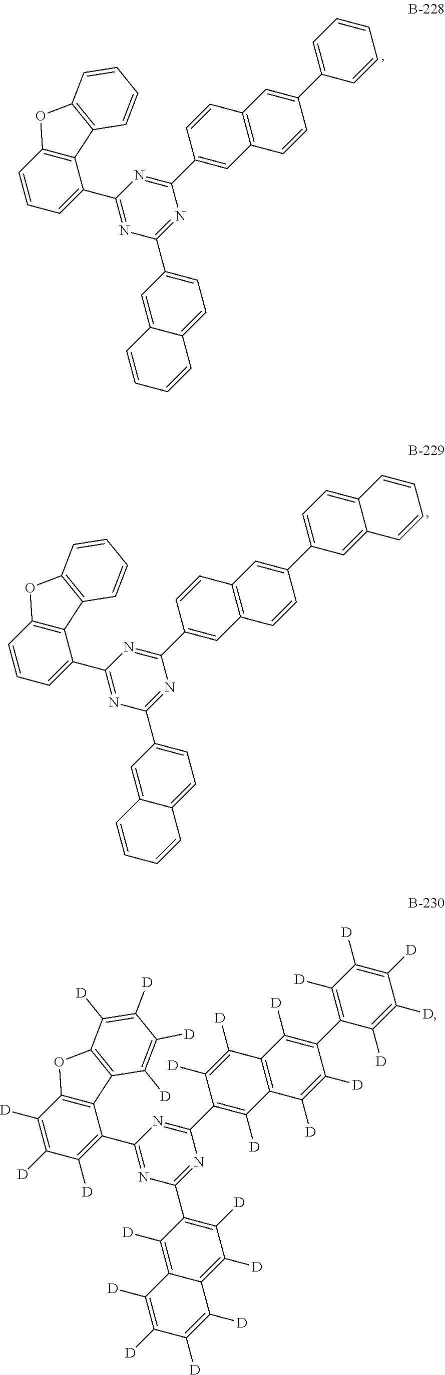

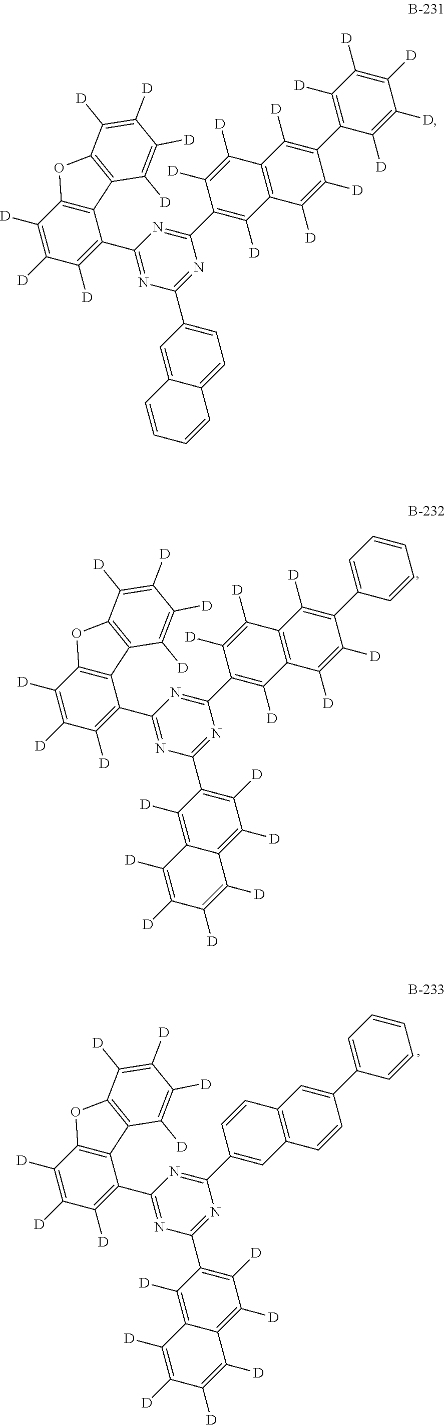

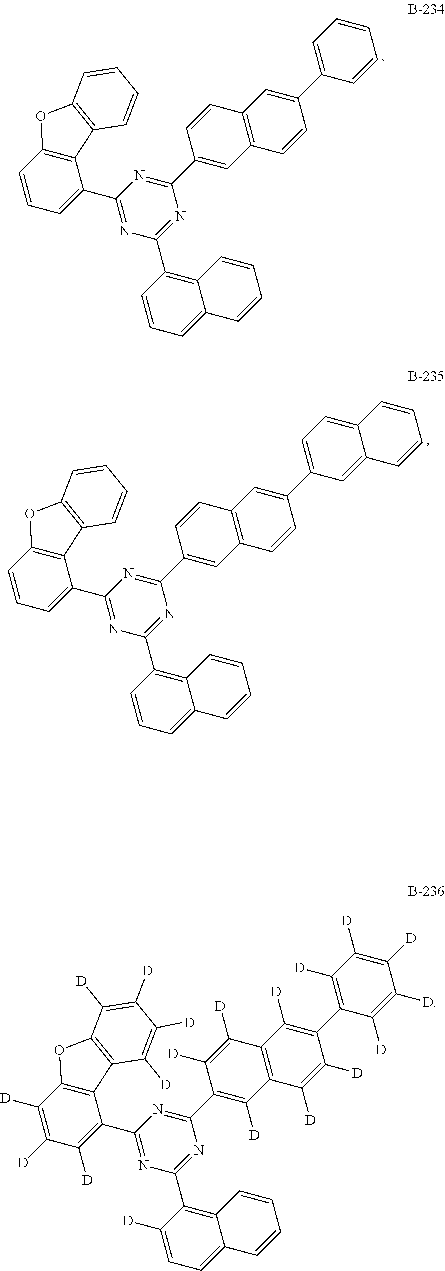

According to an embodiment of the present disclosure, hydrogen in Compound B-1 to Compound B-236 can be partially or fully substituted with deuterium.

According to another embodiment of the present disclosure, further disclosed is a compound composition. The compound composition comprises a metal complex whose specific structure is described in any one of the preceding embodiments.

### Combination with Other Materials

The materials described in the present disclosure for a particular layer in an organic light emitting device can be used in combination with various other materials present in the device. The combinations of these materials are described in more detail in U.S. patent application No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. patent application No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods, and other related contents, the inherent data of samples can be obtained with certainty and without influence, so the above related contents are not further described in this patent.

### Material Synthesis Example

Methods for preparing the compounds of the present disclosure are not limited. Those skilled in the art can select appropriate raw materials and process routes according to the synthesis target. For example, the metal complex of the present disclosure can be synthesized according to the route described below.

Reference may be made to the related art such as a method in CN111269269A to prepare an Lₐ ligand compound. After the Lₐ ligand compound is obtained, the target metal complex can be prepared through a common synthesis method in the related art. For example, the Lₐ ligand compound reacts with an iridium complex to obtain the target metal complex. The synthesis route is shown as follows:

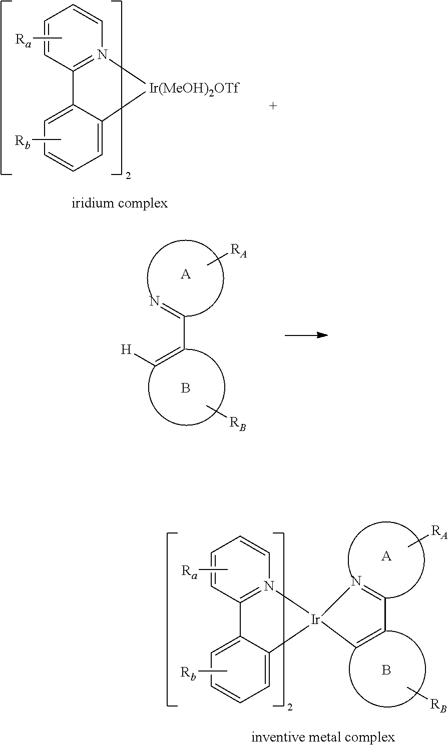

When the metal complex of the present disclosure is synthesized, those skilled in the art may also refer to the related art or synthesis methods recorded in previous applications such as US20240109926A1 to prepare the metal complex, or those skilled in the art may design a synthesis route through reverse synthesis (retrosynthesis) to effectively synthesize the metal complex of the present disclosure.

Those skilled in the art will appreciate that the above preparation method is merely exemplary. Those skilled in the art can obtain other compound structures of the present disclosure through the modifications of the preparation method.

The compounds of the present disclosure can achieve deep red to near-infrared light emission due to a ligand design with multiple fused rings. To further verify the light emission effect, energy levels of some compounds of the present disclosure are calculated through density-functional theory (DFT) calculation.

### DFT Calculation of the Compounds of the Present Disclosure

A B3LYP hybrid functional and a CEP-31G effective core potential basis set were used in a Gaussian software package with a solvation model based on density (SMD) for simulating a tetrahydrofuran (THF) solvent environment, and DFT calculation was performed on some compounds disclosed in the present disclosure and Compounds RD-A and RD-B in comparative examples. Data of triplet-state energy levels (T1), highest occupied molecular orbital (HOMO) energy levels and lowest unoccupied molecular orbital (LUMO) energy levels of the compounds were obtained, and maximum emission wavelengths of the compounds were calculated according to T1 and using Formula F1. These data are shown in Table 1.

$${λ}_{max} ( nm ) = 1240 / T 1 \qquad Formula F 1$$

TABLE 1
Calculated data

| | | | HOMO | LUMO |
|---|---|---|---|---|
| Compound No. | λₘₐₓ (nm) | T1 (eV) | (eV) | (eV) |
| Compound 4 | 776 | 1.5988 | −5.06 | −2.11 |
| Compound 5 | 728 | 1.7028 | −5.12 | −2.16 |
| Compound 9 | 695 | 1.7837 | −4.96 | −2.03 |
| Compound 81 | 746 | 1.6622 | −5.10 | −2.09 |
| Compound 88 | 742 | 1.6722 | −5.09 | −2.15 |
| Compound 171 | 719 | 1.7252 | −4.84 | −2.03 |
| Compound 174 | 694 | 1.7865 | −5.06 | −2.07 |
| Compound 255 | 737 | 1.6814 | −5.01 | −1.93 |
| Compound 258 | 757 | 1.6383 | −5.06 | −2.05 |
| Compound 339 | 727 | 1.7067 | −5.07 | −2.05 |
| Compound RD-A | 563 | 2.2039 | −5.12 | −1.85 |
| Compound RD-B | 572 | 2.1695 | −5.00 | −1.81 |

The related compounds have the following structures:

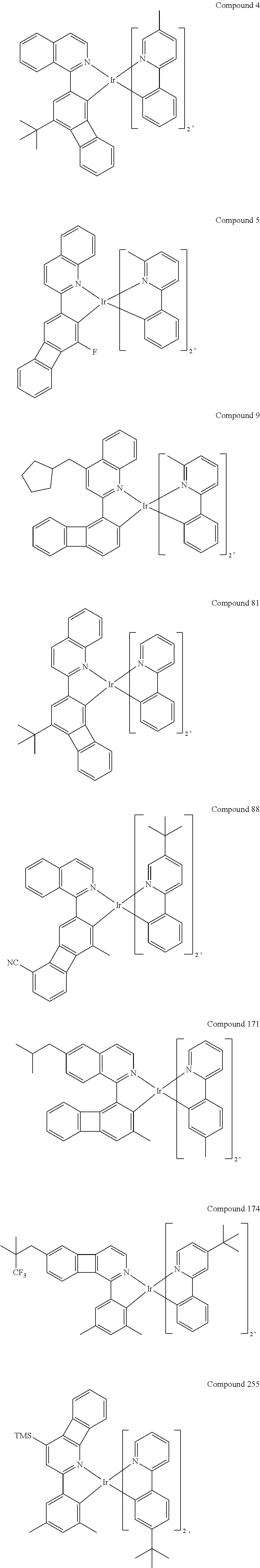

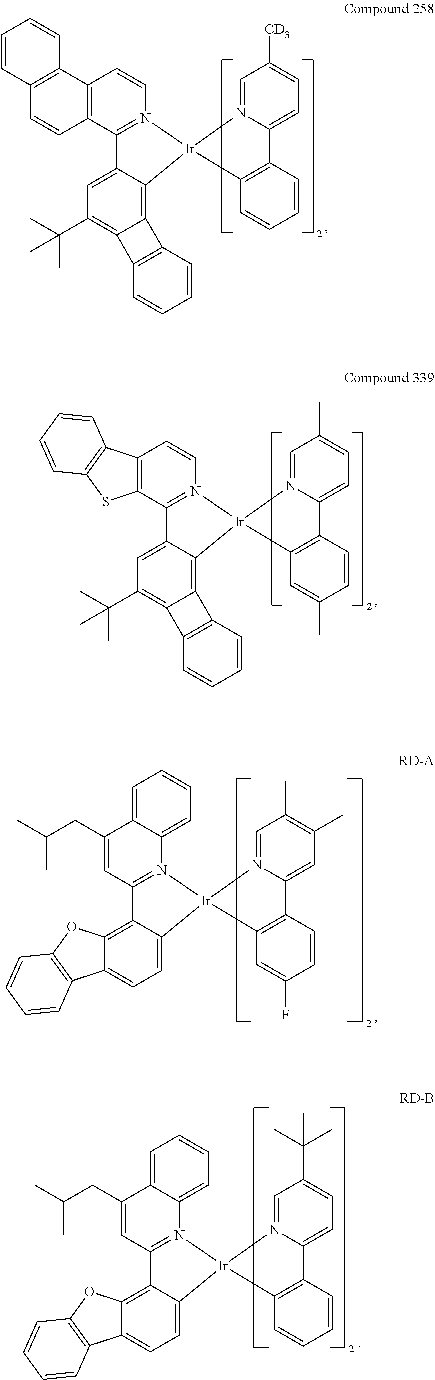

### Discussion

As can be seen from the data in Table 1, the calculated T1 energy levels of the compounds of the present disclosure are generally low. For example, the T1 energy level of Compound 9 of the present disclosure is 1.7837 eV, and the maximum emission wavelength of Compound 9 is calculated to be 695 nm. Compound 9 of the present disclosure differs from Compounds RD-A and RD-B in the comparative examples mainly in that biphenylene or a similar structure thereof of Formula 2 is introduced into a skeleton structure of a ligand Lₐ of Compound 9 of the present disclosure instead of a dibenzofuran structure. This structure enables the maximum emission wavelength of Compound 9 of the present disclosure to achieve an unexpectedly significant red shift. The significant red shift is more than 120 nm relative to Compounds RD-A and RD-B in the comparative examples, indicating that the compound of the present disclosure can achieve a beneficial effect of significantly adjusting the emission wavelength due to the ligand design with biphenylene. Further, as can be seen from the data in Table 1, since the biphenylene structure is introduced into the ligand and a particular ligand having a PPy (2-phenyl-pyridine) skeleton structure is used, the compound of the present disclosure has a significantly red-shifted maximum emission wavelength and can achieve deep red light emission more than 640 nm (for example, the maximum emission wavelengths of Compound 9 and Compound 174 are both more than 690 nm) or near-infrared light emission more than 700 nm (for example, the maximum emission wavelengths of Compound 5, Compound 81, Compound 88, Compound 171, Compound 255 and Compound 339 are all more than 710 nm, and the maximum emission wavelengths of Compound 4 and Compound 258 are even more than 750 nm).

In addition, the HOMO energy level values of the compounds of the present disclosure, which are generally within an interval of −5.12 eV to −4.84 eV, are equivalent to or shallower than those of the compounds in the comparative examples, indicating that the compounds of the present disclosure may have hole trapping capabilities that are equivalent to or stronger than those of the compounds in the comparative examples. A strong hole trapping capability is conducive to the metal complex of the present disclosure achieving excellent performance in a device, for example, a low voltage, high device efficiency and a long device lifetime, indicating that the metal complex of the present disclosure has great potential to become a phosphorescent material with excellent performance.

In conclusion, since particular biphenylene represented by Formula 2 or a similar structure thereof is introduced into a skeleton structure of a ligand Lₐ and a particular ligand having a PPy skeleton structure is used, the metal complex disclosed in the present disclosure can achieve light emission in different bands from deep red to near-infrared, having great potential to become a phosphorescent material with excellent performance, and having great application potential and broad application prospects of bringing devices excellent performance such as low voltages, high efficiency and long lifetimes.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. A metal complex having a general formula of M(Lₐ)ₘ(L_{b})ₙ(L_{c})_{q}, wherein the metal M is selected from a metal with a relative atomic mass greater than 40, and Lₐ, L_{b} and L_{c} are a first ligand, a second ligand and a third ligand coordinated to the metal M, respectively; Lₐ, L_{b} and L_{c} are the same or different;
Lₐ, L_{b} and Le can be optionally joined to form a multidentate ligand;
m is 1 or 2, n is 1 or 2, q is 0 or 1, and m+n+q is equal to an oxidation state of the metal M;
when m is equal to 2, two Lₐ are the same or different; when n is equal to 2, two L_{b} are the same or different;
the first ligand Lₐ has a structure represented by Formula 1: 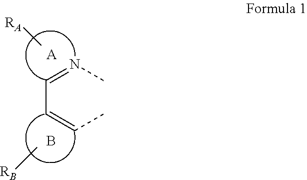
the ring A or the ring B has a structure represented by Formula 2: 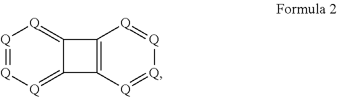
Q is, at each occurrence identically or differently, selected from N or C;
when the ring A has the structure represented by Formula 2, the ring B is selected from an unsaturated carbocyclic ring having 5 to 30 carbon atoms or an unsaturated heterocyclic ring having 2 to 30 carbon atoms;
when the ring B has the structure represented by Formula 2, the ring A is selected from a fused heteroaromatic ring having 3 to 30 carbon atoms;
R_{A} and R_{B} represent, at each occurrence identically or differently, mono-substitution, multiple substitutions or non-substitution;
R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{A} and R_{B} can be optionally joined to form a ring;
the second ligand L_{b} is represented by Formula 3: 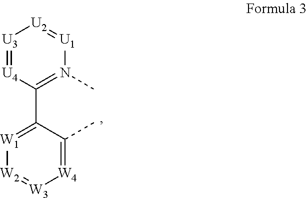
U₁ to U₄ are, at each occurrence identically or differently, selected from N or CR_{U};
W₁ to W₄ are, at each occurrence identically or differently, selected from N or CR_{W};
R_{U} and R_{W} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{U} and R_{W} can be optionally joined to form a ring; and
L is selected from a monoanionic bidentate ligand.

2. The metal complex according to claim 1, wherein in the Lₐ, the ring A has the structure represented by Formula 2, and the ring B is selected from an aromatic ring having 6 to 18 carbon atoms or a heteroaromatic ring having 3 to 18 carbon atoms;
preferably, the ring B is selected from a benzene ring, a naphthalene ring, a pyridine ring, a pyrimidine ring, a pyrazine ring, an azanaphthalene ring, a furan ring, a thiophene ring, an isoxazole ring, an isothiazole ring, a pyrrole ring, a pyrazole ring, a benzofuran ring, a benzothiophene ring, a benzopyrrole ring, a dibenzofuran ring, a dibenzothiophene ring, a dibenzopyrrole ring, an azabenzofuran ring or an azabenzothiophene ring;
more preferably, the ring B is selected from a benzene ring, a naphthalene ring, a benzofuran ring, a benzothiophene ring, a dibenzofuran ring, a dibenzothiophene ring or a dibenzopyrrole ring.

3. The metal complex according to claim 1, wherein in the Lₐ, the ring B has the structure represented by Formula 2, and the ring A is selected from a fused heteroaromatic ring having 3 to 18 carbon atoms;
preferably, the ring A is selected from a quinoline ring, an isoquinoline ring, a benzoquinoline ring, a benzisoquinoline ring, a quinazoline ring, a benzoxazole ring, a benzisothiazole ring, a benzopyrrole ring, a benzopyrazole ring, an azabenzofuran ring, an azabenzothiophene ring, an azabenzopyrrole ring, an azadibenzofuran ring, an azadibenzothiophene ring or an azadibenzopyrrole ring; and
more preferably, the ring A is selected from a quinoline ring, an isoquinoline ring, a benzoquinoline ring, a benzisoquinoline ring, an azadibenzofuran ring, an azadibenzothiophene ring or an azadibenzopyrrole ring.

4. The metal complex according to claim 1, wherein the Lₐ is selected from a structure represented by any one of Formula 4 to Formula 27: 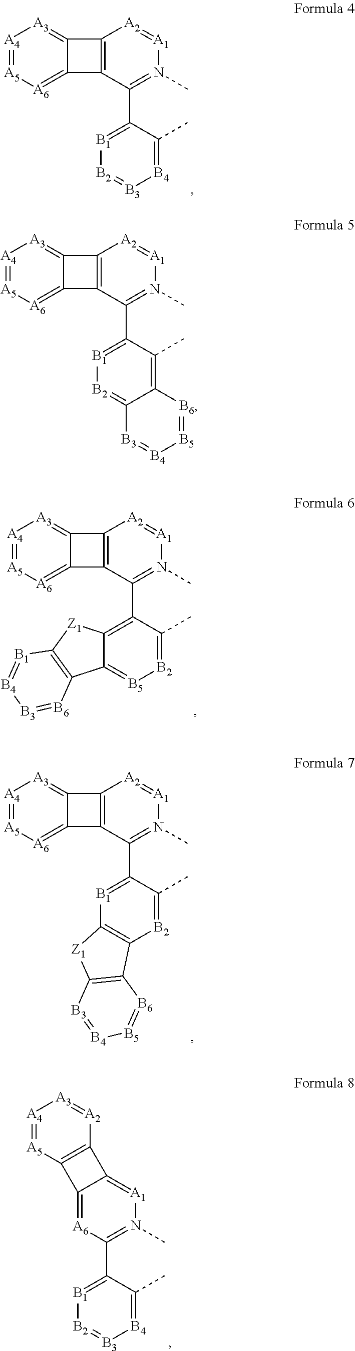 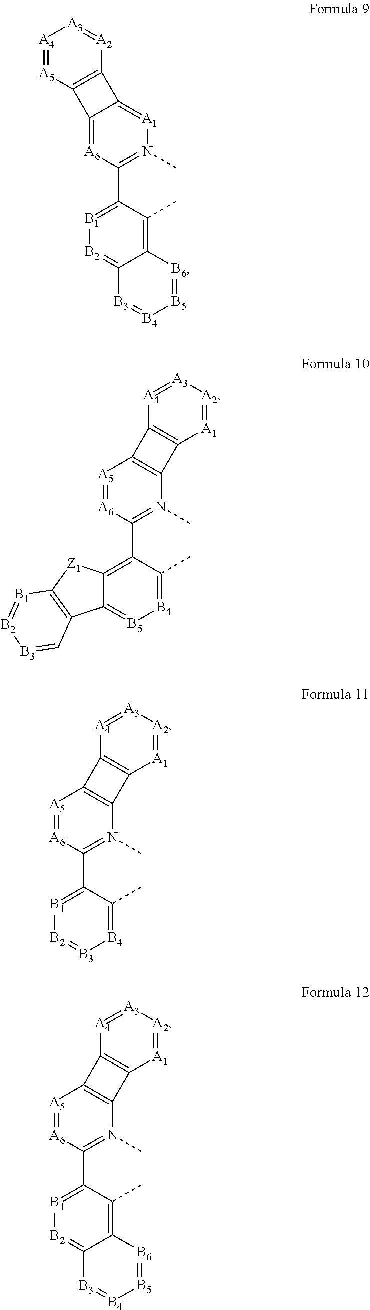 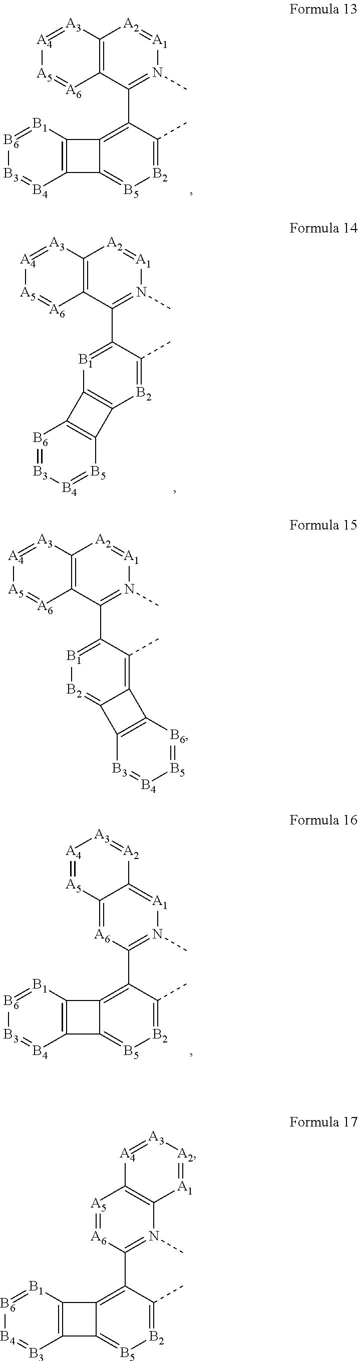 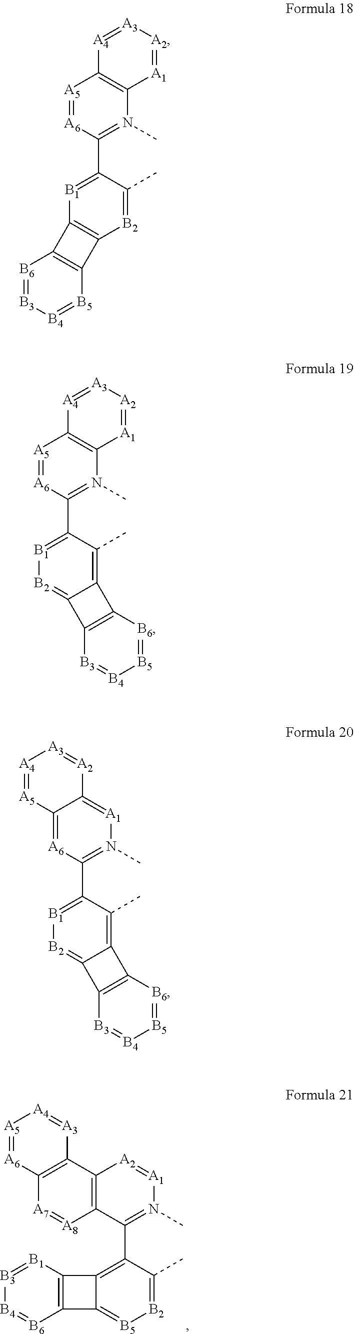 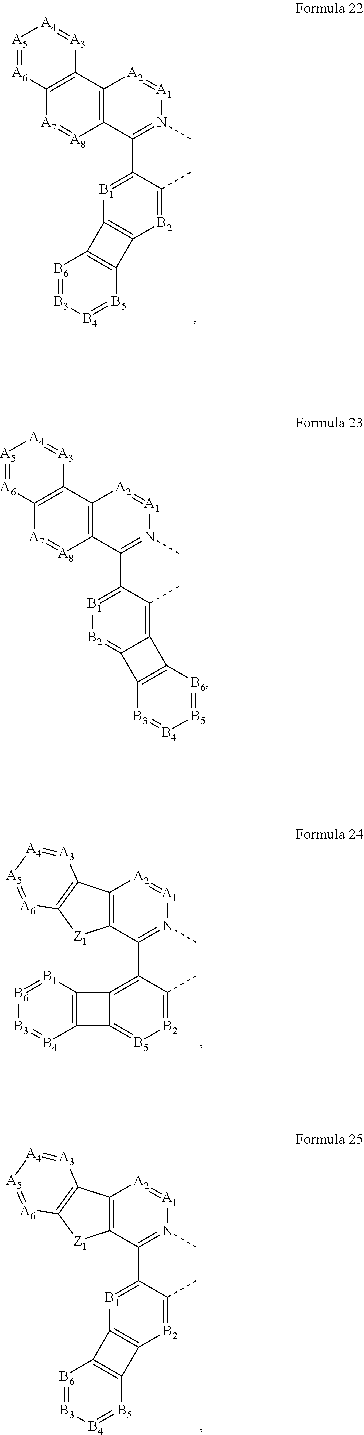 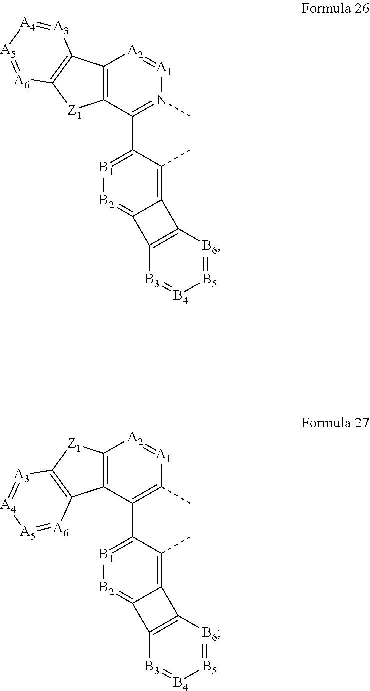
wherein,
A₁ to A₈ are, at each occurrence identically or differently, selected from N or CR_{A};
B₁ to B₆ are, at each occurrence identically or differently, selected from N or CR_{B};
Z₁ is, at each occurrence identically or differently, selected from O, S, Se, NR_{Z}, CR_{Z}R_{Z}, SiR_{Z}R_{Z} or PR_{Z};
R_{A}, R_{B} and R_{Z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{A}, R_{B} and R_{Z} can be optionally joined to form a ring;
preferably, Lₐ is selected from a structure represented by Formula 4, Formula 5, Formula 10, Formula 12, Formula 13, Formula 15, Formula 17, Formula 19, Formula 21, Formula 23, Formula 24 or Formula 26; and
more preferably, Lₐ is selected from a structure represented by Formula 5, Formula 12, Formula 15, Formula 19, Formula 21, Formula 23, Formula 24 or Formula 26.

5. The metal complex according to claim 1, wherein in the Formula 6, Formula 7, Formula 10, Formula 24, Formula 25, Formula 26 or Formula 27, Z₁ is selected from O, S or NR_{Z}; R_{Z} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms and combinations thereof; and
preferably, Z₁ is selected from O or S.

6. The metal complex according to claim 1, wherein in the Formula 4 to Formula 27, A₁ to A₈ are each independently selected from CR_{A}, and B₁ to B₆ are each independently selected from CR_{B}; R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{A} and R_{B} can be optionally joined to form a ring;
preferably, the R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkoxy having 1 to 20 carbon atoms, substituted or unsubstituted aryloxy having 6 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group and combinations thereof; and
more preferably, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, a cyano group and combinations thereof.

7. The metal complex according to claim 1, wherein in the Formula 4 to Formula 27, at least one of A to Aₘ is, at each occurrence identically or differently, selected from CR_{A}, wherein the Aₘ corresponds to one with the largest serial number among A₁ to A₈ in any one of Formula 4 to Formula 27; the R_{A} is, at each occurrence identically or differently, selected from the group consisting of: deuterium, halogen, cyano, hydroxyl, sulfanyl, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms and combinations thereof;
adjacent substituents R_{A} can be optionally joined to form a ring; and
preferably, the R_{A} is, at each occurrence identically or differently, selected from the group consisting of: deuterium, fluorine, cyano, hydroxyl, sulfanyl, amino, methoxy, phenoxy, methyl, ethyl, isopropyl, isobutyl, sec-butyl, tert-butyl, neopentyl, cyclopentyl, cyclopentylmethyl, cyclohexyl, norbornyl, adamantyl, trimethylsilyl, triethylsilyl, phenyldimethylsilyl, trimethylgermanyl, triethylgermanyl, phenyl, 2,6-dimethylphenyl, 2,6-diisopropylphenyl, pyridyl, pyrimidinyl, triazinyl and combinations thereof.

8. The metal complex according to claim 1, wherein in the Formula 4 to Formula 27, at least one of B₁ to Bₙ is selected from CR_{B}, wherein the Bₙ corresponds to one with the largest serial number among B₁ to B₆ in any one of Formula 4 to Formula 27; the R_{B} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group, a hydroxyl group, a sulfanyl group and combinations thereof;
adjacent substituents R_{B} can be optionally joined to form a ring;
preferably, in Formula 4 to Formula 27, B₂ and/or B₄ are selected from CR_{B}; and
more preferably, the R_{B} is, at each occurrence identically or differently, selected from the group consisting of: hydrogen, deuterium, fluorine, cyano, hydroxyl, sulfanyl, amino, methoxy, phenoxy, methylthio, phenylthio, dimethylamino, diphenylamino, phenylmethylamino, vinyl, tetrahydrofuranyl, tetrahydropyranyl, tetrahydrothienyl, piperidinyl, morpholinyl, benzyl, methyl, ethyl, isopropyl, isobutyl, tert-butyl, neopentyl, cyclopentyl, cyclopentylmethyl, cyclohexyl, trimethylsilyl, triethylsilyl, trimethylgermanyl, triethylgermanyl, phenyl, pyridyl, triazinyl, deuterated methyl, deuterated ethyl, deuterated isopropyl, deuterated isobutyl, deuterated tert-butyl, deuterated cyclopentyl, deuterated cyclopentylmethyl, deuterated cyclohexyl, deuterated neopentyl and combinations thereof.

9. The metal complex according to claim 1, wherein in Formula 4 to Formula 27, at least one of A₁ to Aₘ and/or B₁ to Bₙ is selected from N, wherein the Aₘ corresponds to one with the largest serial number among A₁ to A₈ in any one of Formula 4 to Formula 27, and the Bₙ corresponds to one with the largest serial number among B₁ to Be in any one of Formula 4 to Formula 27; and
preferably, in Formula 4 to Formula 7, Formula 13 to Formula 15 and Formula 21 to Formula 27, A₂ is N; in Formula 17 to Formula 19, As is N.

10. The metal complex according to claim 1, wherein the Lₐ is, at each occurrence identically or differently, selected from the group consisting of the following structures: 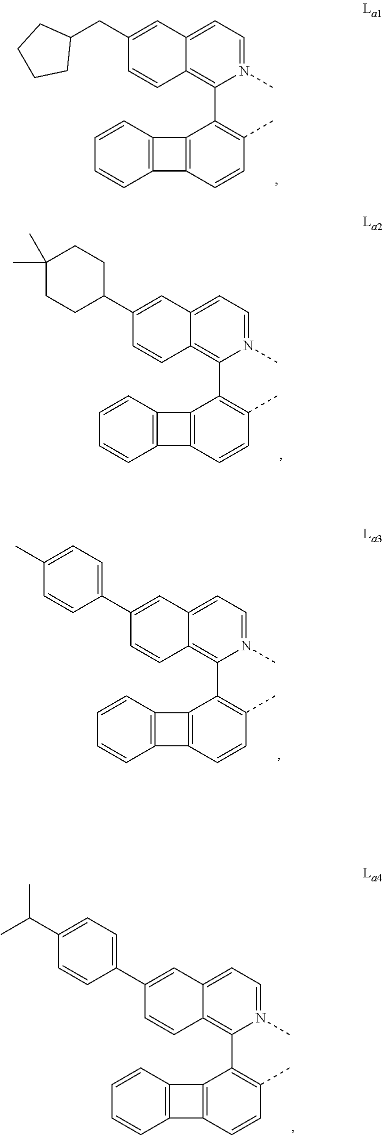 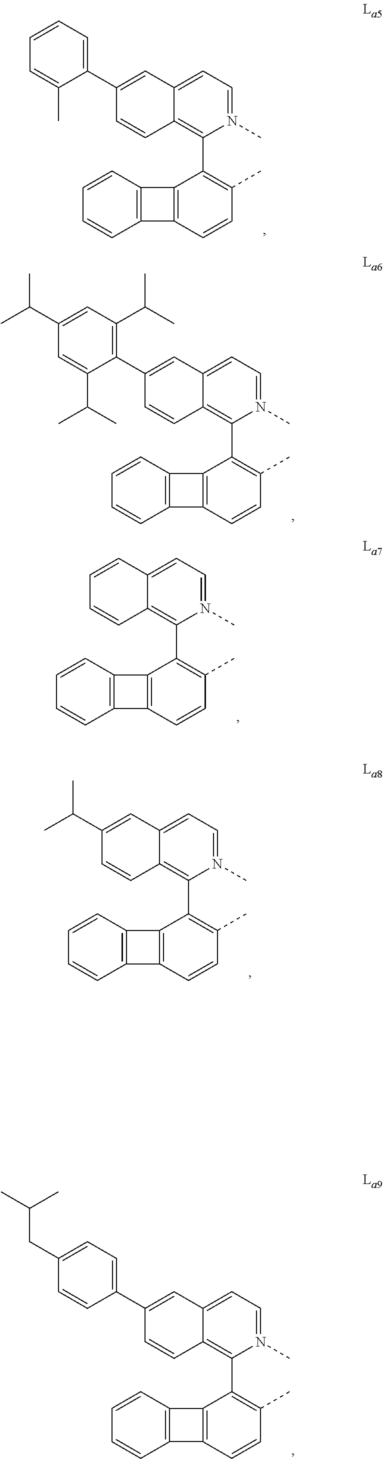 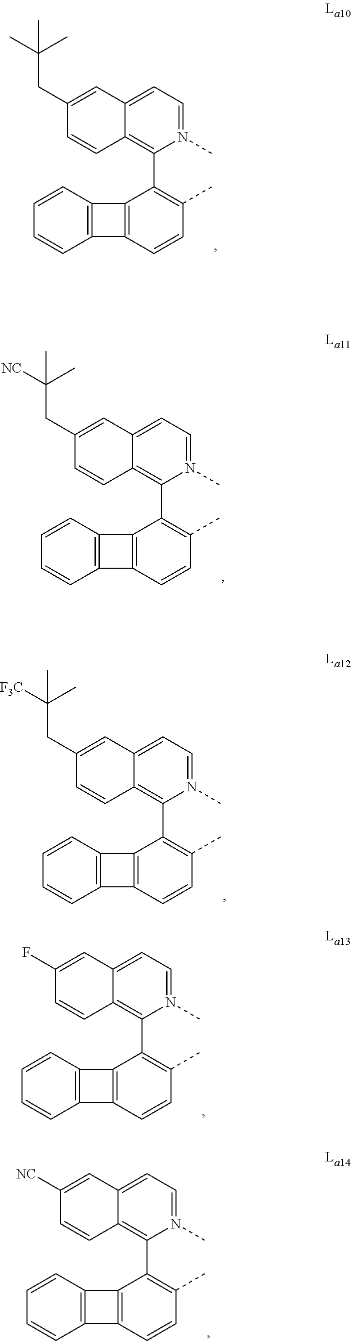 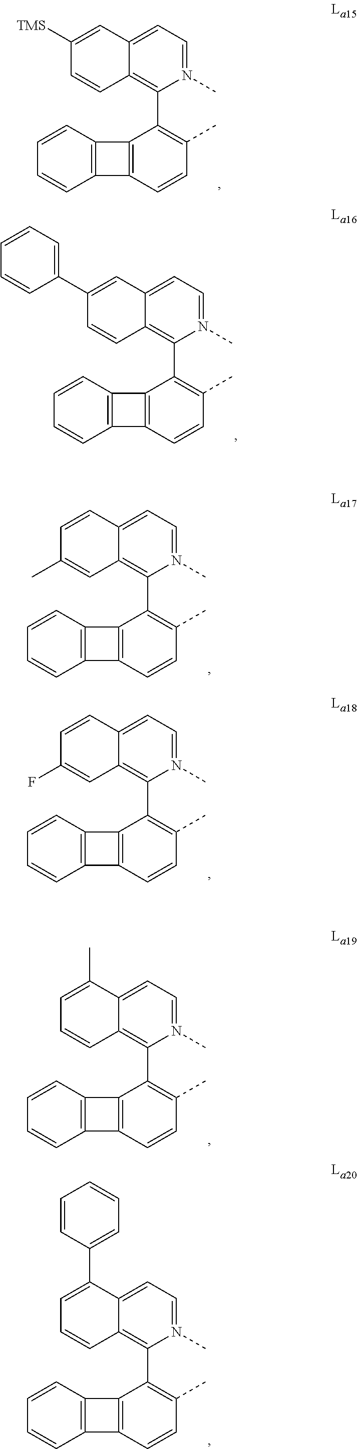 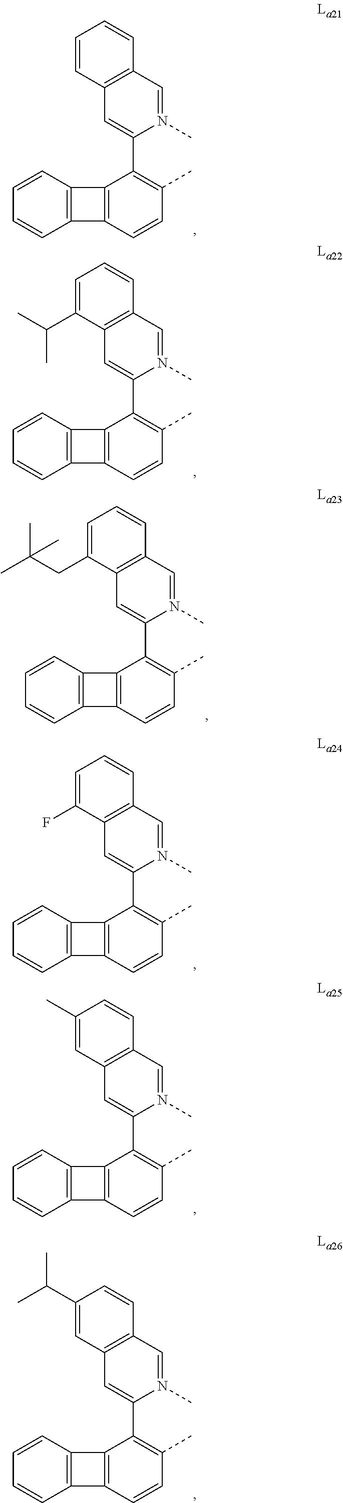 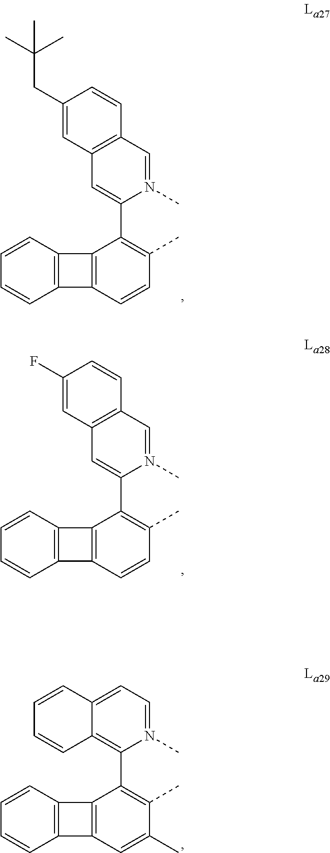 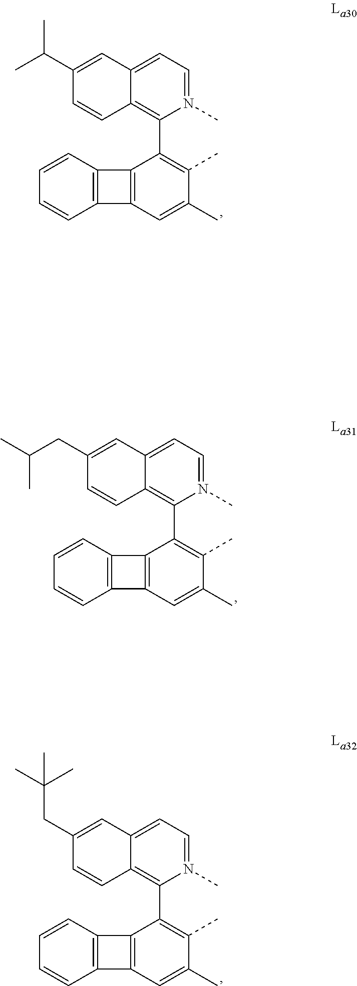 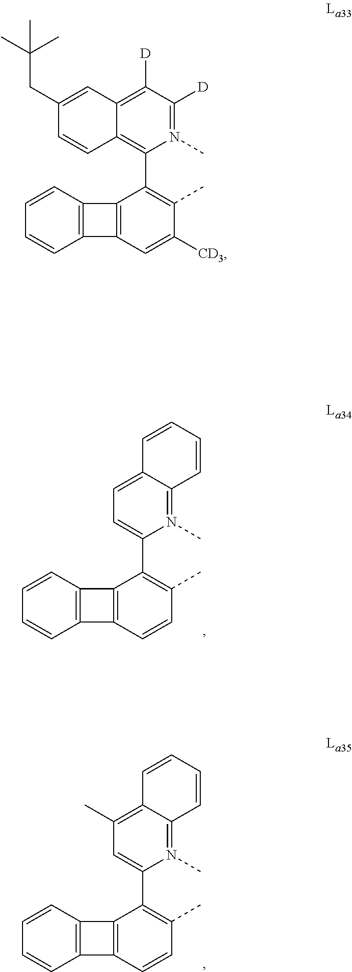 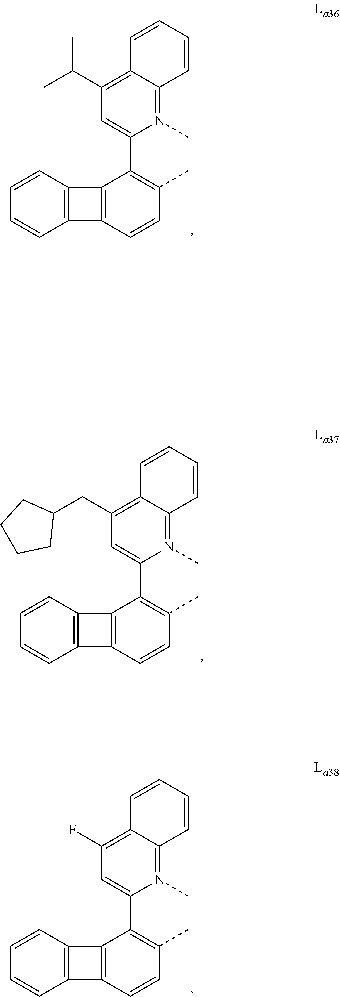 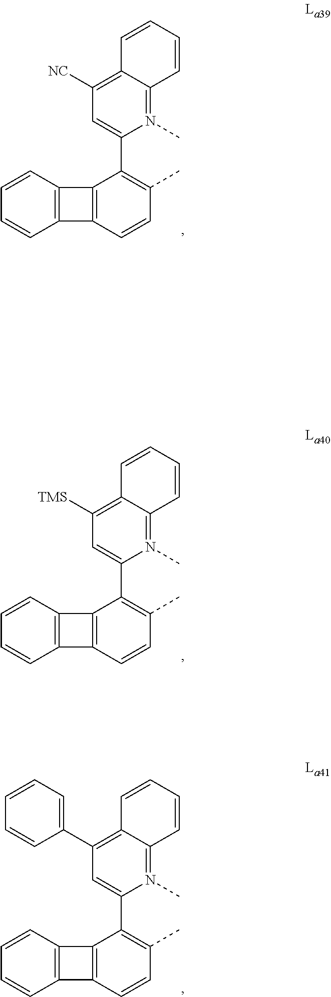 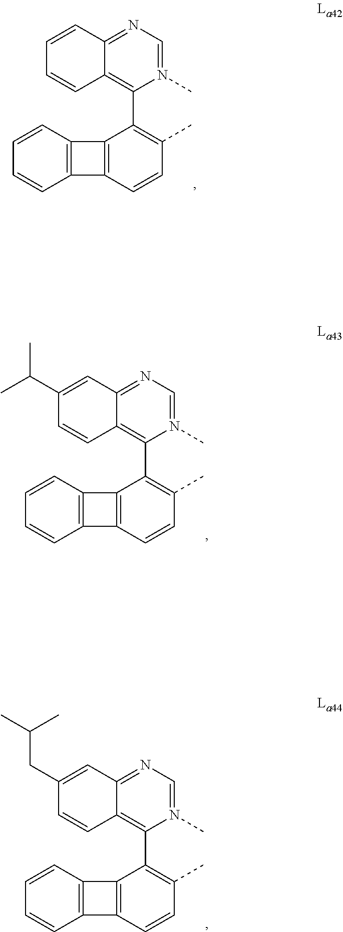 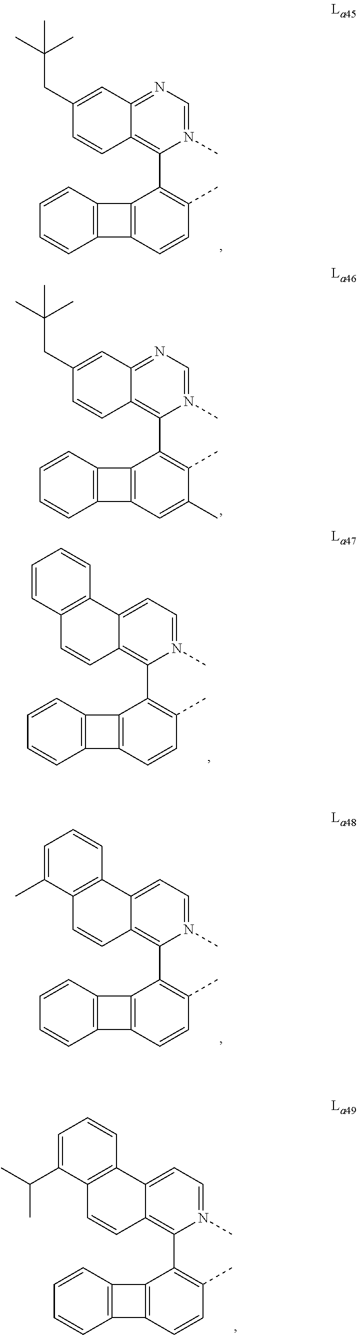 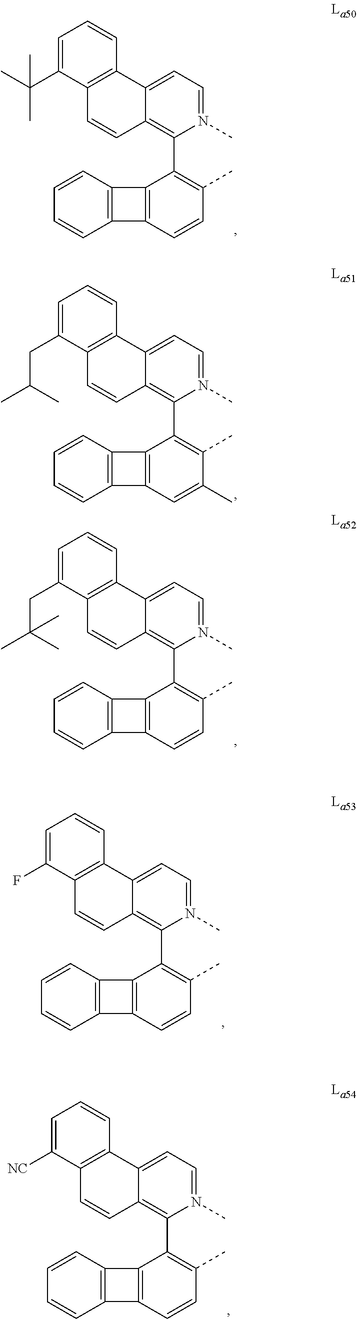 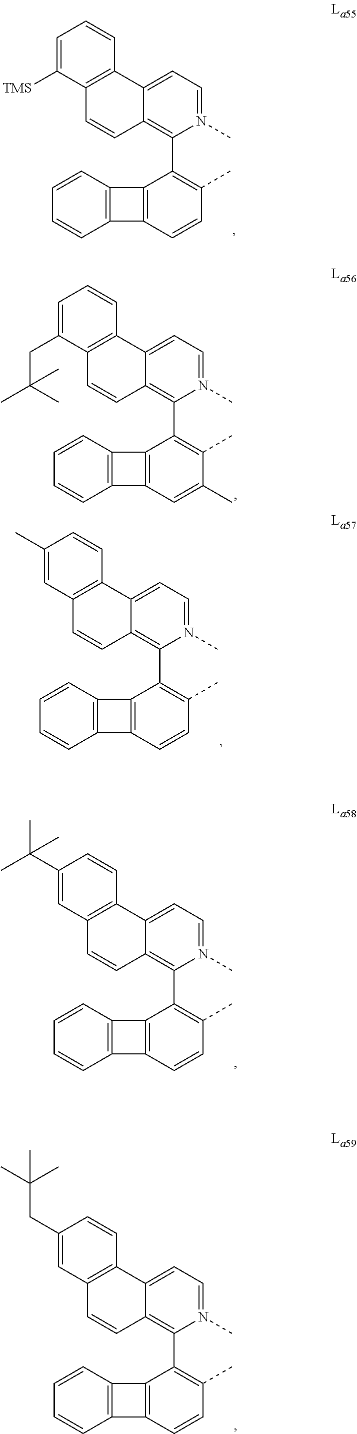 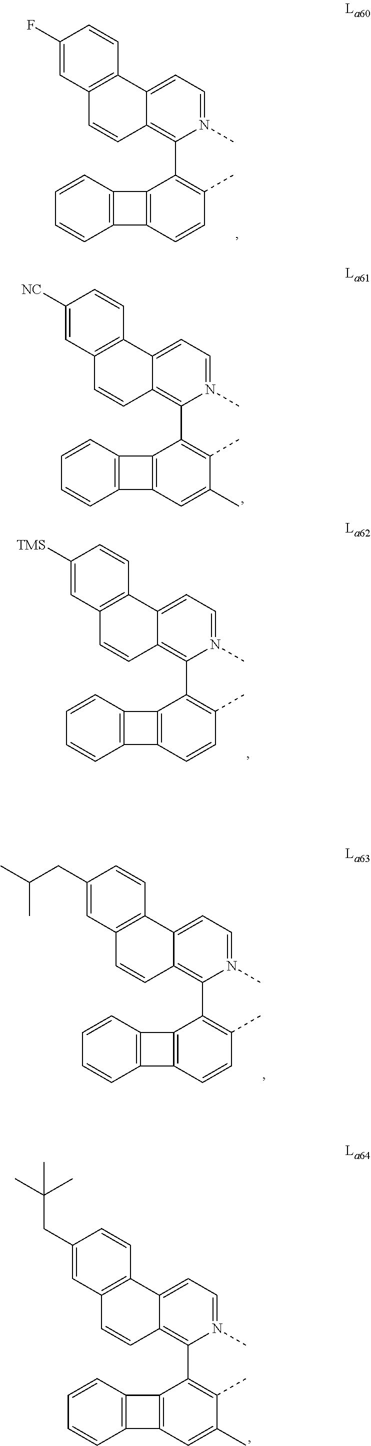 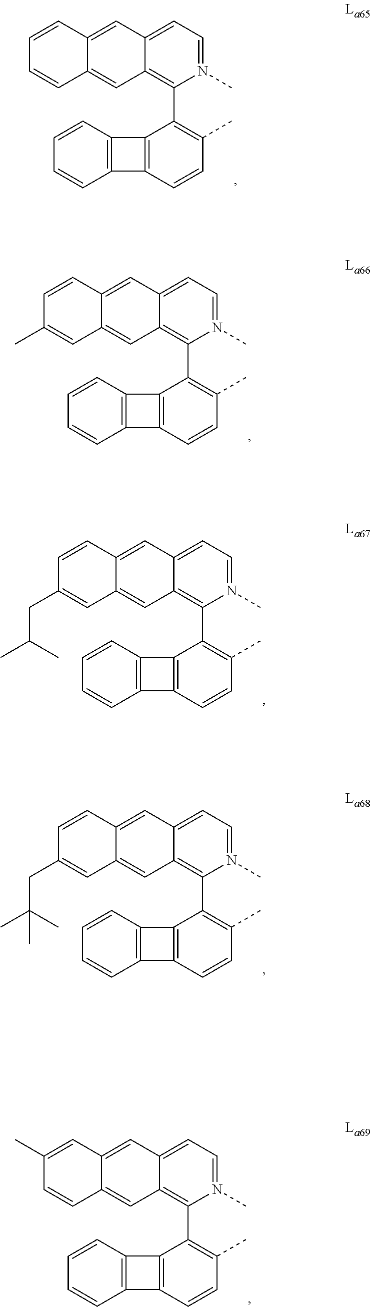 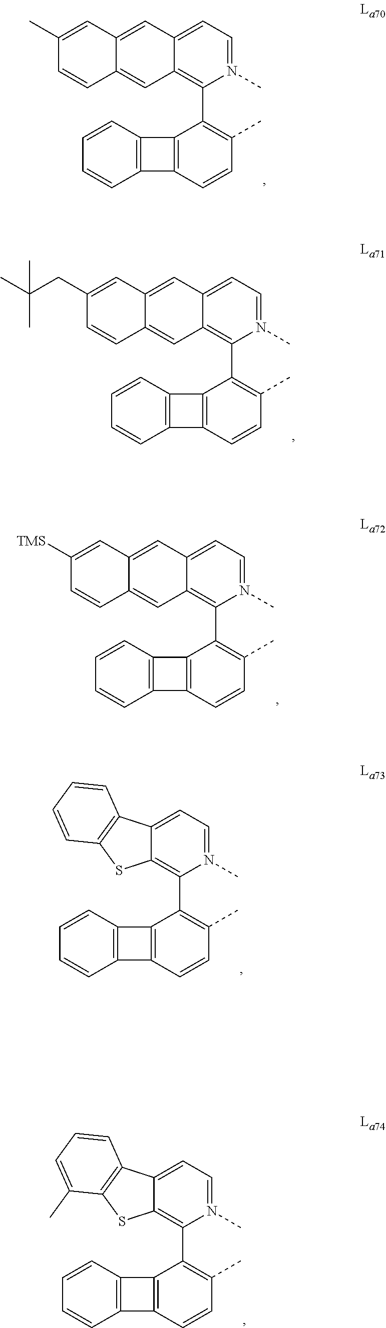 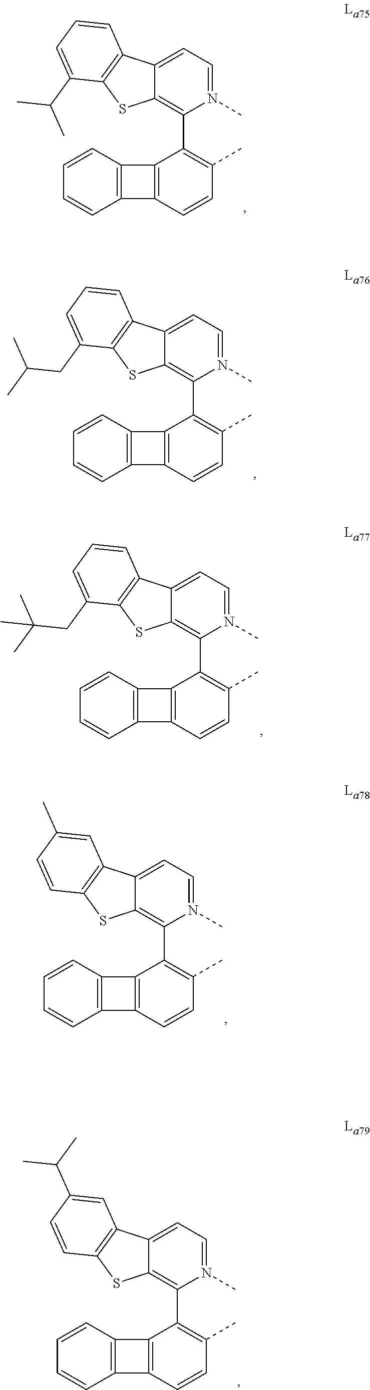 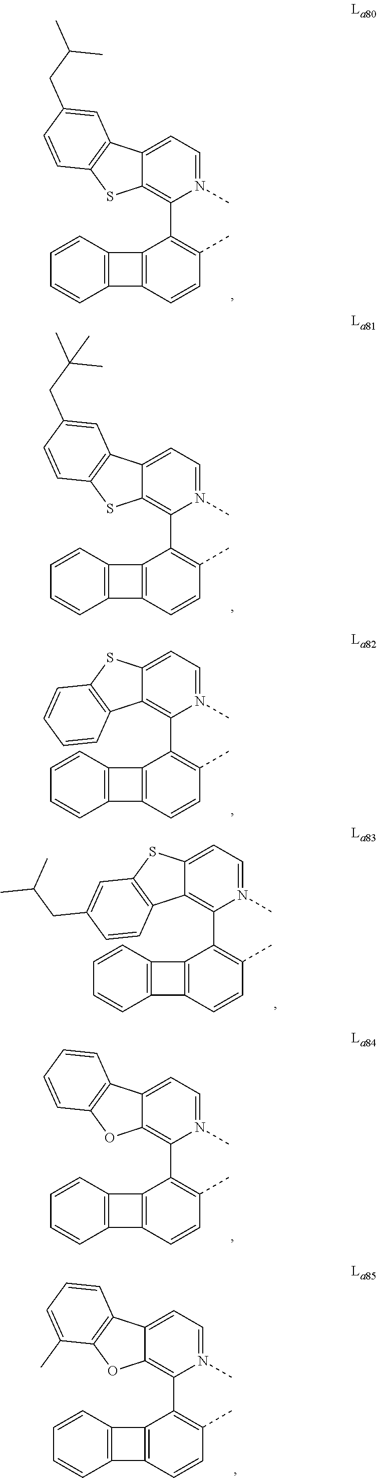 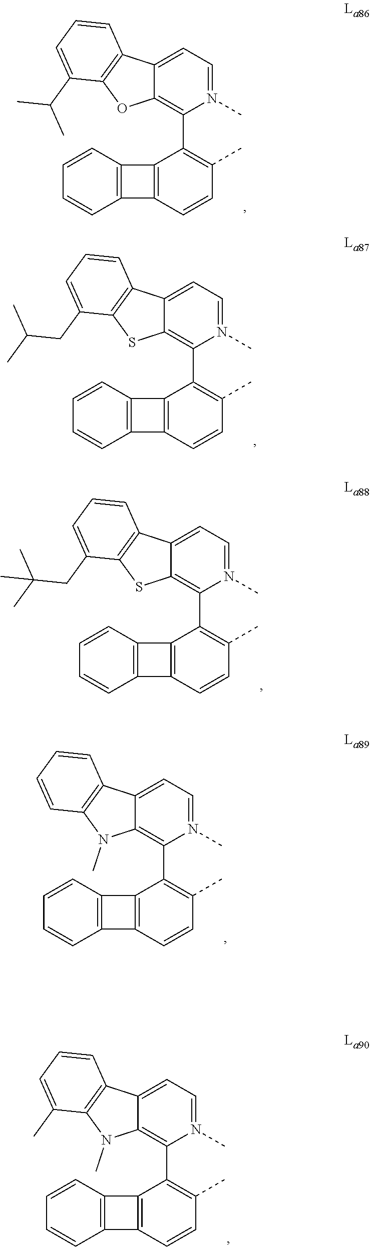 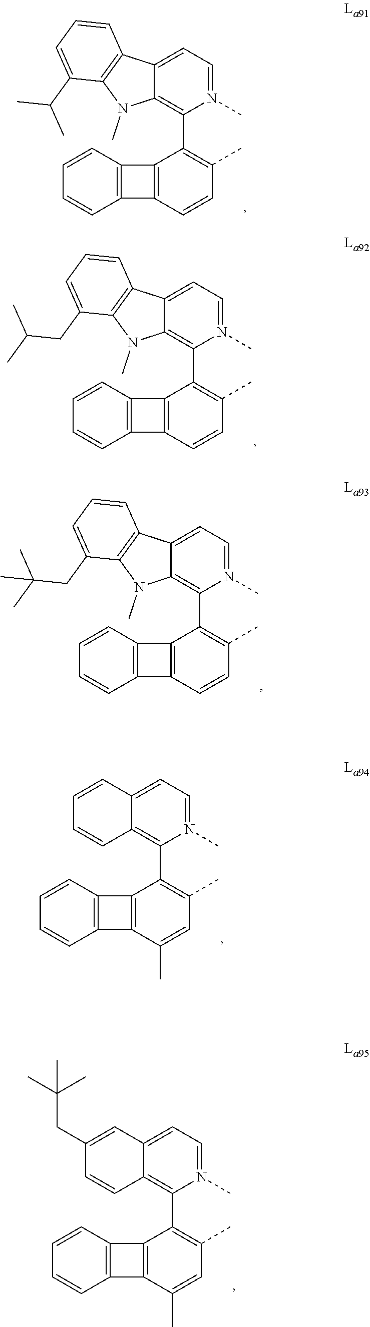 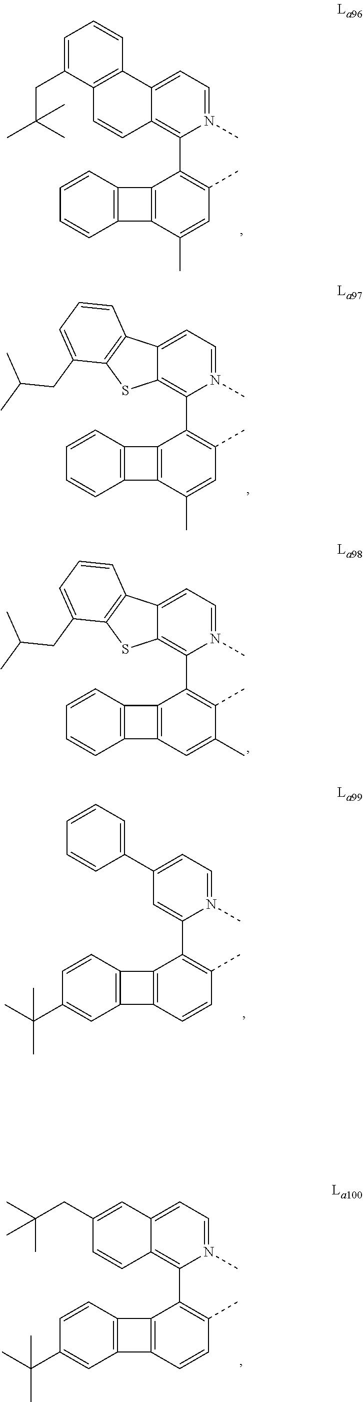 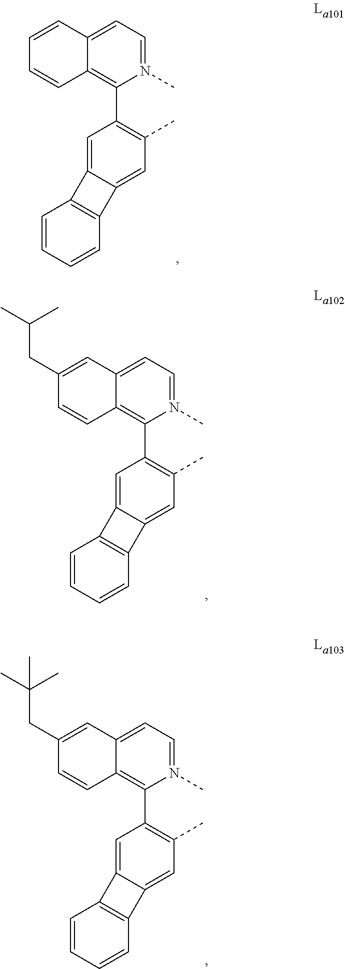 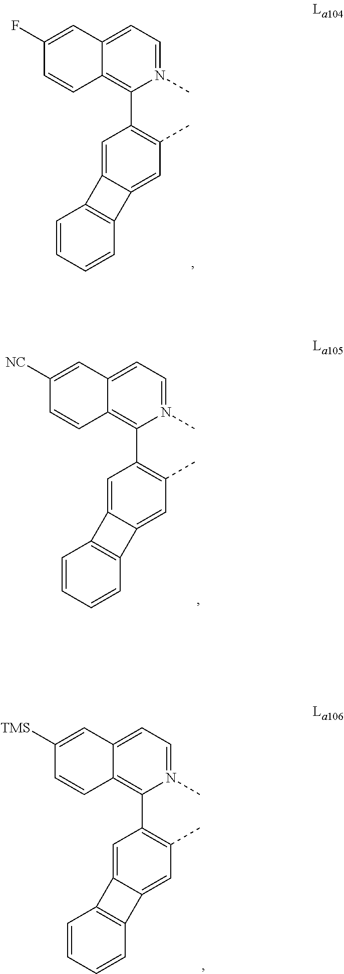 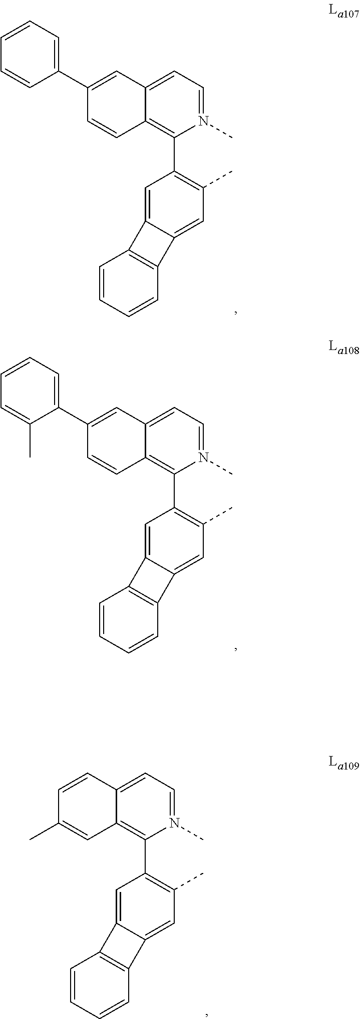 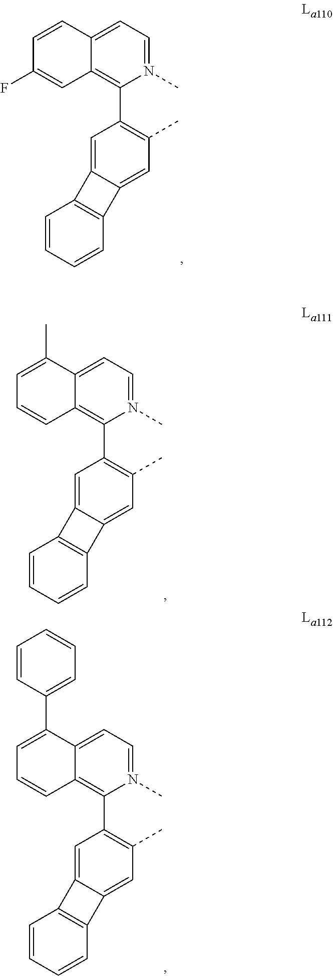 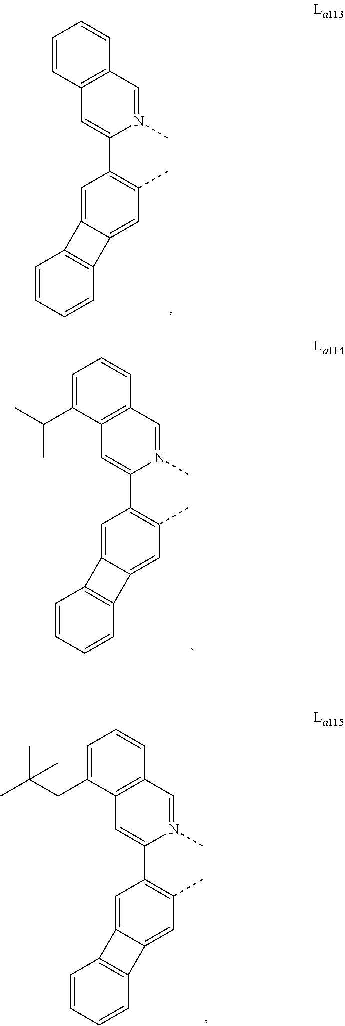 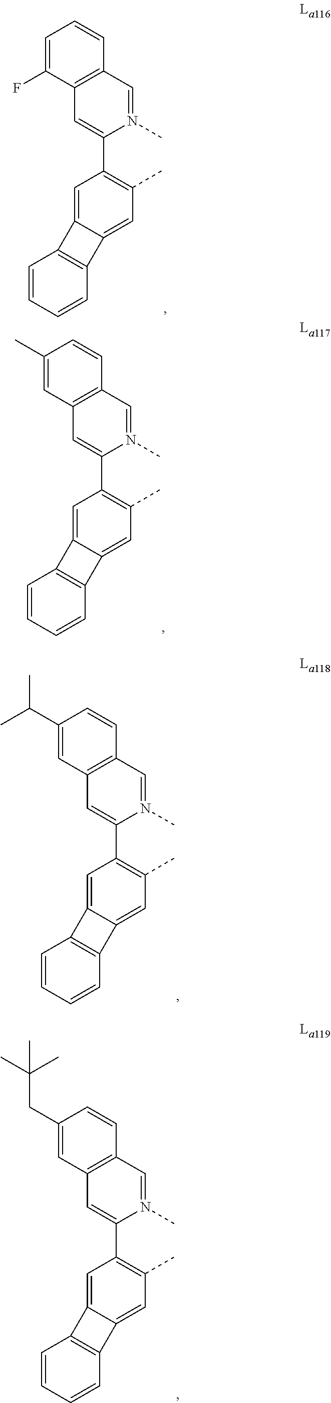 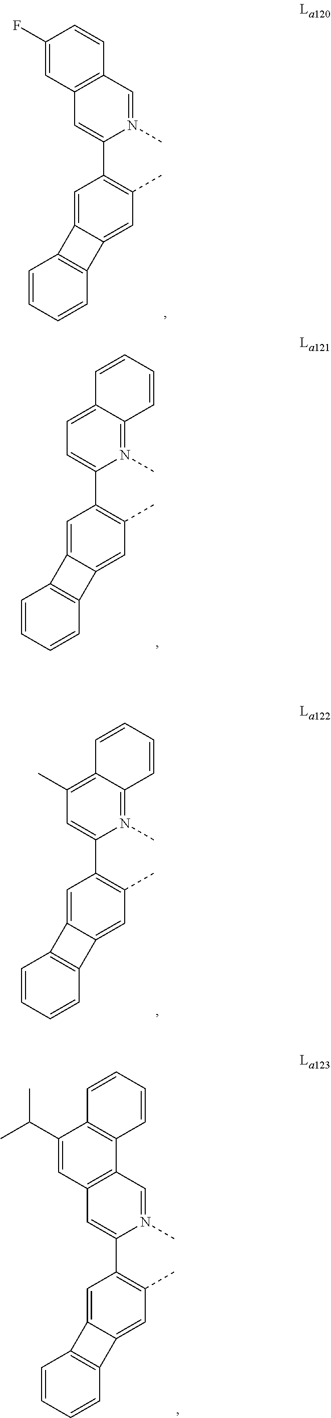 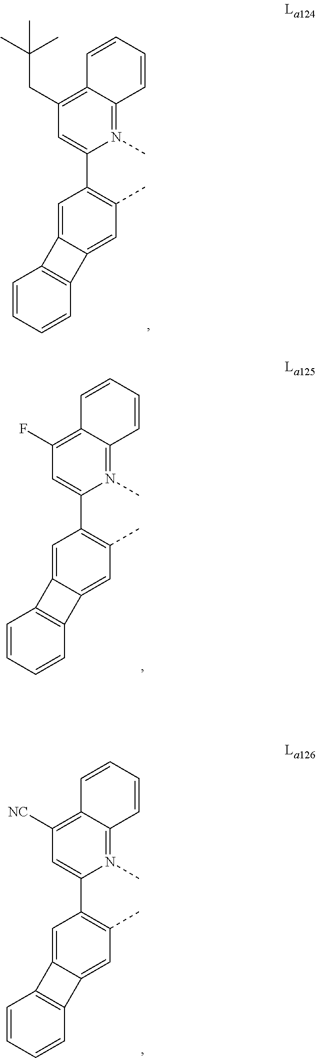 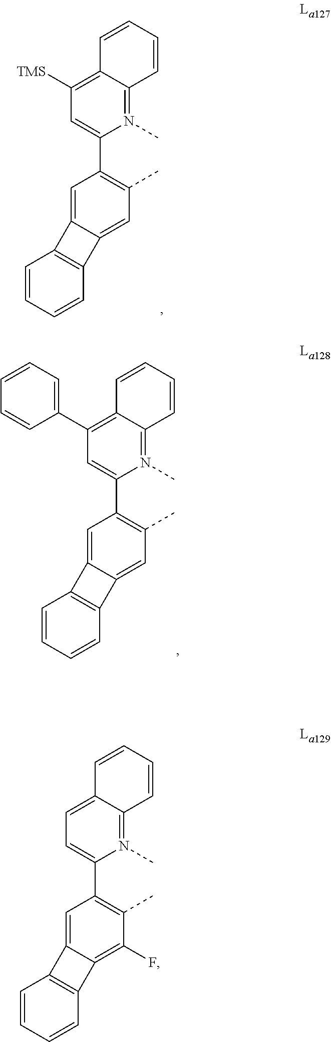 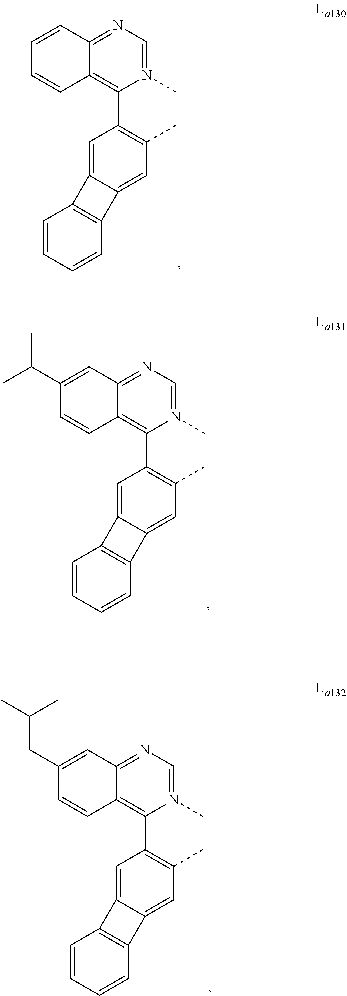 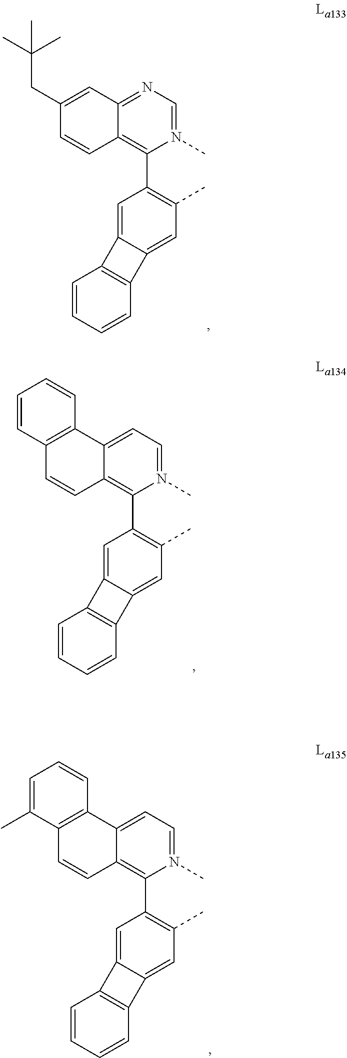 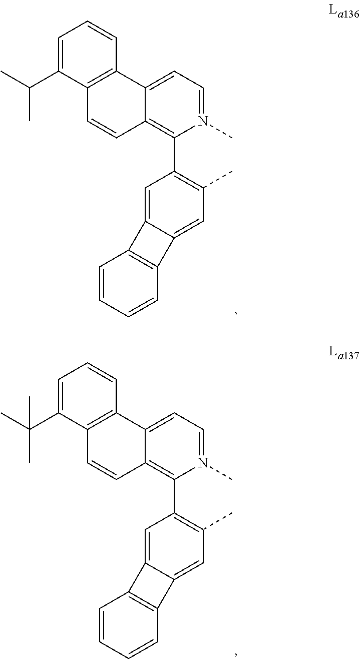 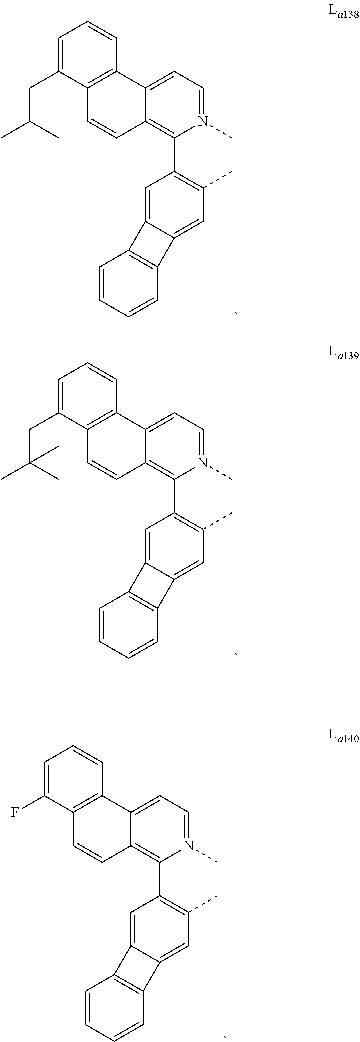 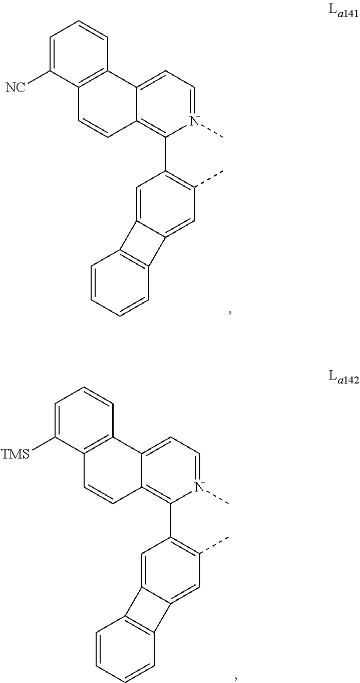 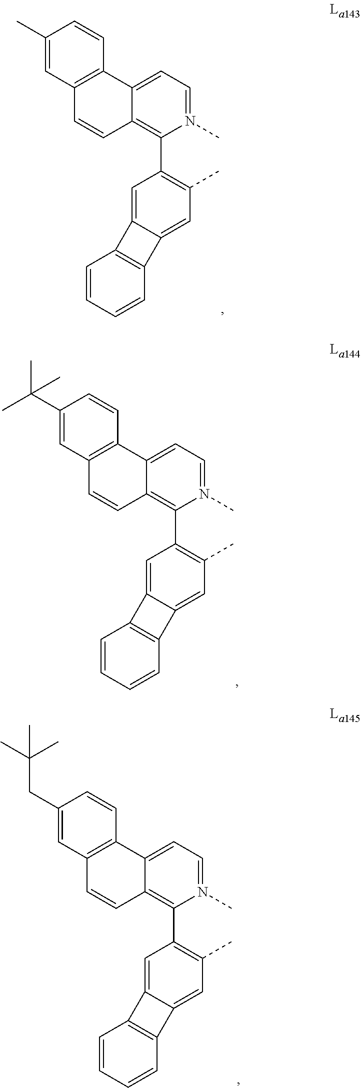 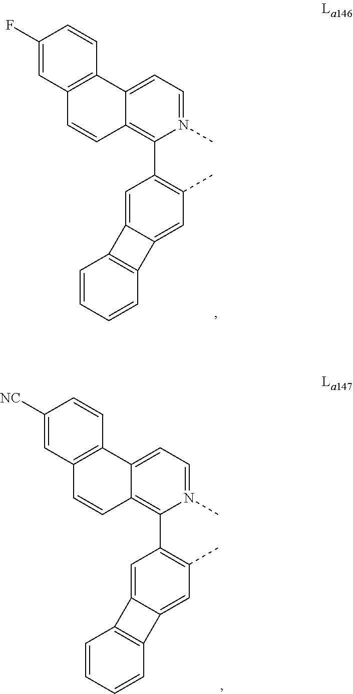 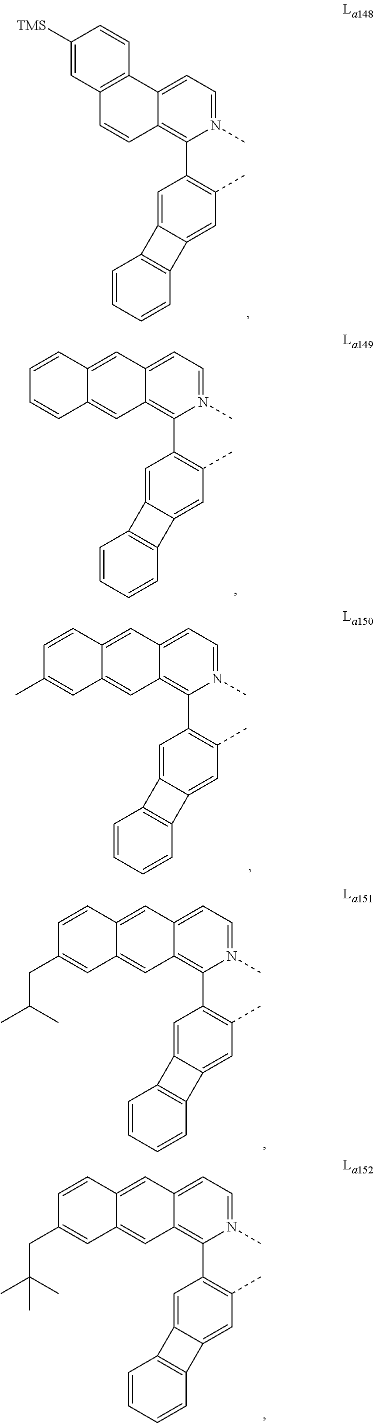 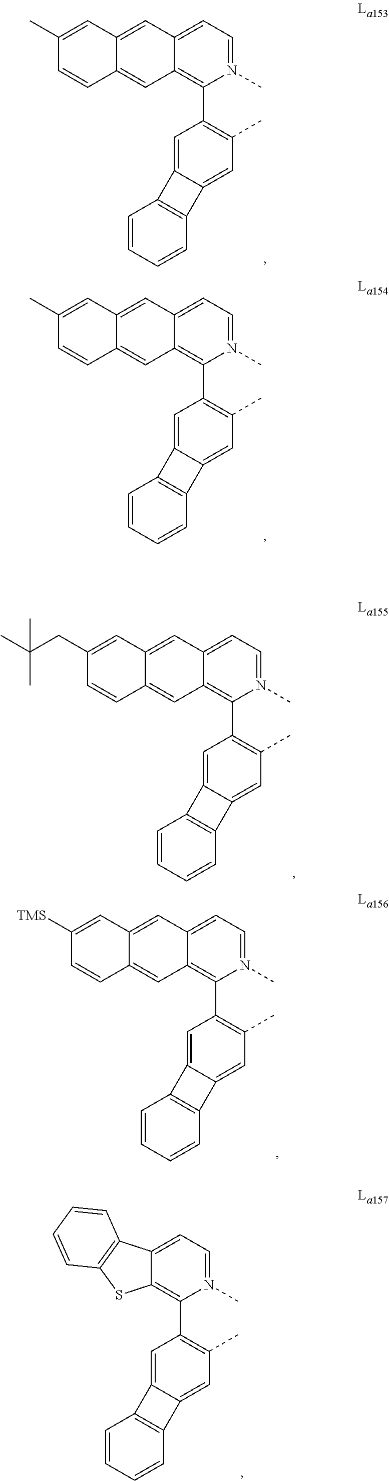 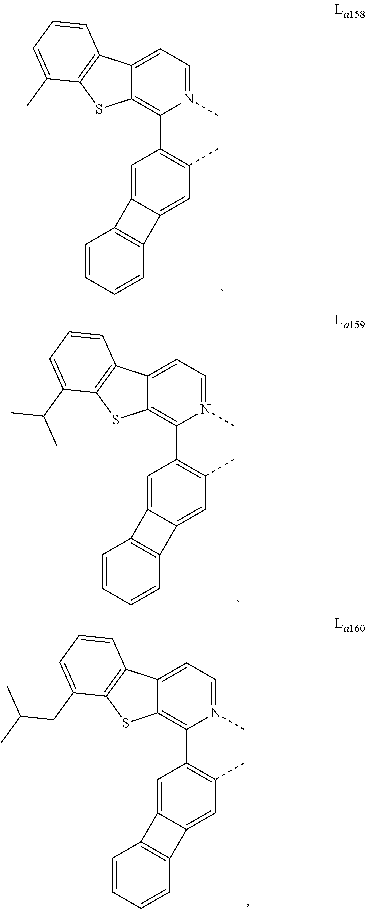 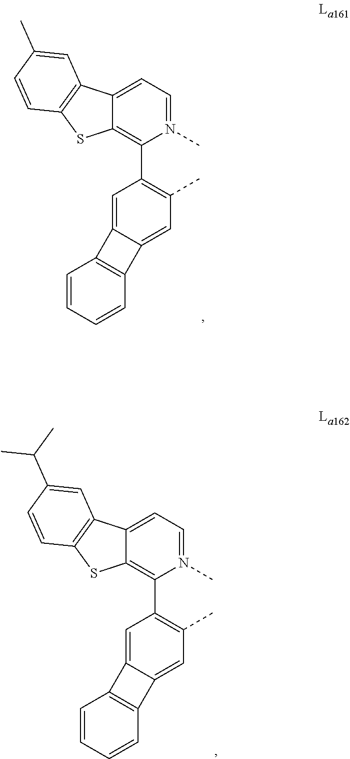 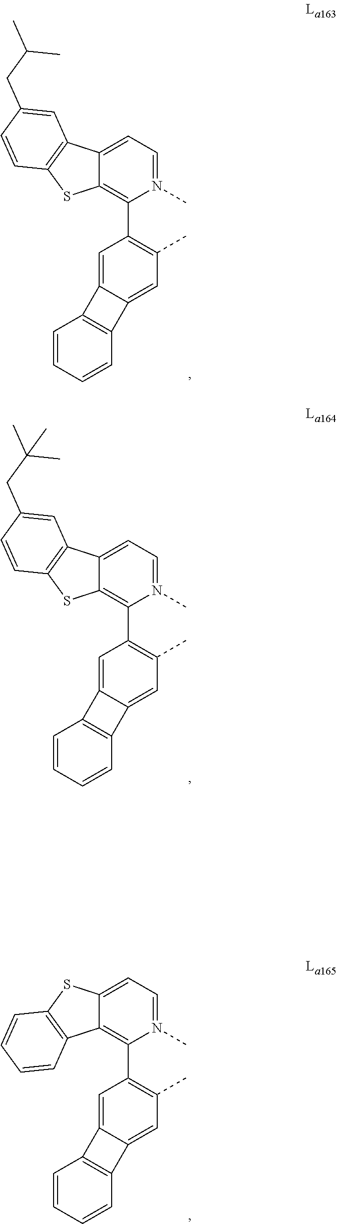 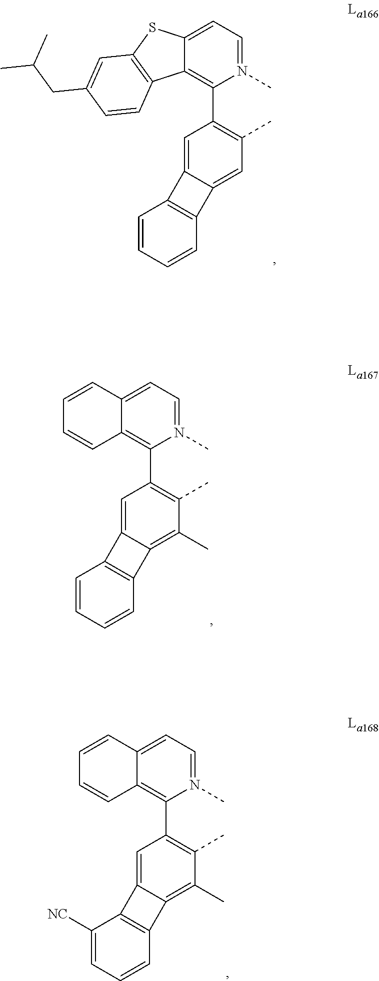 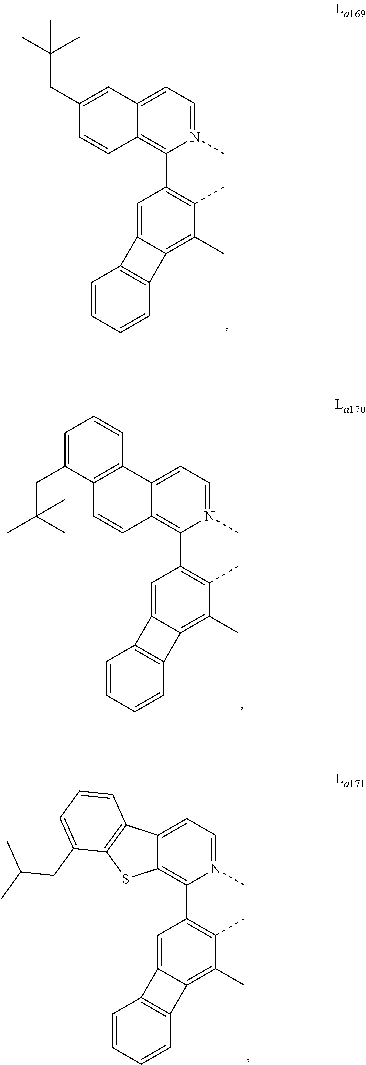 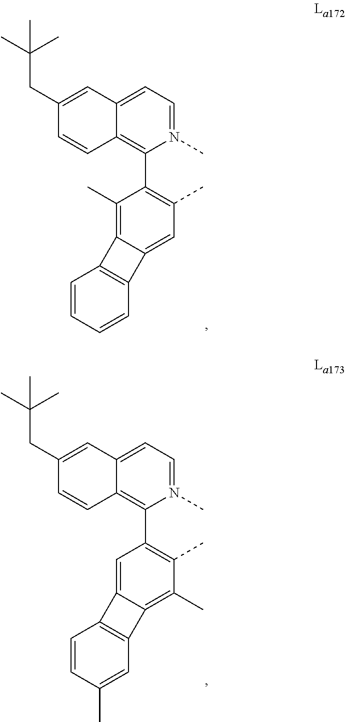 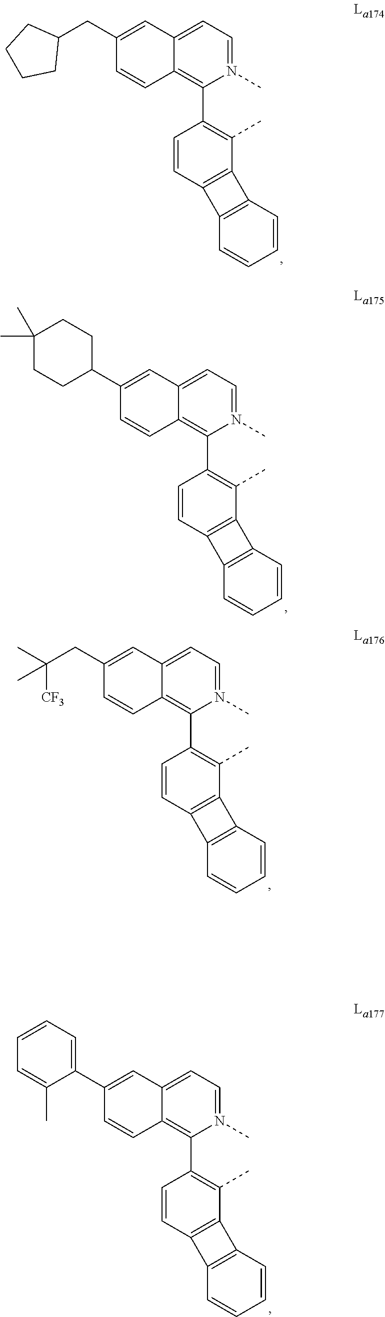 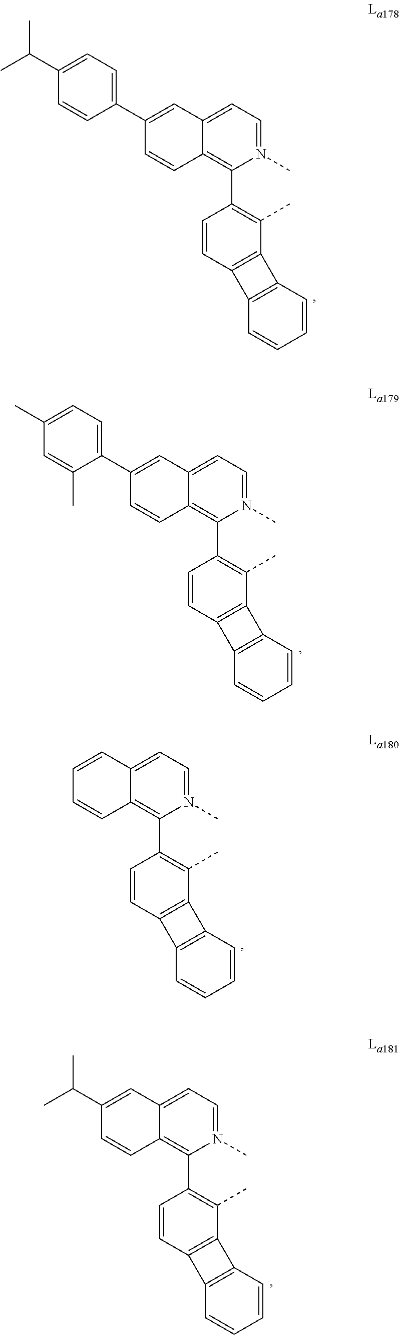 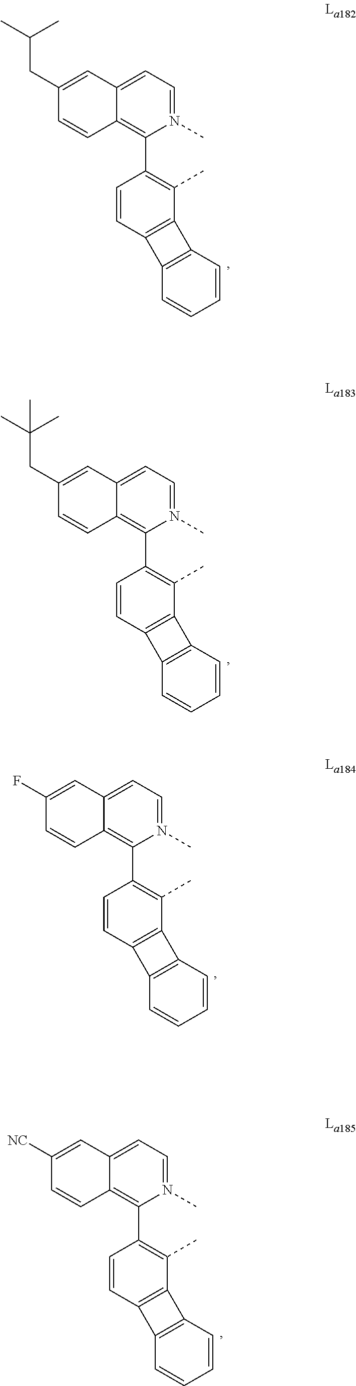 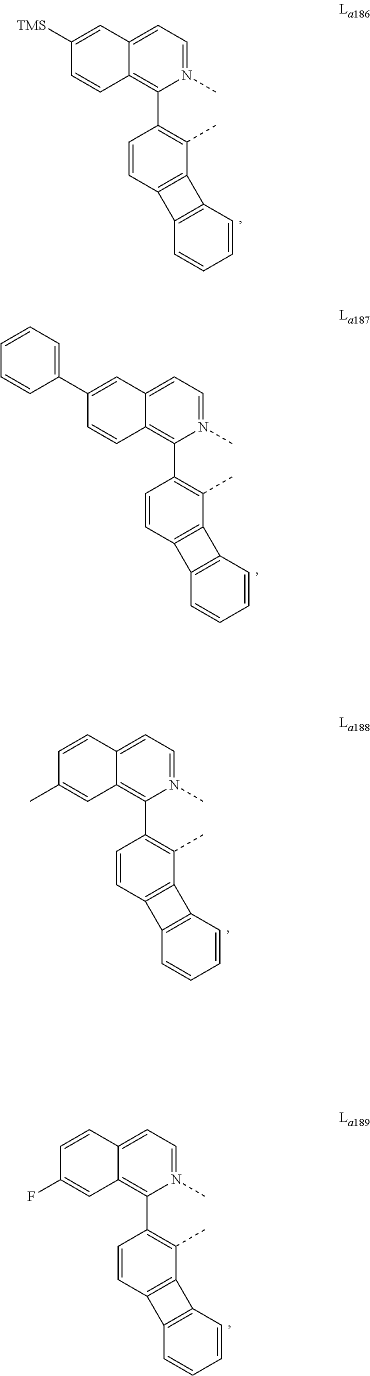 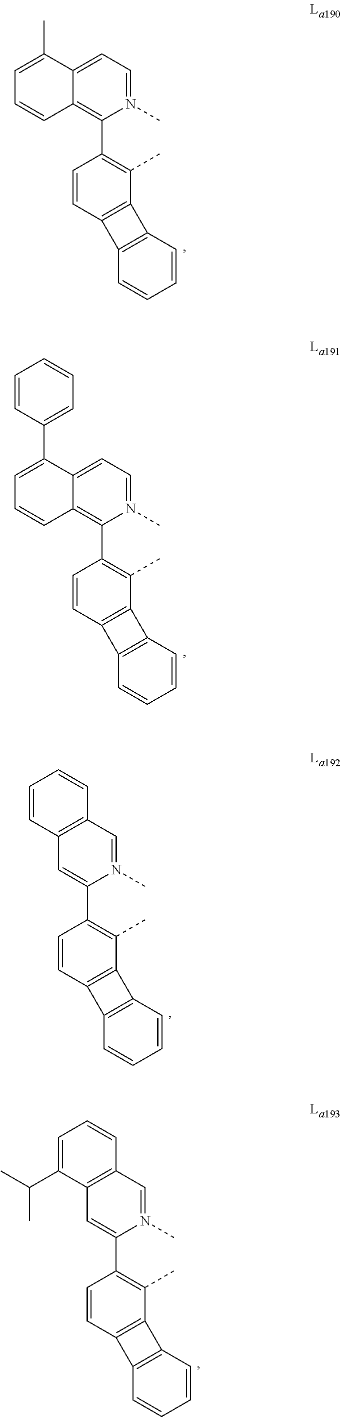 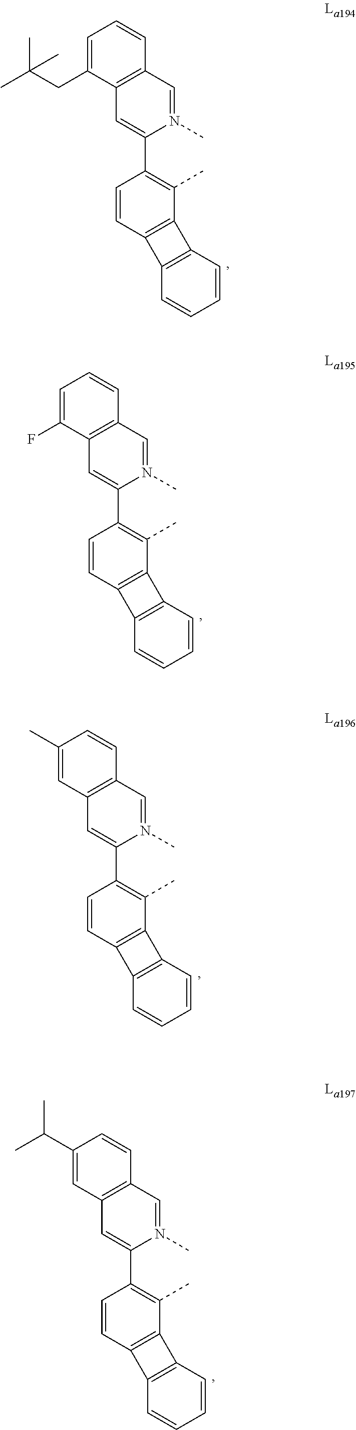 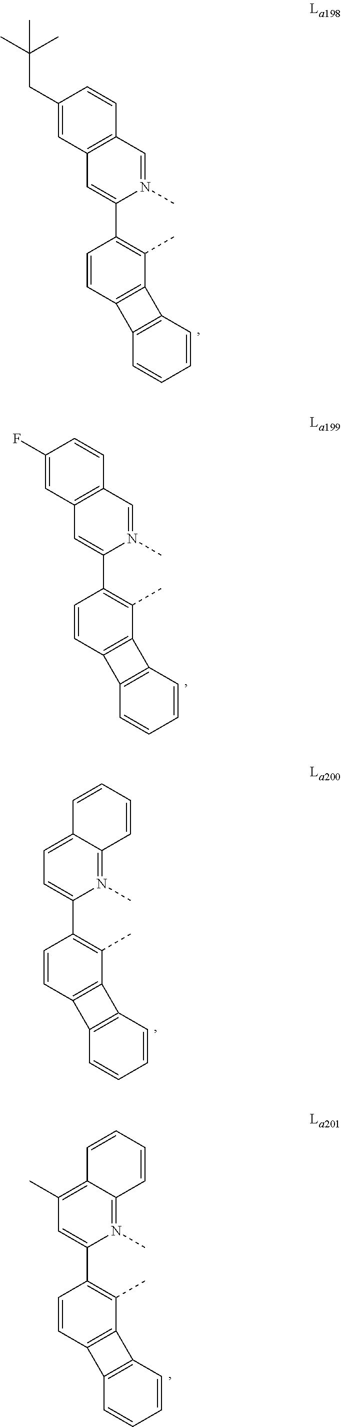 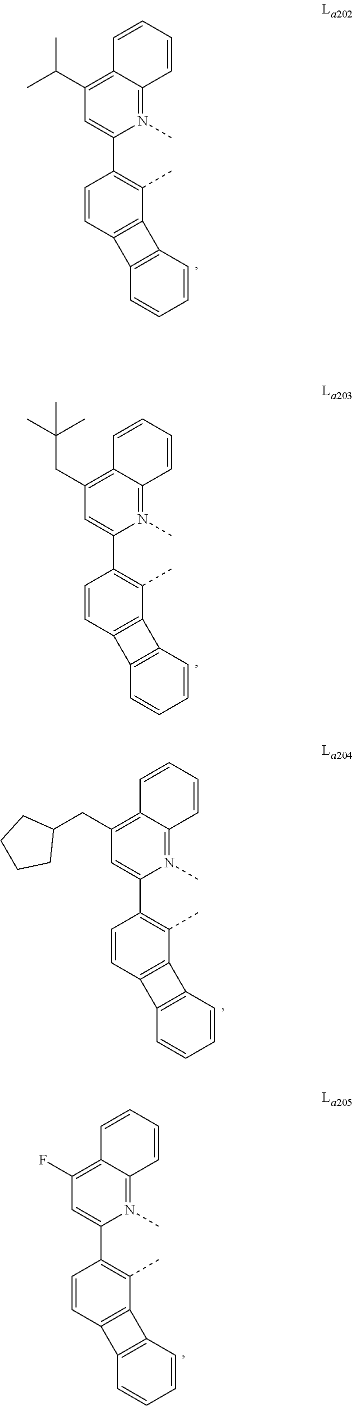 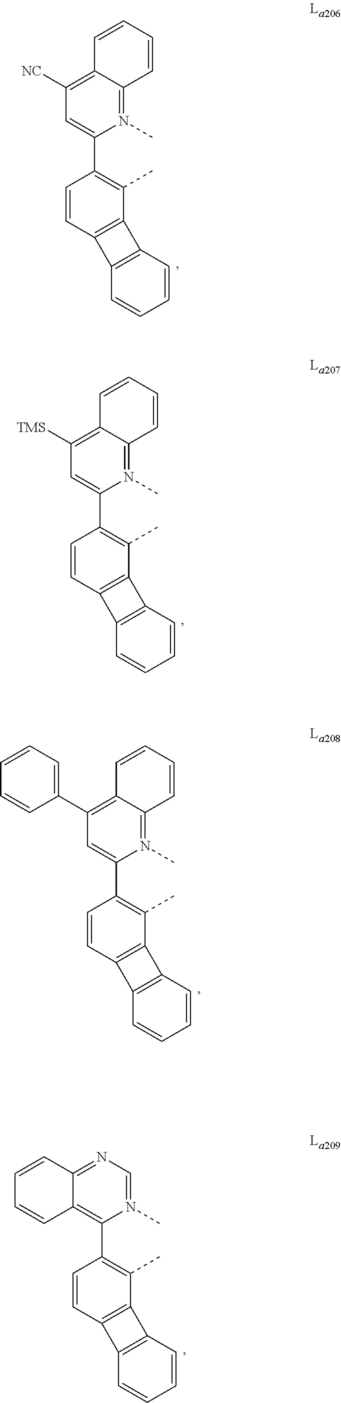 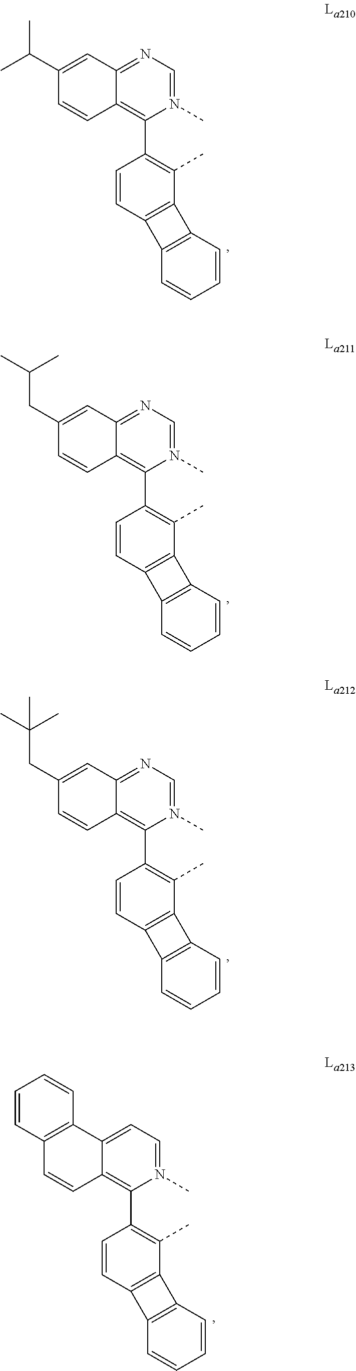 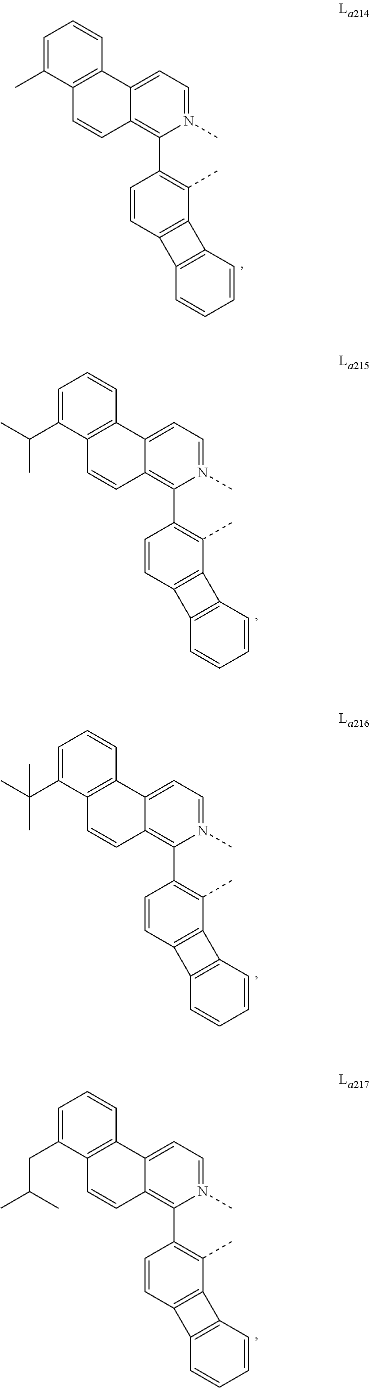 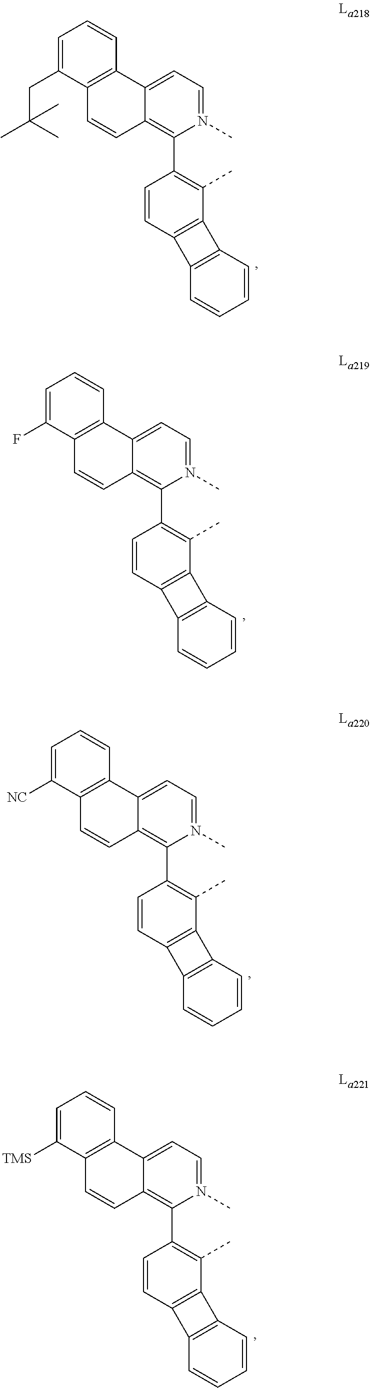 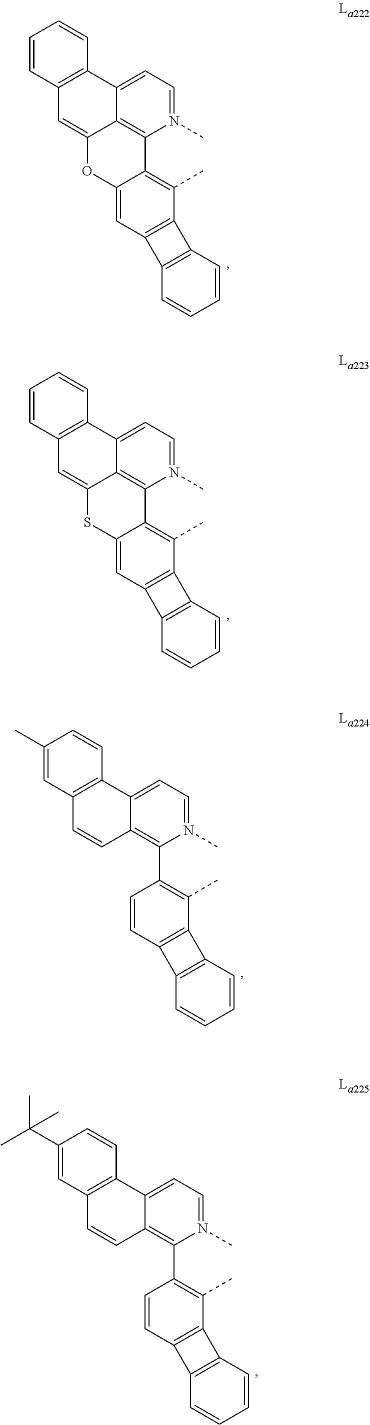 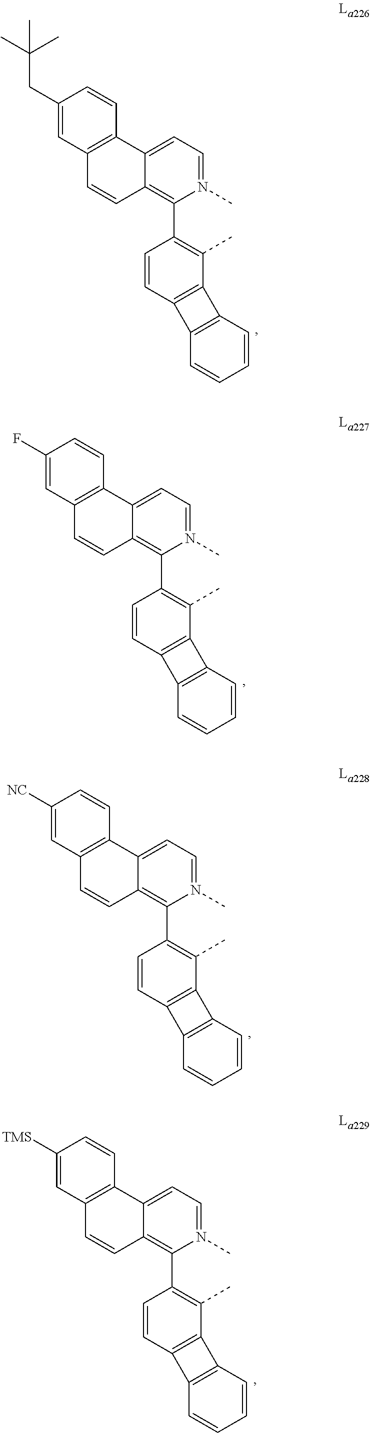 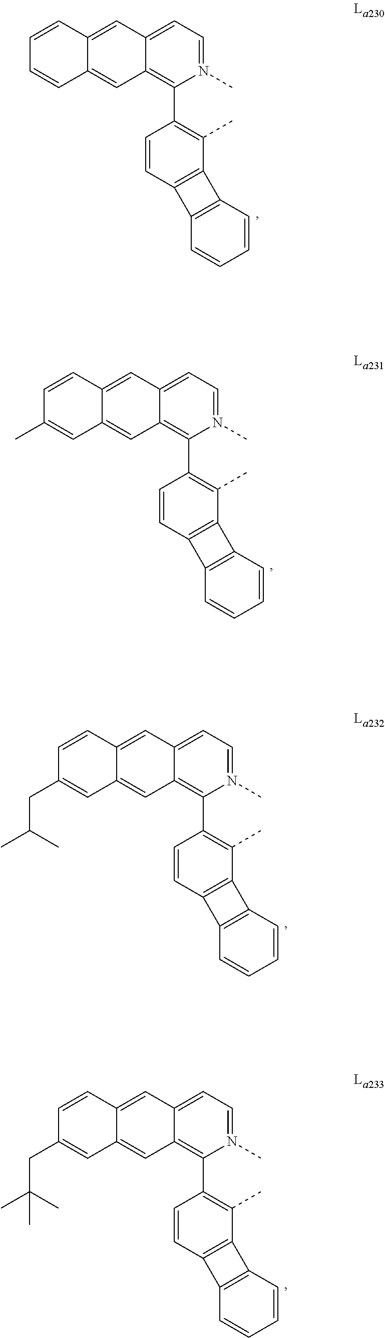 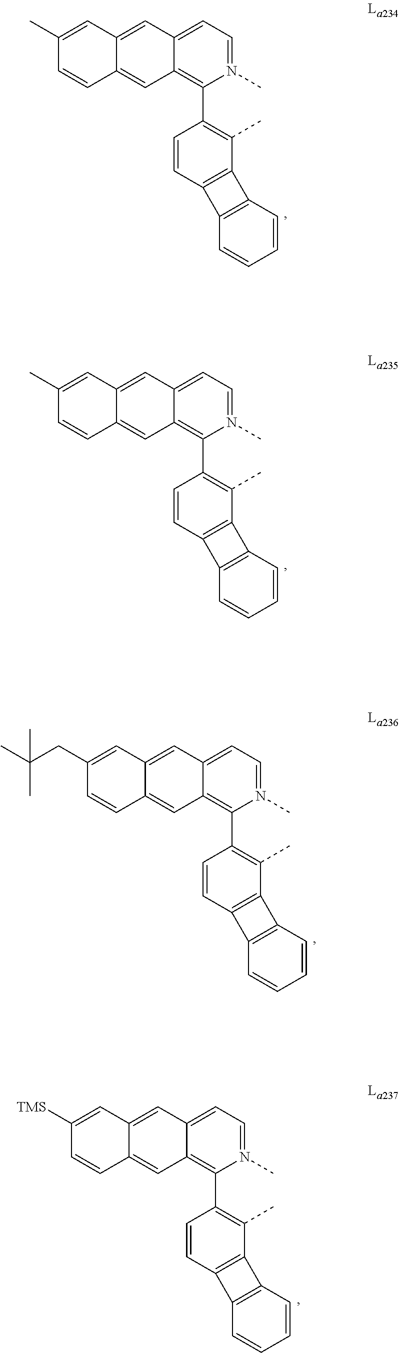 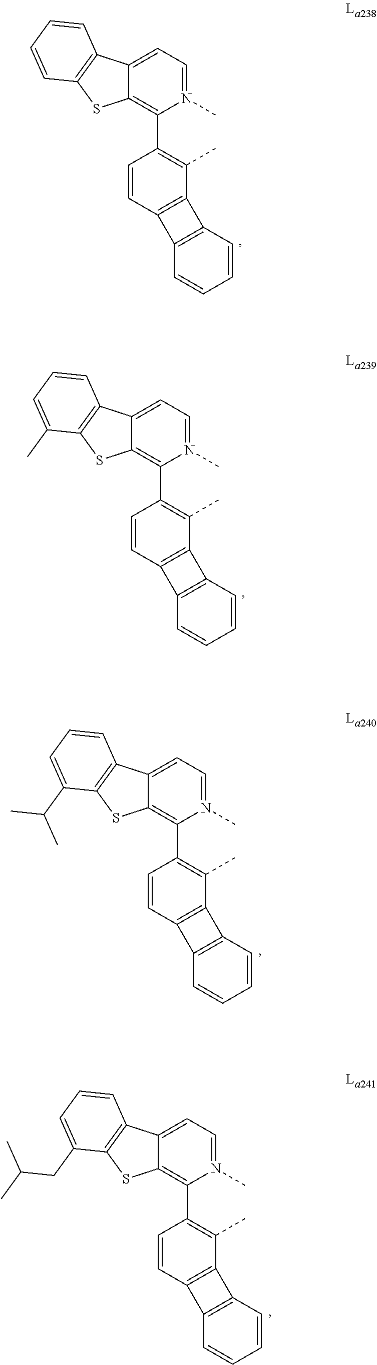 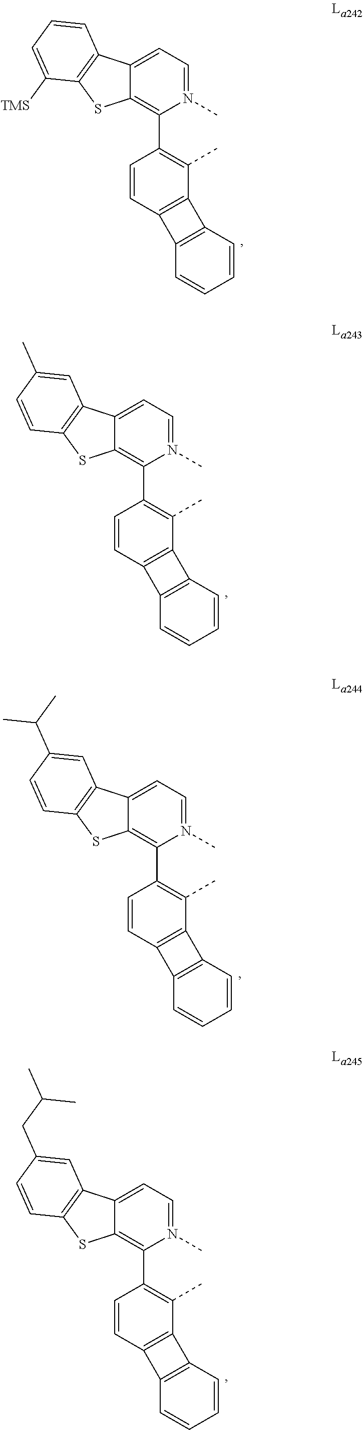 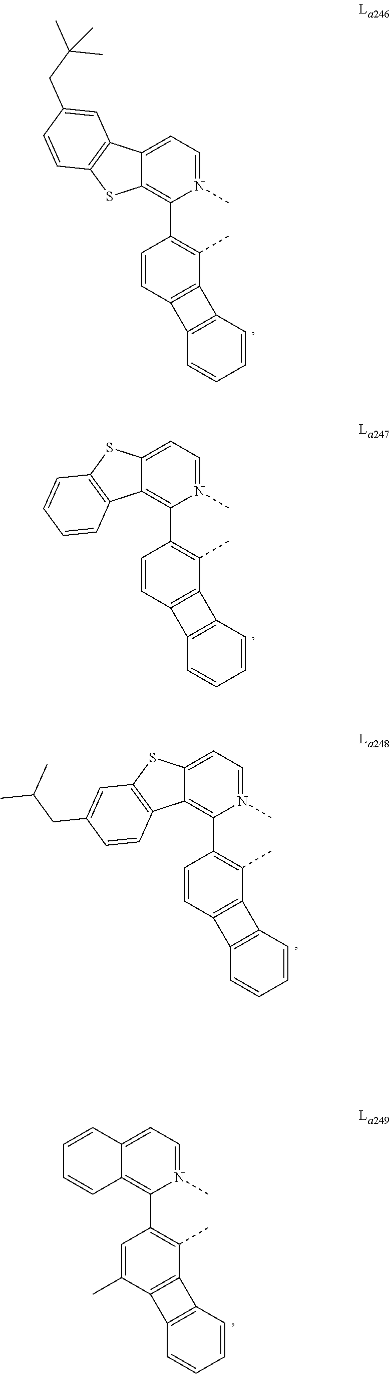 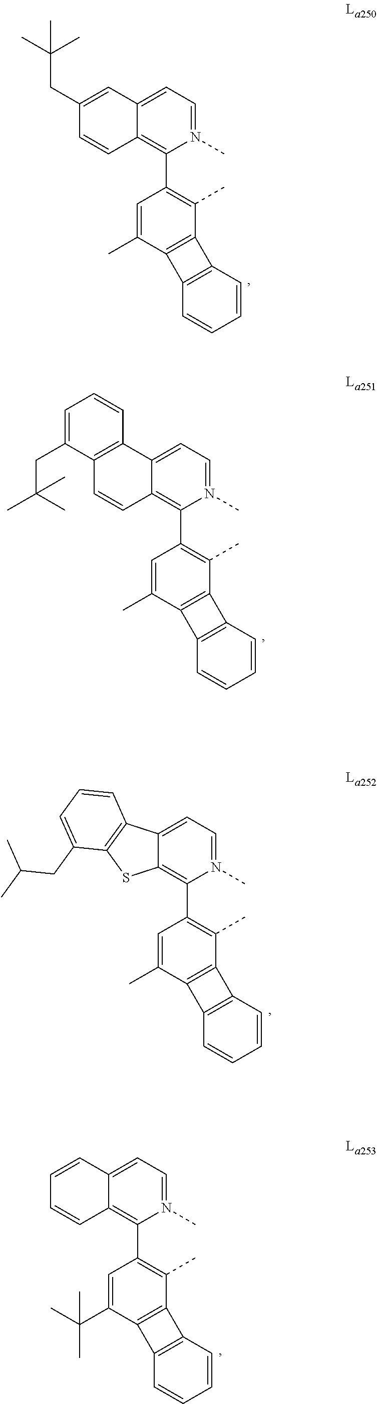 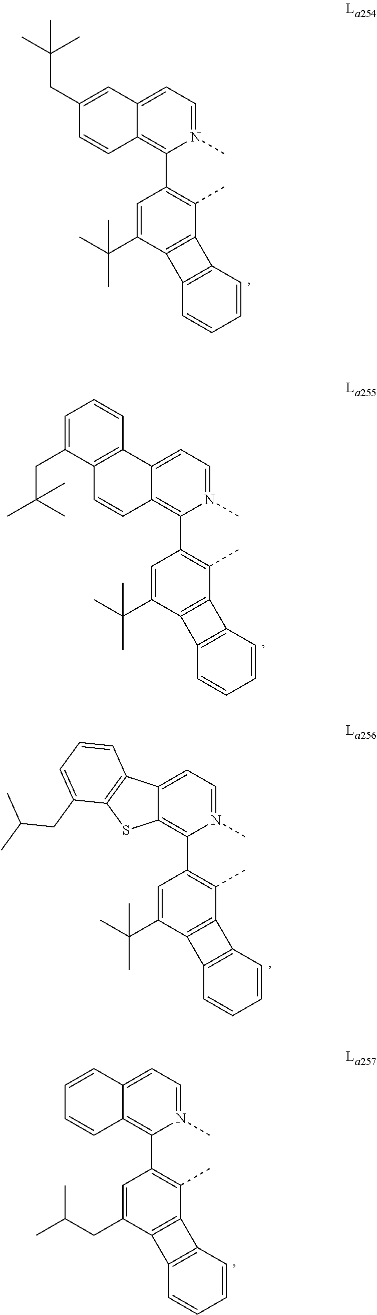 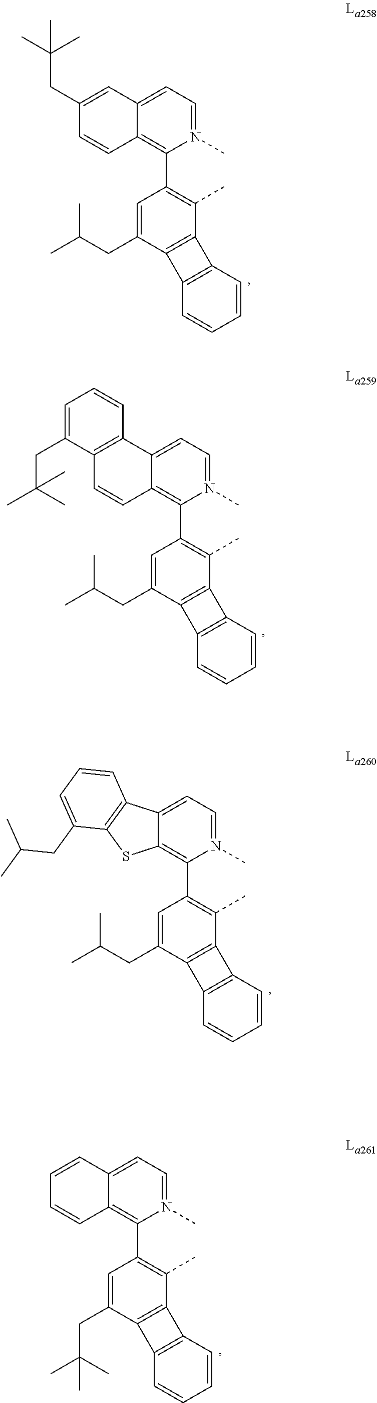 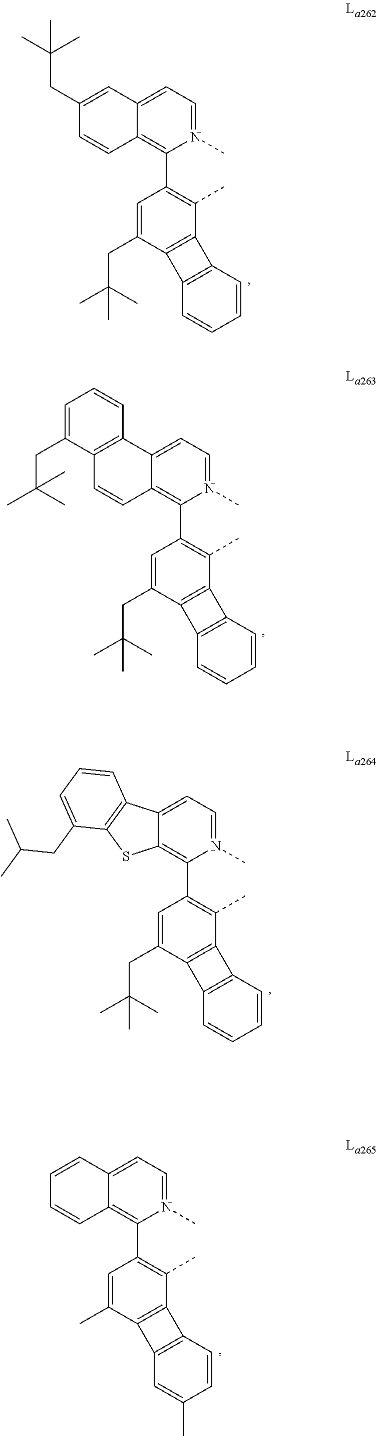 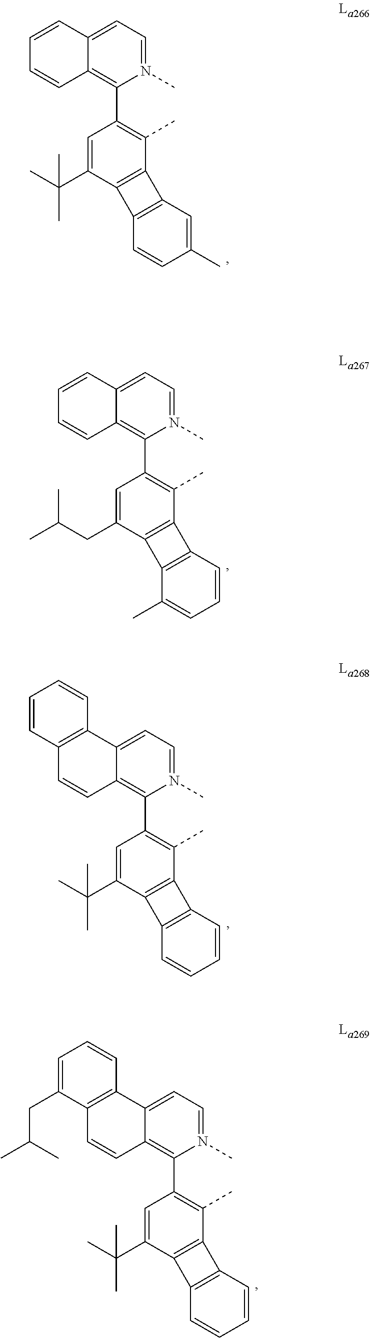 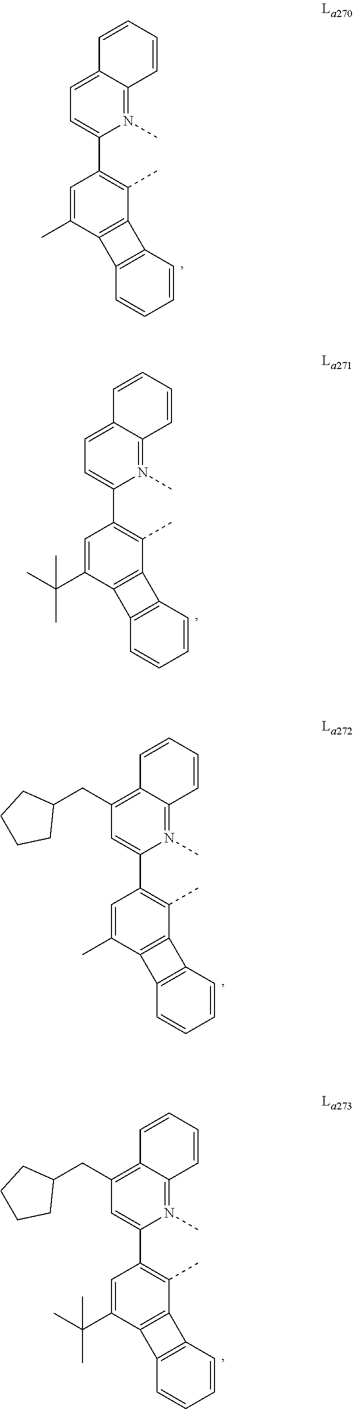 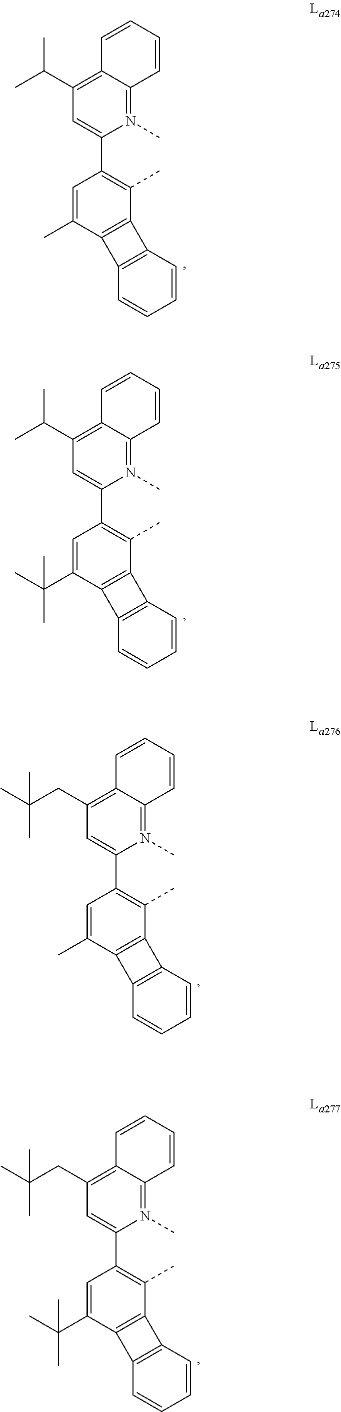 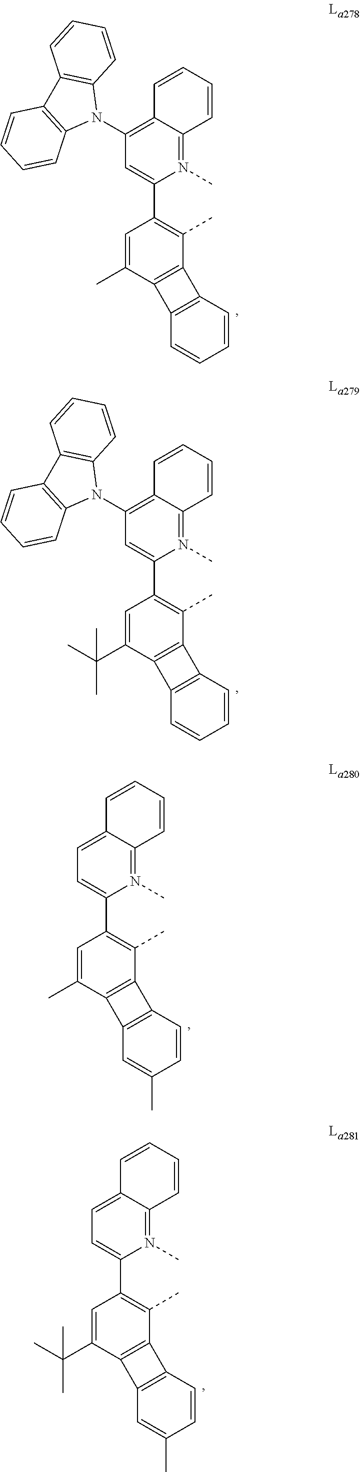 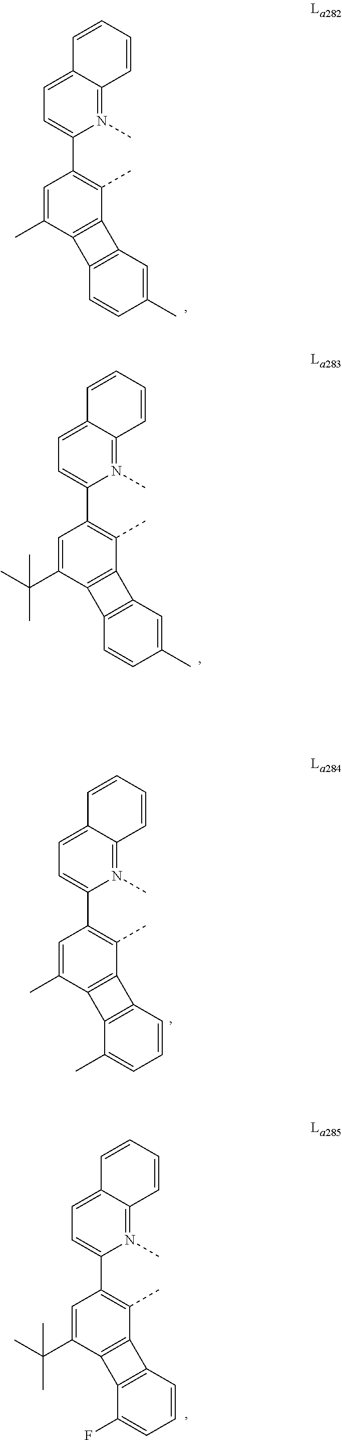 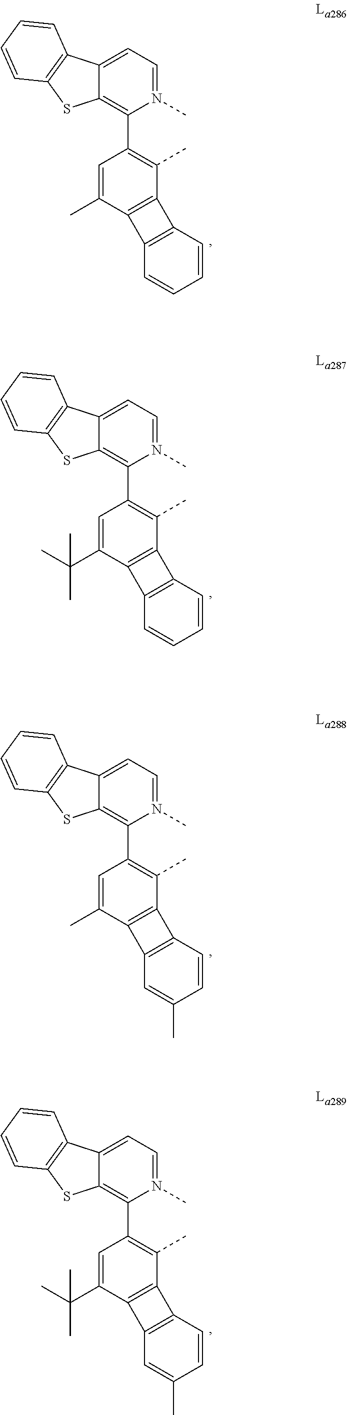 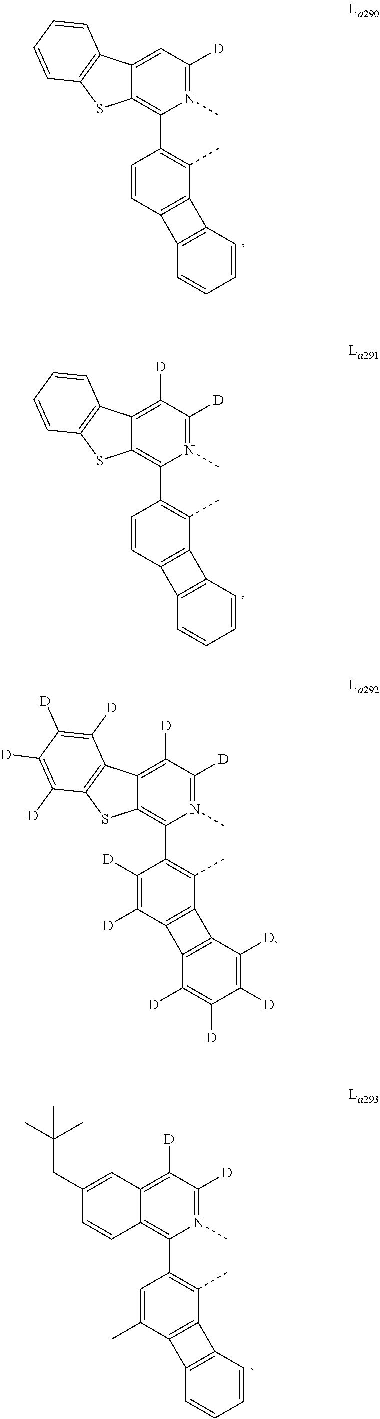 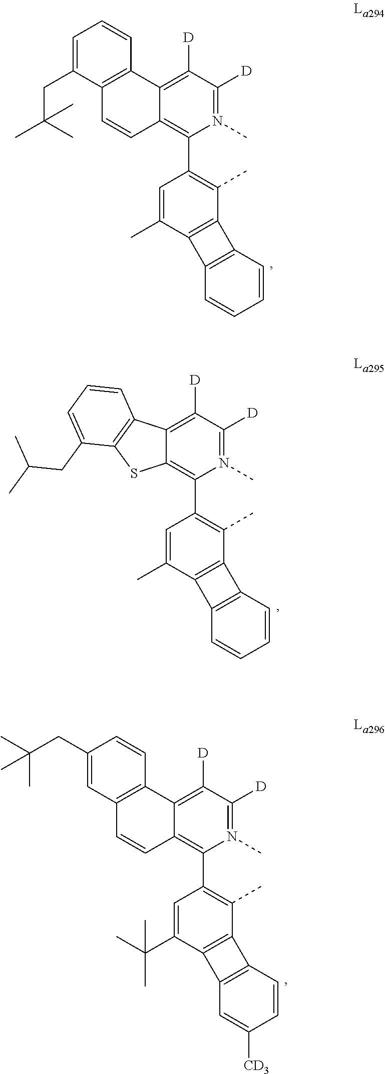 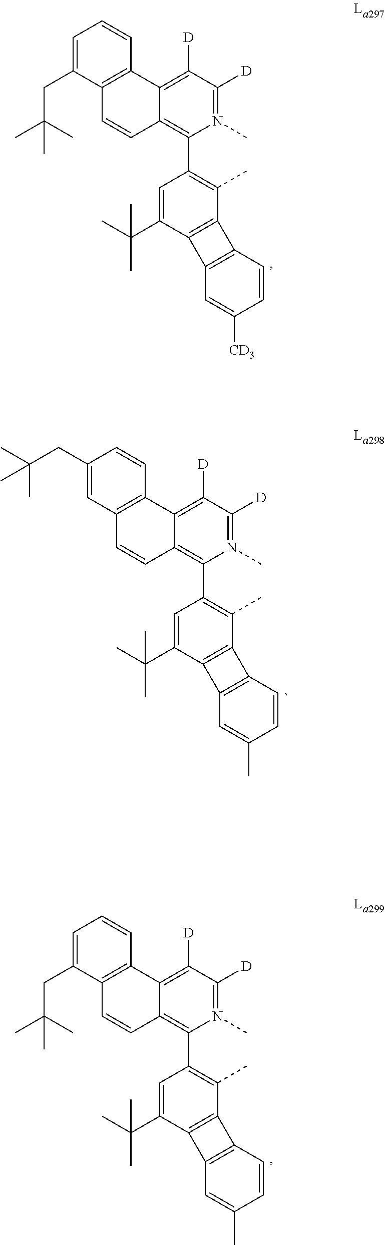 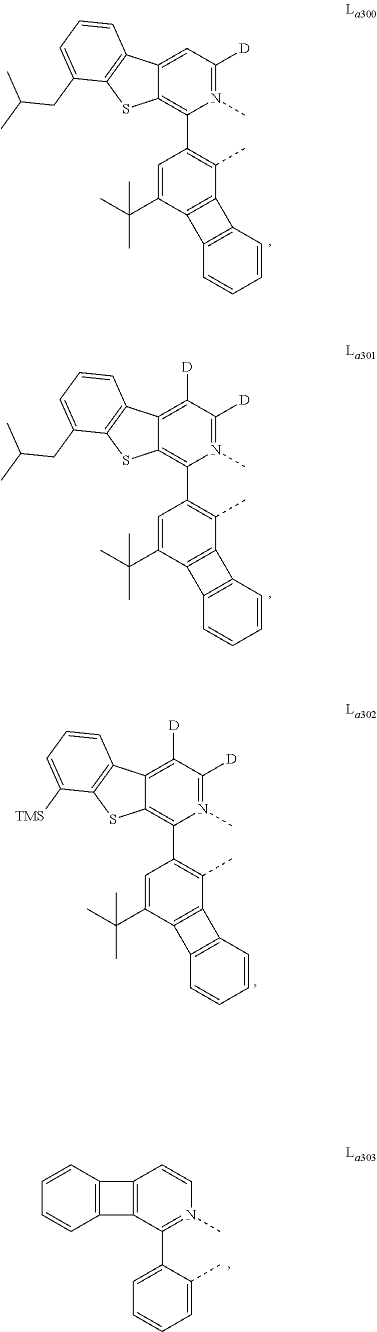 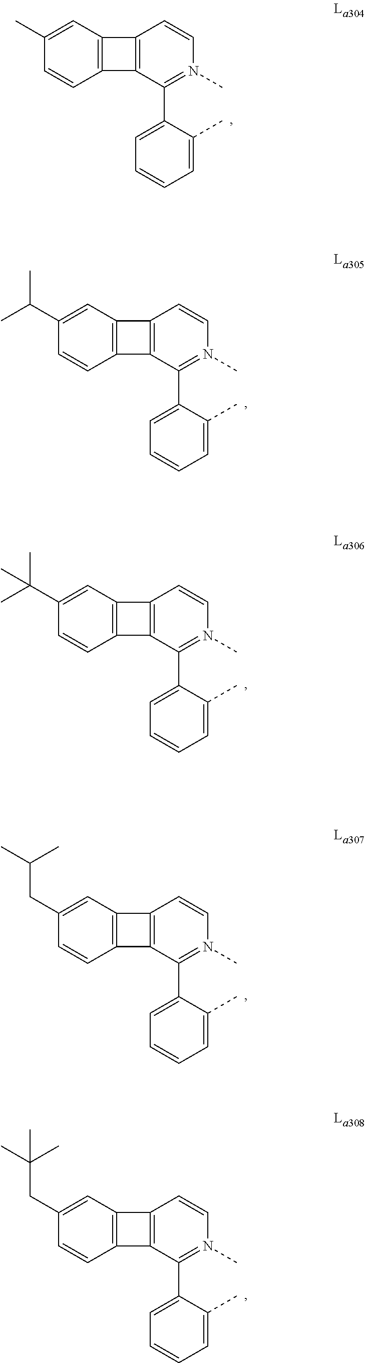 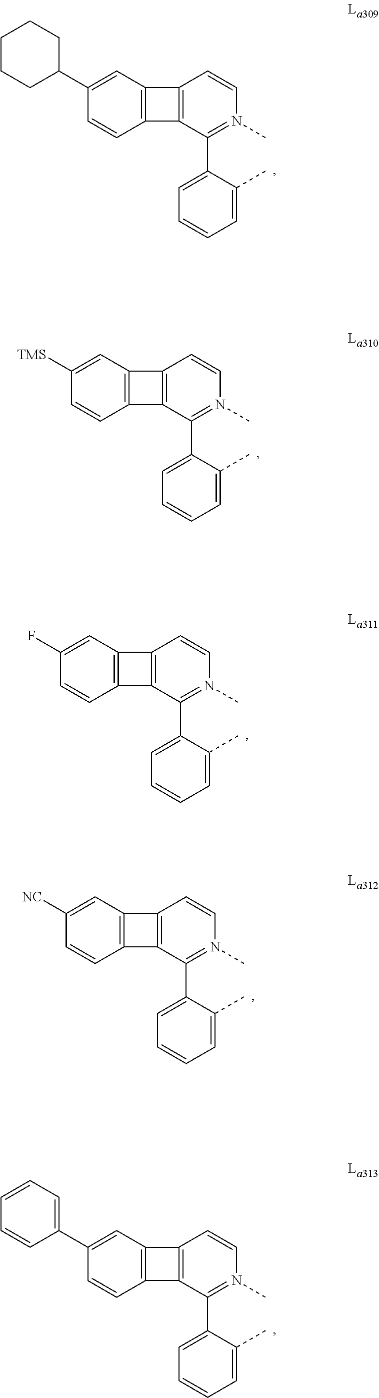 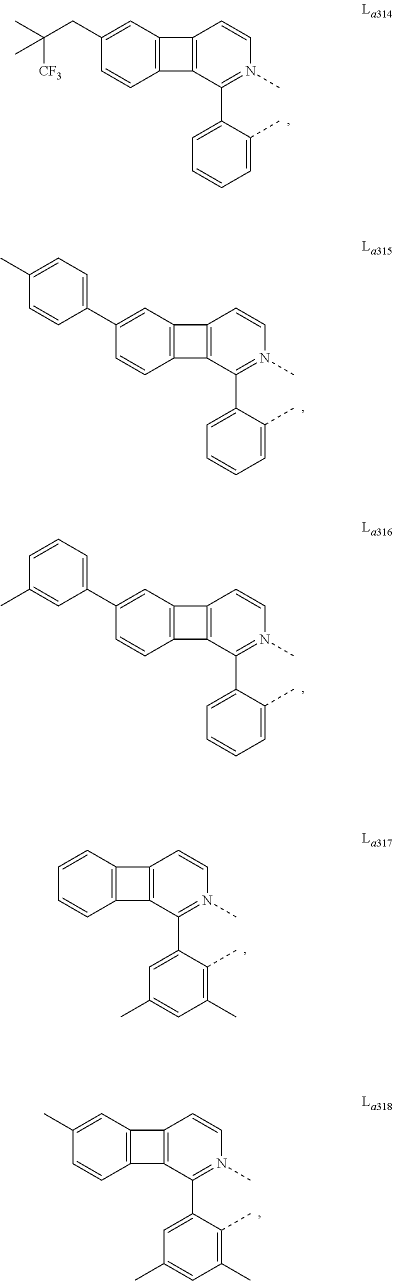 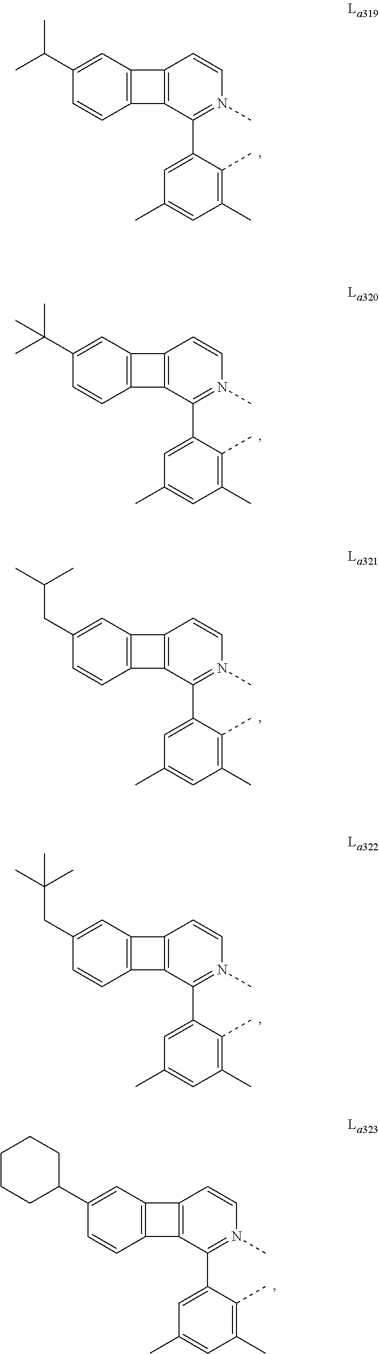 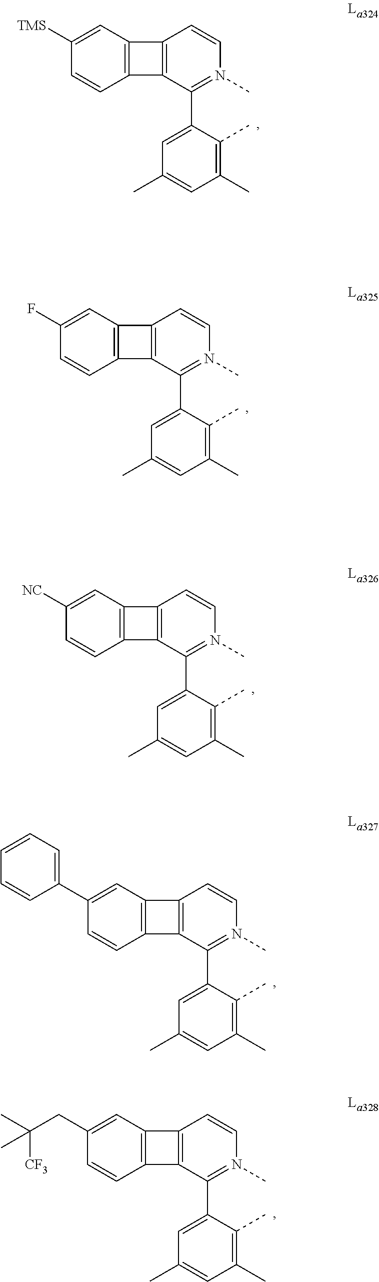 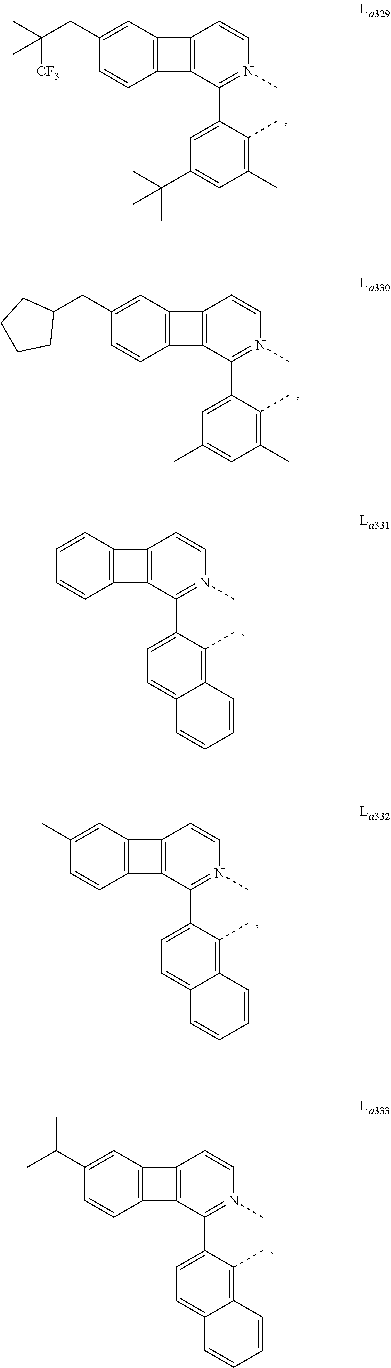 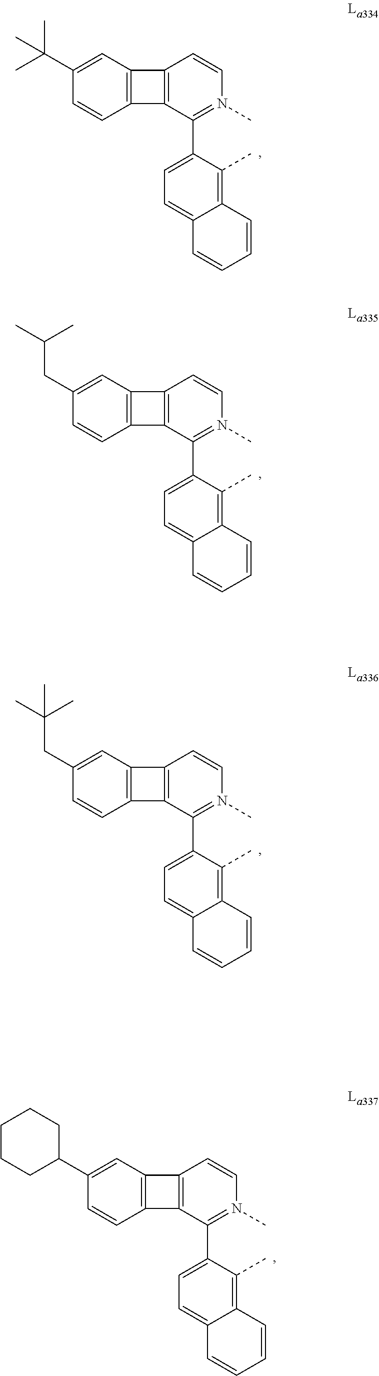 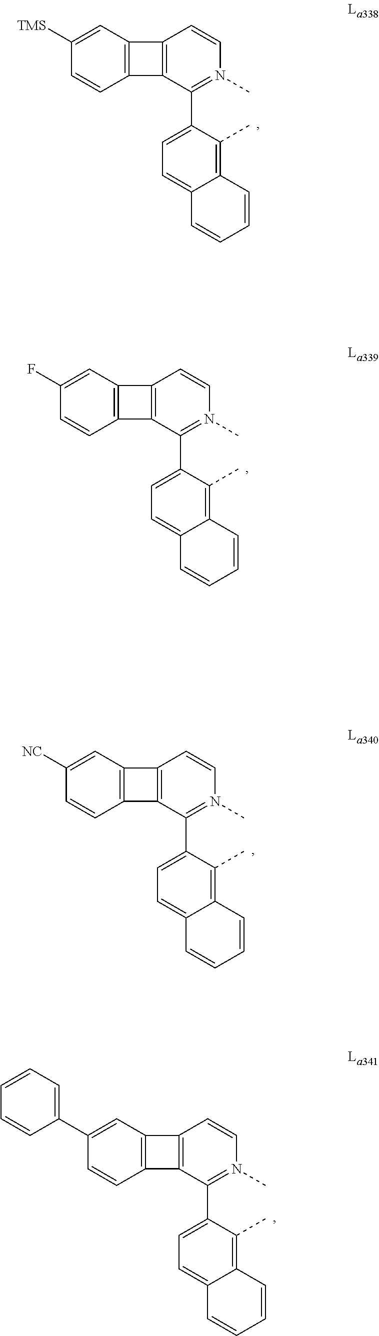 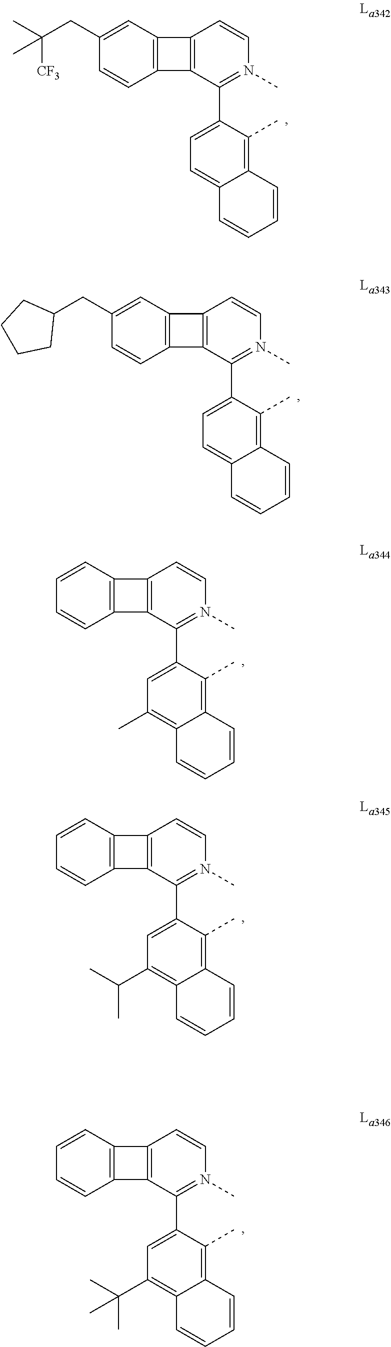 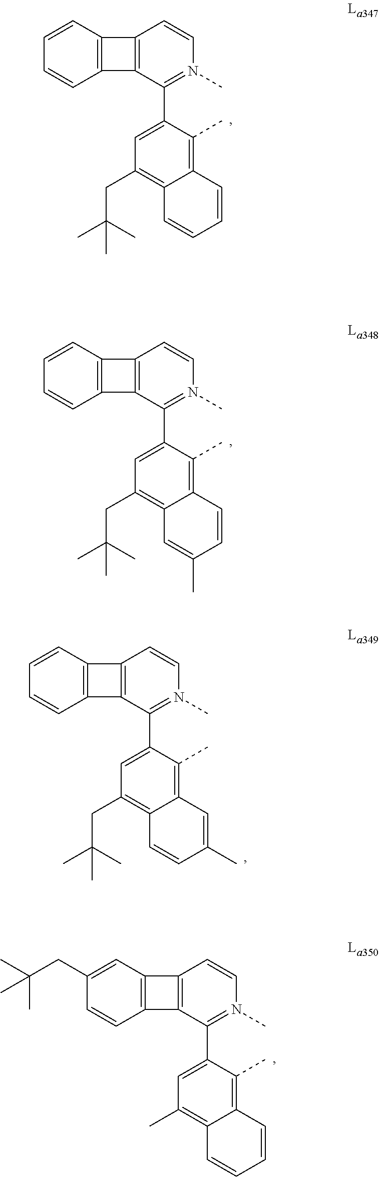 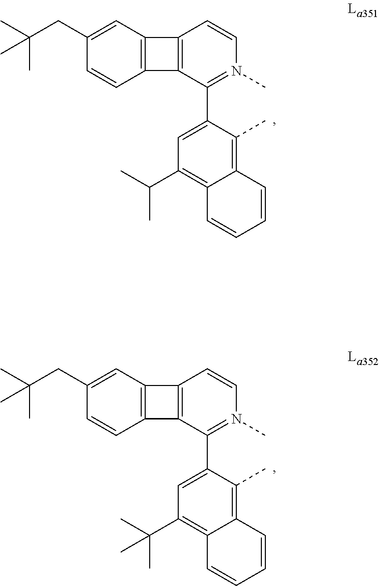 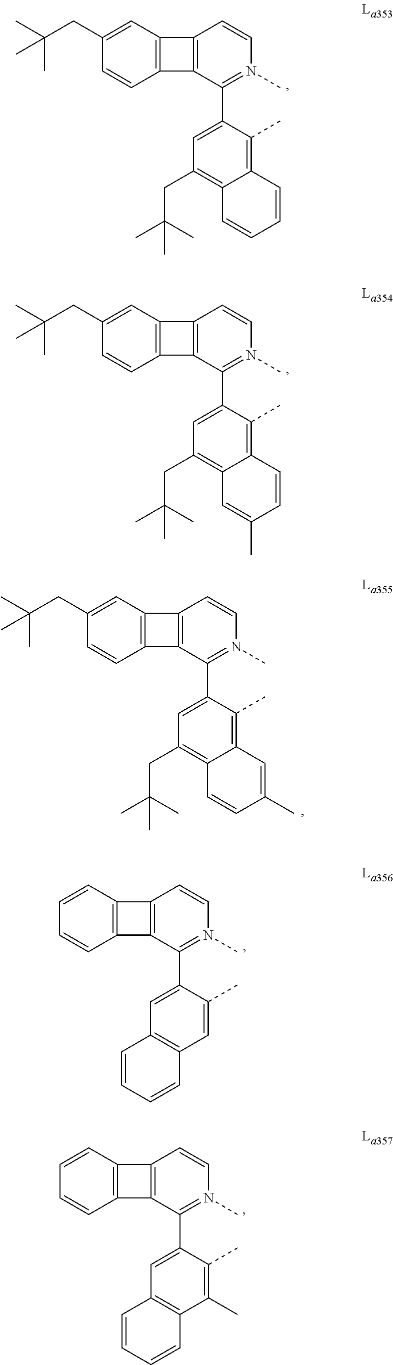 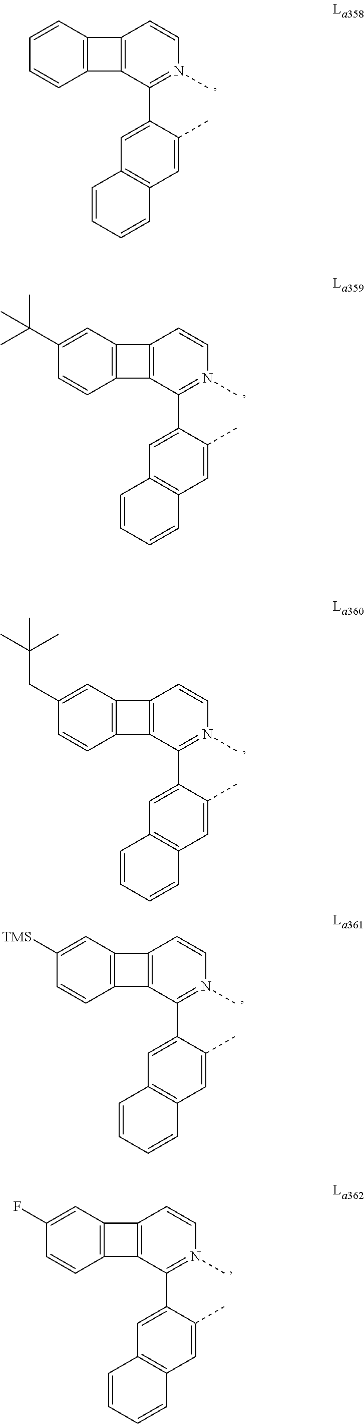 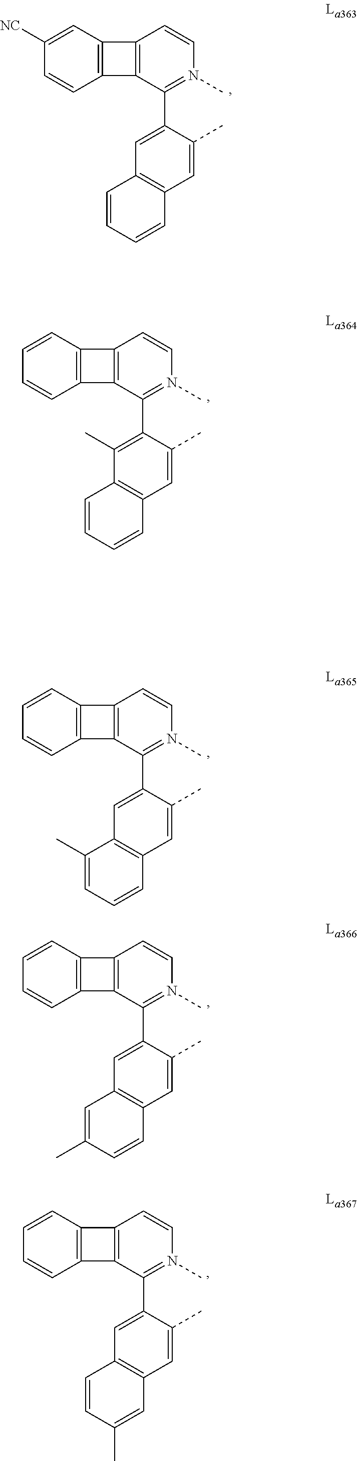 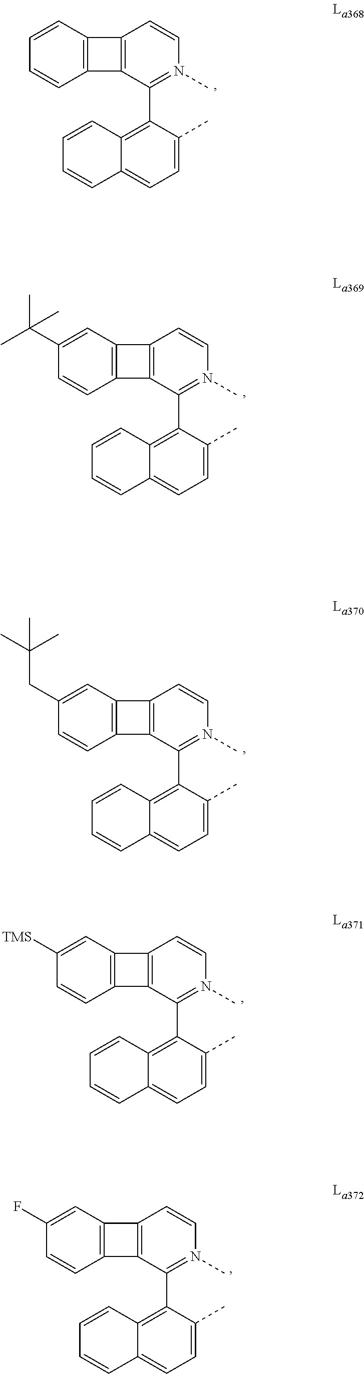 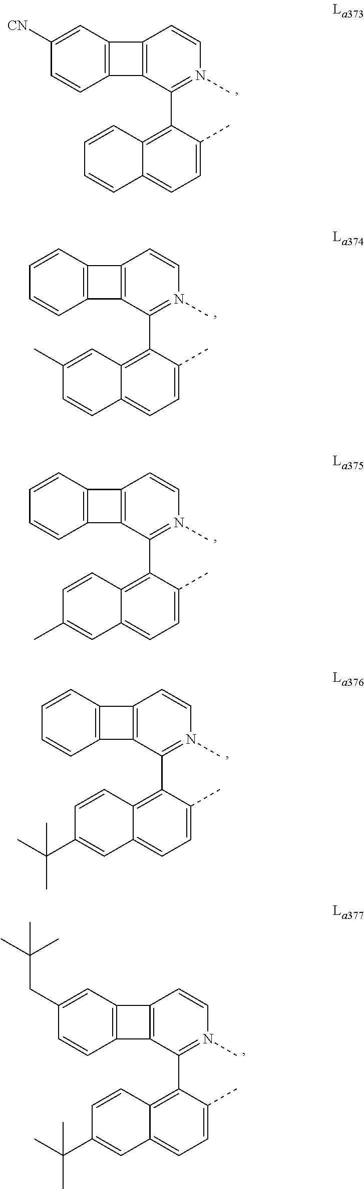 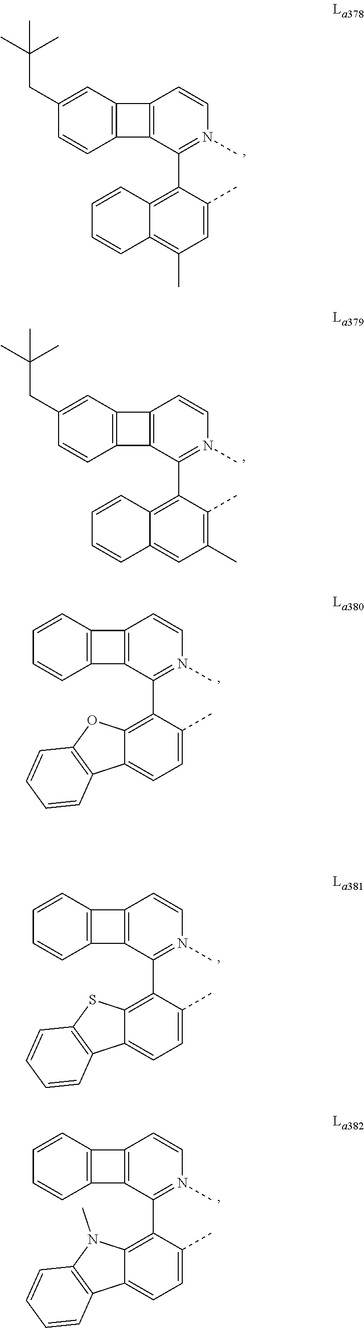 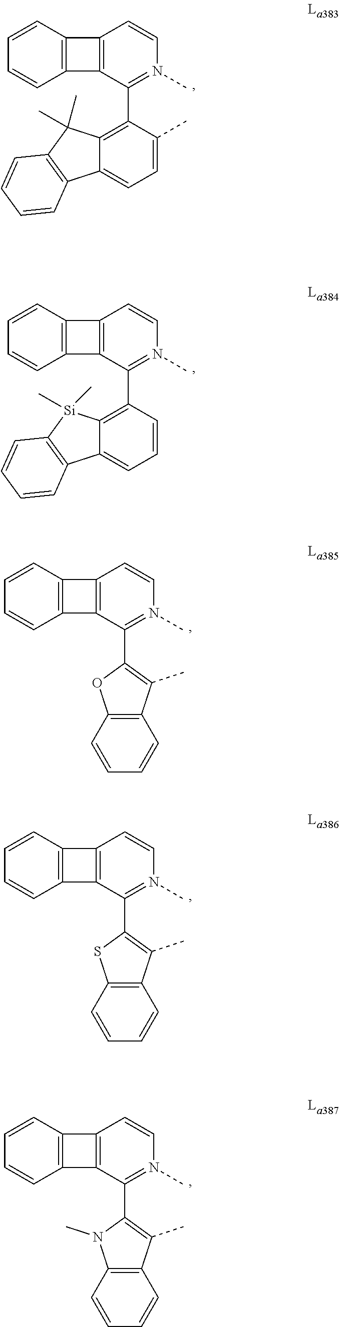 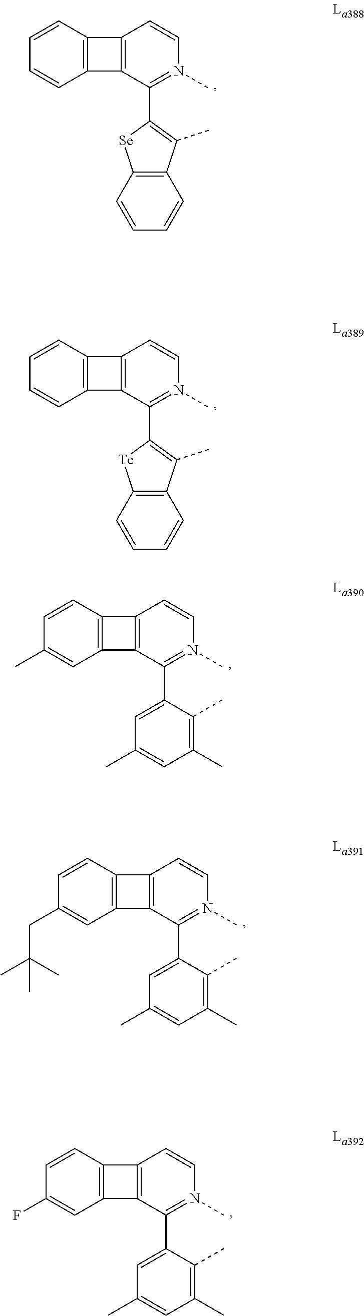 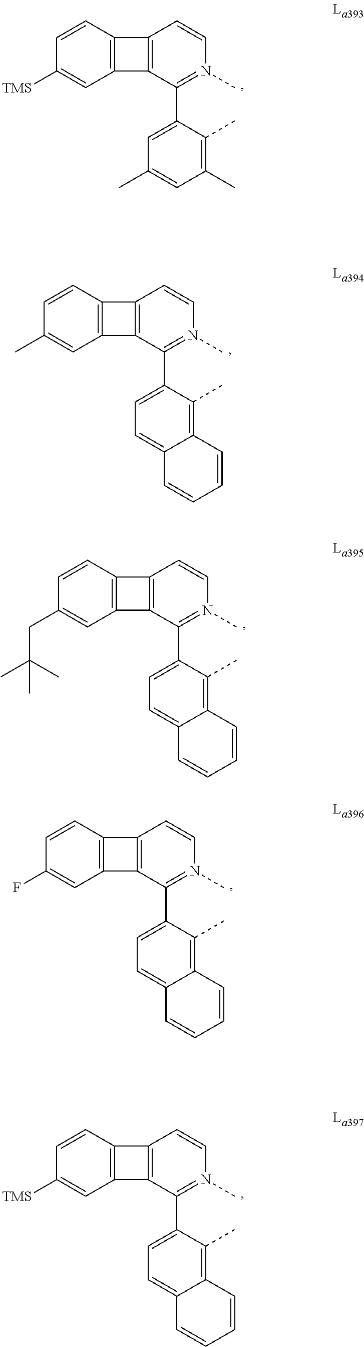 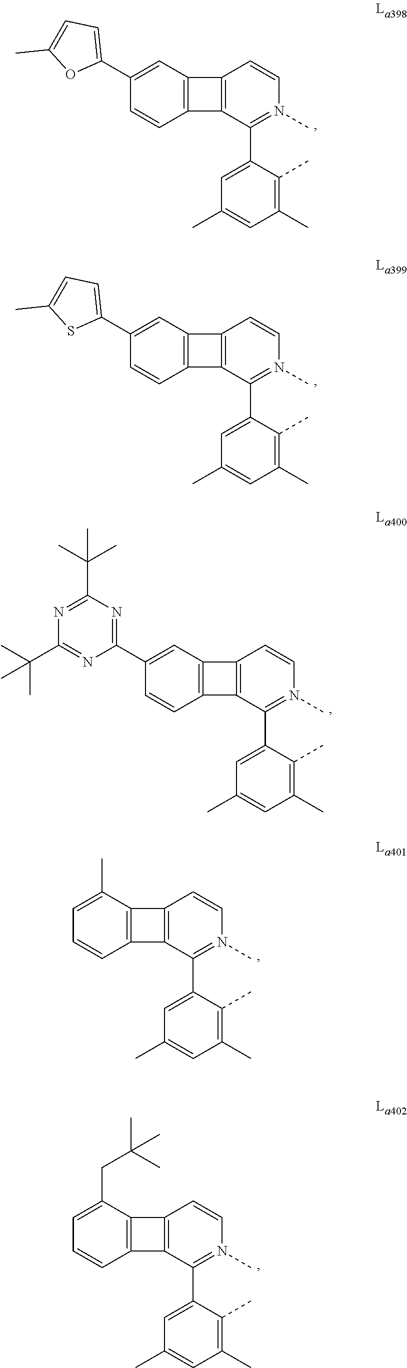 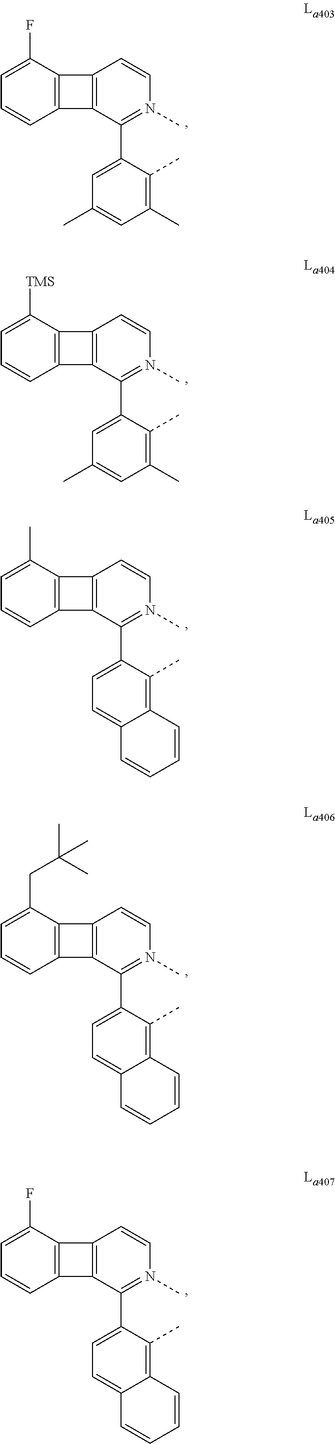 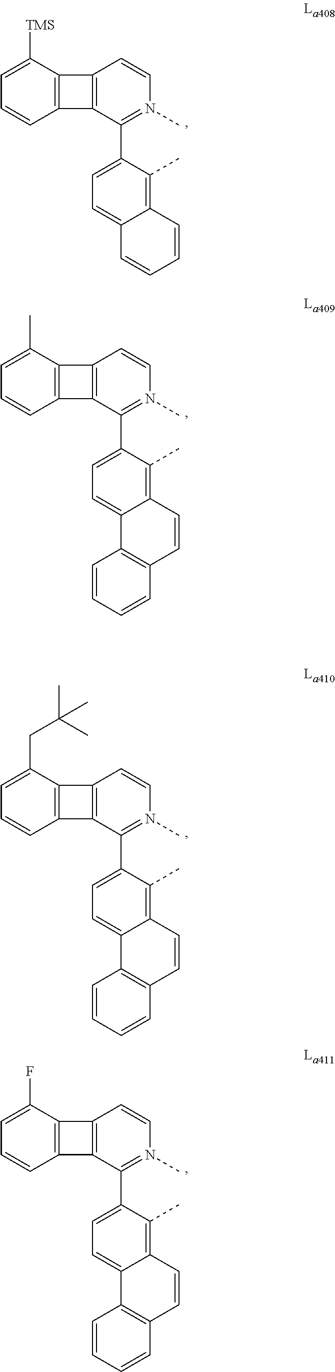 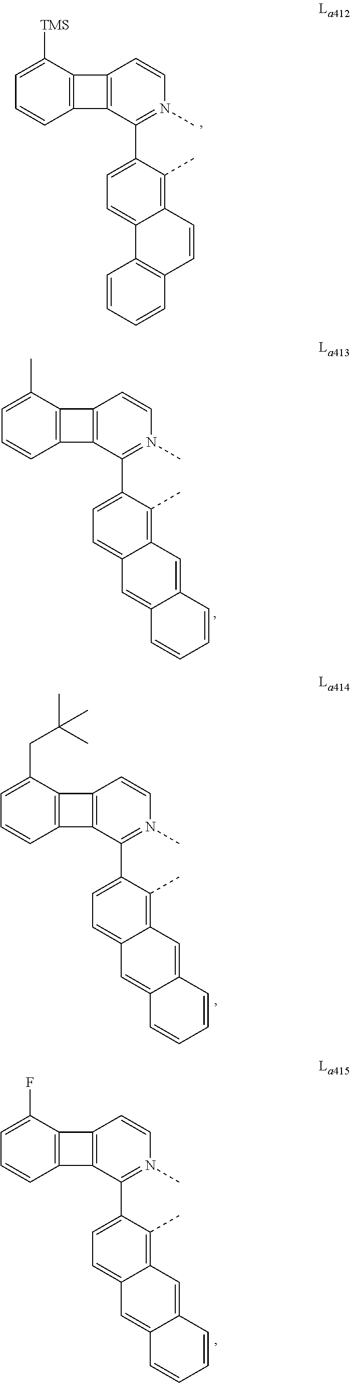 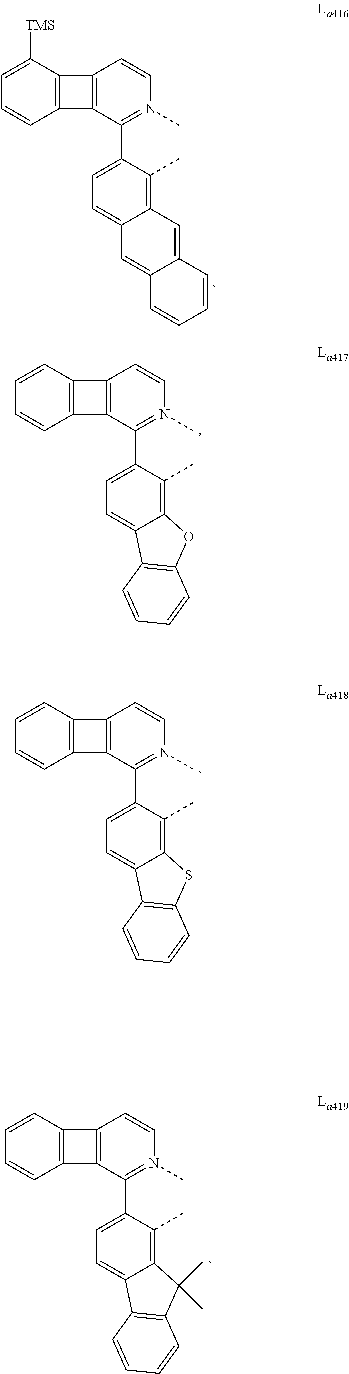 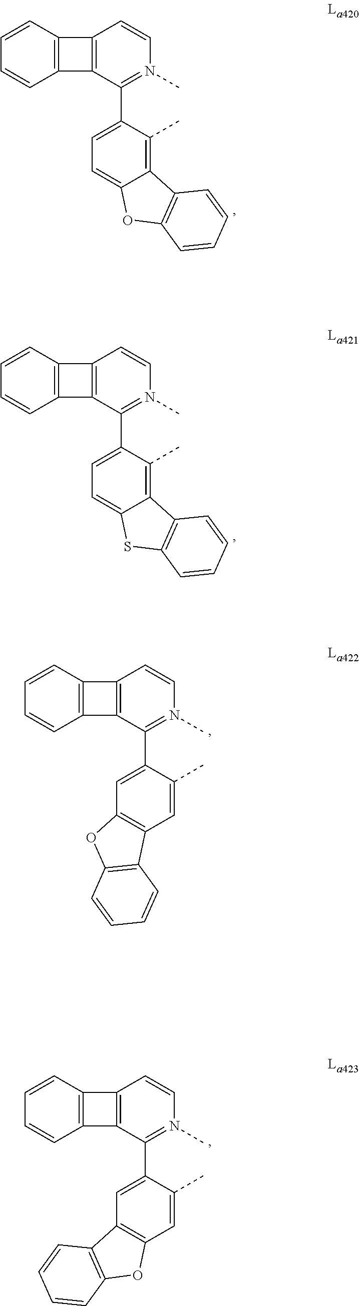 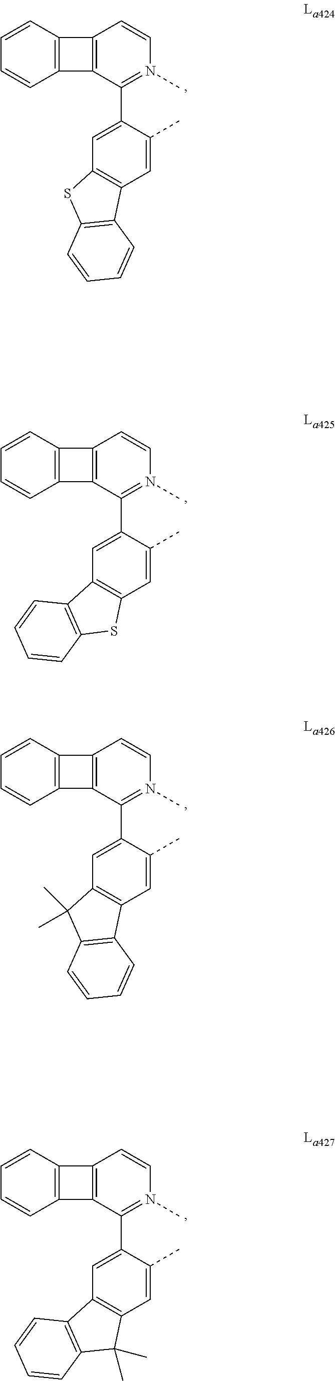 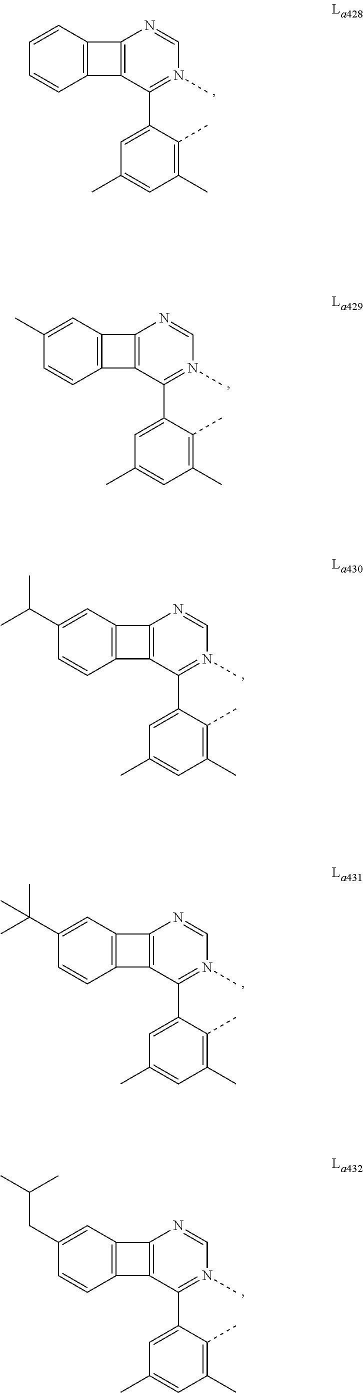 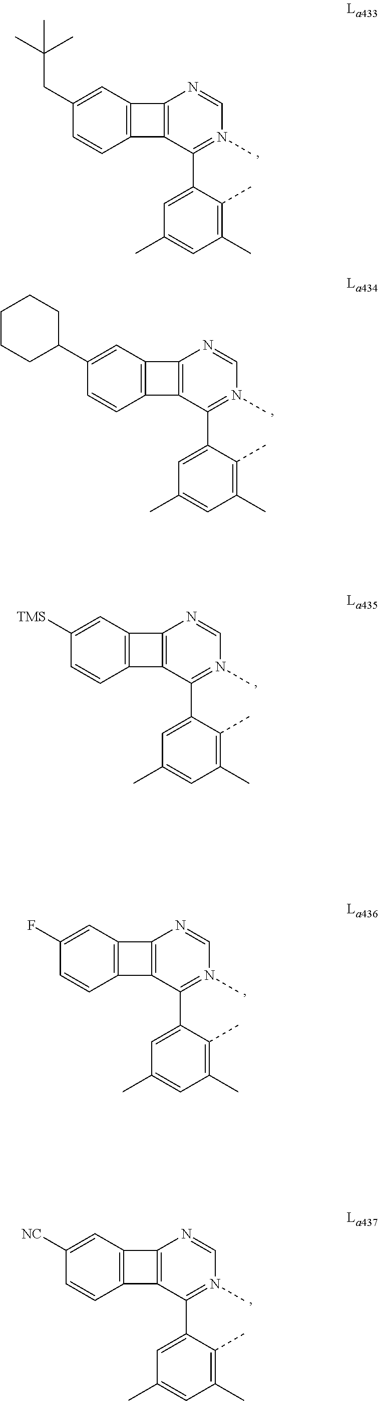 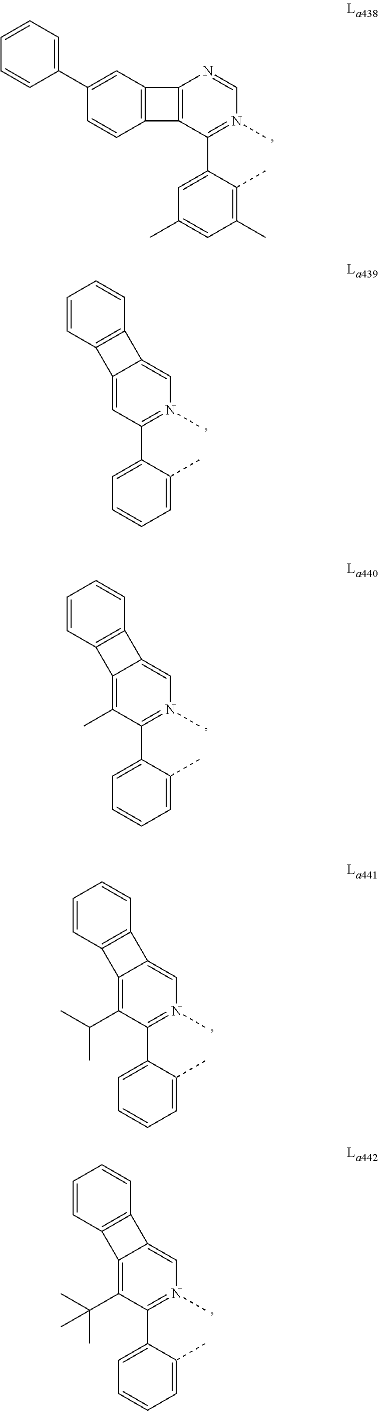 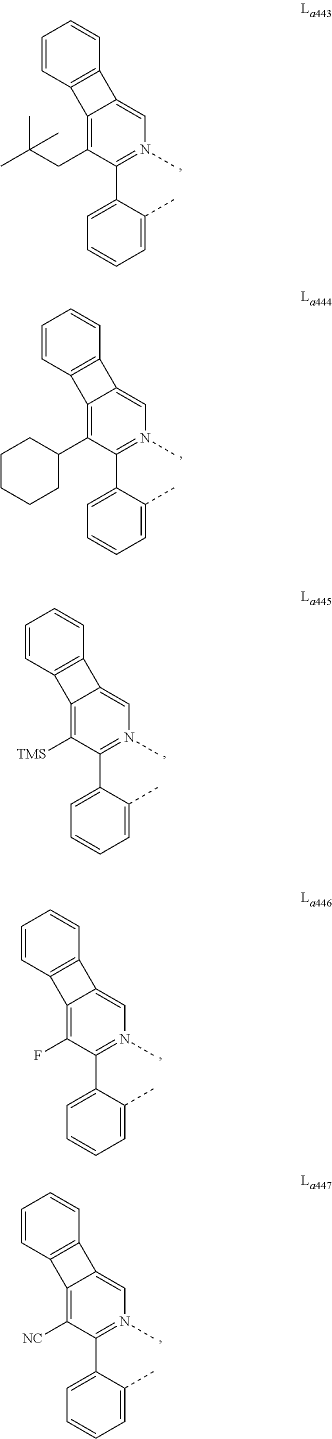 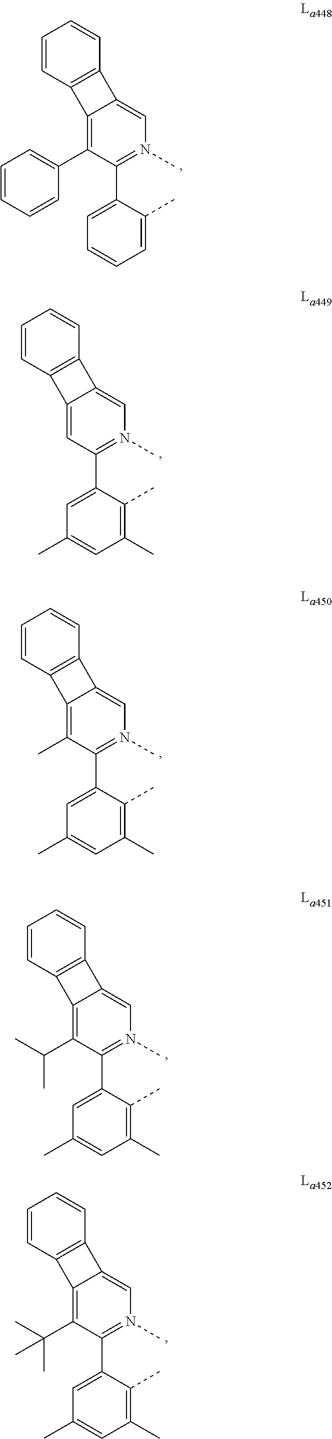 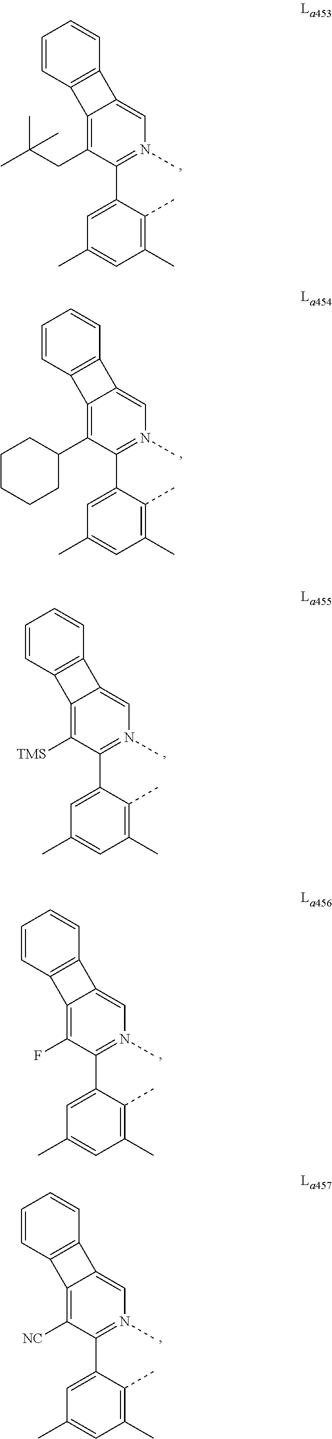 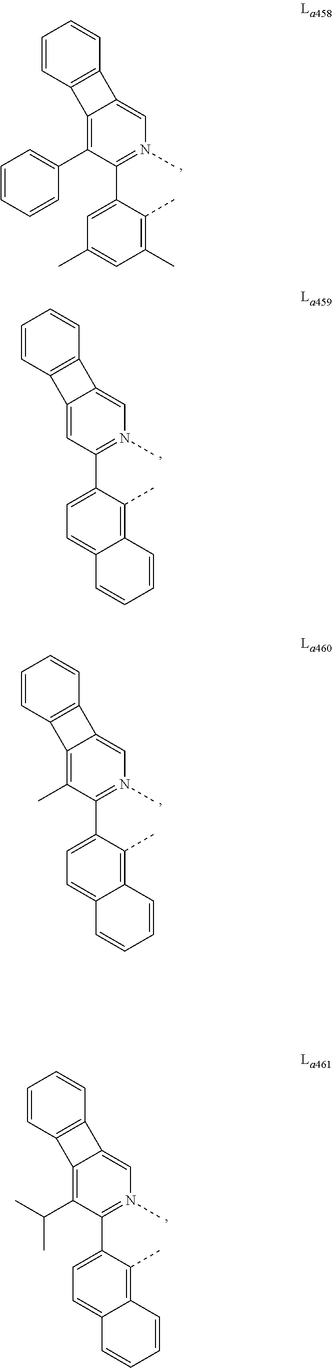 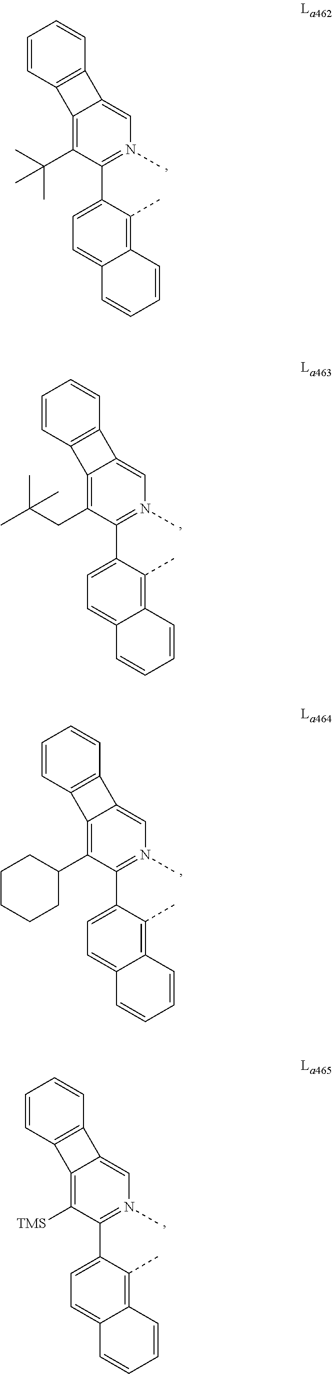 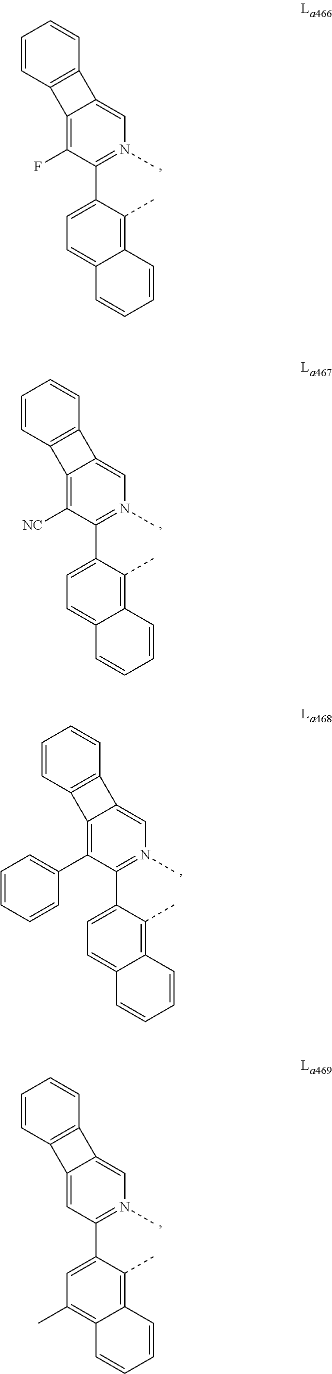 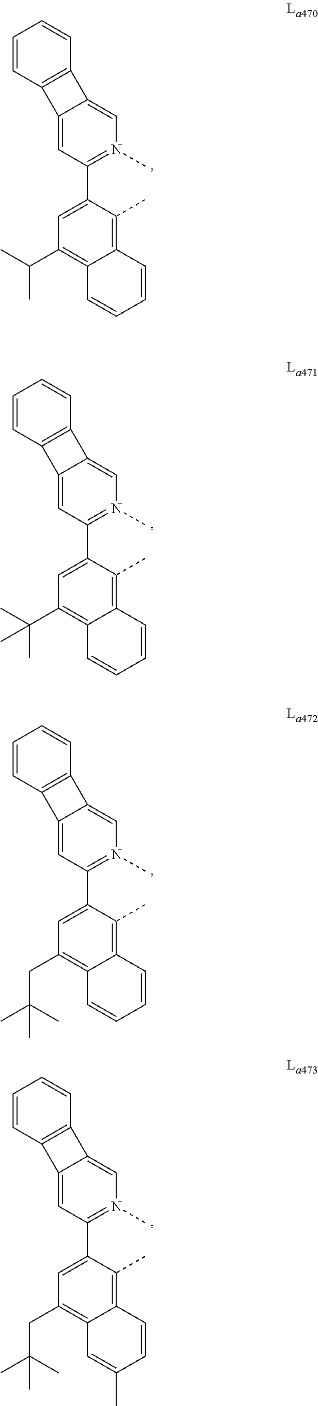 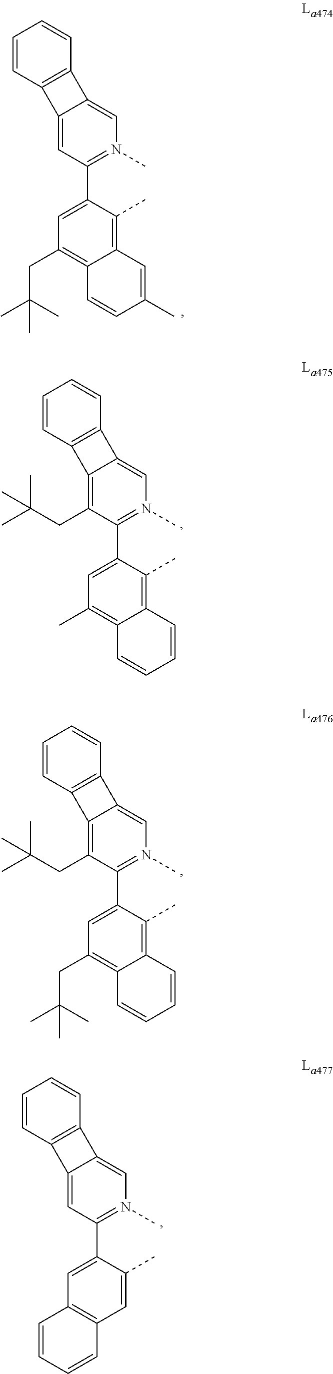 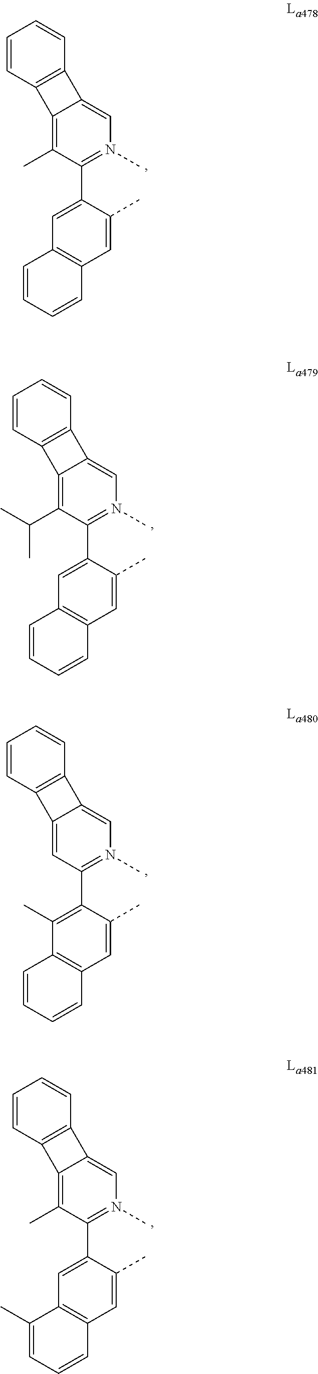 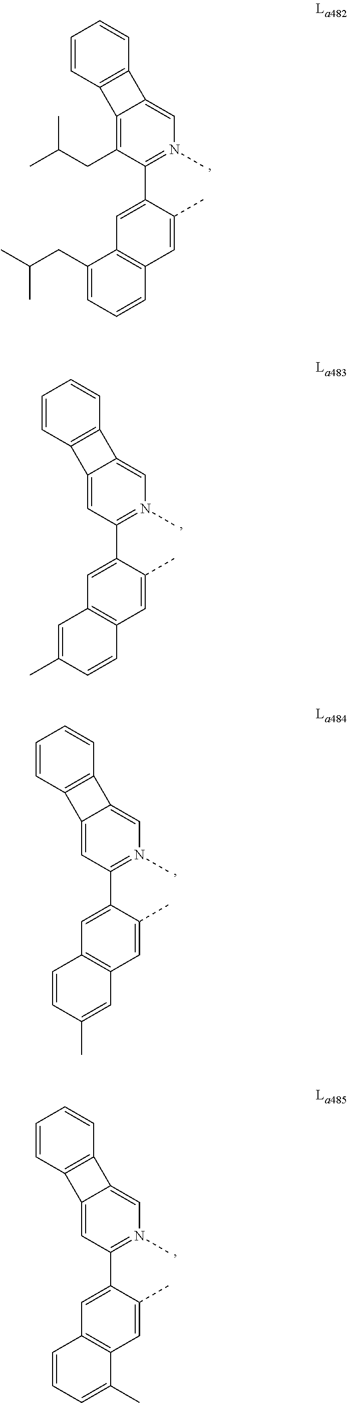 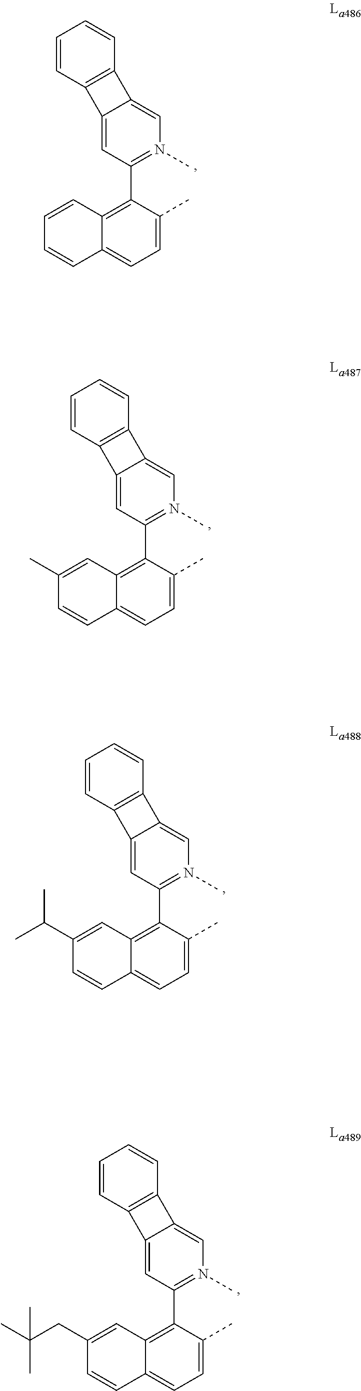 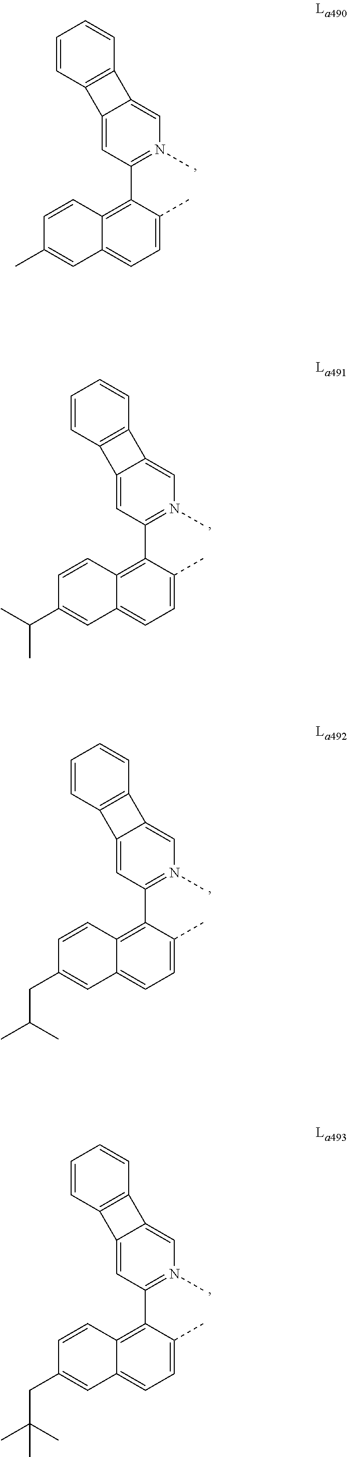 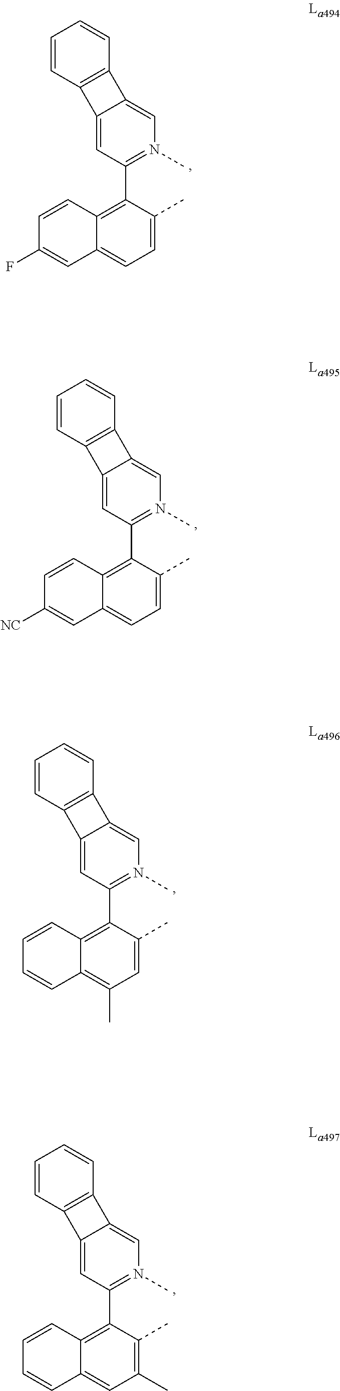 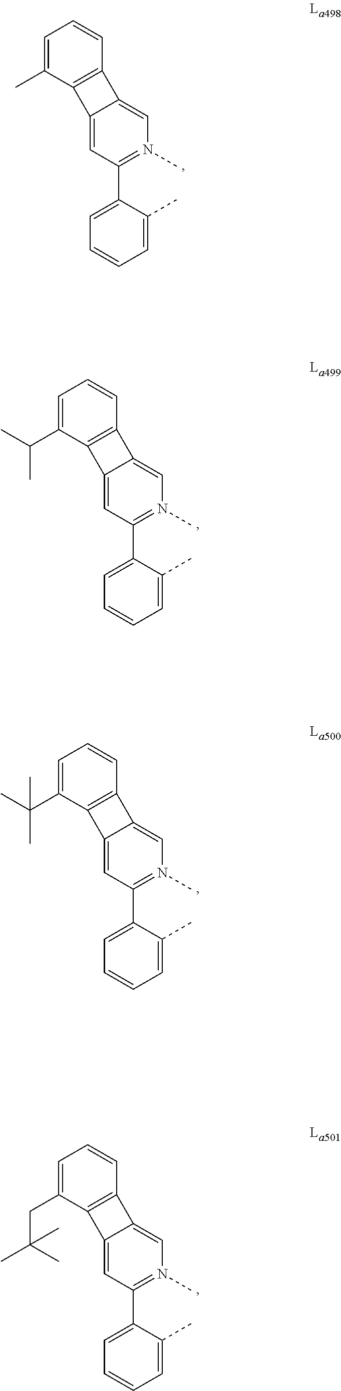 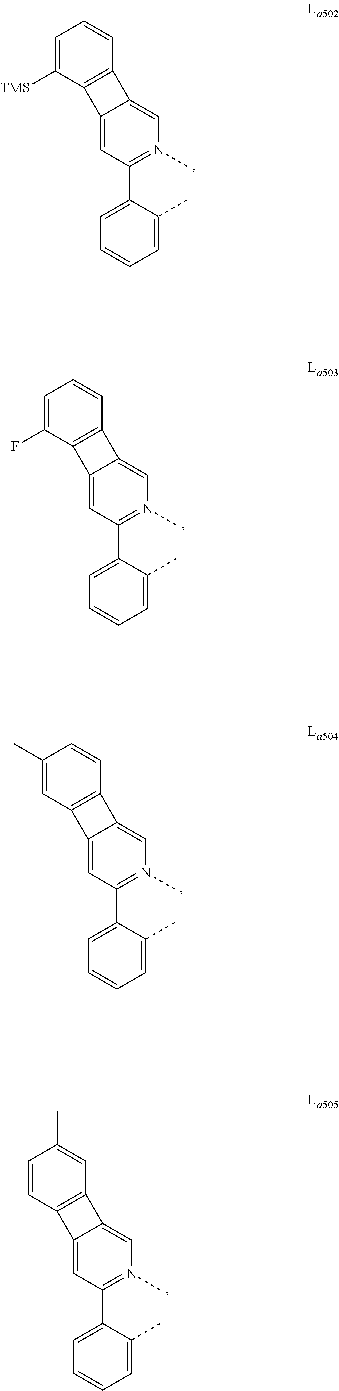 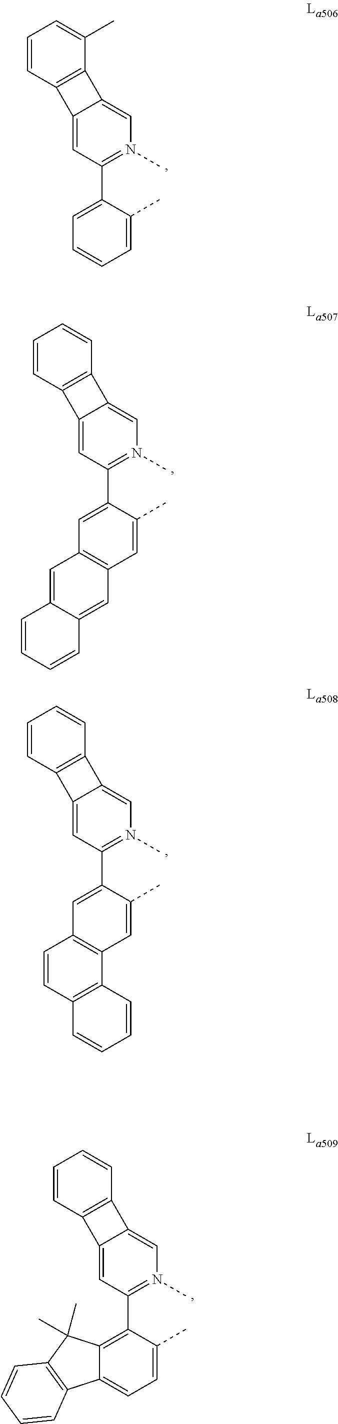 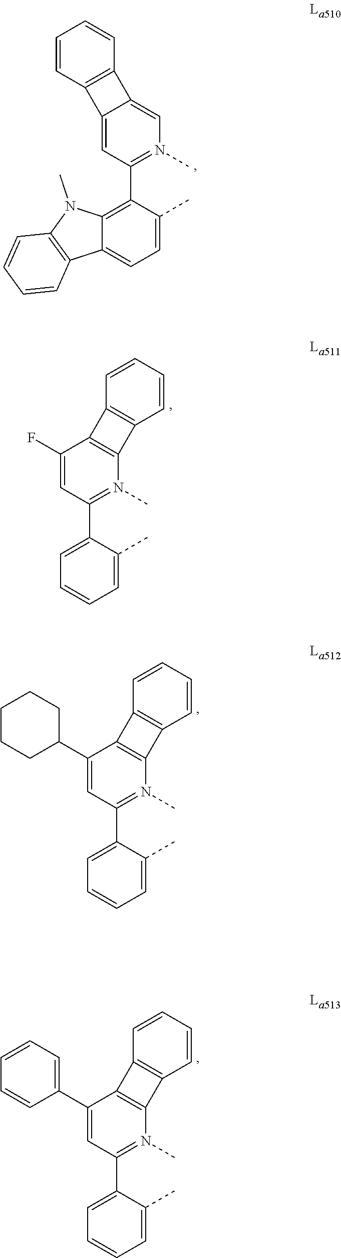 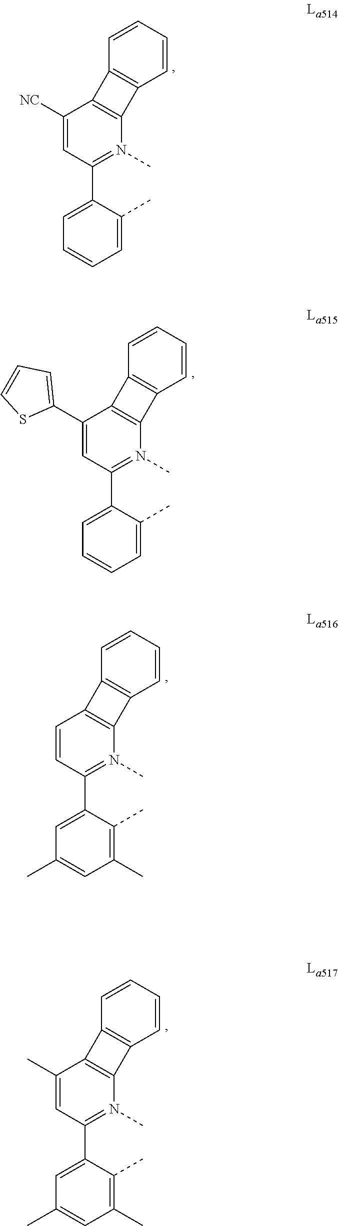 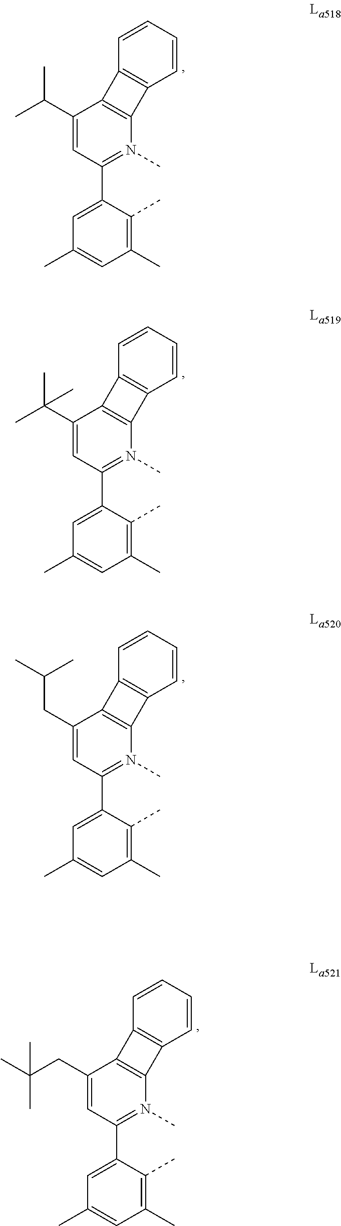 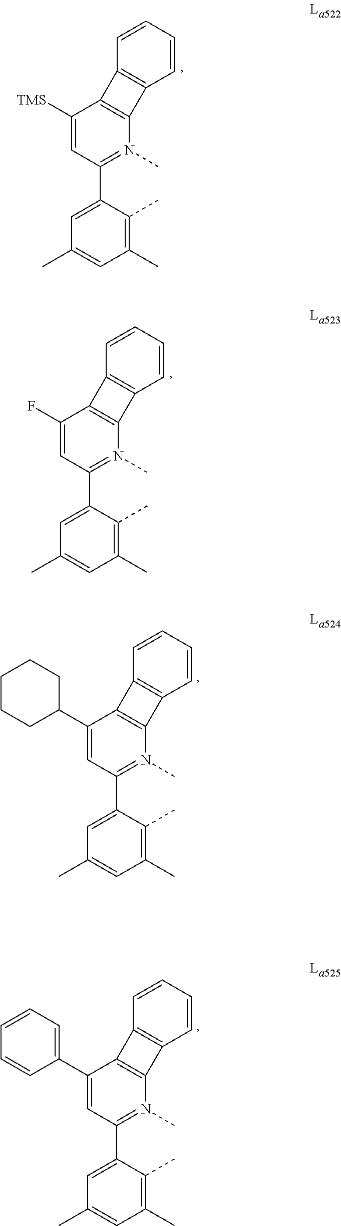 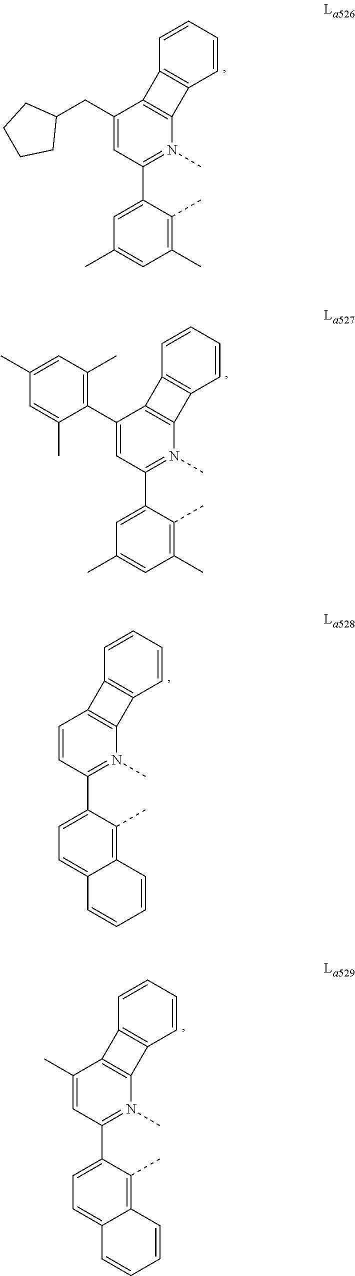 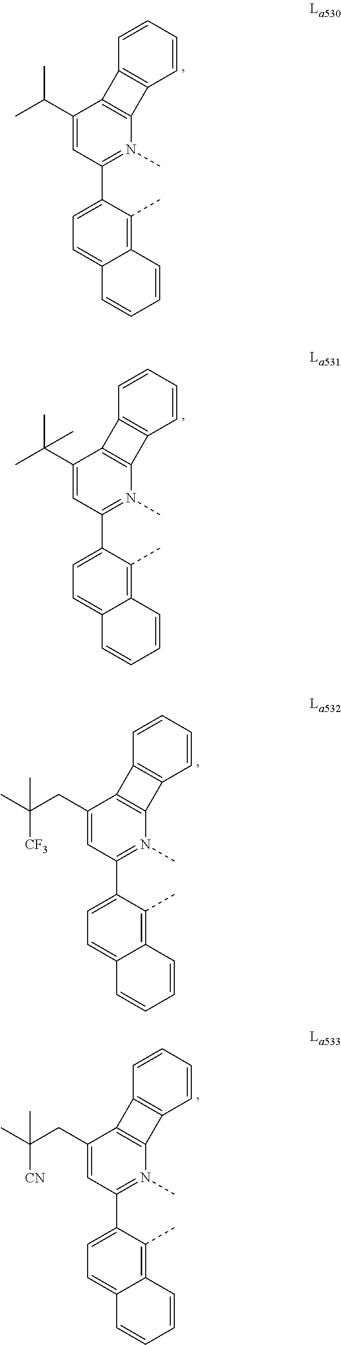 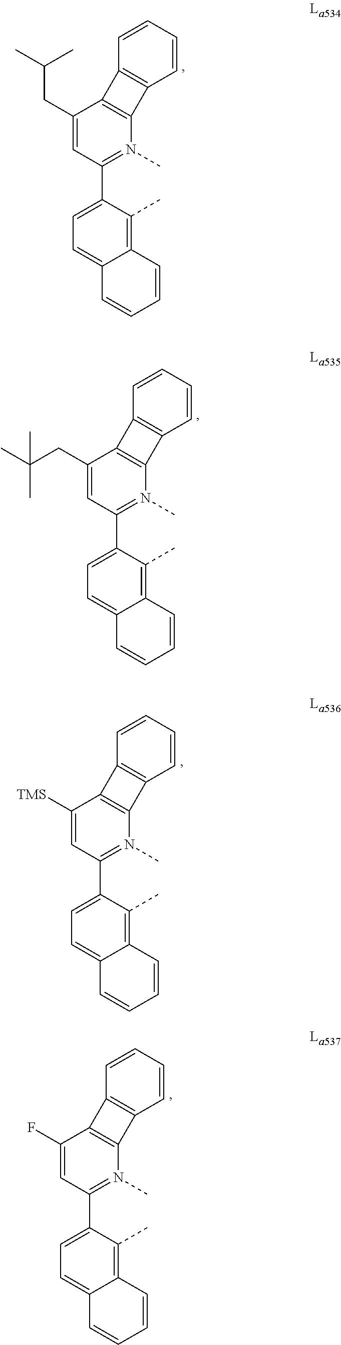 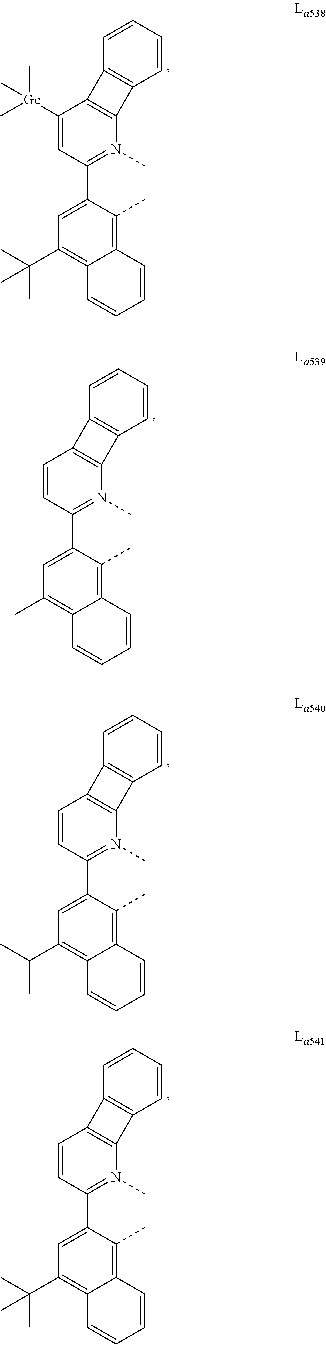 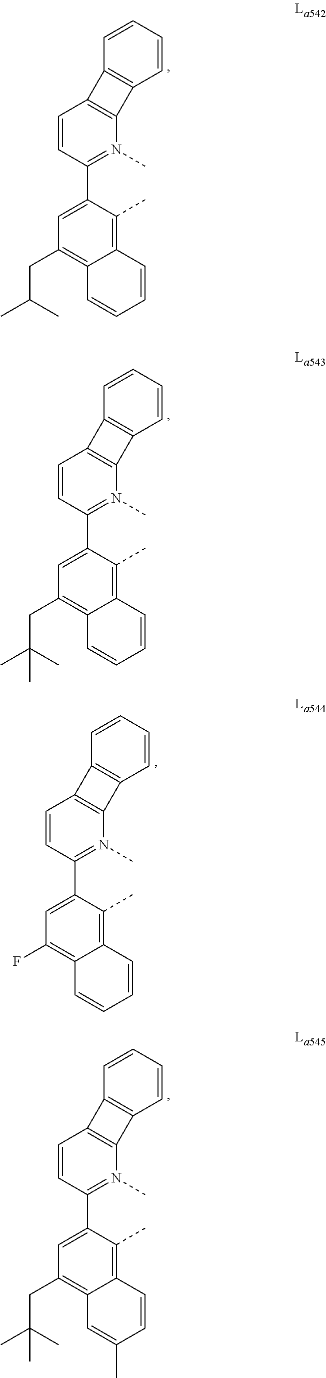 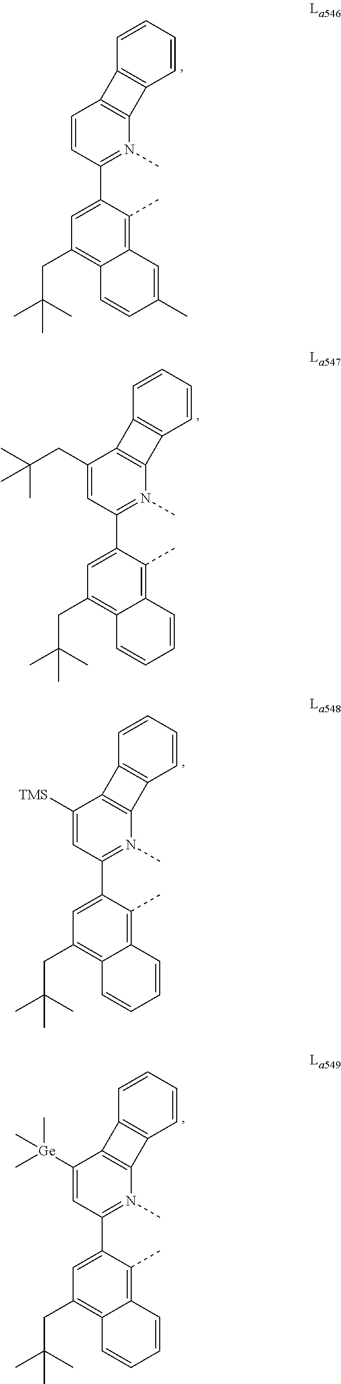 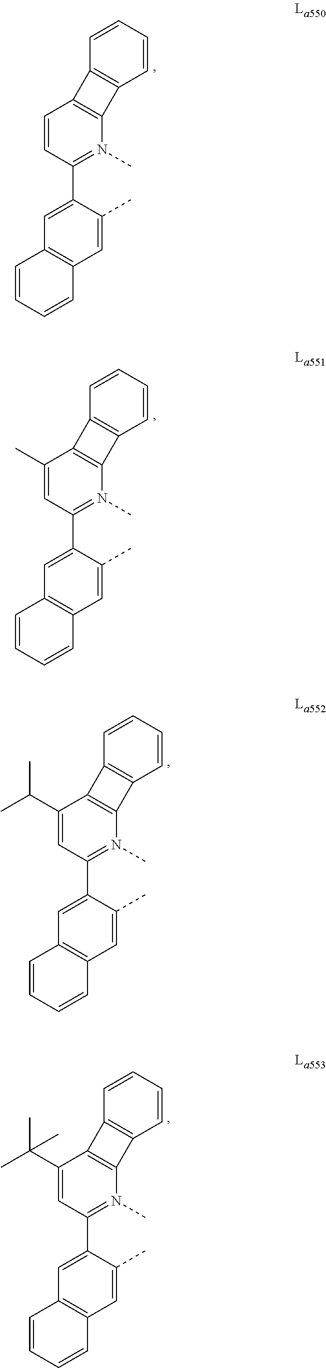 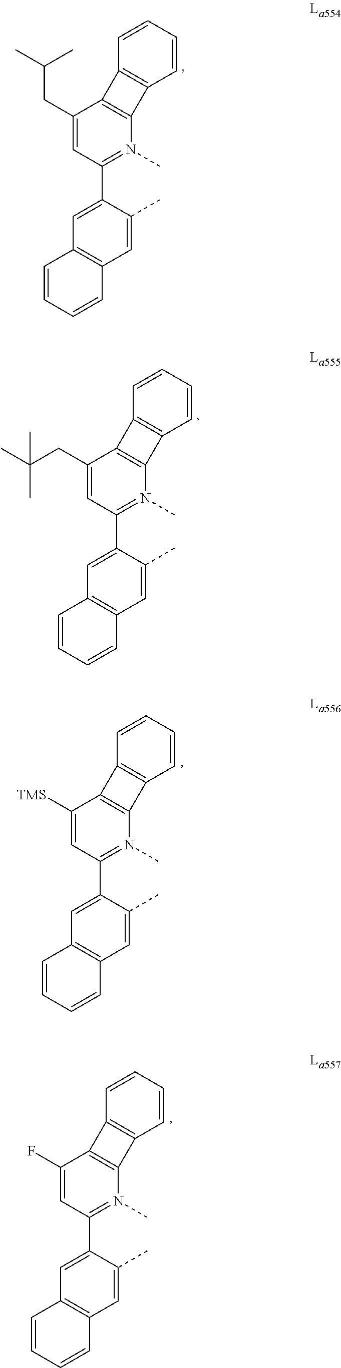 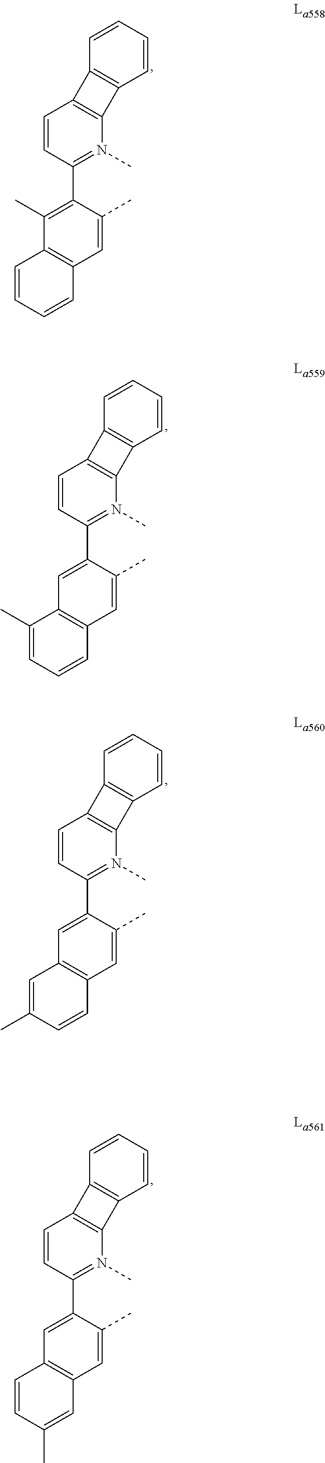 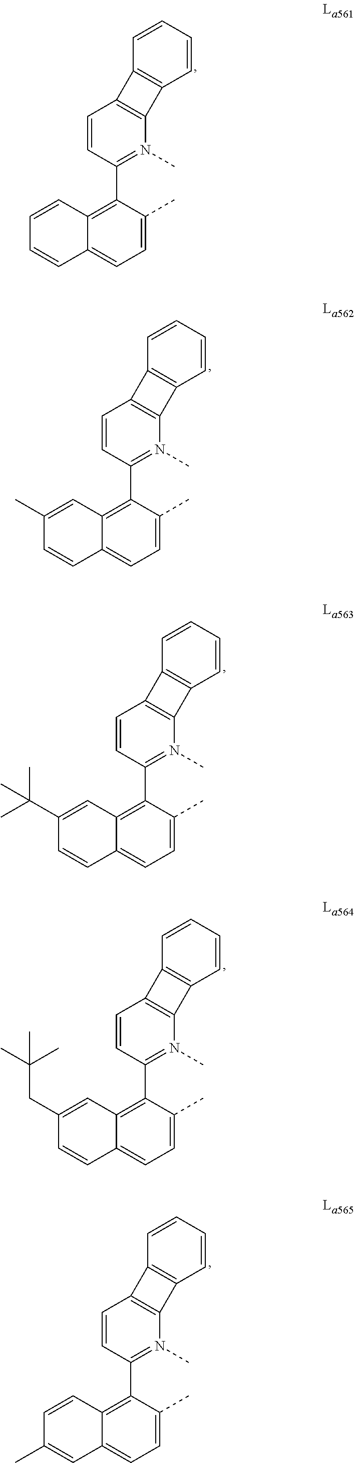 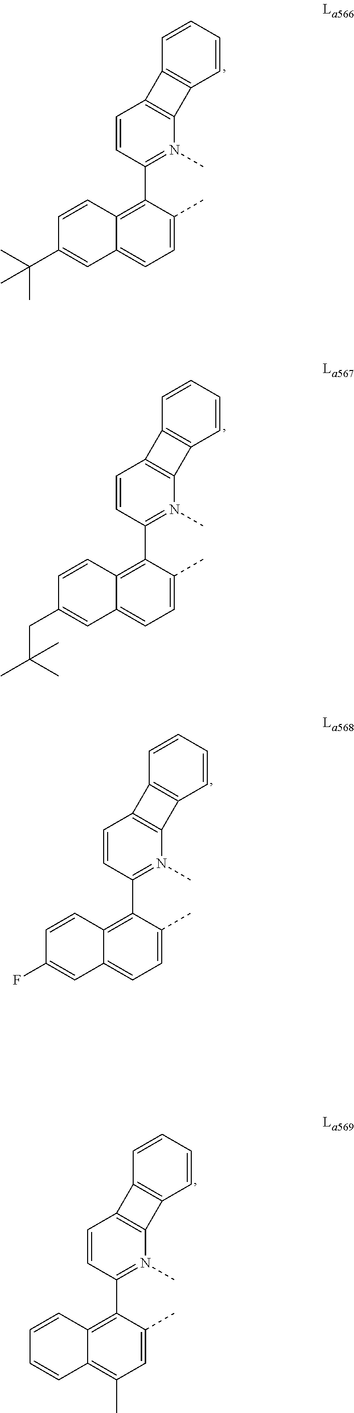 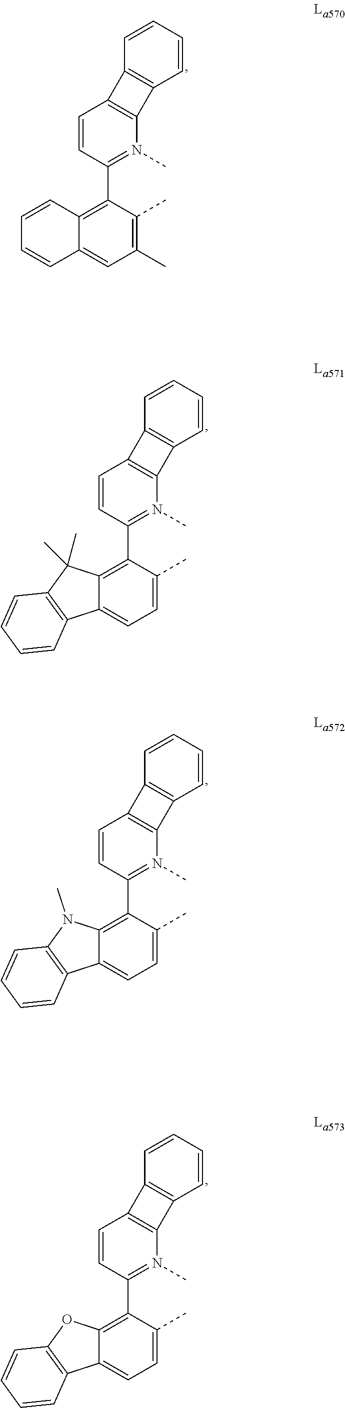 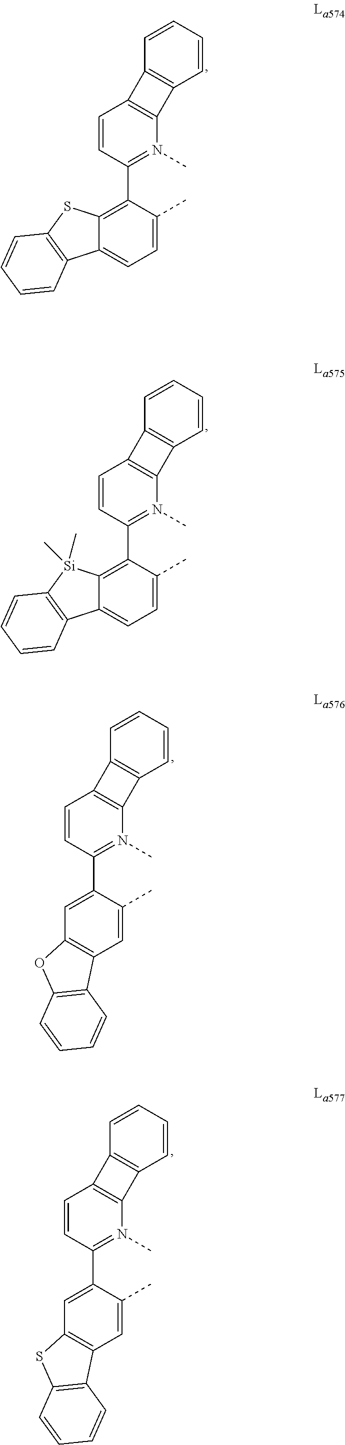 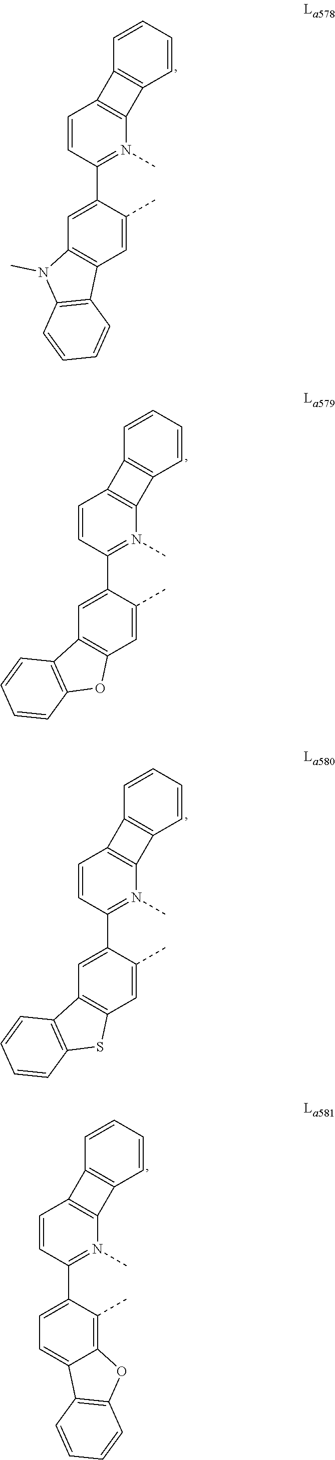 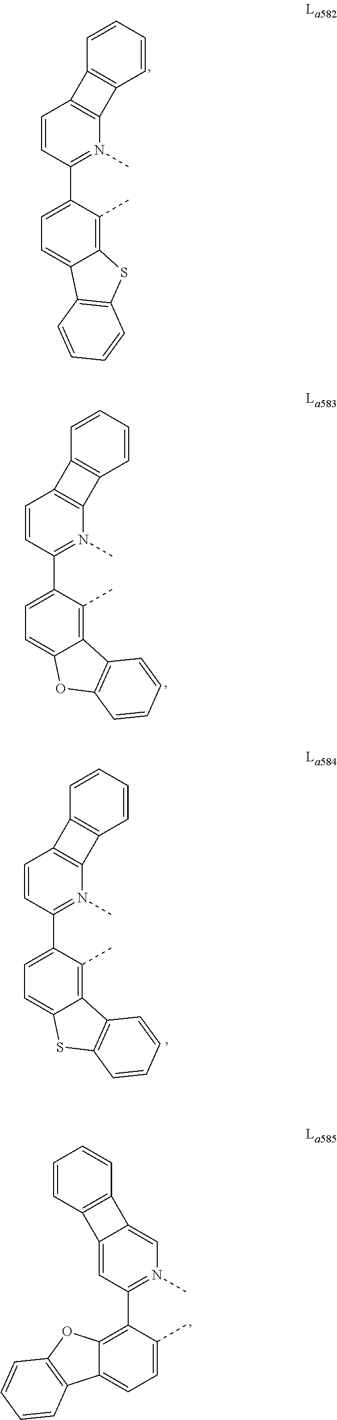 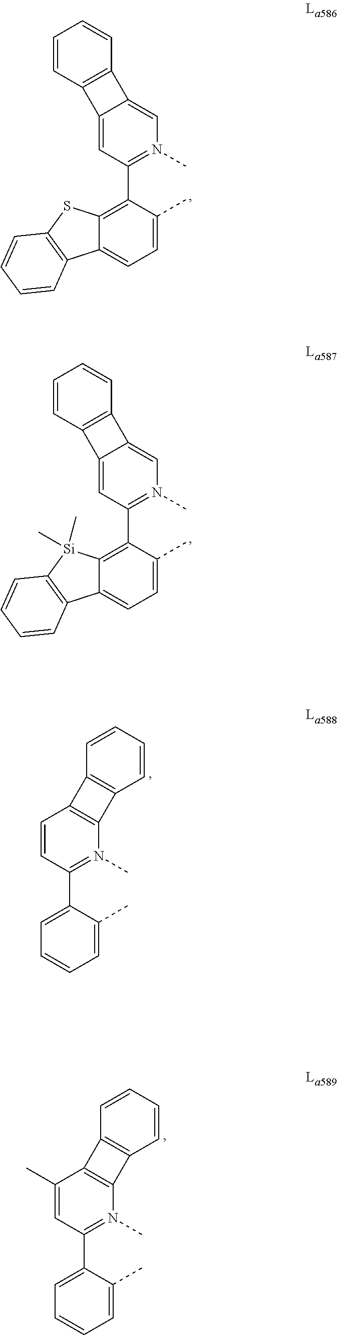 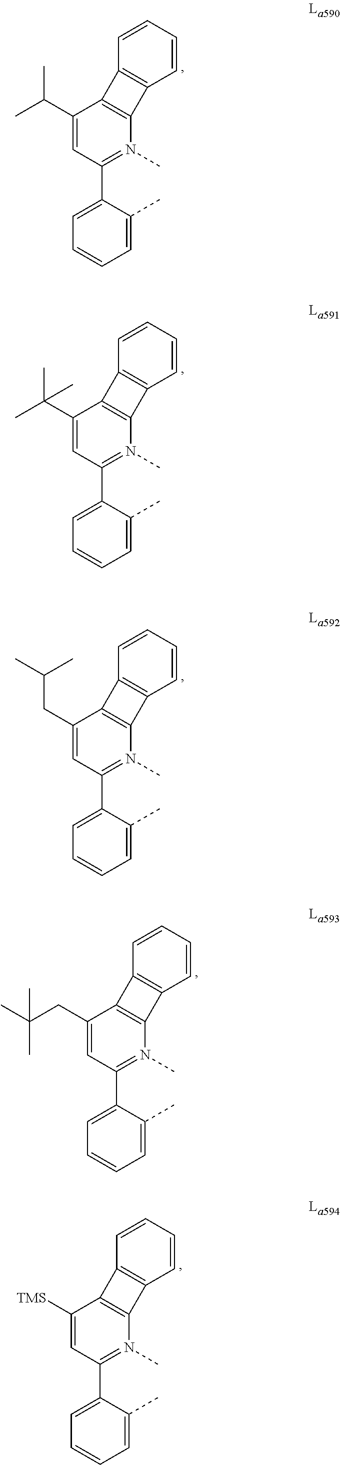 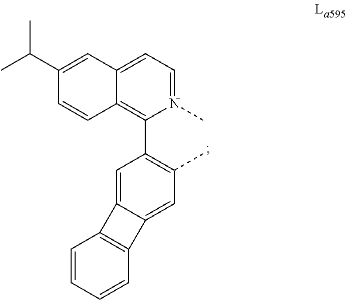
wherein TMS represents trimethylsilyl; and
optionally, hydrogen in the structures of Lₐ₁ to Lₐ₅₉₅ can be partially or fully substituted with deuterium.

11. The metal complex according to claim 1, wherein the second ligand L_{b} has a structure represented by Formula 28: 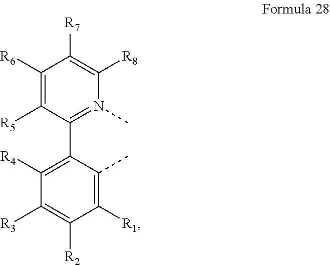
R₁ to R₈ are, at each occurrence identically or differently, selected from the group consisting of: hydrogen, deuterium, halogen, cyano, hydroxyl, sulfanyl, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms and combinations thereof;
adjacent substituents R₁ to R₈ can be optionally joined to form a ring;
preferably, R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof; and
more preferably, R₁ to R₈ are, at each occurrence identically or differently, selected from the group consisting of: hydrogen, deuterium, fluorine, methyl, ethyl, isopropyl, isobutyl, tert-butyl, cyclopentyl, cyclopentylmethyl, cyclohexyl, neopentyl, deuterated methyl, deuterated ethyl, deuterated isopropyl, deuterated isobutyl, deuterated tert-butyl, deuterated cyclopentyl, deuterated cyclopentylmethyl, deuterated cyclohexyl, deuterated neopentyl, trimethylsilyl and combinations thereof.

12. The metal complex according to claim 11, wherein at least one, at least two, at least three or all of R₂, R₃, R₆ and R₇ are, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof;
preferably, at least one, at least two, at least three or all of R₂, R₃, R₆ and R₇ are, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms and combinations thereof;
more preferably, at least one, at least two, at least three or all of R₂, R₃, R₆ and R₇ are, at each occurrence identically or differently, selected from the group consisting of: deuterium, methyl, ethyl, propyl, isopropyl, n-butyl, isobutyl, tert-butyl, cyclopentyl, cyclohexyl, neopentyl, tert-pentyl, and any preceding group that is partially or fully substituted with deuterium.

13. The metal complex according to claim 10, wherein L_{b} is, at each occurrence identically or differently, selected from the group consisting of the following: 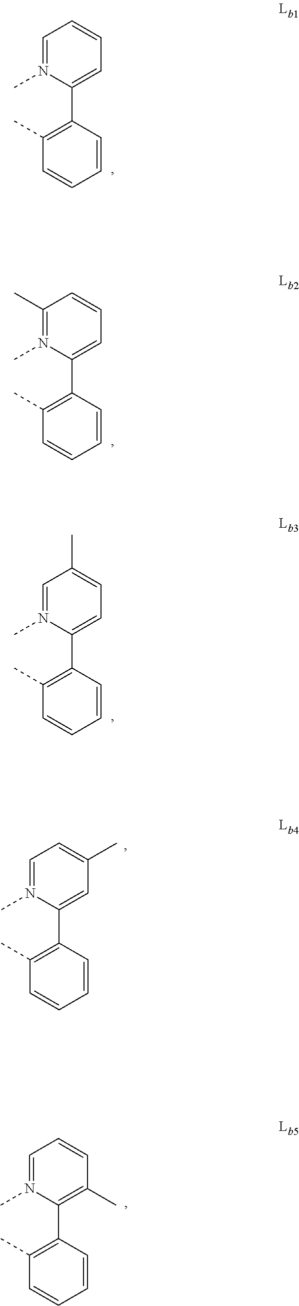 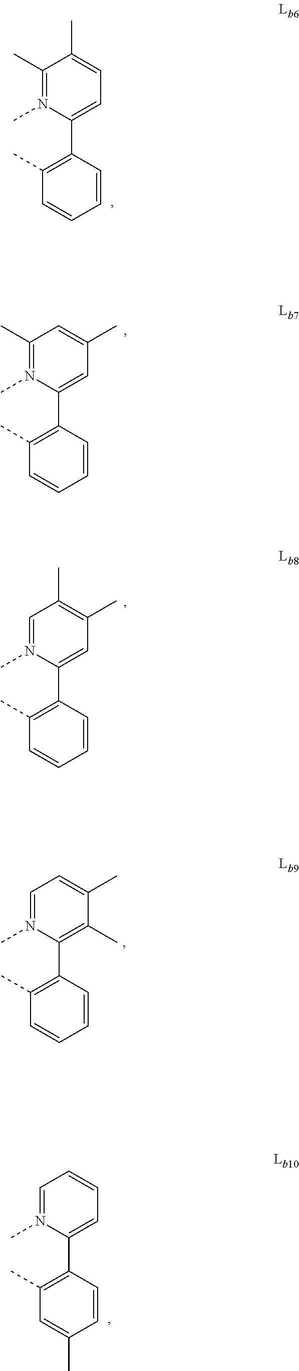 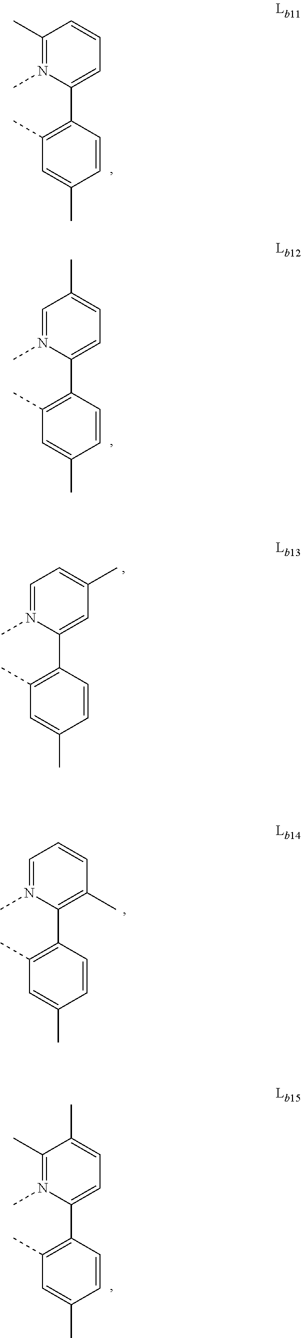 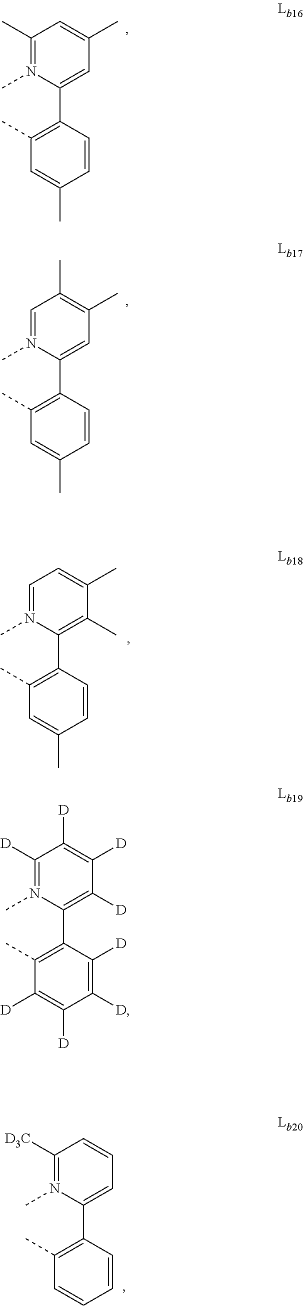 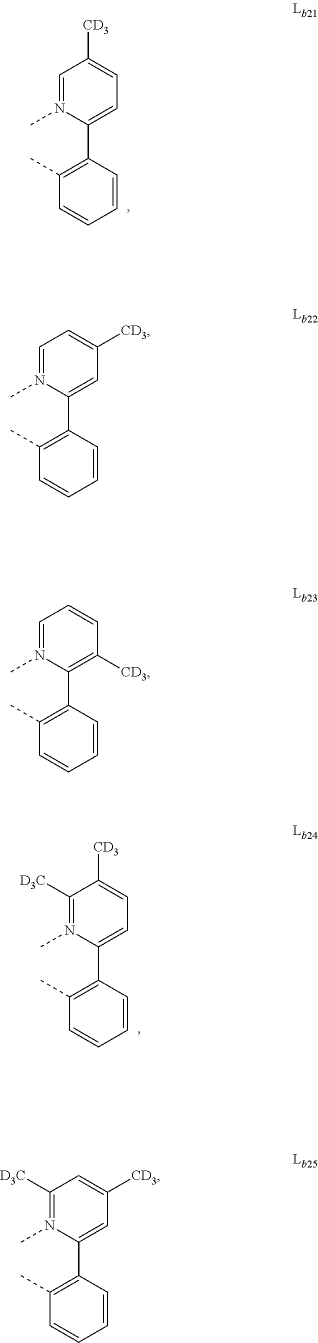 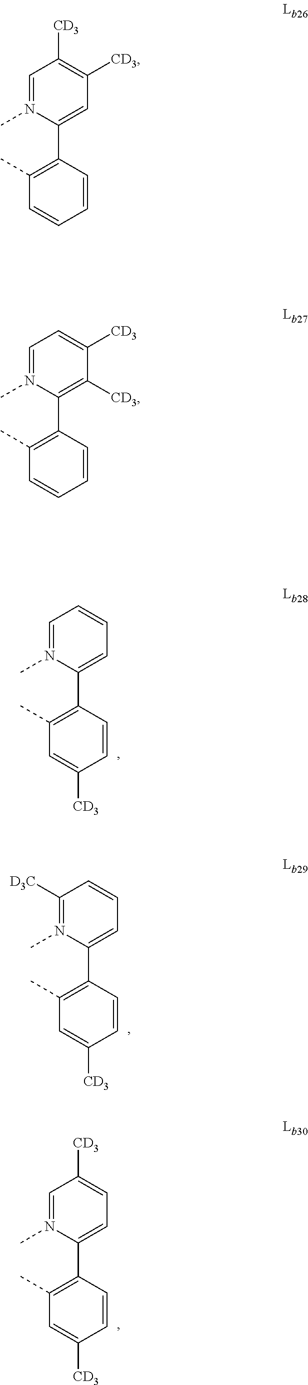 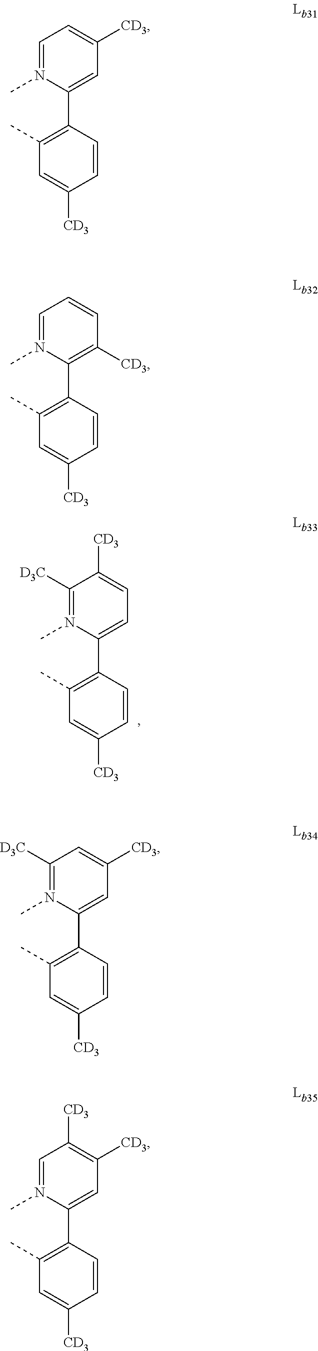 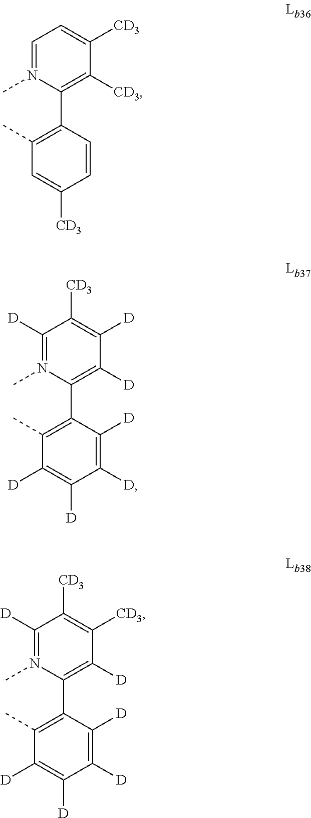 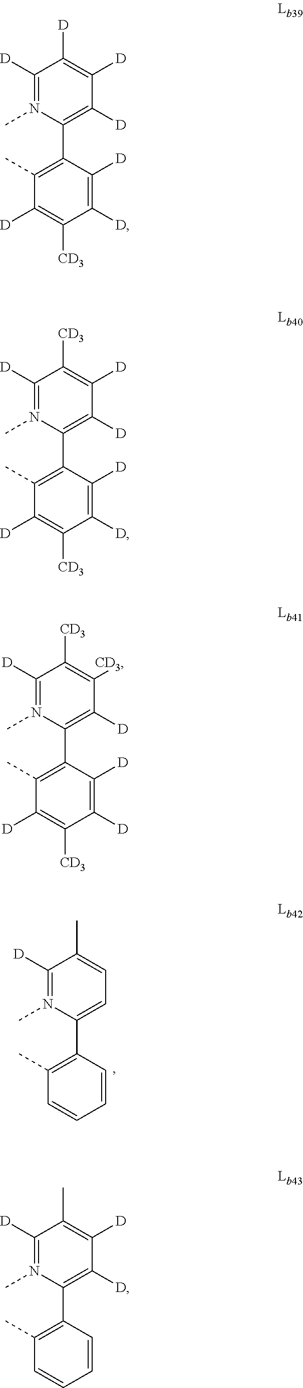 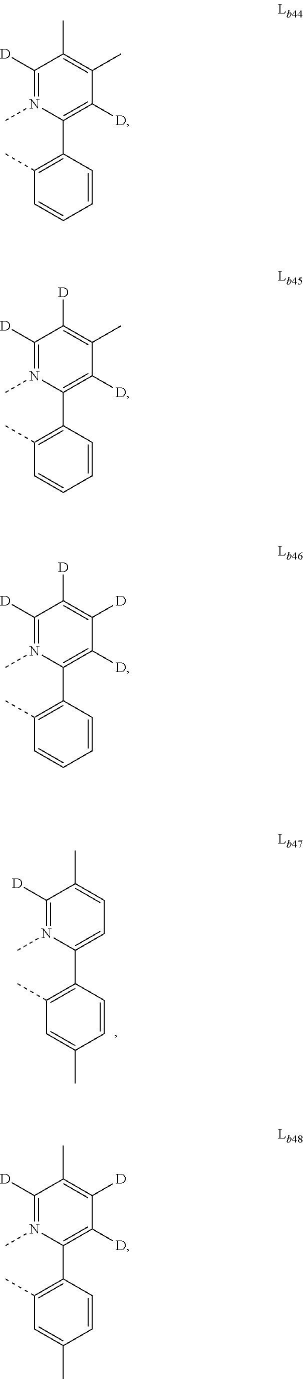 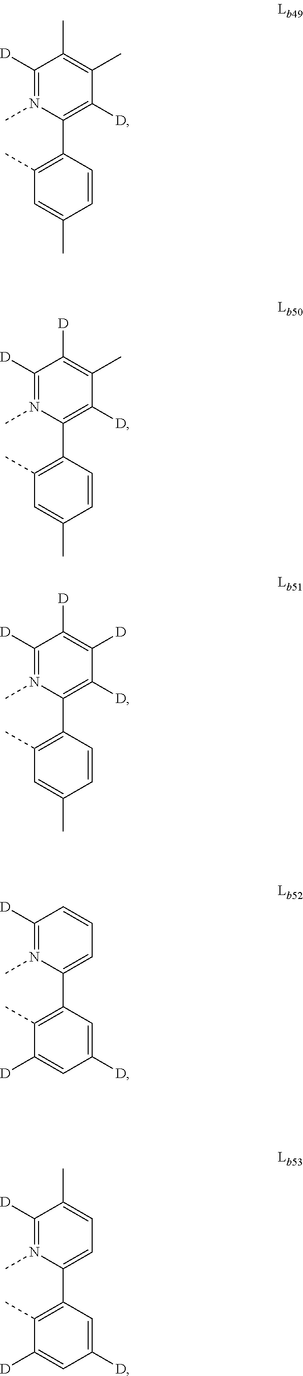 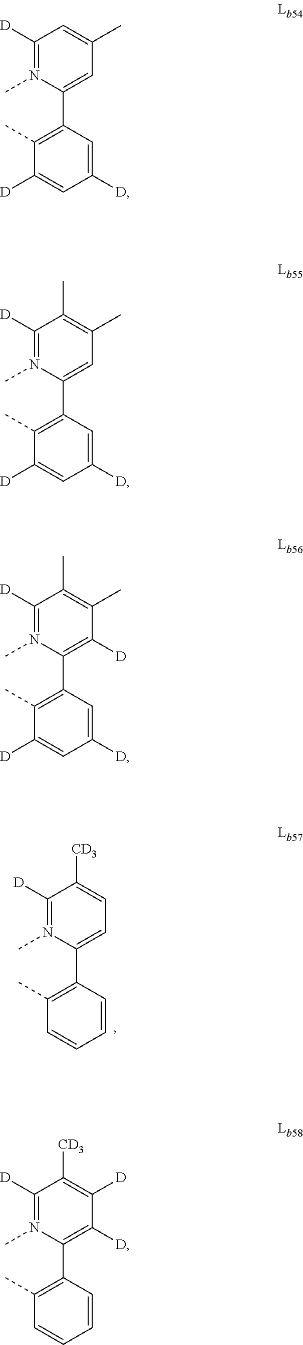 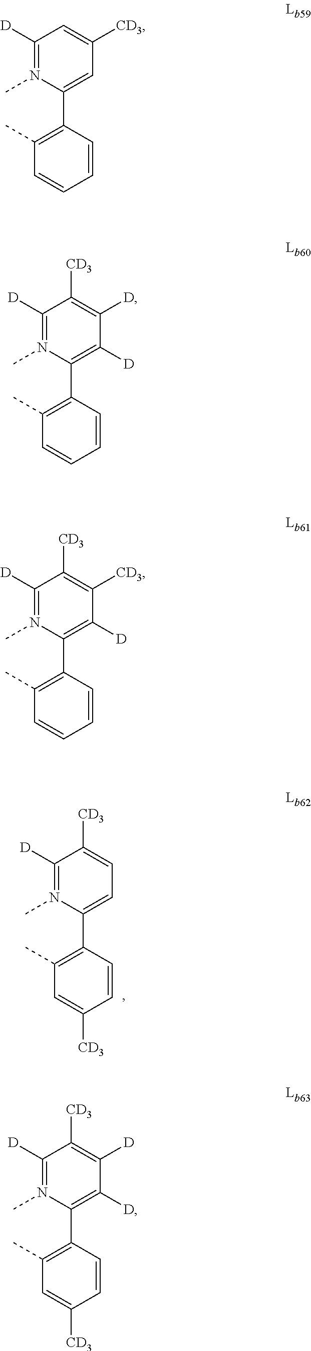 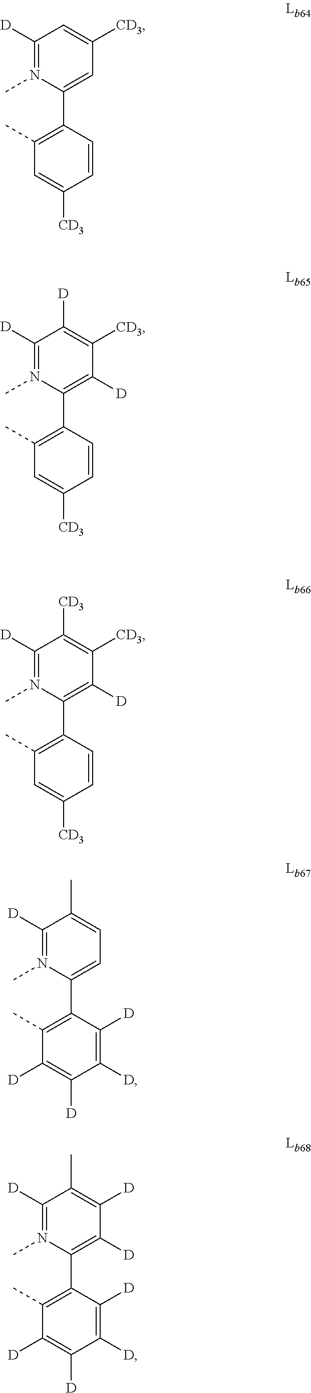 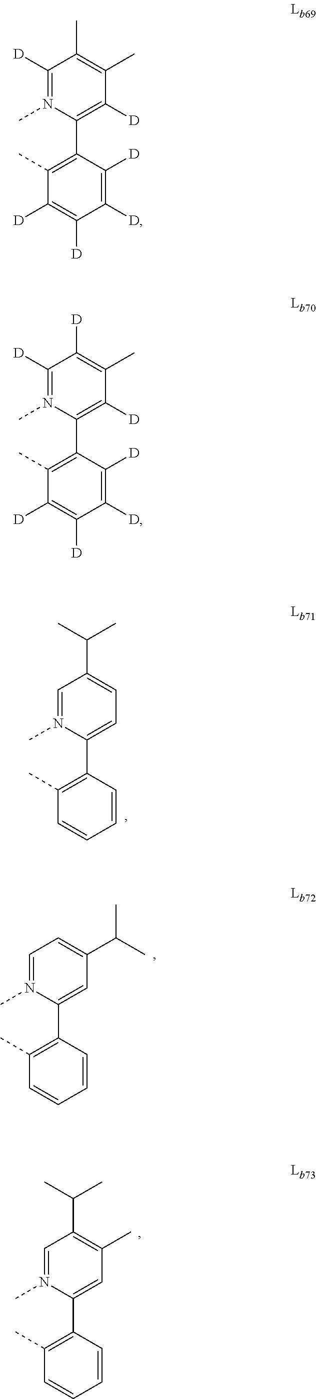 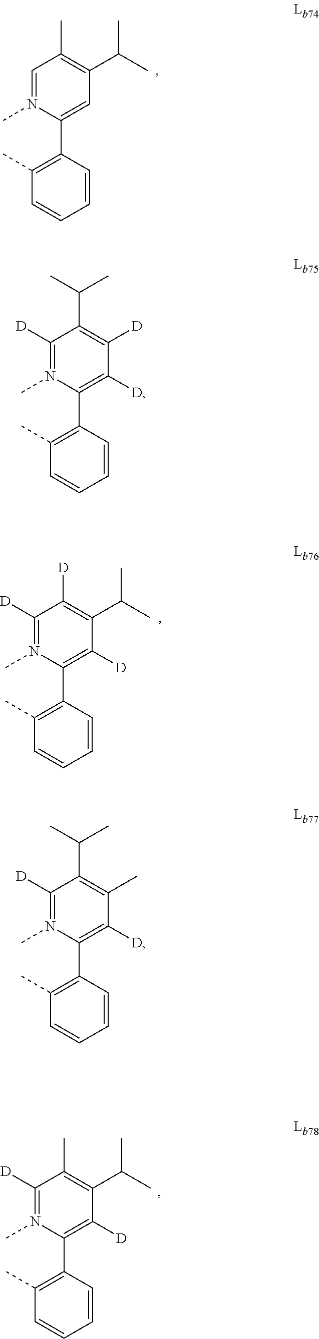 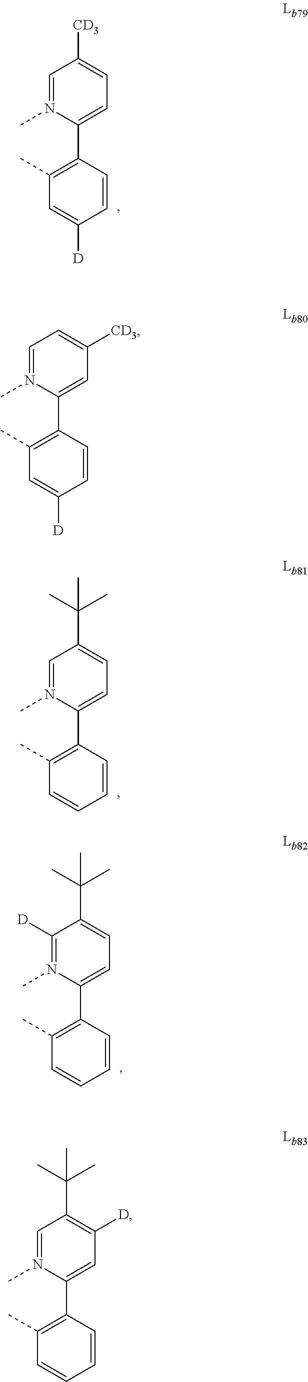 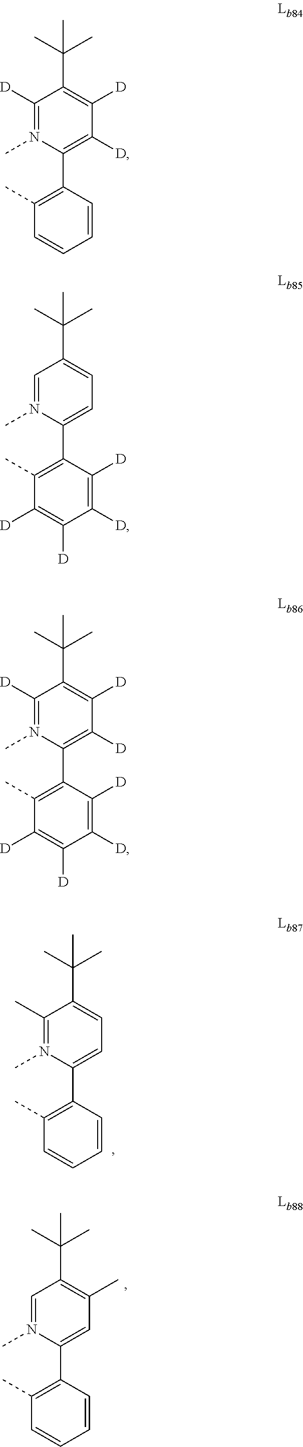 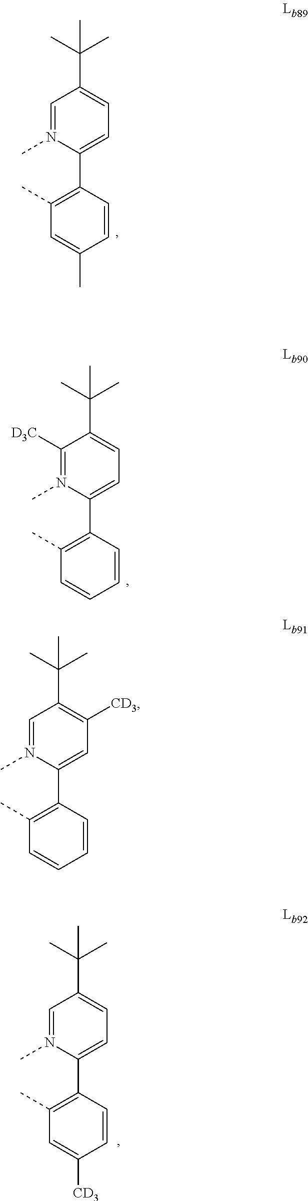 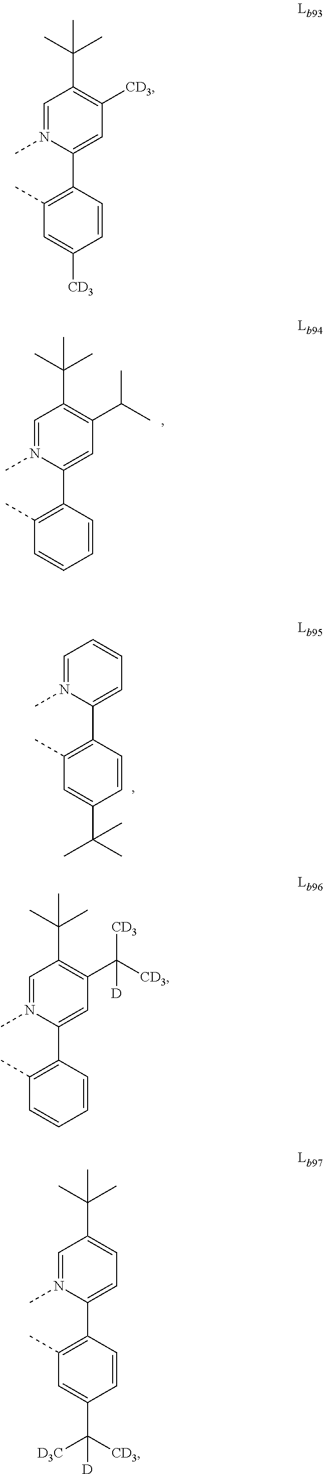 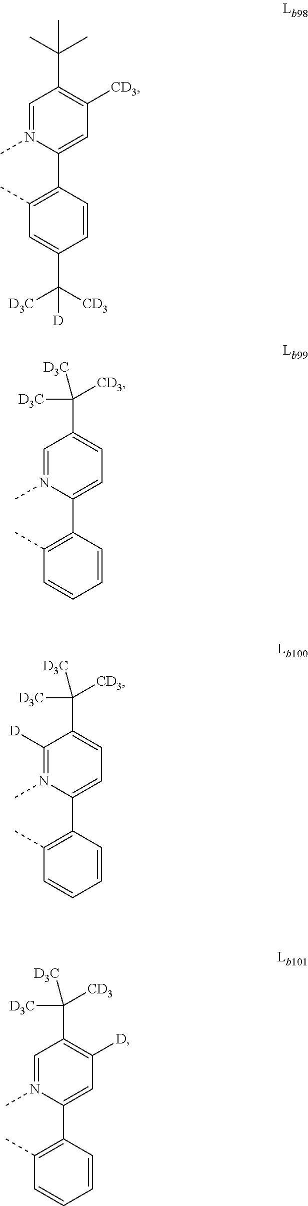 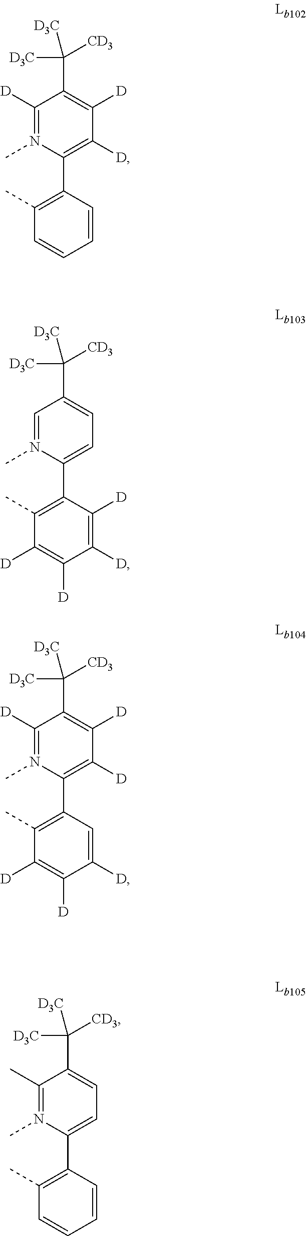 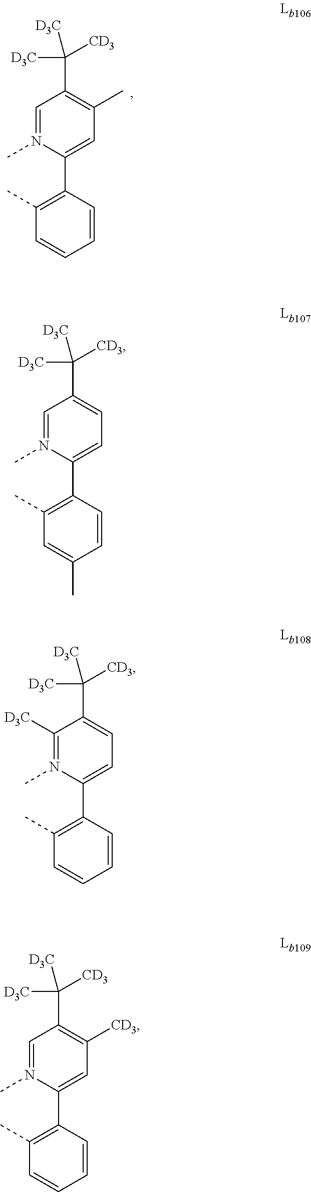 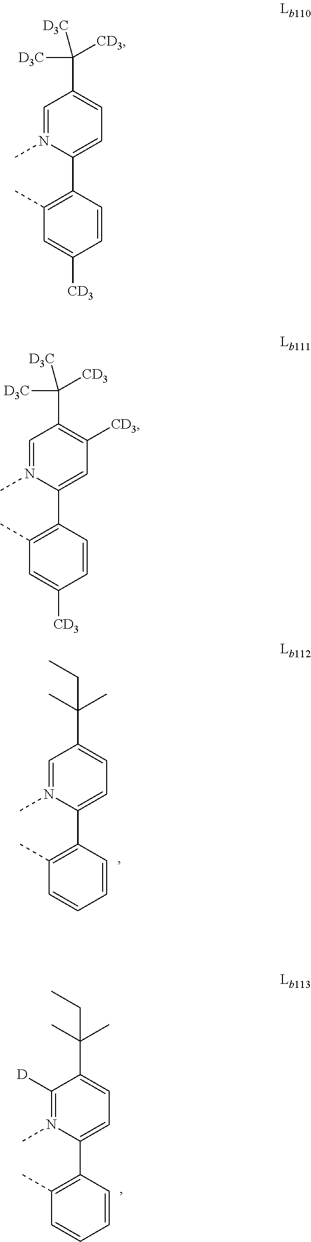 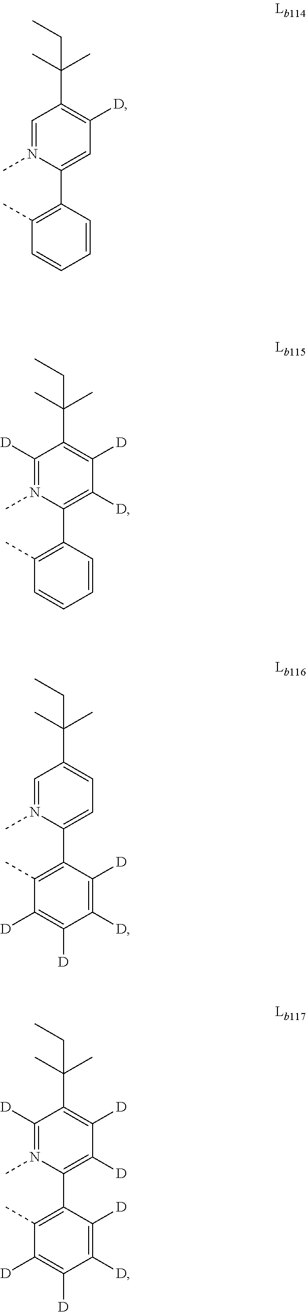 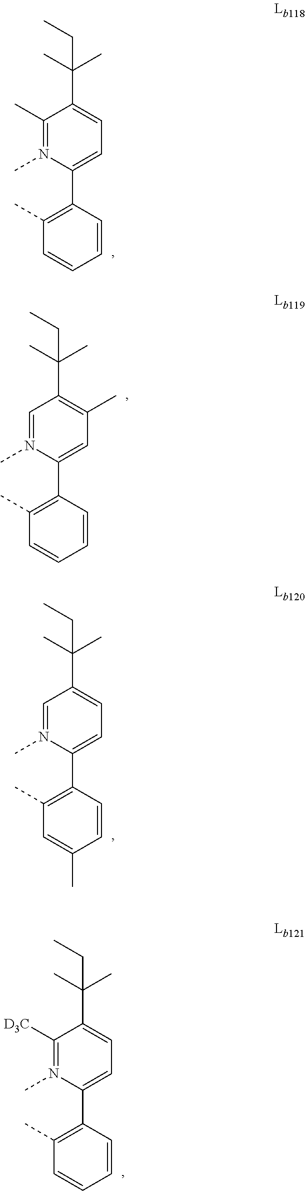 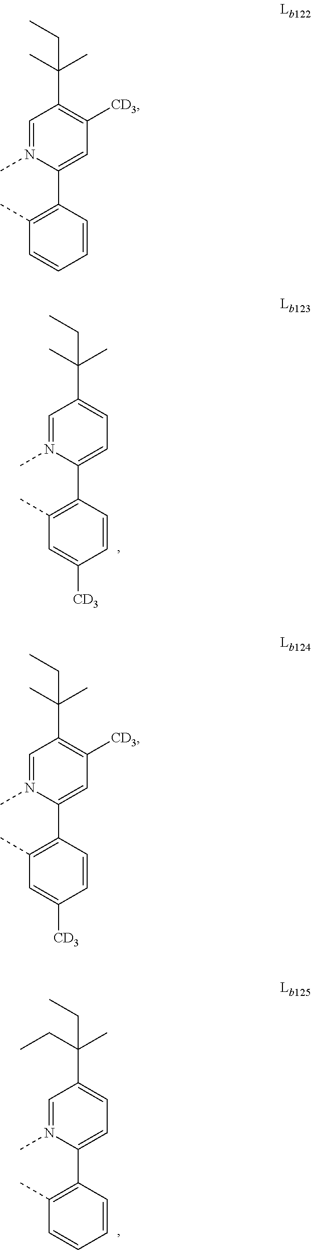 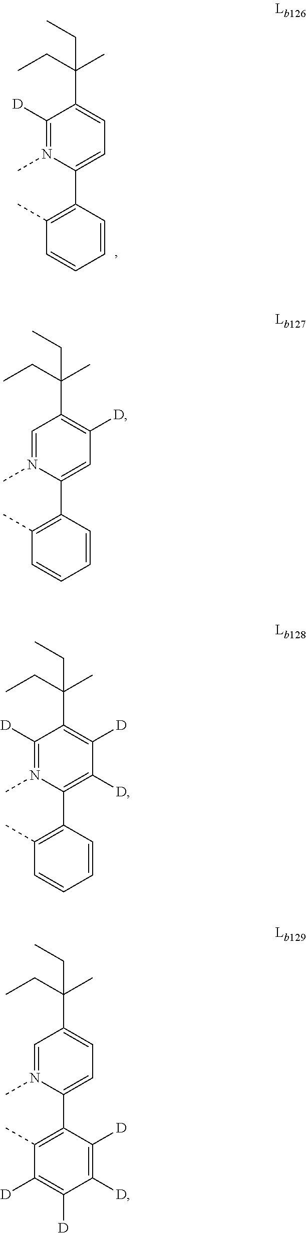 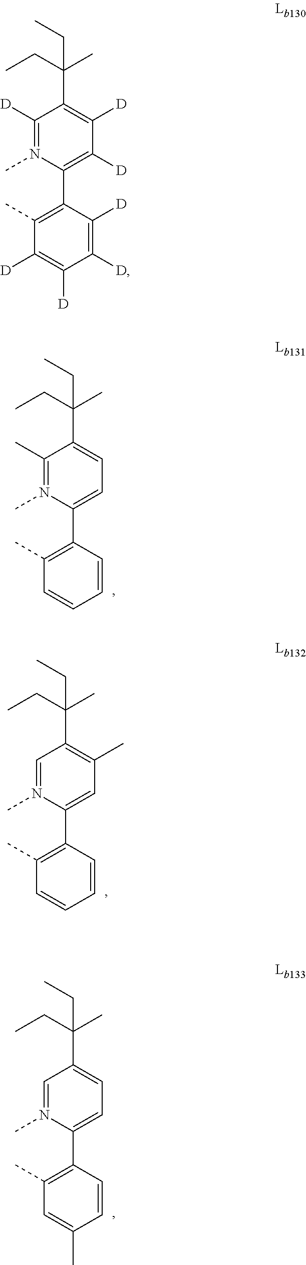 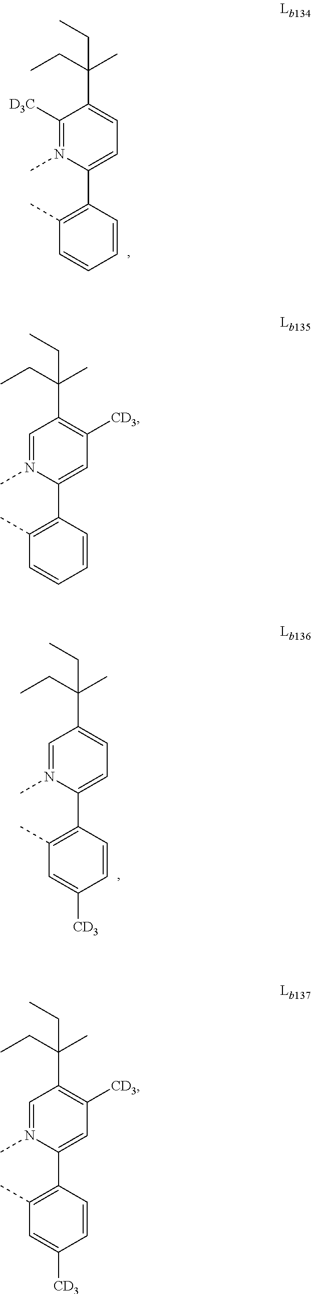 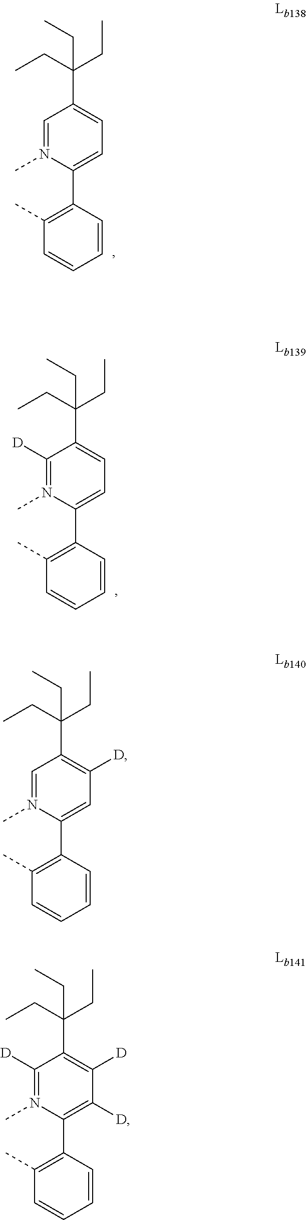 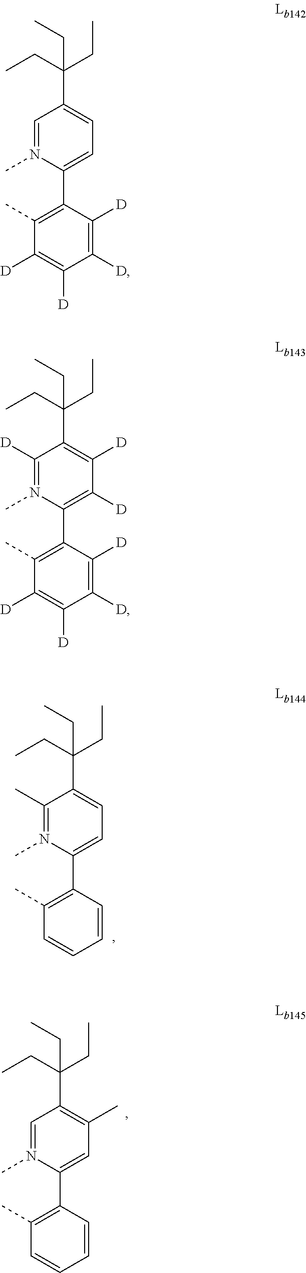 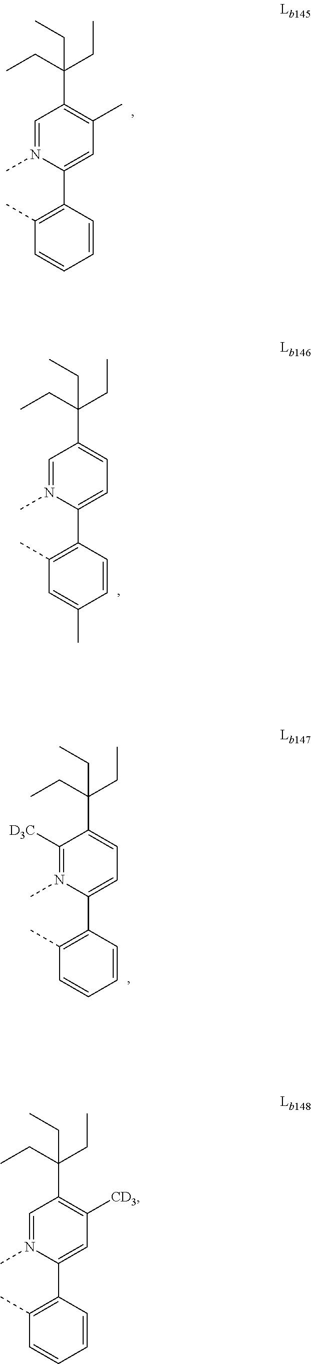 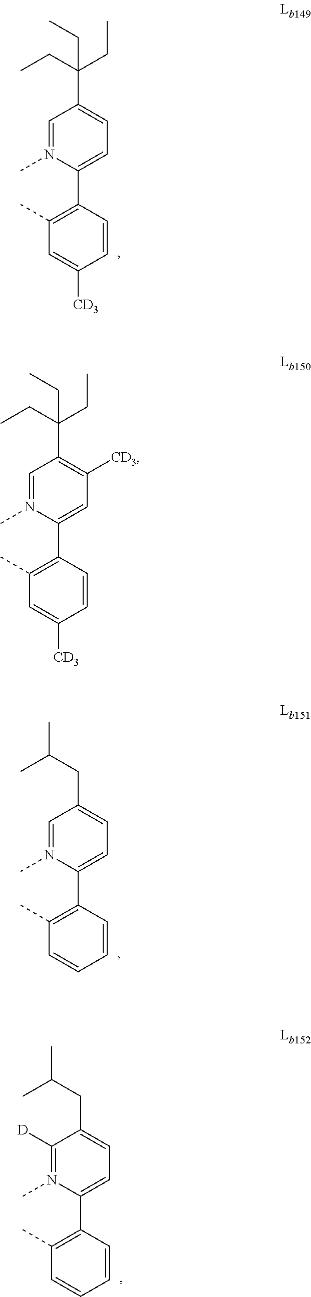 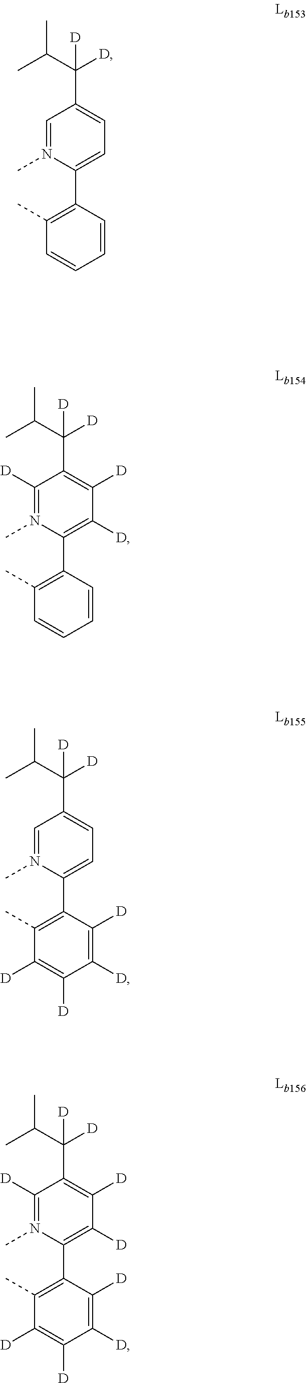 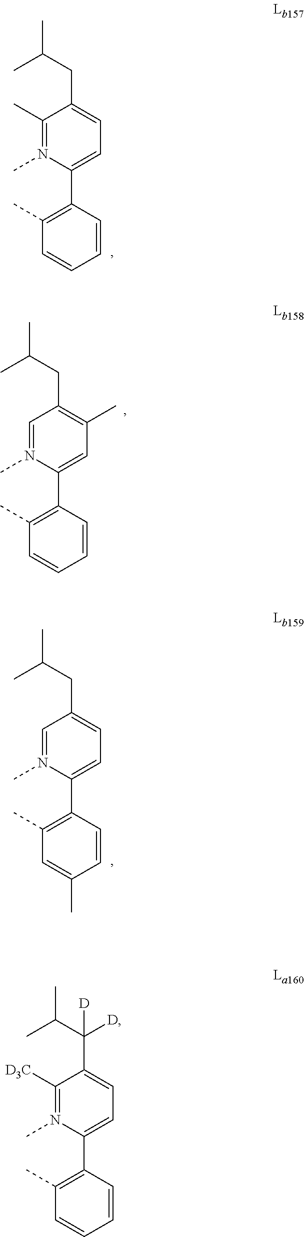 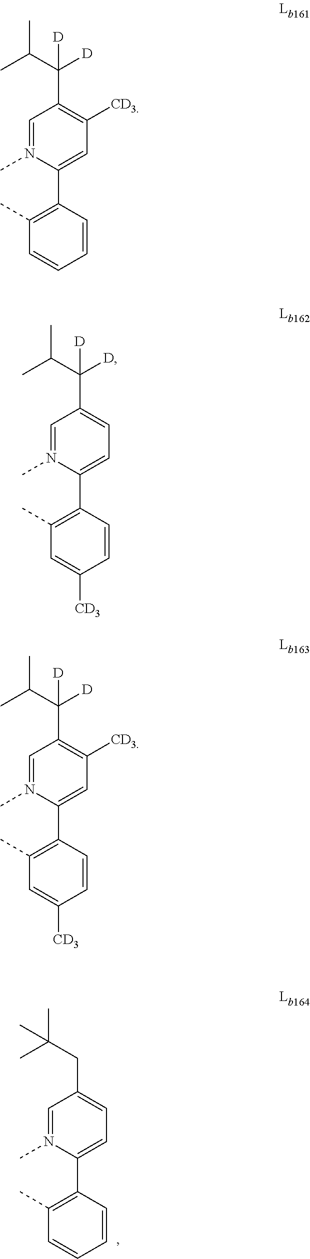 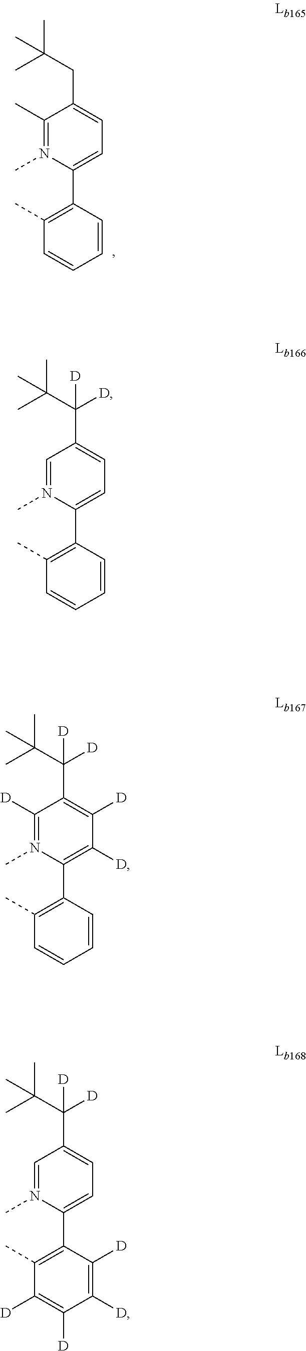 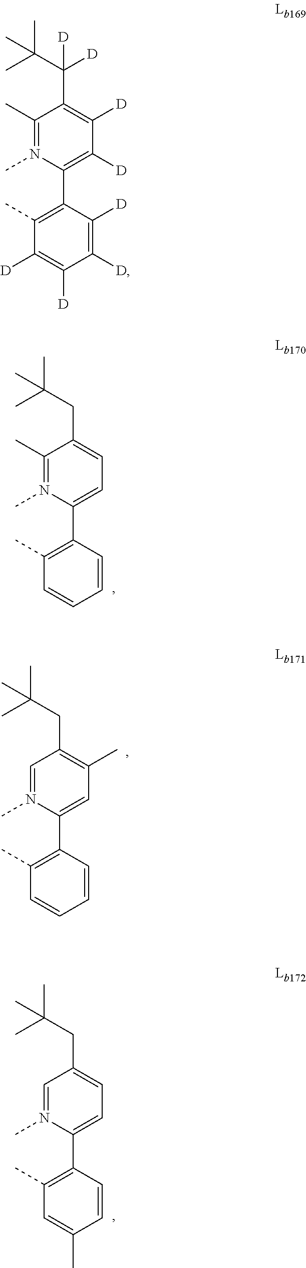 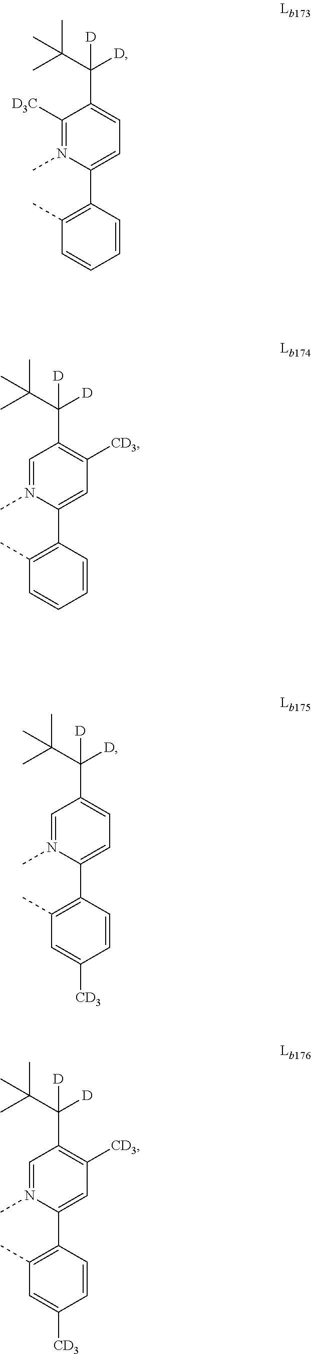 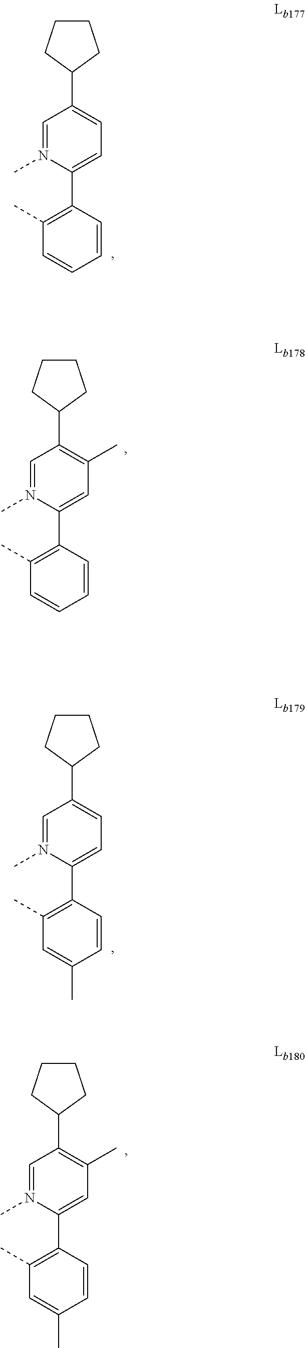 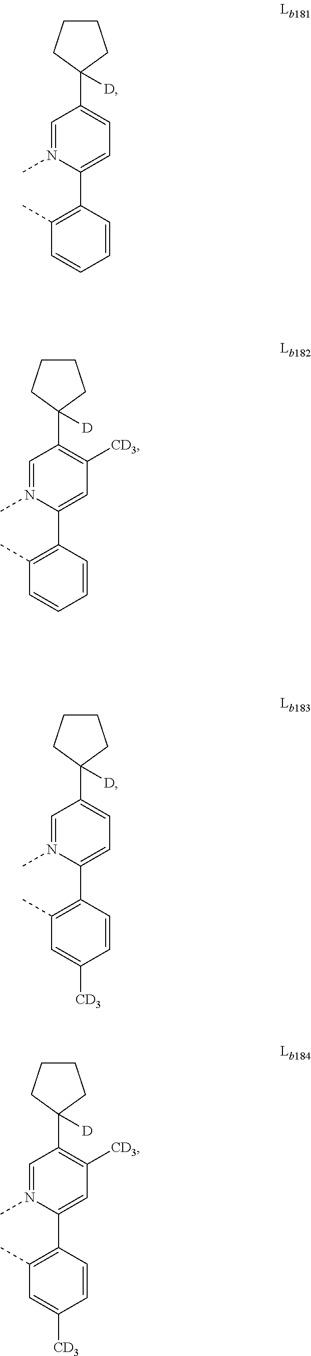 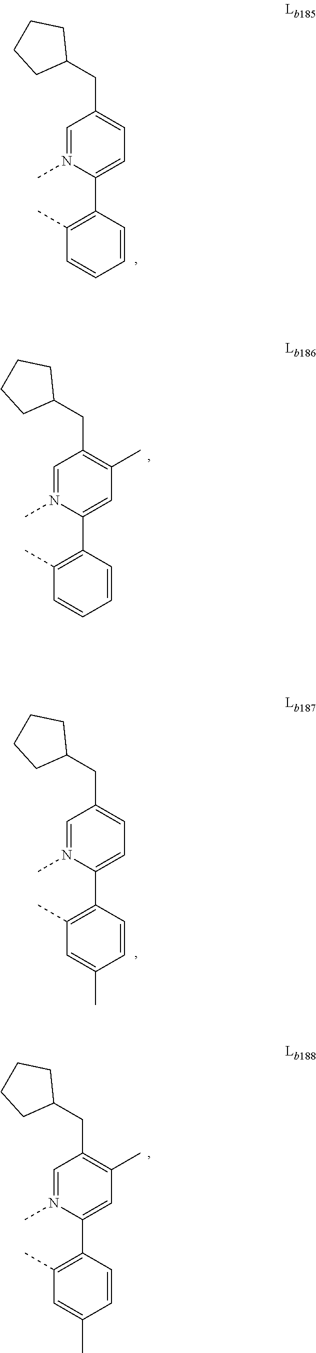 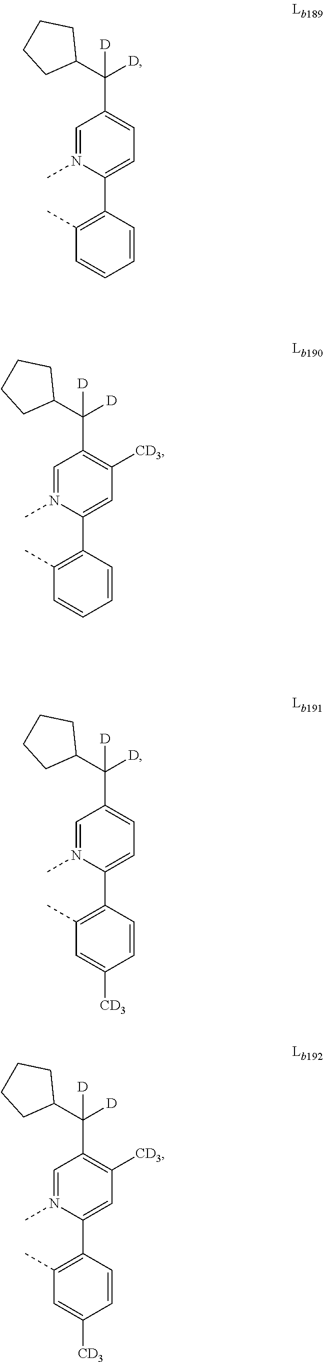 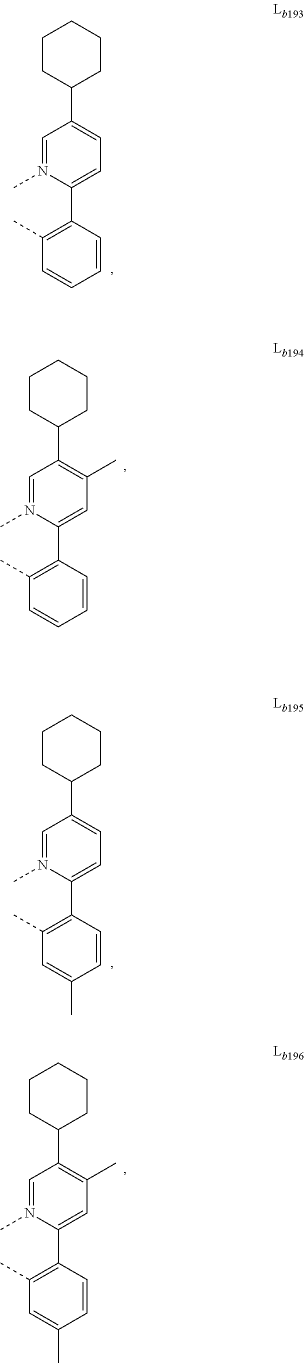 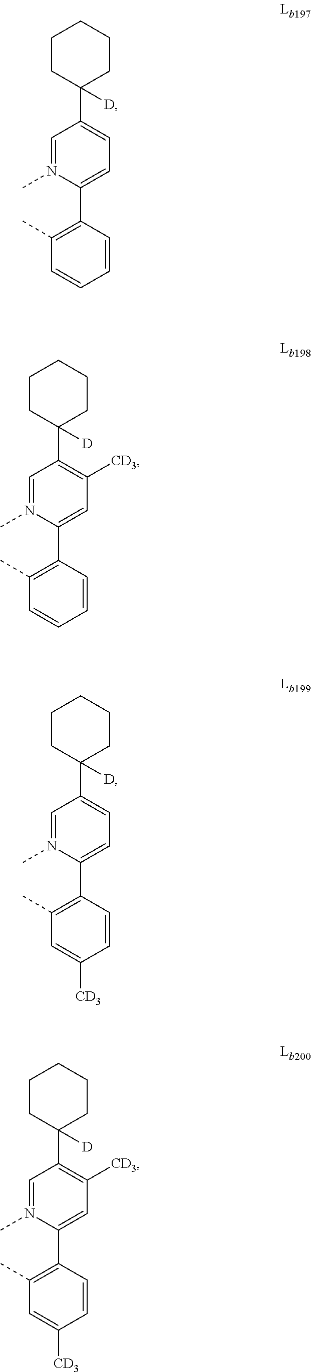 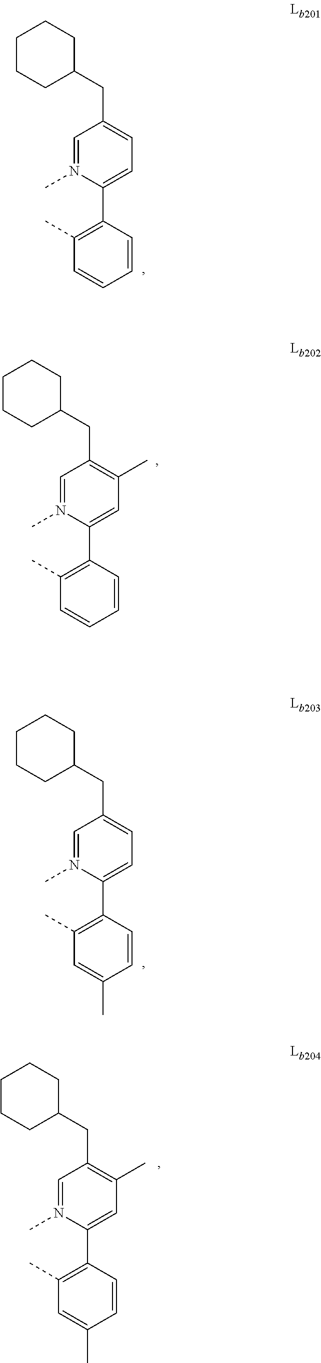 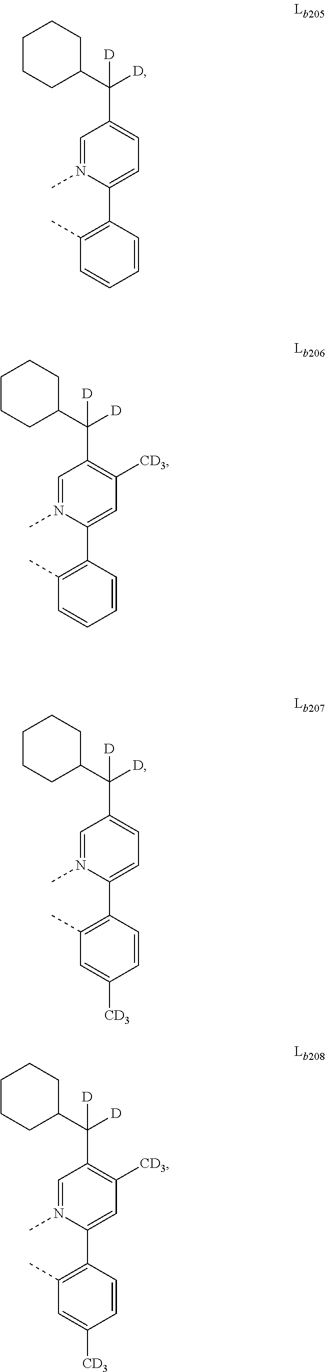 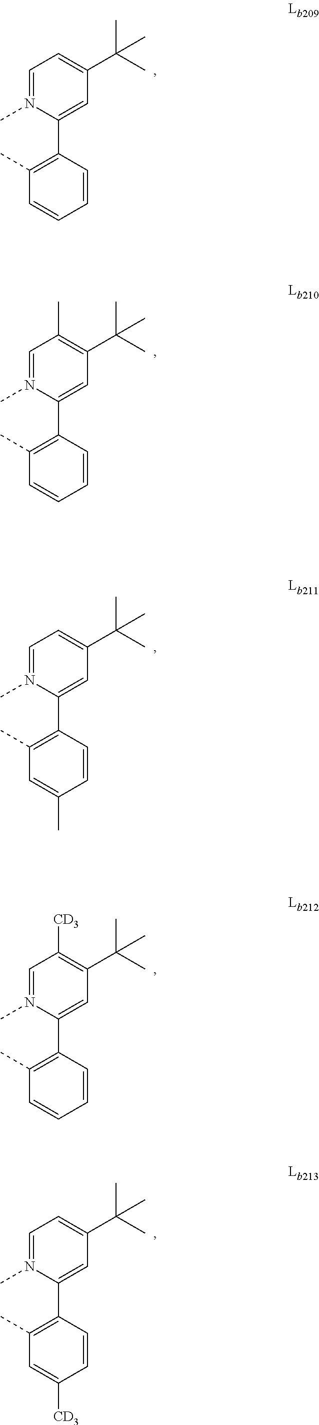 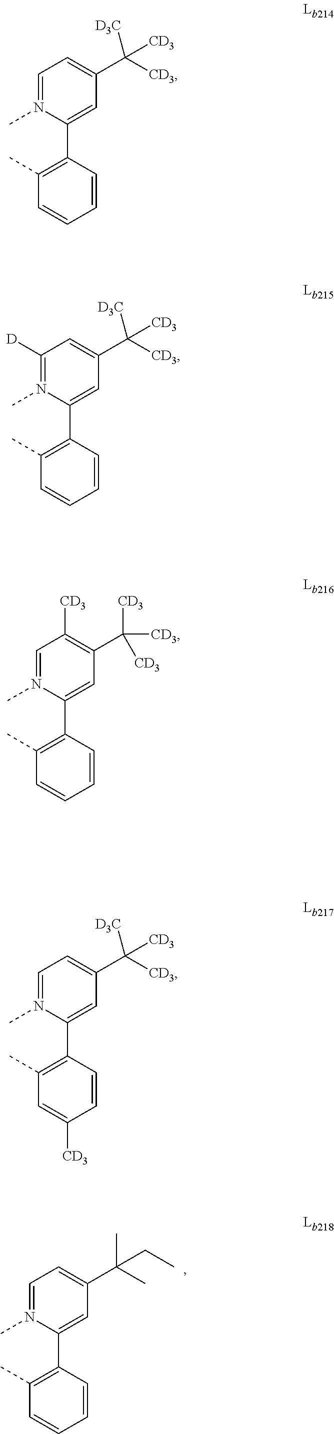 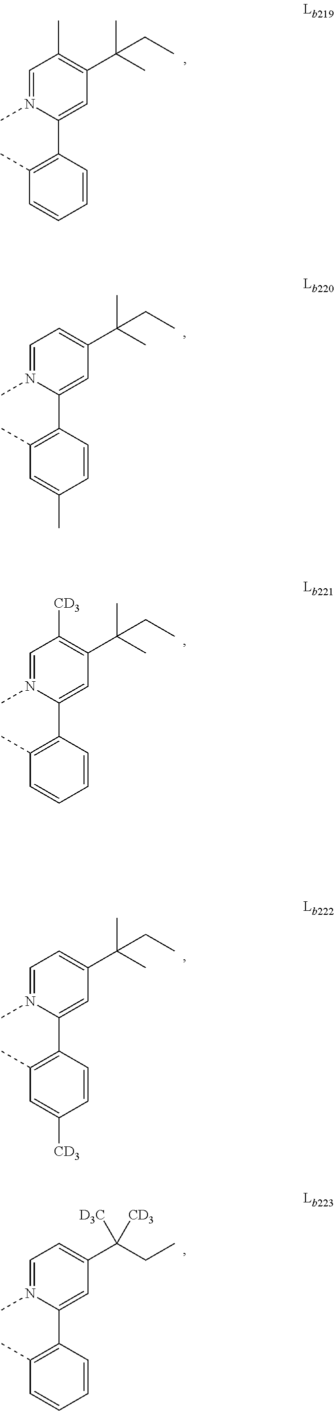 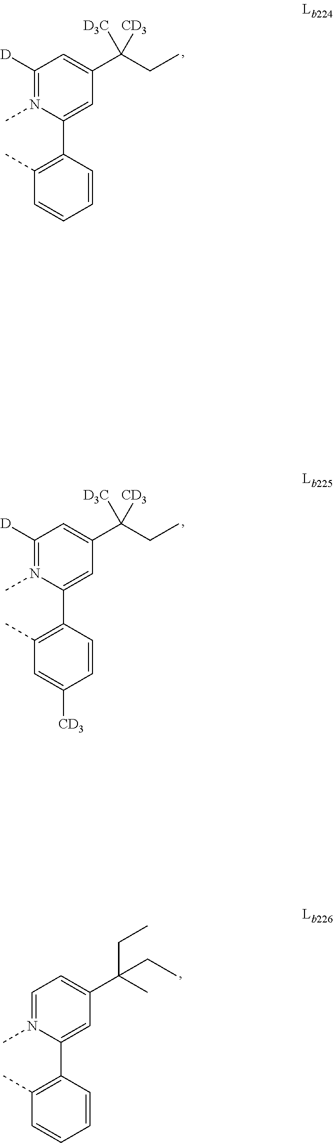 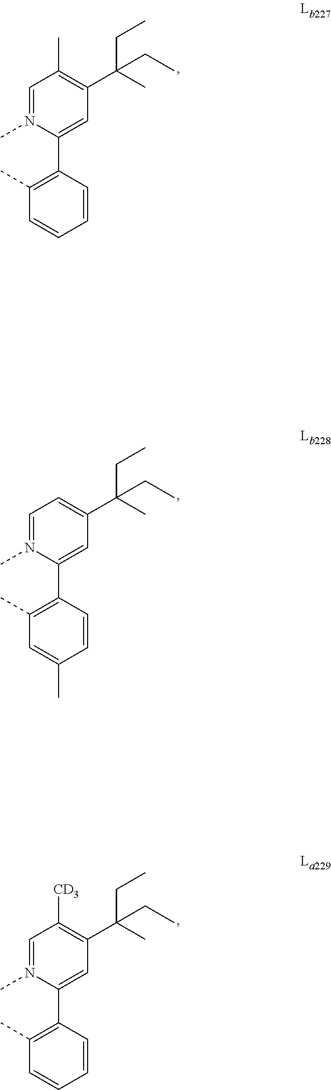 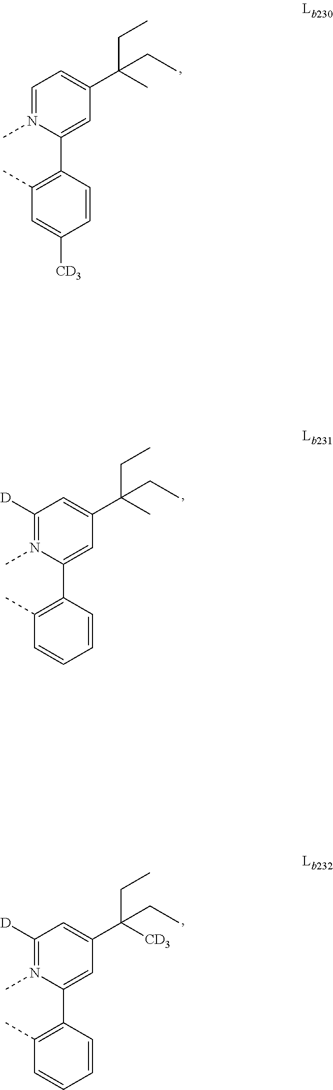 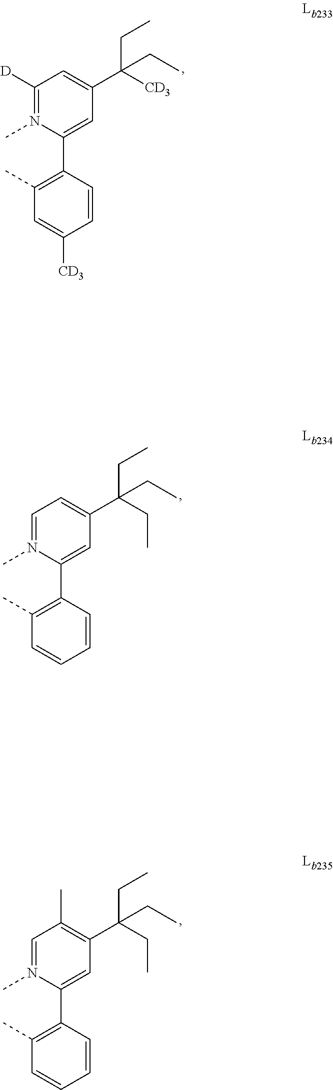 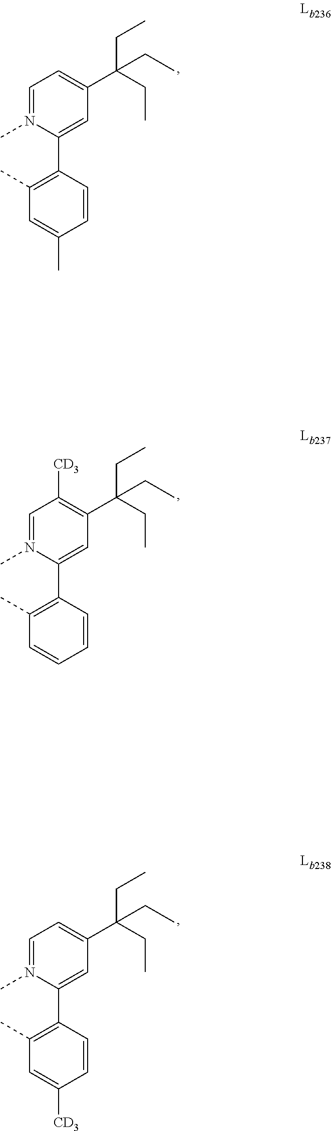 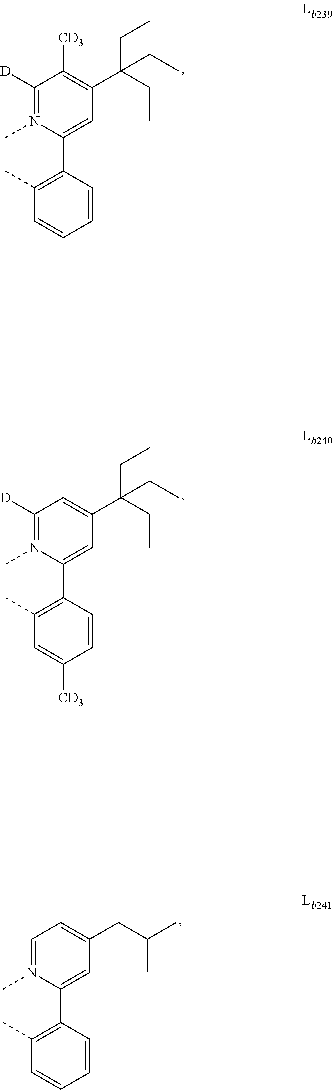 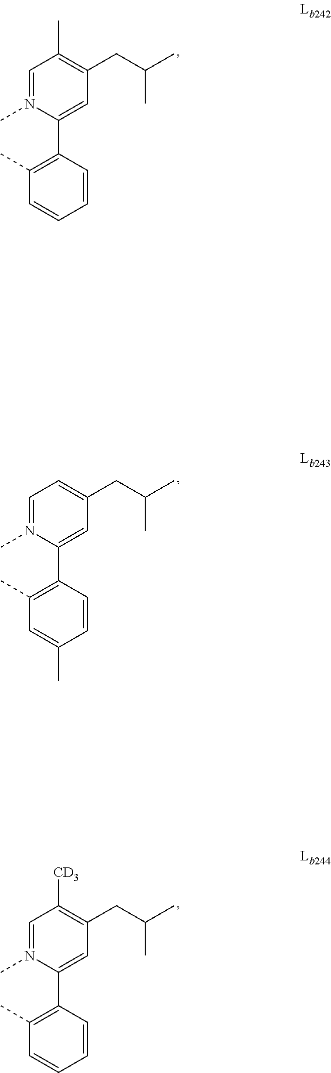 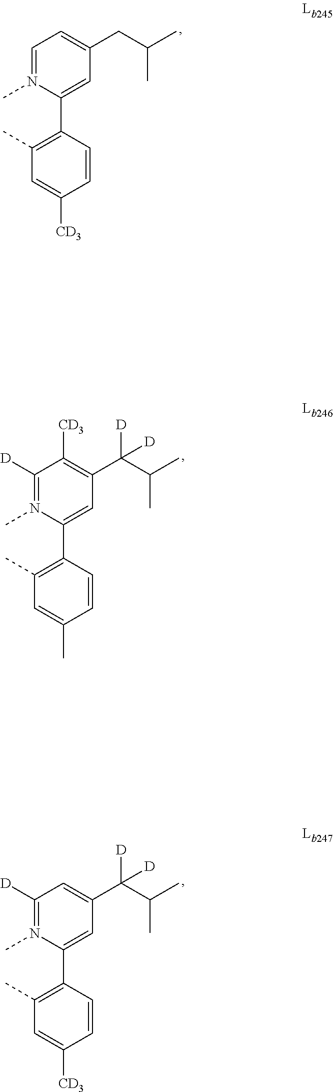 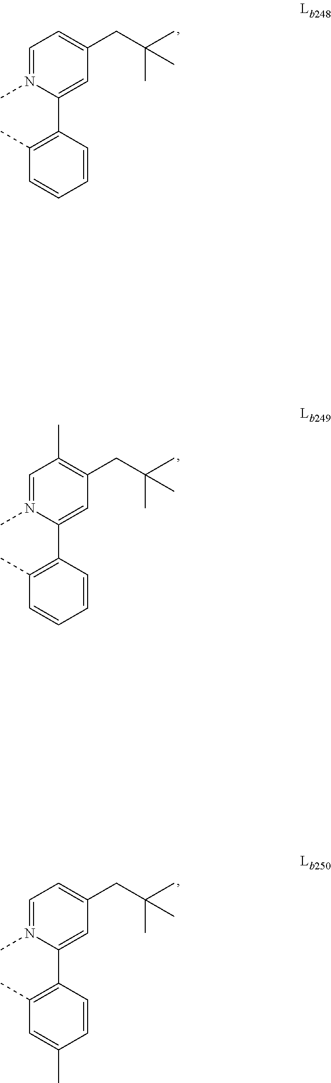 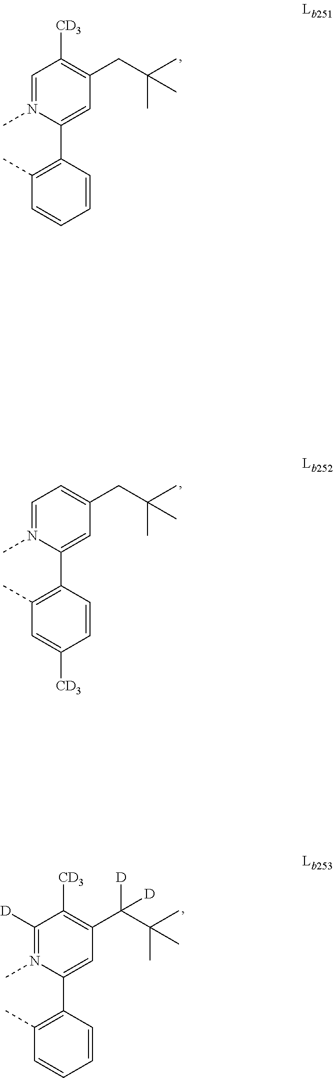 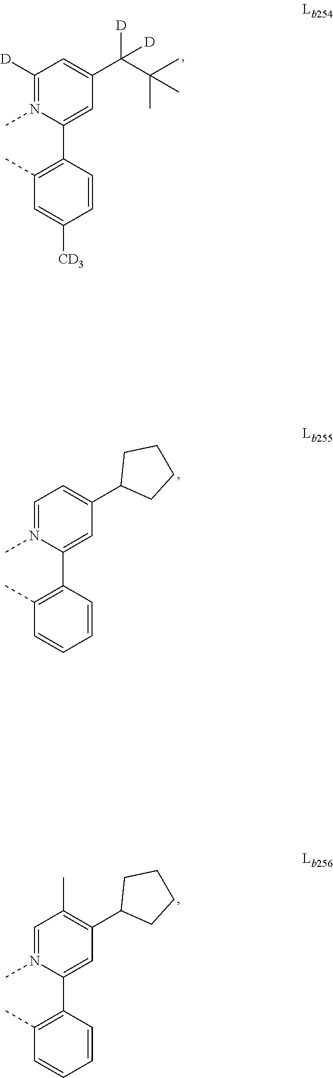 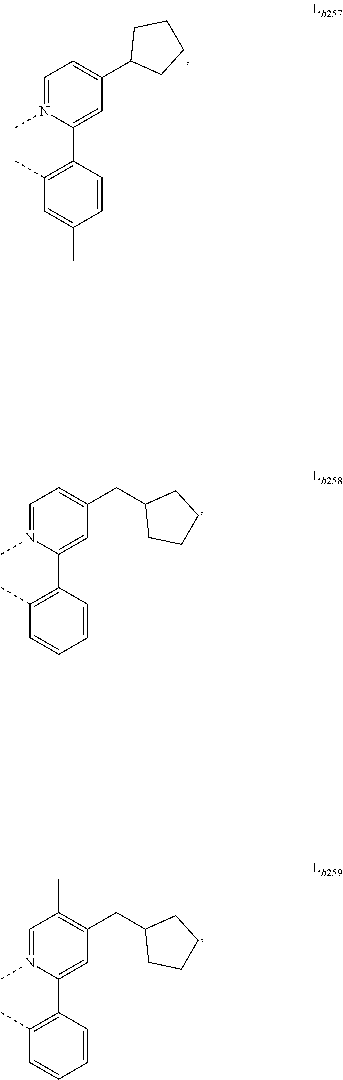 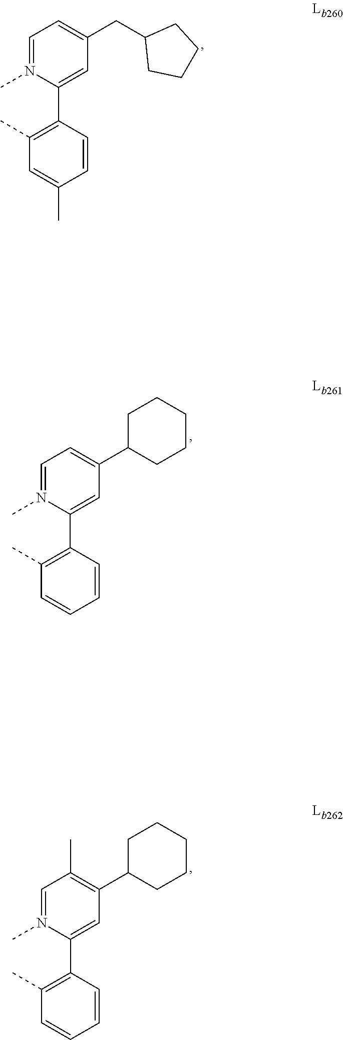 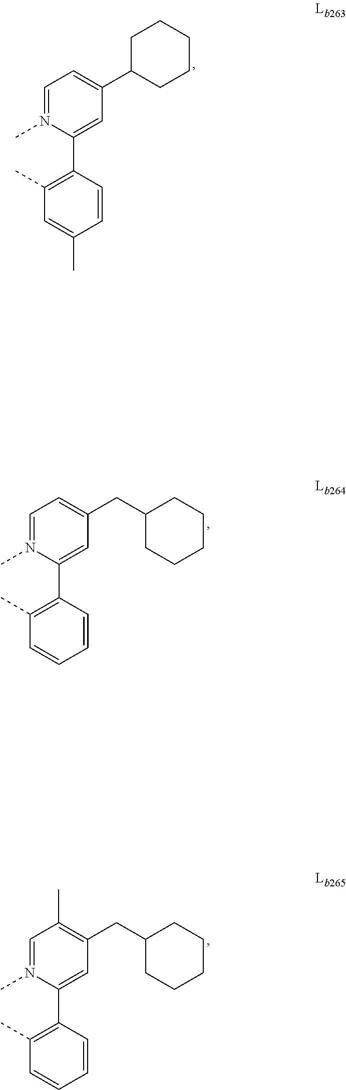 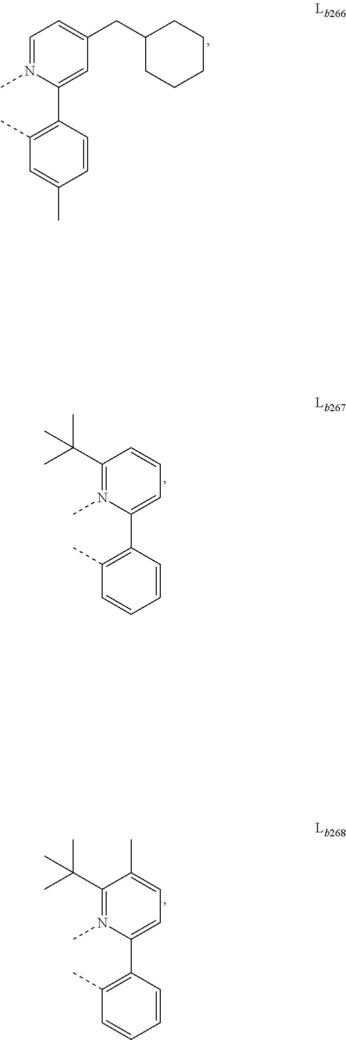 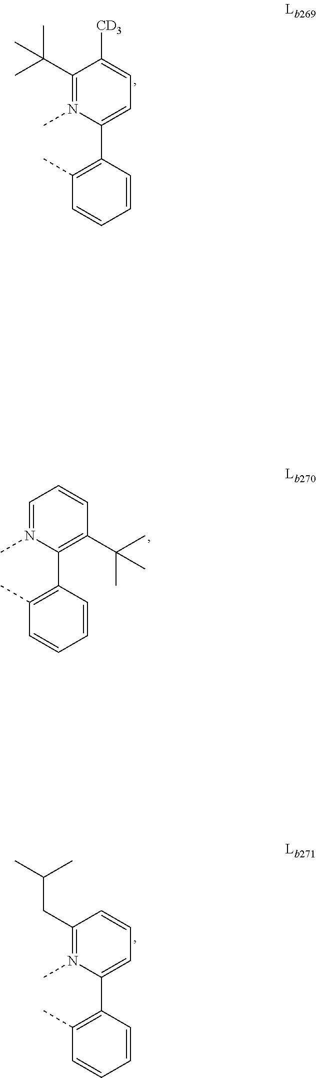 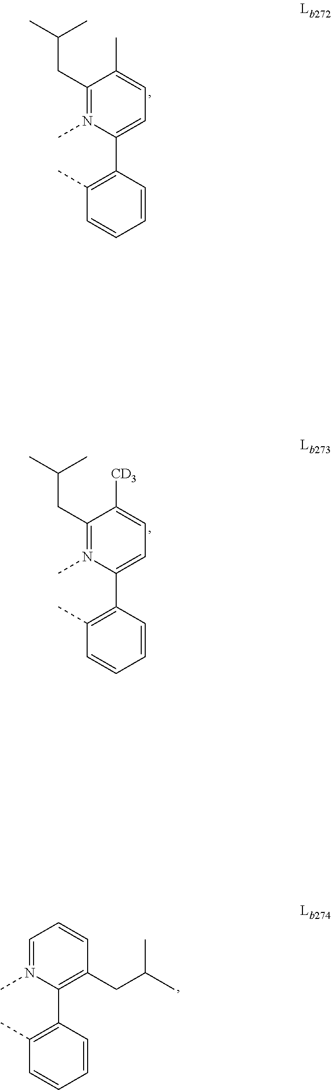 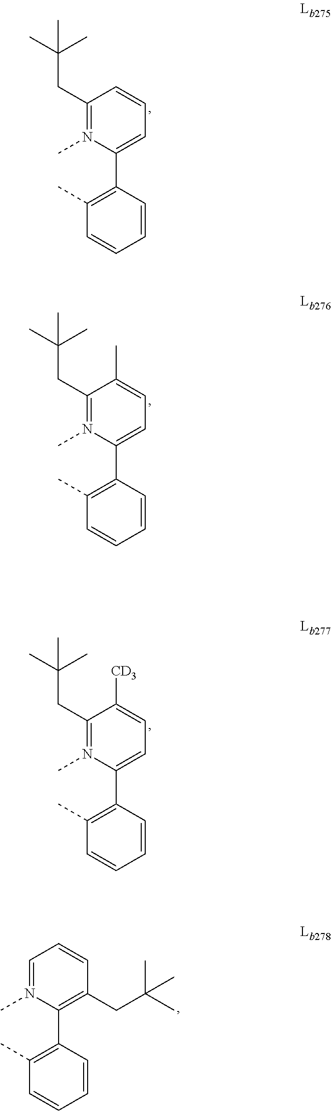 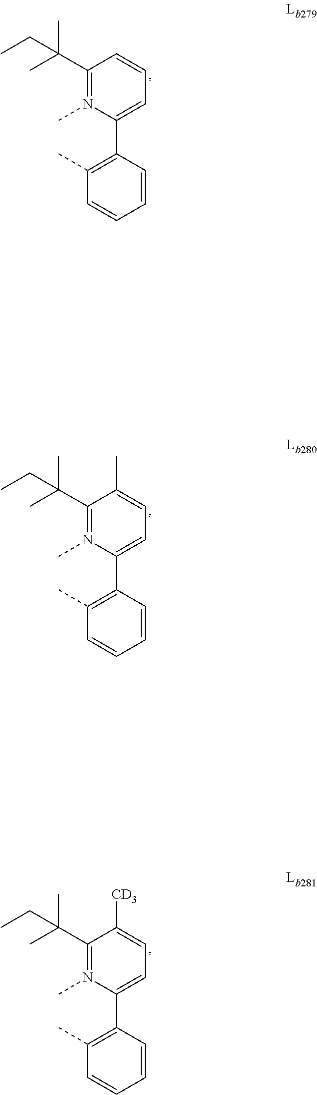 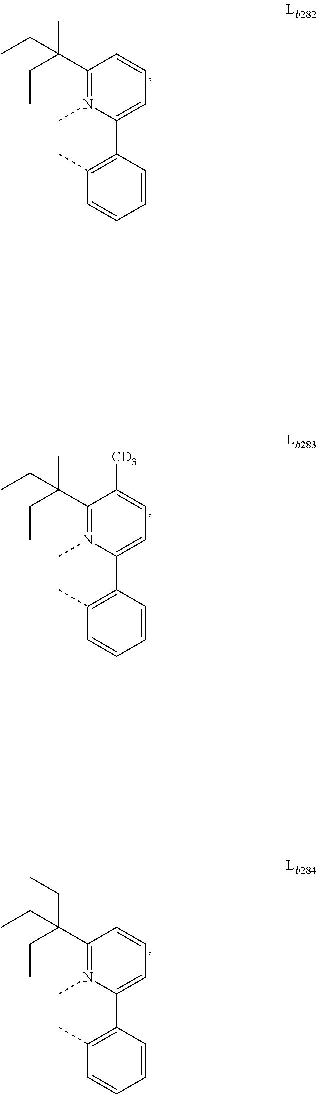 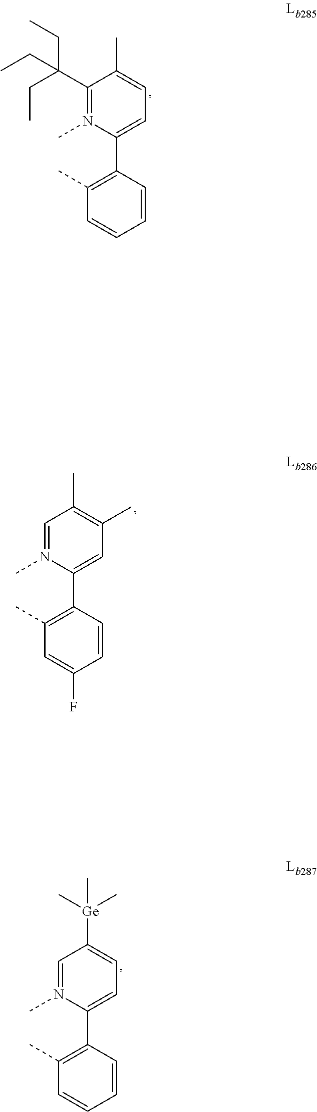 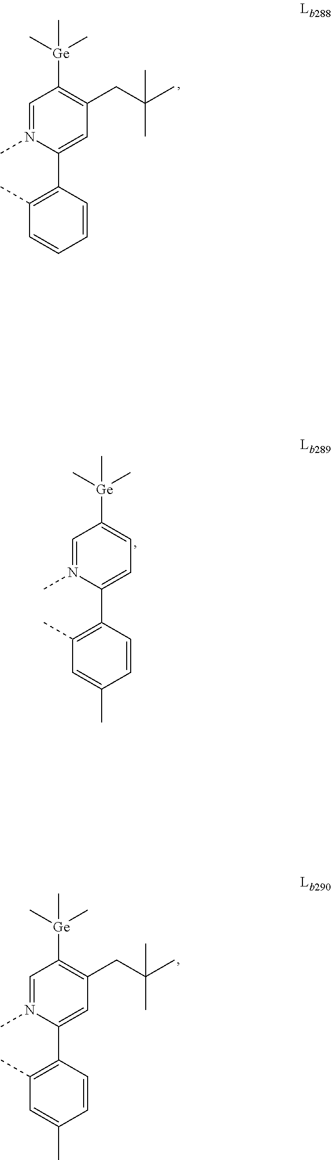 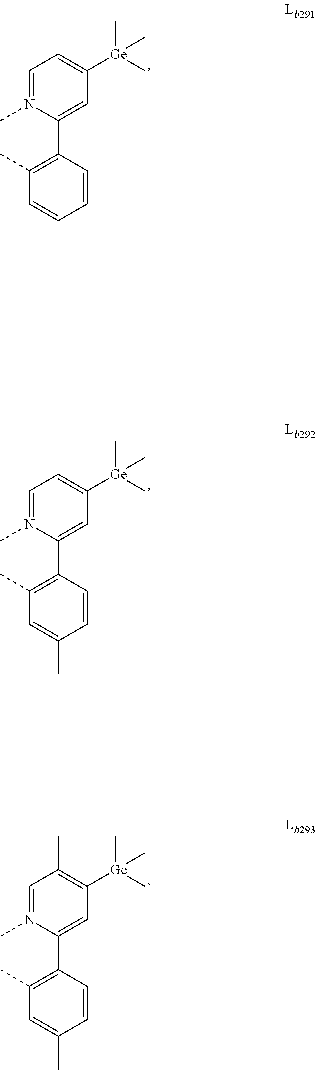 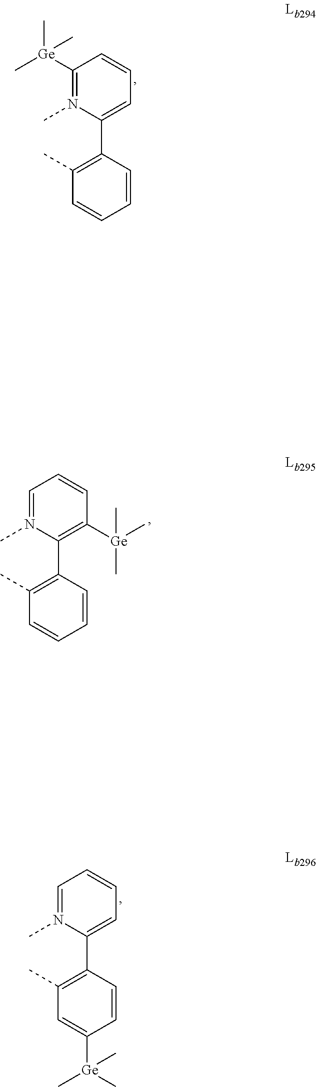 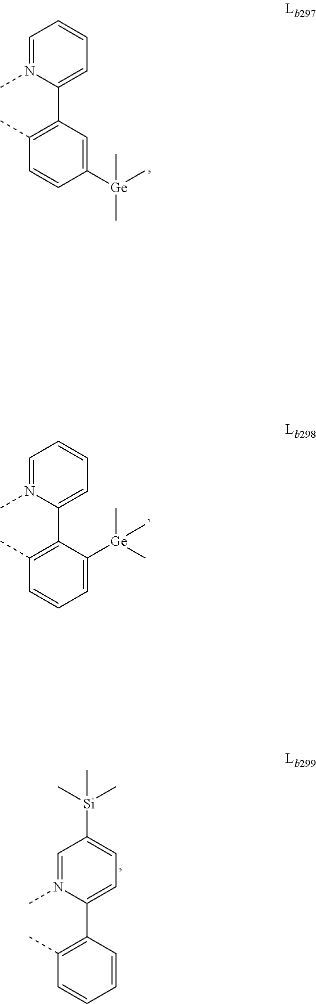 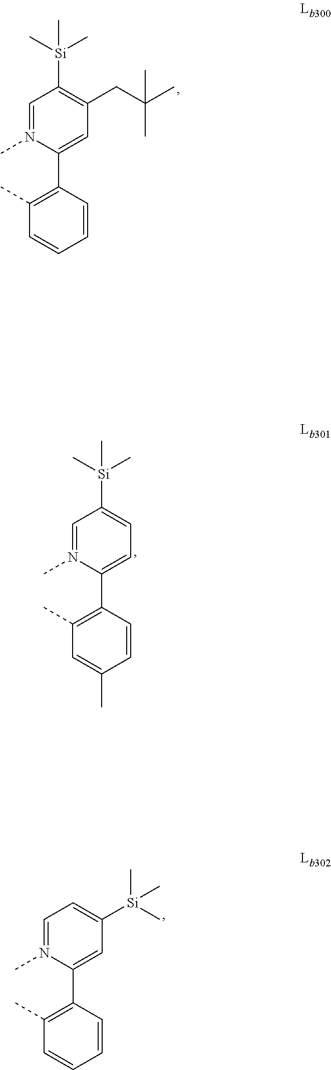 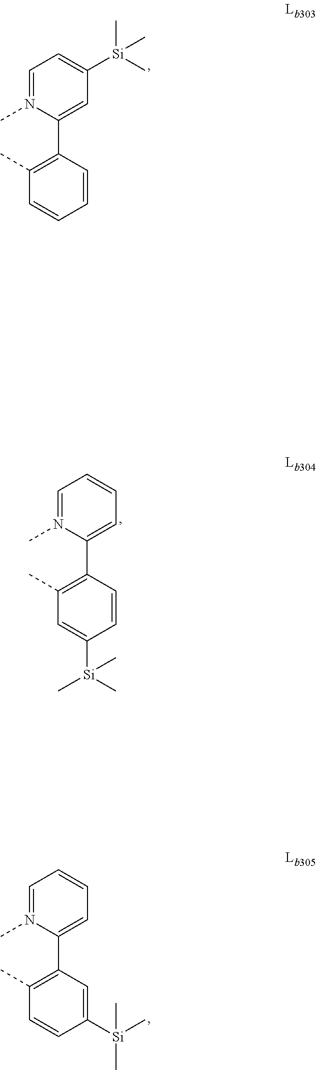 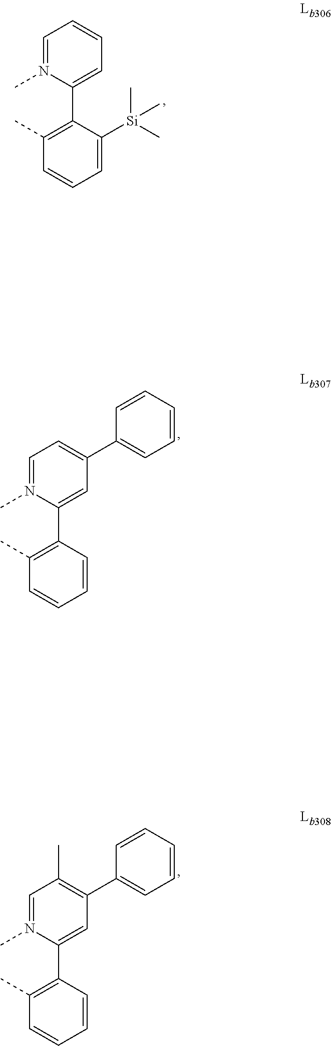 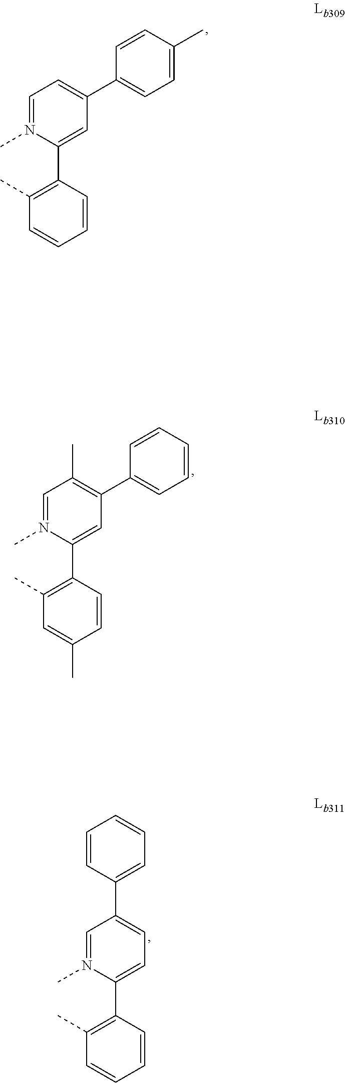 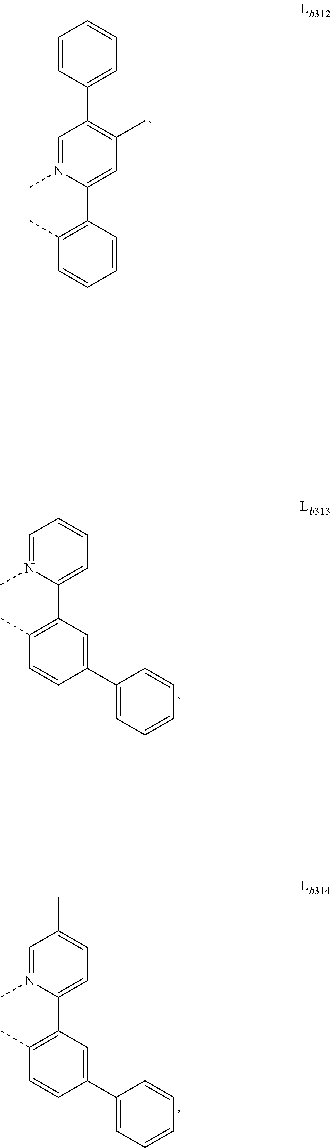 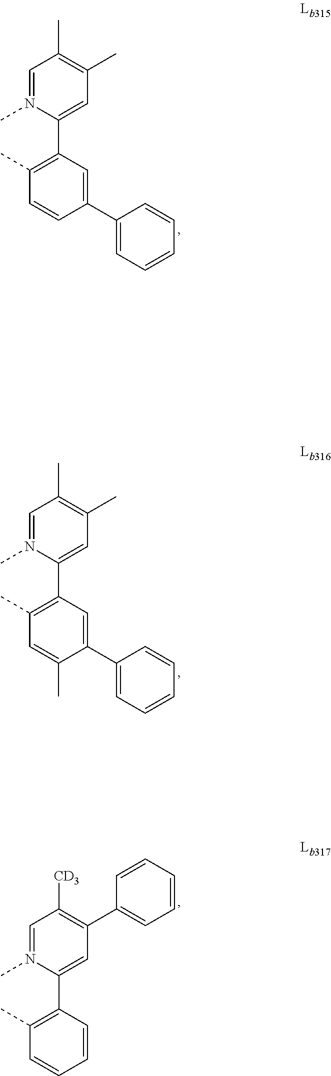 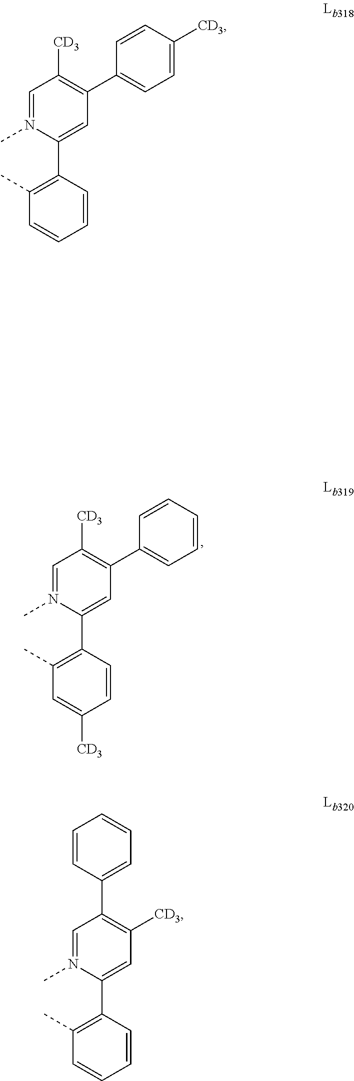 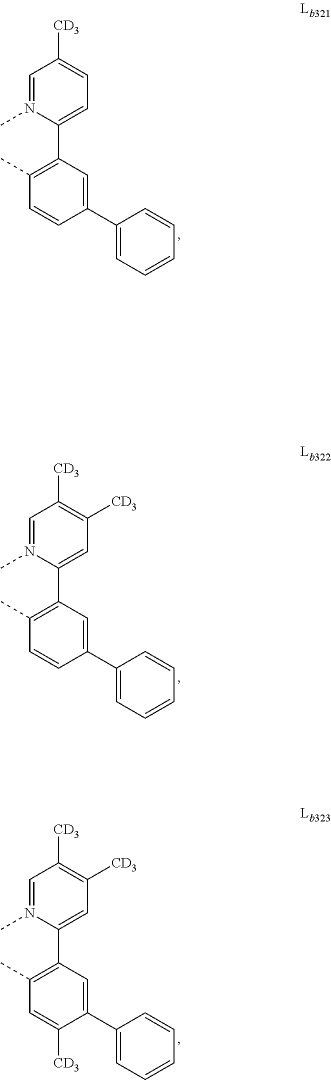 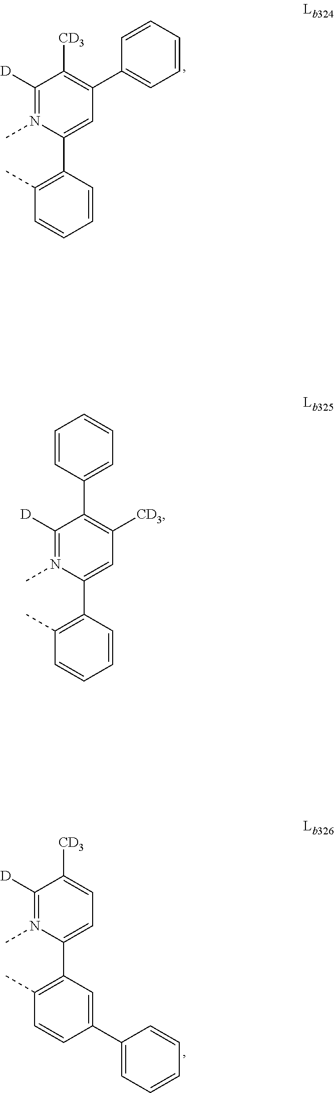 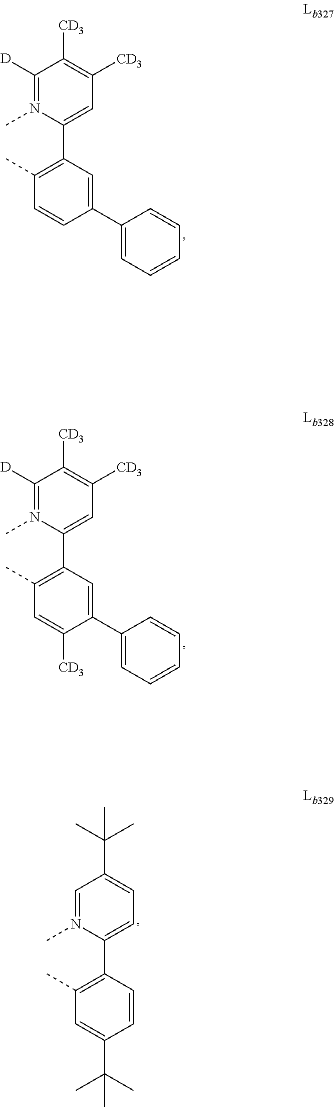 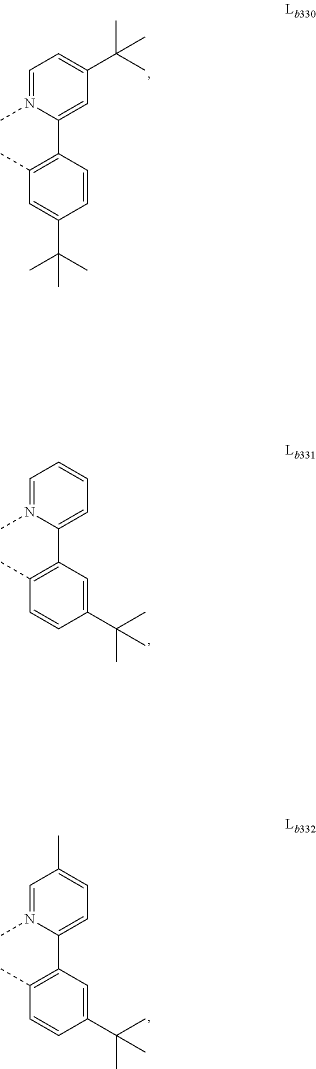 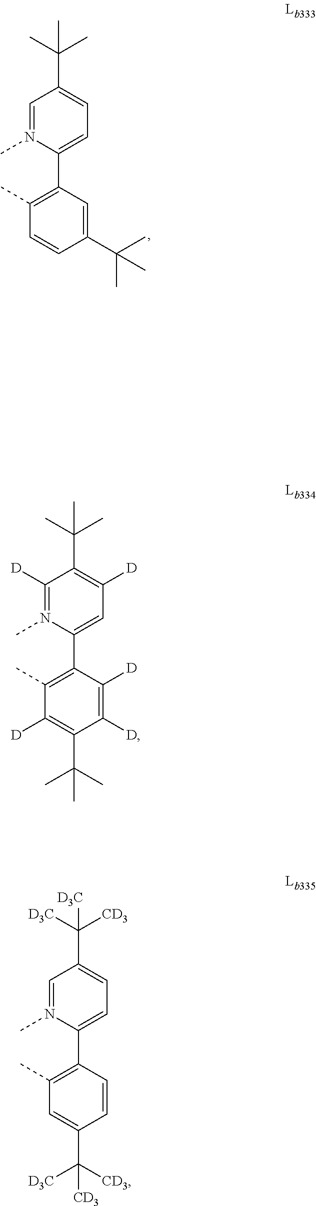 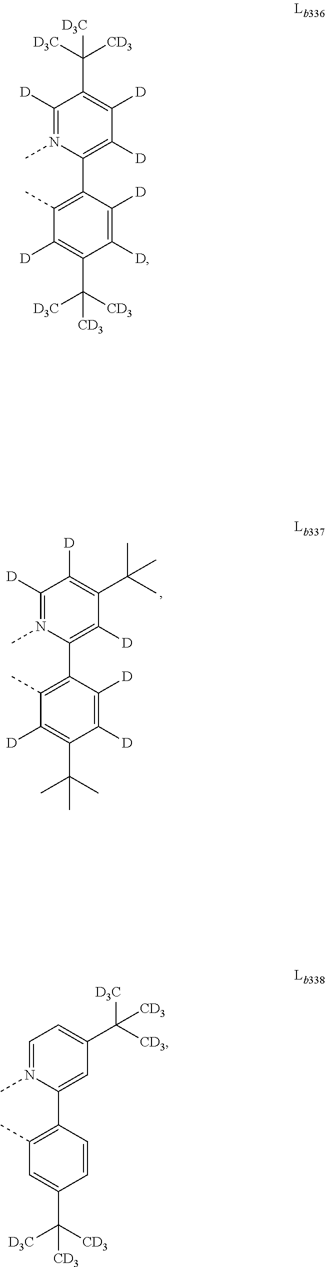 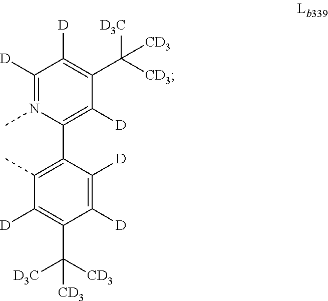
wherein optionally, hydrogen atoms in L_{b1} to L_{b339} can be partially or fully substituted with deuterium.

14. The metal complex according to claim 1, wherein Le is, at each occurrence identically or differently, selected from the group consisting of the following structures: 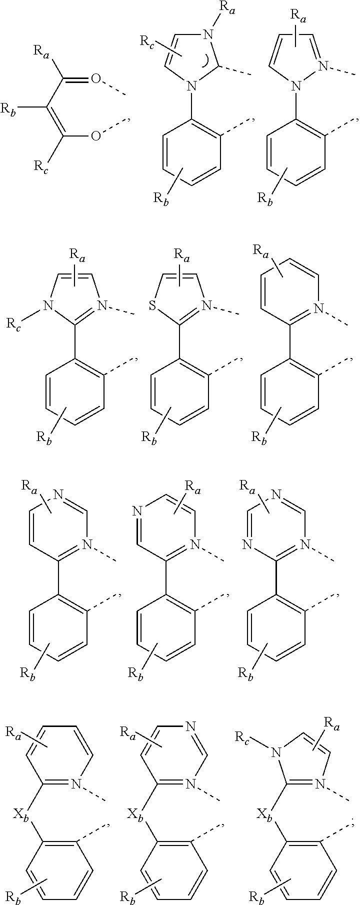
Rₐ, R_{b} and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{C1} and R_{C2} can be optionally joined to form a ring.

15. The metal complex according to claim 1, wherein the metal M is selected from Ir, Rh, Re, Os, Pt, Au or Cu; preferably, the metal M is selected from Ir, Pt or Os; more preferably, the metal M is Ir.

16. The metal complex according to claim 13, wherein Le is, at each occurrence identically or differently, selected from the group consisting of the following structures: 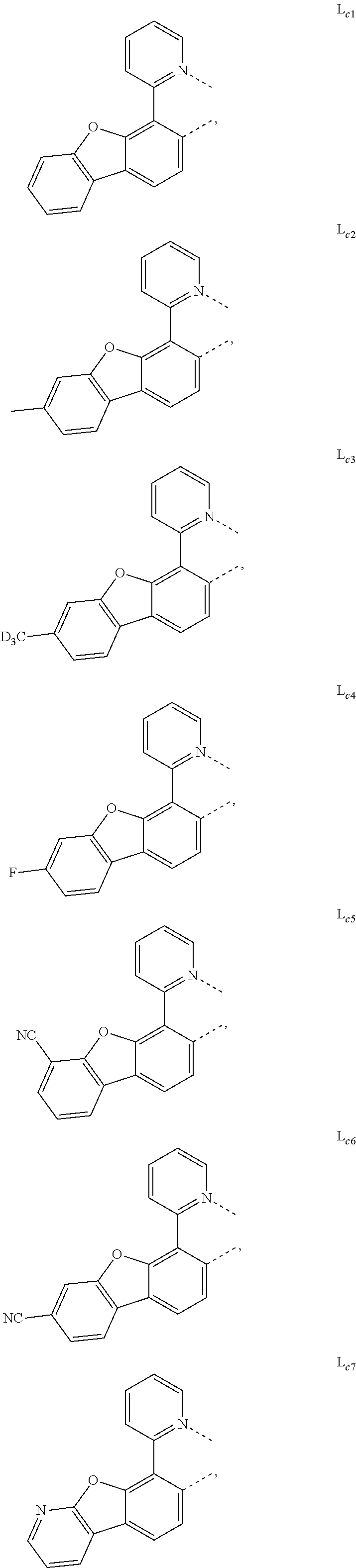 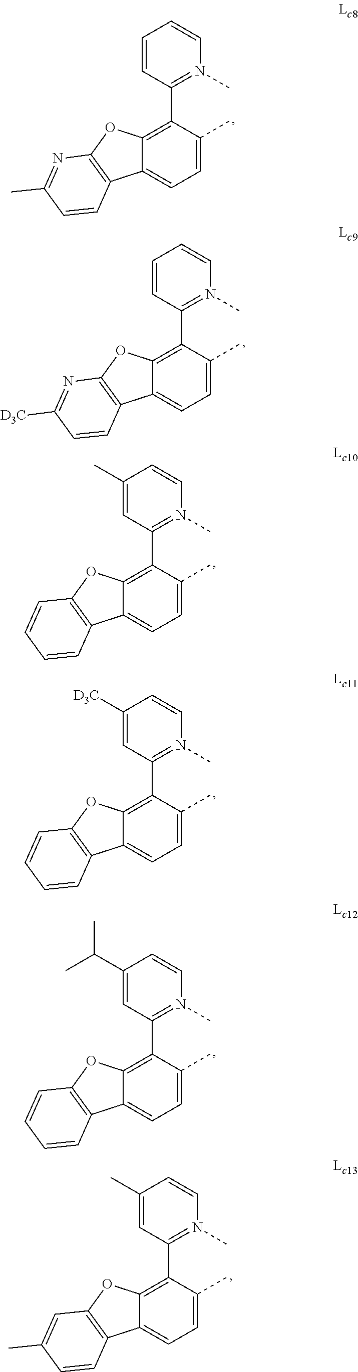 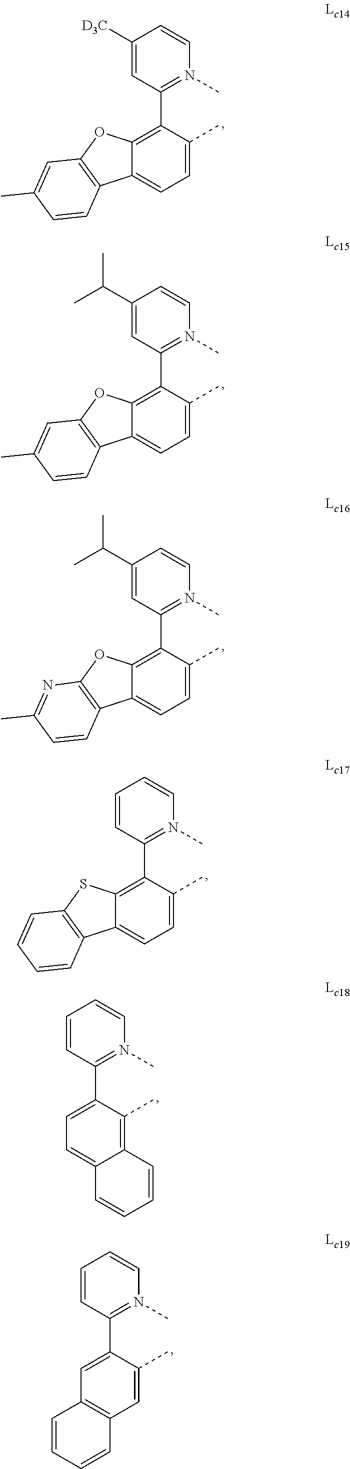 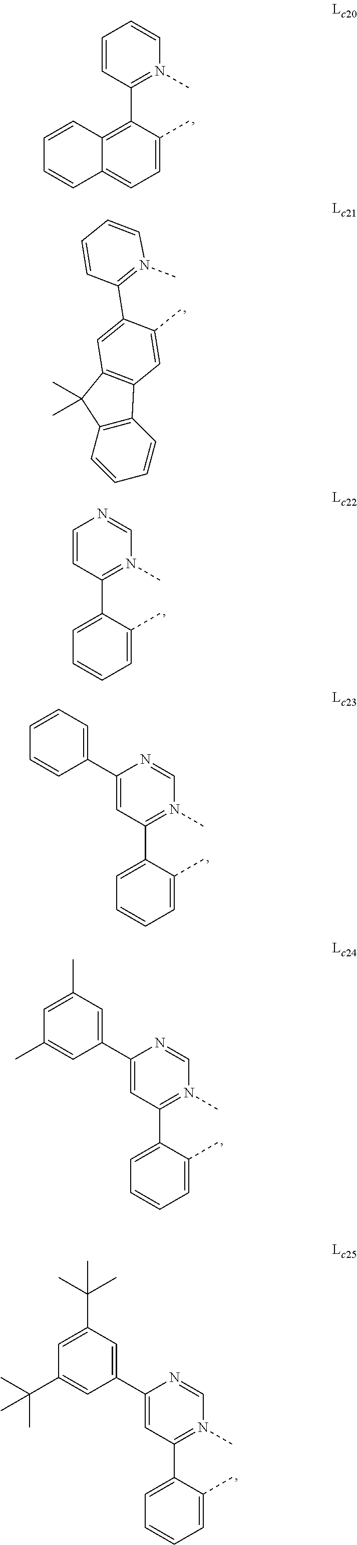 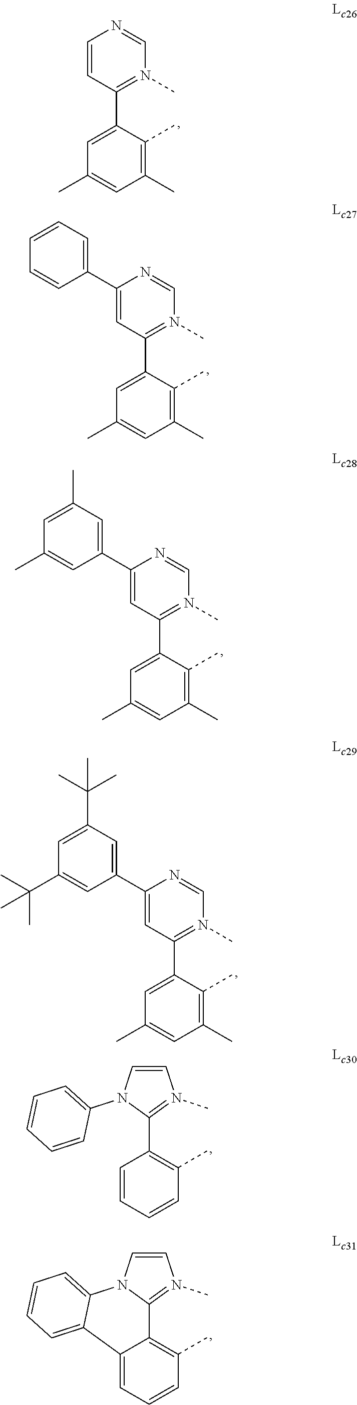 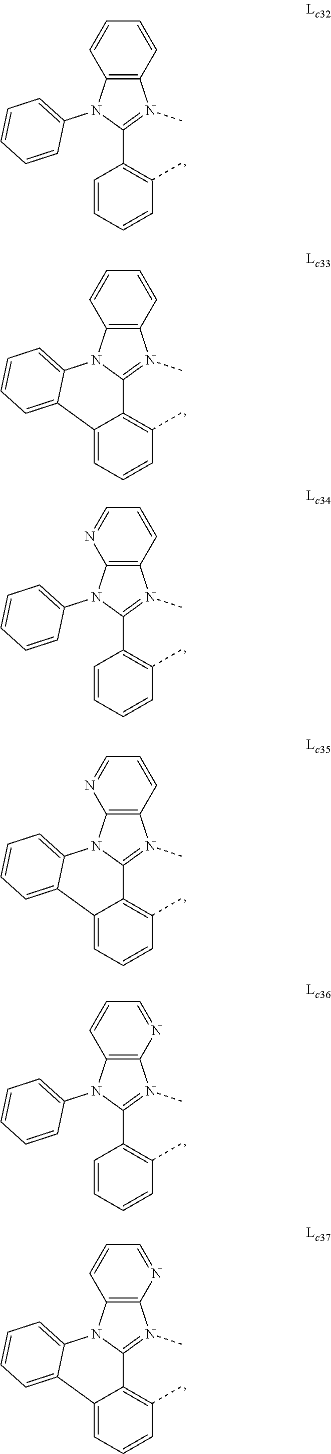 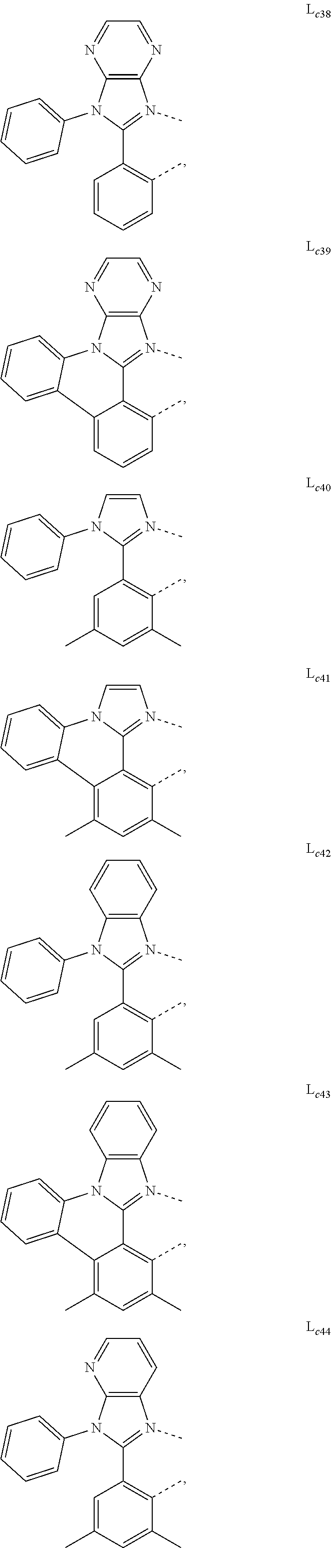 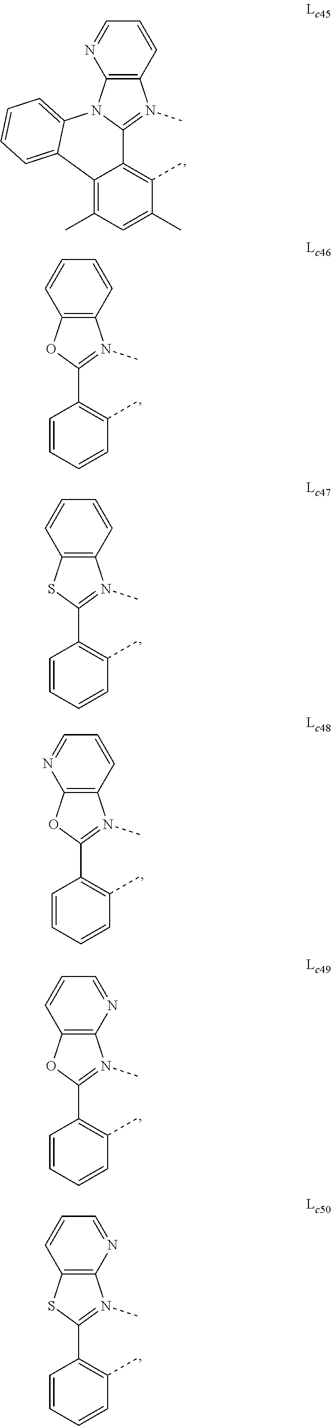 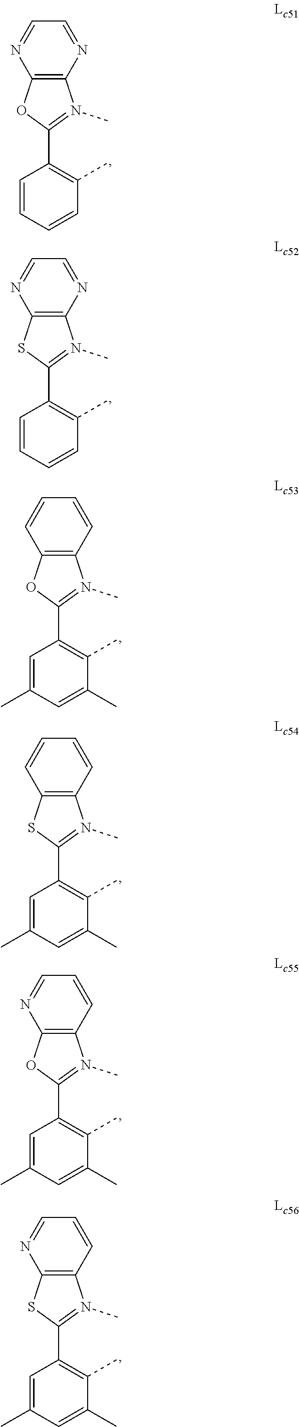 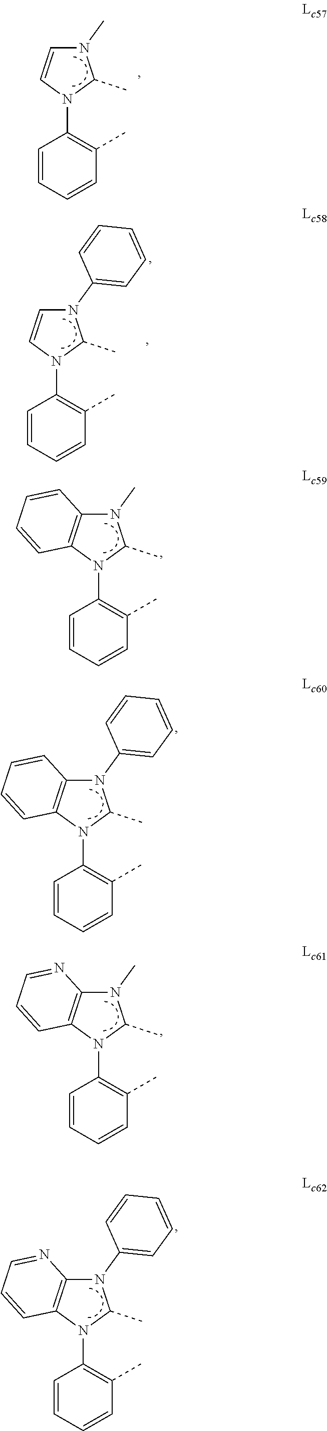 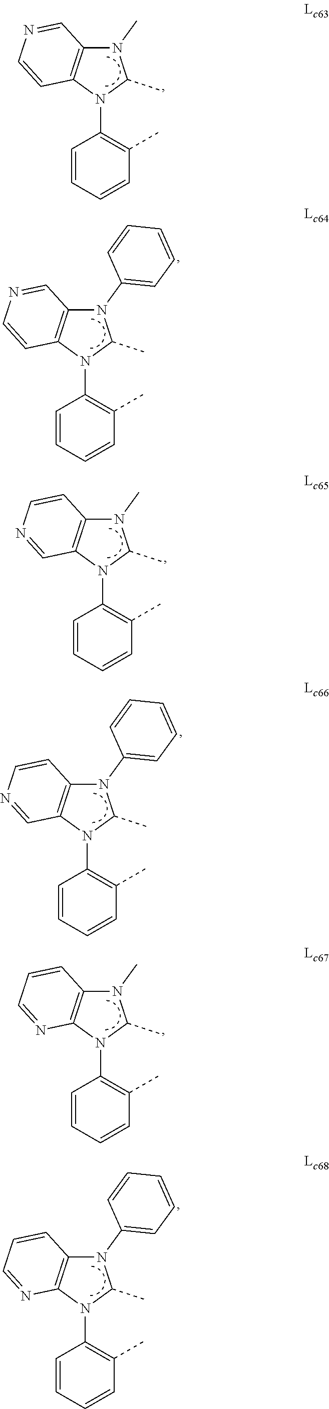 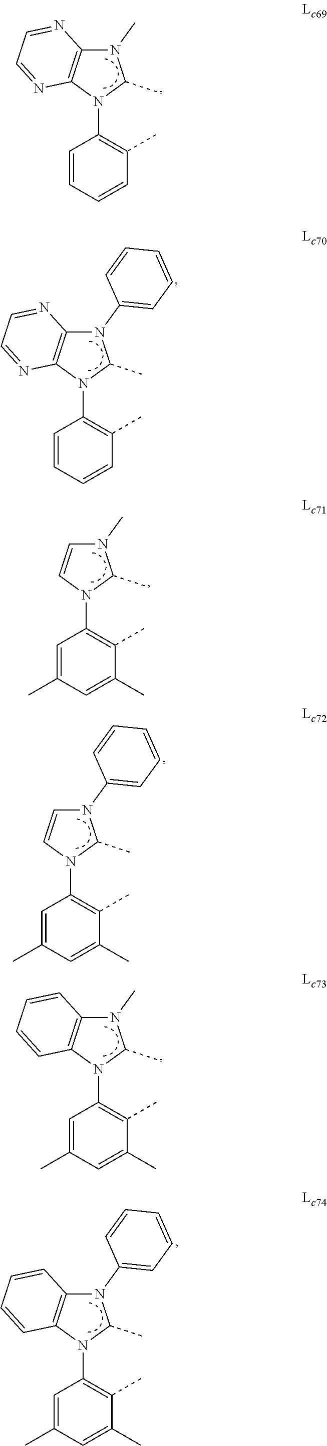 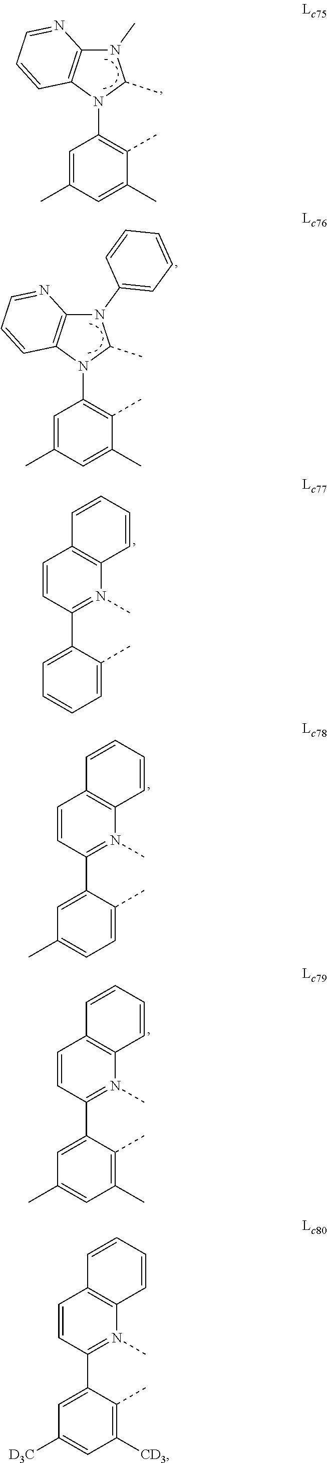 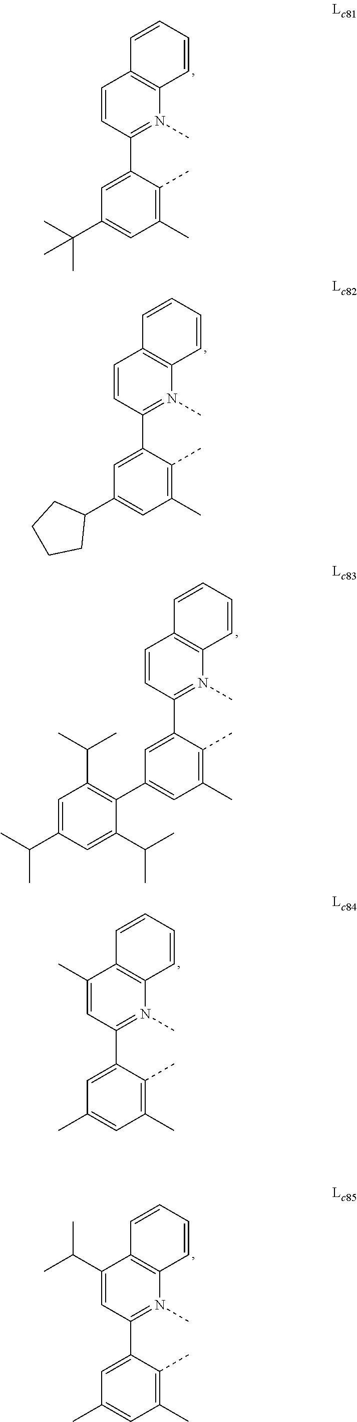 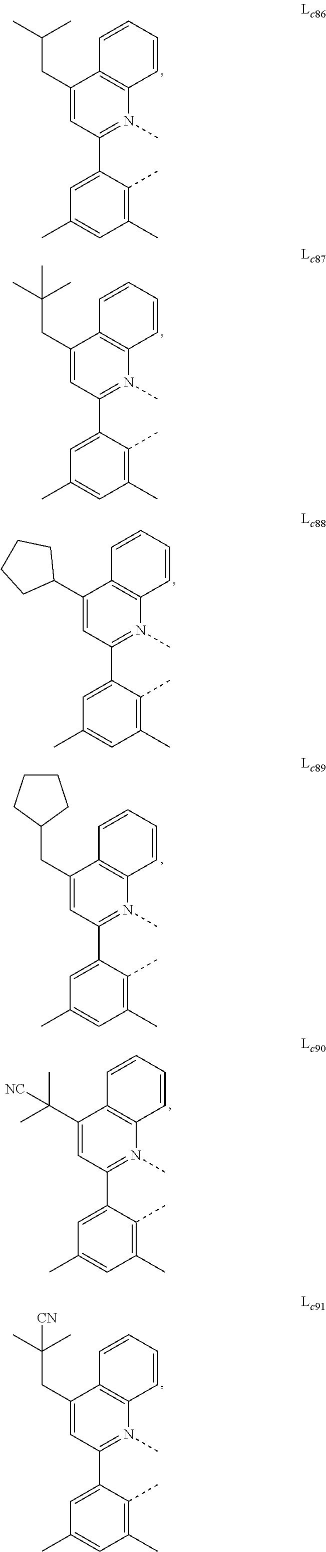 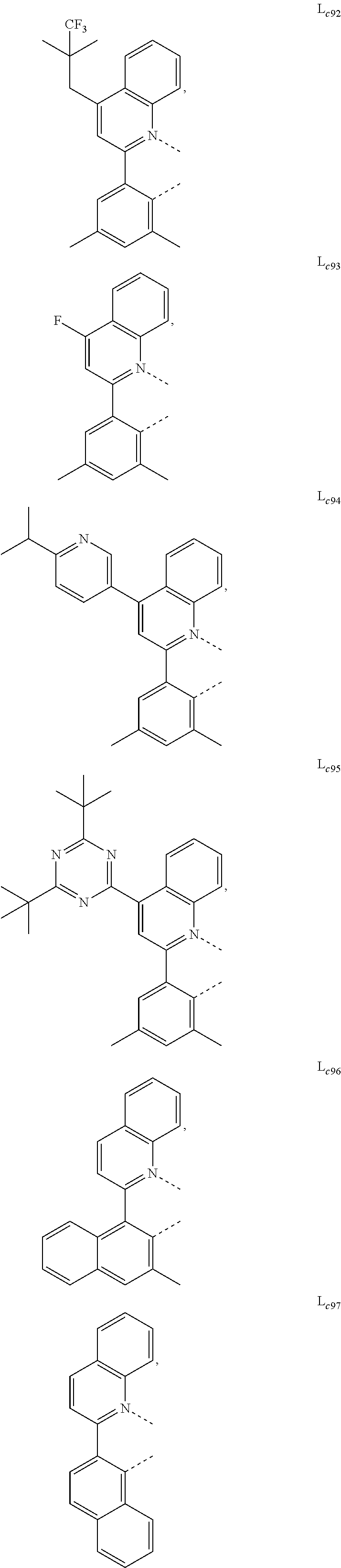 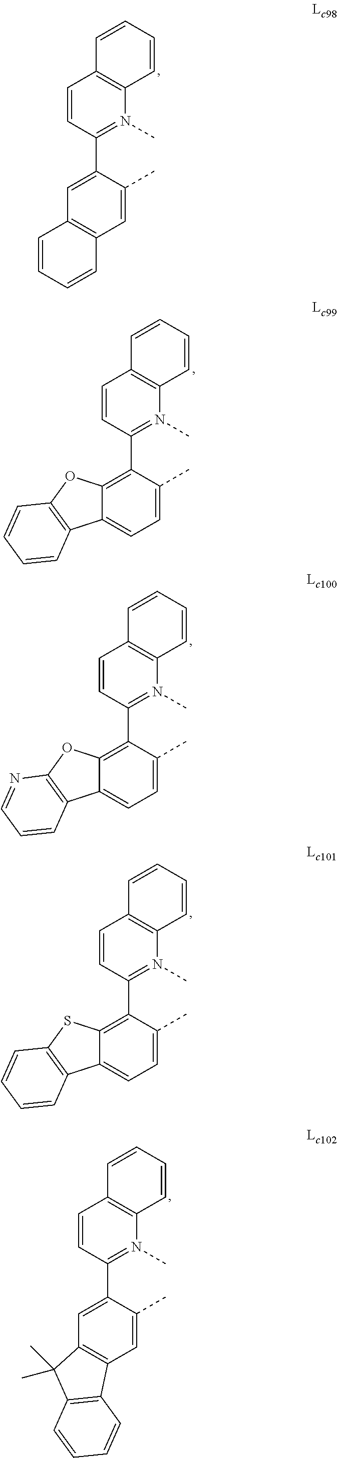 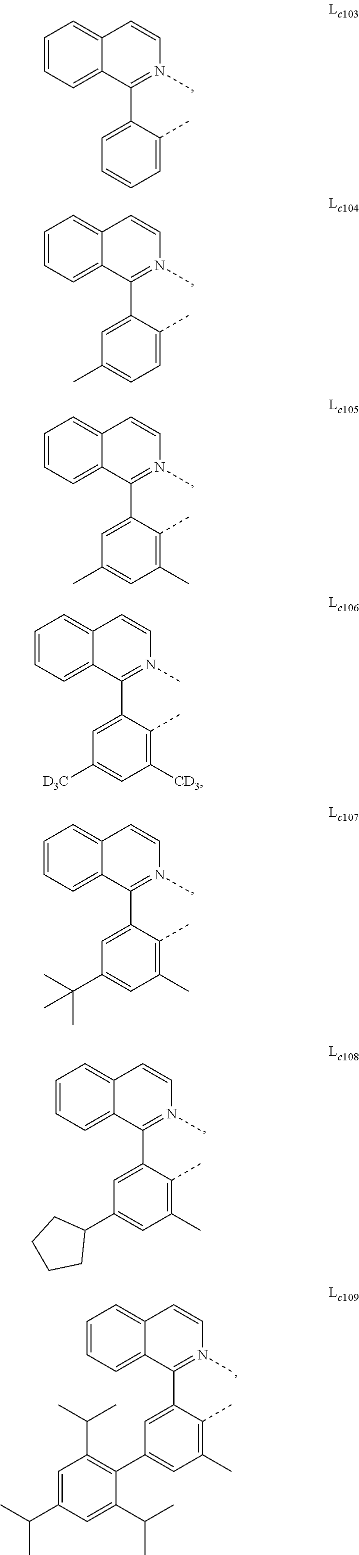 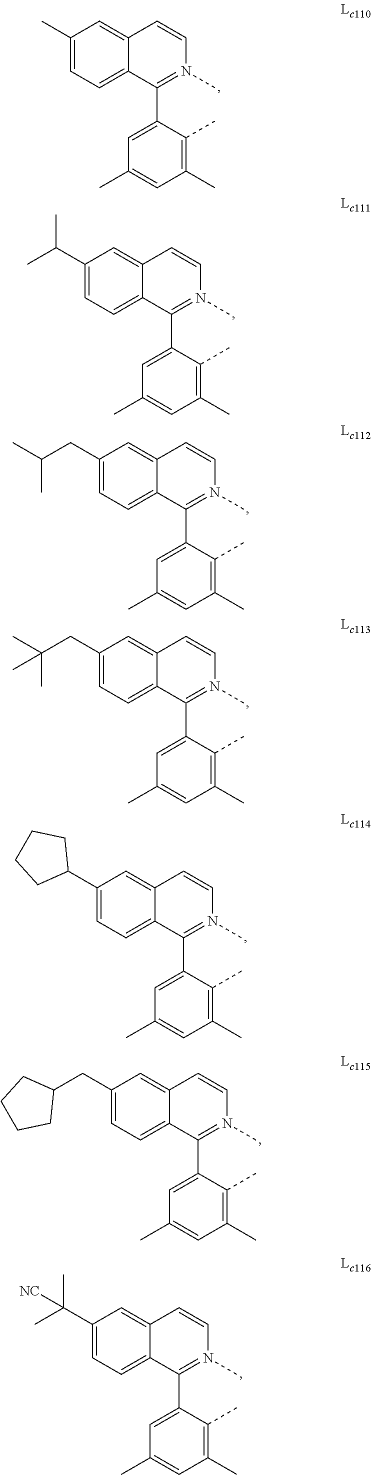 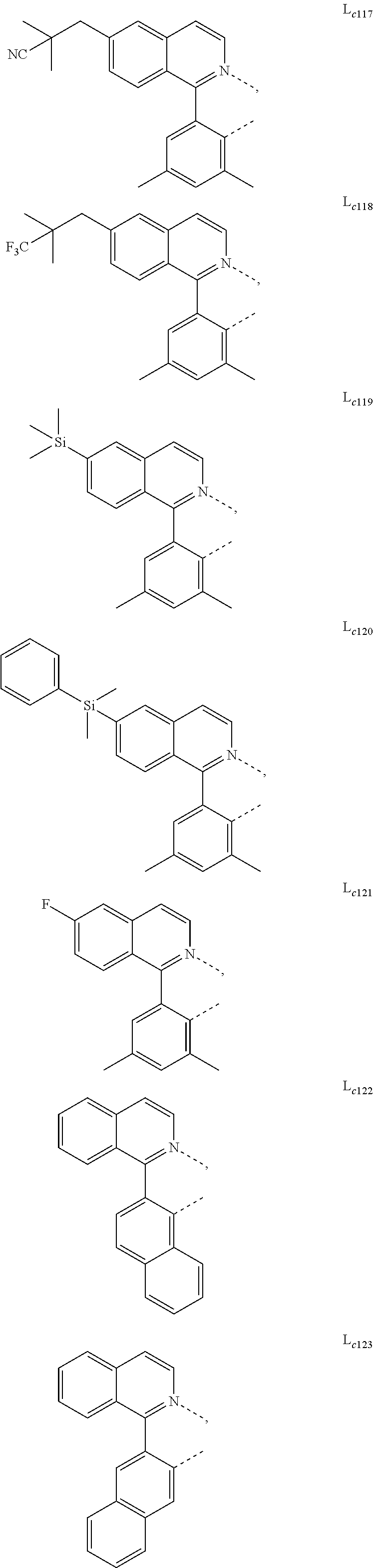 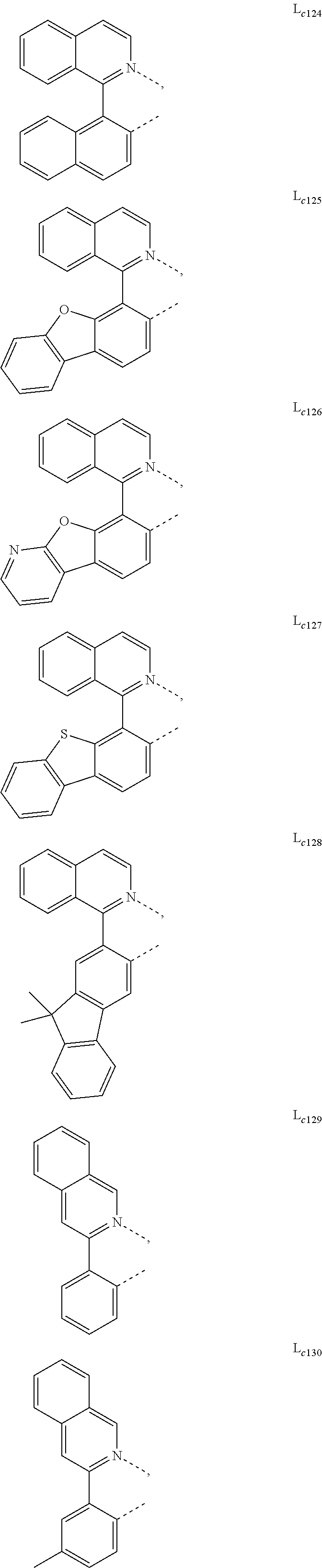 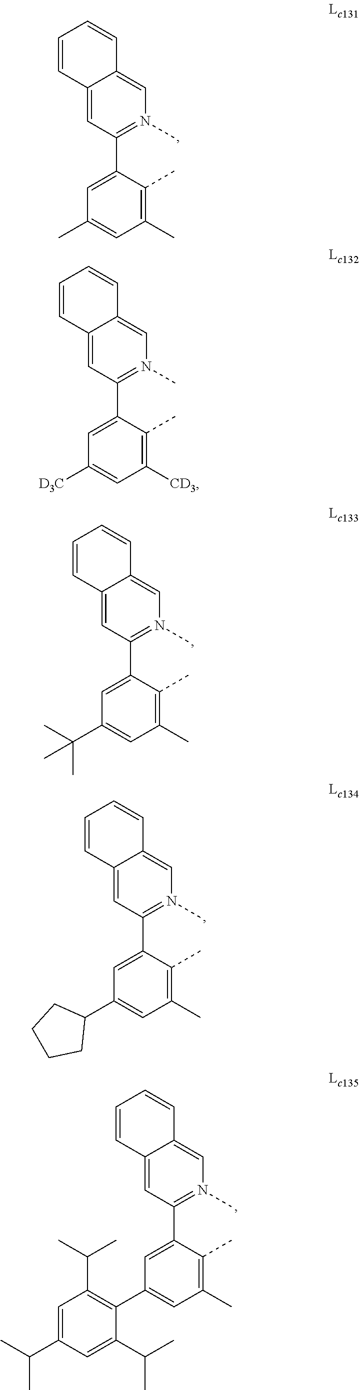 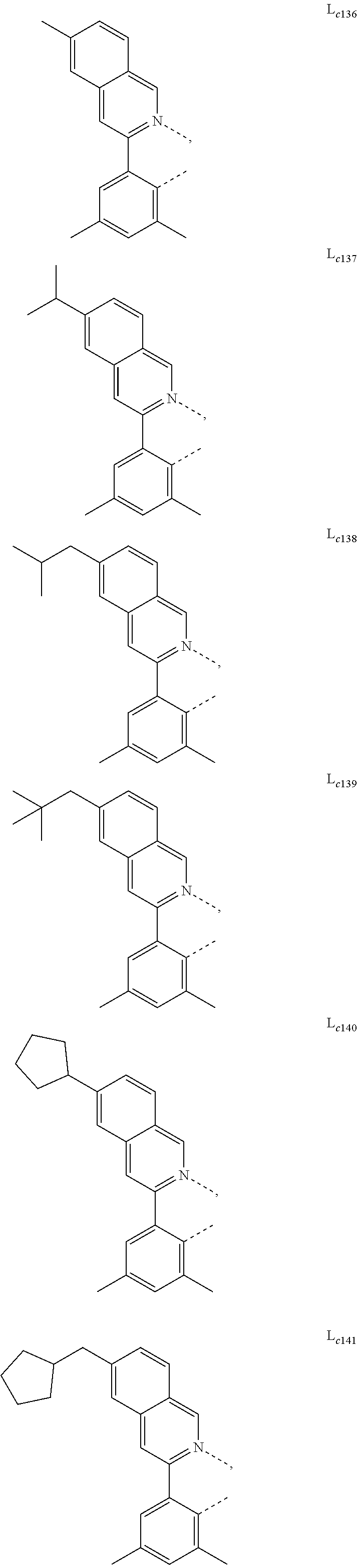 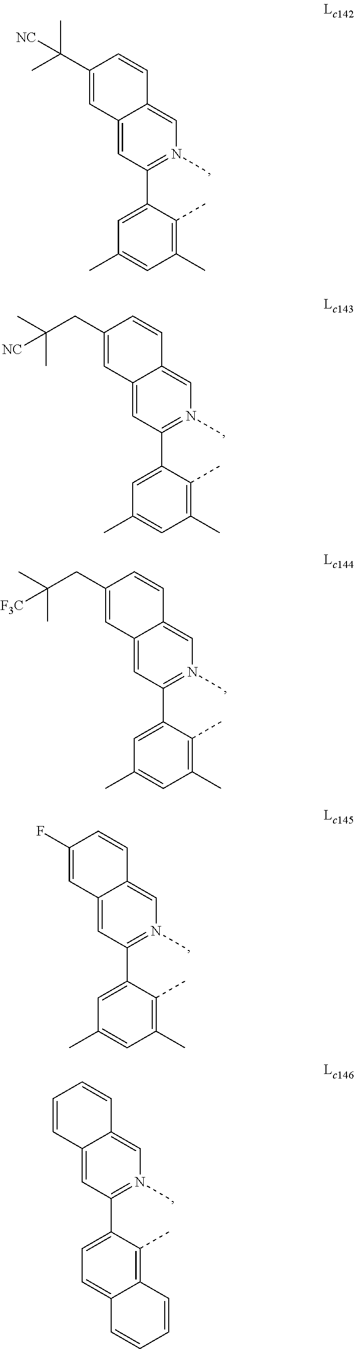 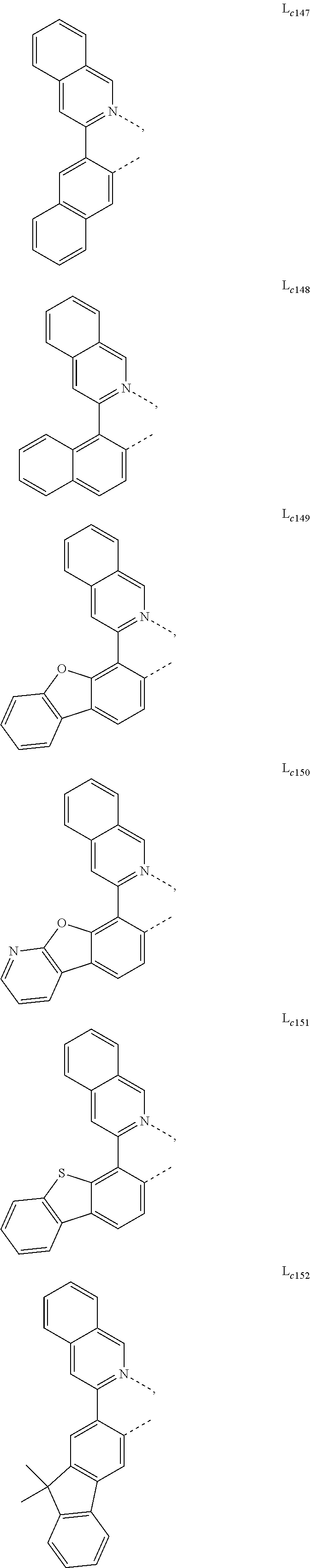 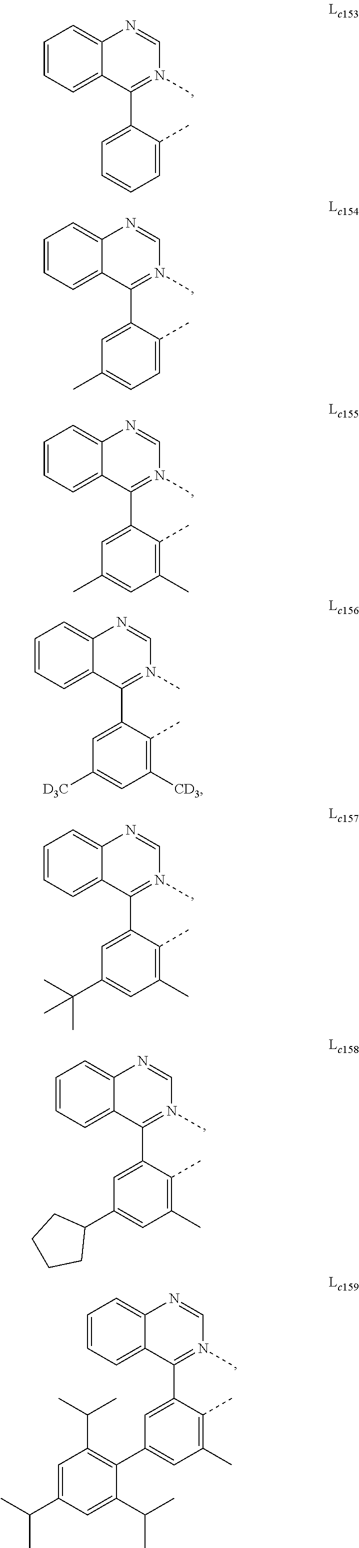 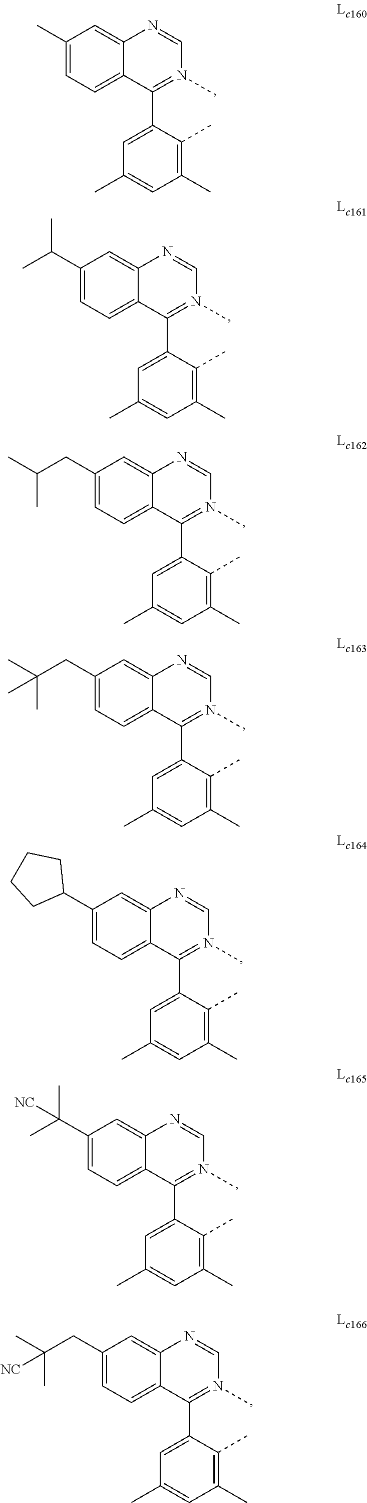 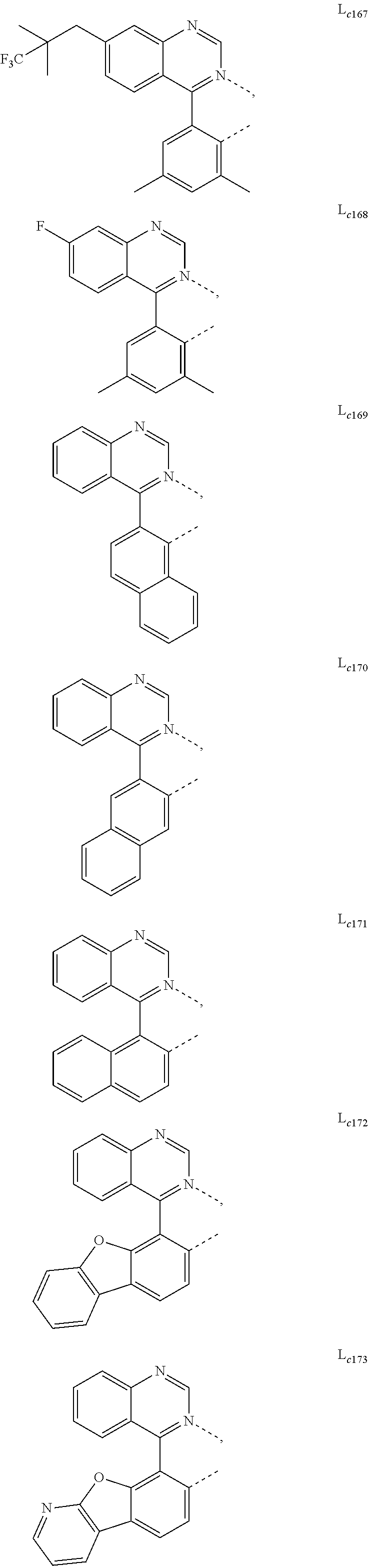 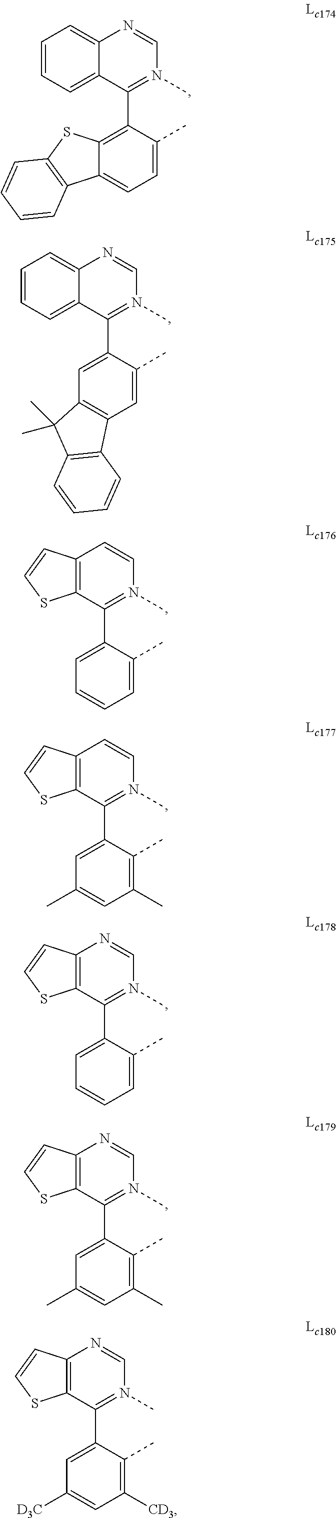 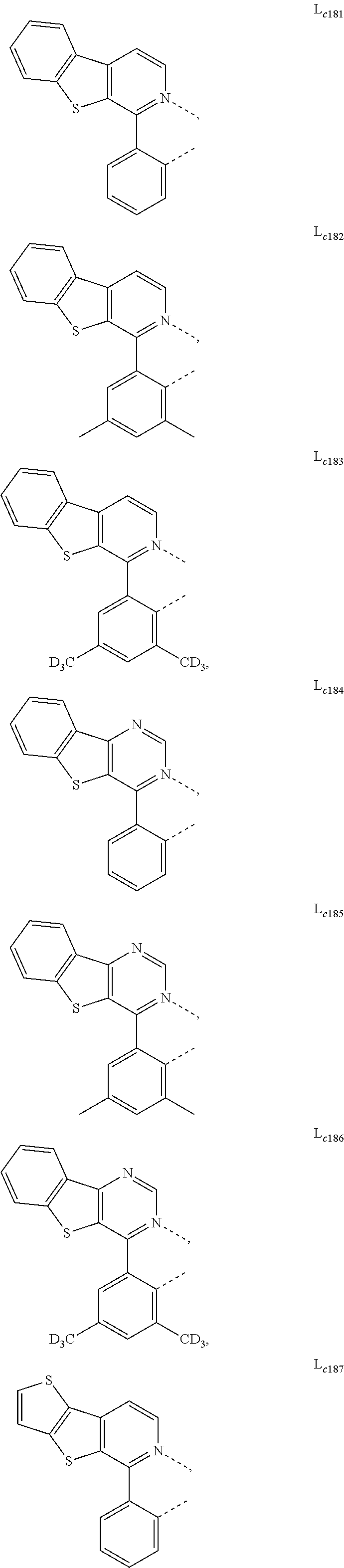 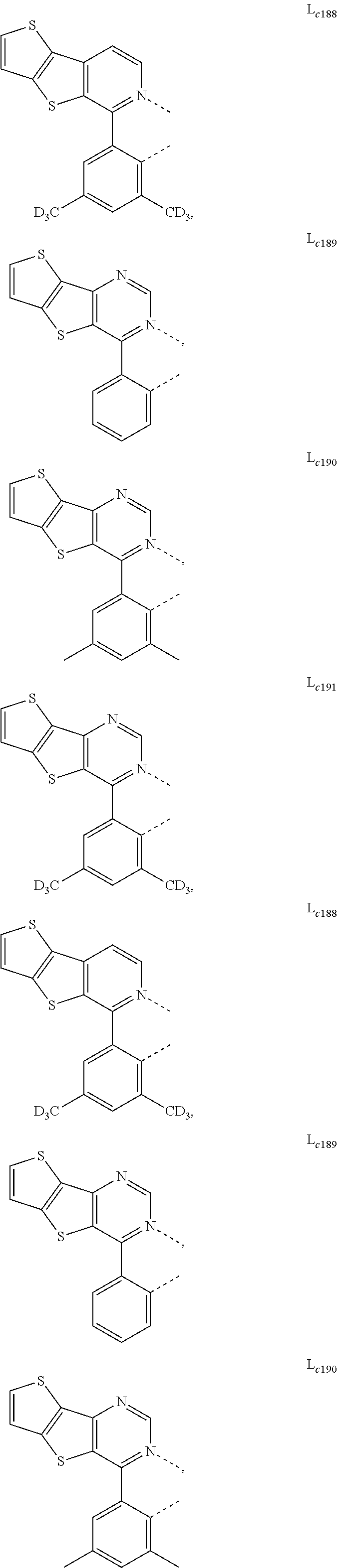 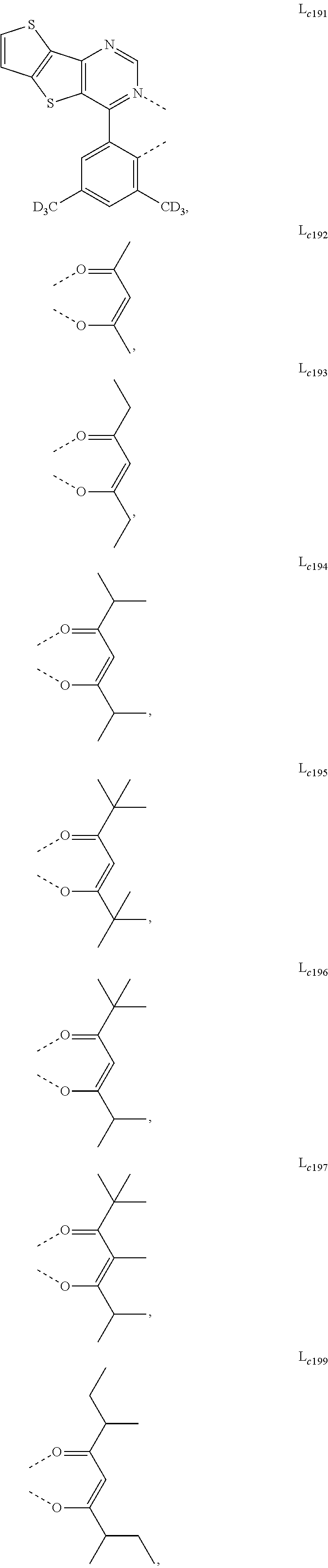 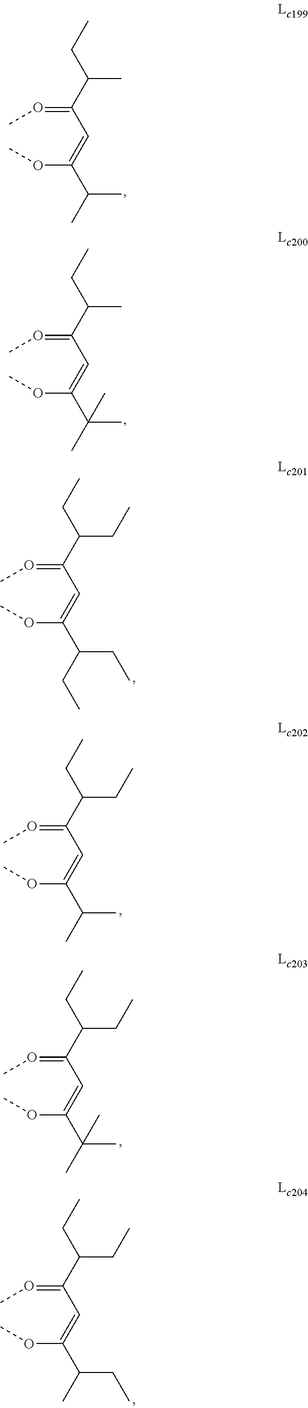 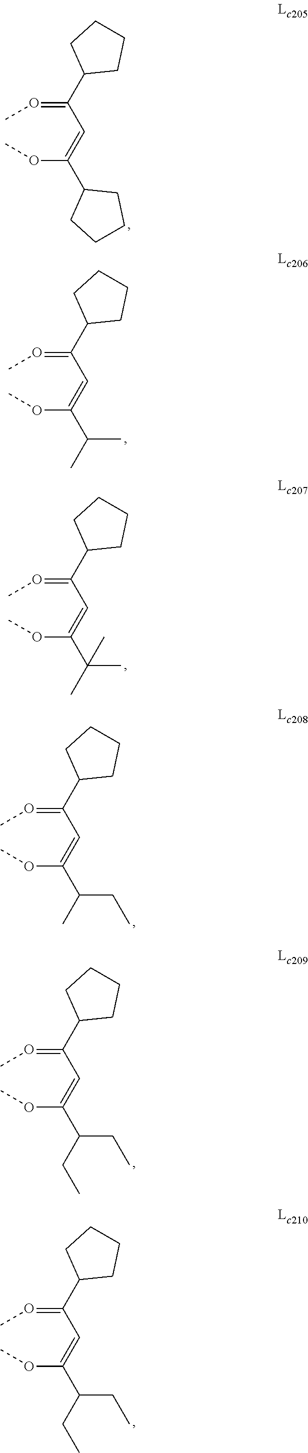 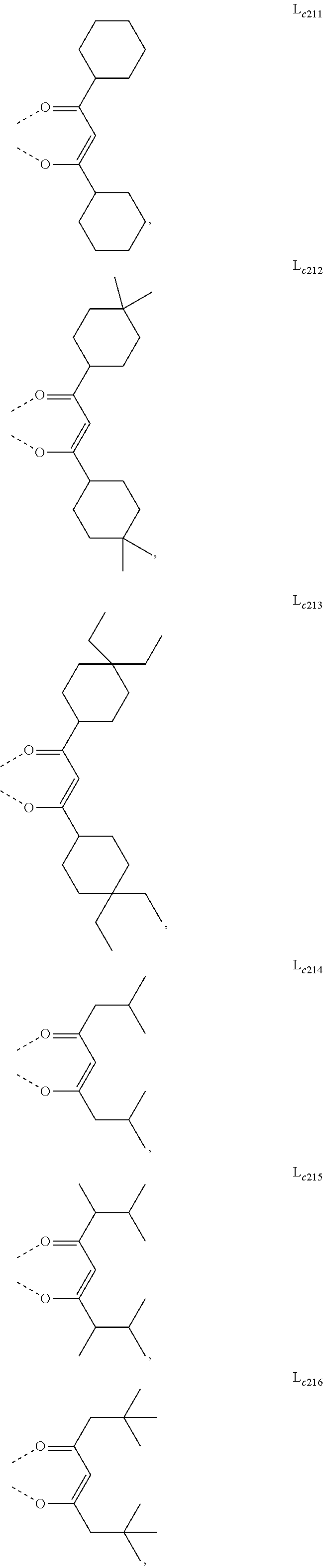 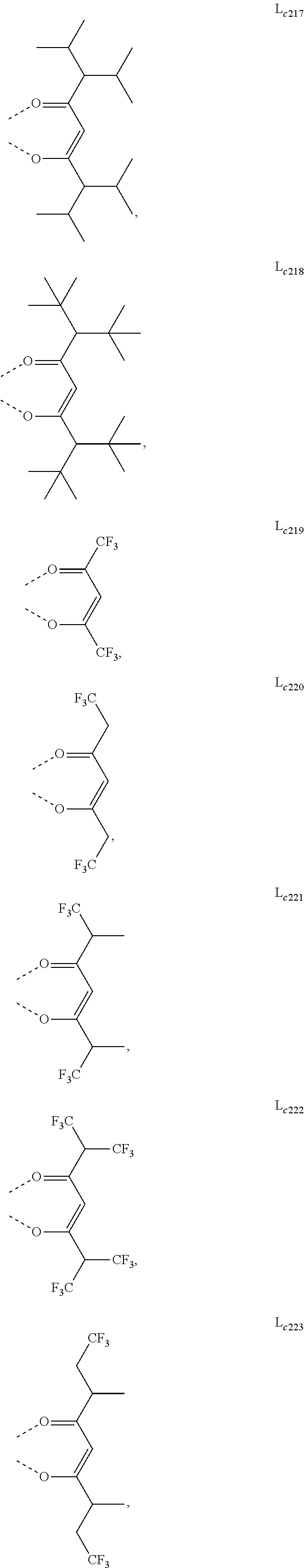 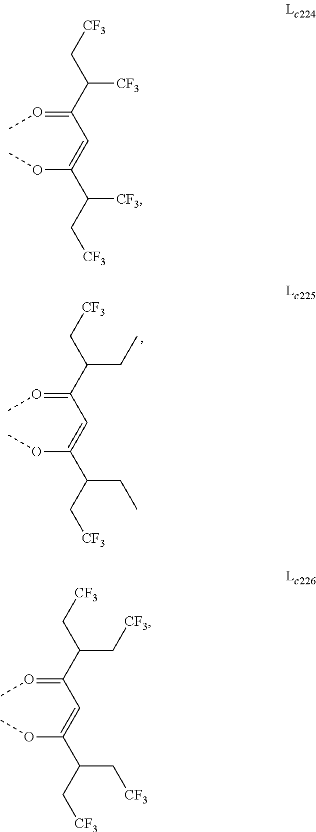 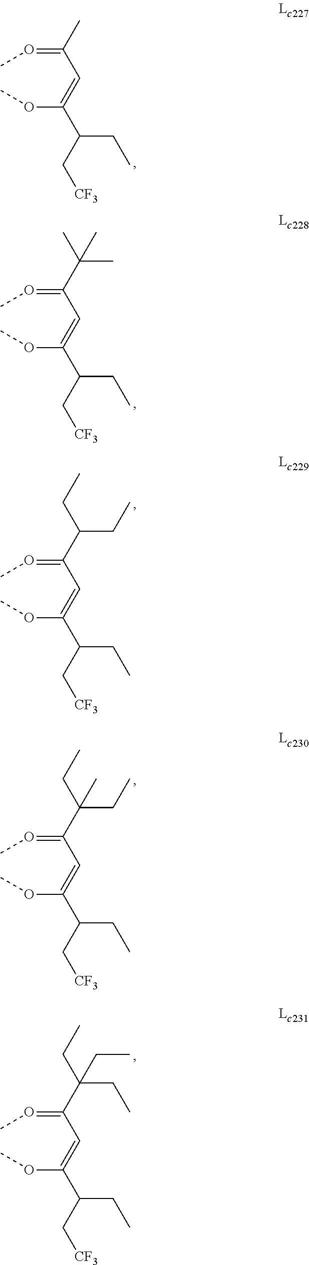 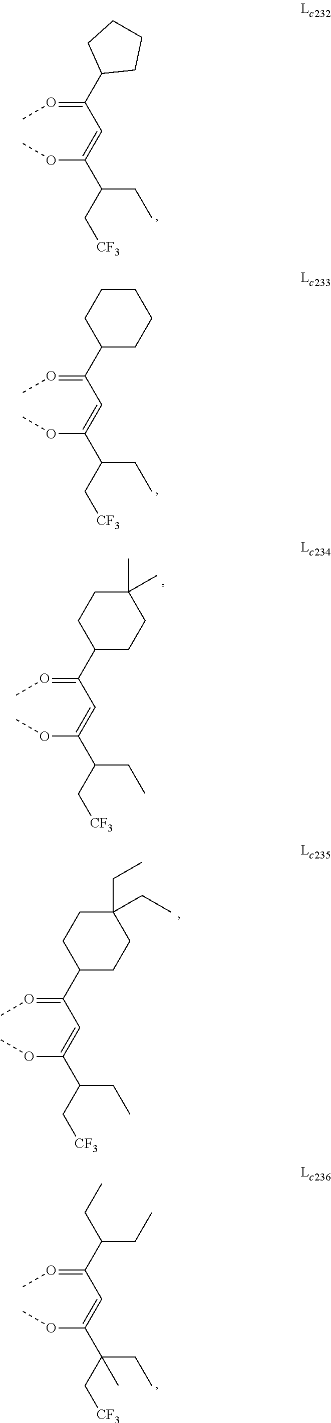 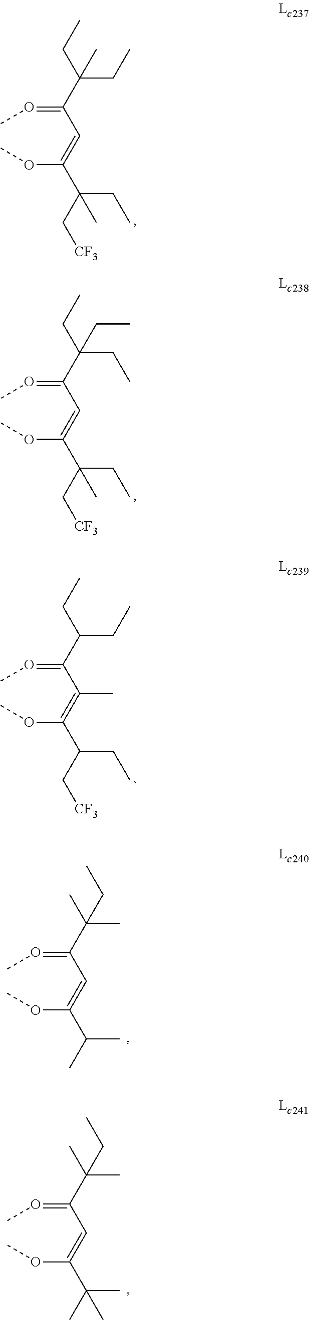 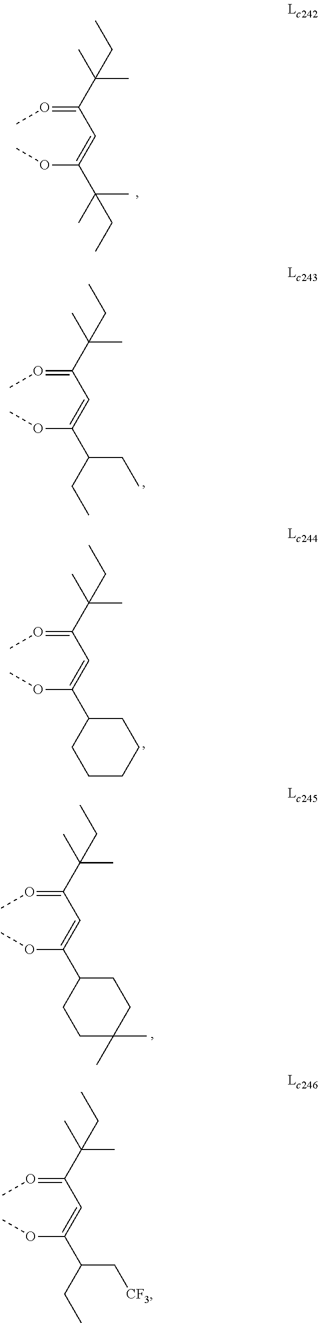 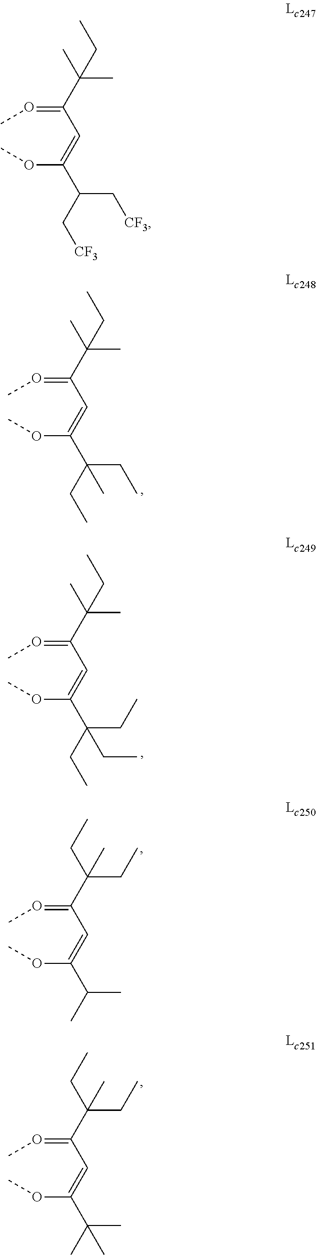 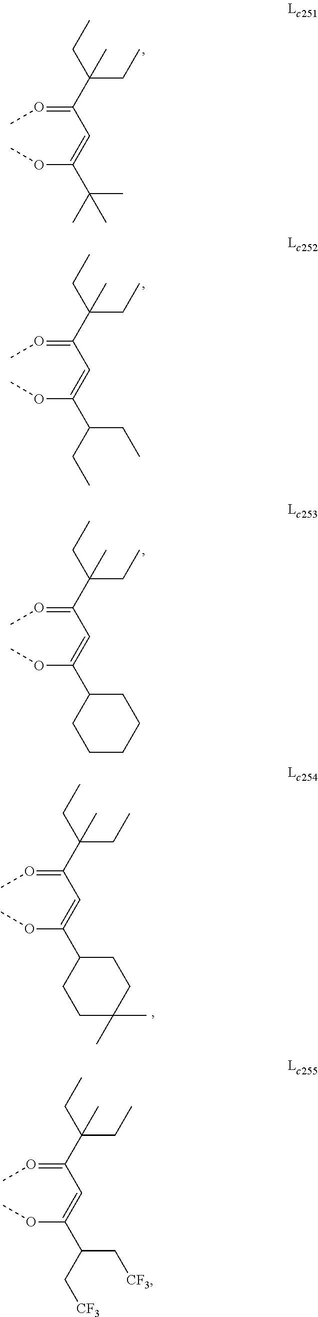 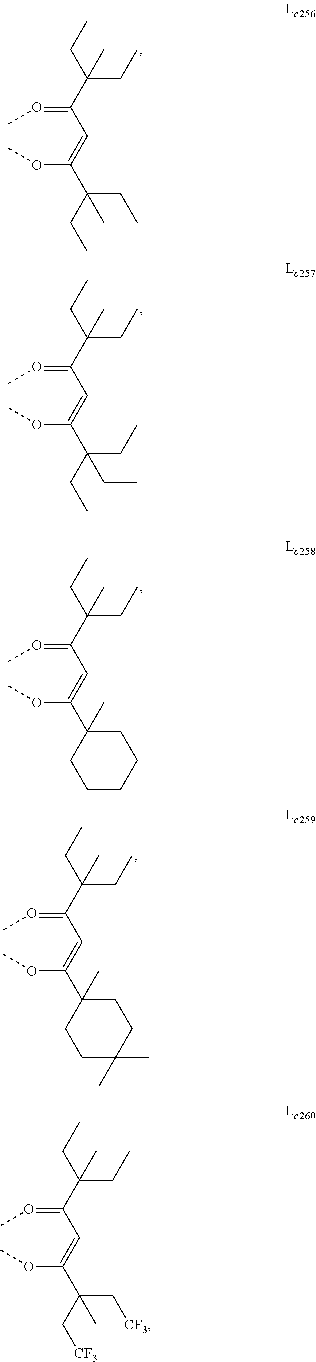 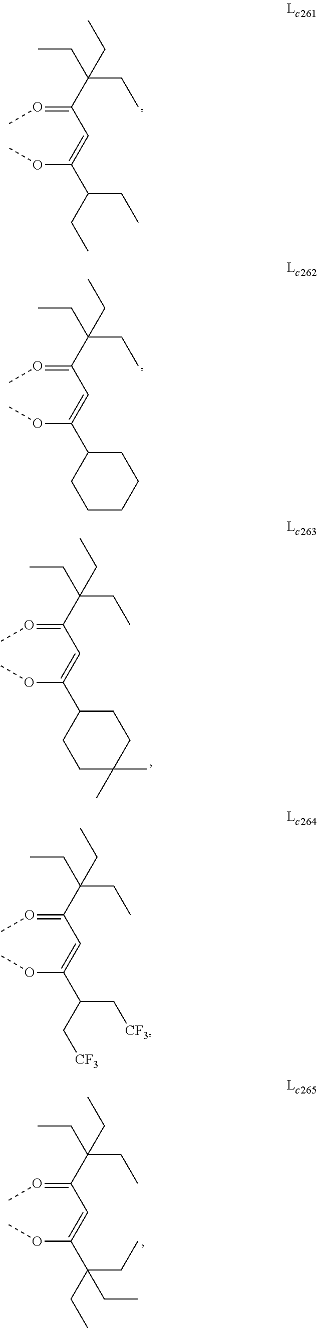 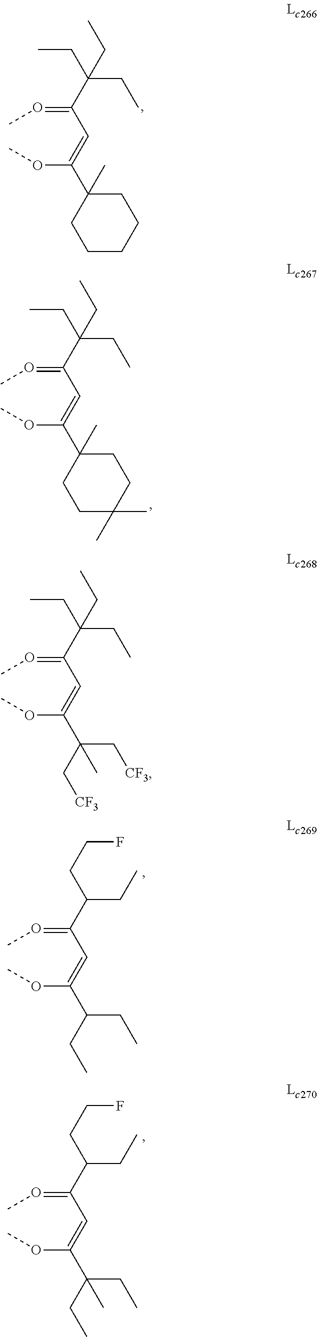 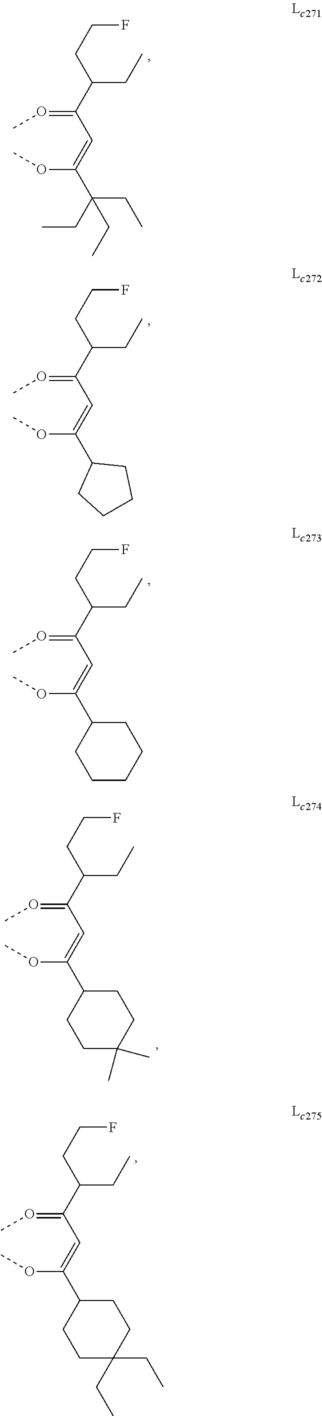 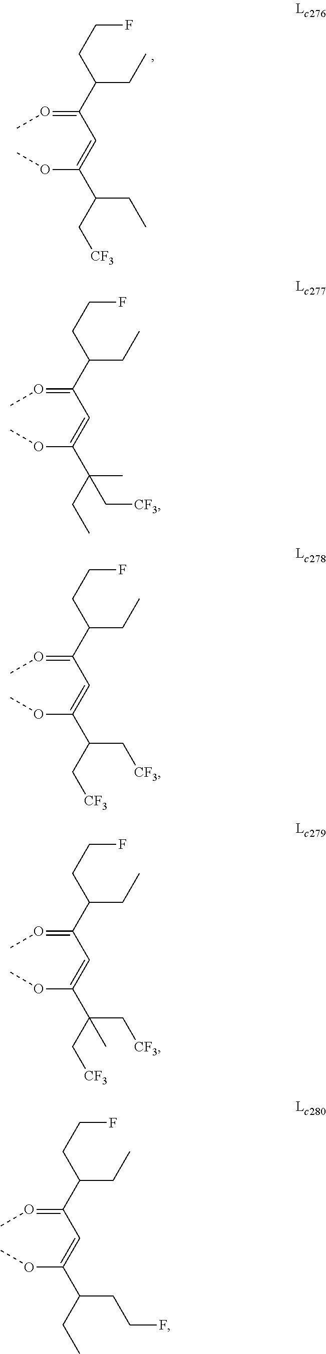 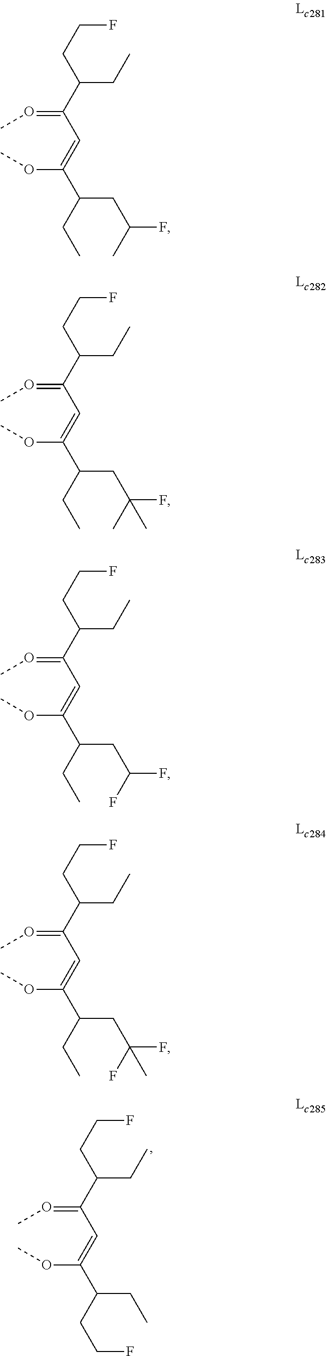 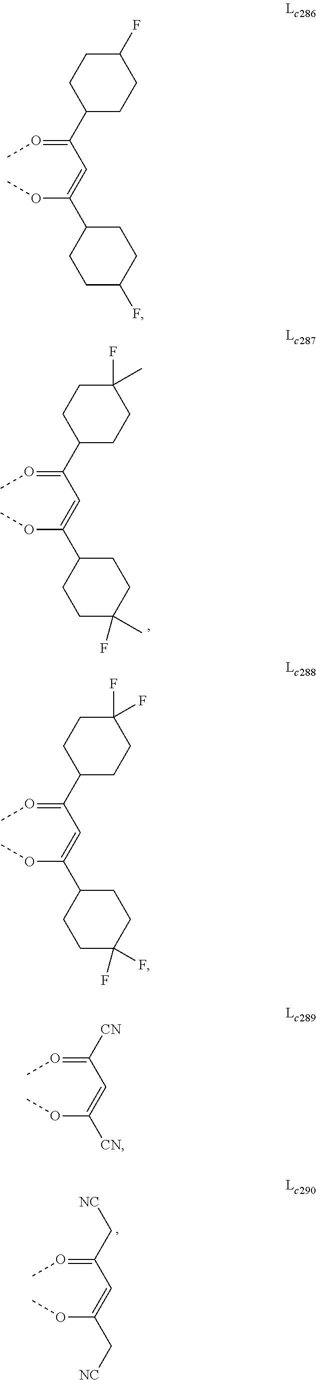 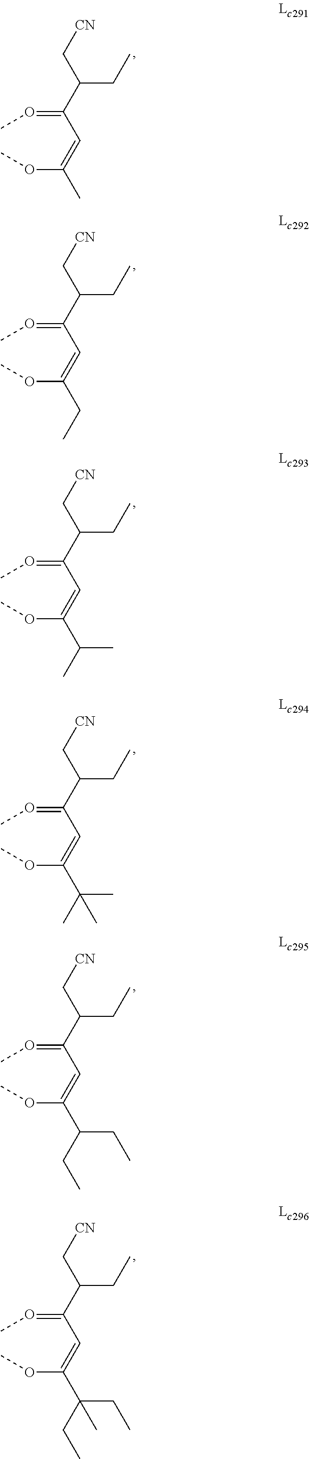 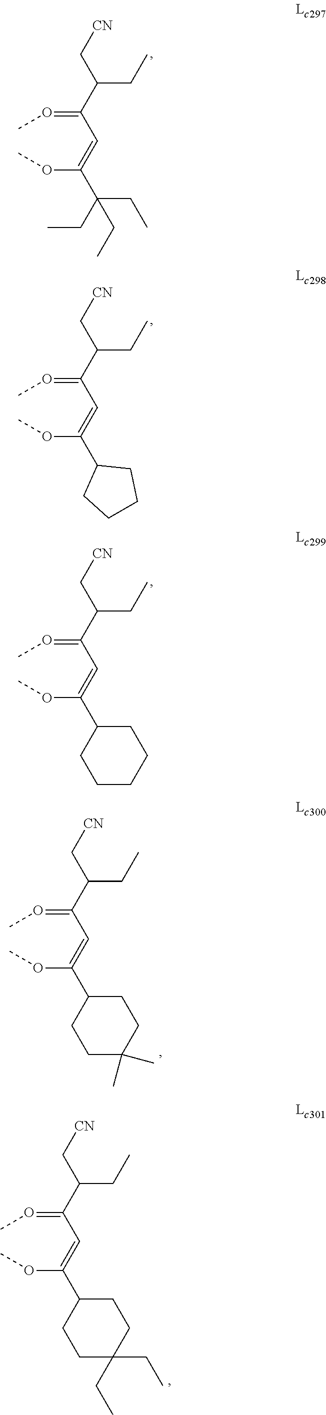 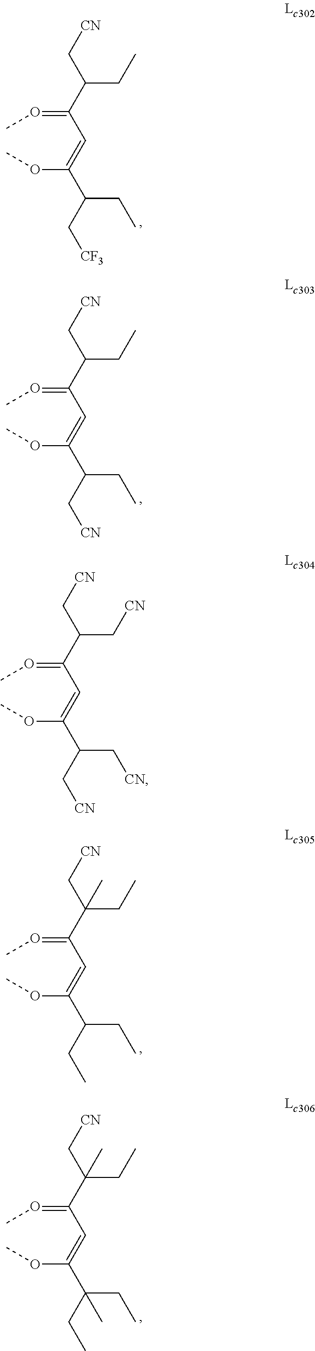 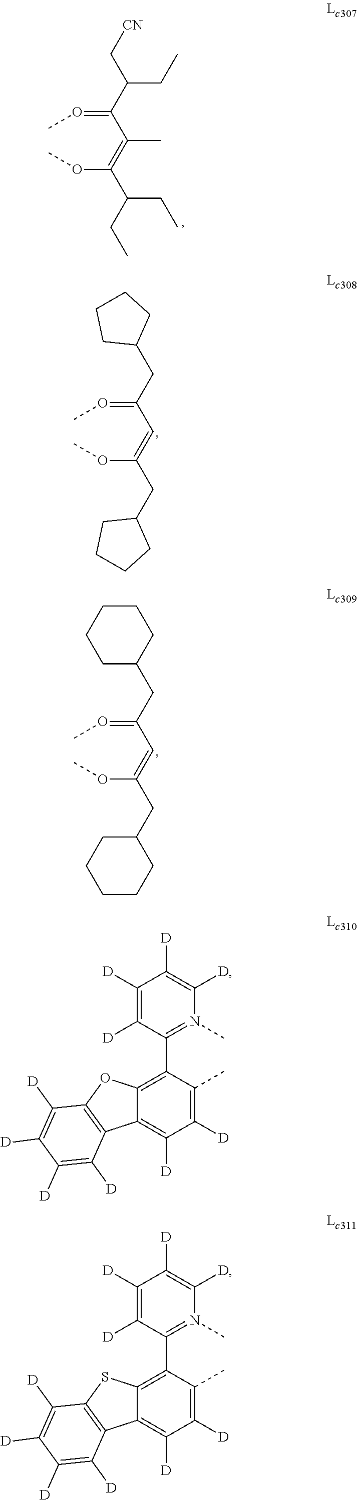 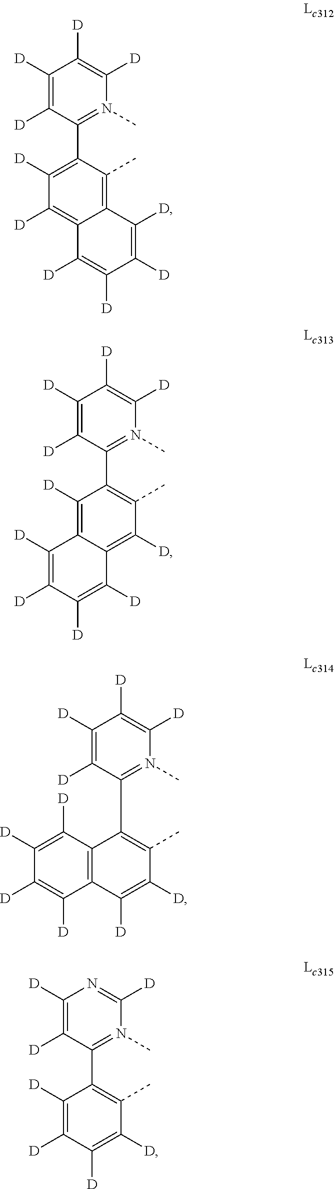 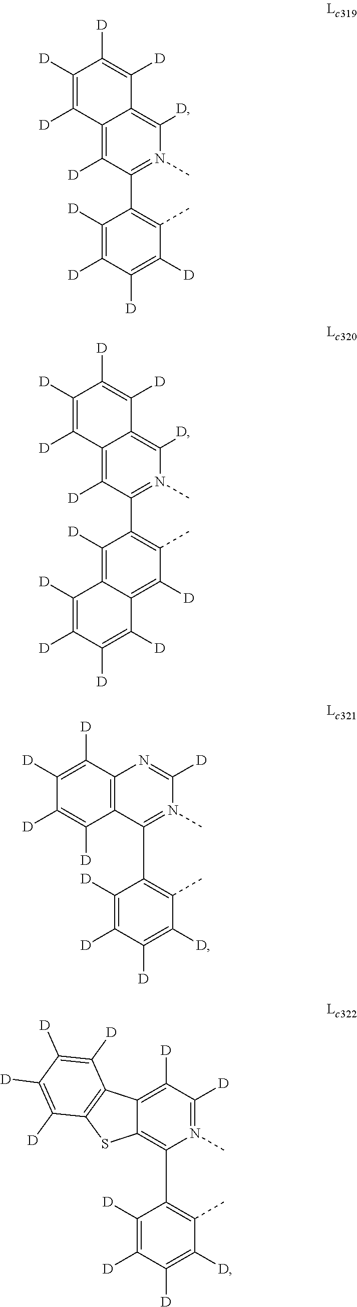 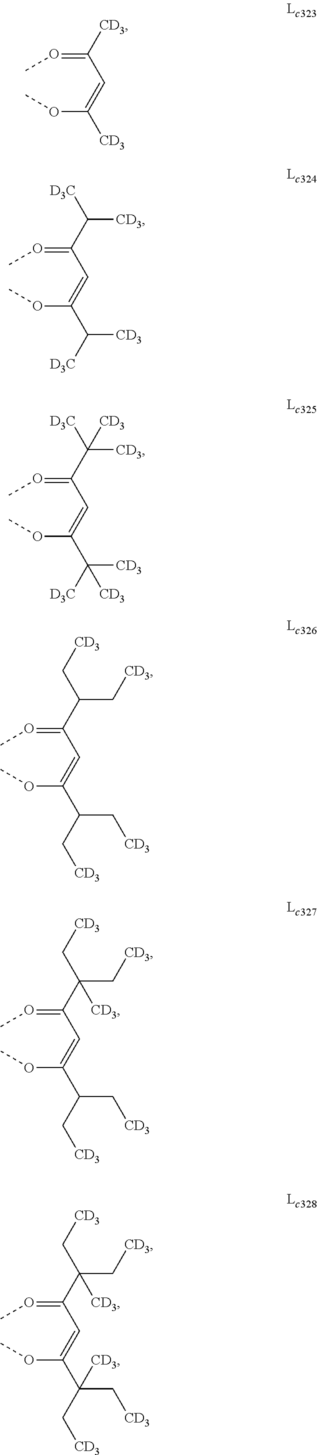 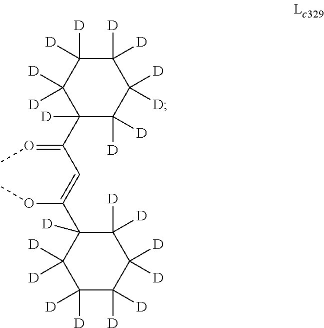
wherein optionally, hydrogen atoms in the L_{c1} to L_{c329} can be partially or fully substituted with deuterium.

17. The metal complex according to claim 16, wherein the metal complex has a structure of Ir(Lₐ)(L_{b})₂ or Ir(Lₐ)₂(L_{b}) or Ir(Lₐ)(L_{b})(L_{c});
when the metal complex has a structure of Ir(Lₐ)(L_{b}) 2, Lₐ is selected from any one of the group consisting of Lₐ₁ to Lₐ₅₉₅, and L_{b} is, at each occurrence identically or differently, selected from any one or any two of the group consisting of L_{b} to L_{b339}; when the metal complex has a structure of Ir(Lₐ)₂(L_{b}), Lₐ is, at each occurrence identically or differently, selected from any one or any two of the group consisting of Lₐ₁ to Lₐ₅₉₅, and L_{b} is selected from any one of the group consisting of L_{b1} to L_{b339}; when the metal complex has a structure of Ir(Lₐ)(L_{b})(L_{c}), Lₐ is selected from any one of the group consisting of Lₐ₁ to Lₐ₅₉₅, L_{b} is selected from any one of the group consisting of L_{b1} to L_{b339}, and L_{c} is selected from any one of the group consisting of Lei to L_{c329};
preferably, the metal complex is selected from the group consisting of Compound 1 to Compound 608;
wherein the Compound 1 to Compound 400 each have a structure of Ir(Lₐ)(L_{b})₂, wherein the two L_{b} are the same, and Lₐ and L_{b} are selected from the structures listed in the following table, respectively:

| Compound | | | Compound | | |
|---|---|---|---|---|---|
| No. | Lₐ | L_{b} | No. | Lₐ | L_{b} |
| 1 | Lₐ₂₇₁ | L_{b2} | 2 | Lₐ₂₇₁ | L_{b3} |
| 3 | Lₐ₂₅₃ | L_{b2} | 4 | Lₐ₂₅₃ | L_{b3} |
| 5 | Lₐ₁₂₉ | L_{b2} | 6 | Lₐ₁₂₉ | L_{b3} |
| 7 | Lₐ₁₆₈ | L_{b2} | 8 | Lₐ₁₆₈ | L_{b3} |
| 9 | Lₐ₃₇ | L_{b2} | 10 | Lₐ₃₇ | L_{b3} |
| 11 | Lₐ₃₁ | L_{b2} | 12 | Lₐ₃₁ | L_{b3} |
| 13 | Lₐ₃₂₈ | L_{b2} | 14 | Lₐ₃₂₈ | L_{b3} |
| 15 | Lₐ₅₂₂ | L_{b2} | 16 | Lₐ₅₂₂ | L_{b3} |
| 17 | Lₐ₂₆₈ | L_{b2} | 18 | Lₐ₂₆₈ | L_{b3} |
| 19 | Lₐ₂₈₇ | L_{b2} | 20 | Lₐ₂₈₇ | L_{b3} |
| 21 | Lₐ₇ | L_{b2} | 22 | Lₐ₇ | L_{b3} |
| 23 | Lₐ₂₁ | L_{b2} | 24 | Lₐ₂₁ | L_{b3} |
| 25 | Lₐ₃₄ | L_{b2} | 26 | Lₐ₃₄ | L_{b3} |
| 27 | Lₐ₄₇ | L_{b2} | 28 | Lₐ₄₇ | L_{b3} |
| 29 | Lₐ₆₅ | L_{b2} | 30 | Lₐ₆₅ | L_{b3} |
| 31 | Lₐ₇₃ | L_{b2} | 32 | Lₐ₇₃ | L_{b3} |
| 33 | Lₐ₁₀₁ | L_{b2} | 34 | Lₐ₁₀₁ | L_{b3} |
| 35 | Lₐ₁₁₃ | L_{b2} | 36 | Lₐ₁₁₃ | L_{b3} |
| 37 | Lₐ₁₂₁ | L_{b2} | 38 | Lₐ₁₂₁ | L_{b3} |
| 39 | Lₐ₁₂₀ | L_{b2} | 40 | Lₐ₁₂₀ | L_{b3} |
| 41 | Lₐ₁₃₄ | L_{b2} | 42 | Lₐ₁₃₄ | L_{b3} |
| 43 | Lₐ₁₄₉ | L_{b2} | 44 | Lₐ₁₄₉ | L_{b3} |
| 45 | Lₐ₁₅₇ | L_{b2} | 46 | Lₐ₁₅₇ | L_{b3} |
| 47 | Lₐ₁₈₀ | L_{b2} | 48 | Lₐ₁₈₀ | L_{b3} |
| 49 | Lₐ₁₉₂ | L_{b2} | 50 | Lₐ₁₉₂ | L_{b3} |
| 51 | Lₐ₂₀₀ | L_{b2} | 52 | Lₐ₂₀₀ | L_{b3} |
| 53 | Lₐ₂₁₃ | L_{b2} | 54 | Lₐ₂₁₃ | L_{b3} |
| 55 | Lₐ₂₃₀ | L_{b2} | 56 | Lₐ₂₃₀ | L_{b3} |
| 57 | Lₐ₂₃₈ | L_{b2} | 58 | Lₐ₂₃₈ | L_{b3} |
| 59 | Lₐ₂₉₇ | L_{b2} | 60 | Lₐ₂₉₇ | L_{b3} |
| 61 | Lₐ₃₀₂ | L_{b2} | 62 | Lₐ₃₀₂ | L_{b3} |
| 63 | Lₐ₃₅₄ | L_{b2} | 64 | Lₐ₃₅₄ | L_{b3} |
| 65 | Lₐ₃₅₅ | L_{b2} | 66 | Lₐ₃₅₅ | L_{b3} |
| 67 | Lₐ₃₆₈ | L_{b2} | 68 | Lₐ₃₆₈ | L_{b3} |
| 69 | Lₐ₄₀₉ | L_{b2} | 70 | Lₐ₄₀₉ | L_{b3} |
| 71 | Lₐ₄₁₇ | L_{b2} | 72 | Lₐ₄₁₇ | L_{b3} |
| 73 | Lₐ₄₂₇ | L_{b2} | 74 | Lₐ₄₂₇ | L_{b3} |
| 75 | Lₐ₄₃₃ | L_{b2} | 76 | Lₐ₄₃₃ | L_{b3} |
| 77 | Lₐ₄₄₈ | L_{b2} | 78 | Lₐ₄₄₈ | L_{b3} |
| 79 | Lₐ₅₃₈ | L_{b2} | 80 | Lₐ₅₃₈ | L_{b3} |
| 81 | Lₐ₂₇₁ | L_{b1} | 82 | Lₐ₂₇₁ | L_{b81} |
| 83 | Lₐ₂₅₃ | L_{b1} | 84 | Lₐ₂₅₃ | L_{b81} |
| 85 | Lₐ₁₂₉ | L_{b1} | 86 | Lₐ₁₂₉ | L_{b81} |
| 87 | Lₐ₁₆₈ | L_{b1} | 88 | Lₐ₁₆₈ | L_{b81} |
| 89 | Lₐ₃₇ | L_{b1} | 90 | Lₐ₃₇ | L_{b81} |
| 91 | Lₐ₃₁ | L_{b1} | 92 | Lₐ₃₁ | L_{b81} |
| 93 | Lₐ₃₂₈ | L_{b1} | 94 | Lₐ₃₂₈ | L_{b81} |
| 95 | Lₐ₅₂₂ | L_{b1} | 96 | Lₐ₅₂₂ | L_{b81} |
| 97 | Lₐ₂₆₈ | L_{b1} | 98 | Lₐ₂₆₈ | L_{b81} |
| 99 | Lₐ₂₈₇ | L_{b1} | 100 | Lₐ₂₈₇ | L_{b81} |
| 101 | Lₐ₇ | L_{b1} | 102 | Lₐ₇ | L_{b81} |
| 103 | Lₐ₂₁ | L_{b1} | 104 | Lₐ₂₁ | L_{b81} |
| 105 | Lₐ₃₄ | L_{b1} | 106 | Lₐ₃₄ | L_{b81} |
| 107 | Lₐ₄₇ | L_{b1} | 108 | Lₐ₄₇ | L_{b81} |
| 109 | Lₐ₆₅ | L_{b1} | 110 | Lₐ₆₅ | L_{b81} |
| 111 | Lₐ₇₃ | L_{b1} | 112 | Lₐ₇₃ | L_{b81} |
| 113 | Lₐ₁₀₁ | L_{b1} | 114 | Lₐ₁₀₁ | L_{b81} |
| 115 | Lₐ₁₁₃ | L_{b1} | 116 | Lₐ₁₁₃ | L_{b81} |
| 117 | Lₐ₁₂₁ | L_{b1} | 118 | Lₐ₁₂₁ | L_{b81} |
| 119 | Lₐ₁₂₀ | L_{b1} | 120 | Lₐ₁₂₀ | L_{b81} |
| 121 | Lₐ₁₃₄ | L_{b1} | 122 | Lₐ₁₃₄ | L_{b81} |
| 123 | Lₐ₁₄₉ | L_{b1} | 124 | Lₐ₁₄₉ | L_{b81} |
| 125 | Lₐ₁₅₇ | L_{b1} | 126 | Lₐ₁₅₇ | L_{b81} |
| 127 | Lₐ₁₈₀ | L_{b1} | 128 | Lₐ₁₈₀ | L_{b81} |
| 129 | Lₐ₁₉₂ | L_{b1} | 130 | Lₐ₁₉₂ | L_{b81} |
| 131 | Lₐ₂₀₀ | L_{b1} | 132 | Lₐ₂₀₀ | L_{b81} |
| 133 | Lₐ₂₁₃ | L_{b1} | 134 | Lₐ₂₁₃ | L_{b81} |
| 135 | Lₐ₂₃₀ | L_{b1} | 136 | Lₐ₂₃₀ | L_{b81} |
| 137 | Lₐ₂₃₈ | L_{b1} | 138 | Lₐ₂₃₈ | L_{b81} |
| 139 | Lₐ₂₉₇ | L_{b1} | 140 | Lₐ₂₉₇ | L_{b81} |
| 141 | Lₐ₃₀₂ | L_{b1} | 142 | Lₐ₃₀₂ | L_{b81} |
| 143 | Lₐ₃₅₄ | L_{b1} | 144 | Lₐ₃₅₄ | L_{b81} |
| 145 | Lₐ₃₅₅ | L_{b1} | 146 | Lₐ₃₅₅ | L_{b81} |
| 147 | Lₐ₃₆₈ | L_{b1} | 148 | Lₐ₃₆₈ | L_{b81} |
| 149 | Lₐ₄₀₉ | L_{b1} | 150 | Lₐ₄₀₉ | L_{b81} |
| 151 | Lₐ₄₁₇ | L_{b1} | 152 | Lₐ₄₁₇ | L_{b81} |
| 153 | Lₐ₄₂₇ | L_{b1} | 154 | Lₐ₄₂₇ | L_{b81} |
| 155 | Lₐ₄₃₃ | L_{b1} | 156 | Lₐ₄₃₃ | L_{b81} |
| 157 | Lₐ₄₄₈ | L_{b1} | 158 | Lₐ₄₄₈ | L_{b81} |
| 159 | Lₐ₅₃₈ | L_{b1} | 160 | Lₐ₅₃₈ | L_{b81} |
| 161 | Lₐ₂₇₁ | L_{b10} | 162 | Lₐ₂₇₁ | L_{b209} |
| 163 | Lₐ₂₅₃ | L_{b10} | 164 | Lₐ₂₅₃ | L_{b209} |
| 165 | Lₐ₁₂₉ | L_{b10} | 166 | Lₐ₁₂₉ | L_{b209} |
| 167 | Lₐ₁₆₈ | L_{b10} | 168 | Lₐ₁₆₈ | L_{b209} |
| 169 | Lₐ₃₇ | L_{b10} | 170 | Lₐ₃₇ | L_{b209} |
| 171 | Lₐ₃₁ | L_{b10} | 172 | Lₐ₃₁ | L_{b209} |
| 173 | Lₐ₃₂₈ | L_{b10} | 174 | Lₐ₃₂₈ | L_{b209} |
| 175 | Lₐ₅₂₂ | L_{b10} | 176 | Lₐ₅₂₂ | L_{b209} |
| 177 | Lₐ₂₆₈ | L_{b10} | 178 | Lₐ₂₆₈ | L_{b209} |
| 179 | Lₐ₂₈₇ | L_{b10} | 180 | Lₐ₂₈₇ | L_{b209} |
| 181 | Lₐ₇ | L_{b10} | 182 | Lₐ₇ | L_{b209} |
| 183 | Lₐ₂₁ | L_{b10} | 184 | Lₐ₂₁ | L_{b209} |
| 185 | Lₐ₃₄ | L_{b10} | 186 | Lₐ₃₄ | L_{b209} |
| 187 | Lₐ₄₇ | L_{b10} | 188 | Lₐ₄₇ | L_{b209} |
| 189 | Lₐ₆₅ | L_{b10} | 190 | Lₐ₆₅ | L_{b209} |
| 191 | Lₐ₇₃ | L_{b10} | 192 | Lₐ₇₃ | L_{b209} |
| 193 | Lₐ₁₀₁ | L_{b10} | 194 | Lₐ₁₀₁ | L_{b209} |
| 195 | Lₐ₁₁₃ | L_{b10} | 196 | Lₐ₁₁₃ | L_{b209} |
| 197 | Lₐ₁₂₁ | L_{b10} | 198 | Lₐ₁₂₁ | L_{b209} |
| 199 | Lₐ₁₂₀ | L_{b10} | 200 | Lₐ₁₂₀ | L_{b209} |
| 201 | Lₐ₁₃₄ | L_{b10} | 202 | Lₐ₁₃₄ | L_{b209} |
| 203 | Lₐ₁₄₉ | L_{b10} | 204 | Lₐ₁₄₉ | L_{b209} |
| 205 | Lₐ₁₅₇ | L_{b10} | 206 | Lₐ₁₅₇ | L_{b209} |
| 207 | Lₐ₁₈₀ | L_{b10} | 208 | Lₐ₁₈₀ | L_{b209} |
| 209 | Lₐ₁₉₂ | L_{b10} | 210 | Lₐ₁₉₂ | L_{b209} |
| 211 | Lₐ₂₀₀ | L_{b10} | 212 | Lₐ₂₀₀ | L_{b209} |
| 213 | Lₐ₂₁₃ | L_{b10} | 214 | Lₐ₂₁₃ | L_{b209} |
| 215 | Lₐ₂₃₀ | L_{b10} | 216 | Lₐ₂₃₀ | L_{b209} |
| 217 | Lₐ₂₃₈ | L_{b10} | 218 | Lₐ₂₃₈ | L_{b209} |
| 219 | Lₐ₂₉₇ | L_{b10} | 220 | Lₐ₂₉₇ | L_{b209} |
| 221 | Lₐ₃₀₂ | L_{b10} | 222 | Lₐ₃₀₂ | L_{b209} |
| 223 | Lₐ₃₅₄ | L_{b10} | 224 | Lₐ₃₅₄ | L_{b209} |
| 225 | Lₐ₃₅₅ | L_{b10} | 226 | Lₐ₃₅₅ | L_{b209} |
| 227 | Lₐ₃₆₈ | L_{b10} | 228 | Lₐ₃₆₈ | L_{b209} |
| 229 | Lₐ₄₀₉ | L_{b10} | 230 | Lₐ₄₀₉ | L_{b209} |
| 231 | Lₐ₄₁₇ | L_{b10} | 232 | Lₐ₄₁₇ | L_{b209} |
| 233 | Lₐ₄₂₇ | L_{b10} | 234 | Lₐ₄₂₇ | L_{b209} |
| 235 | Lₐ₄₃₃ | L_{b10} | 236 | Lₐ₄₃₃ | L_{b209} |
| 237 | Lₐ₄₄₈ | L_{b10} | 238 | Lₐ₄₄₈ | L_{b209} |
| 239 | Lₐ₅₃₈ | L_{b10} | 240 | Lₐ₅₃₈ | L_{b209} |
| 241 | Lₐ₂₇₁ | L_{b95} | 242 | Lₐ₂₇₁ | L_{b21} |
| 243 | Lₐ₂₅₃ | L_{b95} | 244 | Lₐ₂₅₃ | L_{b21} |
| 245 | Lₐ₁₂₉ | L_{b95} | 246 | Lₐ₁₂₉ | L_{b21} |
| 247 | Lₐ₁₆₈ | L_{b95} | 248 | Lₐ₁₆₈ | L_{b21} |
| 249 | Lₐ₃₇ | L_{b95} | 250 | Lₐ₃₇ | L_{b21} |
| 251 | Lₐ₃₁ | L_{b95} | 252 | Lₐ₃₁ | L_{b21} |
| 253 | Lₐ₃₂₈ | L_{b9} | 254 | Lₐ₃₂₈ | L_{b21} |
| 255 | Lₐ₅₂₂ | L_{b95} | 256 | Lₐ₅₂₂ | L_{b21} |
| 257 | Lₐ₂₆₈ | L_{b95} | 258 | Lₐ₂₆₈ | L_{b21} |
| 259 | Lₐ₂₈₇ | L_{b95} | 260 | Lₐ₂₈₇ | L_{b21} |
| 261 | Lₐ₇ | L_{b95} | 262 | Lₐ₇ | L_{b21} |
| 263 | Lₐ₂₁ | L_{b95} | 264 | Lₐ₂₁ | L_{b21} |
| 265 | Lₐ₃₄ | L₆₉₅ | 266 | Lₐ₃₄ | L_{b21} |
| 267 | Lₐ₄₇ | L_{b95} | 268 | Lₐ₄₇ | L_{b21} |
| 269 | Lₐ₆₅ | L_{b95} | 270 | Lₐ₆₅ | L_{b21} |
| 271 | Lₐ₇₃ | L_{b95} | 272 | Lₐ₇₃ | L_{b21} |
| 273 | Lₐ₁₀₁ | L_{b95} | 274 | Lₐ₁₀₁ | L_{b21} |
| 275 | Lₐ₁₁₃ | L_{b95} | 276 | Lₐ₁₁₃ | L_{b21} |
| 277 | Lₐ₁₂₁ | L_{b95} | 278 | Lₐ₁₂₁ | L_{b21} |
| 279 | Lₐ₁₂₀ | L_{b95} | 280 | Lₐ₁₂₀ | L_{b21} |
| 281 | Lₐ₁₃₄ | L_{b95} | 282 | Lₐ₁₃₄ | L_{b21} |
| 283 | Lₐ₁₄₉ | L_{b95} | 284 | Lₐ₁₄₉ | L_{b21} |
| 285 | Lₐ₁₅₇ | L_{b95} | 286 | Lₐ₁₅₇ | L_{b21} |
| 287 | Lₐ₁₈₀ | L_{b95} | 288 | Lₐ₁₈₀ | L_{b21} |
| 289 | Lₐ₁₉₂ | L_{b95} | 290 | Lₐ₁₉₂ | L_{b21} |
| 291 | Lₐ₂₀₀ | L_{b9} | 292 | Lₐ₂₀₀ | L_{b21} |
| 293 | Lₐ₂₁₃ | L_{b95} | 294 | Lₐ₂₁₃ | L_{b21} |
| 295 | Lₐ₂₃₀ | L_{b95} | 296 | Lₐ₂₃₀ | L_{b21} |
| 297 | Lₐ₂₃₈ | L_{b95} | 298 | Lₐ₂₃₈ | L_{b21} |
| 299 | Lₐ₂₉₇ | L_{b95} | 300 | Lₐ₂₉₇ | L_{b21} |
| 301 | Lₐ₃₀₂ | L_{b95} | 302 | Lₐ₃₀₂ | L_{b21} |
| 303 | Lₐ₃₅₄ | L_{b95} | 304 | Lₐ₃₅₄ | L_{b21} |
| 305 | Lₐ₃₅₅ | L_{b95} | 306 | Lₐ₃₅₅ | L_{b21} |
| 307 | Lₐ₃₆₈ | L_{b95} | 308 | Lₐ₃₆₈ | L_{b21} |
| 309 | Lₐ₄₀₉ | L_{b95} | 310 | Lₐ₄₀₉ | L_{b21} |
| 311 | Lₐ₄₁₇ | L_{b95} | 312 | Lₐ₄₁₇ | L_{b21} |
| 313 | Lₐ₄₂₇ | L_{b95} | 314 | Lₐ₄₂₇ | L_{b21} |
| 315 | Lₐ₄₃₃ | L_{b95} | 316 | Lₐ₄₃₃ | L_{b21} |
| 317 | Lₐ₄₄₈ | L_{b95} | 318 | Lₐ₄₄₈ | L_{b21} |
| 319 | Lₐ₅₃₈ | L_{b95} | 320 | Lₐ₅₃₈ | L_{b21} |
| 321 | Lₐ₂₇₁ | L_{b12} | 322 | Lₐ₂₇₁ | L_{b286} |
| 323 | Lₐ₂₅₃ | L_{b12} | 324 | Lₐ₂₅₃ | L_{b286} |
| 325 | Lₐ₁₂₉ | L_{b12} | 326 | Lₐ₁₂₉ | L_{b286} |
| 327 | Lₐ₁₆₈ | L_{b12} | 328 | Lₐ₁₆₈ | L_{b286} |
| 329 | Lₐ₃₇ | L_{b12} | 330 | Lₐ₃₇ | L_{b286} |
| 331 | Lₐ₃₁ | L_{b12} | 332 | Lₐ₃₁ | L_{b286} |
| 333 | Lₐ₃₂₈ | L_{b12} | 334 | Lₐ₃₂₈ | L_{b286} |
| 335 | Lₐ₅₂₂ | L_{b12} | 336 | Lₐ₅₂₂ | L_{b286} |
| 337 | Lₐ₂₆₈ | L_{b12} | 338 | Lₐ₂₆₈ | L_{b286} |
| 339 | Lₐ₂₈₇ | L_{b12} | 340 | Lₐ₂₈₇ | L_{b286} |
| 341 | Lₐ₇ | L_{b12} | 342 | Lₐ₇ | L_{b286} |
| 343 | Lₐ₂₁ | L_{b12} | 344 | Lₐ₂₁ | L_{b286} |
| 345 | Lₐ₃₄ | L_{b12} | 346 | Lₐ₃₄ | L_{b286} |
| 347 | Lₐ₄₇ | L_{b12} | 348 | Lₐ₄₇ | L_{b286} |
| 349 | Lₐ₆₅ | L_{b12} | 350 | Lₐ₆₅ | L_{b286} |
| 351 | Lₐ₇₃ | L_{b12} | 352 | Lₐ₇₃ | L_{b286} |
| 353 | Lₐ₁₀₁ | L_{b12} | 354 | Lₐ₁₀₁ | L_{b286} |
| 355 | Lₐ₁₁₃ | L_{b12} | 356 | Lₐ₁₁₃ | L_{b286} |
| 357 | Lₐ₁₂₁ | L_{b12} | 358 | Lₐ₁₂₁ | L_{b286} |
| 359 | Lₐ₁₂₀ | L_{b12} | 360 | Lₐ₁₂₀ | L_{b286} |
| 361 | Lₐ₁₃₄ | L_{b12} | 362 | Lₐ₁₃₄ | L_{b286} |
| 363 | Lₐ₁₄₉ | L_{b12} | 364 | Lₐ₁₄₉ | L_{b286} |
| 365 | Lₐ₁₅₇ | L_{b12} | 366 | Lₐ₁₅₇ | L_{b286} |
| 367 | Lₐ₁₈₀ | L_{b12} | 368 | Lₐ₁₈₀ | L_{b286} |
| 369 | Lₐ₁₉₂ | L_{b12} | 370 | Lₐ₁₉₂ | L_{b286} |
| 371 | Lₐ₂₀₀ | L_{b12} | 372 | Lₐ₂₀₀ | L_{b286} |
| 373 | Lₐ₂₁₃ | L_{b12} | 374 | Lₐ₂₁₃ | L_{b286} |
| 375 | Lₐ₂₃₀ | L_{b12} | 376 | Lₐ₂₃₀ | L_{b286} |
| 377 | Lₐ₂₃₈ | L_{b12} | 378 | Lₐ₂₃₈ | L_{b286} |
| 379 | Lₐ₂₉₇ | L_{b12} | 380 | Lₐ₂₉₇ | L_{b286} |
| 381 | Lₐ₃₀₂ | L_{b12} | 382 | Lₐ₃₀₂ | L_{b286} |
| 383 | Lₐ₃₅₄ | L_{b12} | 384 | Lₐ₃₅₄ | L_{b286} |
| 385 | Lₐ₃₅₅ | L_{b12} | 386 | Lₐ₃₅₅ | L_{b286} |
| 387 | Lₐ₃₆₈ | L_{b12} | 388 | Lₐ₃₆₈ | L_{b286} |
| 389 | Lₐ₄₀₉ | L_{b12} | 390 | Lₐ₄₀₉ | L_{b286} |
| 391 | Lₐ₄₁₇ | L_{b12} | 392 | Lₐ₄₁₇ | L_{b286} |
| 393 | Lₐ₄₂₇ | L_{b12} | 394 | Lₐ₄₂₇ | L_{b286} |
| 395 | Lₐ₄₃₃ | L_{b12} | 396 | Lₐ₄₃₃ | L_{b286} |
| 397 | Lₐ₄₄₈ | L_{b12} | 398 | Lₐ₄₄₈ | L_{b286} |
| 399 | Lₐ₅₃₈ | L_{b12} | 400 | Lₐ₅₃₈ | L_{b286} |

wherein the Compound 401 to Compound 522 each have a structure of Ir(Lₐ)₂(L_{b}), wherein the two Lₐ are the same, and Lₐ and L_{b} are selected from the structures listed in the following table, respectively:

| Compound | | | Compound | | |
|---|---|---|---|---|---|
| No. | Lₐ | L_{b} | No. | Lₐ | L_{b} |
| 401 | Lₐ₂₇₁ | L_{b2} | 402 | Lₐ₂₇₁ | L_{b3} |
| 403 | Lₐ₂₅₃ | L_{b2} | 404 | Lₐ₂₅₃ | L_{b3} |
| 405 | Lₐ₁₀₁ | L_{b2} | 406 | Lₐ₁₀₁ | L_{b3} |
| 407 | Lₐ₁₁₃ | L_{b2} | 408 | Lₐ₁₁₃ | L_{b3} |
| 409 | Lₐ₁₂₁ | L_{b2} | 410 | Lₐ₁₂₁ | L_{b3} |
| 411 | Lₐ₁₂₀ | L_{b2} | 412 | Lₐ₁₂₀ | L_{b3} |
| 413 | Lₐ₁₃₄ | L_{b2} | 414 | Lₐ₁₃₄ | L_{b3} |
| 415 | Lₐ₁₄₉ | L_{b2} | 416 | Lₐ₁₄₉ | L_{b3} |
| 417 | Lₐ₁₅₇ | L_{b2} | 418 | Lₐ₁₅₇ | L_{b3} |
| 419 | Lₐ₁₈₀ | L_{b2} | 420 | Lₐ₁₈₀ | L_{b3} |
| 421 | Lₐ₁₉₂ | L_{b2} | 422 | Lₐ₁₉₂ | L_{b3} |
| 423 | Lₐ₂₀₀ | L_{b2} | 424 | Lₐ₂₀₀ | L_{b3} |
| 425 | Lₐ₂₁₃ | L_{b2} | 426 | Lₐ₂₁₃ | L_{b3} |
| 427 | Lₐ₂₃₀ | L_{b2} | 428 | Lₐ₂₃₀ | L_{b3} |
| 429 | Lₐ₂₃₈ | L_{b2} | 430 | Lₐ₂₃₈ | L_{b3} |
| 431 | Lₐ₅₂₂ | L_{b1} | 432 | Lₐ₅₂₂ | L_{b81} |
| 433 | Lₐ₂₆₈ | L_{b1} | 434 | Lₐ₂₆₈ | L_{b81} |
| 435 | Lₐ₂₇₁ | L_{b10} | 436 | Lₐ₂₇₁ | L_{b209} |
| 437 | Lₐ₂₅₃ | L_{b10} | 438 | Lₐ₂₅₃ | L_{b209} |
| 465 | Lₐ₇₃ | L_{b10} | 466 | Lₐ₇₃ | L_{b209} |
| 467 | Lₐ₁₀₁ | L_{b10} | 468 | Lₐ₁₀₁ | L_{b209} |
| 469 | Lₐ₁₁₃ | L_{b10} | 470 | Lₐ₁₁₃ | L_{b209} |
| 471 | Lₐ₁₂₁ | L_{b10} | 472 | Lₐ₁₂₁ | L_{b209} |
| 473 | Lₐ₁₂₀ | L_{b10} | 474 | Lₐ₁₂₀ | L_{b209} |
| 475 | Lₐ₁₃₄ | L_{b10} | 476 | Lₐ₁₃₄ | L_{b209} |
| 477 | Lₐ₁₄₉ | L_{b10} | 478 | Lₐ₁₄₉ | L_{b209} |
| 479 | Lₐ₃₆₈ | L_{b10} | 480 | Lₐ₃₆₈ | L_{b209} |
| 481 | Lₐ₄₀₉ | L_{b10} | 482 | Lₐ₄₀₉ | L_{b209} |
| 483 | Lₐ₄₁₇ | L_{b10} | 484 | Lₐ₄₁₇ | L_{b209} |
| 485 | Lₐ₄₂₇ | L_{b10} | 486 | Lₐ₄₂₇ | L_{b209} |
| 487 | Lₐ₄₃₃ | L_{b10} | 488 | Lₐ₄₃₃ | L_{b209} |
| 489 | Lₐ₄₄₈ | L_{b10} | 490 | Lₐ₄₄₈ | L_{b209} |
| 491 | Lₐ₅₃₈ | L_{b10} | 492 | Lₐ₅₃₈ | L_{b209} |
| 493 | Lₐ₂₇₁ | L_{b95} | 494 | Lₐ₂₇₁ | L_{b21} |
| 495 | Lₐ₂₅₃ | L_{b95} | 496 | Lₐ₂₅₃ | L_{b21} |
| 497 | Lₐ₁₂₉ | L_{b95} | 498 | Lₐ₁₂₉ | L_{b21} |
| 499 | Lₐ₁₆₈ | L_{b95} | 500 | Lₐ₁₆₈ | L_{b21} |
| 501 | Lₐ₃₇ | L_{b95} | 502 | Lₐ₃₇ | L_{b21} |
| 503 | Lₐ₅₂₂ | L_{b12} | 504 | Lₐ₅₂₂ | L_{b286} |
| 505 | Lₐ₂₆₈ | L_{b12} | 506 | Lₐ₂₆₈ | L_{b286} |
| 507 | Lₐ₁₃₄ | L_{b12} | 508 | Lₐ₁₃₄ | L_{b286} |
| 509 | Lₐ₁₄₉ | L_{b12} | 510 | Lₐ₁₄₉ | L_{b286} |
| 511 | Lₐ₁₅₇ | L_{b12} | 512 | Lₐ₁₅₇ | L_{b286} |
| 513 | Lₐ₁₈₀ | L_{b12} | 514 | Lₐ₁₈₀ | L_{b286} |
| 515 | Lₐ₁₉₂ | L_{b12} | 516 | Lₐ₁₉₂ | L_{b286} |
| 517 | Lₐ₂₀₀ | L_{b12} | 518 | Lₐ₂₀₀ | L_{b286} |
| 519 | Lₐ₂₁₃ | L_{b12} | 520 | Lₐ₂₁₃ | L_{b286} |
| 521 | Lₐ₂₃₀ | L_{b12} | 522 | Lₐ₂₃₀ | L_{b286} |

wherein the Compound 523 to Compound 608 each have a structure of Ir(Lₐ)(L_{b})(L_{c}), wherein Lₐ, L_{b} and L_{c} are selected from the structures listed in the following table, respectively:

| Compound | | | | Compound | | | |
|---|---|---|---|---|---|---|---|
| No. | Lₐ | L_{b} | L_{c} | No. | Lₐ | L_{b} | L_{c} |
| 523 | Lₐ₂₇₁ | L_{b81} | L_{c1} | 524 | Lₐ₄₇ | L_{b81} | L_{c1} |
| 525 | Lₐ₂₅₃ | L_{b81} | L_{c3} | 526 | Lₐ₆₅ | L_{b81} | L_{c3} |
| 527 | Lₐ₁₂₉ | L_{b81} | L_{c5} | 528 | Lₐ₇₃ | L_{b81} | L_{c5} |
| 529 | Lₐ₁₆₈ | L_{b81} | L_{c12} | 530 | Lₐ₁₀₁ | L_{b81} | L_{c12} |
| 531 | Lₐ₃₇ | L_{b81} | L_{c17} | 532 | Lₐ₁₁₃ | L_{b81} | L_{c17} |
| 533 | Lₐ₃₁ | L_{b81} | L_{c18} | 534 | Lₐ₁₂₁ | L_{b81} | L_{c18} |
| 535 | Lₐ₃₂₈ | L_{b81} | L_{c29} | 536 | Lₐ₁₃₄ | L_{b81} | L_{c29} |
| 537 | Lₐ₅₂₂ | L_{b81} | L_{c30} | 538 | Lₐ₁₄₉ | L_{b81} | L_{c30} |
| 539 | Lₐ₂₆₈ | L_{b81} | L_{c40} | 540 | Lₐ₁₅₇ | L_{b81} | L_{c40} |
| 541 | Lₐ₂₈₇ | L_{b81} | L_{c46} | 542 | Lₐ₁₈₀ | L_{b81} | L_{c46} |
| 543 | Lₐ₇ | L_{b81} | L_{c59} | 544 | Lₐ₁₉₂ | L_{b81} | L_{c59} |
| 545 | Lₐ₂₁ | L_{b81} | L_{c79} | 546 | Lₐ₂₀₀ | L_{b81} | L_{c79} |
| 547 | Lₐ₃₄ | L_{b81} | L_{c99} | 548 | Lₐ₂₁₃ | L_{b81} | L_{c99} |
| 549 | Lₐ₂₃₀ | L_{b81} | L_{c112} | 550 | Lₐ₂₃₈ | L_{b81} | L_{c112} |
| 551 | Lₐ₂₉₇ | L_{b81} | L_{c138} | 552 | Lₐ₃₃₀₂ | L_{b81} | L_{c138} |
| 553 | Lₐ₃₅₄ | L_{b81} | L_{c182} | 554 | Lₐ₃₅₅ | L_{b81} | L_{c182} |
| 555 | Lₐ₃₆₈ | L_{b81} | L_{c192} | 556 | Lₐ₄₀₉ | L_{b81} | L_{c192} |
| 557 | Lₐ₄₁₇ | L_{b81} | L_{c195} | 558 | Lₐ₄₂₇ | L_{b81} | L_{c195} |
| 559 | Lₐ₄₃₃ | L_{b81} | L_{c201} | 560 | Lₐ₄₄₈ | L_{b81} | L_{c201} |
| 587 | Lₐ₅₃₈ | L_{b81} | L_{c205} | 588 | Lₐ₃₃ | L_{b81} | L_{c205} |
| 589 | Lₐ₂₈ | L_{b81} | L_{c211} | 590 | Lₐ₃₃ | L_{b81} | L_{c211} |
| 591 | Lₐ₂₈ | L_{b81} | L_{c212} | 592 | Lₐ₃₃ | L_{b81} | L_{c212} |
| 593 | Lₐ₂₈ | L_{b81} | L_{c226} | 594 | Lₐ₃₃ | L_{b81} | L_{c226} |
| 595 | Lₐ₂₈ | L_{b81} | L_{c229} | 596 | Lₐ₃₃ | L_{b81} | L_{c229} |
| 597 | Lₐ₂₈ | L_{b81} | L_{c252} | 598 | Lₐ₃₃ | L_{b81} | L_{c252} |
| 599 | Lₐ₂₈ | L_{b81} | L_{c256} | 600 | Lₐ₃₃ | L_{b81} | L_{c256} |
| 601 | Lₐ₂₈ | L_{b81} | L_{c310} | 602 | Lₐ₃₃ | L_{b81} | L_{c310} |
| 603 | Lₐ₂₈ | L_{b81} | L_{c326} | 604 | Lₐ₃₃ | L_{b81} | L_{c326} |
| 605 | Lₐ₂₈ | L_{b81} | L_{c327} | 606 | Lₐ₃₃ | L_{b81} | L_{c327} |
| 607 | Lₐ₂₈ | L_{b81} | L_{c328} | 608 | Lₐ₃₃ | L_{b81} | L_{c328} |

wherein optionally, hydrogen atoms in the Compound 1 to Compound 608 can be partially or fully substituted with deuterium.

18. An electroluminescent device, comprising:
an anode,
a cathode, and
an organic layer disposed between the anode and the cathode, wherein the organic layer comprises the metal complex of claim 1.

19. The device according to claim 18, wherein the organic layer is an emissive layer, and the metal complex is a light-emitting material.

20. The device according to claim 19, wherein the emissive layer further comprises at least one host material;
preferably, the at least one host material comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof;
more preferably, the emissive layer comprises a first host material and a second host material;
the first host material is selected from the group consisting of Compound 1-1-1 to Compound 1-1-104, Compound 1-2-1 to Compound 1-2-100 and Compound 1-3-1 to Compound 1-3-100: 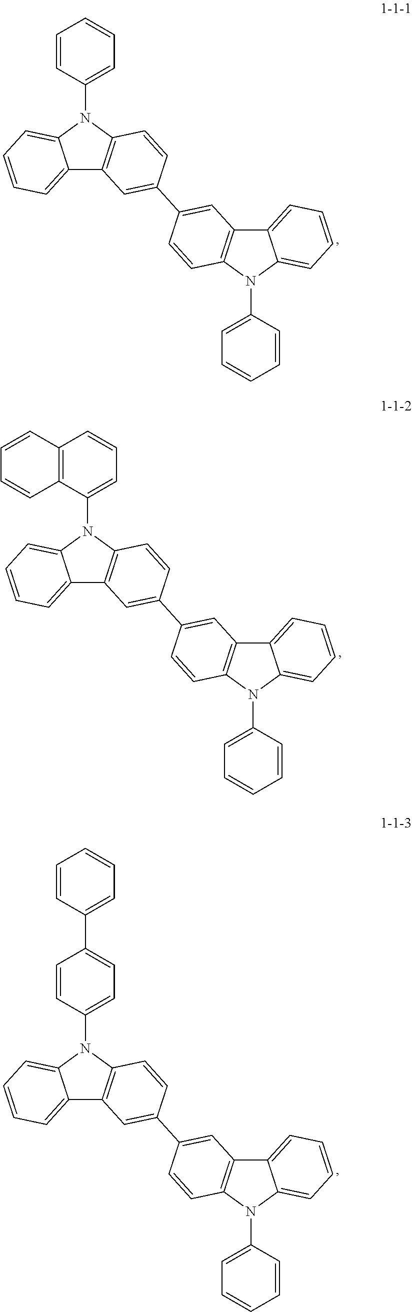 [SMILES: c1ccc(-n2c3ccccc3c3cc(-c4ccc5c(c4)c4ccccc4n5-c4ccccc4)ccc32)cc1 ; c1ccc(-n2c3ccccc3c3cc(-c4ccc5c(c4)c4ccccc4n5-c4cccc5ccccc45)ccc32)cc1 ; c1ccc(-c2ccc(-n3c4ccccc4c4cc(-c5ccc6c(c5)c5ccccc5n6-c5ccccc5)ccc43)cc2)cc1] 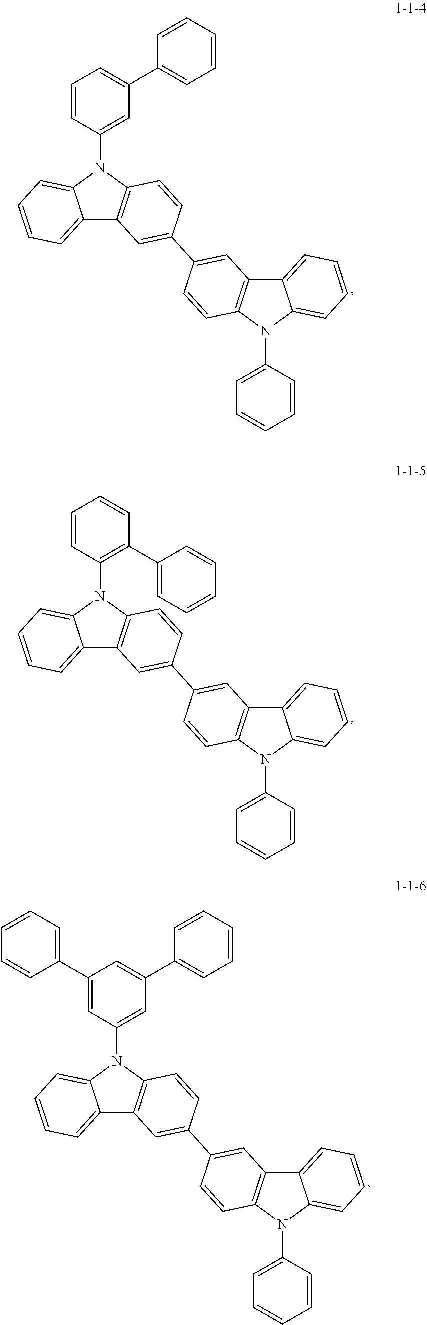 [SMILES: c1ccc(-c2cccc(-n3c4ccccc4c4cc(-c5ccc6c(c5)c5ccccc5n6-c5ccccc5)ccc43)c2)cc1 ; c1ccc(-c2ccccc2-n2c3ccccc3c3cc(-c4ccc5c(c4)c4ccccc4n5-c4ccccc4)ccc32)cc1 ; c1ccc(-c2cc(-c3ccccc3)cc(-n3c4ccccc4c4cc(-c5ccc6c(c5)c5ccccc5n6-c5ccccc5)ccc43)c2)cc1] 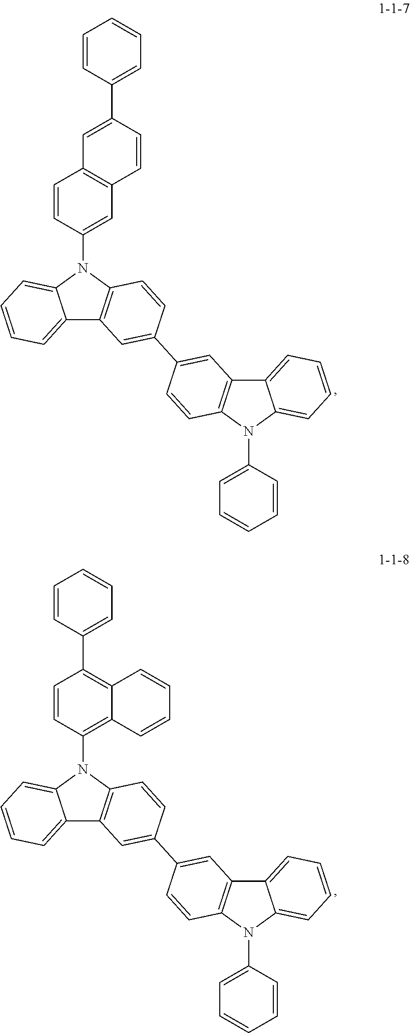 [SMILES: c1ccc(-c2ccc3cc(-n4c5ccccc5c5cc(-c6ccc7c(c6)c6ccccc6n7-c6ccccc6)ccc54)ccc3c2)cc1 ; c1ccc(-c2ccc(-n3c4ccccc4c4cc(-c5ccc6c(c5)c5ccccc5n6-c5ccccc5)ccc43)c3ccccc23)cc1] 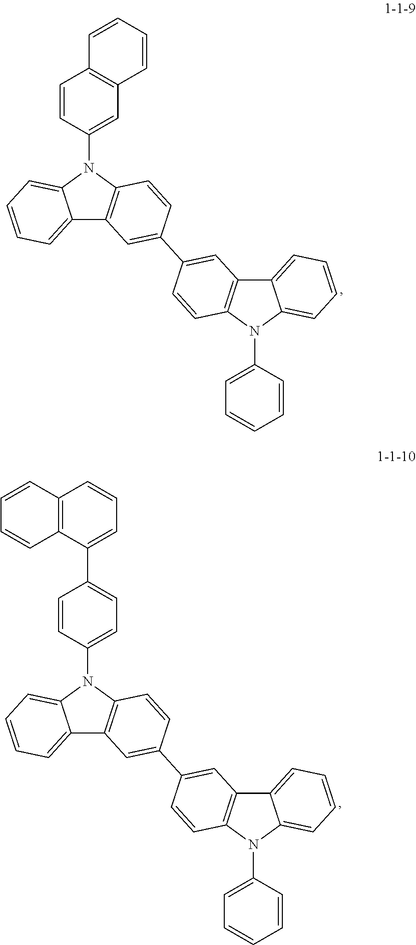 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4ccc(-c5cccc6ccccc56)cc4)ccc32)cc1] 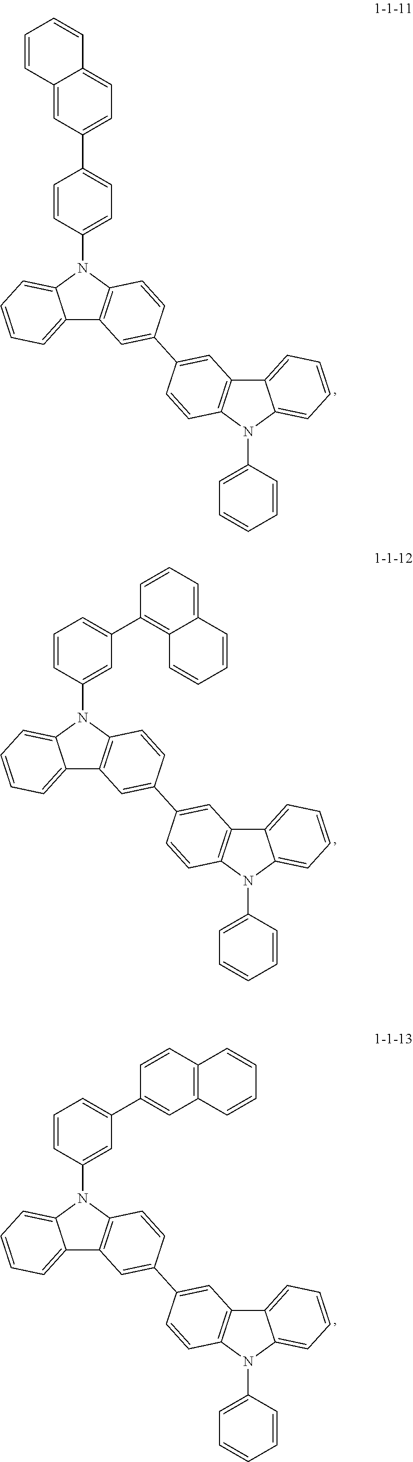 [SMILES: c1ccc(-n2c3ccccc3c3cc(-c4ccc5c(c4)c4ccccc4n5-c4ccc(-c5ccc6ccccc6c5)cc4)ccc32)cc1 ; c1ccc(-n2c3ccccc3c3cc(-c4ccc5c(c4)c4ccccc4n5-c4cccc(-c5cccc6ccccc56)c4)ccc32)cc1 ; c1ccc(-n2c3ccccc3c3cc(-c4ccc5c(c4)c4ccccc4n5-c4cccc(-c5ccc6ccccc6c5)c4)ccc32)cc1] 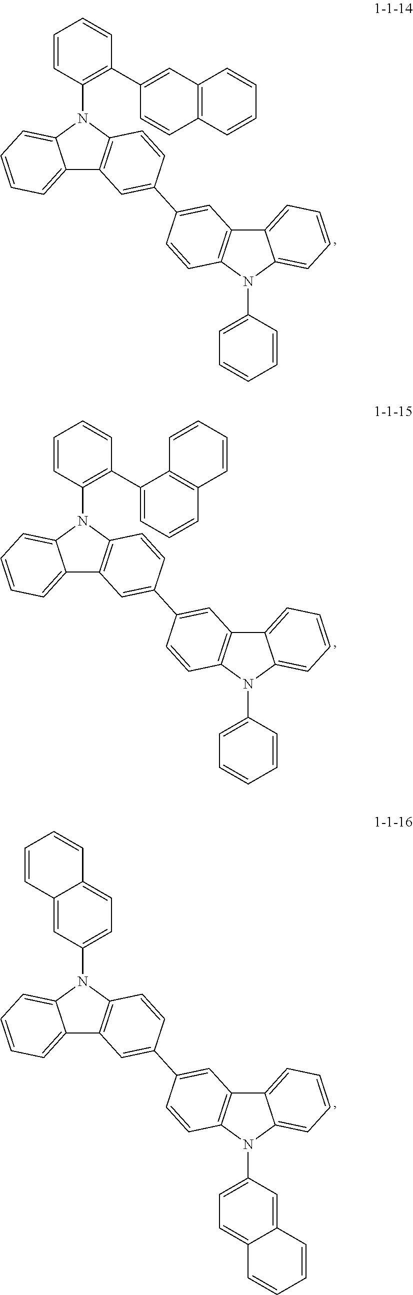 [SMILES: c1ccc(-n2c3ccccc3c3cc(-c4ccc5c(c4)c4ccccc4n5-c4ccccc4-c4ccc5ccccc5c4)ccc32)cc1 ; c1ccc(-n2c3ccccc3c3cc(-c4ccc5c(c4)c4ccccc4n5-c4ccccc4-c4cccc5ccccc45)ccc32)cc1 ; c1ccc2cc(-n3c4ccccc4c4cc(-c5ccc6c(c5)c5ccccc5n6-c5ccc6ccccc6c5)ccc43)ccc2c1] 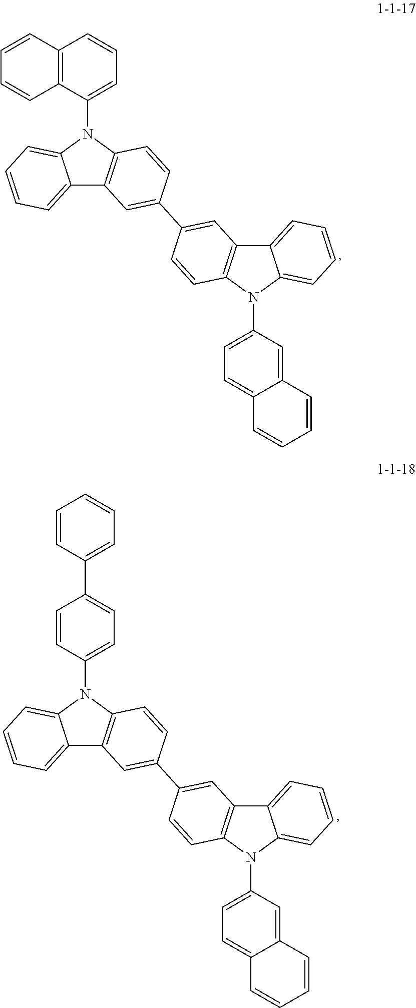 [SMILES: c1ccc2cc(-n3c4ccccc4c4cc(-c5ccc6c(c5)c5ccccc5n6-c5cccc6ccccc56)ccc43)ccc2c1 ; c1ccc(-c2ccc(-n3c4ccccc4c4cc(-c5ccc6c(c5)c5ccccc5n6-c5ccc6ccccc6c5)ccc43)cc2)cc1] 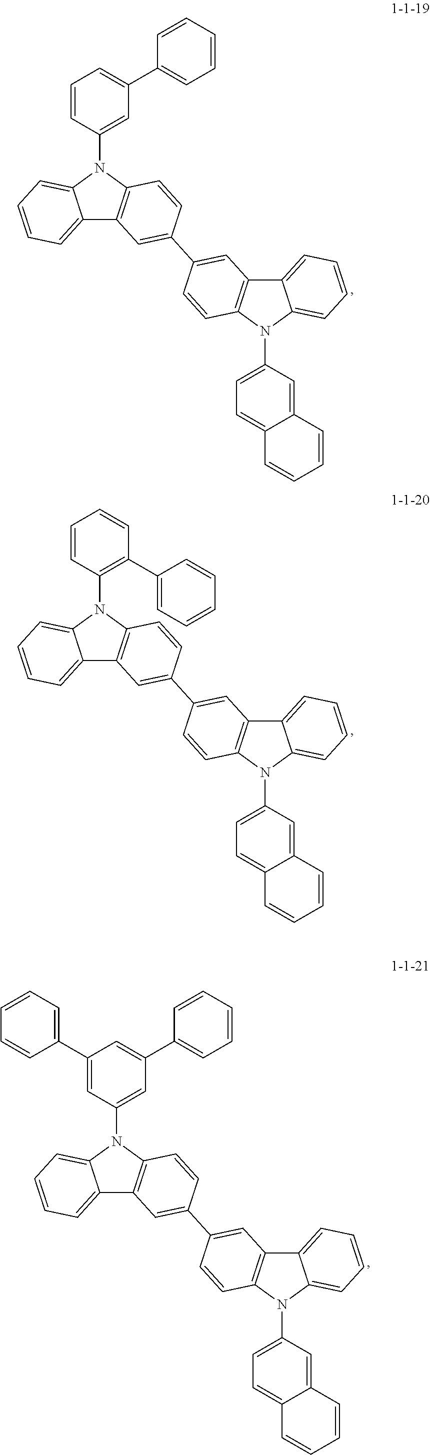 [SMILES: c1ccc(-c2cccc(-n3c4ccccc4c4cc(-c5ccc6c(c5)c5ccccc5n6-c5ccc6ccccc6c5)ccc43)c2)cc1 ; c1ccc(-c2ccccc2-n2c3ccccc3c3cc(-c4ccc5c(c4)c4ccccc4n5-c4ccc5ccccc5c4)ccc32)cc1 ; c1ccc(-c2cc(-c3ccccc3)cc(-n3c4ccccc4c4cc(-c5ccc6c(c5)c5ccccc5n6-c5ccc6ccccc6c5)ccc43)c2)cc1] 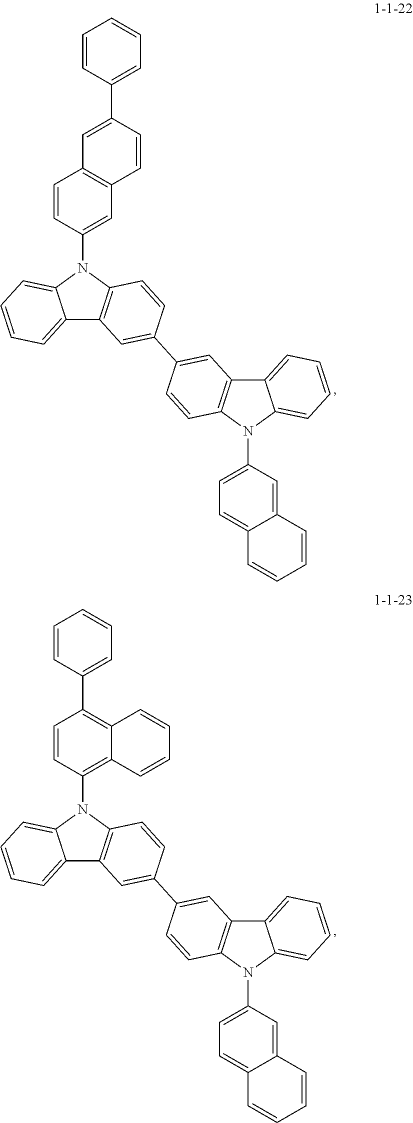 [SMILES: c1ccc(-c2ccc3cc(-n4c5ccccc5c5cc(-c6ccc7c(c6)c6ccccc6n7-c6ccc7ccccc7c6)ccc54)ccc3c2)cc1 ; c1ccc(-c2ccc(-n3c4ccccc4c4cc(-c5ccc6c(c5)c5ccccc5n6-c5ccc6ccccc6c5)ccc43)c3ccccc23)cc1] 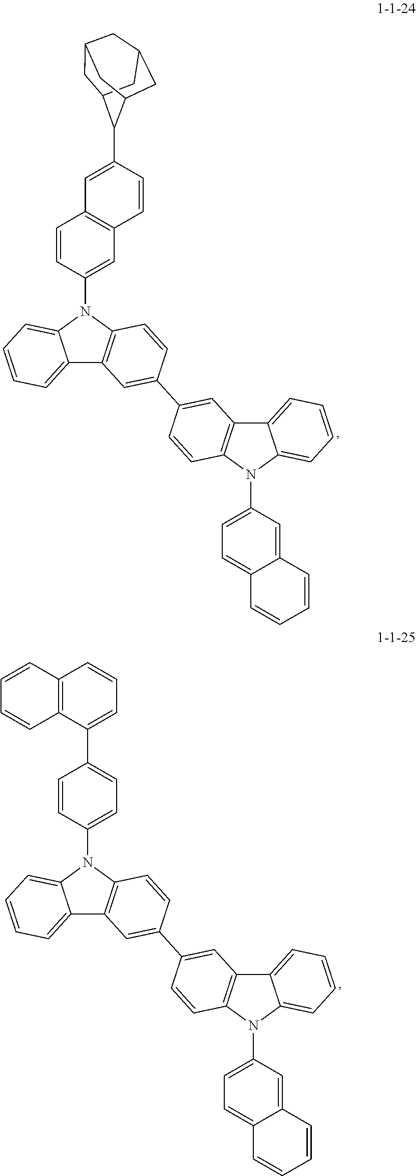 [SMILES: c1ccc2cc(-n3c4ccccc4c4cc(-c5ccc6c(c5)c5ccccc5n6-c5ccc6cc(C7C8CC9CC(C8)CC7C9)ccc6c5)ccc43)ccc2c1 ; c1ccc2cc(-n3c4ccccc4c4cc(-c5ccc6c(c5)c5ccccc5n6-c5ccc(-c6cccc7ccccc67)cc5)ccc43)ccc2c1] 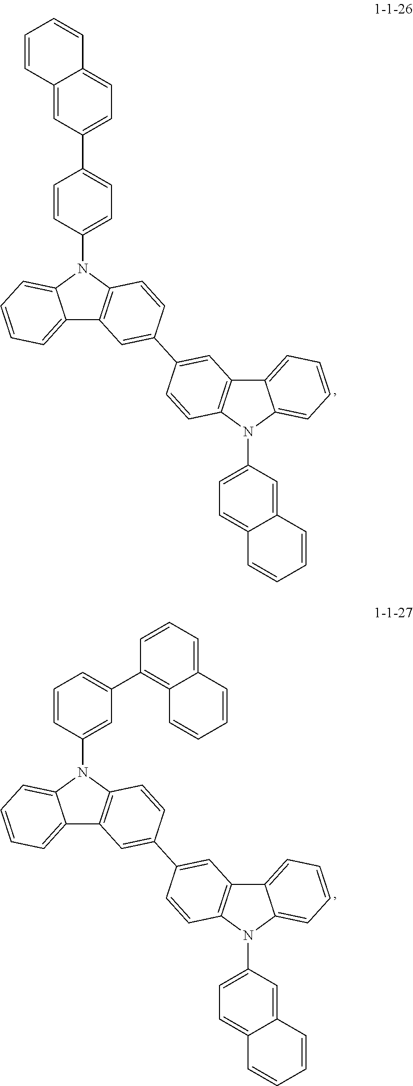 [SMILES: c1ccc2cc(-c3ccc(-n4c5ccccc5c5cc(-c6ccc7c(c6)c6ccccc6n7-c6ccc7ccccc7c6)ccc54)cc3)ccc2c1 ; c1cc(-c2cccc3ccccc23)cc(-n2c3ccccc3c3cc(-c4ccc5c(c4)c4ccccc4n5-c4ccc5ccccc5c4)ccc32)c1] 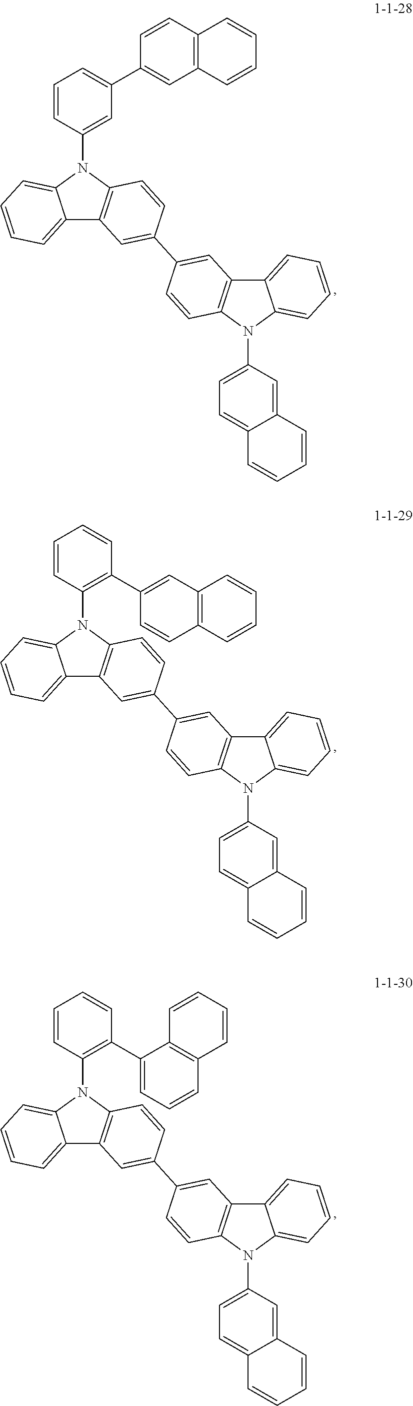 [SMILES: c1cc(-c2ccc3ccccc3c2)cc(-n2c3ccccc3c3cc(-c4ccc5c(c4)c4ccccc4n5-c4ccc5ccccc5c4)ccc32)c1 ; c1ccc(-n2c3ccccc3c3cc(-c4ccc5c(c4)c4ccccc4n5-c4ccc5ccccc5c4)ccc32)c(-c2ccc3ccccc3c2)c1 ; c1ccc(-n2c3ccccc3c3cc(-c4ccc5c(c4)c4ccccc4n5-c4ccc5ccccc5c4)ccc32)c(-c2cccc3ccccc23)c1] 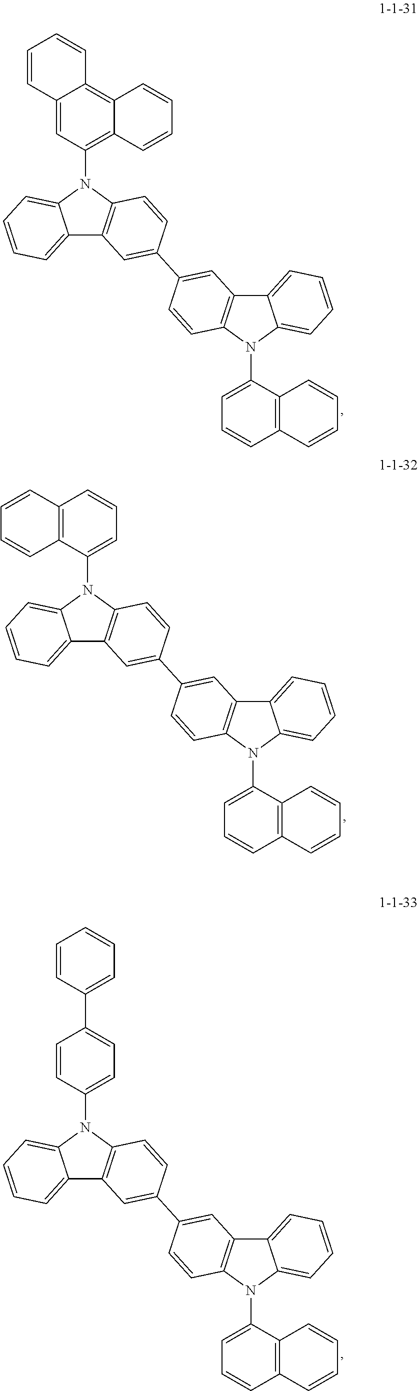 [SMILES: c1ccc2c(-n3c4ccccc4c4cc(-c5ccc6c(c5)c5ccccc5n6-c5cc6ccccc6c6ccccc56)ccc43)cccc2c1 ; c1ccc2c(-n3c4ccccc4c4cc(-c5ccc6c(c5)c5ccccc5n6-c5cccc6ccccc56)ccc43)cccc2c1 ; c1ccc(-c2ccc(-n3c4ccccc4c4cc(-c5ccc6c(c5)c5ccccc5n6-c5cccc6ccccc56)ccc43)cc2)cc1] 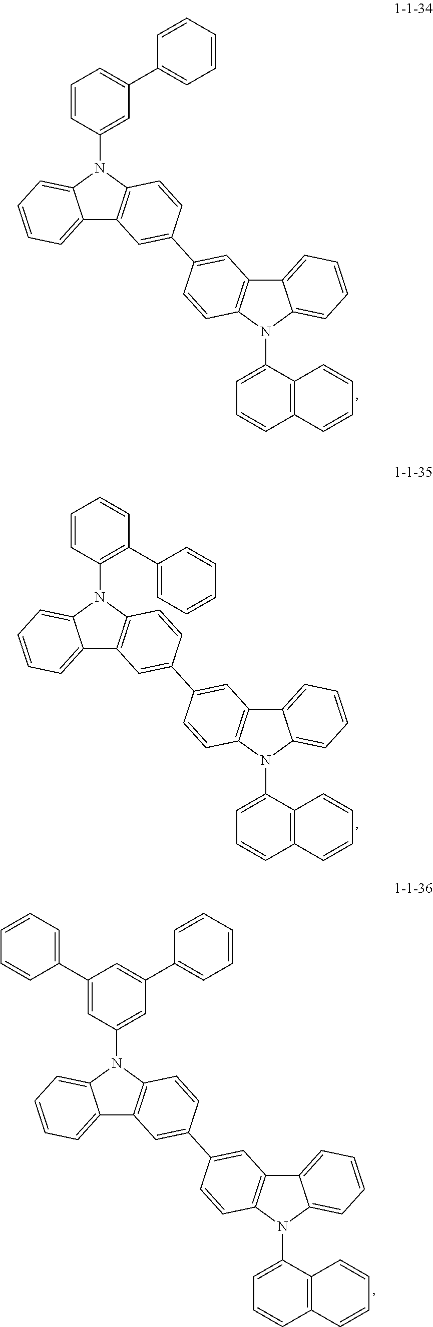 [SMILES: c1ccc(-c2cccc(-n3c4ccccc4c4cc(-c5ccc6c(c5)c5ccccc5n6-c5cccc6ccccc56)ccc43)c2)cc1 ; c1ccc(-c2ccccc2-n2c3ccccc3c3cc(-c4ccc5c(c4)c4ccccc4n5-c4cccc5ccccc45)ccc32)cc1 ; c1ccc(-c2cc(-c3ccccc3)cc(-n3c4ccccc4c4cc(-c5ccc6c(c5)c5ccccc5n6-c5cccc6ccccc56)ccc43)c2)cc1] 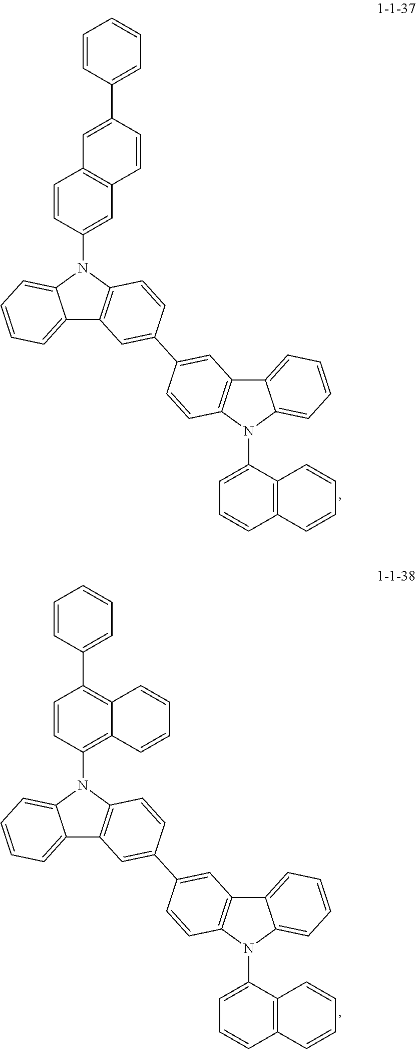 [SMILES: c1ccc(-c2ccc3cc(-n4c5ccccc5c5cc(-c6ccc7c(c6)c6ccccc6n7-c6cccc7ccccc67)ccc54)ccc3c2)cc1 ; c1ccc(-c2ccc(-n3c4ccccc4c4cc(-c5ccc6c(c5)c5ccccc5n6-c5cccc6ccccc56)ccc43)c3ccccc23)cc1] 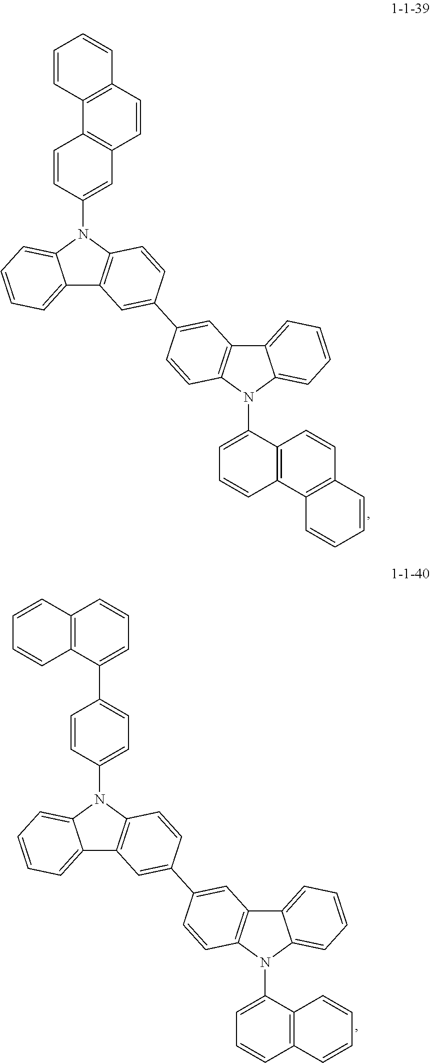 [SMILES: c1ccc2c(c1)ccc1cc(-n3c4ccccc4c4cc(-c5ccc6c(c5)c5ccccc5n6-c5cccc6c5ccc5ccccc56)ccc43)ccc12 ; c1ccc2c(-c3ccc(-n4c5ccccc5c5cc(-c6ccc7c(c6)c6ccccc6n7-c6cccc7ccccc67)ccc54)cc3)cccc2c1] 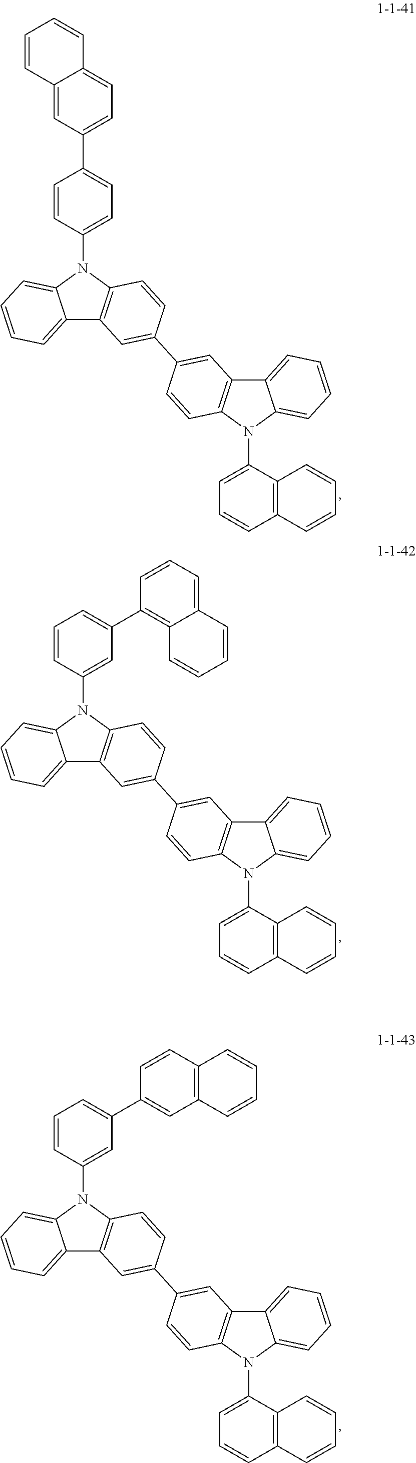 [SMILES: c1ccc2cc(-c3ccc(-n4c5ccccc5c5cc(-c6ccc7c(c6)c6ccccc6n7-c6cccc7ccccc67)ccc54)cc3)ccc2c1 ; c1cc(-c2cccc3ccccc23)cc(-n2c3ccccc3c3cc(-c4ccc5c(c4)c4ccccc4n5-c4cccc5ccccc45)ccc32)c1 ; c1cc(-c2ccc3ccccc3c2)cc(-n2c3ccccc3c3cc(-c4ccc5c(c4)c4ccccc4n5-c4cccc5ccccc45)ccc32)c1] 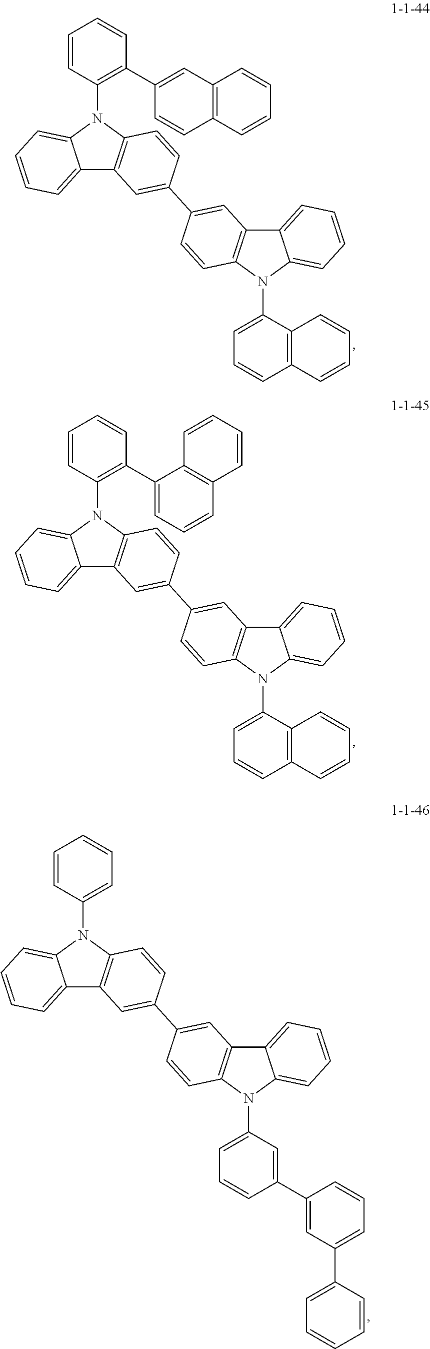 [SMILES: c1ccc(-n2c3ccccc3c3cc(-c4ccc5c(c4)c4ccccc4n5-c4cccc5ccccc45)ccc32)c(-c2ccc3ccccc3c2)c1 ; c1ccc(-n2c3ccccc3c3cc(-c4ccc5c(c4)c4ccccc4n5-c4cccc5ccccc45)ccc32)c(-c2cccc3ccccc23)c1 ; c1ccc(-c2cccc(-c3cccc(-n4c5ccccc5c5cc(-c6ccc7c(c6)c6ccccc6n7-c6ccccc6)ccc54)c3)c2)cc1] 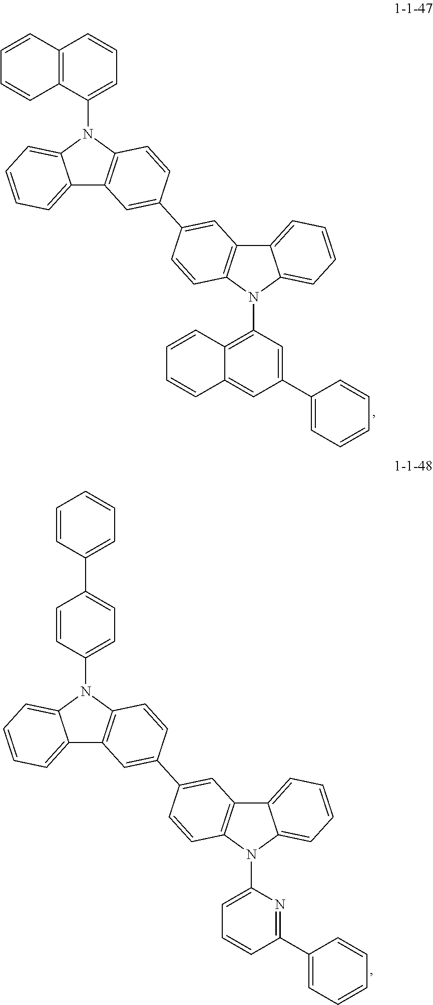 [SMILES: c1ccc(-c2cc(-n3c4ccccc4c4cc(-c5ccc6c(c5)c5ccccc5n6-c5cccc6ccccc56)ccc43)c3ccccc3c2)cc1 ; c1ccc(-c2ccc(-n3c4ccccc4c4cc(-c5ccc6c(c5)c5ccccc5n6-c5cccc(-c6ccccc6)n5)ccc43)cc2)cc1] 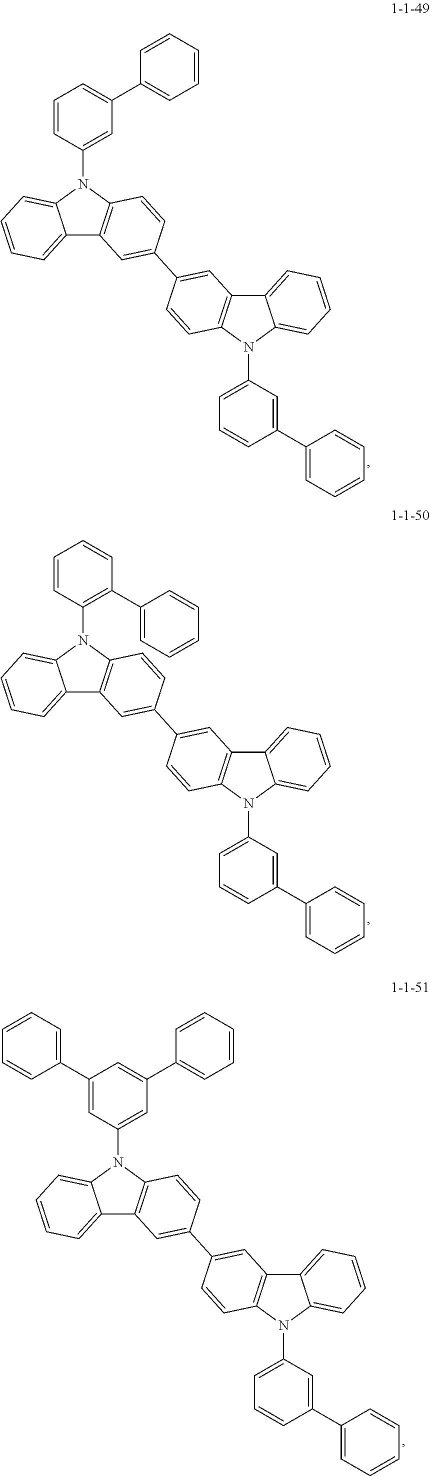 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1 ; c1ccc(-c2cccc(-n3c4ccccc4c4cc(-c5ccc6c(c5)c5ccccc5n6-c5cc(-c6ccccc6)cc(-c6ccccc6)c5)ccc43)c2)cc1] 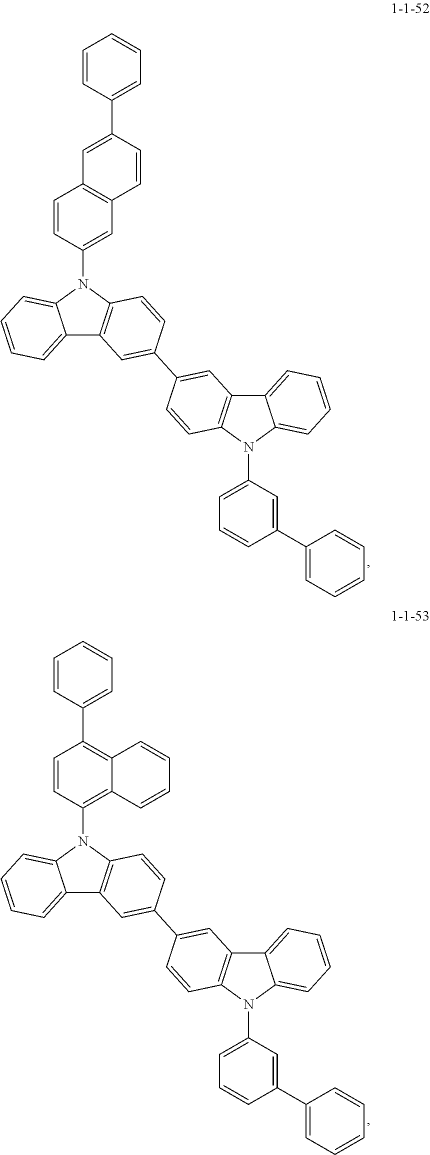 [SMILES: c1ccc(-c2cccc(-n3c4ccccc4c4cc(-c5ccc6c(c5)c5ccccc5n6-c5ccc6cc(-c7ccccc7)ccc6c5)ccc43)c2)cc1 ; c1ccc(-c2cccc(-n3c4ccccc4c4cc(-c5ccc6c(c5)c5ccccc5n6-c5ccc(-c6ccccc6)c6ccccc56)ccc43)c2)cc1] 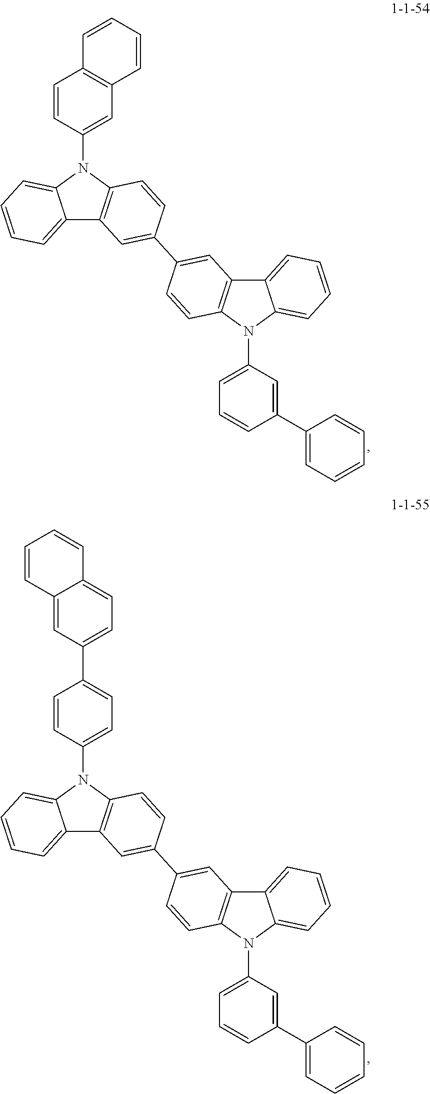 [SMILES: c1ccc(-c2cccc(-n3c4ccccc4c4cc(-c5ccc6c(c5)c5ccccc5n6-c5ccc6ccccc6c5)ccc43)c2)cc1 ; c1ccc(-c2cccc(-n3c4ccccc4c4cc(-c5ccc6c(c5)c5ccccc5n6-c5ccc(-c6ccc7ccccc7c6)cc5)ccc43)c2)cc1] 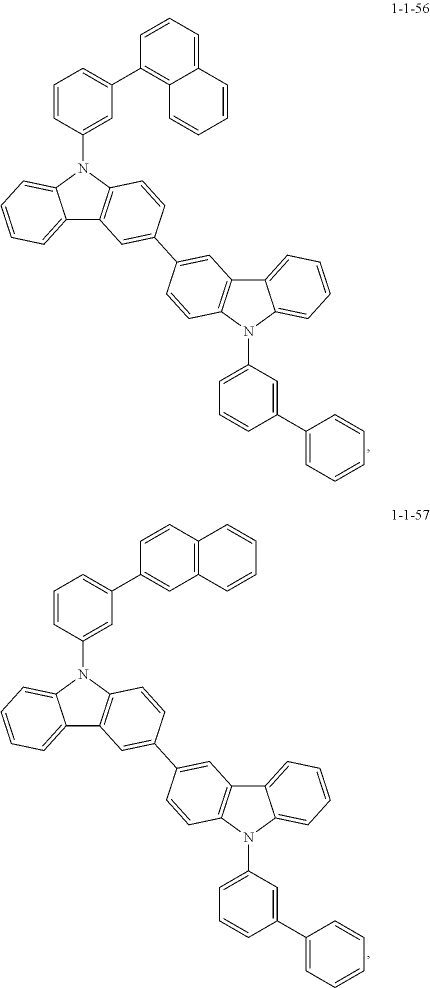 [SMILES: c1ccc(-c2cccc(-n3c4ccccc4c4cc(-c5ccc6c(c5)c5ccccc5n6-c5cccc(-c6cccc7ccccc67)c5)ccc43)c2)cc1 ; c1ccc(-c2cccc(-n3c4ccccc4c4cc(-c5ccc6c(c5)c5ccccc5n6-c5cccc(-c6ccc7ccccc7c6)c5)ccc43)c2)cc1] 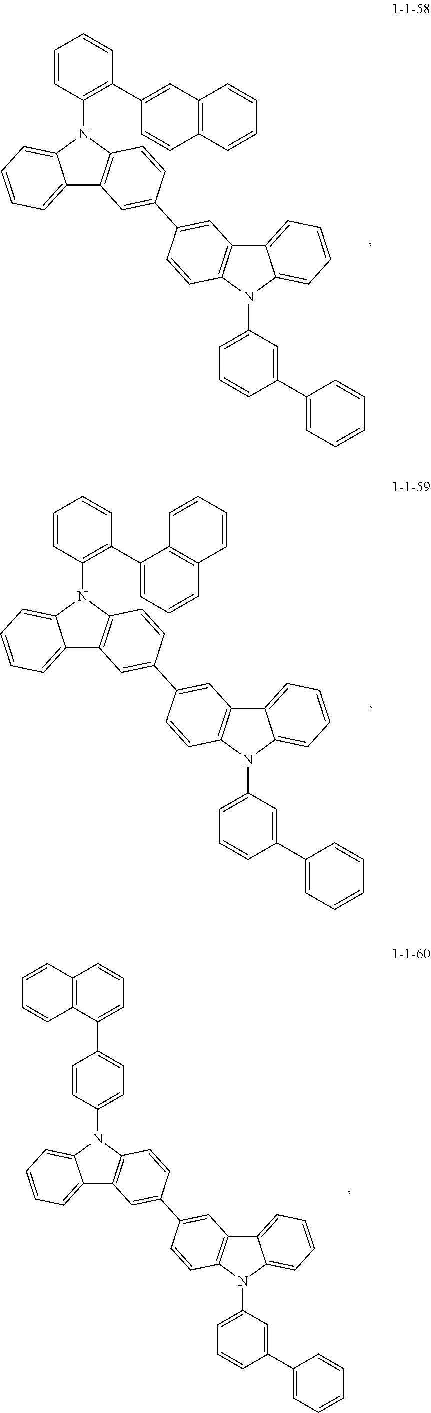 [SMILES: c1ccc(-c2cccc(-n3c4ccccc4c4cc(-c5ccc6c(c5)c5ccccc5n6-c5ccccc5-c5ccc6ccccc6c5)ccc43)c2)cc1 ; c1ccc(-c2cccc(-n3c4ccccc4c4cc(-c5ccc6c(c5)c5ccccc5n6-c5ccccc5-c5cccc6ccccc56)ccc43)c2)cc1 ; c1ccc(-c2cccc(-n3c4ccccc4c4cc(-c5ccc6c(c5)c5ccccc5n6-c5ccc(-c6cccc7ccccc67)cc5)ccc43)c2)cc1] 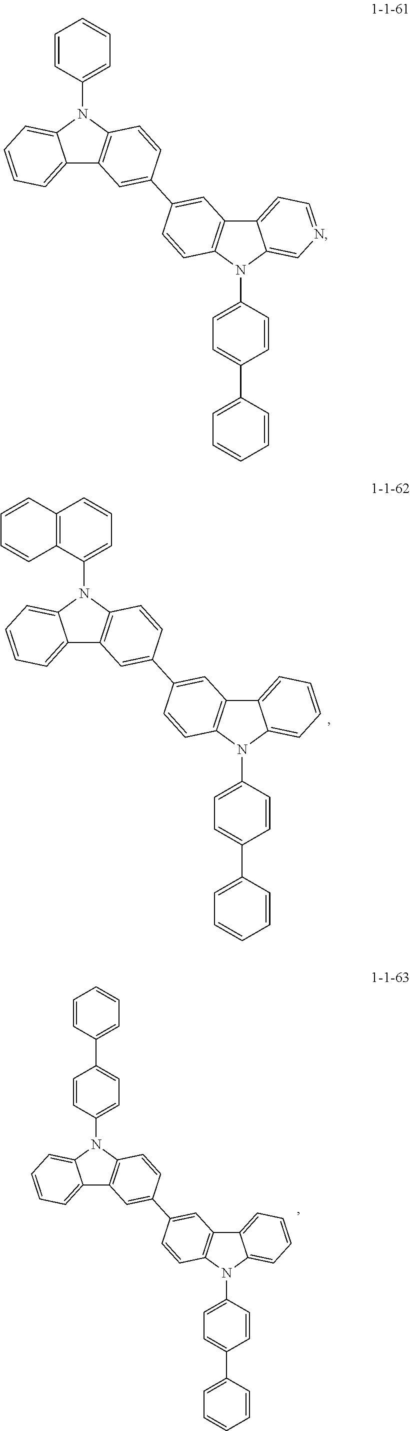 [SMILES: c1ccc(-c2ccc(-n3c4ccc(-c5ccc6c(c5)c5ccccc5n6-c5ccccc5)cc4c4ccncc43)cc2)cc1 ; c1ccc(-c2ccc(-n3c4ccccc4c4cc(-c5ccc6c(c5)c5ccccc5n6-c5cccc6ccccc56)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1] 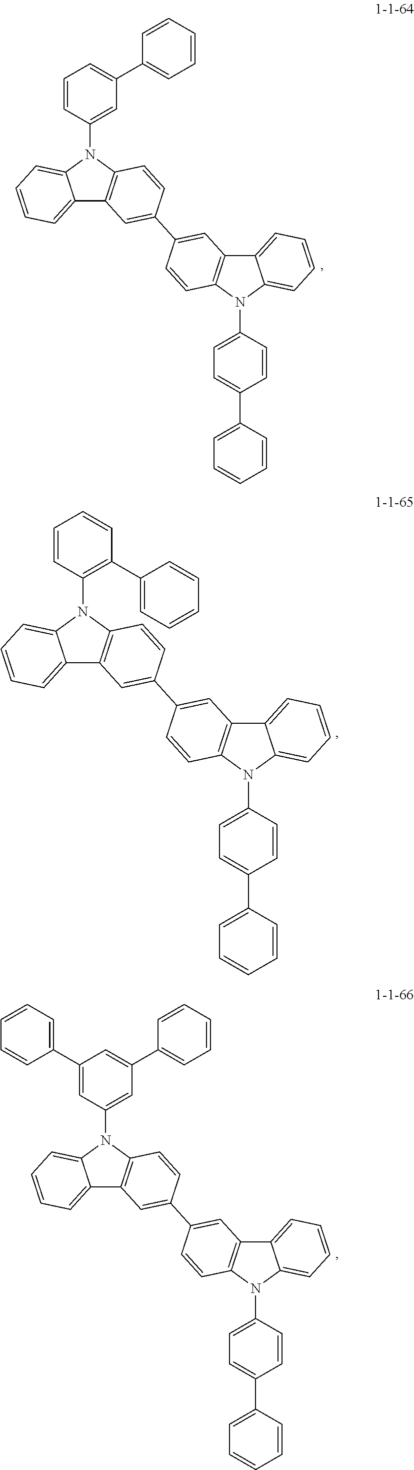 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5cc(-c6ccccc6)cc(-c6ccccc6)c5)ccc43)cc2)cc1] 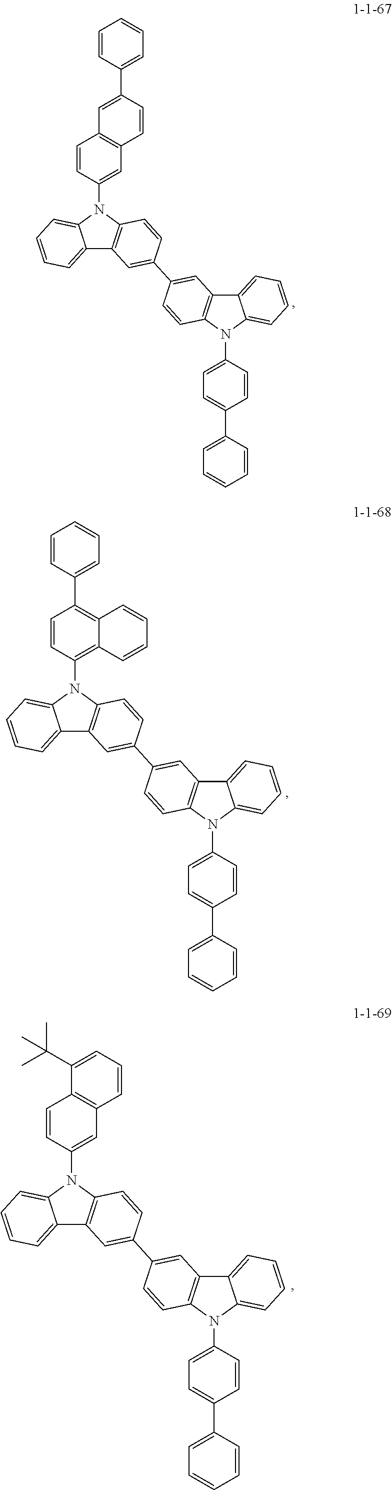 [SMILES: c1ccc(-c2ccc(-n3c4ccccc4c4cc(-c5ccc6c(c5)c5ccccc5n6-c5ccc6cc(-c7ccccc7)ccc6c5)ccc43)cc2)cc1 ; c1ccc(-c2ccc(-n3c4ccccc4c4cc(-c5ccc6c(c5)c5ccccc5n6-c5ccc(-c6ccccc6)c6ccccc56)ccc43)cc2)cc1 ; CC(C)(C)c1cccc2cc(-n3c4ccccc4c4cc(-c5ccc6c(c5)c5ccccc5n6-c5ccc(-c6ccccc6)cc5)ccc43)ccc12] 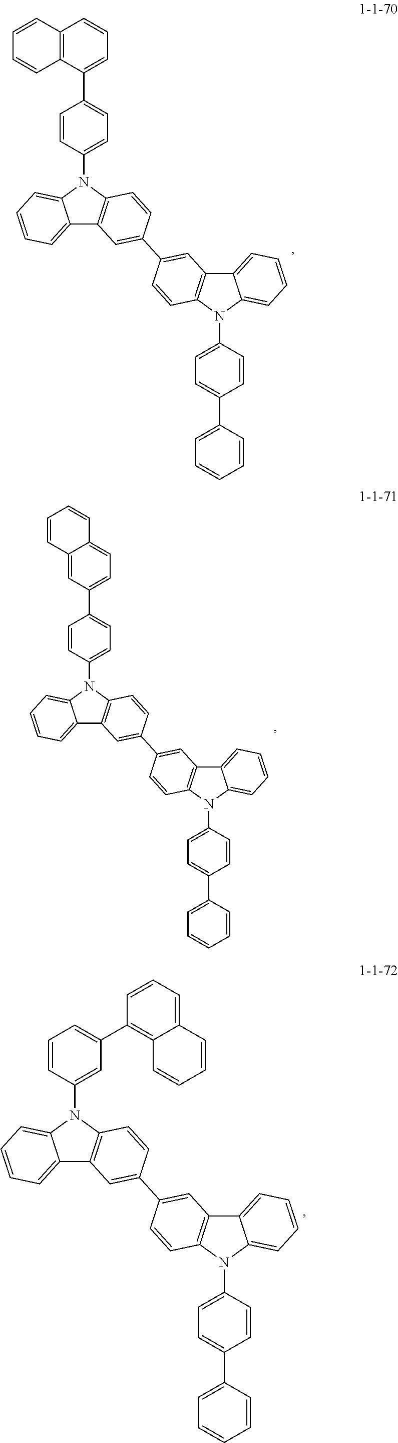 [SMILES: c1ccc(-c2ccc(-n3c4ccccc4c4cc(-c5ccc6c(c5)c5ccccc5n6-c5ccc(-c6cccc7ccccc67)cc5)ccc43)cc2)cc1 ; c1ccc(-c2ccc(-n3c4ccccc4c4cc(-c5ccc6c(c5)c5ccccc5n6-c5ccc(-c6ccc7ccccc7c6)cc5)ccc43)cc2)cc1 ; c1ccc(-c2ccc(-n3c4ccccc4c4cc(-c5ccc6c(c5)c5ccccc5n6-c5cccc(-c6cccc7ccccc67)c5)ccc43)cc2)cc1] 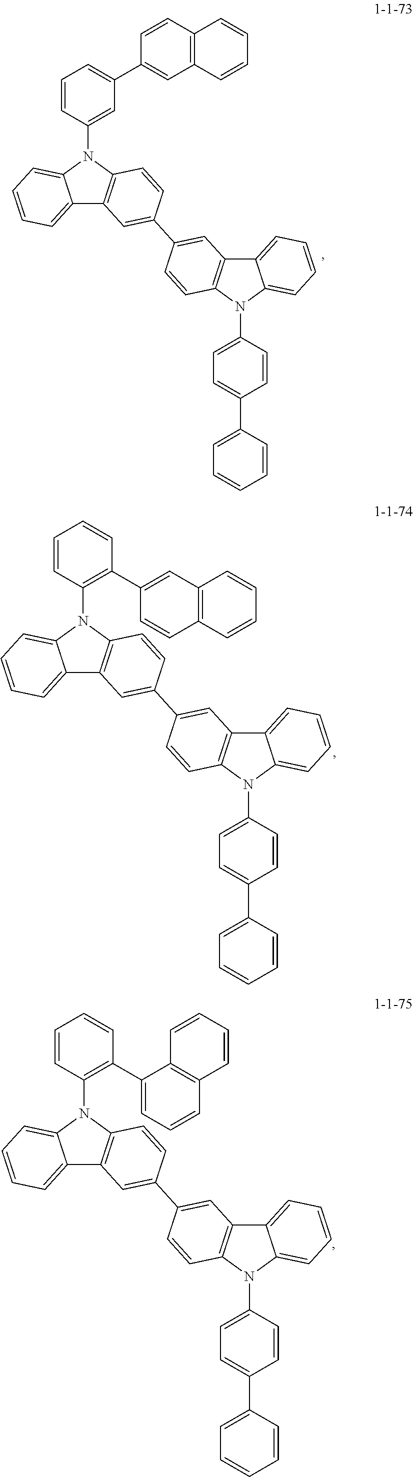 [SMILES: c1ccc(-c2ccc(-n3c4ccccc4c4cc(-c5ccc6c(c5)c5ccccc5n6-c5cccc(-c6ccc7ccccc7c6)c5)ccc43)cc2)cc1 ; c1ccc(-c2ccc(-n3c4ccccc4c4cc(-c5ccc6c(c5)c5ccccc5n6-c5ccccc5-c5ccc6ccccc6c5)ccc43)cc2)cc1 ; c1ccc(-c2ccc(-n3c4ccccc4c4cc(-c5ccc6c(c5)c5ccccc5n6-c5ccccc5-c5cccc6ccccc56)ccc43)cc2)cc1] 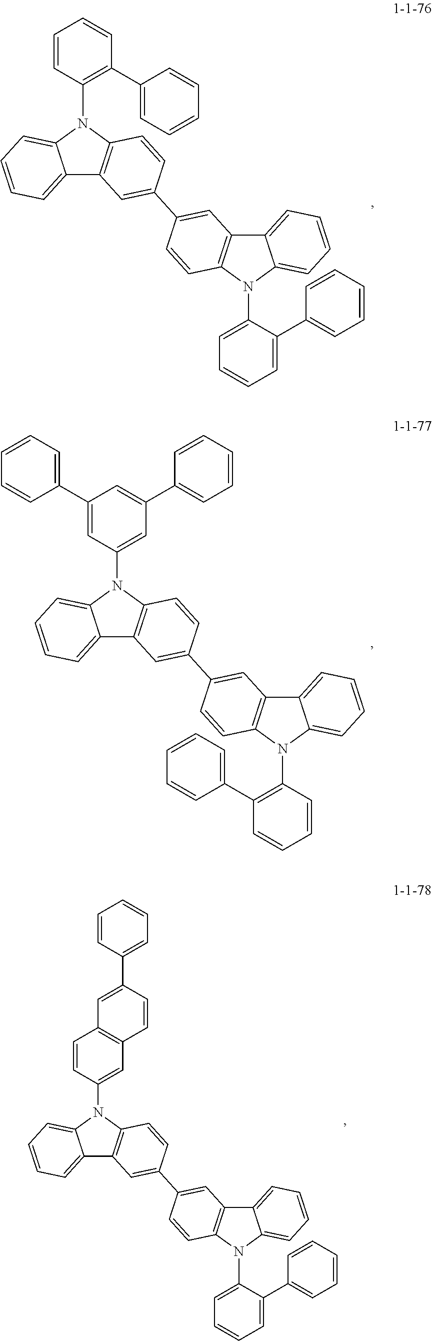 [SMILES: c1ccc(-c2ccccc2-n2c3ccccc3c3cc(-c4ccc5c(c4)c4ccccc4n5-c4ccccc4-c4ccccc4)ccc32)cc1 ; c1ccc(-c2cc(-c3ccccc3)cc(-n3c4ccccc4c4cc(-c5ccc6c(c5)c5ccccc5n6-c5ccccc5-c5ccccc5)ccc43)c2)cc1 ; c1ccc(-c2ccc3cc(-n4c5ccccc5c5cc(-c6ccc7c(c6)c6ccccc6n7-c6ccccc6-c6ccccc6)ccc54)ccc3c2)cc1] 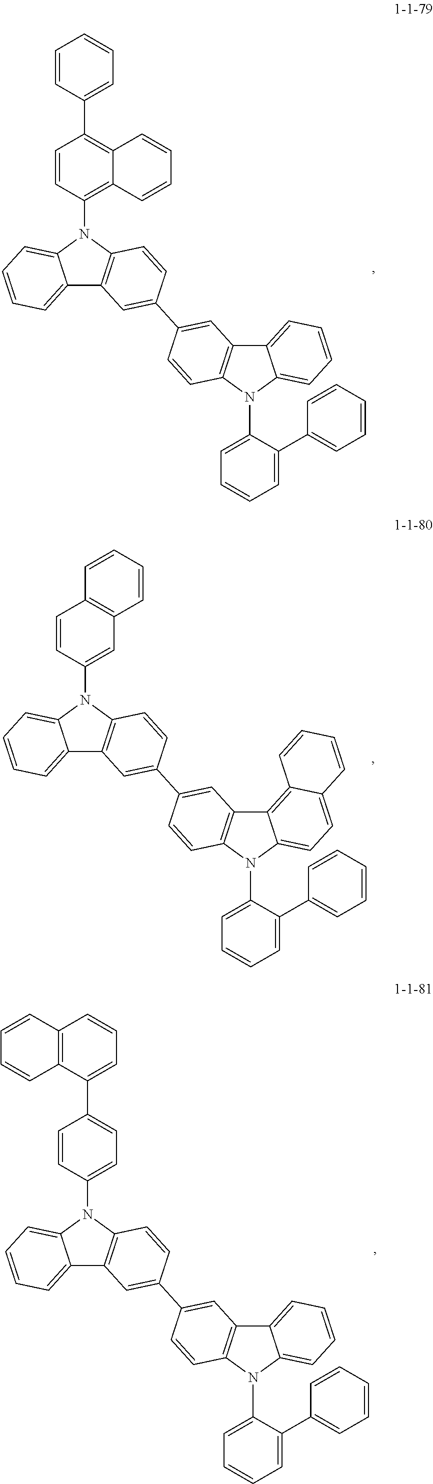 [SMILES: c1ccc(-c2ccccc2-n2c3ccccc3c3cc(-c4ccc5c(c4)c4ccccc4n5-c4ccc(-c5ccccc5)c5ccccc45)ccc32)cc1 ; c1ccc(-c2ccccc2-n2c3ccc(-c4ccc5c(c4)c4ccccc4n5-c4ccc5ccccc5c4)cc3c3c4ccccc4ccc32)cc1 ; c1ccc(-c2ccccc2-n2c3ccccc3c3cc(-c4ccc5c(c4)c4ccccc4n5-c4ccc(-c5cccc6ccccc56)cc4)ccc32)cc1] 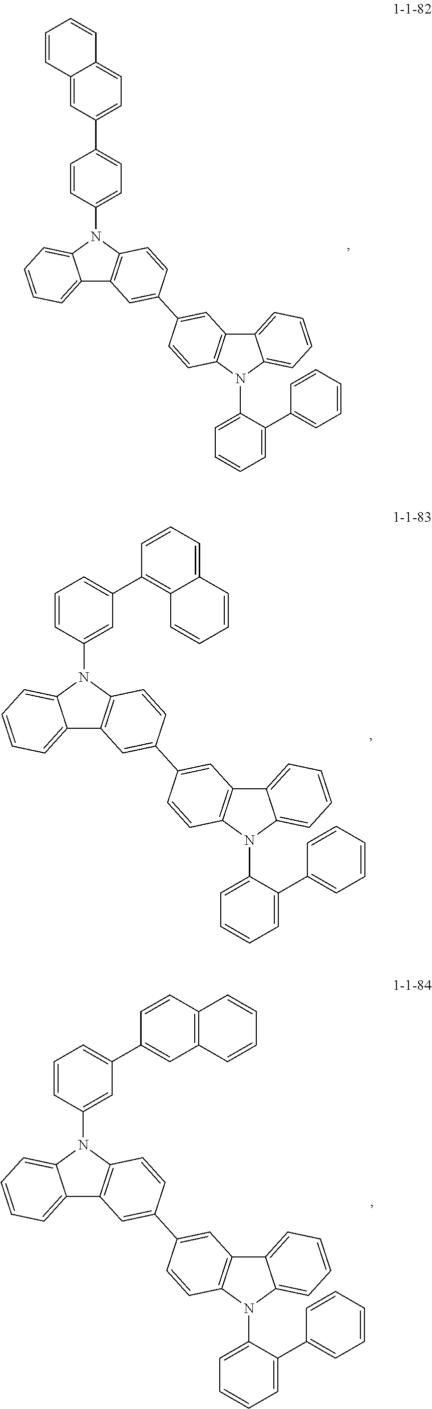 [SMILES: c1ccc(-c2ccccc2-n2c3ccccc3c3cc(-c4ccc5c(c4)c4ccccc4n5-c4ccc(-c5ccc6ccccc6c5)cc4)ccc32)cc1 ; c1ccc(-c2ccccc2-n2c3ccccc3c3cc(-c4ccc5c(c4)c4ccccc4n5-c4cccc(-c5cccc6ccccc56)c4)ccc32)cc1 ; c1ccc(-c2ccccc2-n2c3ccccc3c3cc(-c4ccc5c(c4)c4ccccc4n5-c4cccc(-c5ccc6ccccc6c5)c4)ccc32)cc1] 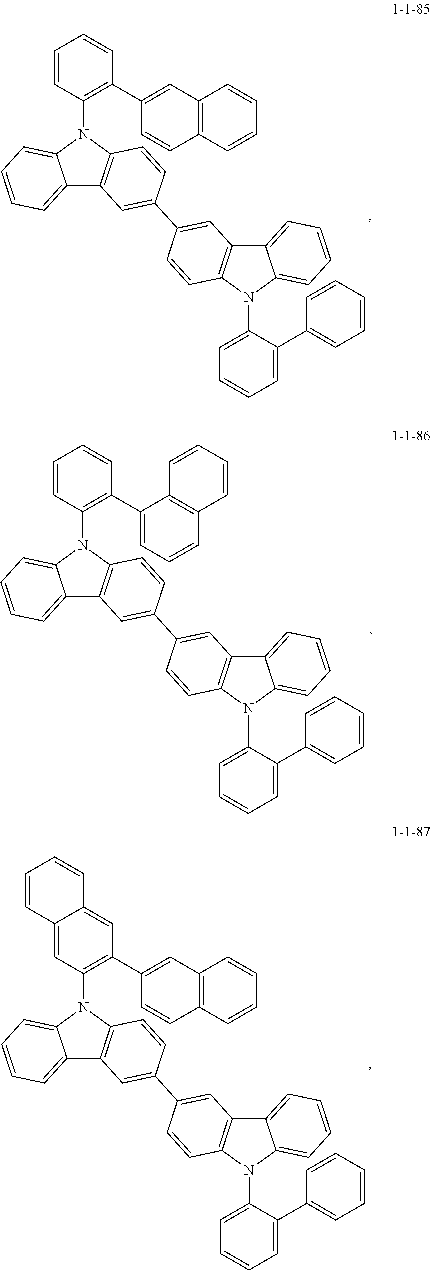 [SMILES: c1ccc(-c2ccccc2-n2c3ccccc3c3cc(-c4ccc5c(c4)c4ccccc4n5-c4ccccc4-c4ccc5ccccc5c4)ccc32)cc1 ; c1ccc(-c2ccccc2-n2c3ccccc3c3cc(-c4ccc5c(c4)c4ccccc4n5-c4ccccc4-c4cccc5ccccc45)ccc32)cc1 ; c1ccc(-c2ccccc2-n2c3ccccc3c3cc(-c4ccc5c(c4)c4ccccc4n5-c4cc5ccccc5cc4-c4ccc5ccccc5c4)ccc32)cc1] 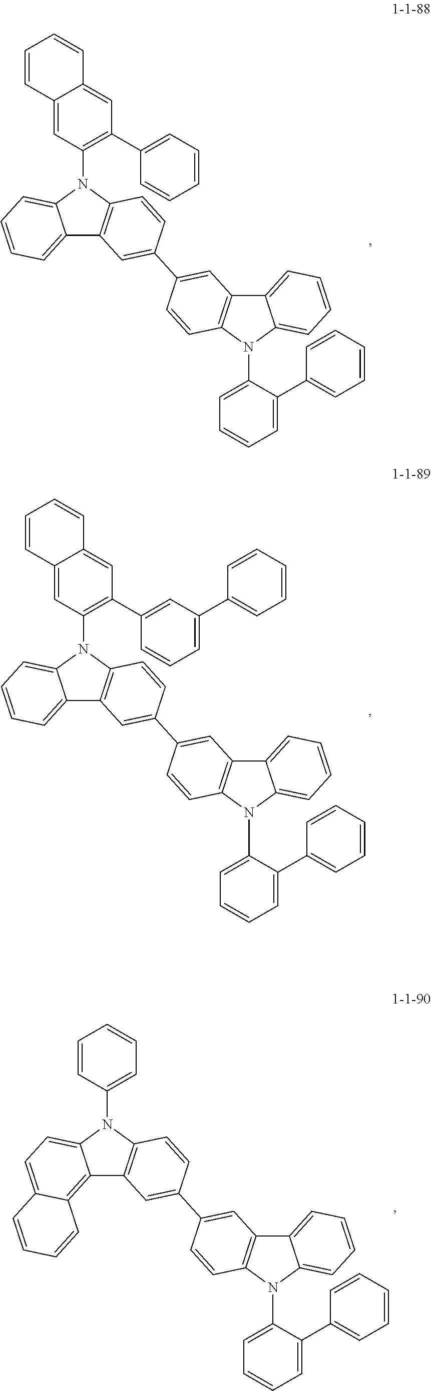 [SMILES: c1ccc(-c2ccccc2-n2c3ccccc3c3cc(-c4ccc5c(c4)c4ccccc4n5-c4cc5ccccc5cc4-c4ccccc4)ccc32)cc1 ; c1ccc(-c2cccc(-c3cc4ccccc4cc3-n3c4ccccc4c4cc(-c5ccc6c(c5)c5ccccc5n6-c5ccccc5-c5ccccc5)ccc43)c2)cc1 ; c1ccc(-c2ccccc2-n2c3ccccc3c3cc(-c4ccc5c(c4)c4c6ccccc6ccc4n5-c4ccccc4)ccc32)cc1] 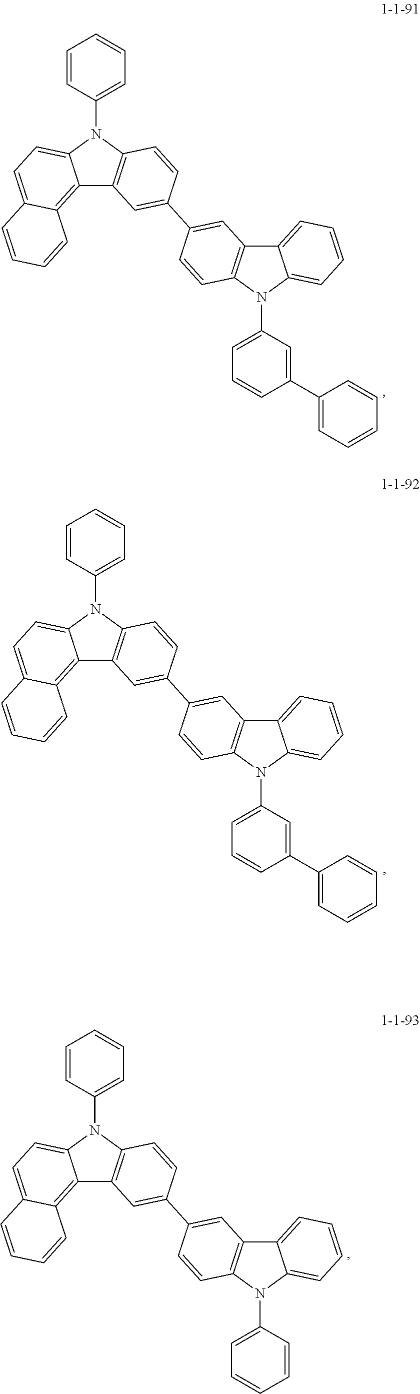 [SMILES: c1ccc(-c2cccc(-n3c4ccccc4c4cc(-c5ccc6c(c5)c5c7ccccc7ccc5n6-c5ccccc5)ccc43)c2)cc1 ; c1ccc(-c2cccc(-n3c4ccccc4c4cc(-c5ccc6c(c5)c5c7ccccc7ccc5n6-c5ccccc5)ccc43)c2)cc1 ; c1ccc(-n2c3ccccc3c3cc(-c4ccc5c(c4)c4c6ccccc6ccc4n5-c4ccccc4)ccc32)cc1] 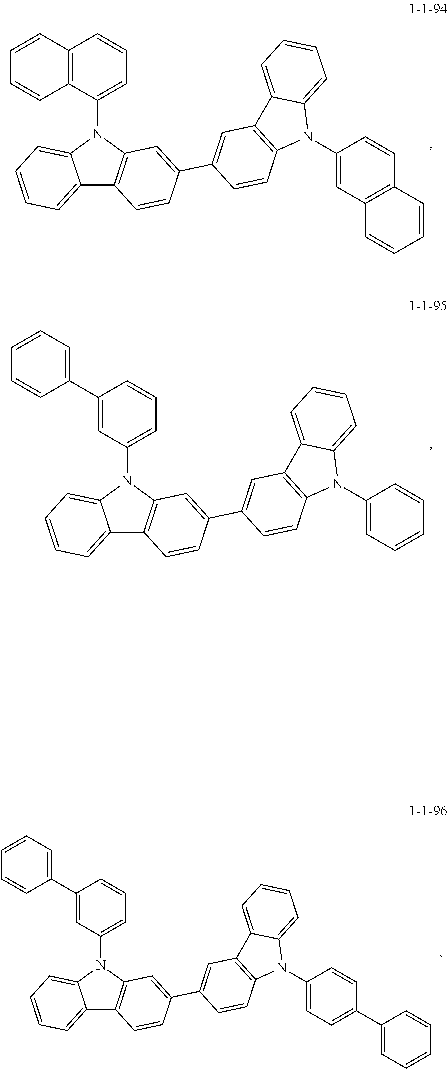 [SMILES: c1ccc2cc(-n3c4ccccc4c4cc(-c5ccc6c7ccccc7n(-c7cccc8ccccc78)c6c5)ccc43)ccc2c1 ; c1ccc(-c2cccc(-n3c4ccccc4c4ccc(-c5ccc6c(c5)c5ccccc5n6-c5ccccc5)cc43)c2)cc1 ; c1ccc(-c2ccc(-n3c4ccccc4c4cc(-c5ccc6c7ccccc7n(-c7cccc(-c8ccccc8)c7)c6c5)ccc43)cc2)cc1] 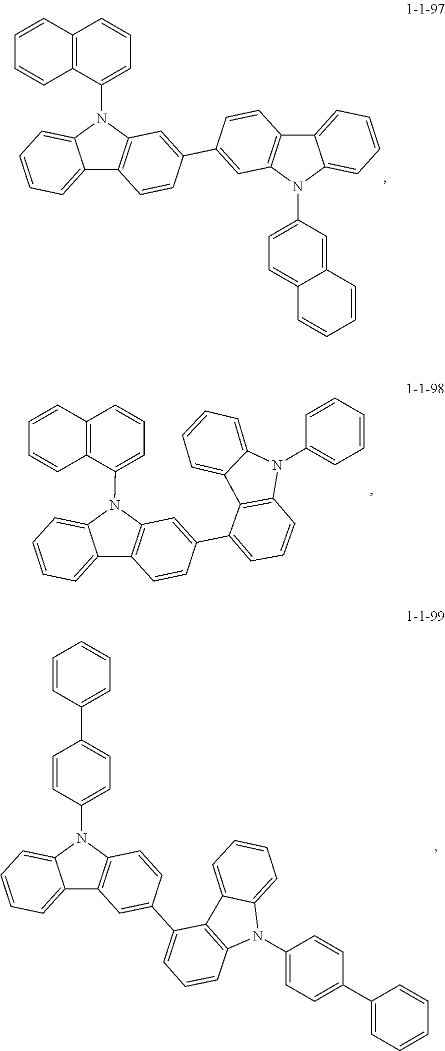 [SMILES: c1ccc2cc(-n3c4ccccc4c4ccc(-c5ccc6c7ccccc7n(-c7cccc8ccccc78)c6c5)cc43)ccc2c1 ; c1ccc(-n2c3ccccc3c3c(-c4ccc5c6ccccc6n(-c6cccc7ccccc67)c5c4)cccc32)cc1 ; c1ccc(-c2ccc(-n3c4ccccc4c4cc(-c5cccc6c5c5ccccc5n6-c5ccc(-c6ccccc6)cc5)ccc43)cc2)cc1] 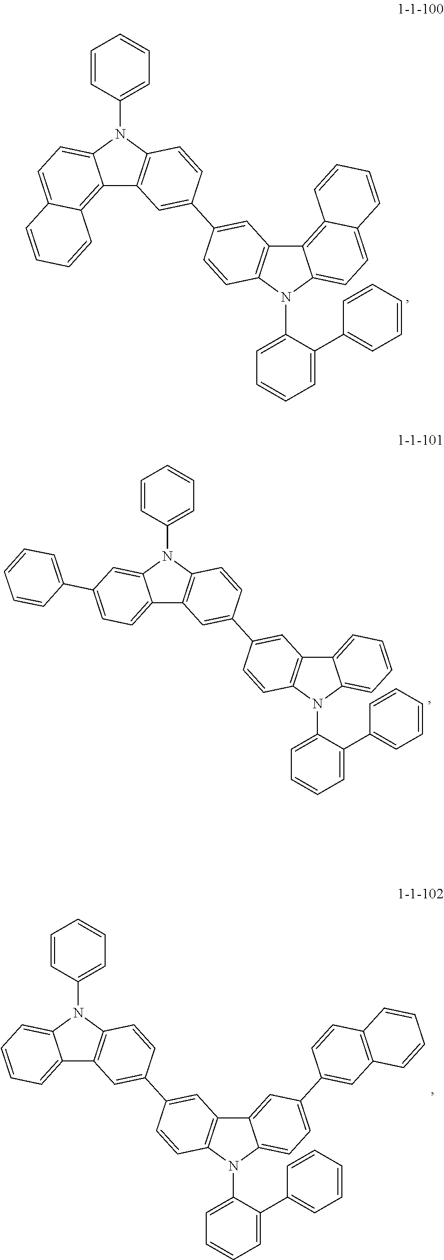 [SMILES: c1ccc(-c2ccccc2-n2c3ccc(-c4ccc5c(c4)c4c6ccccc6ccc4n5-c4ccccc4)cc3c3c4ccccc4ccc32)cc1 ; c1ccc(-c2ccc3c4cc(-c5ccc6c(c5)c5ccccc5n6-c5ccccc5-c5ccccc5)ccc4n(-c4ccccc4)c3c2)cc1 ; c1ccc(-c2ccccc2-n2c3ccc(-c4ccc5ccccc5c4)cc3c3cc(-c4ccc5c(c4)c4ccccc4n5-c4ccccc4)ccc32)cc1] 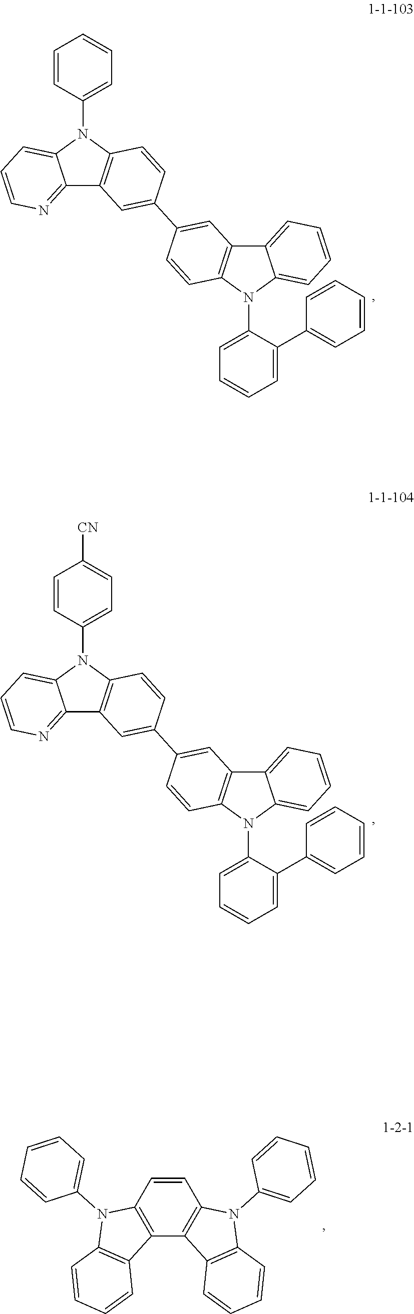 [SMILES: c1ccc(-c2ccccc2-n2c3ccccc3c3cc(-c4ccc5c(c4)c4ncccc4n5-c4ccccc4)ccc32)cc1 ; N#Cc1ccc(-n2c3ccc(-c4ccc5c(c4)c4ccccc4n5-c4ccccc4-c4ccccc4)cc3c3ncccc32)cc1 ; c1ccc(-n2c3ccccc3c3c4c5ccccc5n(-c5ccccc5)c4ccc32)cc1] 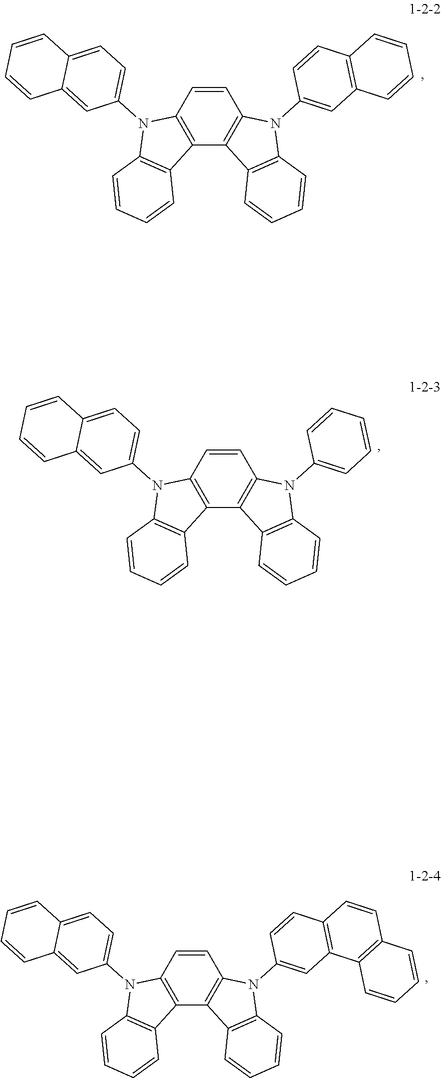 [SMILES: c1ccc2cc(-n3c4ccccc4c4c5c6ccccc6n(-c6ccc7ccccc7c6)c5ccc43)ccc2c1 ; c1ccc(-n2c3ccccc3c3c4c5ccccc5n(-c5ccc6ccccc6c5)c4ccc32)cc1 ; c1ccc2cc(-n3c4ccccc4c4c5c6ccccc6n(-c6ccc7ccc8ccccc8c7c6)c5ccc43)ccc2c1] 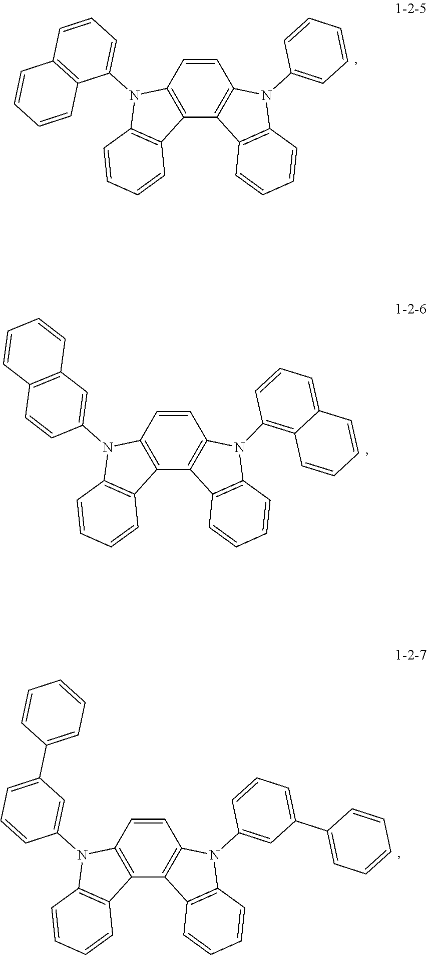 [SMILES: c1ccc(-n2c3ccccc3c3c4c5ccccc5n(-c5cccc6ccccc56)c4ccc32)cc1 ; c1ccc2cc(-n3c4ccccc4c4c5c6ccccc6n(-c6cccc7ccccc67)c5ccc43)ccc2c1 ; c1ccc(-c2cccc(-n3c4ccccc4c4c5c6ccccc6n(-c6cccc(-c7ccccc7)c6)c5ccc43)c2)cc1] 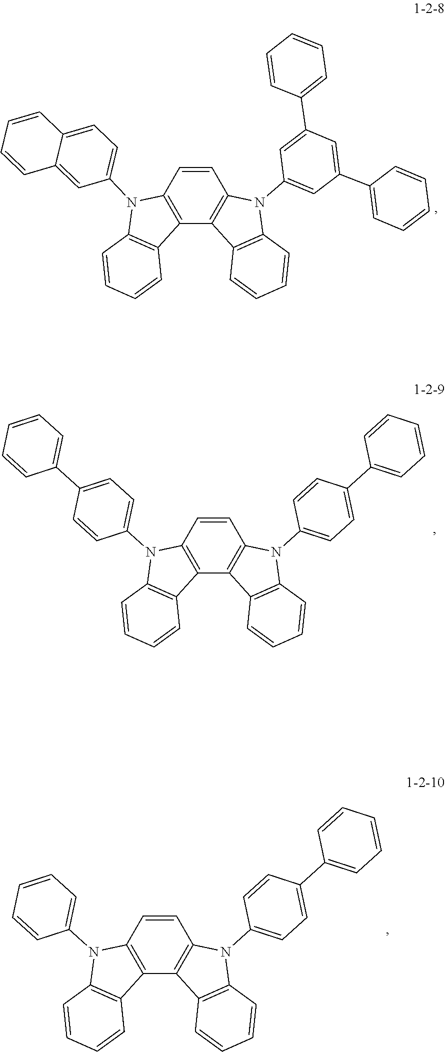 [SMILES: c1ccc(-c2cc(-c3ccccc3)cc(-n3c4ccccc4c4c5c6ccccc6n(-c6ccc7ccccc7c6)c5ccc43)c2)cc1 ; c1ccc(-c2ccc(-n3c4ccccc4c4c5c6ccccc6n(-c6ccc(-c7ccccc7)cc6)c5ccc43)cc2)cc1 ; c1ccc(-c2ccc(-n3c4ccccc4c4c5c6ccccc6n(-c6ccccc6)c5ccc43)cc2)cc1] 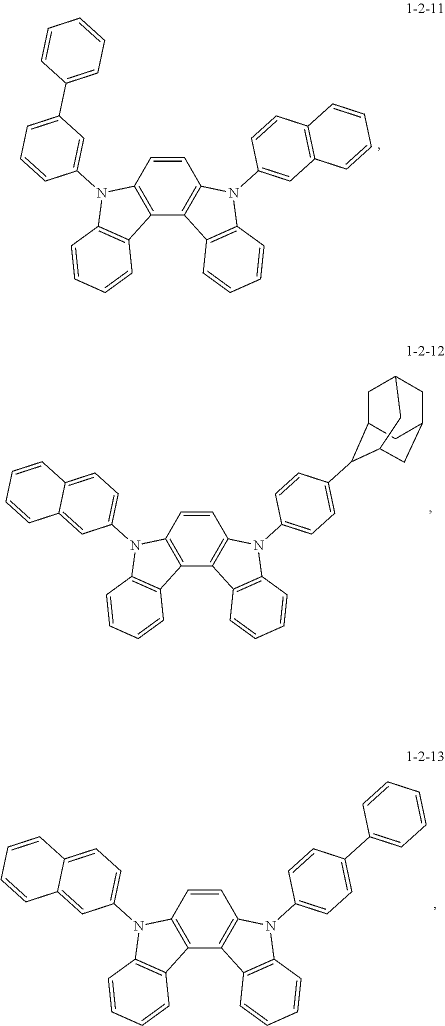 [SMILES: c1ccc(-c2cccc(-n3c4ccccc4c4c5c6ccccc6n(-c6ccc7ccccc7c6)c5ccc43)c2)cc1 ; c1ccc2cc(-n3c4ccccc4c4c5c6ccccc6n(-c6ccc(C7C8CC9CC(C8)CC7C9)cc6)c5ccc43)ccc2c1 ; c1ccc(-c2ccc(-n3c4ccccc4c4c5c6ccccc6n(-c6ccc7ccccc7c6)c5ccc43)cc2)cc1] 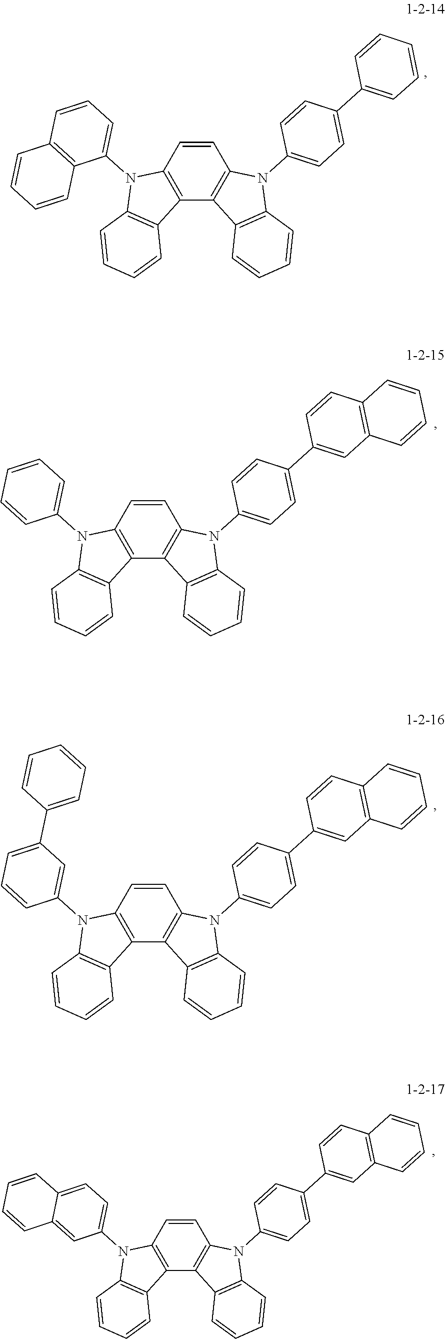 [SMILES: c1ccc(-c2ccc(-n3c4ccccc4c4c5c6ccccc6n(-c6cccc7ccccc67)c5ccc43)cc2)cc1 ; c1ccc(-n2c3ccccc3c3c4c5ccccc5n(-c5ccc(-c6ccc7ccccc7c6)cc5)c4ccc32)cc1 ; c1ccc(-c2cccc(-n3c4ccccc4c4c5c6ccccc6n(-c6ccc(-c7ccc8ccccc8c7)cc6)c5ccc43)c2)cc1 ; c1ccc2cc(-c3ccc(-n4c5ccccc5c5c6c7ccccc7n(-c7ccc8ccccc8c7)c6ccc54)cc3)ccc2c1] 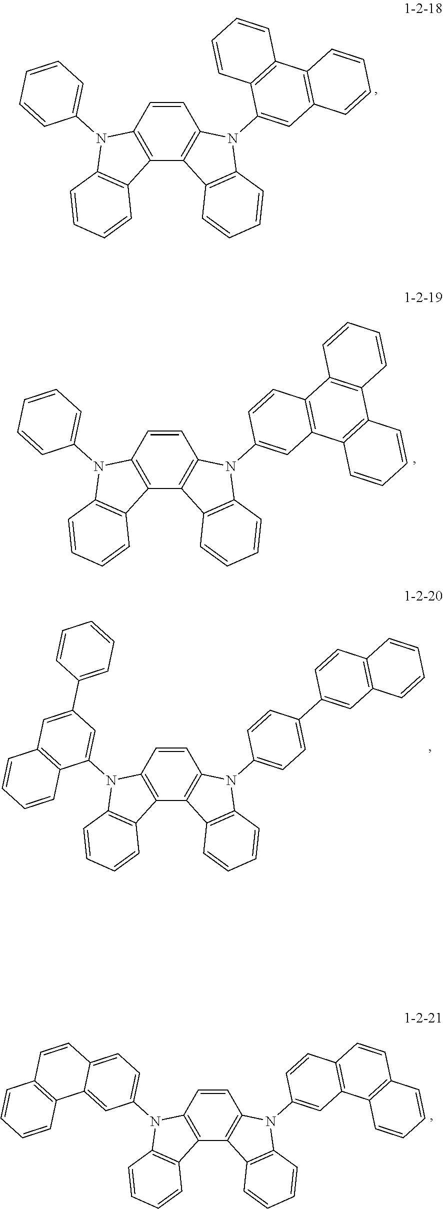 [SMILES: c1ccc(-n2c3ccccc3c3c4c5ccccc5n(-c5cc6ccccc6c6ccccc56)c4ccc32)cc1 ; c1ccc(-n2c3ccccc3c3c4c5ccccc5n(-c5ccc6c7ccccc7c7ccccc7c6c5)c4ccc32)cc1 ; c1ccc(-c2cc(-n3c4ccccc4c4c5c6ccccc6n(-c6ccc(-c7ccc8ccccc8c7)cc6)c5ccc43)c3ccccc3c2)cc1 ; c1ccc2c(c1)ccc1ccc(-n3c4ccccc4c4c5c6ccccc6n(-c6ccc7ccc8ccccc8c7c6)c5ccc43)cc12] 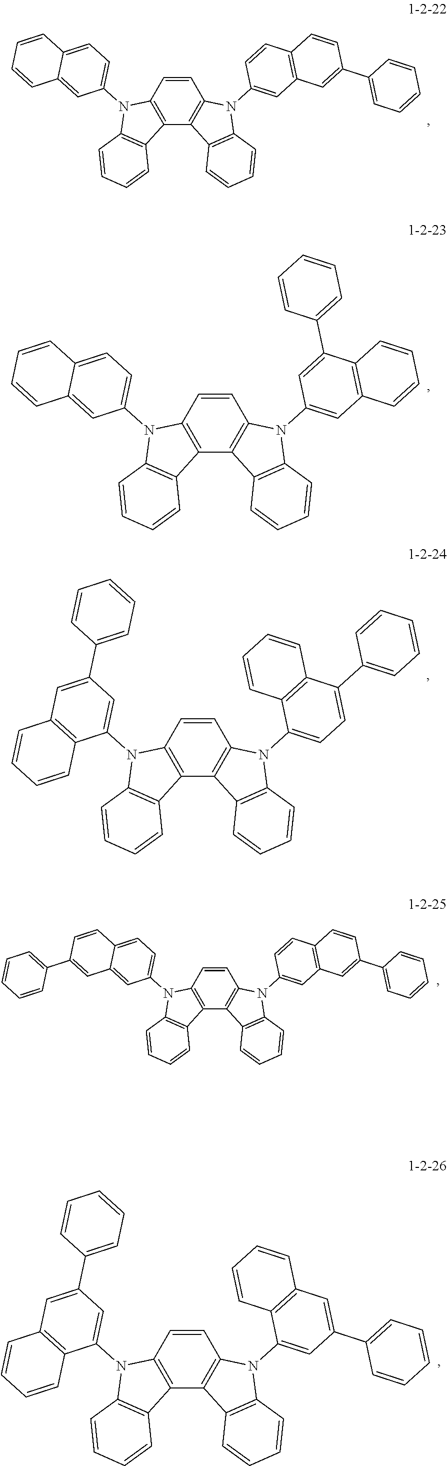 [SMILES: c1ccc(-c2ccc3ccc(-n4c5ccccc5c5c6c7ccccc7n(-c7ccc8ccccc8c7)c6ccc54)cc3c2)cc1 ; c1ccc(-c2cc(-n3c4ccccc4c4c5c6ccccc6n(-c6ccc7ccccc7c6)c5ccc43)cc3ccccc23)cc1 ; c1ccc(-c2cc(-n3c4ccccc4c4c5c6ccccc6n(-c6ccc(-c7ccccc7)c7ccccc67)c5ccc43)c3ccccc3c2)cc1 ; c1ccc(-c2ccc3ccc(-n4c5ccccc5c5c6c7ccccc7n(-c7ccc8ccc(-c9ccccc9)cc8c7)c6ccc54)cc3c2)cc1 ; c1ccc(-c2cc(-n3c4ccccc4c4c5c6ccccc6n(-c6cc(-c7ccccc7)cc7ccccc67)c5ccc43)c3ccccc3c2)cc1] 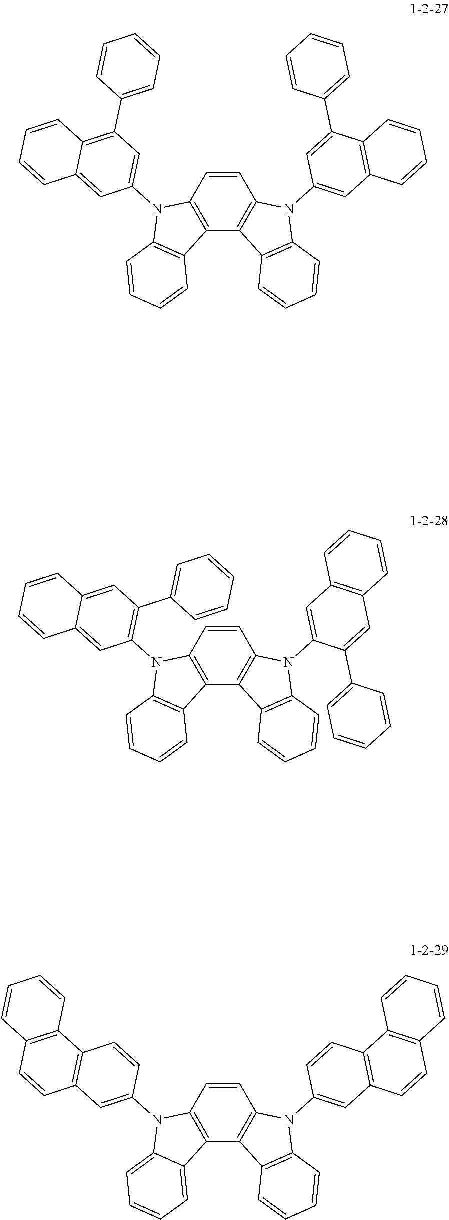 [SMILES: c1ccc(-c2cc(-n3c4ccccc4c4c5c6ccccc6n(-c6cc(-c7ccccc7)c7ccccc7c6)c5ccc43)cc3ccccc23)cc1 ; c1ccc(-c2cc3ccccc3cc2-n2c3ccccc3c3c4c5ccccc5n(-c5cc6ccccc6cc5-c5ccccc5)c4ccc32)cc1 ; c1ccc2c(c1)ccc1cc(-n3c4ccccc4c4c5c6ccccc6n(-c6ccc7c(ccc8ccccc87)c6)c5ccc43)ccc12] 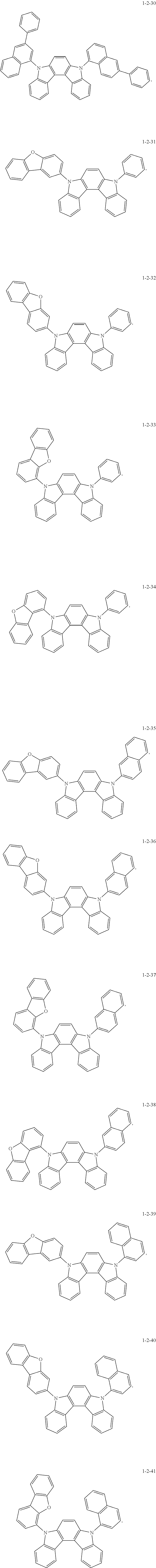 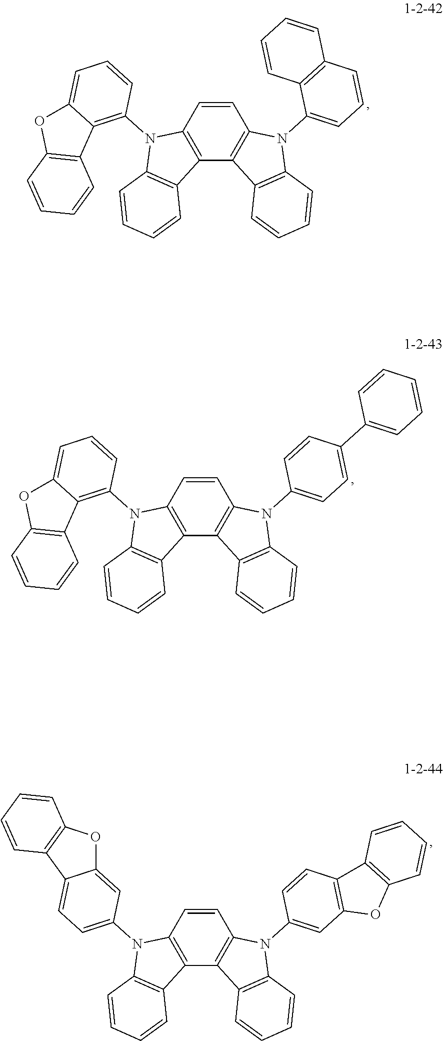 [SMILES: c1ccc2c(-n3c4ccccc4c4c5c6ccccc6n(-c6cccc7oc8ccccc8c67)c5ccc43)cccc2c1 ; c1ccc(-c2ccc(-n3c4ccccc4c4c5c6ccccc6n(-c6cccc7oc8ccccc8c67)c5ccc43)cc2)cc1 ; c1ccc2c(c1)oc1cc(-n3c4ccccc4c4c5c6ccccc6n(-c6ccc7c(c6)oc6ccccc67)c5ccc43)ccc12] 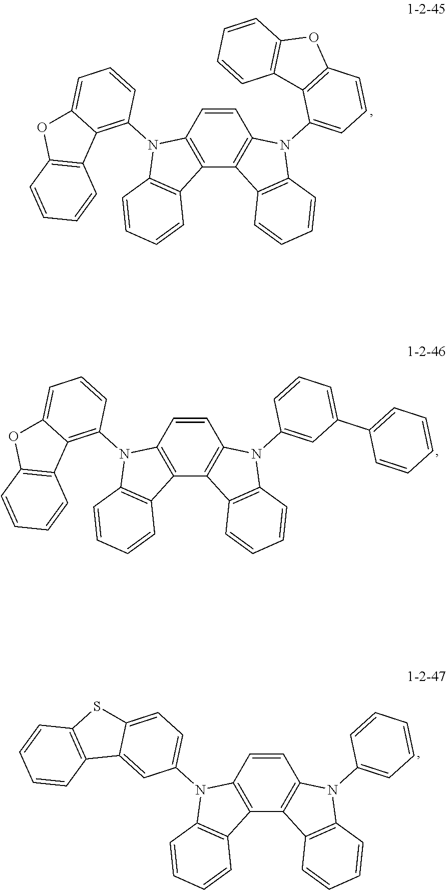 [SMILES: c1ccc2c(c1)oc1cccc(-n3c4ccccc4c4c5c6ccccc6n(-c6cccc7oc8ccccc8c67)c5ccc43)c12 ; c1ccc(-c2cccc(-n3c4ccccc4c4c5c6ccccc6n(-c6cccc7oc8ccccc8c67)c5ccc43)c2)cc1 ; c1ccc(-n2c3ccccc3c3c4c5ccccc5n(-c5ccc6sc7ccccc7c6c5)c4ccc32)cc1] 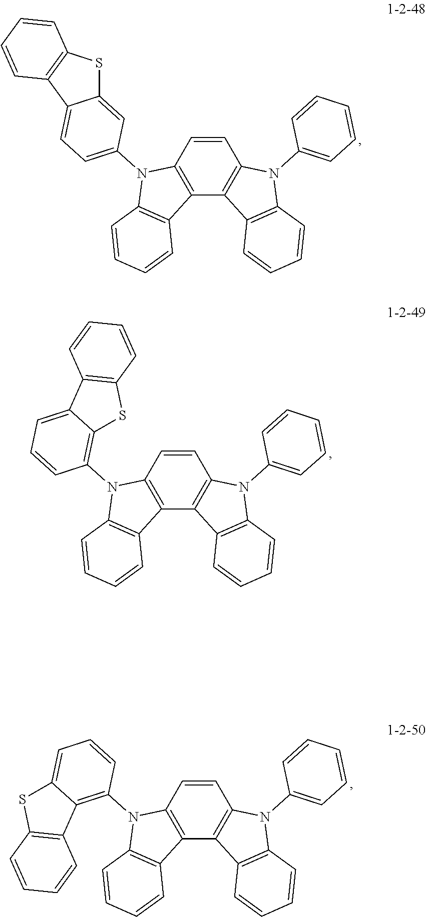 [SMILES: c1ccc(-n2c3ccccc3c3c4c5ccccc5n(-c5ccc6c(c5)sc5ccccc56)c4ccc32)cc1 ; c1ccc(-n2c3ccccc3c3c4c5ccccc5n(-c5cccc6c5sc5ccccc56)c4ccc32)cc1 ; c1ccc(-n2c3ccccc3c3c4c5ccccc5n(-c5cccc6sc7ccccc7c56)c4ccc32)cc1] 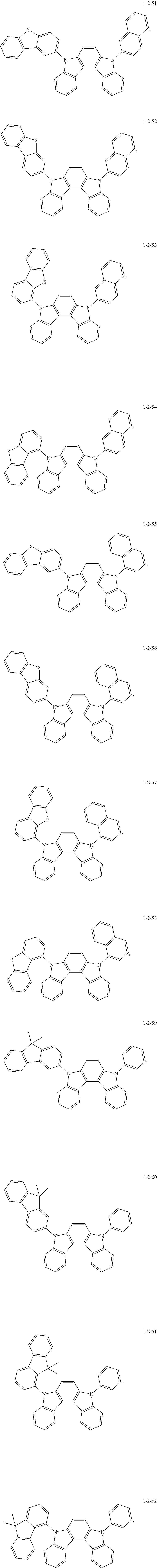 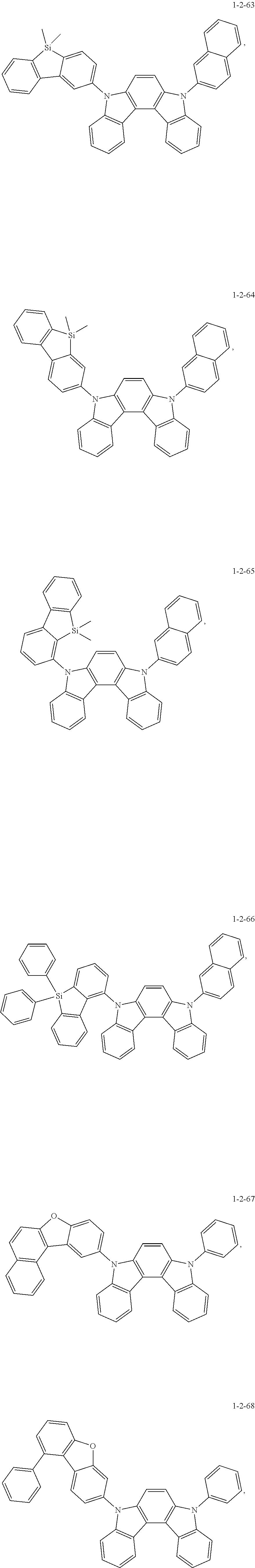 [SMILES: C[Si]1(C)c2ccccc2-c2cc(-n3c4ccccc4c4c5c6ccccc6n(-c6ccc7ccccc7c6)c5ccc43)ccc21 ; C[Si]1(C)c2ccccc2-c2ccc(-n3c4ccccc4c4c5c6ccccc6n(-c6ccc7ccccc7c6)c5ccc43)cc21 ; C[Si]1(C)c2ccccc2-c2cccc(-n3c4ccccc4c4c5c6ccccc6n(-c6ccc7ccccc7c6)c5ccc43)c21 ; c1ccc([Si]2(c3ccccc3)c3ccccc3-c3c(-n4c5ccccc5c5c6c7ccccc7n(-c7ccc8ccccc8c7)c6ccc54)cccc32)cc1 ; c1ccc(-n2c3ccccc3c3c4c5ccccc5n(-c5ccc6oc7ccc8ccccc8c7c6c5)c4ccc32)cc1 ; c1ccc(-c2cccc3oc4cc(-n5c6ccccc6c6c7c8ccccc8n(-c8ccccc8)c7ccc65)ccc4c23)cc1] 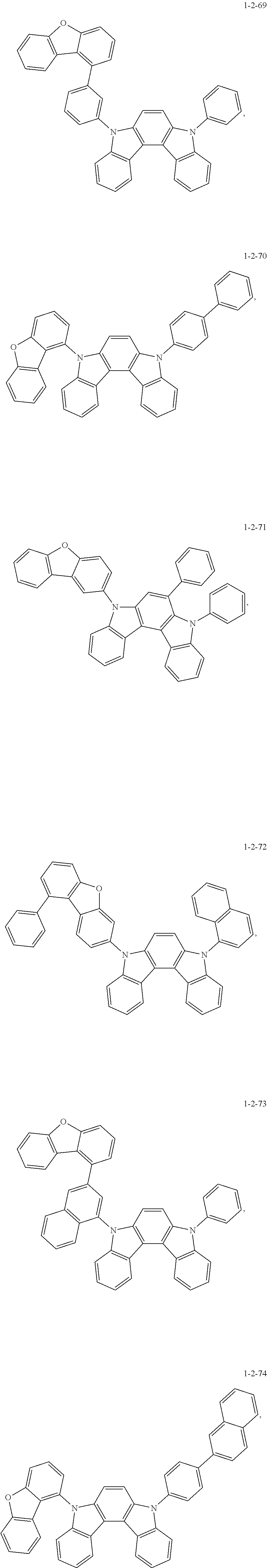 [SMILES: c1ccc(-n2c3ccccc3c3c4c5ccccc5n(-c5cccc(-c6cccc7oc8ccccc8c67)c5)c4ccc32)cc1 ; c1ccc(-c2ccc(-n3c4ccccc4c4c5c6ccccc6n(-c6cccc7oc8ccccc8c67)c5ccc43)cc2)cc1 ; c1ccc(-c2cc3c(c4ccccc4n3-c3ccc4oc5ccccc5c4c3)c3c4ccccc4n(-c4ccccc4)c23)cc1 ; c1ccc(-c2cccc3oc4cc(-n5c6ccccc6c6c7c8ccccc8n(-c8cccc9ccccc89)c7ccc65)ccc4c23)cc1 ; c1ccc(-n2c3ccccc3c3c4c5ccccc5n(-c5cc(-c6cccc7oc8ccccc8c67)cc6ccccc56)c4ccc32)cc1 ; c1ccc2cc(-c3ccc(-n4c5ccccc5c5c6c7ccccc7n(-c7cccc8oc9ccccc9c78)c6ccc54)cc3)ccc2c1] 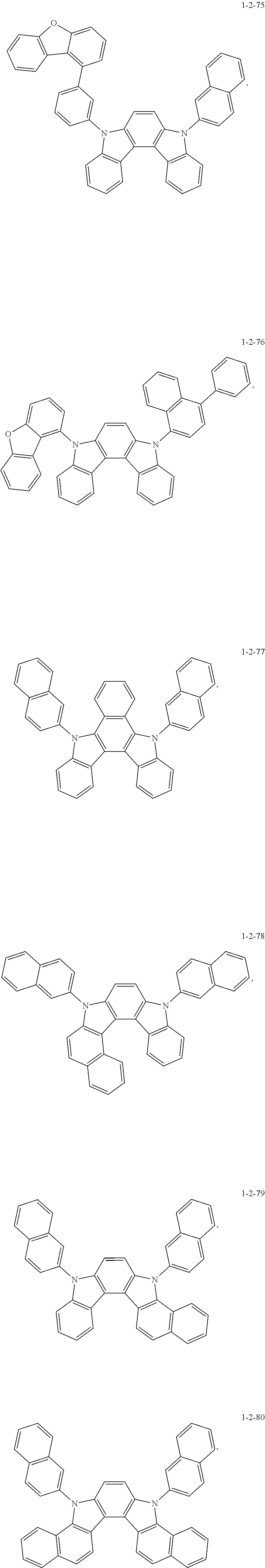 [SMILES: c1cc(-c2cccc3oc4ccccc4c23)cc(-n2c3ccccc3c3c4c5ccccc5n(-c5ccc6ccccc6c5)c4ccc32)c1 ; c1ccc(-c2ccc(-n3c4ccccc4c4c5c6ccccc6n(-c6cccc7oc8ccccc8c67)c5ccc43)c3ccccc23)cc1 ; c1ccc2cc(-n3c4ccccc4c4c5c6ccccc6n(-c6ccc7ccccc7c6)c5c5ccccc5c43)ccc2c1 ; c1ccc2cc(-n3c4ccccc4c4c5c6c7ccccc7ccc6n(-c6ccc7ccccc7c6)c5ccc43)ccc2c1 ; c1ccc2cc(-n3c4ccccc4c4c5c6ccc7ccccc7c6n(-c6ccc7ccccc7c6)c5ccc43)ccc2c1 ; c1ccc2cc(-n3c4ccc5c(c6ccc7ccccc7c6n5-c5ccc6ccccc6c5)c4c4ccc5ccccc5c43)ccc2c1] 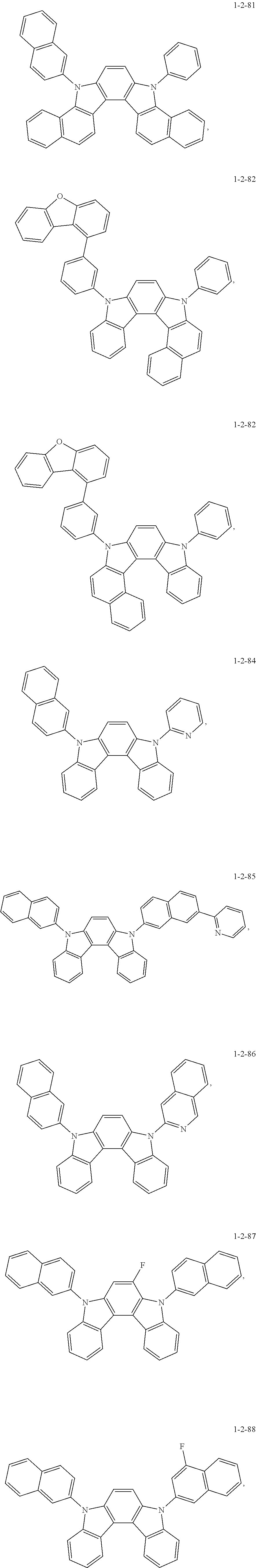 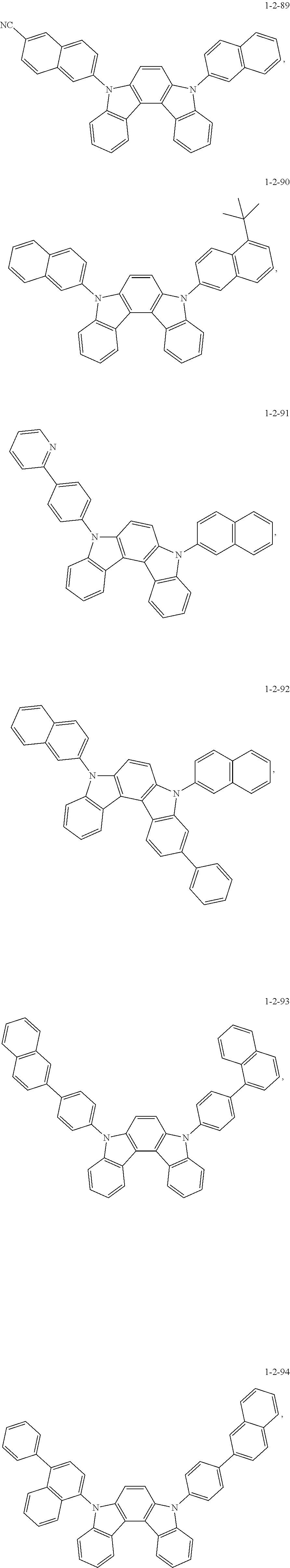 [SMILES: N#Cc1ccc2cc(-n3c4ccccc4c4c5c6ccccc6n(-c6ccc7ccccc7c6)c5ccc43)ccc2c1 ; CC(C)(C)c1cccc2cc(-n3c4ccccc4c4c5c6ccccc6n(-c6ccc7ccccc7c6)c5ccc43)ccc12 ; c1ccc(-c2ccc(-n3c4ccccc4c4c5c6ccccc6n(-c6ccc7ccccc7c6)c5ccc43)cc2)nc1 ; c1ccc(-c2ccc3c4c5c6ccccc6n(-c6ccc7ccccc7c6)c5ccc4n(-c4ccc5ccccc5c4)c3c2)cc1 ; c1ccc2cc(-c3ccc(-n4c5ccccc5c5c6c7ccccc7n(-c7ccc(-c8cccc9ccccc89)cc7)c6ccc54)cc3)ccc2c1 ; c1ccc(-c2ccc(-n3c4ccccc4c4c5c6ccccc6n(-c6ccc(-c7ccc8ccccc8c7)cc6)c5ccc43)c3ccccc23)cc1] 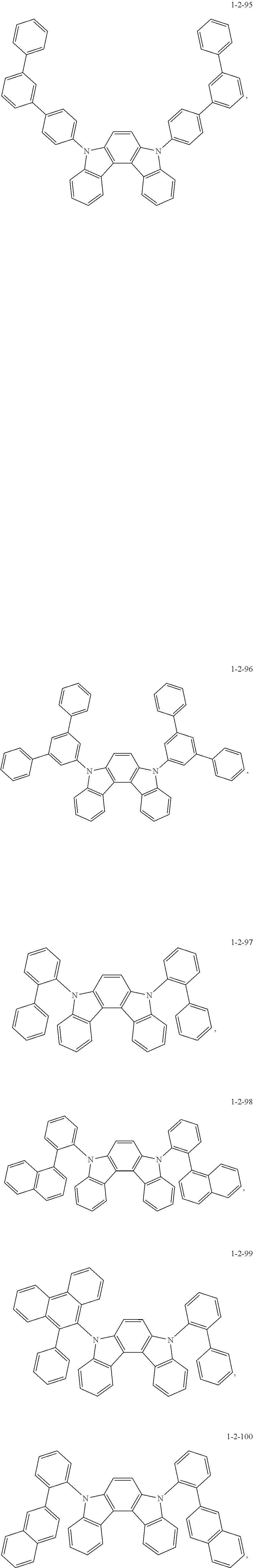 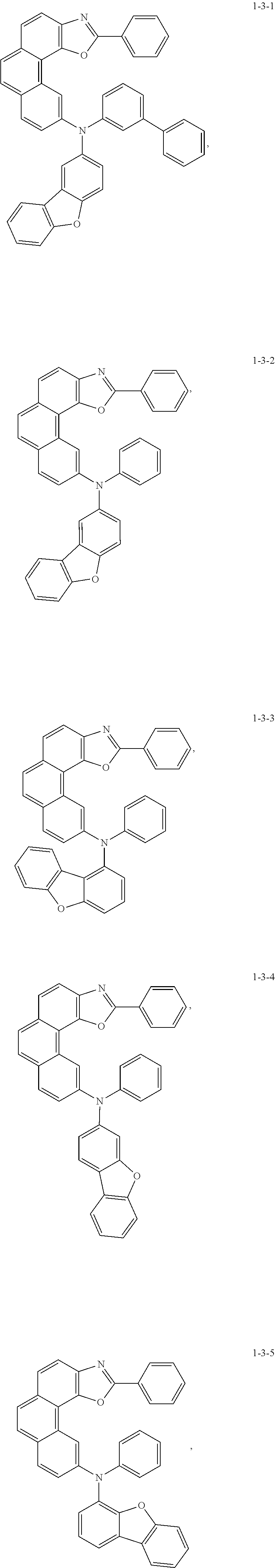 [SMILES: c1ccc(-c2cccc(N(c3ccc4oc5ccccc5c4c3)c3ccc4ccc5ccc6nc(-c7ccccc7)oc6c5c4c3)c2)cc1 ; c1ccc(-c2nc3ccc4ccc5ccc(N(c6ccccc6)c6ccc7oc8ccccc8c7c6)cc5c4c3o2)cc1 ; c1ccc(-c2nc3ccc4ccc5ccc(N(c6ccccc6)c6cccc7oc8ccccc8c67)cc5c4c3o2)cc1 ; c1ccc(-c2nc3ccc4ccc5ccc(N(c6ccccc6)c6ccc7c(c6)oc6ccccc67)cc5c4c3o2)cc1 ; c1ccc(-c2nc3ccc4ccc5ccc(N(c6ccccc6)c6cccc7c6oc6ccccc67)cc5c4c3o2)cc1] 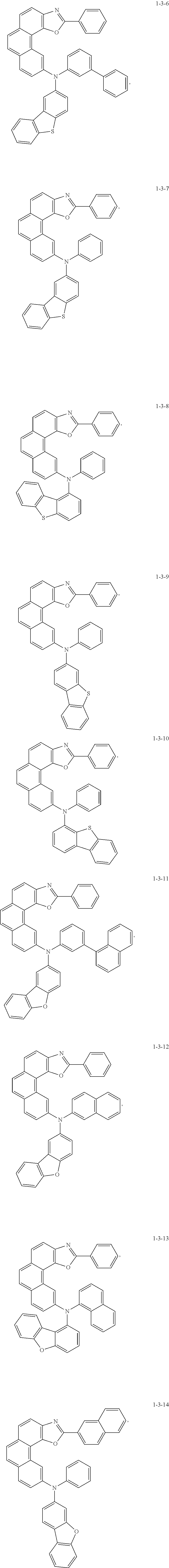 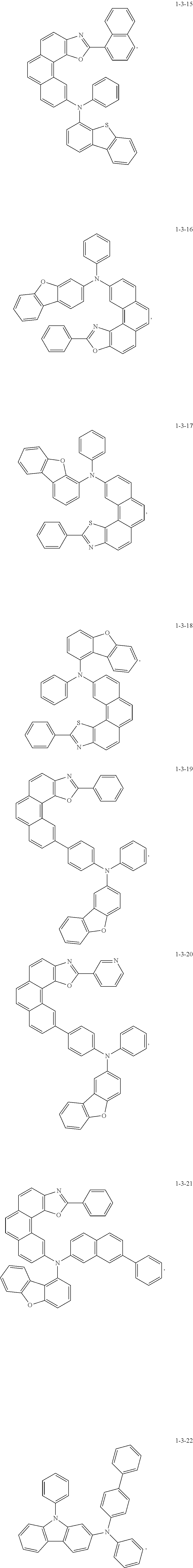 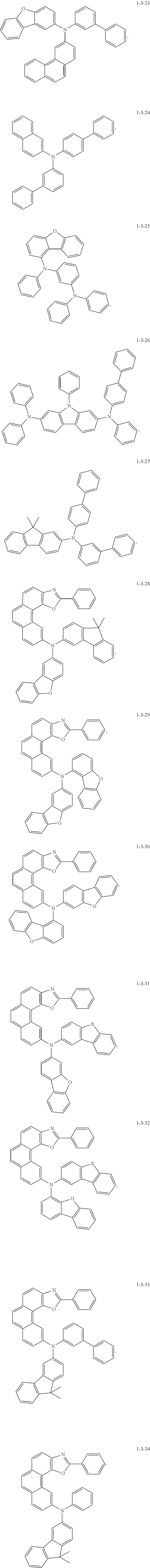 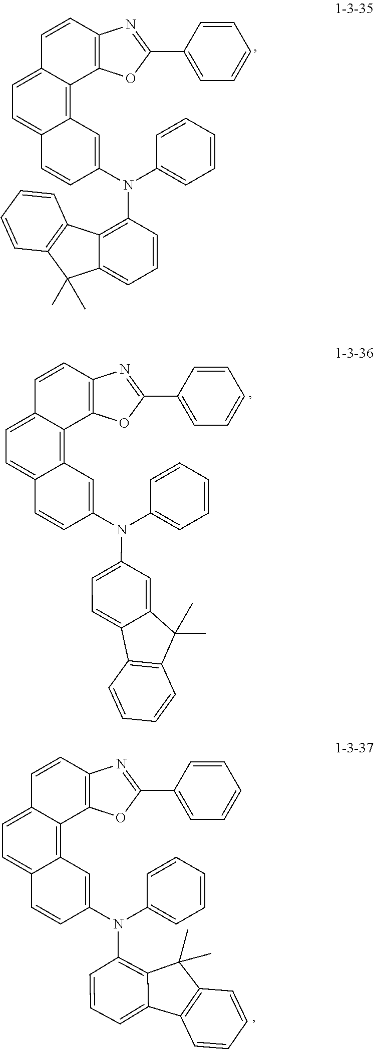 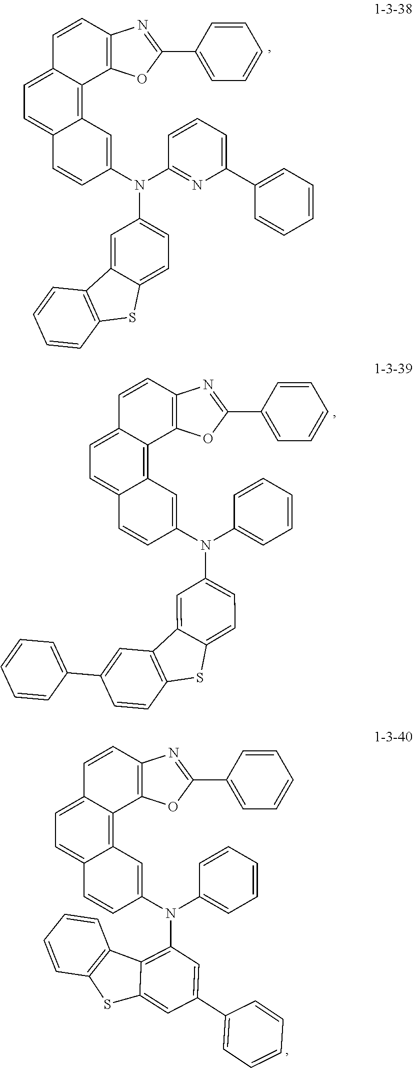 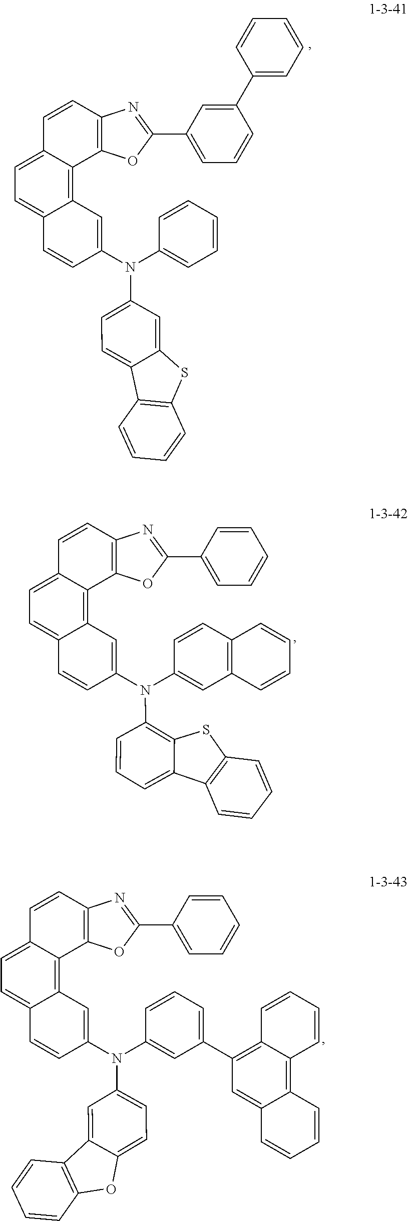 [SMILES: c1ccc(-c2cccc(-c3nc4ccc5ccc6ccc(N(c7ccccc7)c7ccc8c(c7)sc7ccccc78)cc6c5c4o3)c2)cc1 ; c1ccc(-c2nc3ccc4ccc5ccc(N(c6ccc7ccccc7c6)c6cccc7c6sc6ccccc67)cc5c4c3o2)cc1 ; c1ccc(-c2nc3ccc4ccc5ccc(N(c6cccc(-c7cc8ccccc8c8ccccc78)c6)c6ccc7oc8ccccc8c7c6)cc5c4c3o2)cc1] 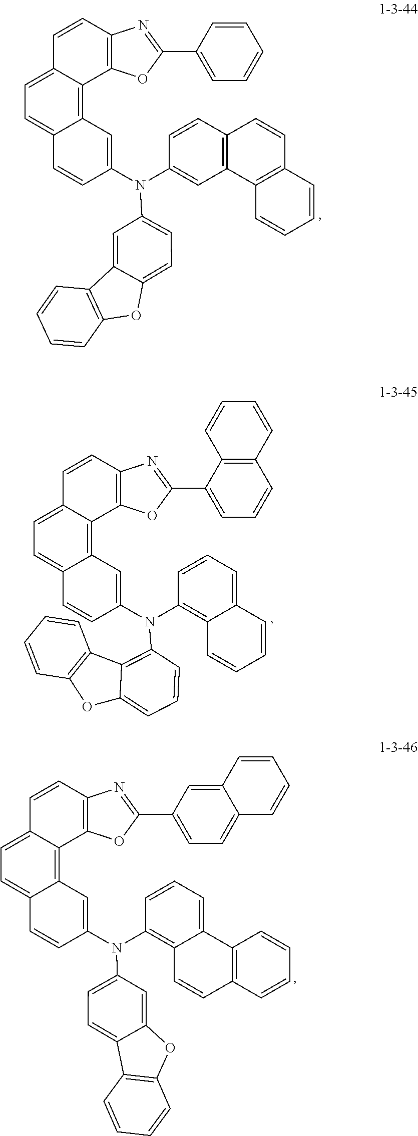 [SMILES: c1ccc(-c2nc3ccc4ccc5ccc(N(c6ccc7ccc8ccccc8c7c6)c6ccc7oc8ccccc8c7c6)cc5c4c3o2)cc1 ; c1ccc2c(-c3nc4ccc5ccc6ccc(N(c7cccc8ccccc78)c7cccc8oc9ccccc9c78)cc6c5c4o3)cccc2c1 ; c1ccc2cc(-c3nc4ccc5ccc6ccc(N(c7ccc8c(c7)oc7ccccc78)c7cccc8c7ccc7ccccc78)cc6c5c4o3)ccc2c1] 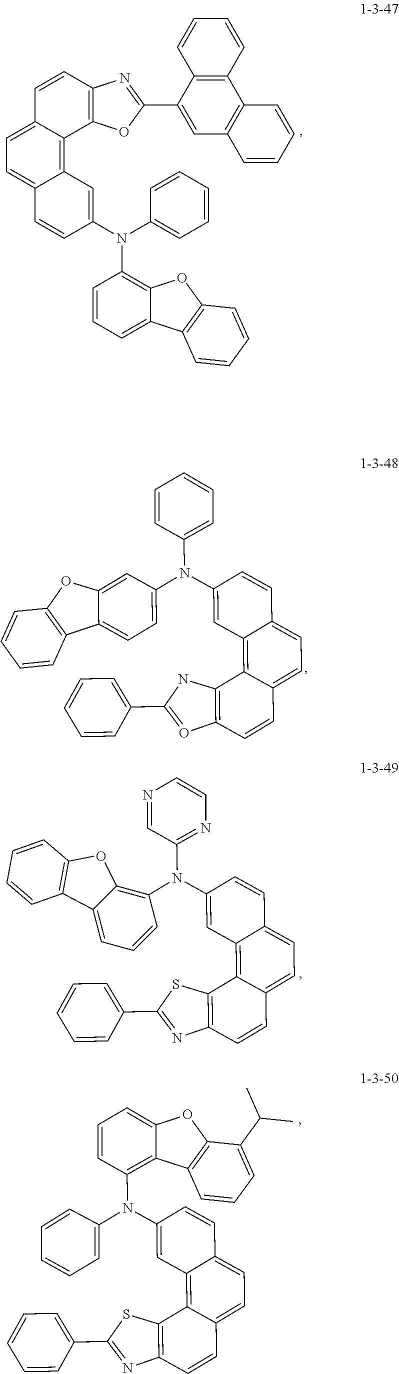 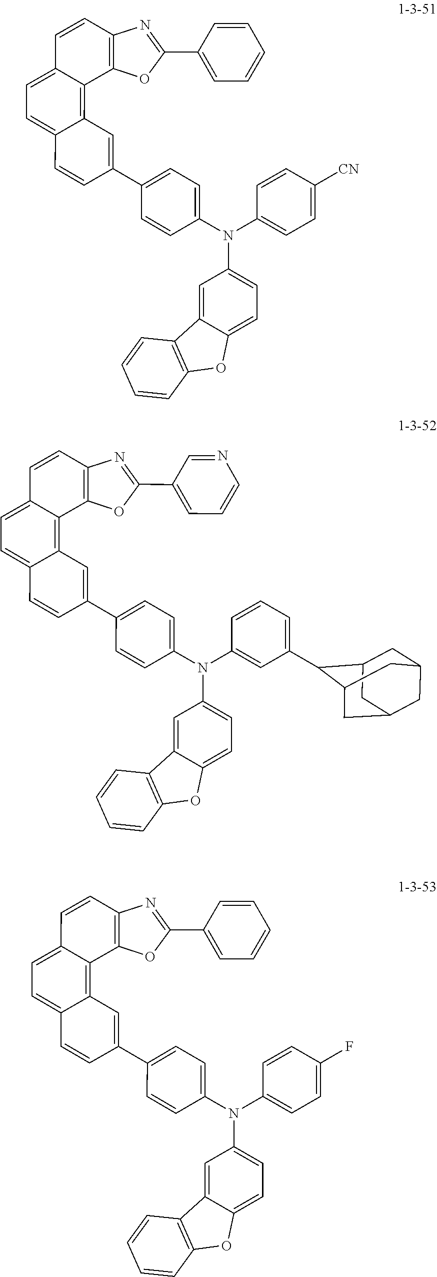 [SMILES: N#Cc1ccc(N(c2ccc(-c3ccc4ccc5ccc6nc(-c7ccccc7)oc6c5c4c3)cc2)c2ccc3oc4ccccc4c3c2)cc1 ; c1cncc(-c2nc3ccc4ccc5ccc(-c6ccc(N(c7cccc(C8C9CC%10CC(C9)CC8C%10)c7)c7ccc8oc9ccccc9c8c7)cc6)cc5c4c3o2)c1 ; Fc1ccc(N(c2ccc(-c3ccc4ccc5ccc6nc(-c7ccccc7)oc6c5c4c3)cc2)c2ccc3oc4ccccc4c3c2)cc1] 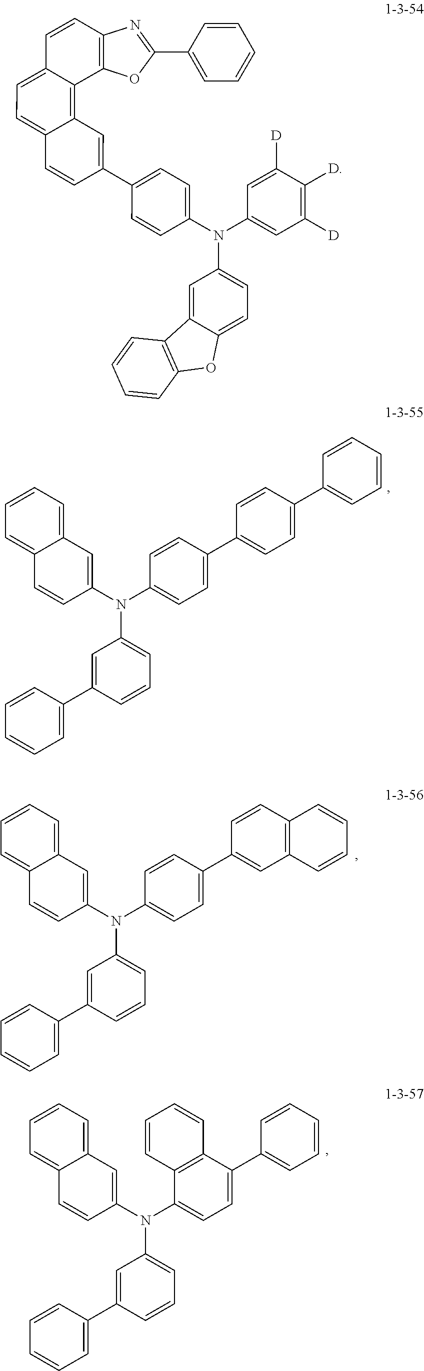 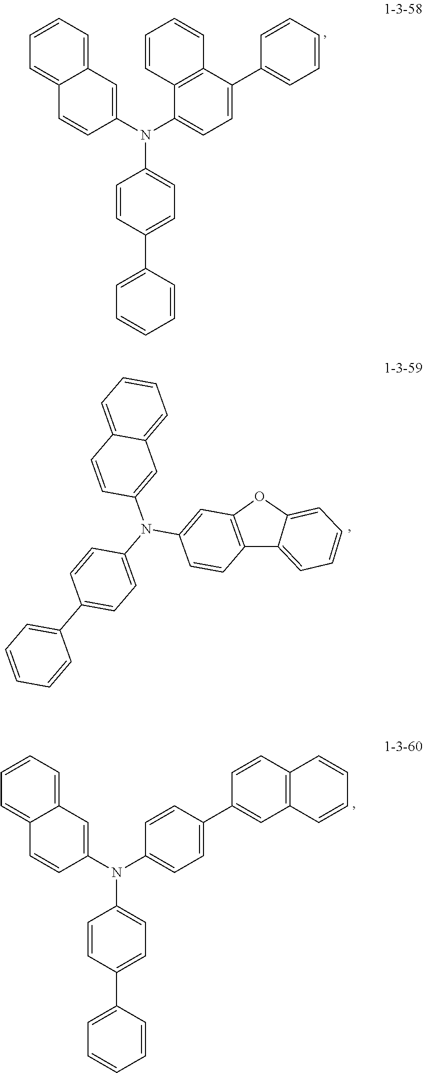 [SMILES: c1ccc(-c2ccc(N(c3ccc4ccccc4c3)c3ccc(-c4ccccc4)c4ccccc34)cc2)cc1 ; c1ccc(-c2ccc(N(c3ccc4ccccc4c3)c3ccc4c(c3)oc3ccccc34)cc2)cc1 ; c1ccc(-c2ccc(N(c3ccc(-c4ccc5ccccc5c4)cc3)c3ccc4ccccc4c3)cc2)cc1] 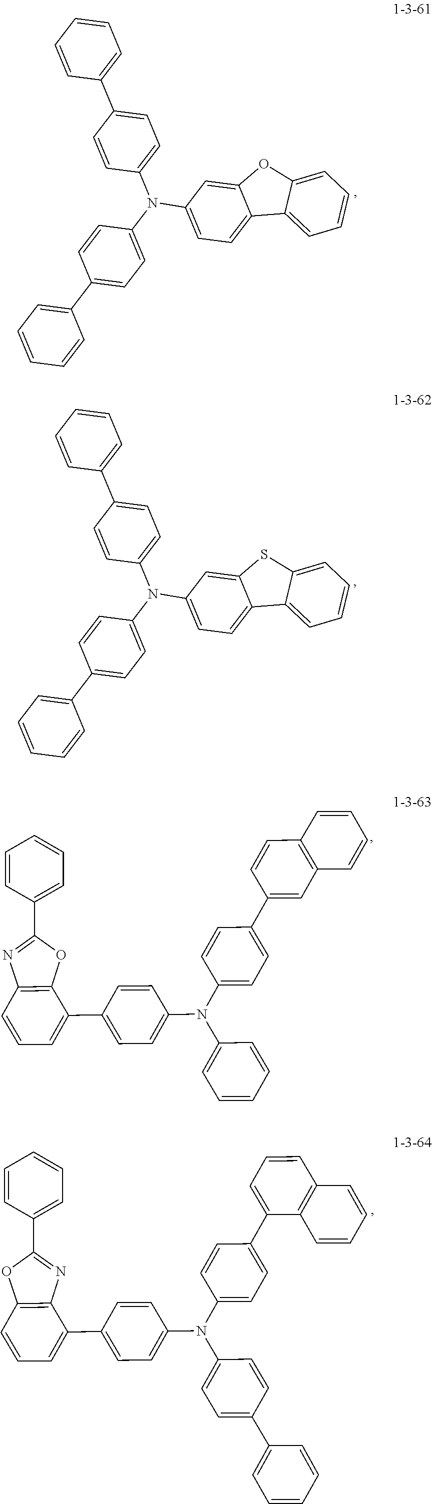 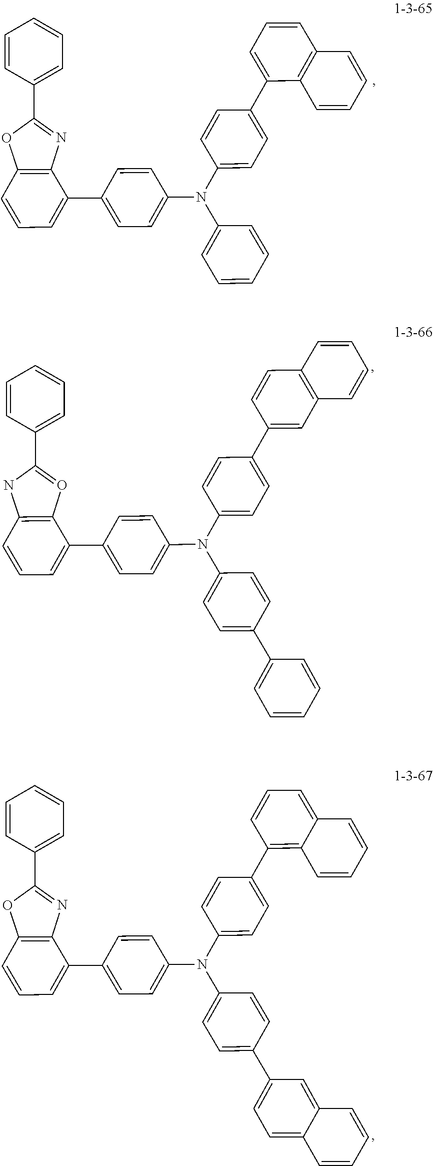 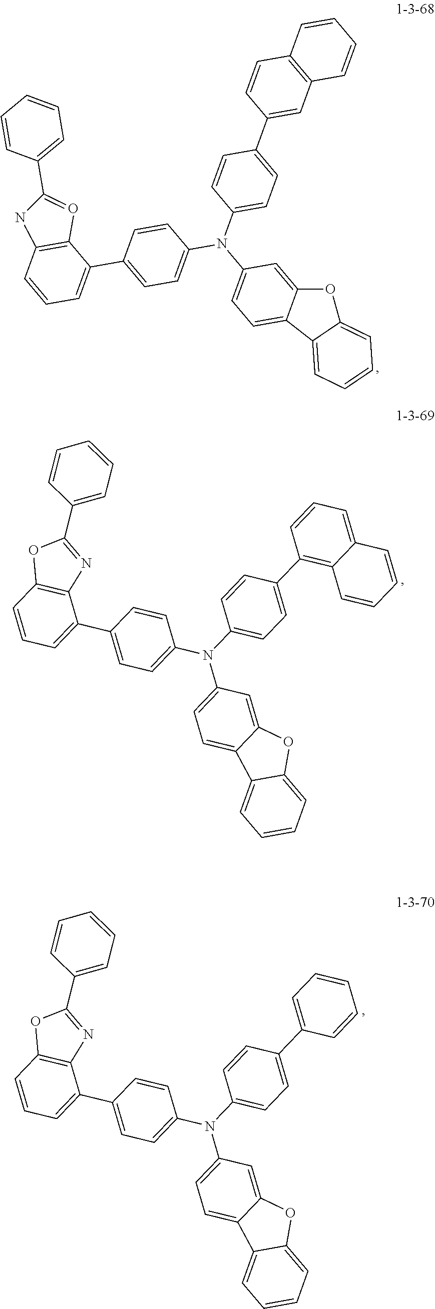 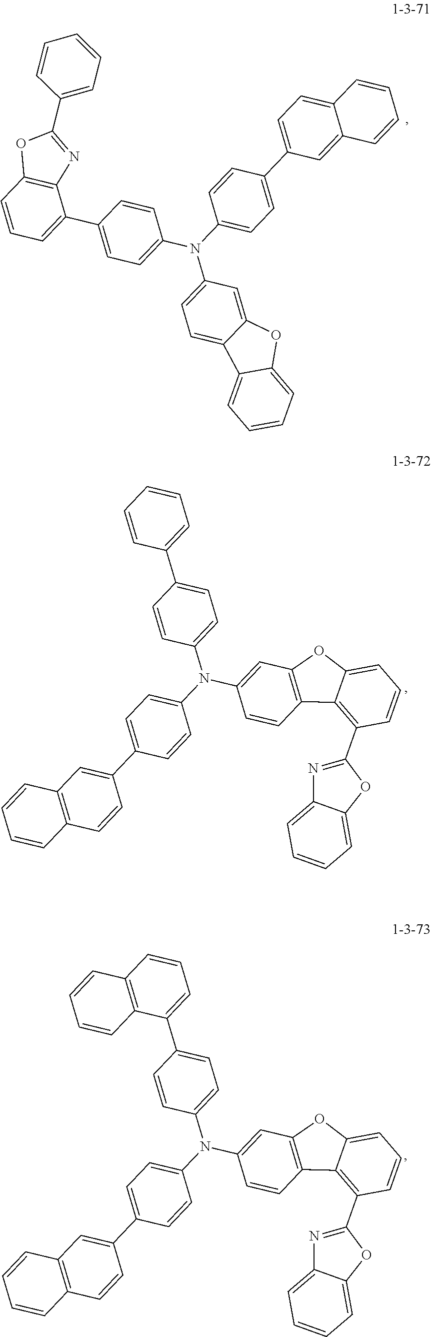 [SMILES: c1ccc(-c2nc3c(-c4ccc(N(c5ccc(-c6ccc7ccccc7c6)cc5)c5ccc6c(c5)oc5ccccc56)cc4)cccc3o2)cc1 ; c1ccc(-c2ccc(N(c3ccc(-c4ccc5ccccc5c4)cc3)c3ccc4c(c3)oc3cccc(-c5nc6ccccc6o5)c34)cc2)cc1 ; c1ccc2cc(-c3ccc(N(c4ccc(-c5cccc6ccccc56)cc4)c4ccc5c(c4)oc4cccc(-c6nc7ccccc7o6)c45)cc3)ccc2c1] 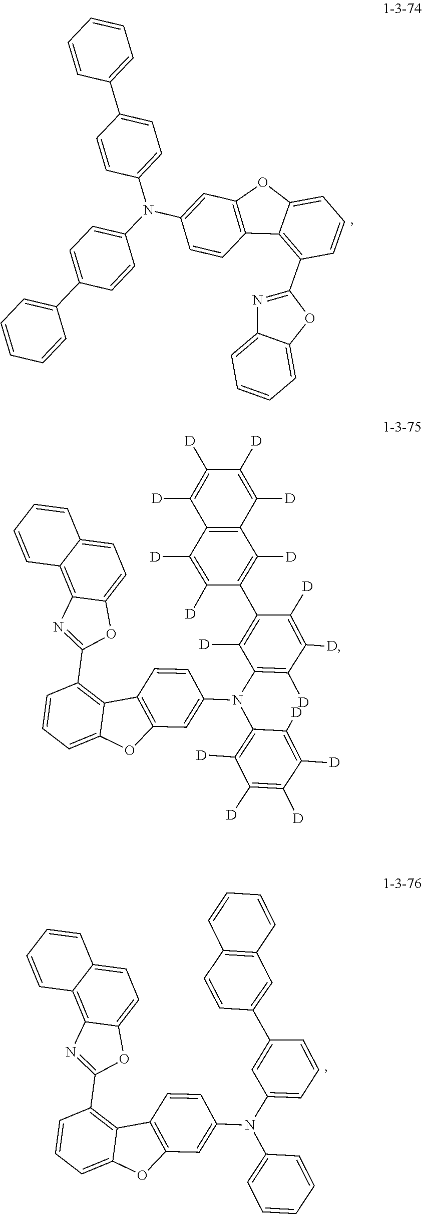 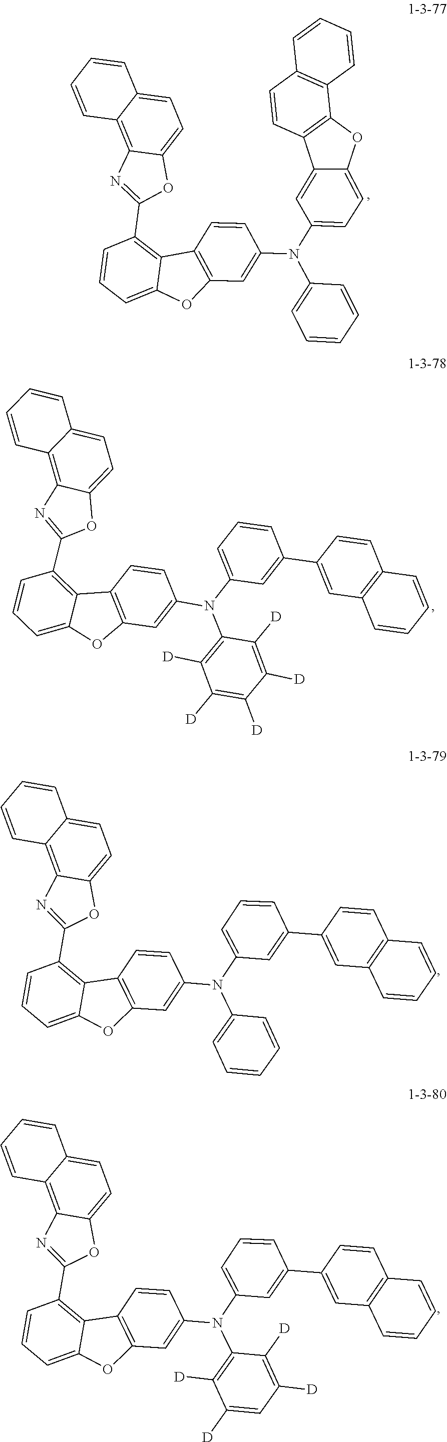 [SMILES: c1ccc(N(c2ccc3c(c2)oc2cccc(-c4nc5c(ccc6ccccc65)o4)c23)c2ccc3oc4c5ccccc5ccc4c3c2)cc1 ; [2H]c1c([2H])c([2H])c(N(c2cccc(-c3ccc4ccccc4c3)c2)c2ccc3c(c2)oc2cccc(-c4nc5c(ccc6ccccc65)o4)c23)c([2H])c1[2H] ; c1ccc(N(c2cccc(-c3ccc4ccccc4c3)c2)c2ccc3c(c2)oc2cccc(-c4nc5c(ccc6ccccc65)o4)c23)cc1 ; [2H]c1cc([2H])c([2H])c(N(c2cccc(-c3ccc4ccccc4c3)c2)c2ccc3c(c2)oc2cccc(-c4nc5c(ccc6ccccc65)o4)c23)c1[2H]] 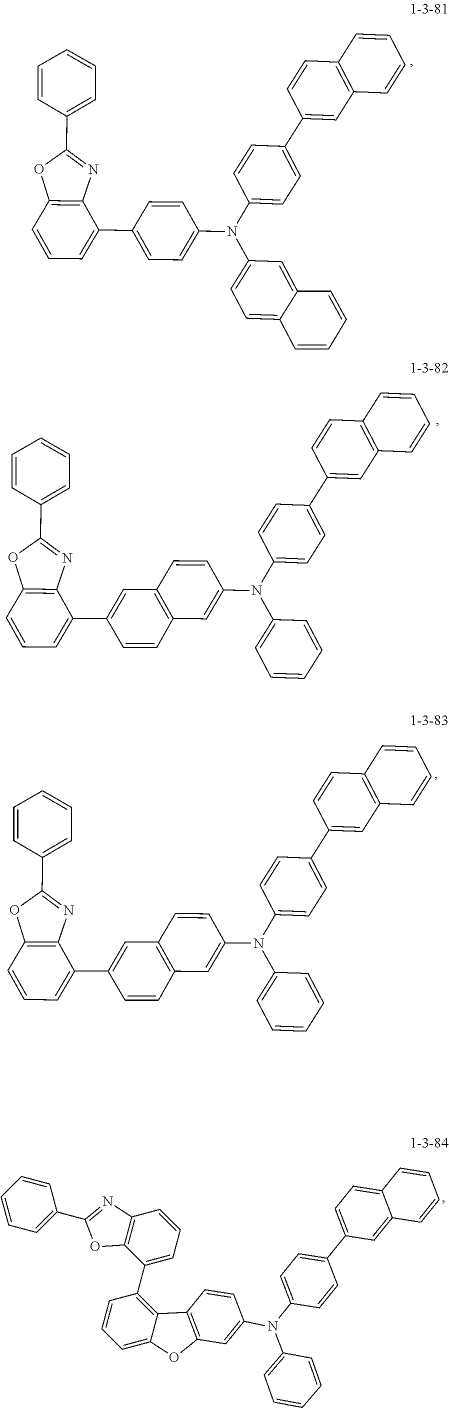 [SMILES: c1ccc(-c2nc3c(-c4ccc(N(c5ccc(-c6ccc7ccccc7c6)cc5)c5ccc6ccccc6c5)cc4)cccc3o2)cc1 ; c1ccc(-c2nc3c(-c4ccc5cc(N(c6ccccc6)c6ccc(-c7ccc8ccccc8c7)cc6)ccc5c4)cccc3o2)cc1 ; c1ccc(-c2nc3c(-c4ccc5cc(N(c6ccccc6)c6ccc(-c7ccc8ccccc8c7)cc6)ccc5c4)cccc3o2)cc1 ; c1ccc(-c2nc3cccc(-c4cccc5oc6cc(N(c7ccccc7)c7ccc(-c8ccc9ccccc9c8)cc7)ccc6c45)c3o2)cc1] 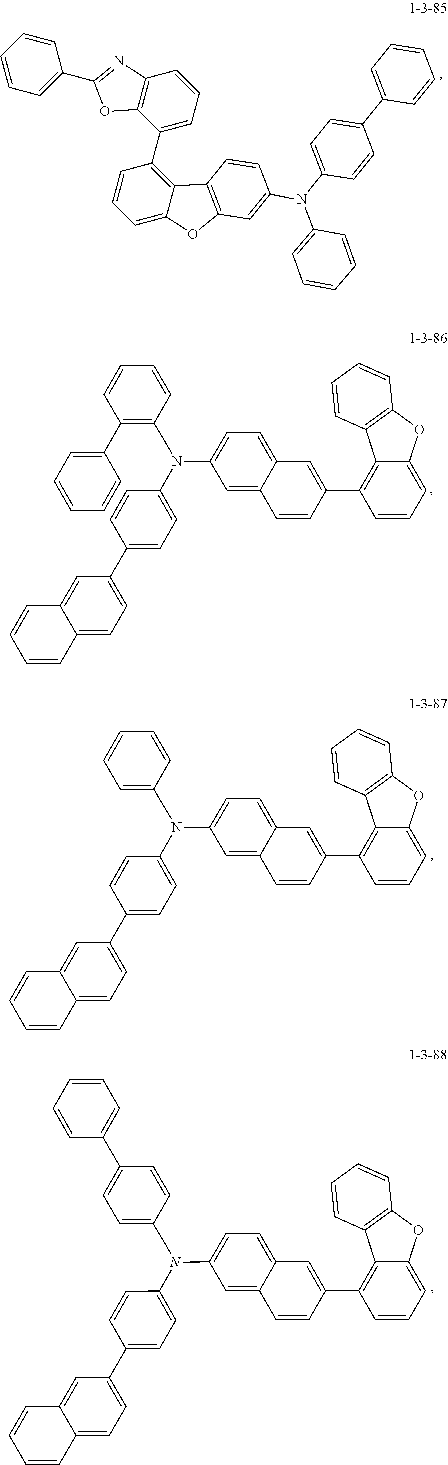 [SMILES: c1ccc(-c2ccc(N(c3ccccc3)c3ccc4c(c3)oc3cccc(-c5cccc6nc(-c7ccccc7)oc56)c34)cc2)cc1 ; c1ccc(-c2ccccc2N(c2ccc(-c3ccc4ccccc4c3)cc2)c2ccc3cc(-c4cccc5oc6ccccc6c45)ccc3c2)cc1 ; c1ccc(N(c2ccc(-c3ccc4ccccc4c3)cc2)c2ccc3cc(-c4cccc5oc6ccccc6c45)ccc3c2)cc1 ; c1ccc(-c2ccc(N(c3ccc(-c4ccc5ccccc5c4)cc3)c3ccc4cc(-c5cccc6oc7ccccc7c56)ccc4c3)cc2)cc1] 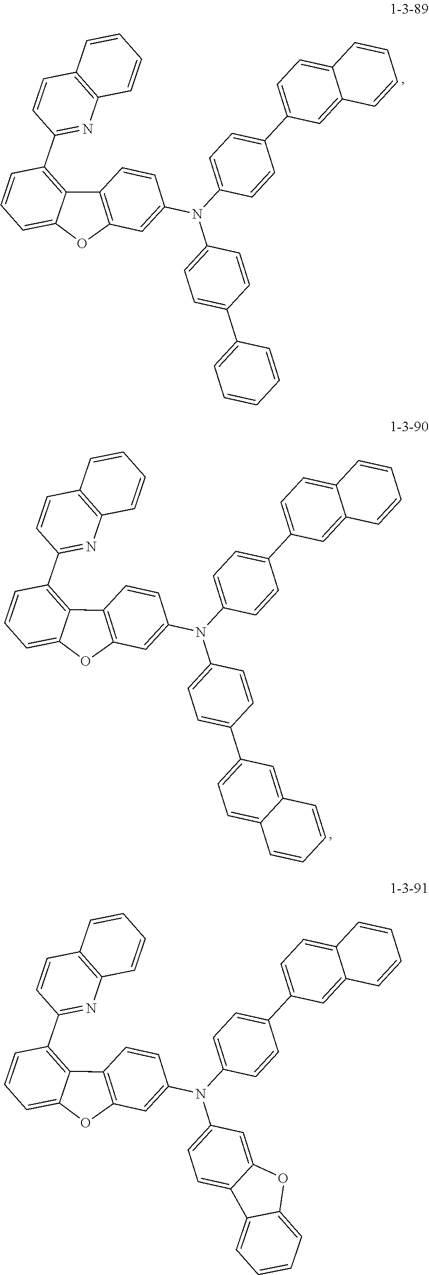 [SMILES: c1ccc(-c2ccc(N(c3ccc(-c4ccc5ccccc5c4)cc3)c3ccc4c(c3)oc3cccc(-c5ccc6ccccc6n5)c34)cc2)cc1 ; c1ccc2cc(-c3ccc(N(c4ccc(-c5ccc6ccccc6c5)cc4)c4ccc5c(c4)oc4cccc(-c6ccc7ccccc7n6)c45)cc3)ccc2c1 ; c1ccc2cc(-c3ccc(N(c4ccc5c(c4)oc4ccccc45)c4ccc5c(c4)oc4cccc(-c6ccc7ccccc7n6)c45)cc3)ccc2c1] 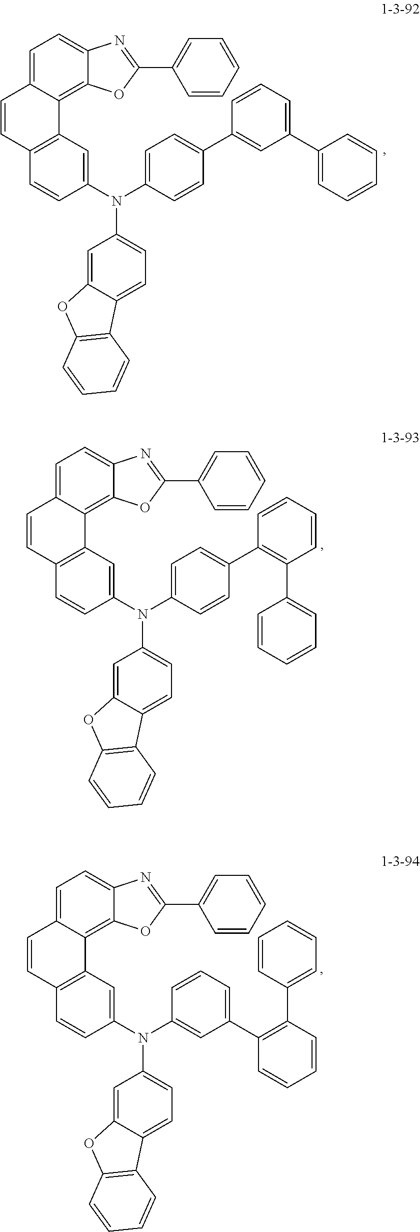 [SMILES: c1ccc(-c2cccc(-c3ccc(N(c4ccc5c(c4)oc4ccccc45)c4ccc5ccc6ccc7nc(-c8ccccc8)oc7c6c5c4)cc3)c2)cc1 ; c1ccc(-c2nc3ccc4ccc5ccc(N(c6ccc(-c7ccccc7-c7ccccc7)cc6)c6ccc7c(c6)oc6ccccc67)cc5c4c3o2)cc1 ; c1ccc(-c2nc3ccc4ccc5ccc(N(c6cccc(-c7ccccc7-c7ccccc7)c6)c6ccc7c(c6)oc6ccccc67)cc5c4c3o2)cc1] 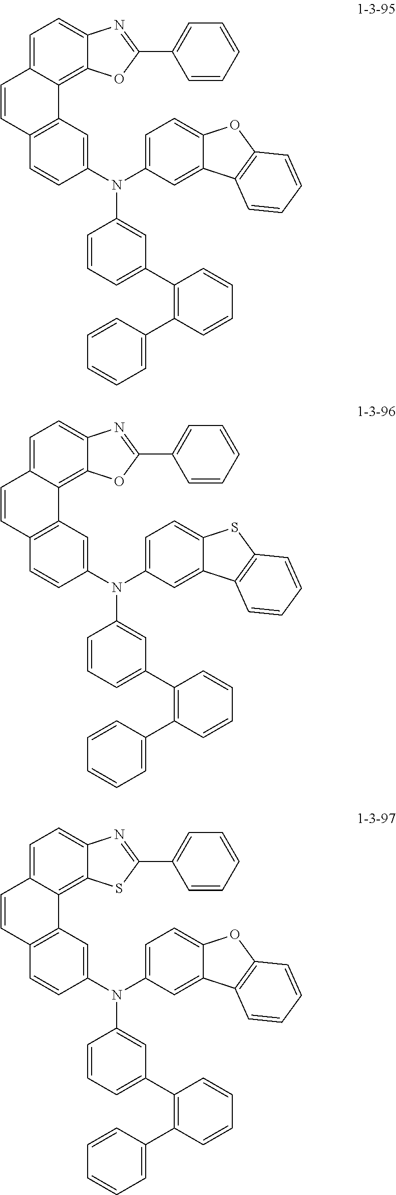 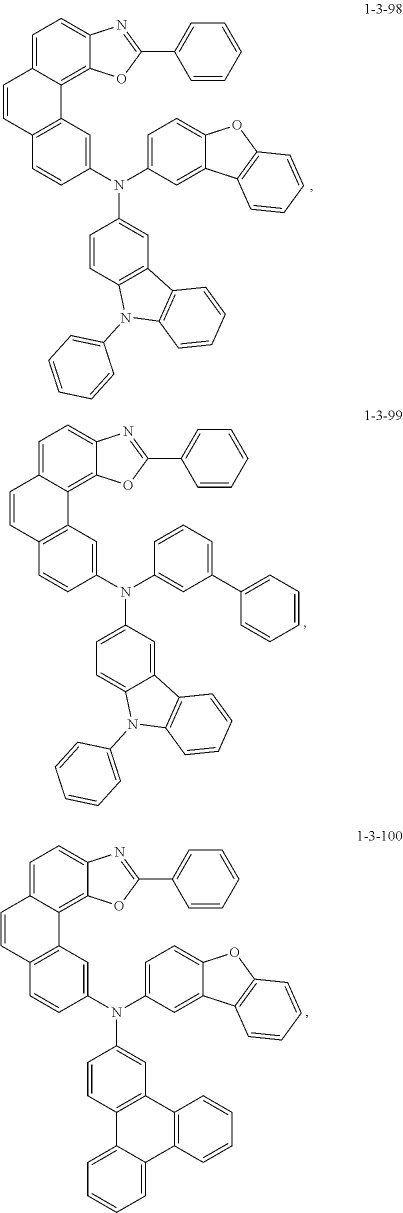
wherein optionally, hydrogen in Compound 1-1-1 to Compound 1-1-104, Compound 1-2-1 to Compound 1-2-100 and Compound 1-3-1 to Compound 1-3-100 can be partially or fully substituted with deuterium;
the second host material is selected from the group consisting of Compound B-1 to Compound B-236: 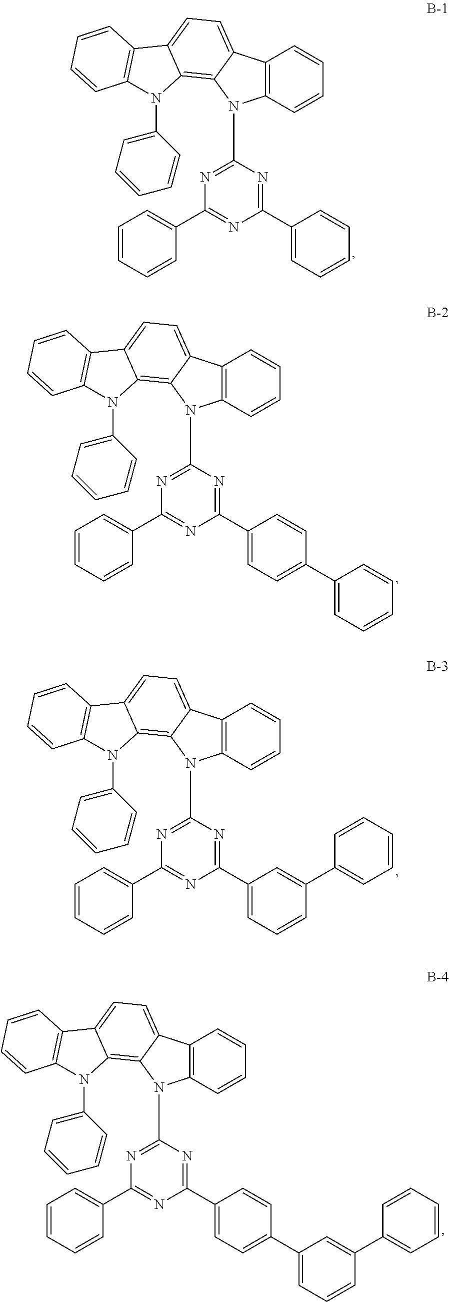 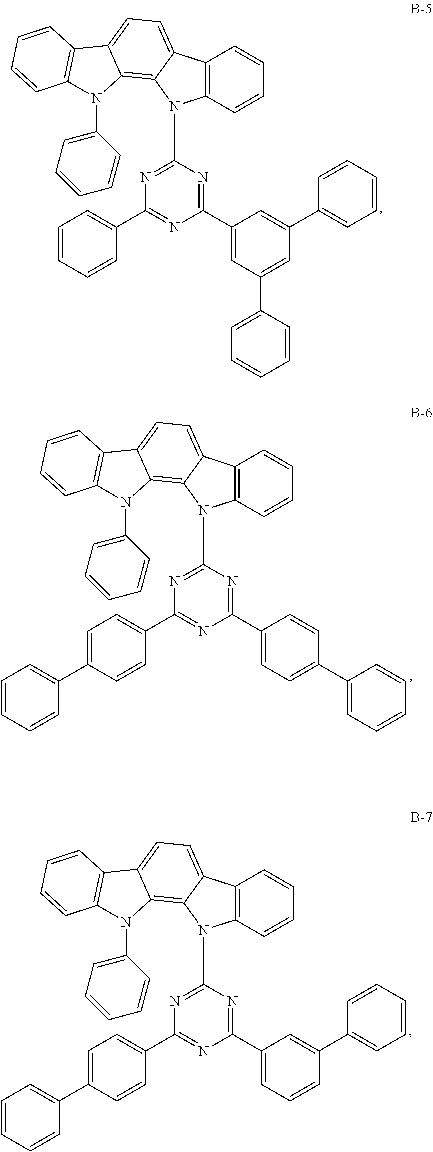 [SMILES: c1ccc(-c2cc(-c3ccccc3)cc(-c3nc(-c4ccccc4)nc(-n4c5ccccc5c5ccc6c7ccccc7n(-c7ccccc7)c6c54)n3)c2)cc1 ; c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1 ; c1ccc(-c2ccc(-c3nc(-c4cccc(-c5ccccc5)c4)nc(-n4c5ccccc5c5ccc6c7ccccc7n(-c7ccccc7)c6c54)n3)cc2)cc1] 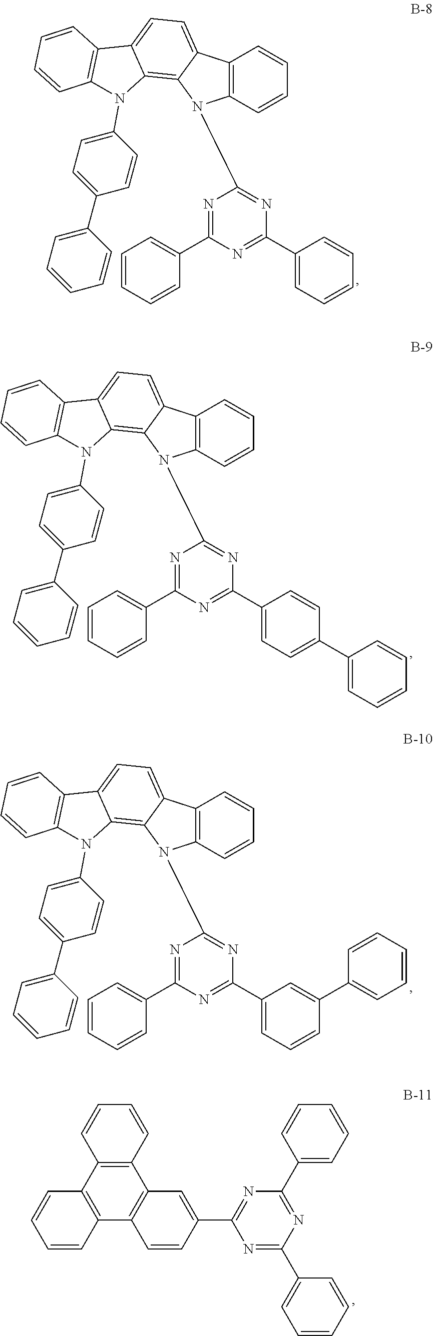 [SMILES: c1ccc(-c2ccc(-n3c4ccccc4c4ccc5c6ccccc6n(-c6nc(-c7ccccc7)nc(-c7ccccc7)n6)c5c43)cc2)cc1 ; c1ccc(-c2ccc(-c3nc(-c4ccccc4)nc(-n4c5ccccc5c5ccc6c7ccccc7n(-c7ccc(-c8ccccc8)cc7)c6c54)n3)cc2)cc1 ; c1ccc(-c2ccc(-n3c4ccccc4c4ccc5c6ccccc6n(-c6nc(-c7ccccc7)nc(-c7cccc(-c8ccccc8)c7)n6)c5c43)cc2)cc1 ; c1ccc(-c2nc(-c3ccccc3)nc(-c3ccc4c5ccccc5c5ccccc5c4c3)n2)cc1] 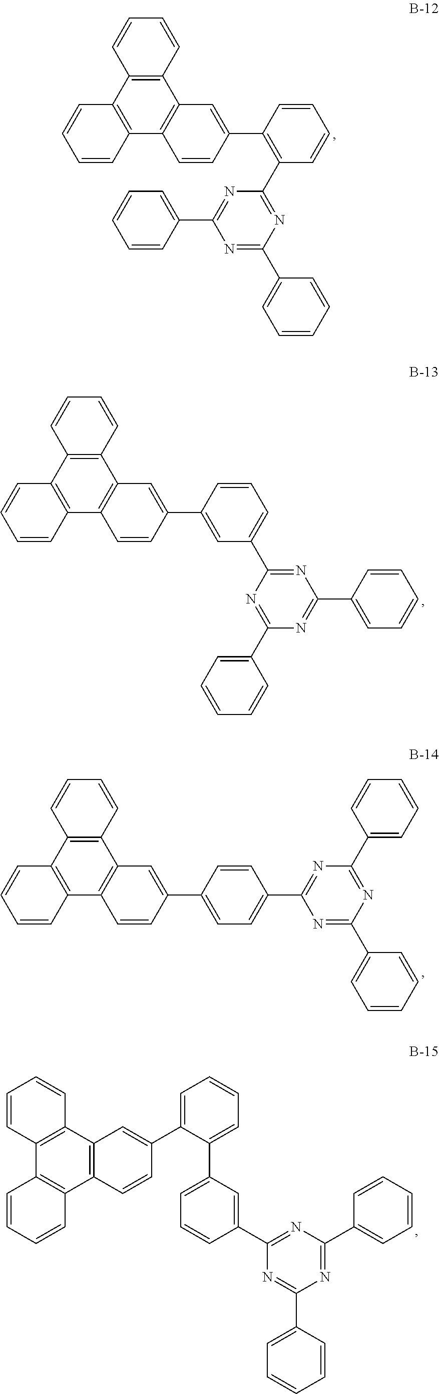 [SMILES: c1ccc(-c2nc(-c3ccccc3)nc(-c3ccccc3-c3ccc4c5ccccc5c5ccccc5c4c3)n2)cc1 ; c1ccc(-c2nc(-c3ccccc3)nc(-c3cccc(-c4ccc5c6ccccc6c6ccccc6c5c4)c3)n2)cc1 ; c1ccc(-c2nc(-c3ccccc3)nc(-c3ccc(-c4ccc5c6ccccc6c6ccccc6c5c4)cc3)n2)cc1 ; c1ccc(-c2nc(-c3ccccc3)nc(-c3cccc(-c4ccccc4-c4ccc5c6ccccc6c6ccccc6c5c4)c3)n2)cc1] 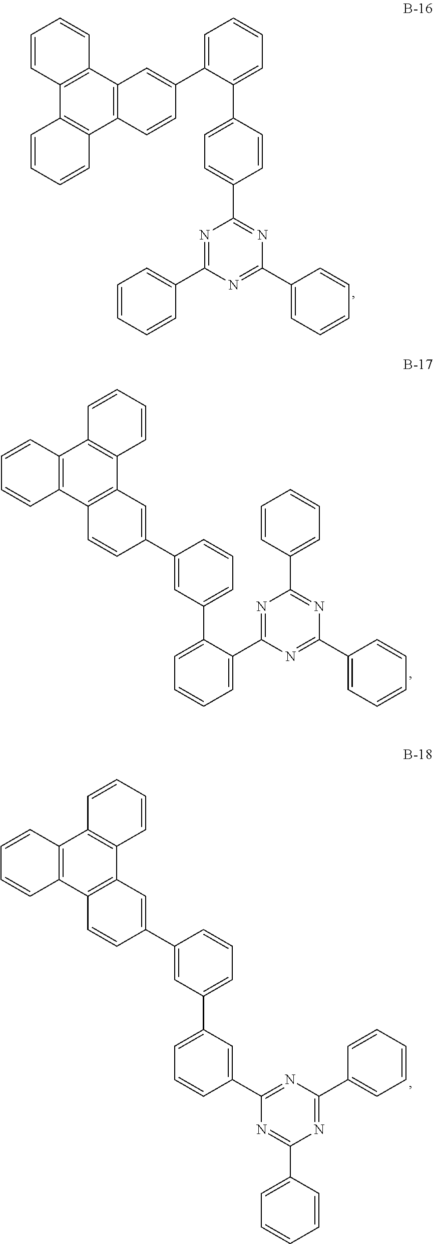 [SMILES: c1ccc(-c2nc(-c3ccccc3)nc(-c3ccc(-c4ccccc4-c4ccc5c6ccccc6c6ccccc6c5c4)cc3)n2)cc1 ; c1ccc(-c2nc(-c3ccccc3)nc(-c3ccccc3-c3cccc(-c4ccc5c6ccccc6c6ccccc6c5c4)c3)n2)cc1 ; c1ccc(-c2nc(-c3ccccc3)nc(-c3cccc(-c4cccc(-c5ccc6c7ccccc7c7ccccc7c6c5)c4)c3)n2)cc1] 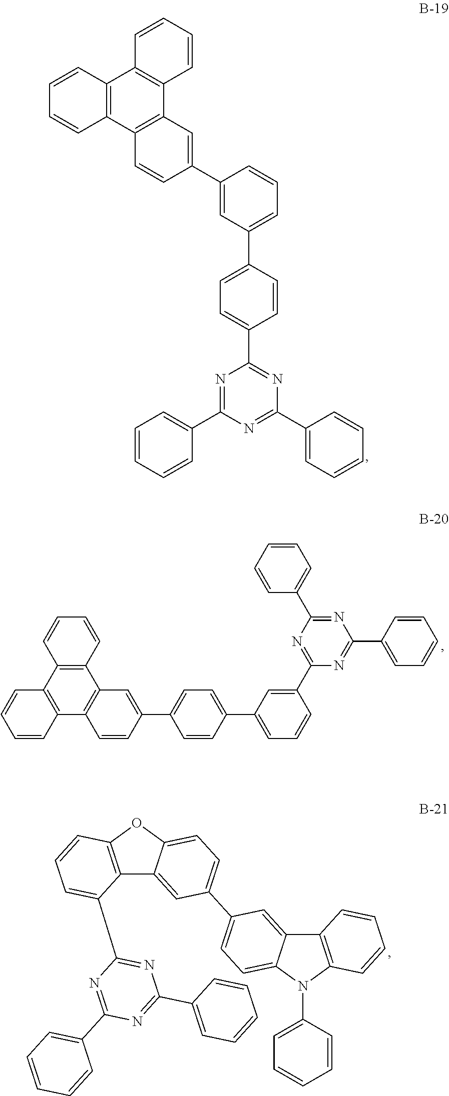 [SMILES: c1ccc(-c2nc(-c3ccccc3)nc(-c3ccc(-c4cccc(-c5ccc6c7ccccc7c7ccccc7c6c5)c4)cc3)n2)cc1 ; c1ccc(-c2nc(-c3ccccc3)nc(-c3cccc(-c4ccc(-c5ccc6c7ccccc7c7ccccc7c6c5)cc4)c3)n2)cc1 ; c1ccc(-c2nc(-c3ccccc3)nc(-c3cccc4oc5ccc(-c6ccc7c(c6)c6ccccc6n7-c6ccccc6)cc5c34)n2)cc1] 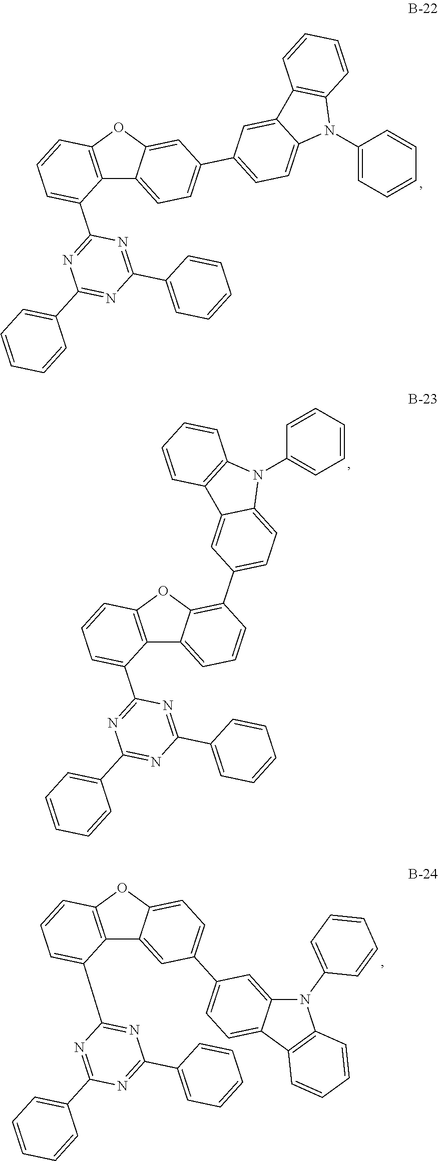 [SMILES: c1ccc(-c2nc(-c3ccccc3)nc(-c3cccc4oc5cc(-c6ccc7c(c6)c6ccccc6n7-c6ccccc6)ccc5c34)n2)cc1 ; c1ccc(-c2nc(-c3ccccc3)nc(-c3cccc4oc5c(-c6ccc7c(c6)c6ccccc6n7-c6ccccc6)cccc5c34)n2)cc1 ; c1ccc(-c2nc(-c3ccccc3)nc(-c3cccc4oc5ccc(-c6ccc7c8ccccc8n(-c8ccccc8)c7c6)cc5c34)n2)cc1] 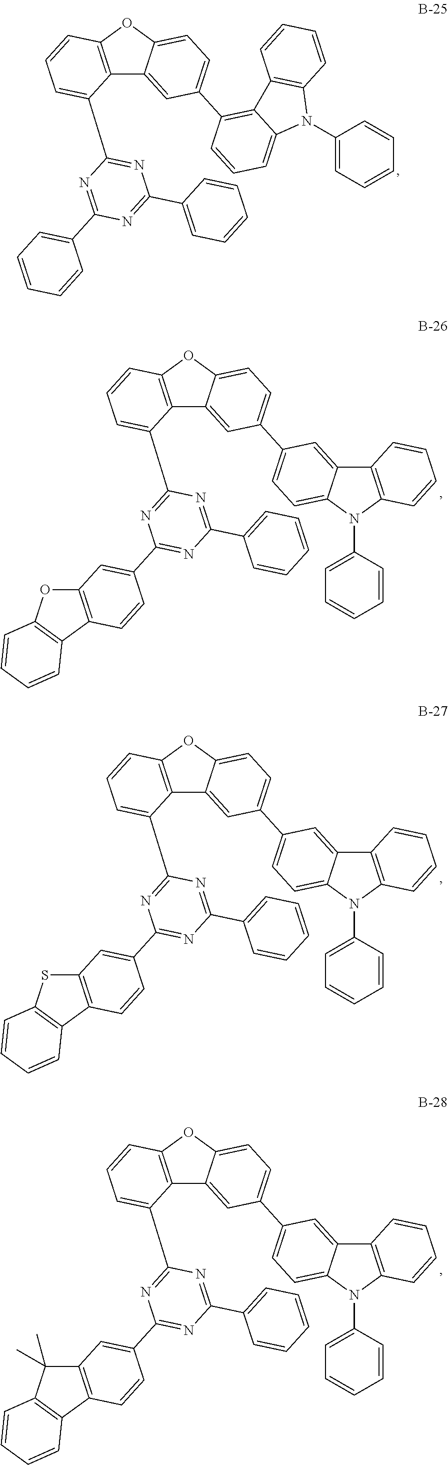 [SMILES: c1ccc(-c2nc(-c3ccccc3)nc(-c3cccc4oc5ccc(-c6cccc7c6c6ccccc6n7-c6ccccc6)cc5c34)n2)cc1 ; c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1 ; c1ccc(-c2nc(-c3ccc4c(c3)sc3ccccc34)nc(-c3cccc4oc5ccc(-c6ccc7c(c6)c6ccccc6n7-c6ccccc6)cc5c34)n2)cc1 ; CC1(C)c2ccccc2-c2ccc(-c3nc(-c4ccccc4)nc(-c4cccc5oc6ccc(-c7ccc8c(c7)c7ccccc7n8-c7ccccc7)cc6c45)n3)cc21] 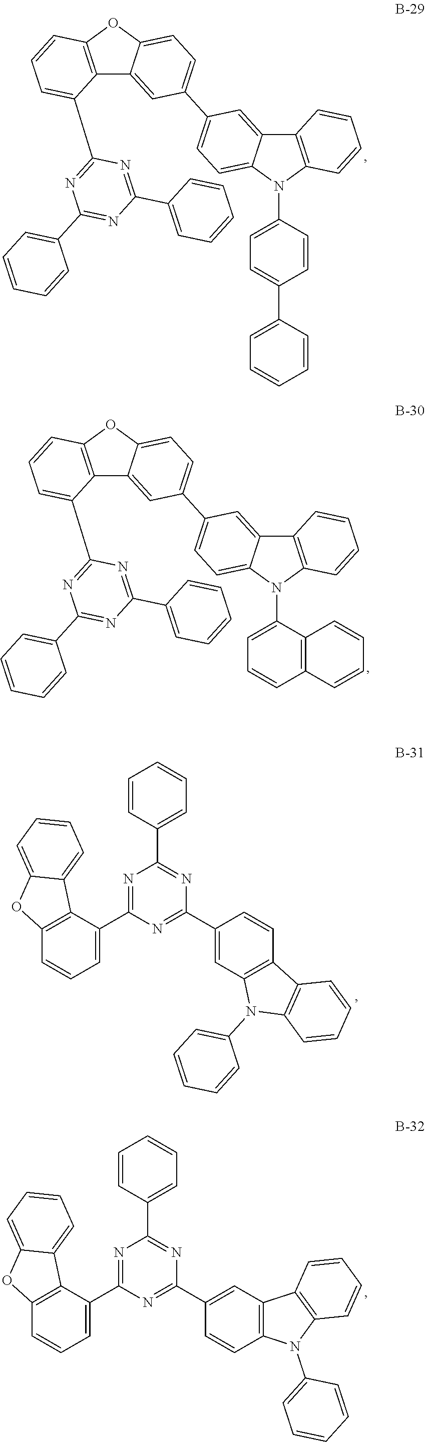 [SMILES: c1ccc(-c2ccc(-n3c4ccccc4c4cc(-c5ccc6oc7cccc(-c8nc(-c9ccccc9)nc(-c9ccccc9)n8)c7c6c5)ccc43)cc2)cc1 ; c1ccc(-c2nc(-c3ccccc3)nc(-c3cccc4oc5ccc(-c6ccc7c(c6)c6ccccc6n7-c6cccc7ccccc67)cc5c34)n2)cc1 ; c1ccc(-c2nc(-c3ccc4c5ccccc5n(-c5ccccc5)c4c3)nc(-c3cccc4oc5ccccc5c34)n2)cc1 ; c1ccc(-c2nc(-c3ccc4c(c3)c3ccccc3n4-c3ccccc3)nc(-c3cccc4oc5ccccc5c34)n2)cc1] 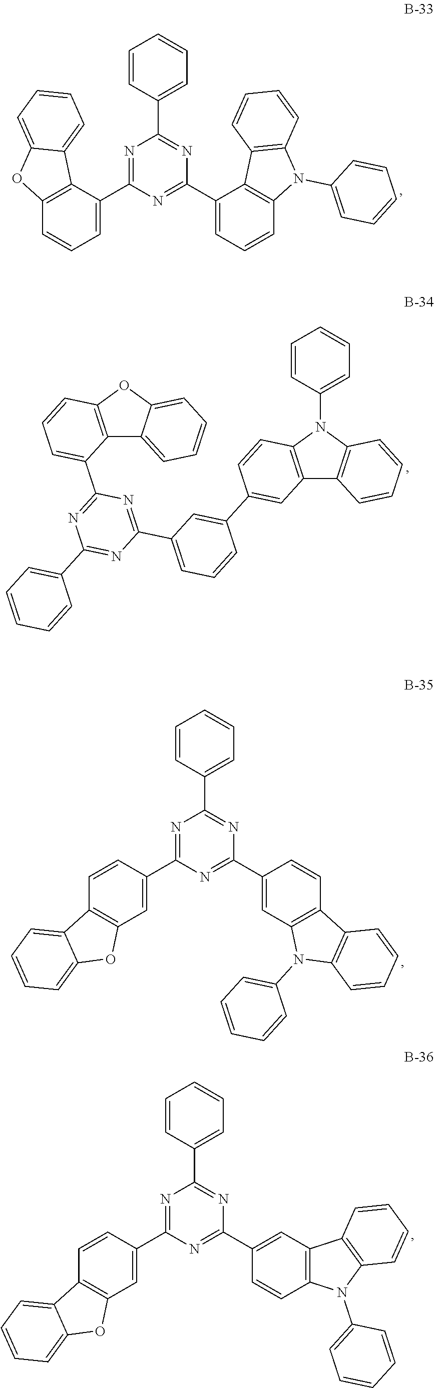 [SMILES: c1ccc(-c2nc(-c3cccc4oc5ccccc5c34)nc(-c3cccc4c3c3ccccc3n4-c3ccccc3)n2)cc1 ; c1ccc(-c2nc(-c3cccc(-c4ccc5c(c4)c4ccccc4n5-c4ccccc4)c3)nc(-c3cccc4oc5ccccc5c34)n2)cc1 ; c1ccc(-c2nc(-c3ccc4c(c3)oc3ccccc34)nc(-c3ccc4c5ccccc5n(-c5ccccc5)c4c3)n2)cc1 ; c1ccc(-c2nc(-c3ccc4c(c3)oc3ccccc34)nc(-c3ccc4c(c3)c3ccccc3n4-c3ccccc3)n2)cc1] 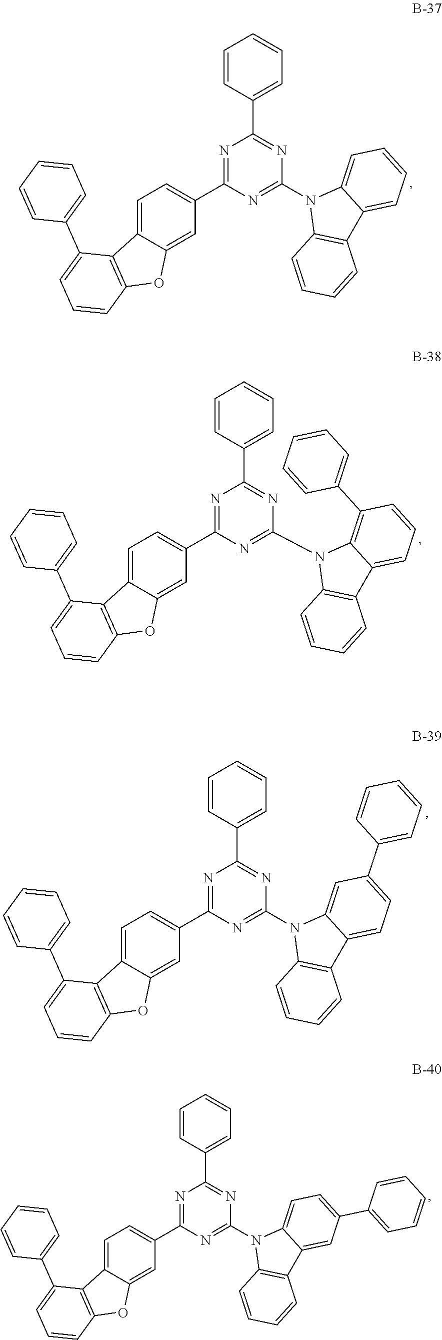 [SMILES: c1ccc(-c2nc(-c3ccc4c(c3)oc3cccc(-c5ccccc5)c34)nc(-n3c4ccccc4c4ccccc43)n2)cc1 ; c1ccc(-c2nc(-c3ccc4c(c3)oc3cccc(-c5ccccc5)c34)nc(-n3c4ccccc4c4cccc(-c5ccccc5)c43)n2)cc1 ; c1ccc(-c2ccc3c4ccccc4n(-c4nc(-c5ccccc5)nc(-c5ccc6c(c5)oc5cccc(-c7ccccc7)c56)n4)c3c2)cc1 ; c1ccc(-c2ccc3c(c2)c2ccccc2n3-c2nc(-c3ccccc3)nc(-c3ccc4c(c3)oc3cccc(-c5ccccc5)c34)n2)cc1] 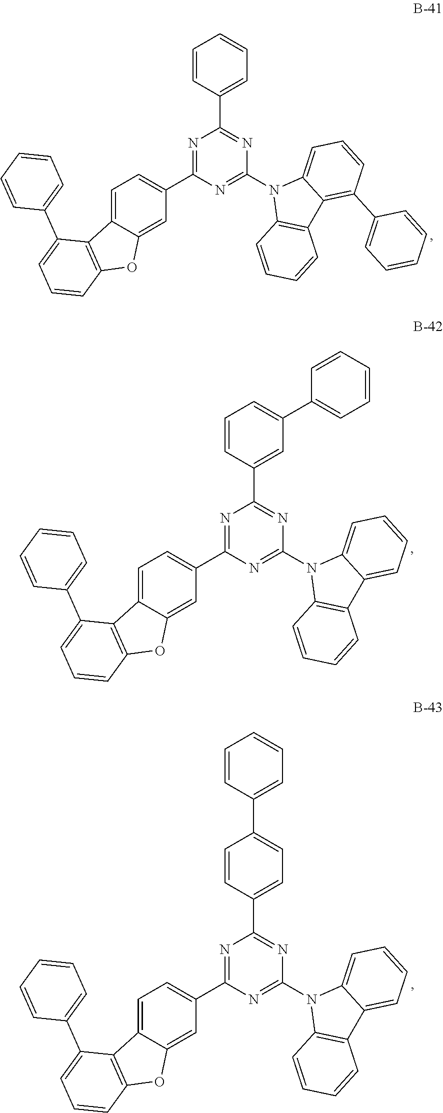 [SMILES: c1ccc(-c2nc(-c3ccc4c(c3)oc3cccc(-c5ccccc5)c34)nc(-n3c4ccccc4c4c(-c5ccccc5)cccc43)n2)cc1 ; c1ccc(-c2cccc(-c3nc(-c4ccc5c(c4)oc4cccc(-c6ccccc6)c45)nc(-n4c5ccccc5c5ccccc54)n3)c2)cc1 ; c1ccc(-c2ccc(-c3nc(-c4ccc5c(c4)oc4cccc(-c6ccccc6)c45)nc(-n4c5ccccc5c5ccccc54)n3)cc2)cc1] 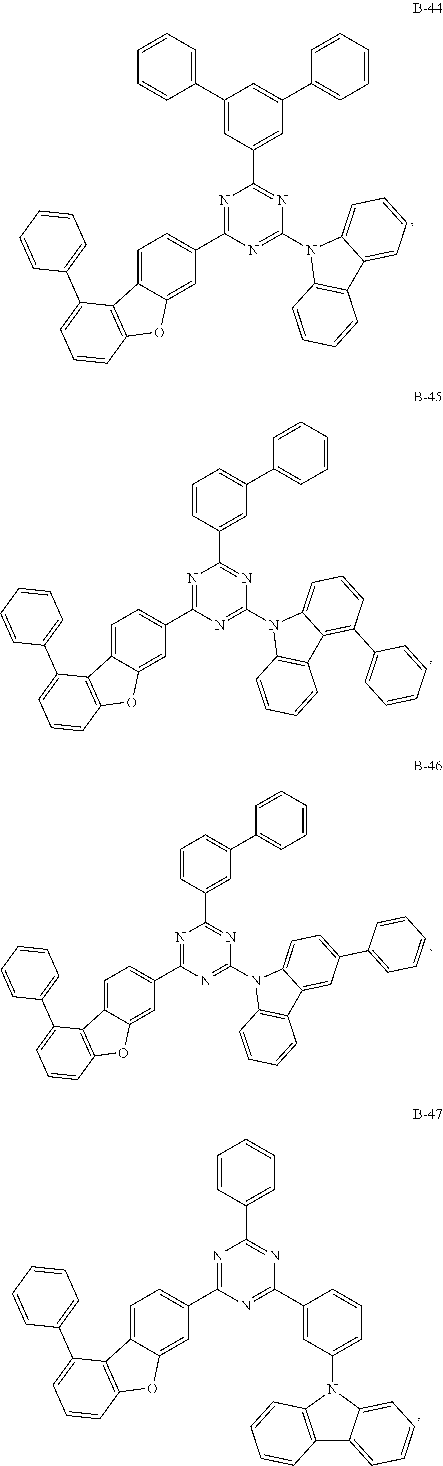 [SMILES: c1ccc(-c2cc(-c3ccccc3)cc(-c3nc(-c4ccc5c(c4)oc4cccc(-c6ccccc6)c45)nc(-n4c5ccccc5c5ccccc54)n3)c2)cc1 ; c1ccc(-c2cccc(-c3nc(-c4ccc5c(c4)oc4cccc(-c6ccccc6)c45)nc(-n4c5ccccc5c5c(-c6ccccc6)cccc54)n3)c2)cc1 ; c1ccc(-c2cccc(-c3nc(-c4ccc5c(c4)oc4cccc(-c6ccccc6)c45)nc(-n4c5ccccc5c5cc(-c6ccccc6)ccc54)n3)c2)cc1 ; c1ccc(-c2nc(-c3cccc(-n4c5ccccc5c5ccccc54)c3)nc(-c3ccc4c(c3)oc3cccc(-c5ccccc5)c34)n2)cc1] 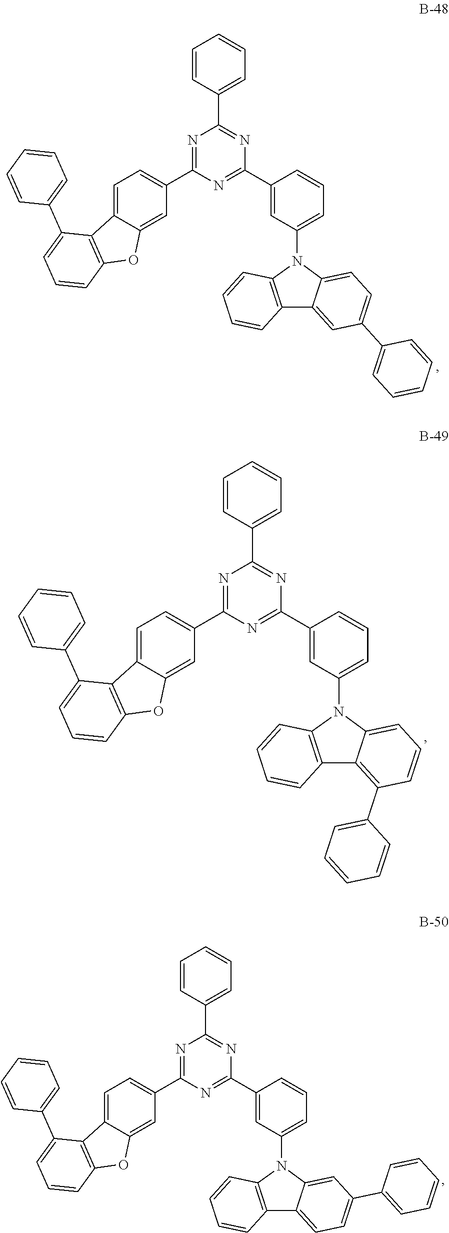 [SMILES: c1ccc(-c2ccc3c(c2)c2ccccc2n3-c2cccc(-c3nc(-c4ccccc4)nc(-c4ccc5c(c4)oc4cccc(-c6ccccc6)c45)n3)c2)cc1 ; c1ccc(-c2nc(-c3cccc(-n4c5ccccc5c5c(-c6ccccc6)cccc54)c3)nc(-c3ccc4c(c3)oc3cccc(-c5ccccc5)c34)n2)cc1 ; c1ccc(-c2ccc3c4ccccc4n(-c4cccc(-c5nc(-c6ccccc6)nc(-c6ccc7c(c6)oc6cccc(-c8ccccc8)c67)n5)c4)c3c2)cc1] 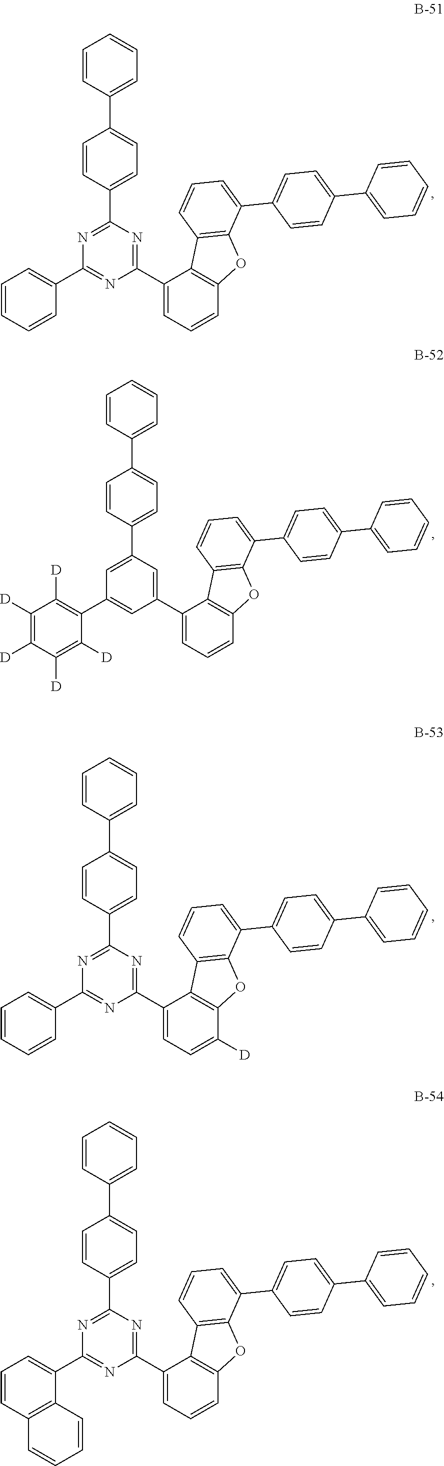 [SMILES: c1ccc(-c2ccc(-c3nc(-c4ccccc4)nc(-c4cccc5oc6c(-c7ccc(-c8ccccc8)cc7)cccc6c45)n3)cc2)cc1 ; [2H]c1c([2H])c([2H])c(-c2cc(-c3ccc(-c4ccccc4)cc3)cc(-c3cccc4oc5c(-c6ccc(-c7ccccc7)cc6)cccc5c34)c2)c([2H])c1[2H] ; [2H]c1ccc(-c2nc(-c3ccccc3)nc(-c3ccc(-c4ccccc4)cc3)n2)c2c1oc1c(-c3ccc(-c4ccccc4)cc3)cccc12 ; c1ccc(-c2ccc(-c3nc(-c4cccc5ccccc45)nc(-c4cccc5oc6c(-c7ccc(-c8ccccc8)cc7)cccc6c45)n3)cc2)cc1] 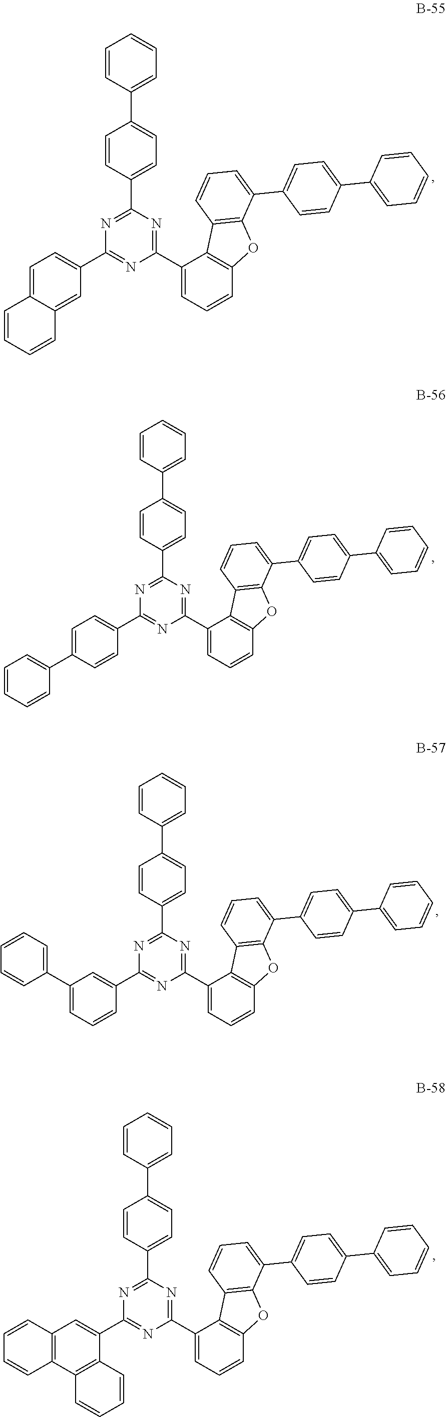 [SMILES: c1ccc(-c2ccc(-c3nc(-c4ccc5ccccc5c4)nc(-c4cccc5oc6c(-c7ccc(-c8ccccc8)cc7)cccc6c45)n3)cc2)cc1 ; c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1 ; c1ccc(-c2ccc(-c3nc(-c4cc5ccccc5c5ccccc45)nc(-c4cccc5oc6c(-c7ccc(-c8ccccc8)cc7)cccc6c45)n3)cc2)cc1] 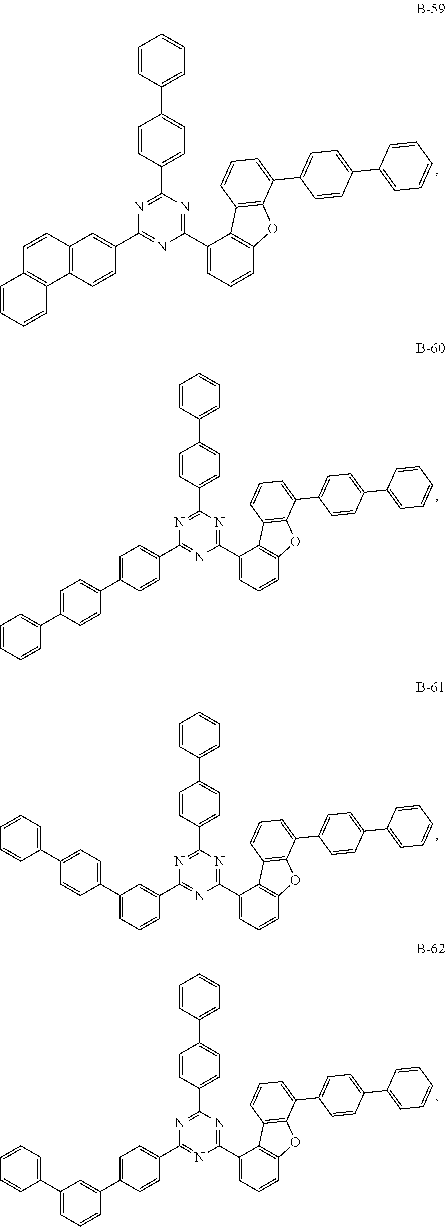 [SMILES: c1ccc(-c2ccc(-c3nc(-c4ccc5c(ccc6ccccc65)c4)nc(-c4cccc5oc6c(-c7ccc(-c8ccccc8)cc7)cccc6c45)n3)cc2)cc1 ; c1ccc(-c2ccc(-c3ccc(-c4nc(-c5ccc(-c6ccccc6)cc5)nc(-c5cccc6oc7c(-c8ccc(-c9ccccc9)cc8)cccc7c56)n4)cc3)cc2)cc1 ; c1ccc(-c2ccc(-c3cccc(-c4nc(-c5ccc(-c6ccccc6)cc5)nc(-c5cccc6oc7c(-c8ccc(-c9ccccc9)cc8)cccc7c56)n4)c3)cc2)cc1 ; c1ccc(-c2ccc(-c3nc(-c4ccc(-c5cccc(-c6ccccc6)c5)cc4)nc(-c4cccc5oc6c(-c7ccc(-c8ccccc8)cc7)cccc6c45)n3)cc2)cc1] 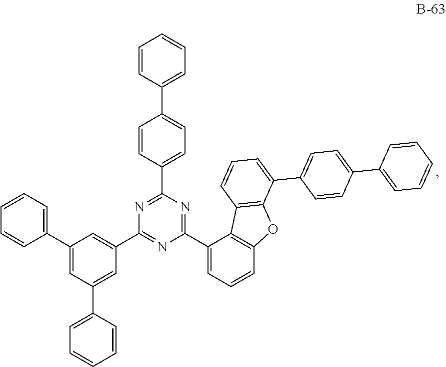 [SMILES: c1ccc(-c2ccc(-c3nc(-c4cc(-c5ccccc5)cc(-c5ccccc5)c4)nc(-c4cccc5oc6c(-c7ccc(-c8ccccc8)cc7)cccc6c45)n3)cc2)cc1] 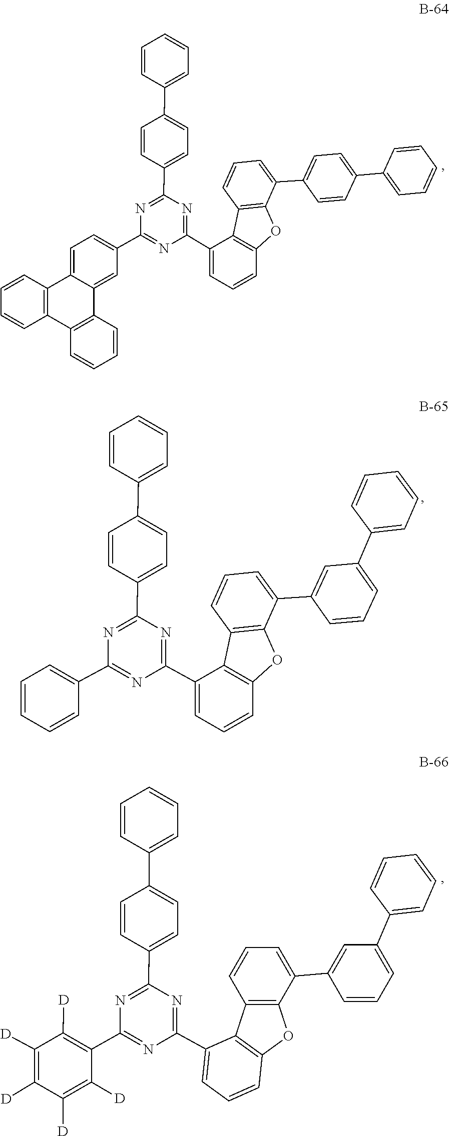 [SMILES: c1ccc(-c2ccc(-c3nc(-c4ccc5c6ccccc6c6ccccc6c5c4)nc(-c4cccc5oc6c(-c7ccc(-c8ccccc8)cc7)cccc6c45)n3)cc2)cc1 ; c1ccc(-c2ccc(-c3nc(-c4ccccc4)nc(-c4cccc5oc6c(-c7cccc(-c8ccccc8)c7)cccc6c45)n3)cc2)cc1 ; [2H]c1c([2H])c([2H])c(-c2nc(-c3ccc(-c4ccccc4)cc3)nc(-c3cccc4oc5c(-c6cccc(-c7ccccc7)c6)cccc5c34)n2)c([2H])c1[2H]] 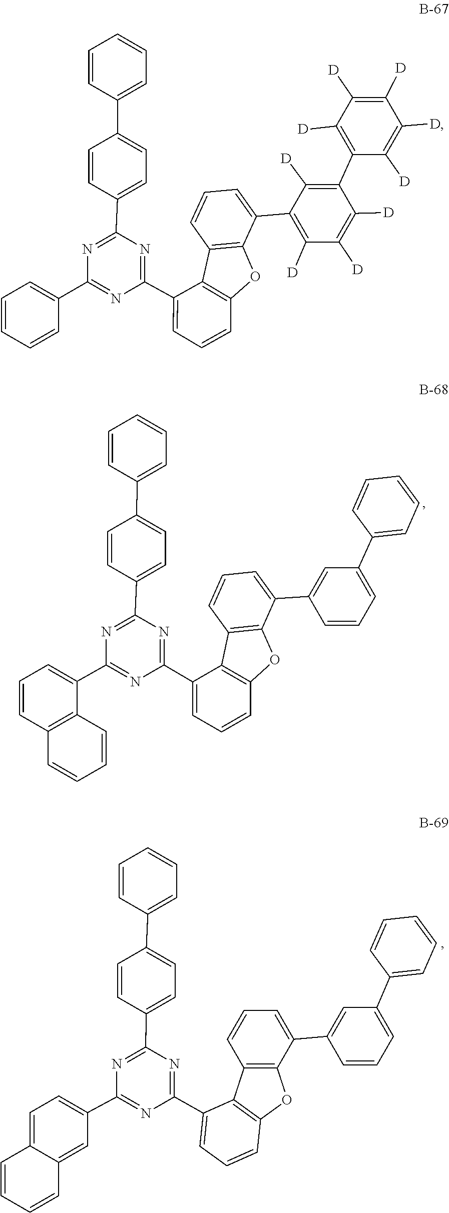 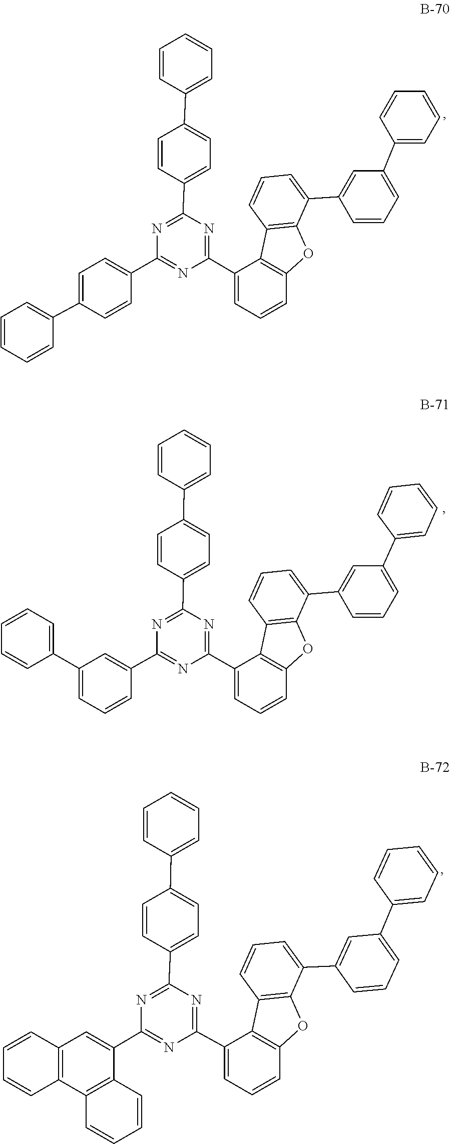 [SMILES: c1ccc(-c2ccc(-c3nc(-c4ccc(-c5ccccc5)cc4)nc(-c4cccc5oc6c(-c7cccc(-c8ccccc8)c7)cccc6c45)n3)cc2)cc1 ; c1ccc(-c2ccc(-c3nc(-c4cccc(-c5ccccc5)c4)nc(-c4cccc5oc6c(-c7cccc(-c8ccccc8)c7)cccc6c45)n3)cc2)cc1 ; c1ccc(-c2ccc(-c3nc(-c4cc5ccccc5c5ccccc45)nc(-c4cccc5oc6c(-c7cccc(-c8ccccc8)c7)cccc6c45)n3)cc2)cc1] 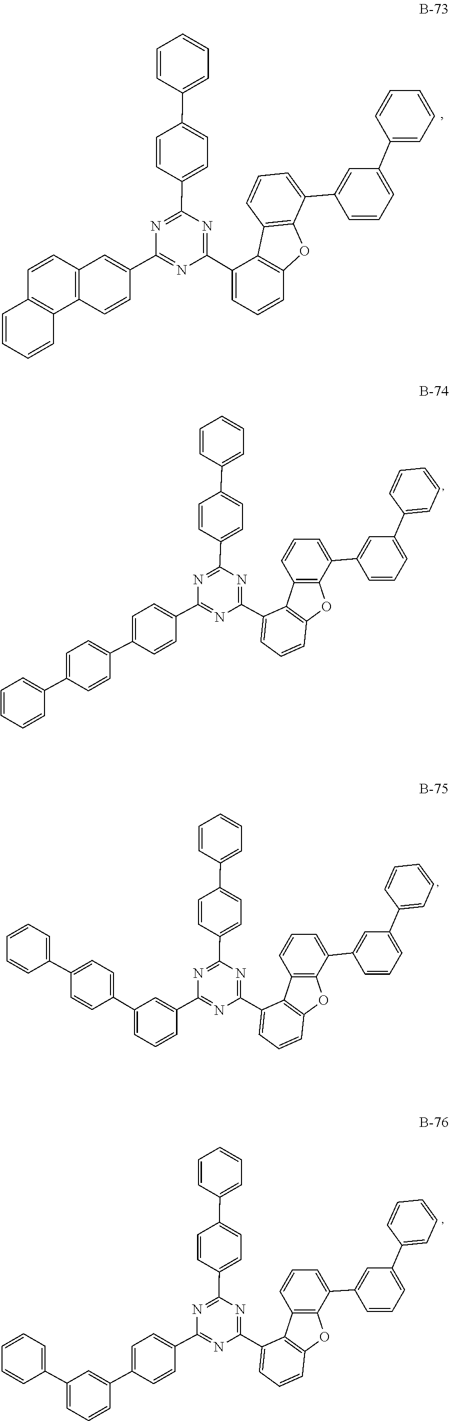 [SMILES: c1ccc(-c2ccc(-c3nc(-c4ccc5c(ccc6ccccc65)c4)nc(-c4cccc5oc6c(-c7cccc(-c8ccccc8)c7)cccc6c45)n3)cc2)cc1 ; c1ccc(-c2ccc(-c3ccc(-c4nc(-c5ccc(-c6ccccc6)cc5)nc(-c5cccc6oc7c(-c8cccc(-c9ccccc9)c8)cccc7c56)n4)cc3)cc2)cc1 ; c1ccc(-c2ccc(-c3cccc(-c4nc(-c5ccc(-c6ccccc6)cc5)nc(-c5cccc6oc7c(-c8cccc(-c9ccccc9)c8)cccc7c56)n4)c3)cc2)cc1 ; c1ccc(-c2ccc(-c3nc(-c4ccc(-c5cccc(-c6ccccc6)c5)cc4)nc(-c4cccc5oc6c(-c7cccc(-c8ccccc8)c7)cccc6c45)n3)cc2)cc1] 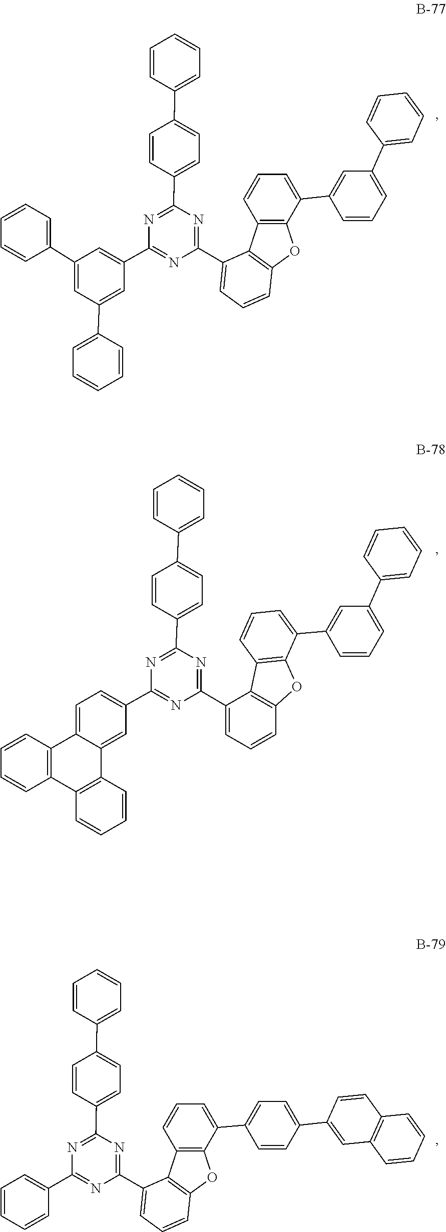 [SMILES: c1ccc(-c2ccc(-c3nc(-c4cc(-c5ccccc5)cc(-c5ccccc5)c4)nc(-c4cccc5oc6c(-c7cccc(-c8ccccc8)c7)cccc6c45)n3)cc2)cc1 ; c1ccc(-c2ccc(-c3nc(-c4ccc5c6ccccc6c6ccccc6c5c4)nc(-c4cccc5oc6c(-c7cccc(-c8ccccc8)c7)cccc6c45)n3)cc2)cc1 ; c1ccc(-c2ccc(-c3nc(-c4ccccc4)nc(-c4cccc5oc6c(-c7ccc(-c8ccc9ccccc9c8)cc7)cccc6c45)n3)cc2)cc1] 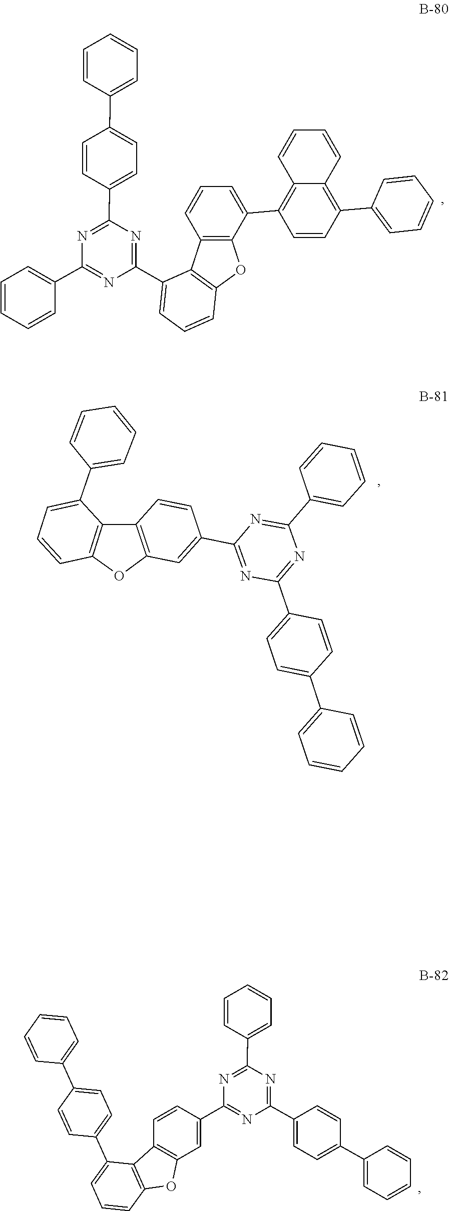 [SMILES: c1ccc(-c2ccc(-c3nc(-c4ccccc4)nc(-c4cccc5oc6c(-c7ccc(-c8ccccc8)c8ccccc78)cccc6c45)n3)cc2)cc1 ; c1ccc(-c2ccc(-c3nc(-c4ccccc4)nc(-c4ccc5c(c4)oc4cccc(-c6ccccc6)c45)n3)cc2)cc1 ; c1ccc(-c2ccc(-c3nc(-c4ccccc4)nc(-c4ccc5c(c4)oc4cccc(-c6ccc(-c7ccccc7)cc6)c45)n3)cc2)cc1] 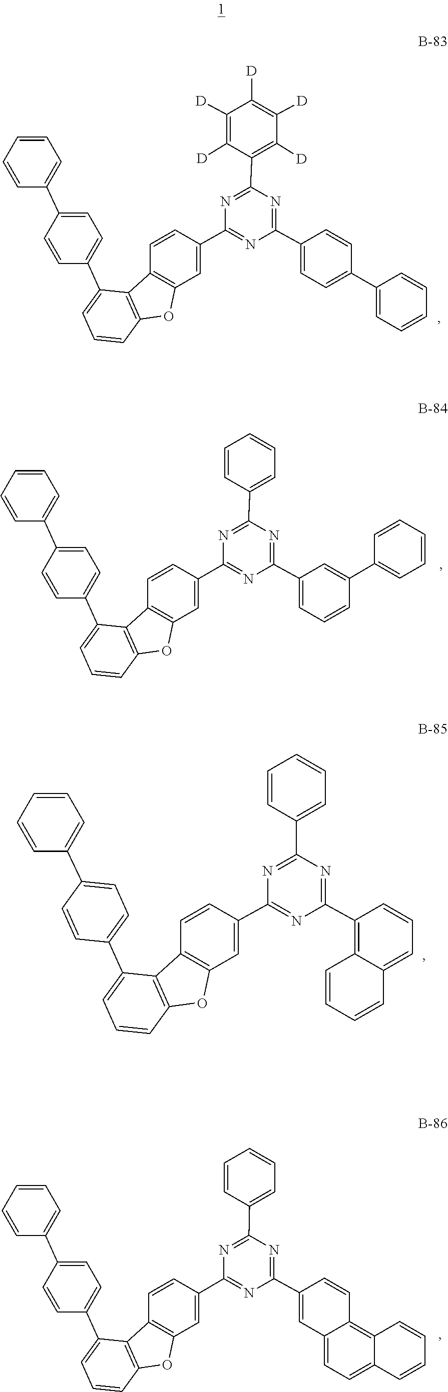 [SMILES: [2H]c1c([2H])c([2H])c(-c2nc(-c3ccc(-c4ccccc4)cc3)nc(-c3ccc4c(c3)oc3cccc(-c5ccc(-c6ccccc6)cc5)c34)n2)c([2H])c1[2H] ; c1ccc(-c2ccc(-c3cccc4oc5cc(-c6nc(-c7ccccc7)nc(-c7cccc(-c8ccccc8)c7)n6)ccc5c34)cc2)cc1 ; c1ccc(-c2ccc(-c3cccc4oc5cc(-c6nc(-c7ccccc7)nc(-c7cccc8ccccc78)n6)ccc5c34)cc2)cc1 ; c1ccc(-c2ccc(-c3cccc4oc5cc(-c6nc(-c7ccccc7)nc(-c7ccc8c(ccc9ccccc98)c7)n6)ccc5c34)cc2)cc1] 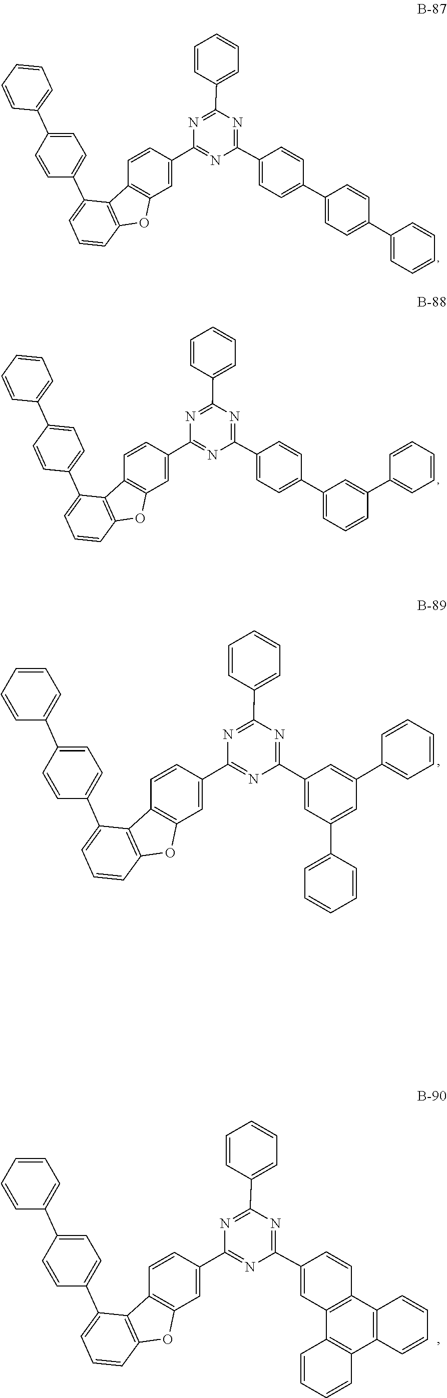 [SMILES: c1ccc(-c2ccc(-c3ccc(-c4nc(-c5ccccc5)nc(-c5ccc6c(c5)oc5cccc(-c7ccc(-c8ccccc8)cc7)c56)n4)cc3)cc2)cc1 ; c1ccc(-c2ccc(-c3cccc4oc5cc(-c6nc(-c7ccccc7)nc(-c7ccc(-c8cccc(-c9ccccc9)c8)cc7)n6)ccc5c34)cc2)cc1 ; c1ccc(-c2ccc(-c3cccc4oc5cc(-c6nc(-c7ccccc7)nc(-c7cc(-c8ccccc8)cc(-c8ccccc8)c7)n6)ccc5c34)cc2)cc1 ; c1ccc(-c2ccc(-c3cccc4oc5cc(-c6nc(-c7ccccc7)nc(-c7ccc8c9ccccc9c9ccccc9c8c7)n6)ccc5c34)cc2)cc1] 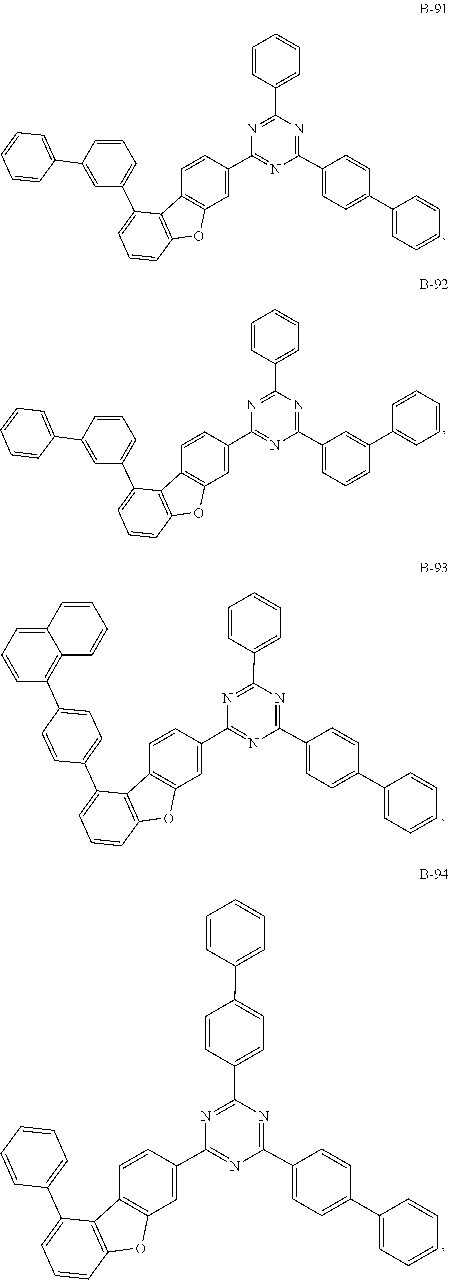 [SMILES: c1ccc(-c2ccc(-c3nc(-c4ccccc4)nc(-c4ccc5c(c4)oc4cccc(-c6cccc(-c7ccccc7)c6)c45)n3)cc2)cc1 ; c1ccc(-c2cccc(-c3nc(-c4ccccc4)nc(-c4ccc5c(c4)oc4cccc(-c6cccc(-c7ccccc7)c6)c45)n3)c2)cc1 ; c1ccc(-c2ccc(-c3nc(-c4ccccc4)nc(-c4ccc5c(c4)oc4cccc(-c6ccc(-c7cccc8ccccc78)cc6)c45)n3)cc2)cc1 ; c1ccc(-c2ccc(-c3nc(-c4ccc(-c5ccccc5)cc4)nc(-c4ccc5c(c4)oc4cccc(-c6ccccc6)c45)n3)cc2)cc1] 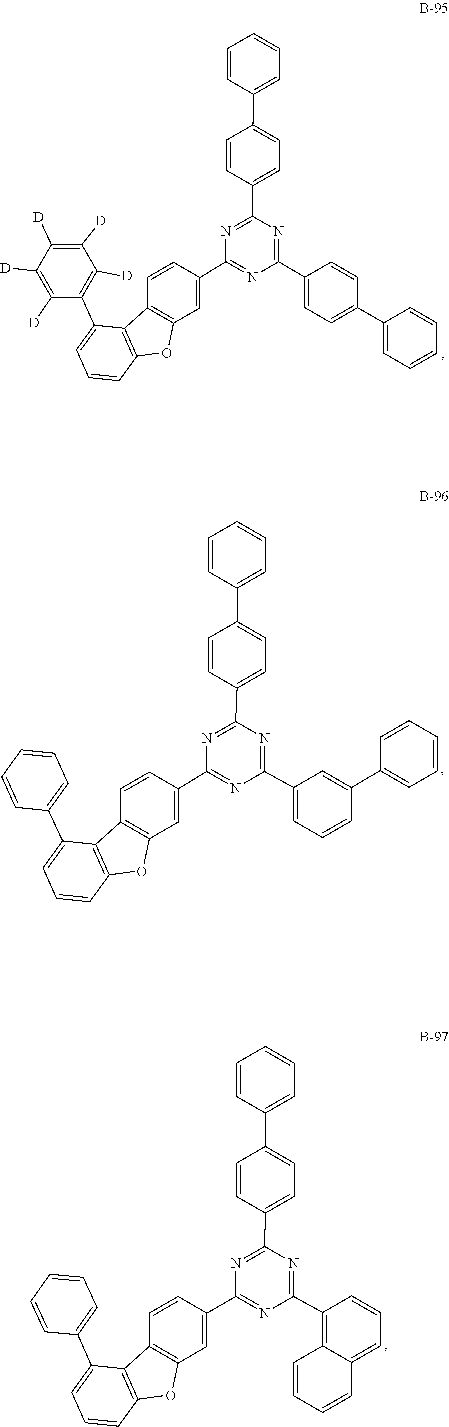 [SMILES: [2H]c1c([2H])c([2H])c(-c2cccc3oc4cc(-c5nc(-c6ccc(-c7ccccc7)cc6)nc(-c6ccc(-c7ccccc7)cc6)n5)ccc4c23)c([2H])c1[2H] ; c1ccc(-c2ccc(-c3nc(-c4cccc(-c5ccccc5)c4)nc(-c4ccc5c(c4)oc4cccc(-c6ccccc6)c45)n3)cc2)cc1 ; c1ccc(-c2ccc(-c3nc(-c4ccc5c(c4)oc4cccc(-c6ccccc6)c45)nc(-c4cccc5ccccc45)n3)cc2)cc1] 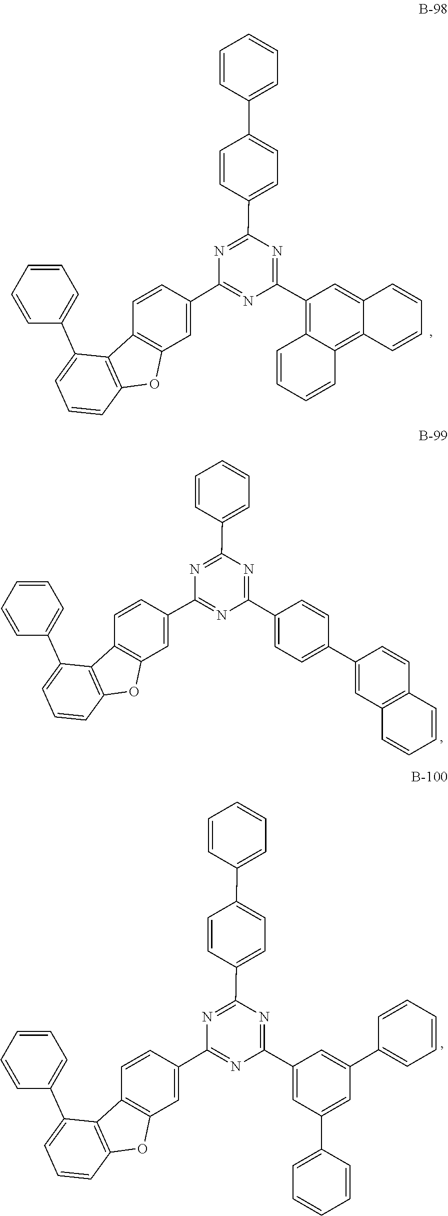 [SMILES: c1ccc(-c2ccc(-c3nc(-c4ccc5c(c4)oc4cccc(-c6ccccc6)c45)nc(-c4cc5ccccc5c5ccccc45)n3)cc2)cc1 ; c1ccc(-c2nc(-c3ccc(-c4ccc5ccccc5c4)cc3)nc(-c3ccc4c(c3)oc3cccc(-c5ccccc5)c34)n2)cc1 ; c1ccc(-c2ccc(-c3nc(-c4cc(-c5ccccc5)cc(-c5ccccc5)c4)nc(-c4ccc5c(c4)oc4cccc(-c6ccccc6)c45)n3)cc2)cc1] 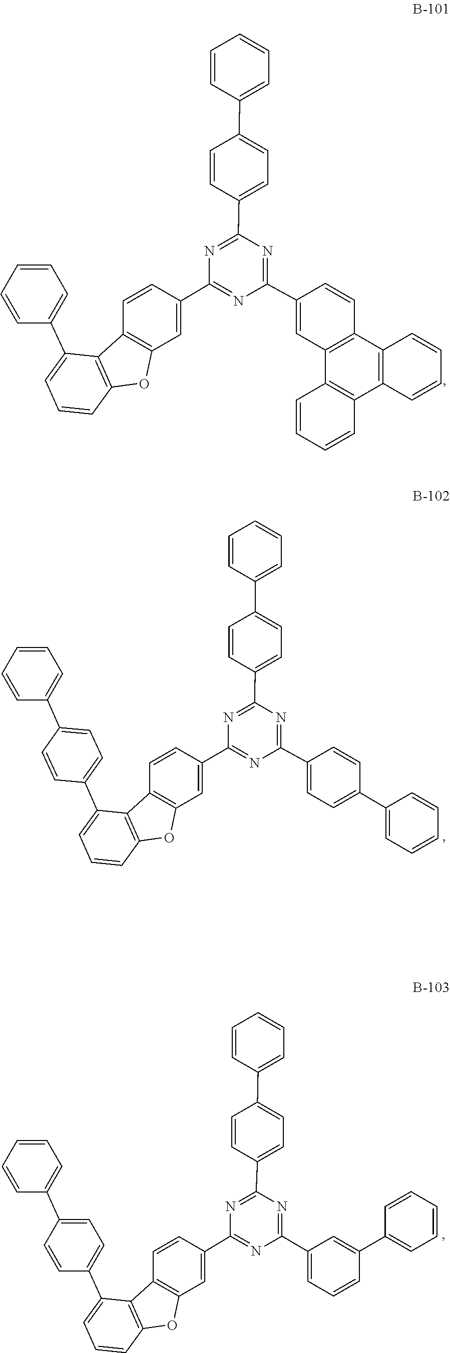 [SMILES: c1ccc(-c2ccc(-c3nc(-c4ccc5c(c4)oc4cccc(-c6ccccc6)c45)nc(-c4ccc5c6ccccc6c6ccccc6c5c4)n3)cc2)cc1 ; c1ccc(-c2ccc(-c3nc(-c4ccc(-c5ccccc5)cc4)nc(-c4ccc5c(c4)oc4cccc(-c6ccc(-c7ccccc7)cc6)c45)n3)cc2)cc1 ; c1ccc(-c2ccc(-c3nc(-c4cccc(-c5ccccc5)c4)nc(-c4ccc5c(c4)oc4cccc(-c6ccc(-c7ccccc7)cc6)c45)n3)cc2)cc1] 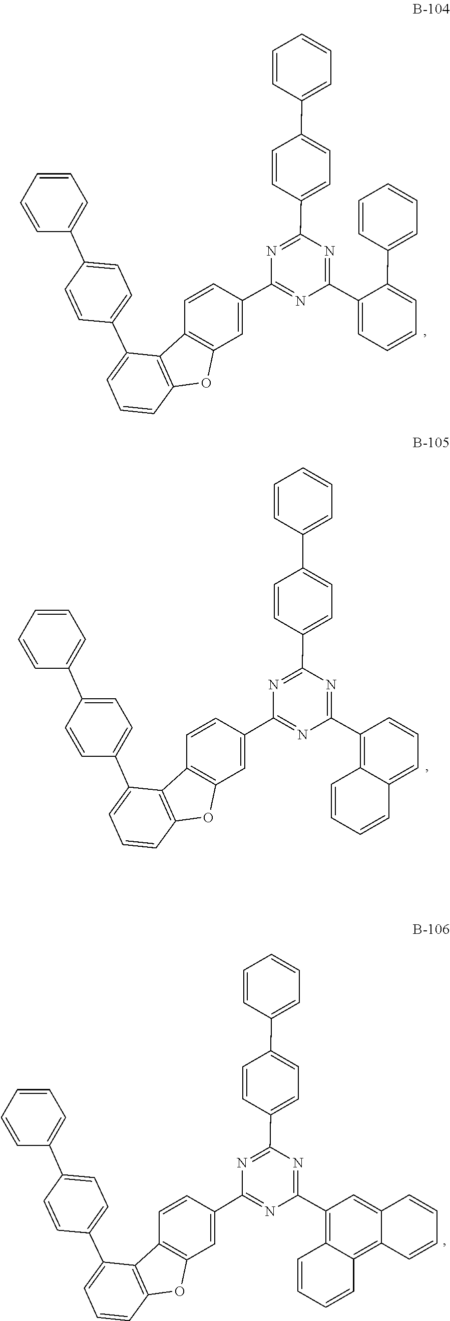 [SMILES: c1ccc(-c2ccc(-c3nc(-c4ccc5c(c4)oc4cccc(-c6ccc(-c7ccccc7)cc6)c45)nc(-c4ccccc4-c4ccccc4)n3)cc2)cc1 ; c1ccc(-c2ccc(-c3nc(-c4ccc5c(c4)oc4cccc(-c6ccc(-c7ccccc7)cc6)c45)nc(-c4cccc5ccccc45)n3)cc2)cc1 ; c1ccc(-c2ccc(-c3nc(-c4ccc5c(c4)oc4cccc(-c6ccc(-c7ccccc7)cc6)c45)nc(-c4cc5ccccc5c5ccccc45)n3)cc2)cc1] 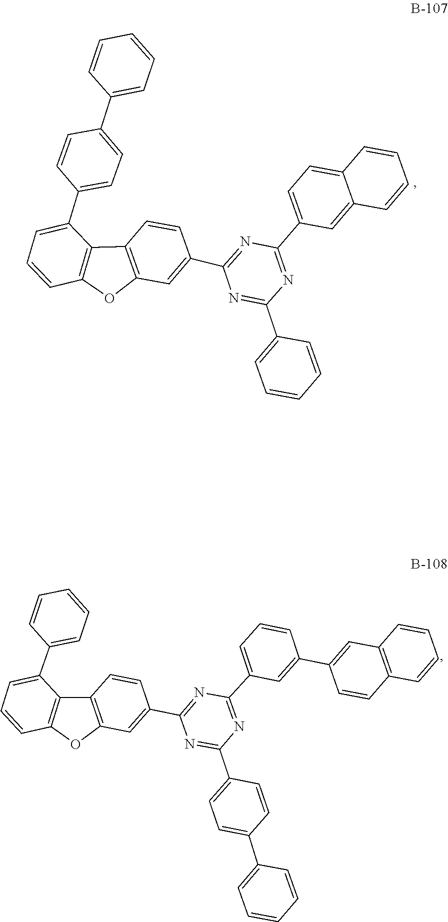 [SMILES: c1ccc(-c2ccc(-c3cccc4oc5cc(-c6nc(-c7ccccc7)nc(-c7ccc8ccccc8c7)n6)ccc5c34)cc2)cc1 ; c1ccc(-c2ccc(-c3nc(-c4cccc(-c5ccc6ccccc6c5)c4)nc(-c4ccc5c(c4)oc4cccc(-c6ccccc6)c45)n3)cc2)cc1] 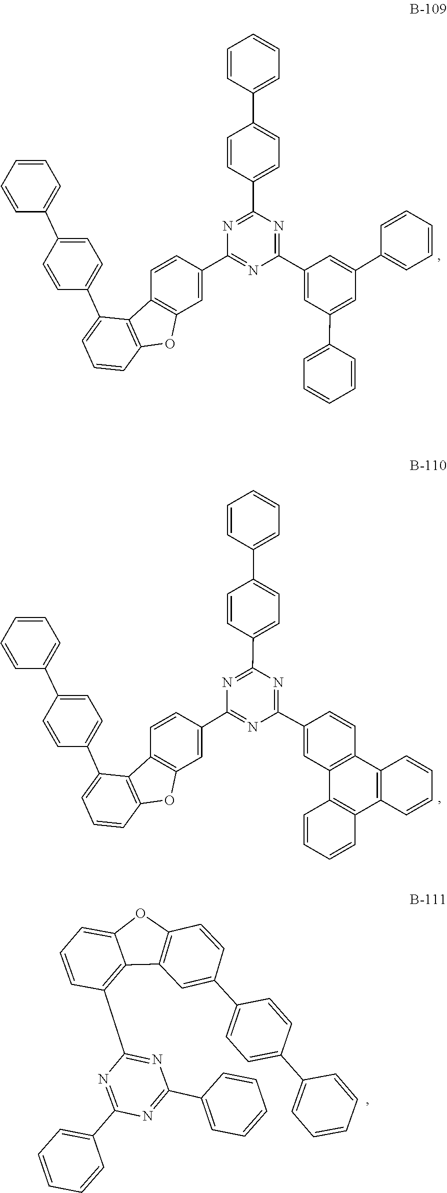 [SMILES: c1ccc(-c2ccc(-c3nc(-c4cc(-c5ccccc5)cc(-c5ccccc5)c4)nc(-c4ccc5c(c4)oc4cccc(-c6ccc(-c7ccccc7)cc6)c45)n3)cc2)cc1 ; c1ccc(-c2ccc(-c3nc(-c4ccc5c(c4)oc4cccc(-c6ccc(-c7ccccc7)cc6)c45)nc(-c4ccc5c6ccccc6c6ccccc6c5c4)n3)cc2)cc1 ; c1ccc(-c2ccc(-c3ccc4oc5cccc(-c6nc(-c7ccccc7)nc(-c7ccccc7)n6)c5c4c3)cc2)cc1] 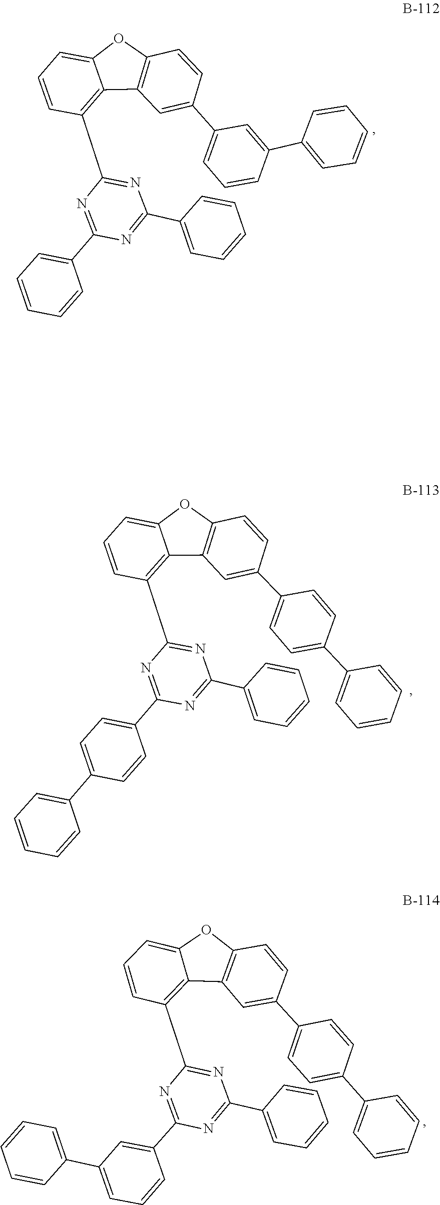 [SMILES: c1ccc(-c2cccc(-c3ccc4oc5cccc(-c6nc(-c7ccccc7)nc(-c7ccccc7)n6)c5c4c3)c2)cc1 ; c1ccc(-c2ccc(-c3ccc4oc5cccc(-c6nc(-c7ccccc7)nc(-c7ccc(-c8ccccc8)cc7)n6)c5c4c3)cc2)cc1 ; c1ccc(-c2ccc(-c3ccc4oc5cccc(-c6nc(-c7ccccc7)nc(-c7cccc(-c8ccccc8)c7)n6)c5c4c3)cc2)cc1] 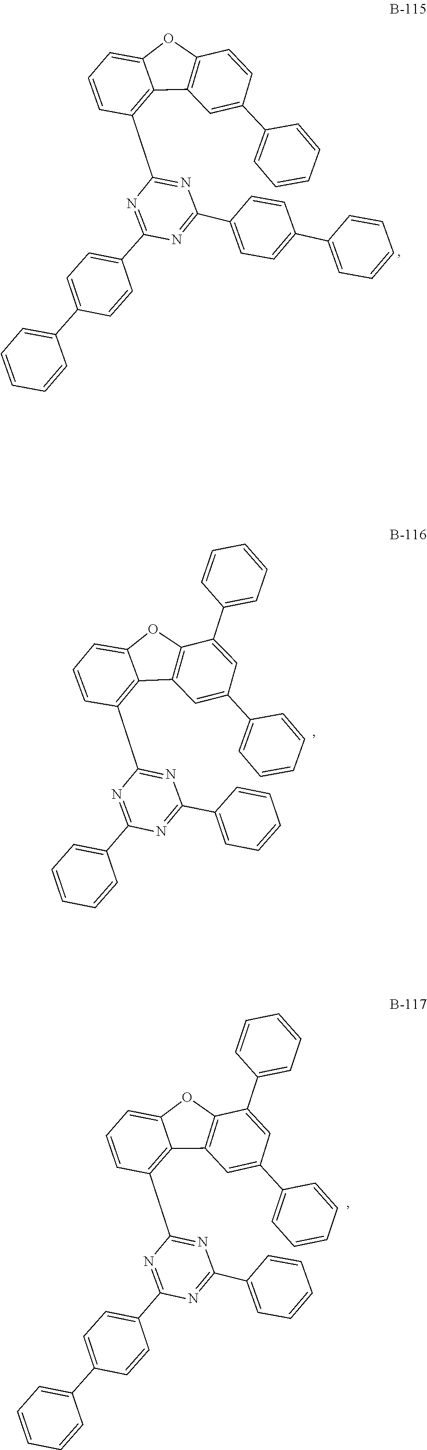 [SMILES: c1ccc(-c2ccc(-c3nc(-c4ccc(-c5ccccc5)cc4)nc(-c4cccc5oc6ccc(-c7ccccc7)cc6c45)n3)cc2)cc1 ; c1ccc(-c2cc(-c3ccccc3)c3oc4cccc(-c5nc(-c6ccccc6)nc(-c6ccccc6)n5)c4c3c2)cc1 ; c1ccc(-c2ccc(-c3nc(-c4ccccc4)nc(-c4cccc5oc6c(-c7ccccc7)cc(-c7ccccc7)cc6c45)n3)cc2)cc1] 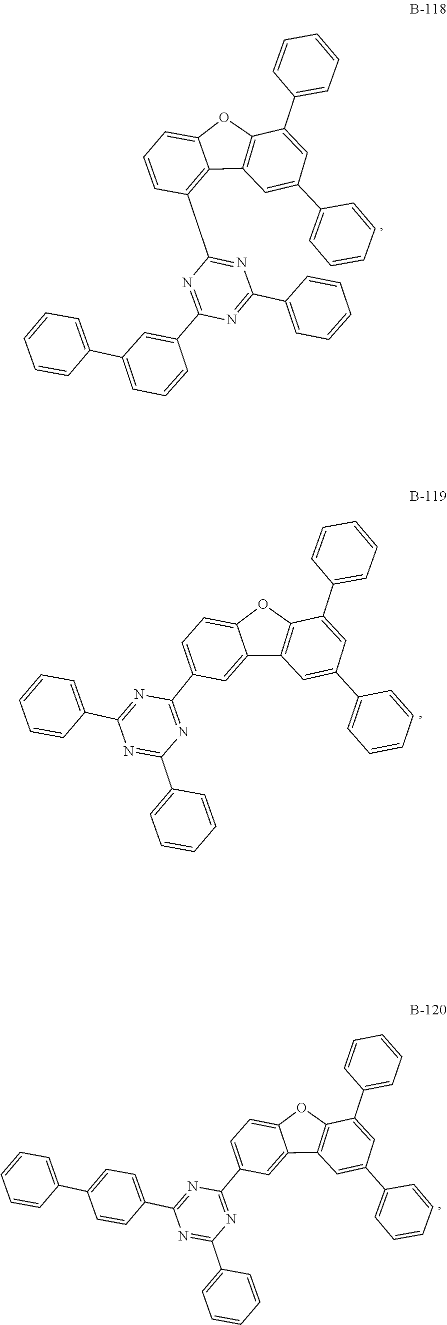 [SMILES: c1ccc(-c2cccc(-c3nc(-c4ccccc4)nc(-c4cccc5oc6c(-c7ccccc7)cc(-c7ccccc7)cc6c45)n3)c2)cc1 ; c1ccc(-c2cc(-c3ccccc3)c3oc4ccc(-c5nc(-c6ccccc6)nc(-c6ccccc6)n5)cc4c3c2)cc1 ; c1ccc(-c2ccc(-c3nc(-c4ccccc4)nc(-c4ccc5oc6c(-c7ccccc7)cc(-c7ccccc7)cc6c5c4)n3)cc2)cc1] 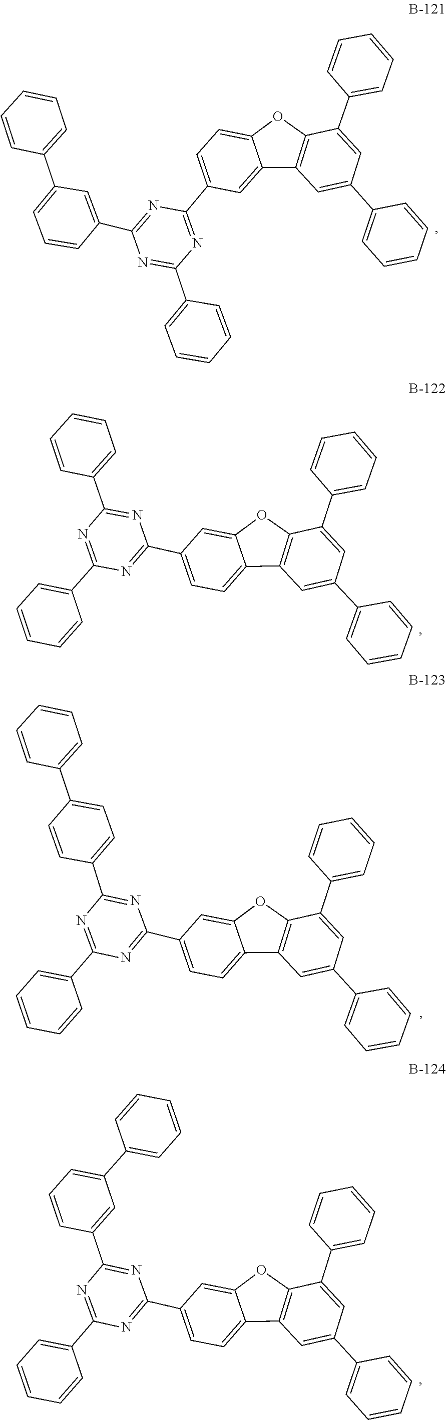 [SMILES: c1ccc(-c2cccc(-c3nc(-c4ccccc4)nc(-c4ccc5oc6c(-c7ccccc7)cc(-c7ccccc7)cc6c5c4)n3)c2)cc1 ; c1ccc(-c2cc(-c3ccccc3)c3oc4cc(-c5nc(-c6ccccc6)nc(-c6ccccc6)n5)ccc4c3c2)cc1 ; c1ccc(-c2ccc(-c3nc(-c4ccccc4)nc(-c4ccc5c(c4)oc4c(-c6ccccc6)cc(-c6ccccc6)cc45)n3)cc2)cc1 ; c1ccc(-c2cccc(-c3nc(-c4ccccc4)nc(-c4ccc5c(c4)oc4c(-c6ccccc6)cc(-c6ccccc6)cc45)n3)c2)cc1] 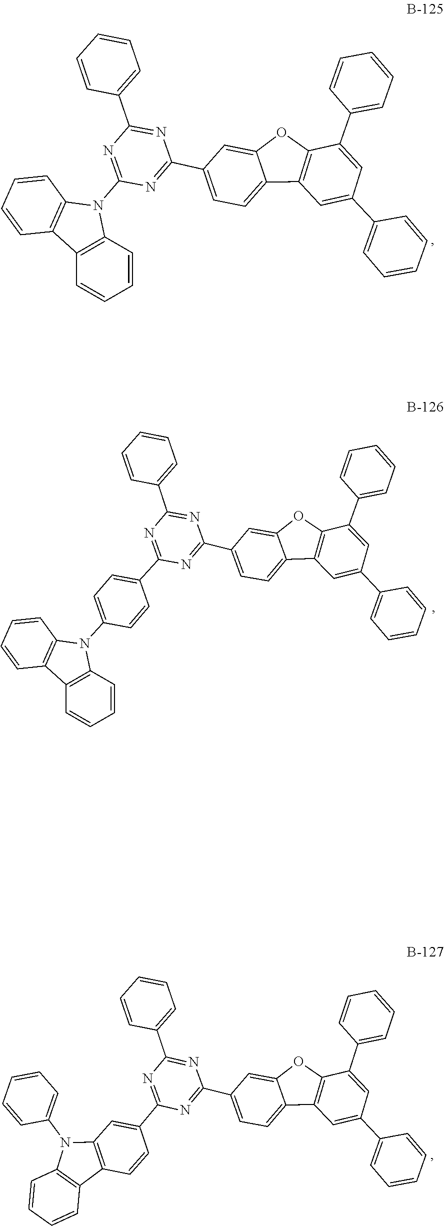 [SMILES: c1ccc(-c2cc(-c3ccccc3)c3oc4cc(-c5nc(-c6ccccc6)nc(-n6c7ccccc7c7ccccc76)n5)ccc4c3c2)cc1 ; c1ccc(-c2cc(-c3ccccc3)c3oc4cc(-c5nc(-c6ccccc6)nc(-c6ccc(-n7c8ccccc8c8ccccc87)cc6)n5)ccc4c3c2)cc1 ; c1ccc(-c2cc(-c3ccccc3)c3oc4cc(-c5nc(-c6ccccc6)nc(-c6ccc7c8ccccc8n(-c8ccccc8)c7c6)n5)ccc4c3c2)cc1] 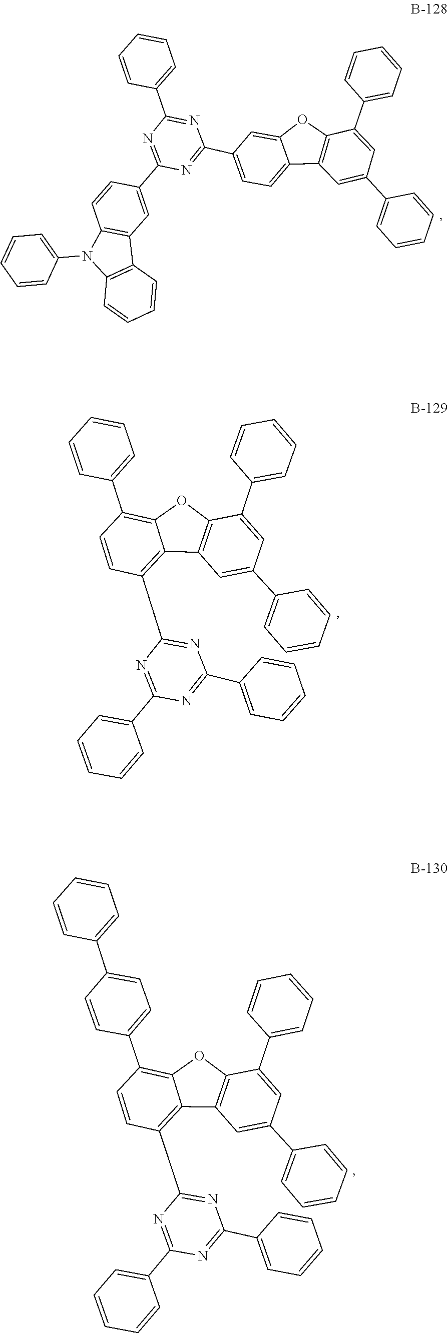 [SMILES: c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1 ; c1ccc(-c2cc(-c3ccccc3)c3oc4c(-c5ccccc5)ccc(-c5nc(-c6ccccc6)nc(-c6ccccc6)n5)c4c3c2)cc1 ; c1ccc(-c2ccc(-c3ccc(-c4nc(-c5ccccc5)nc(-c5ccccc5)n4)c4c3oc3c(-c5ccccc5)cc(-c5ccccc5)cc34)cc2)cc1] 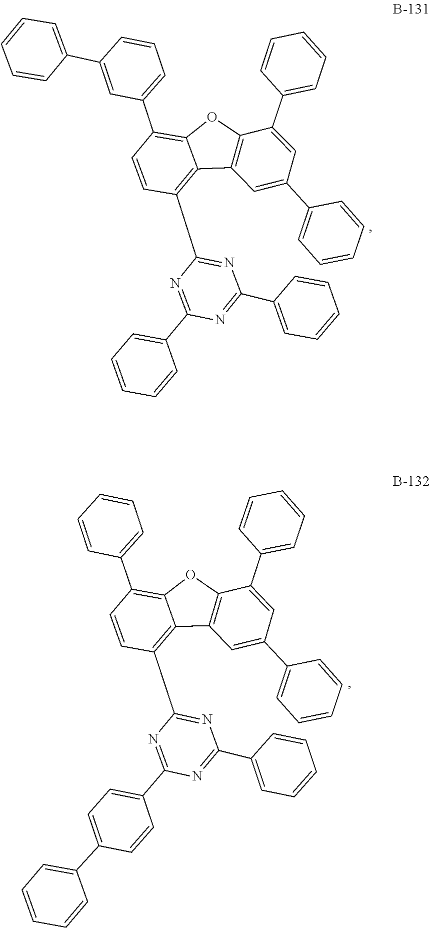 [SMILES: c1ccc(-c2cccc(-c3ccc(-c4nc(-c5ccccc5)nc(-c5ccccc5)n4)c4c3oc3c(-c5ccccc5)cc(-c5ccccc5)cc34)c2)cc1 ; c1ccc(-c2ccc(-c3nc(-c4ccccc4)nc(-c4ccc(-c5ccccc5)c5oc6c(-c7ccccc7)cc(-c7ccccc7)cc6c45)n3)cc2)cc1] 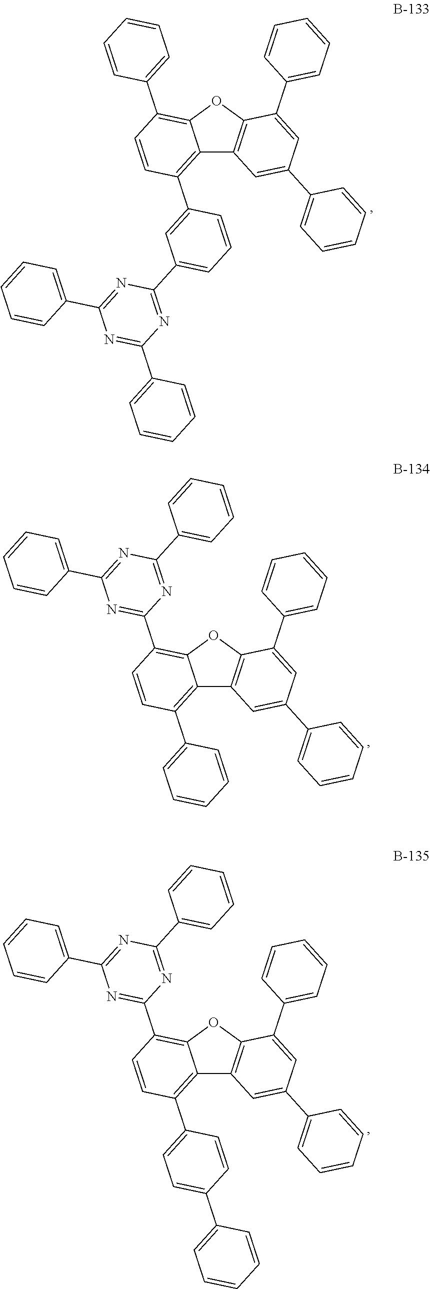 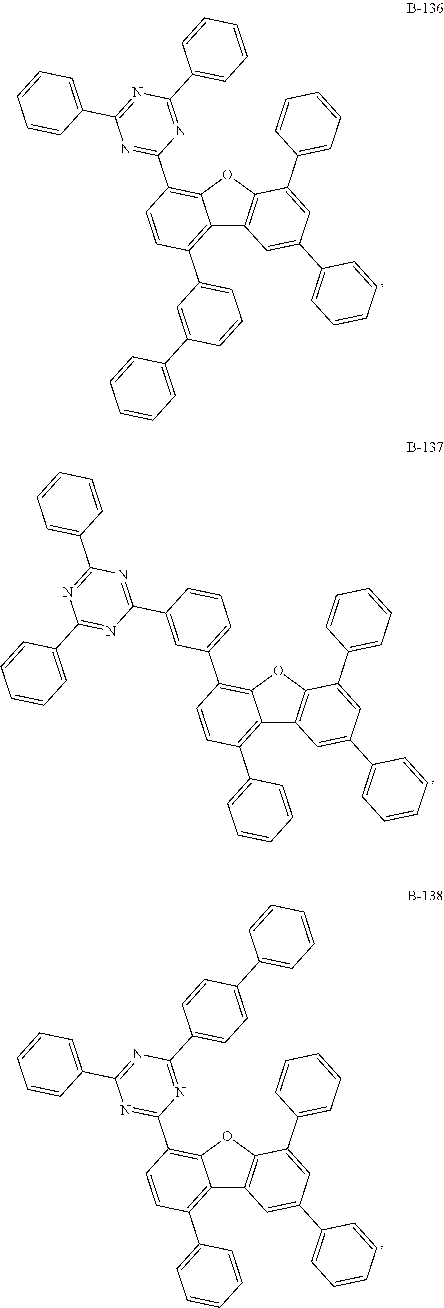 [SMILES: c1ccc(-c2cccc(-c3ccc(-c4nc(-c5ccccc5)nc(-c5ccccc5)n4)c4oc5c(-c6ccccc6)cc(-c6ccccc6)cc5c34)c2)cc1 ; c1ccc(-c2cc(-c3ccccc3)c3oc4c(-c5cccc(-c6nc(-c7ccccc7)nc(-c7ccccc7)n6)c5)ccc(-c5ccccc5)c4c3c2)cc1 ; c1ccc(-c2ccc(-c3nc(-c4ccccc4)nc(-c4ccc(-c5ccccc5)c5c4oc4c(-c6ccccc6)cc(-c6ccccc6)cc45)n3)cc2)cc1] 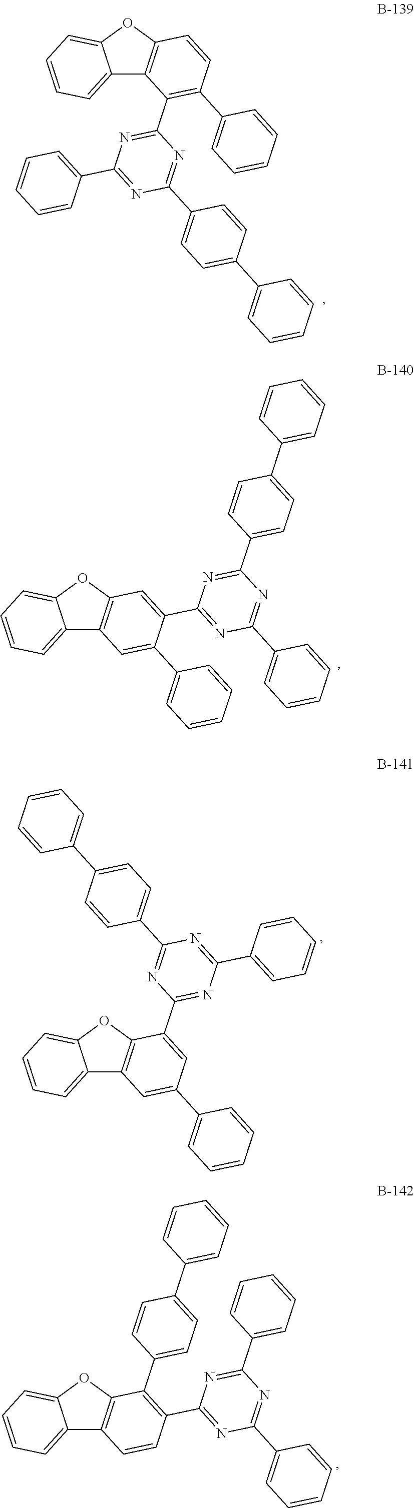 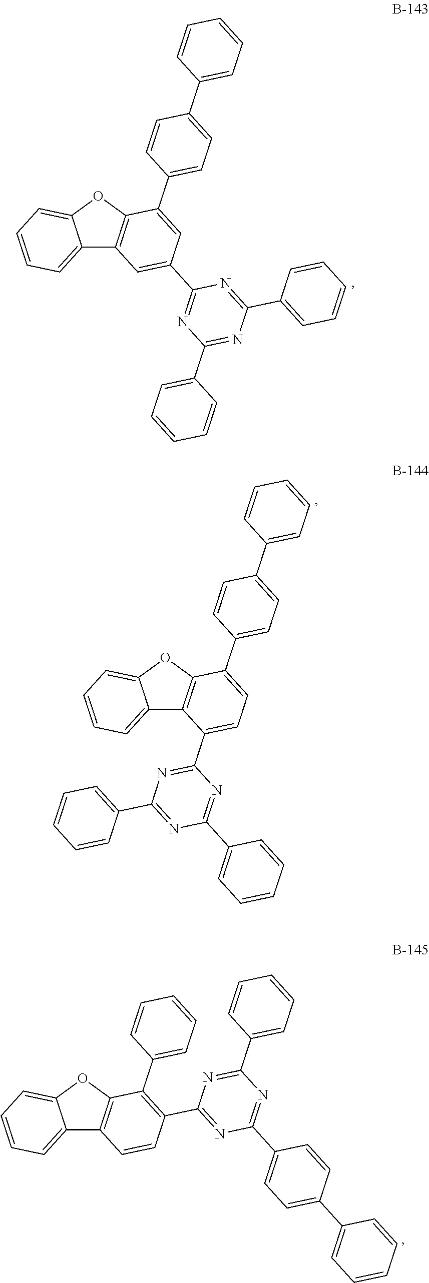 [SMILES: c1ccc(-c2ccc(-c3cc(-c4nc(-c5ccccc5)nc(-c5ccccc5)n4)cc4c3oc3ccccc34)cc2)cc1 ; c1ccc(-c2ccc(-c3ccc(-c4nc(-c5ccccc5)nc(-c5ccccc5)n4)c4c3oc3ccccc34)cc2)cc1 ; c1ccc(-c2ccc(-c3nc(-c4ccccc4)nc(-c4ccc5c(oc6ccccc65)c4-c4ccccc4)n3)cc2)cc1] 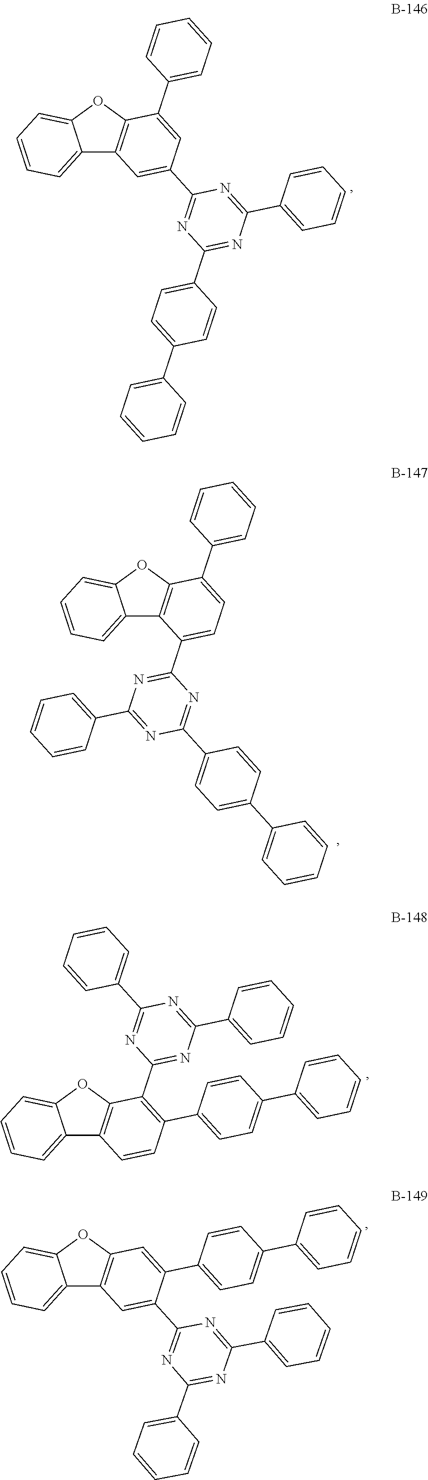 [SMILES: c1ccc(-c2ccc(-c3nc(-c4ccccc4)nc(-c4cc(-c5ccccc5)c5oc6ccccc6c5c4)n3)cc2)cc1 ; c1ccc(-c2ccc(-c3nc(-c4ccccc4)nc(-c4ccc(-c5ccccc5)c5oc6ccccc6c45)n3)cc2)cc1 ; c1ccc(-c2ccc(-c3ccc4c(oc5ccccc54)c3-c3nc(-c4ccccc4)nc(-c4ccccc4)n3)cc2)cc1 ; c1ccc(-c2ccc(-c3cc4oc5ccccc5c4cc3-c3nc(-c4ccccc4)nc(-c4ccccc4)n3)cc2)cc1] 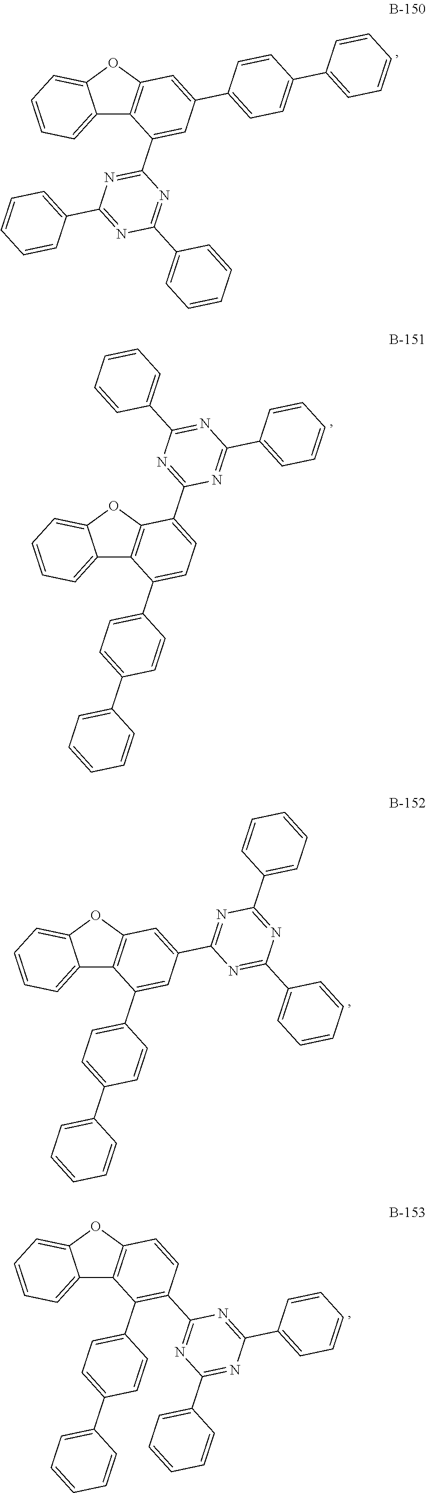 [SMILES: c1ccc(-c2ccc(-c3cc(-c4nc(-c5ccccc5)nc(-c5ccccc5)n4)c4c(c3)oc3ccccc34)cc2)cc1 ; c1ccc(-c2ccc(-c3ccc(-c4nc(-c5ccccc5)nc(-c5ccccc5)n4)c4oc5ccccc5c34)cc2)cc1 ; c1ccc(-c2ccc(-c3cc(-c4nc(-c5ccccc5)nc(-c5ccccc5)n4)cc4oc5ccccc5c34)cc2)cc1 ; c1ccc(-c2ccc(-c3c(-c4nc(-c5ccccc5)nc(-c5ccccc5)n4)ccc4oc5ccccc5c34)cc2)cc1] 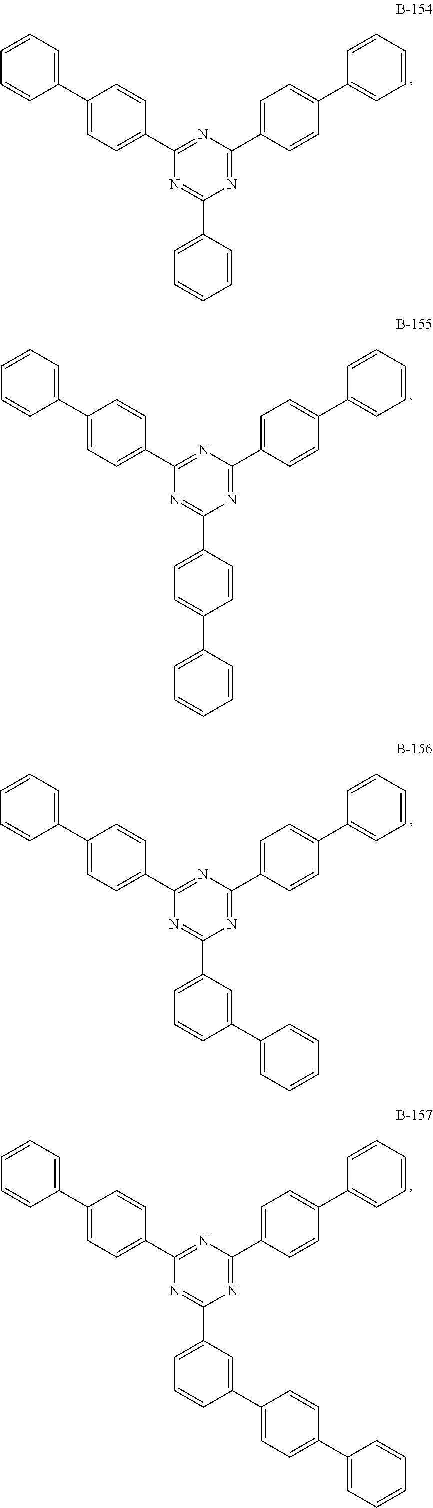 [SMILES: c1ccc(-c2ccc(-c3nc(-c4ccccc4)nc(-c4ccc(-c5ccccc5)cc4)n3)cc2)cc1 ; c1ccc(-c2ccc(-c3nc(-c4ccc(-c5ccccc5)cc4)nc(-c4ccc(-c5ccccc5)cc4)n3)cc2)cc1 ; c1ccc(-c2ccc(-c3nc(-c4ccc(-c5ccccc5)cc4)nc(-c4cccc(-c5ccccc5)c4)n3)cc2)cc1 ; c1ccc(-c2ccc(-c3cccc(-c4nc(-c5ccc(-c6ccccc6)cc5)nc(-c5ccc(-c6ccccc6)cc5)n4)c3)cc2)cc1] 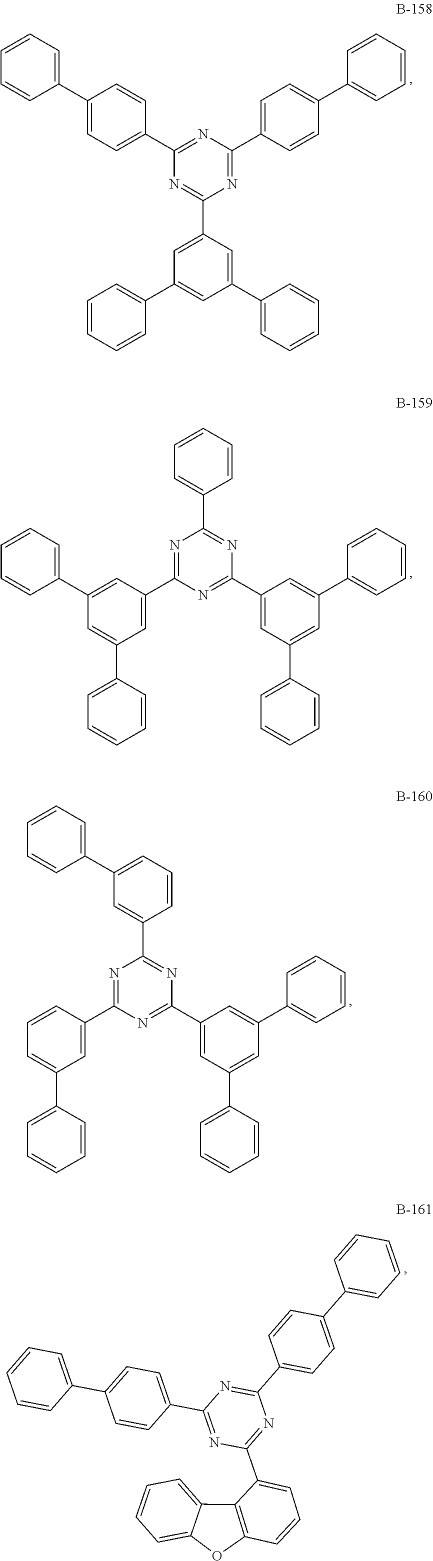 [SMILES: c1ccc(-c2ccc(-c3nc(-c4ccc(-c5ccccc5)cc4)nc(-c4cc(-c5ccccc5)cc(-c5ccccc5)c4)n3)cc2)cc1 ; c1ccc(-c2cc(-c3ccccc3)cc(-c3nc(-c4ccccc4)nc(-c4cc(-c5ccccc5)cc(-c5ccccc5)c4)n3)c2)cc1 ; c1ccc(-c2cccc(-c3nc(-c4cccc(-c5ccccc5)c4)nc(-c4cc(-c5ccccc5)cc(-c5ccccc5)c4)n3)c2)cc1 ; c1ccc(-c2ccc(-c3nc(-c4ccc(-c5ccccc5)cc4)nc(-c4cccc5oc6ccccc6c45)n3)cc2)cc1] 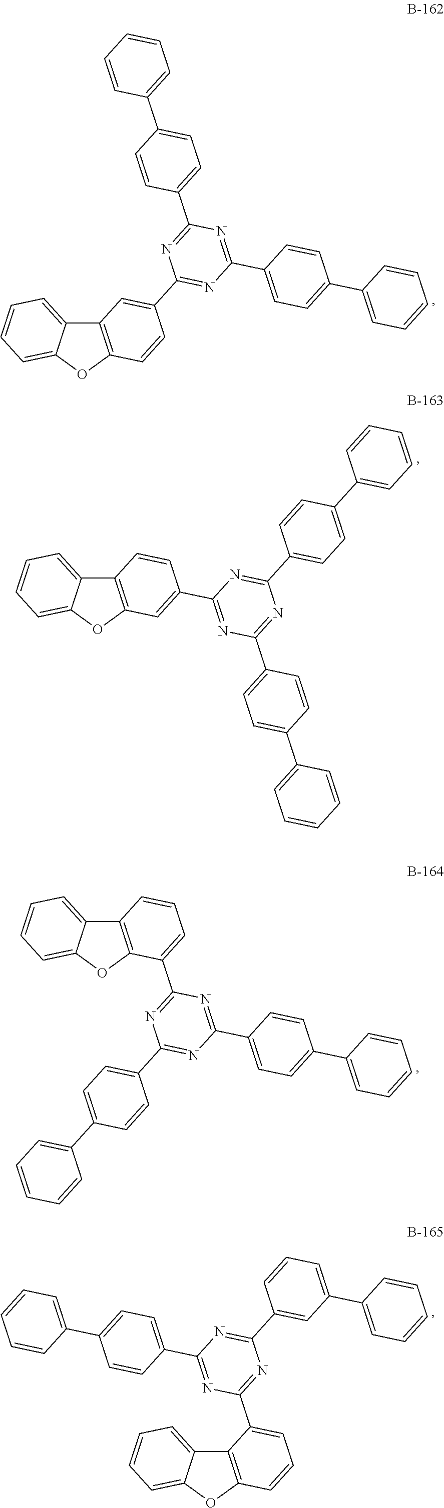 [SMILES: c1ccc(-c2ccc(-c3nc(-c4ccc(-c5ccccc5)cc4)nc(-c4ccc5oc6ccccc6c5c4)n3)cc2)cc1 ; c1ccc(-c2ccc(-c3nc(-c4ccc(-c5ccccc5)cc4)nc(-c4ccc5c(c4)oc4ccccc45)n3)cc2)cc1 ; c1ccc(-c2ccc(-c3nc(-c4ccc(-c5ccccc5)cc4)nc(-c4cccc5c4oc4ccccc45)n3)cc2)cc1 ; c1ccc(-c2ccc(-c3nc(-c4cccc(-c5ccccc5)c4)nc(-c4cccc5oc6ccccc6c45)n3)cc2)cc1] 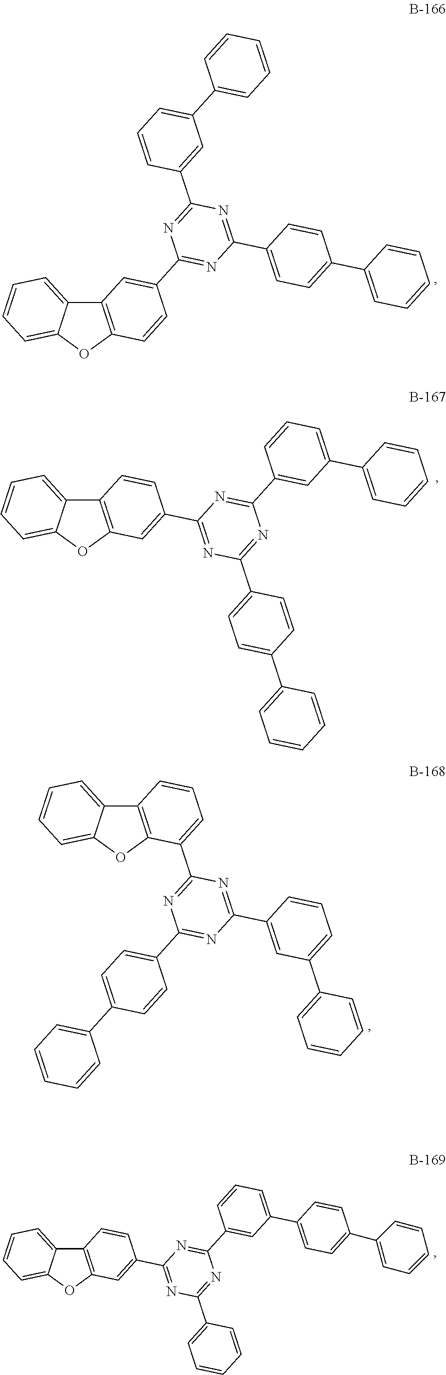 [SMILES: c1ccc(-c2ccc(-c3nc(-c4cccc(-c5ccccc5)c4)nc(-c4ccc5oc6ccccc6c5c4)n3)cc2)cc1 ; c1ccc(-c2ccc(-c3nc(-c4cccc(-c5ccccc5)c4)nc(-c4ccc5c(c4)oc4ccccc45)n3)cc2)cc1 ; c1ccc(-c2ccc(-c3nc(-c4cccc(-c5ccccc5)c4)nc(-c4cccc5c4oc4ccccc45)n3)cc2)cc1 ; c1ccc(-c2ccc(-c3cccc(-c4nc(-c5ccccc5)nc(-c5ccc6c(c5)oc5ccccc56)n4)c3)cc2)cc1] 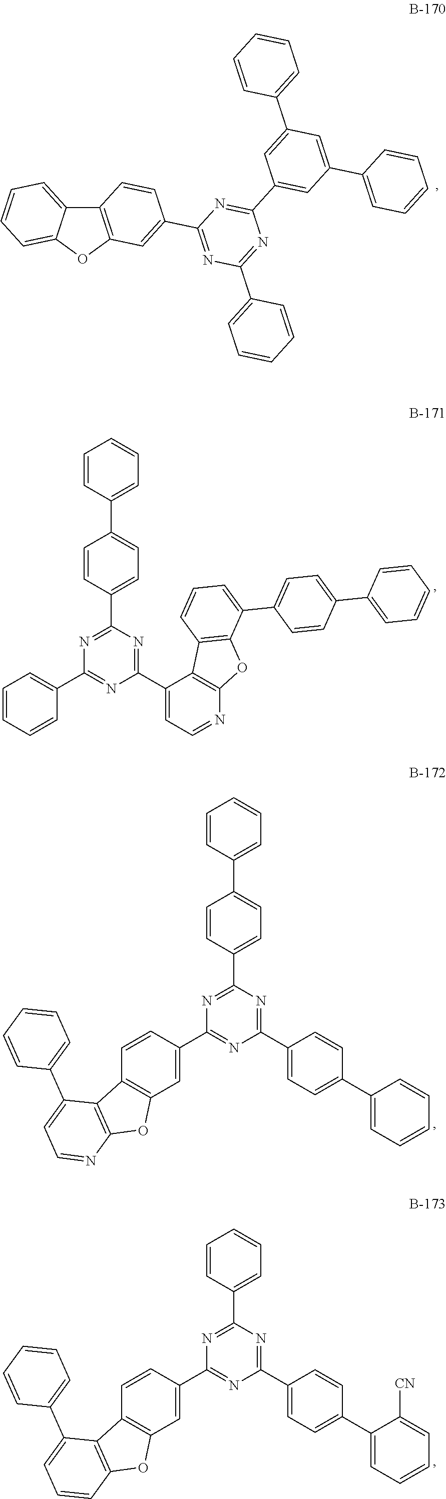 [SMILES: c1ccc(-c2cc(-c3ccccc3)cc(-c3nc(-c4ccccc4)nc(-c4ccc5c(c4)oc4ccccc45)n3)c2)cc1 ; c1ccc(-c2ccc(-c3nc(-c4ccccc4)nc(-c4ccnc5oc6c(-c7ccc(-c8ccccc8)cc7)cccc6c45)n3)cc2)cc1 ; c1ccc(-c2ccc(-c3nc(-c4ccc(-c5ccccc5)cc4)nc(-c4ccc5c(c4)oc4nccc(-c6ccccc6)c45)n3)cc2)cc1 ; N#Cc1ccccc1-c1ccc(-c2nc(-c3ccccc3)nc(-c3ccc4c(c3)oc3cccc(-c5ccccc5)c34)n2)cc1] 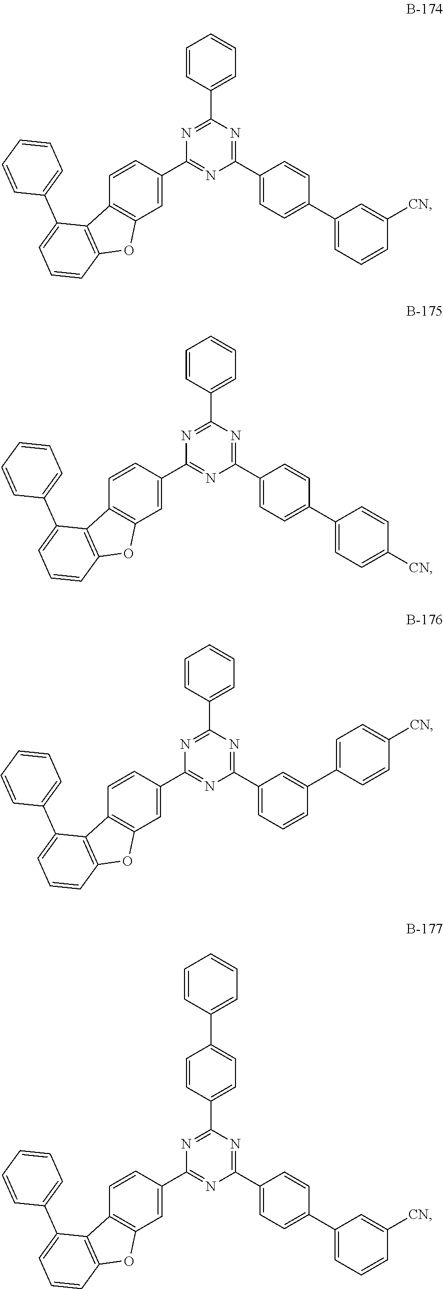 [SMILES: N#Cc1cccc(-c2ccc(-c3nc(-c4ccccc4)nc(-c4ccc5c(c4)oc4cccc(-c6ccccc6)c45)n3)cc2)c1 ; N#Cc1ccc(-c2ccc(-c3nc(-c4ccccc4)nc(-c4ccc5c(c4)oc4cccc(-c6ccccc6)c45)n3)cc2)cc1 ; N#Cc1ccc(-c2cccc(-c3nc(-c4ccccc4)nc(-c4ccc5c(c4)oc4cccc(-c6ccccc6)c45)n3)c2)cc1 ; N#Cc1cccc(-c2ccc(-c3nc(-c4ccc(-c5ccccc5)cc4)nc(-c4ccc5c(c4)oc4cccc(-c6ccccc6)c45)n3)cc2)c1] 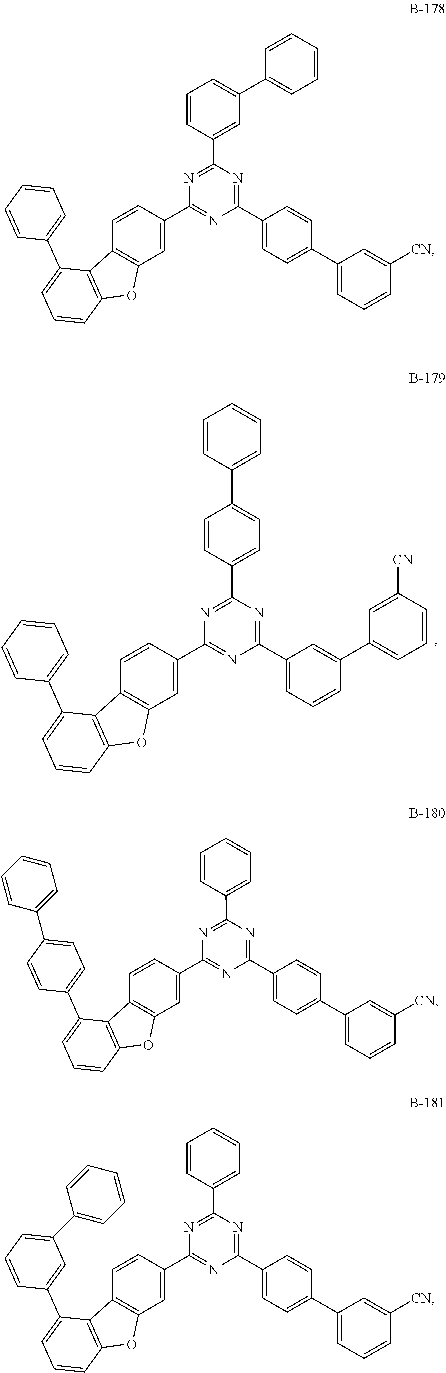 [SMILES: N#Cc1cccc(-c2ccc(-c3nc(-c4cccc(-c5ccccc5)c4)nc(-c4ccc5c(c4)oc4cccc(-c6ccccc6)c45)n3)cc2)c1 ; N#Cc1cccc(-c2cccc(-c3nc(-c4ccc(-c5ccccc5)cc4)nc(-c4ccc5c(c4)oc4cccc(-c6ccccc6)c45)n3)c2)c1 ; N#Cc1cccc(-c2ccc(-c3nc(-c4ccccc4)nc(-c4ccc5c(c4)oc4cccc(-c6ccc(-c7ccccc7)cc6)c45)n3)cc2)c1 ; N#Cc1cccc(-c2ccc(-c3nc(-c4ccccc4)nc(-c4ccc5c(c4)oc4cccc(-c6cccc(-c7ccccc7)c6)c45)n3)cc2)c1] 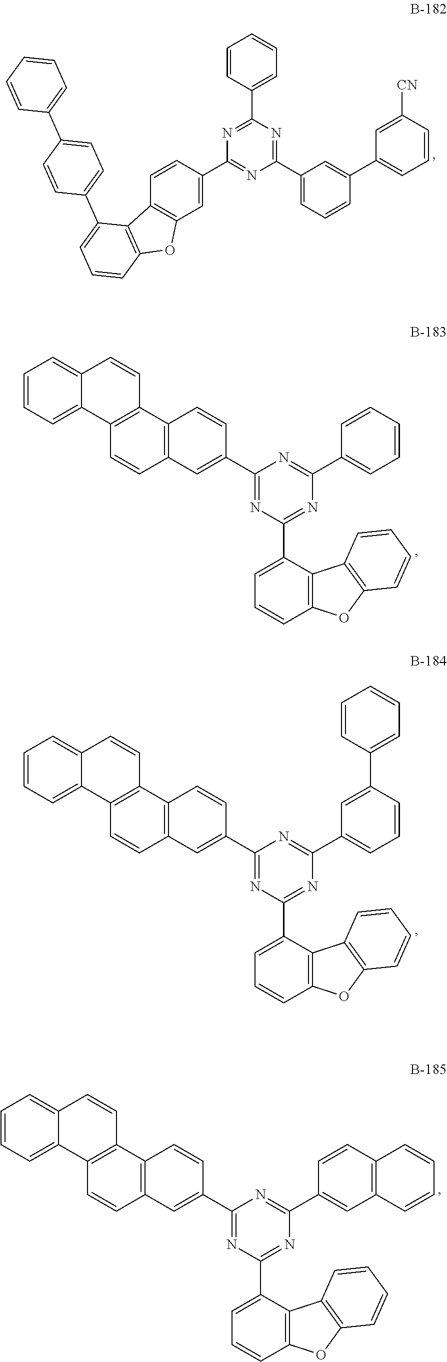 [SMILES: N#Cc1cccc(-c2cccc(-c3nc(-c4ccccc4)nc(-c4ccc5c(c4)oc4cccc(-c6ccc(-c7ccccc7)cc6)c45)n3)c2)c1 ; c1ccc(-c2nc(-c3ccc4c(ccc5c6ccccc6ccc45)c3)nc(-c3cccc4oc5ccccc5c34)n2)cc1 ; c1ccc(-c2cccc(-c3nc(-c4ccc5c(ccc6c7ccccc7ccc56)c4)nc(-c4cccc5oc6ccccc6c45)n3)c2)cc1 ; c1ccc2cc(-c3nc(-c4ccc5c(ccc6c7ccccc7ccc56)c4)nc(-c4cccc5oc6ccccc6c45)n3)ccc2c1] 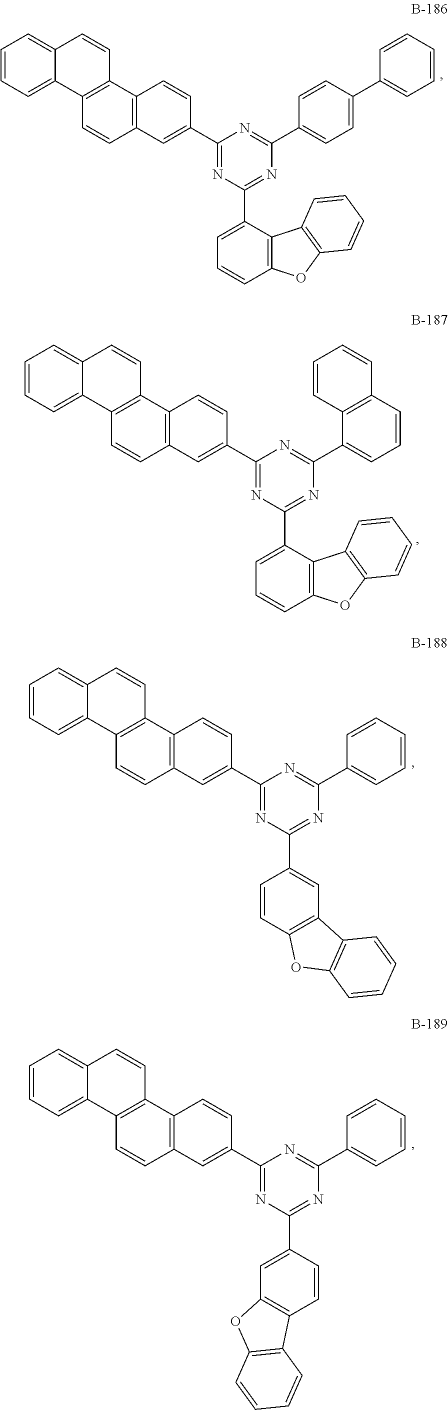 [SMILES: c1ccc(-c2ccc(-c3nc(-c4ccc5c(ccc6c7ccccc7ccc56)c4)nc(-c4cccc5oc6ccccc6c45)n3)cc2)cc1 ; c1ccc2c(-c3nc(-c4ccc5c(ccc6c7ccccc7ccc56)c4)nc(-c4cccc5oc6ccccc6c45)n3)cccc2c1 ; c1ccc(-c2nc(-c3ccc4c(ccc5c6ccccc6ccc45)c3)nc(-c3ccc4oc5ccccc5c4c3)n2)cc1 ; c1ccc(-c2nc(-c3ccc4c(ccc5c6ccccc6ccc45)c3)nc(-c3ccc4c(c3)oc3ccccc34)n2)cc1] 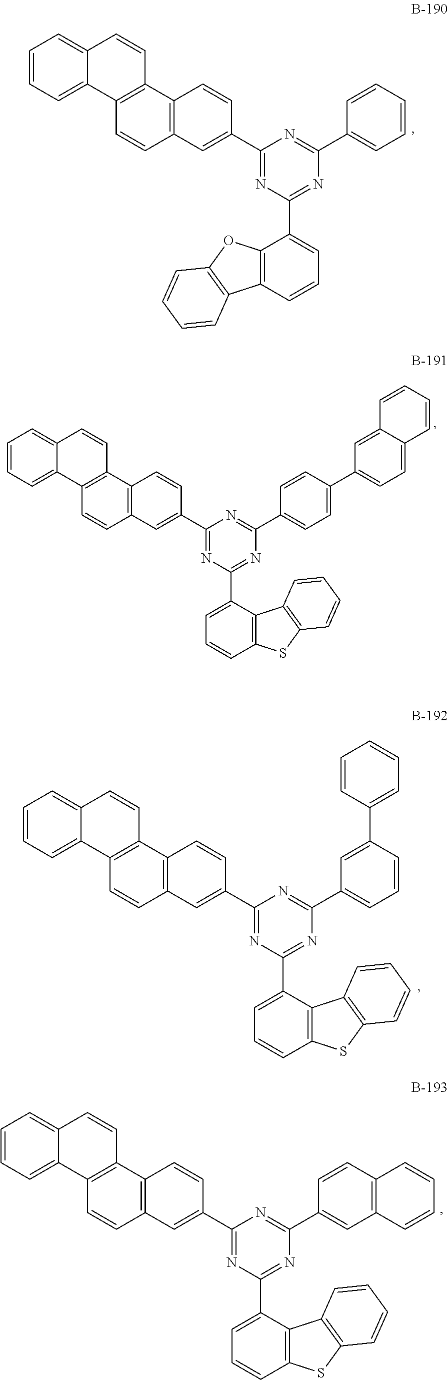 [SMILES: c1ccc(-c2nc(-c3ccc4c(ccc5c6ccccc6ccc45)c3)nc(-c3cccc4c3oc3ccccc34)n2)cc1 ; c1ccc2cc(-c3ccc(-c4nc(-c5ccc6c(ccc7c8ccccc8ccc67)c5)nc(-c5cccc6sc7ccccc7c56)n4)cc3)ccc2c1 ; c1ccc(-c2cccc(-c3nc(-c4ccc5c(ccc6c7ccccc7ccc56)c4)nc(-c4cccc5sc6ccccc6c45)n3)c2)cc1 ; c1ccc2cc(-c3nc(-c4ccc5c(ccc6c7ccccc7ccc56)c4)nc(-c4cccc5sc6ccccc6c45)n3)ccc2c1] 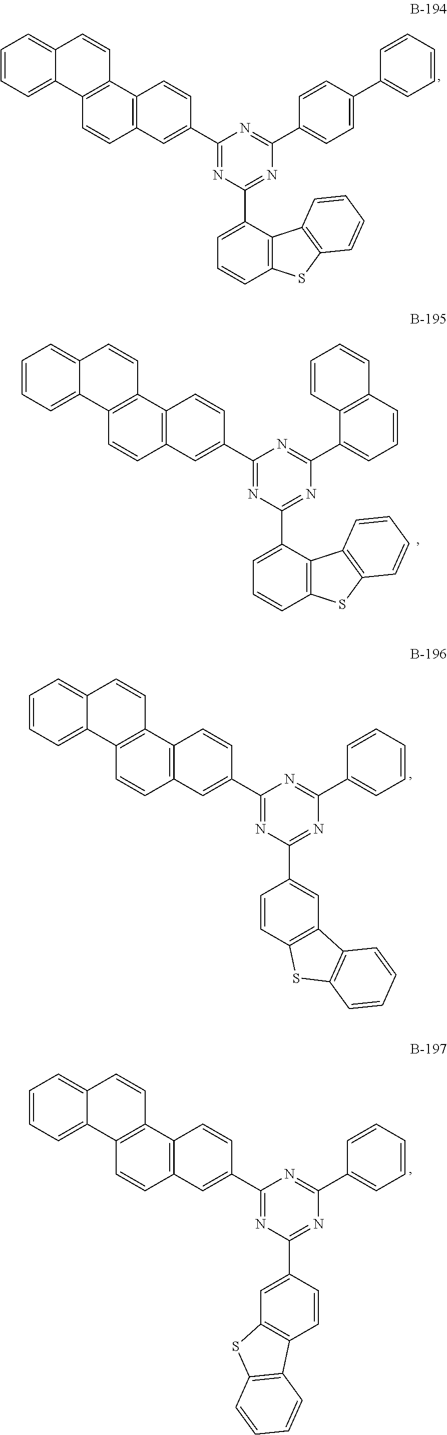 [SMILES: c1ccc(-c2ccc(-c3nc(-c4ccc5c(ccc6c7ccccc7ccc56)c4)nc(-c4cccc5sc6ccccc6c45)n3)cc2)cc1 ; c1ccc2c(-c3nc(-c4ccc5c(ccc6c7ccccc7ccc56)c4)nc(-c4cccc5sc6ccccc6c45)n3)cccc2c1 ; c1ccc(-c2nc(-c3ccc4c(ccc5c6ccccc6ccc45)c3)nc(-c3ccc4sc5ccccc5c4c3)n2)cc1 ; c1ccc(-c2nc(-c3ccc4c(ccc5c6ccccc6ccc45)c3)nc(-c3ccc4c(c3)sc3ccccc34)n2)cc1] 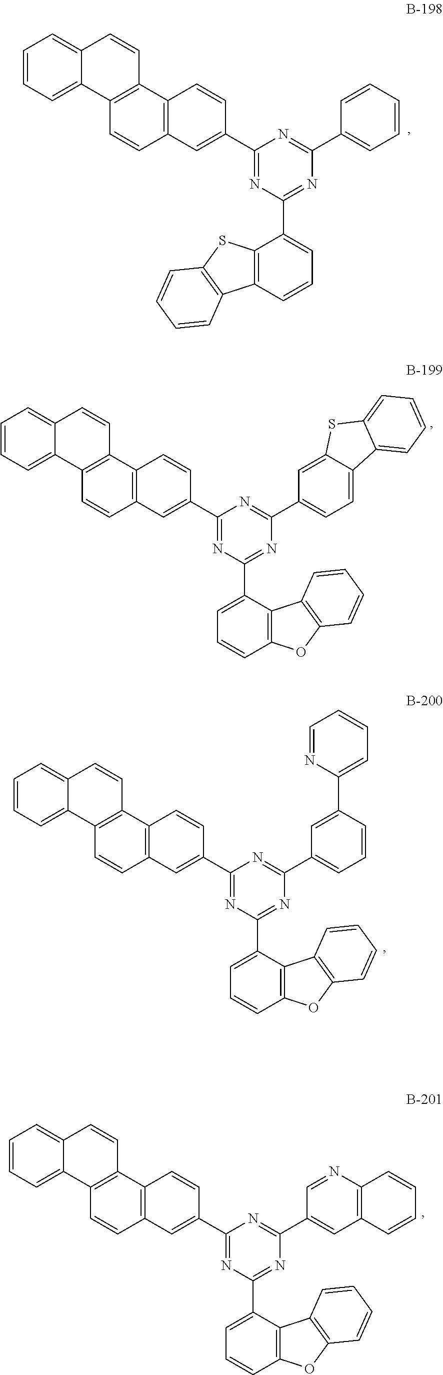 [SMILES: c1ccc(-c2nc(-c3ccc4c(ccc5c6ccccc6ccc45)c3)nc(-c3cccc4c3sc3ccccc34)n2)cc1 ; c1ccc2c(c1)ccc1c3ccc(-c4nc(-c5ccc6c(c5)sc5ccccc56)nc(-c5cccc6oc7ccccc7c56)n4)cc3ccc21 ; c1ccc(-c2cccc(-c3nc(-c4ccc5c(ccc6c7ccccc7ccc56)c4)nc(-c4cccc5oc6ccccc6c45)n3)c2)nc1 ; c1ccc2ncc(-c3nc(-c4ccc5c(ccc6c7ccccc7ccc56)c4)nc(-c4cccc5oc6ccccc6c45)n3)cc2c1] 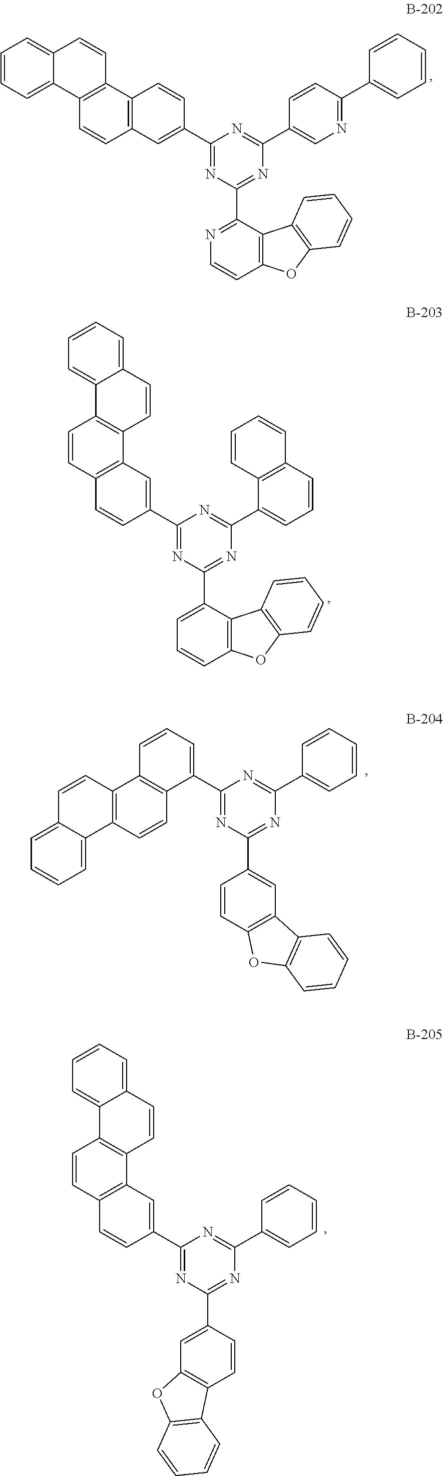 [SMILES: c1ccc(-c2ccc(-c3nc(-c4ccc5c(ccc6c7ccccc7ccc56)c4)nc(-c4nccc5oc6ccccc6c45)n3)cn2)cc1 ; c1ccc2c(-c3nc(-c4ccc5ccc6c7ccccc7ccc6c5c4)nc(-c4cccc5oc6ccccc6c45)n3)cccc2c1 ; c1ccc(-c2nc(-c3ccc4oc5ccccc5c4c3)nc(-c3cccc4c3ccc3c5ccccc5ccc43)n2)cc1 ; c1ccc(-c2nc(-c3ccc4c(c3)oc3ccccc34)nc(-c3ccc4ccc5c6ccccc6ccc5c4c3)n2)cc1] 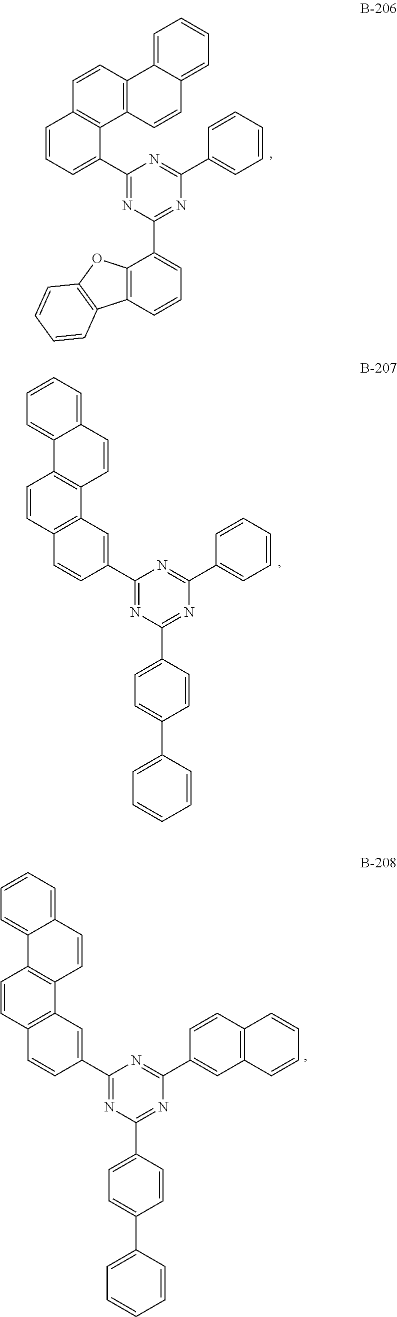 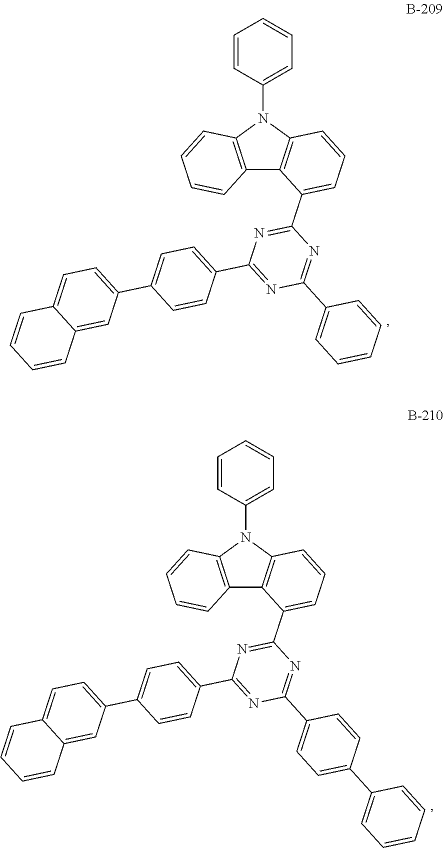 [SMILES: c1ccc(-c2nc(-c3ccc(-c4ccc5ccccc5c4)cc3)nc(-c3cccc4c3c3ccccc3n4-c3ccccc3)n2)cc1 ; c1ccc(-c2ccc(-c3nc(-c4ccc(-c5ccc6ccccc6c5)cc4)nc(-c4cccc5c4c4ccccc4n5-c4ccccc4)n3)cc2)cc1] 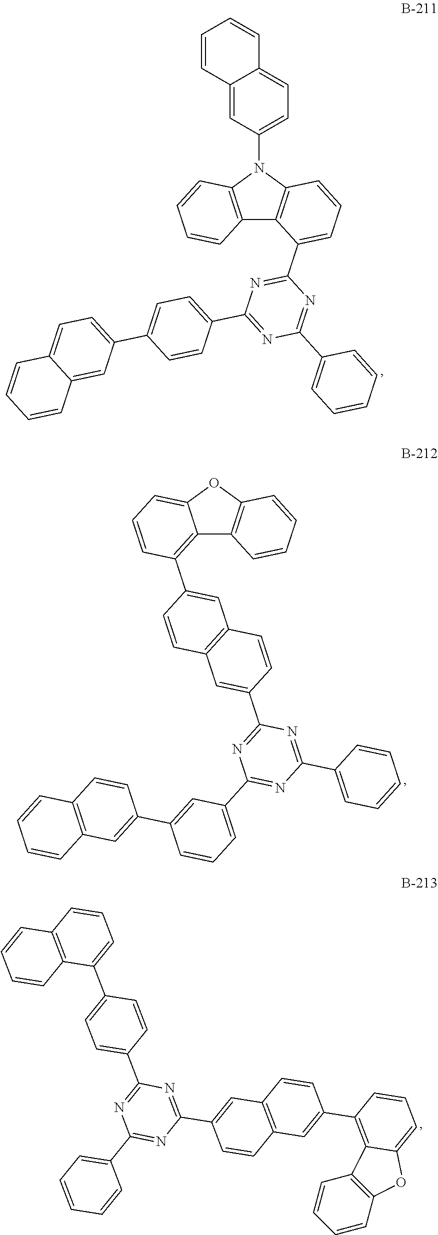 [SMILES: c1ccc(-c2nc(-c3ccc(-c4ccc5ccccc5c4)cc3)nc(-c3cccc4c3c3ccccc3n4-c3ccc4ccccc4c3)n2)cc1 ; c1ccc(-c2nc(-c3cccc(-c4ccc5ccccc5c4)c3)nc(-c3ccc4cc(-c5cccc6oc7ccccc7c56)ccc4c3)n2)cc1 ; c1ccc(-c2nc(-c3ccc(-c4cccc5ccccc45)cc3)nc(-c3ccc4cc(-c5cccc6oc7ccccc7c56)ccc4c3)n2)cc1] 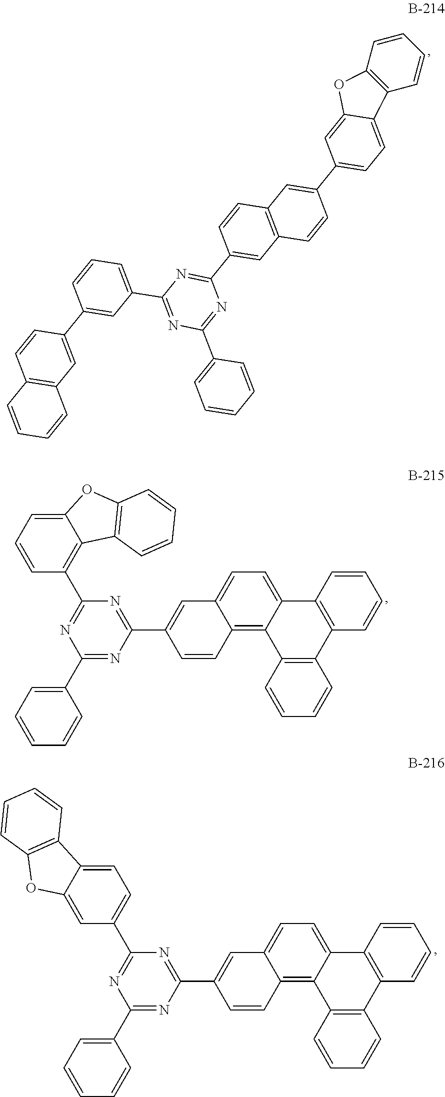 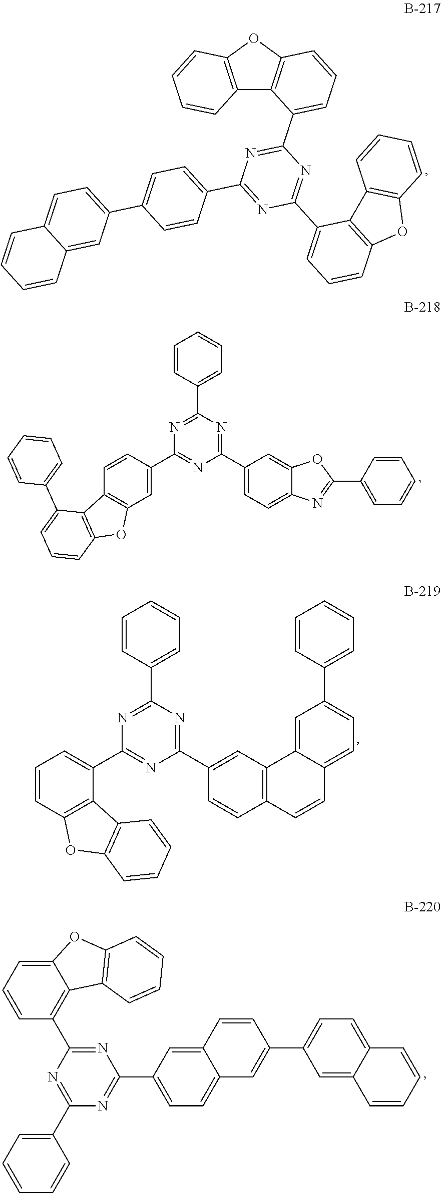 [SMILES: c1ccc2cc(-c3ccc(-c4nc(-c5cccc6oc7ccccc7c56)nc(-c5cccc6oc7ccccc7c56)n4)cc3)ccc2c1 ; c1ccc(-c2nc(-c3ccc4nc(-c5ccccc5)oc4c3)nc(-c3ccc4c(c3)oc3cccc(-c5ccccc5)c34)n2)cc1 ; c1ccc(-c2ccc3ccc4ccc(-c5nc(-c6ccccc6)nc(-c6cccc7oc8ccccc8c67)n5)cc4c3c2)cc1 ; c1ccc(-c2nc(-c3ccc4cc(-c5ccc6ccccc6c5)ccc4c3)nc(-c3cccc4oc5ccccc5c34)n2)cc1] 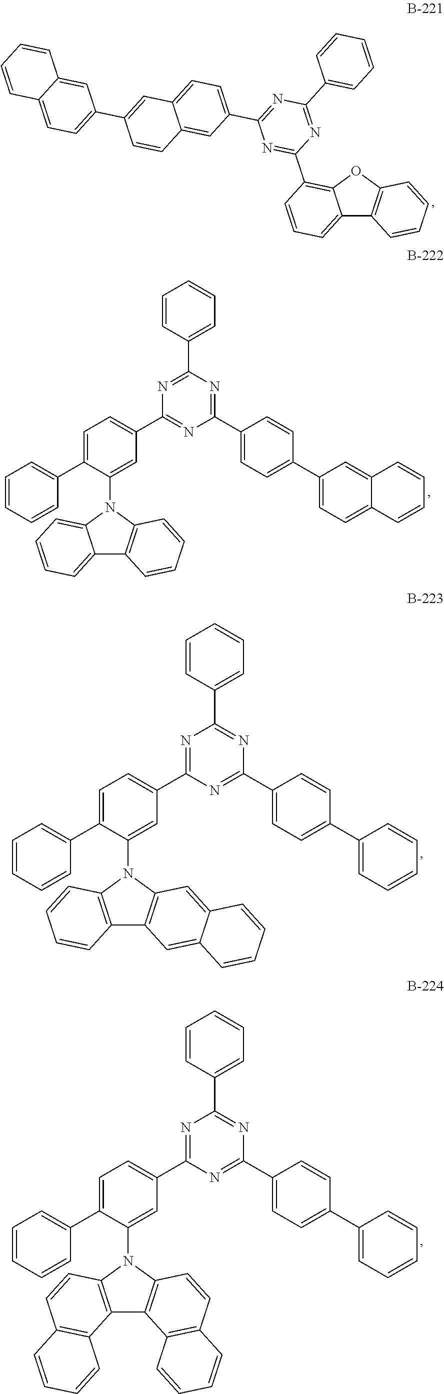 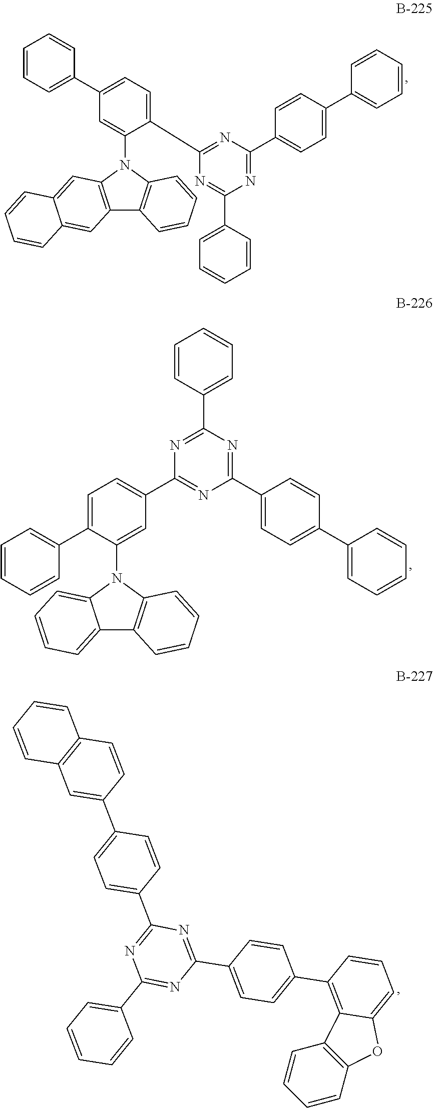 [SMILES: c1ccc(-c2ccc(-c3nc(-c4ccccc4)nc(-c4ccc(-c5ccccc5)cc4-n4c5ccccc5c5cc6ccccc6cc54)n3)cc2)cc1 ; c1ccc(-c2ccc(-c3nc(-c4ccccc4)nc(-c4ccc(-c5ccccc5)c(-n5c6ccccc6c6ccccc65)c4)n3)cc2)cc1 ; c1ccc(-c2nc(-c3ccc(-c4ccc5ccccc5c4)cc3)nc(-c3ccc(-c4cccc5oc6ccccc6c45)cc3)n2)cc1] 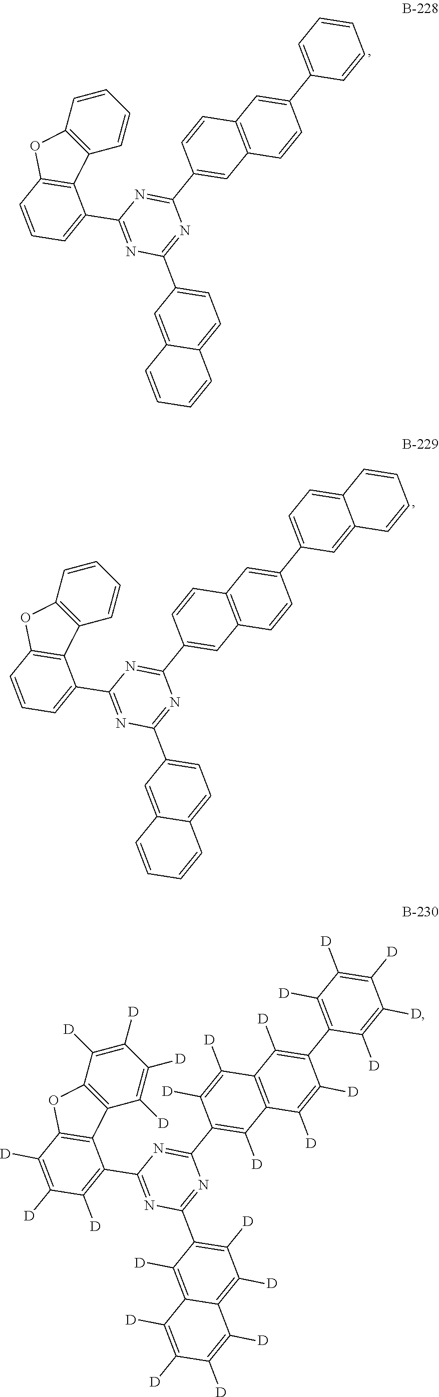 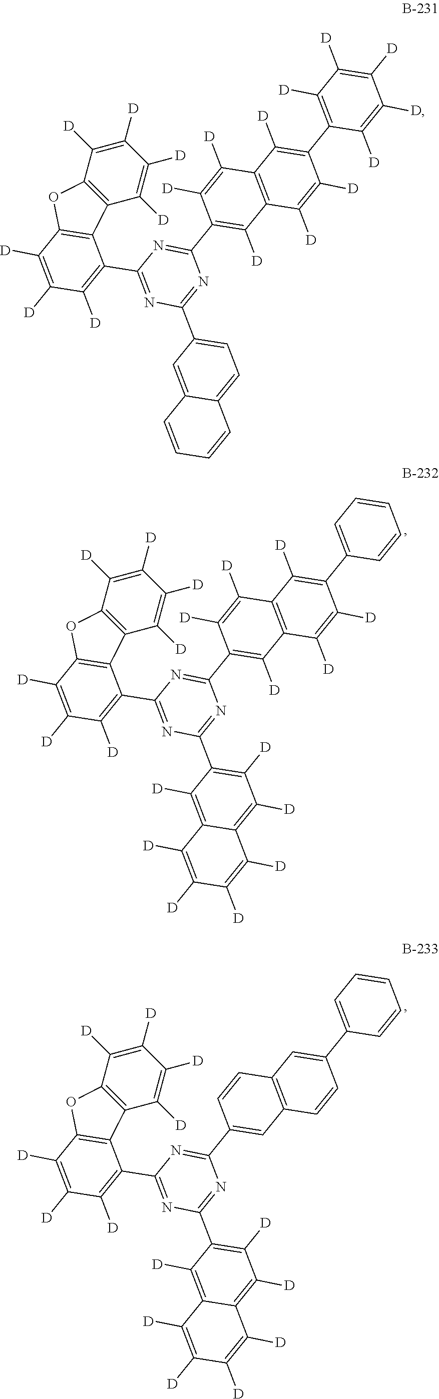 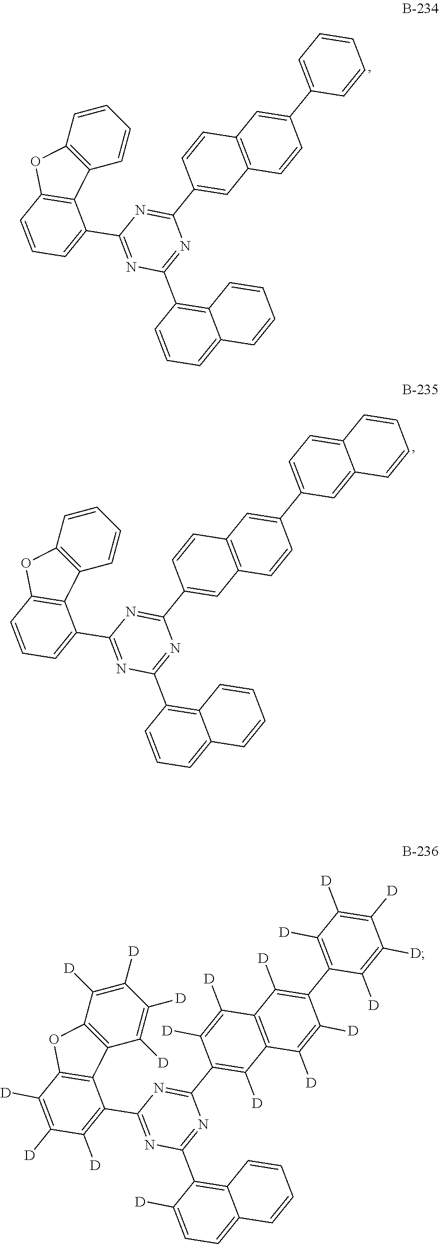
wherein optionally, hydrogen in the Compound B-1 to Compound B-236 can be partially or fully substituted with deuterium.

21. A compound composition, comprising the metal complex according to claim 1.
